(19) United States
(12) Patent Application Publication
(10) Pub. No.: US 2026/0190858 A1
(43) Pub. Date: Jul. 2, 2026

(54) PLURALITY OF HOST MATERIALS, AN ORGANIC ELECTROLUMINESCENT COMPOUND, AND AN ORGANIC ELECTROLUMINESCENT DEVICE COMPRISING THE SAME

(71) Applicant: DuPont Specialty Materials Korea Ltd., Chungcheongnam-do (KR)

(72) Inventors: Jeong-Eun YANG, Gyeonggi-do (KR); Hee-Ryong KANG, Gyeonggi-do (KR); Jeong-Hwan JEON, Gyeonggi-do (KR); Dong-Gil KIM, Gyeonggi-do (KR); Ji-Won UM, Gyeonggi-do (KR); Bitnari KIM, Gyeonggi-do (KR); Mi-Ran SEO, Gyeonggi-do (KR); Sang-Hee CHO, Gyeonggi-do (KR); Byung-Jun PARK, Gyeonggi-do (KR); Yoo-Jin DOH, Gyeonggi-do (KR); HaeYeon KIM, Gyeonggi-do (KR)

(21) Appl. No.: 19/420,828

(22) Filed: Dec. 16, 2025

(30) Foreign Application Priority Data
Dec. 30, 2024 (KR) 10-2024-0199940
Nov. 28, 2025 (KR) 10-2025-0185654

(51) Int. Cl. H10K 85/60; C07F 5/02; C09K 11/02; C09K 11/06; H10K 50/11

(52) U.S. Cl. CPC H10K 85/658; C07F 5/027; C09K 11/02; C09K 11/06; H10K 85/622; H10K 85/636; H10K 85/654; C09K 2211/1007; C09K 2211/1011; C09K 2211/1014; C09K 2211/1018; C09K 2211/1022; H10K 50/11; H10K 85/6574

(57) ABSTRACT

The present disclosure relates to a plurality of host materials, an organic electroluminescent compound, and an organic electroluminescent device comprising the same. By comprising a compound according to the present disclosure, or by comprising a specific combination of compounds according to the present disclosure as a plurality host materials, an organic electroluminescent device having improved driving voltage, luminous efficiency, and/or lifetime properties compared to conventional organic electroluminescent devices can be provided.

### TECHNICAL FIELD

The present disclosure relates to a plurality of host materials, an organic electroluminescent compound, and an organic electroluminescent device comprising the same.

### BACKGROUND ART

The TPD/Alq3 bilayer small-molecule green organic electroluminescent device (OLED) with green emission, which is constituted with a light-emitting layer and a charge transport layer, was first developed by Tang et al. of Eastman Kodak in 1987. Thereafter, studies on organic electroluminescent devices have proceeded rapidly, and OLEDs have since been commercialized. At present, OLEDs primarily use phosphorescent materials having excellent luminous efficiency in panel implementation. In many applications such as TVs and lightings, the lifetime of OLEDs is often insufficient, and higher efficiency of OLEDs is still required. Generally, the lifetime of an OLED decreases as its luminance increases. Thus, OLEDs with high luminous efficiency and/or extended lifetime are required for long-term use and high-resolution displays.

In order to improve luminous efficiency, driving voltage, and/or lifetime, various materials or concepts for an organic layer of an organic electroluminescent device have been proposed, but they were not proven satisfactory in practical use. Accordingly, there is a continuous demand for the development of an organic electroluminescent device with enhanced performance, such as improved driving voltage, luminous efficiency, power efficiency, and/or lifetime properties, as compared to previously disclosed organic electroluminescent devices.

Meanwhile, Korean Patent Application Laid-Open No. 2023-0112796, Chinese Patent Application Laid-Open No. 116802257 A, and Chinese Patent Publication No. 11136978 B disclose an organic electroluminescent compound having a structure such as dibenzo[1,2]azaborine or benzo[1,2]azaborine, and an organic electroluminescent device using the same, or a plurality of host materials comprising the compound of such a structure as a host, and an organic electroluminescent device using the same, but fail to specifically disclose organic electroluminescent devices having improved performance, such as low driving voltage and/or high luminous efficiency and/or longer lifetime properties by comprising an organic electroluminescent compound having a specific substituent at a specific position or a plurality of host materials of a specific combination as in the present disclosure.

### DISCLOSURE OF INVENTION

### Technical Problem

The objective of the present disclosure is to provide an organic electroluminescent compound having a new structure suitable for applying to an organic electroluminescent device. Another objective of the present disclosure is to provide an organic electroluminescent device having lower driving voltage, higher luminous efficiency, and/or improved lifetime property by comprising a plurality of host materials comprising a specific combination of compounds.

### Solution to Problem

As a result of intensive studies to solve the technical problems, the present inventors found that the above objective can be achieved by a plurality of host materials comprising at least one first host compound and at least one second host compound, wherein the first host compound is represented by the following Formula 1 and the second host compound is different from the first host compound; or an an organic electroluminescent compound represented by the following Formula 1′.

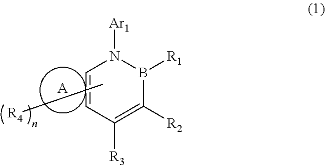

In Formula 1,
ring A is not present, or represents a substituted or unsubstituted benzene, or a substituted or unsubstituted naphthalene;
Ar₁ and R₁ to R₄ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s); and
n represents an integer of 1 to 6; and if n is an integer of 2 or more, each of R₄ may be the same as or different from each other.

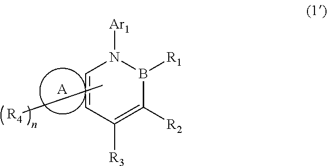

In Formula 1′,
ring A is not present, or represents a substituted or unsubstituted benzene, or a substituted or unsubstituted naphthalene;
Ar₁ and R₁ to R₄ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s); with a proviso that it is excluded that Ar₁ and R₁, and R₂ and R₃ are linked to form a ring(s);
with a proviso that if ring A represents a substituted or unsubstituted benzene, R₂ represents a phenyl unsubstituted or substituted with deuterium, or Ar₁ represents a substituted or unsubstituted (C₆-C₃₀)aryl, a substituted or unsubstituted (3- to 30-membered)heteroaryl, a substituted or unsubstituted mono- or di(C₆-C₃₀)arylamino, or a substituted or unsubstituted (C₆-C₃₀)aryl(3- to 30-membered)heteroarylamino; and
n represents an integer of 1 to 6; and if n is an integer of 2 or more, each of R₄ may be the same as or different from each other.

### Advantageous Effects of Invention

By comprising a plurality of compounds according to the present disclosure as host materials, an organic electroluminescent device having improved driving voltage, luminous efficiency, and/or lifetime properties compared to conventional organic electroluminescent devices is provided. In addition, an organic electroluminescent compound according to the present disclosure exhibits suitable performance for use in an organic electroluminescent device, and it is possible to produce a display system or a lighting system using the same.

### MODE FOR INVENTION

Hereinafter, the present disclosure will be described in detail. However, the following description is intended to explain the present disclosure, and is not meant in any way to restrict the scope of the present disclosure.

The “organic electroluminescent compound” in the present disclosure is a compound that may be used in an organic electroluminescent device, and may be comprised in any layer constituting an organic electroluminescent device, as necessary.

The term “an organic electroluminescent material” in the present disclosure means a material that may be used in an organic electroluminescent device, and may comprise at least one compound. The organic electroluminescent material may be comprised in any layer constituting an organic electroluminescent device, as necessary. For example, the organic electroluminescent material may be a hole injection material, a hole transport material, a hole auxiliary material, a light-emitting auxiliary material, an electron blocking material, a light-emitting material (including a host material and a dopant material), an electron buffer material, a hole blocking material, an electron transport material, an electron injection material, etc.

The term “a plurality of host materials” in the present disclosure means a host material comprising a combination of two or more compounds that may be included in any light-emitting layer constituting an organic electroluminescent device. It may mean both a material before being comprised in an organic electroluminescent device (for example, before vapor deposition) and a material after being comprised in an organic electroluminescent device (for example, after vapor deposition). For example, the plurality of host materials of the present disclosure is a combination of at least two host materials, and may optionally further comprise conventional materials comprised in an organic electroluminescent material. At least two compounds comprised in the plurality of host materials of the present disclosure may be comprised together in one light-emitting layer or may respectively be comprised in different light-emitting layers. For example, the at least two host materials may be mixture-evaporated or co-evaporated, or may be individually evaporated.

Herein, the term “(C₁-C₃₀)alkyl” is meant to refer to a linear or branched alkyl having 1 to 30 carbon atoms constituting a chain, in which the number of carbon atoms is preferably 1 to 10, and more preferably 1 to 6. The above alkyl may include methyl, ethyl, n-propyl, isopropyl, n-butyl, isobutyl, tert-butyl, sec-butyl, etc. The term “(C₃-C₃₀)cycloalkyl” is meant to refer to a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. The term “(3- to 7-membered)heterocycloalkyl” is meant to refer to a cycloalkyl having 3 to 7 ring backbone atoms, and including at least one heteroatom selected from the group consisting of B, N, O, S, Si, and P, and preferably the group consisting of O, S, and N. The above heterocycloalkyl may include tetrahydrofuran, pyrrolidine, thiolane, tetrahydropyran, etc. The term “(C₆-C₃₀)aryl” or “(C₆-C₃₀)arylene” is meant to refer to a monocyclic or fused ring radical derived from an aromatic hydrocarbon having 6 to 30 ring backbone carbon atoms, and may be partially saturated. The above aryl, and arylene may comprise a spiro structure. The above aryl may include phenyl, biphenyl, terphenyl, quinquiphenyl, naphthyl, binaphthyl, phenylnaphthyl, naphthylphenyl, fluorenyl, phenylfluorenyl, diphenylfluorenyl, benzofluorenyl, dibenzofluorenyl, phenanthrenyl, phenylphenanthrenyl, benzophenanthrenyl, anthracenyl, indenyl, triphenylenyl, pyrenyl, tetracenyl, perylenyl, chrysenyl, naphthacenyl, fluoranthenyl, spirobifluorenyl, spiro[fluorene-benzofluoren]yl, spiro[cyclopentene-fluoren]yl, spiro[dihydroindene-fluoren]yl, azulenyl, tetramethyl-dihydrophenanthrenyl, etc. Specifically, the aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzo[a]fluorenyl, benzo[b]fluorenyl, benzo[c]fluorenyl, dibenzofluorenyl, 2-biphenylyl, 3-biphenylyl, 4-biphenylyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, p-tert-butylphenyl, p-(2-phenylpropyl)phenyl, 4′-methylbiphenyl, 4″-tert-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc.

The “(3- to 30-membered)heteroaryl” or “(3- to 30-membered)heteroarylene” in the present disclosure refers to an aryl group or arylene group having 3 to 30 ring backbone atoms and including at least one heteroatom(s) selected from the group consisting of B, N, O, S, Si, P, Se, Te, and Ge. The number of heteroatoms is preferably 1 to 4. The above heteroaryl or heteroarylene may be a monocyclic ring or a fused ring condensed with at least one benzene ring, and may be partially saturated. In addition, the above heteroaryl may be one formed by linking at least one heteroaryl or aryl group to a heteroaryl group via a single bond(s), and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl such as benzofuranyl, benzothiophenyl, isobenzofuranyl, dibenzofuranyl, dibenzothiophenyl, dibenzoselenophenyl, naphthobenzofuranyl, naphthobenzothiophenyl, naphthooxazolyl, benzofuroquinolinyl, benzofuroquinazolinyl, benzofuronaphthyridinyl, benzofuropyrimidinyl, naphthofuropyrimidinyl, benzothienoquinolyl, benzothienoquinazolinyl, naphthyridinyl, benzothienonaphthyridinyl, benzothienopyrimidinyl, naphthienopyrimidinyl, pyrimidoindolyl, benzopyrimidoindolyl, benzofuropyrazinyl, naphthofuropyrazinyl, benzothienopyrazinyl, naphthothienopyrazinyl, phenanthrooxazolyl, phenanthrothiazolyl, phenanthrobenzofuranyl, benzophenanthrothiophenyl, pyrazinoindolyl, benzopyrazinoindolyl, benzimidazolyl, benzothiazolyl, benzisothiazolyl, benzisoxazolyl, benzoxazolyl, isoindolyl, indolyl, indazolyl, benzothiadiazolyl, quinolyl, isoquinolyl, cinnolinyl, quinazolinyl, benzoquinazolinyl, quinoxalinyl, benzoquinoxalinyl, carbazolyl, benzocarbazolyl, dibenzocarbazolyl, phenoxazinyl, phenanthridinyl, benzodioxolyl, dihydroacridinyl, benzotriazolyl, phenazinyl, imidazopyridyl, chromenoquinazolinyl, thiochromenoquinazolinyl, dimethylbenzopyrimidinyl, indolocarbazolyl, indenocarbazolyl, etc. More specifically, the heteroaryl may include 1-pyrrolyl, 2-pyrrolyl, 3-pyrrolyl, pyrazinyl, 2-pyridyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridyl, 3-imidazopyridyl, 5-imidazopyridyl, 6-imidazopyridyl, 7-imidazopyridyl, 8-imidazopyridyl, 3-pyridyl, 4-pyridyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazolyl-1-yl, azacarbazolyl-2-yl, azacarbazolyl-3-yl, azacarbazolyl-4-yl, azacarbazolyl-5-yl, azacarbazolyl-6-yl, azacarbazolyl-7-yl, azacarbazolyl-8-yl, azacarbazolyl-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. Additionally, “(3- to 30-membered)heteroaryl(ene)” can be classified into a heteroaryl(ene) with electronic properties and a heteroaryl(ene) with hole properties. A heteroaryl(ene) with electronic properties is a substituent that is relatively rich in electrons in the parent nucleus, for example, a substituted or unsubstituted pyridyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc. A heteroaryl(ene) with hole properties is a substituent that is relatively electron-deficient in the parent nucleus, for example, a substituted or unsubstituted carbazolyl, a substituted or unsubstituted dibenzofuranyl, a substituted or unsubstituted dibenzothiophenyl, etc. Herein, “halogen” includes F, Cl, Br, and I.

In addition, “ortho-” (“o-”), “meta-” (“m-”), and “para” (“p-”) are prefixes which each represent the relative positions of substituents. The prefix “ortho-” indicates that two substituents are adjacent to each other, and for example, when two substituents in a benzene derivative occupy positions 1 and 2 or 2 and 3, this is called an “ortho-” configuration. The prefix “meta-” indicates that two substituents are at positions 1 and 3, and for example, when two substituents in a benzene derivative occupy positions 1 and 3, this is called a “meta-” configuration. The prefix “para-” indicates that two substituents are at positions 1 and 4, and for example, when two substituents in a benzene derivative occupy positions 1 and 4, this is called a “para-” configuration.

Herein, “substituted” in the expression “substituted or unsubstituted” means that a hydrogen atom in a certain functional group is replaced with another atom or another functional group, i.e., a substituent. Unless otherwise specified, the substituent may replace hydrogen at a position where the substituent can be substituted without limitation, and when two or more hydrogen atoms in a certain functional group are each replaced with a substituent, each substituent may be the same as or different from each other. The maximum number of substituents that can be substituted for a certain functional group may be the total number of valences that can be substituted for each atom forming the functional group. In the present disclosure, the substituted alkyl, the substituted aryl(ene), the substituted heteroaryl(ene), the substituted cycloalkyl, the substituted alkoxy, the substituted trialkylsilyl, the substituted dialkylarylsilyl, the substituted alkyldiarylsilyl, the substituted triarylsilyl, the substituted fused ring group of an aliphatic ring(s) and an aromatic ring(s), the substituted mono- or dialkylamino, the substituted mono- or dialkenylamino, the substituted alkylalkenylamino, the substituted mono- or diarylamino, the substituted alkylarylamino, the substituted mono- or diheteroarylamino, the substituted alkylheteroarylamino, the substituted alkenylarylamino, the substituted alkenylheteroarylamino, and the substituted arylheteroarylamino each independently may be substituted with at least one selected from the group consisting of deuterium, a halogen, a cyano, a carboxyl, a nitro, a hydroxyl, a (C₁-C₃₀)alkyl, a halo(C₁-C₃₀)alkyl, a (C₂-C₃₀)alkenyl, a (C₂-C₃₀)alkynyl, a (C₁-C₃₀)alkoxy, a (C₁-C₃₀)alkylthio, a (C₃-C₃₀)cycloalkyl, a (C₃-C₃₀)cycloalkenyl, a (3- to 7-membered)heterocycloalkyl, a (C₆-C₃₀)aryloxy, a (C₆-C₃₀)arylthio, a (3- to 30-membered)heteroaryl, a (C₆-C₃₀)aryl, a tri(C₁-C₃₀)alkylsilyl, a tri(C₆-C₃₀)arylsilyl, a di(C₁-C₃₀)alkyl(C₆-C₃₀)arylsilyl, a (C₁-C₃₀)alkyldi(C₆-C₃₀)arylsilyl, a fused ring group of a (C₃-C₃₀) aliphatic ring(s) and a (C₆-C₃₀) aromatic ring(s), an amino, a mono- or di(C₁-C₃₀)alkylamino, a substituted or unsubstituted mono- or di(C₆-C₃₀)arylamino, a (C₁-C₃₀)alkyl(C₆-C₃₀)arylamino, a mono- or di(3- to 30-membered)heteroarylamino, a (C₁-C₃₀)alkyl(3- to 30-membered)heteroarylamino, a (C₆-C₃₀)aryl(3- to 30-membered)heteroarylamino, a (C₁-C₃₀)alkylcarbonyl, a (C₁-C₃₀)alkoxycarbonyl, a (C₆-C₃₀)arylcarbonyl, a (C₆-C₃₀)arylphosphinyl, a di(C₆-C₃₀)arylboronyl, a di(C₁-C₃₀)alkylboronyl, a (C₁-C₃₀)alkyl(C₆-C₃₀)arylboronyl, a (C₆-C₃₀)aryl(C₁-C₃₀)alkyl, a (C₁-C₃₀)alkyl(C₆-C₃₀)aryl, and a combination thereof. According to one embodiment of the present disclosure, the substituted alkyl, etc. each independently may be substituted with at least one selected from the group consisting deuterium; a cyano; a (C₁-C₃₀)alkyl; a substituted or unsubstituted (3- to 30-membered)heteroaryl; a substituted or unsubstituted (C₆-C₃₀)aryl; and a mono- or di(C₆-C₃₀)arylamino. According to another embodiment of the present disclosure, the substituted alkyl, etc. each independently may be substituted with at least one selected from the group consisting deuterium; a cyano; a (C₁-C₁₀)alkyl; a substituted or unsubstituted (3- to 20-membered)heteroaryl; a substituted or unsubstituted (C₆-C₂₀)aryl; and a mono- or di(C₆-C₂₀)arylamino. For example, the substituted alkyl, etc. each independently may be substituted with at least one selected from the group consisting deuterium, a cyano, a methyl, a tert-butyl, a phenyl unsubstituted or substituted with deuterium or a naphthyl, a naphthyl unsubstituted or substituted with a phenyl, a biphenyl, a fluoranthenyl, a phenanthrenyl, an anthracenyl, an triphenylenyl, a dibenzofuranyl, a dibenzothiophenyl, a dibenzoselenophenyl, a pyridyl unsubstituted or substituted with a phenyl, a benzimidazolyl unsubstituted or substituted with a phenyl, a triphenylsilyl, and diphenylamino, which may be further substituted with deuterium.

In the present disclosure, if a substituent is not indicated in the chemical formula or compound structure, it may mean that all possible positions for the substituent are hydrogen or deuterium. That is, in the case of deuterium, it is an isotope of hydrogen, and some hydrogen atoms may be the isotope deuterium, and in this case, the content of deuterium may be 0% to 100%. In the present disclosure, in cases where a substituent is not indicated in the chemical formula or compound structure, if the substituent is not explicitly excluded, such as 0% deuterium, 100% hydrogen, and all substituents are hydrogen, hydrogen and deuterium may be used intermixed in a compound. Deuterium is one of the isotopes of hydrogen and an element with a deuteron consisting of one proton and one neutron as its nucleus. It can be represented as hydrogen-2, whose element symbol can also be written as D or ²H. Isotopes are atoms with the same atomic number (Z) but different mass numbers (A), and can also be interpreted as elements with the same number of protons but different numbers of neutrons.

In the present disclosure, “a combination thereof” refers to a combination of one or more elements from the corresponding list to form a known or chemically stable arrangement that can be envisioned by a person skilled in the art from the corresponding list. For example, alkyl and deuterium can be combined to form a partially or fully deuterated alkyl group; a halogen and alkyl can be combined to form a halogenated alkyl substituent; and a halogen, alkyl, and aryl can be combined to form a halogenated arylalkyl. For example, a preferred combination of substituents includes up to 50 atoms that are not hydrogen or deuterium, or up to 40 atoms that are not hydrogen or deuterium, or up to 30 atoms that are not hydrogen or deuterium, or in many cases, a preferred combination of substituents may comprise up to 20 atoms that are not hydrogen or deuterium.

In the Formulas of the present disclosure, when a ring is formed by a linkage of adjacent substituents, the ring may be a substituted or unsubstituted, mono- or polycyclic, (3- to 30-membered) alicyclic or aromatic ring, or a combination thereof, which is formed by linkage of at least two adjacent substituents. In addition, the formed ring may contain at least one heteroatom selected from B, N, O, S, Si, and P, preferably at least one heteroatom selected from N, O, and S. According to one embodiment of the present disclosure, the number of the ring backbone atoms is 5 to 20, and according to another embodiment of the present disclosure, the number of the ring backbone atoms is 5 to 15.

The present disclosure provides a plurality of host materials comprising at least one first host compound and at least one second host compound, wherein the first host compound is represented by Formula 1, and the second host compound is different from the first host compound.

The compound represented by Formula 1 is described in more detail as follows.

In Formula 1, ring A is not present, or represents a substituted or unsubstituted benzene, or a substituted or unsubstituted naphthalene.

In Formula 1, Ar₁ and R₁ to R₄ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s); and n represents an integer of 1 to 6; and if n is an integer of 2 or more, each of R₄ may be the same as or different from each other.

According to one embodiment of the present disclosure, Formula 1 is represented by any one of the following Formulas 1-1 to 1-3.

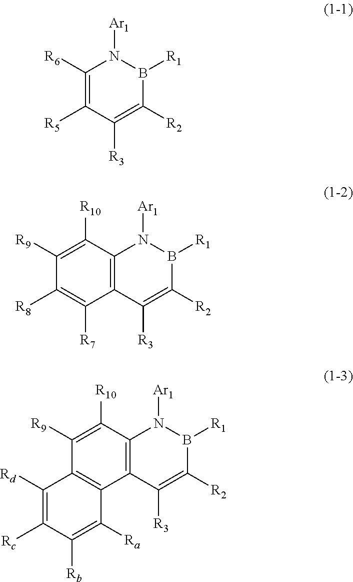

In Formulas 1-1 to 1-3, R₅ to R₁₀ and Rₐ to R_{d} are as defined for R₄ of Formula 1 above.

In Formulas 1-1 to 1-3, R₁ to R₃, and Ar₁ are as defined in Formula 1.

At least one of Ar₁ and R₁ to R₄ in Formula 1 represent a substituted or unsubstituted (C₆-C₃₀)aryl, a substituted or unsubstituted (3- to 30-membered)heteroaryl, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino. According to one embodiment of the present disclosure, at least one of Ar₁ and R₁ to R₄ represent a substituted or unsubstituted (C₆-C₂₀)aryl, a substituted or unsubstituted (3- to 25-membered)heteroaryl, a substituted or unsubstituted mono- or di(C₆-C₂₀)arylamino, a substituted or unsubstituted mono- or di(3- to 25-membered)heteroarylamino, or a substituted or unsubstituted (C₆-C₂₀)aryl(3- to 25-membered)heteroarylamino.

For example, R₁ to R₁₀ and Rₐ to R_{d} each independently may be hydrogen; a phenyl unsubstituted or substituted with a naphthyl or a dibenzofuranyl; a naphthyl; an indolocarbazolyl substituted with a phenyl; a triazinyl substituted with a phenyl, a naphthyl, a dibenzofuranyl, a carbazolyl, or a 23-membered heteroaryl containing nitrogen; a pyrimidinyl substituted with a phenyl; a quinazolinyl substituted with a phenyl; a quinoxalinyl substituted with a phenyl; a phenylbiphenylamino; a phenyldibenzofuranylamino; a phenanthrooxazolyl phenylamino; or a benzophenanthrofuranyl phenylamino, etc.

According to one embodiment of the present disclosure, Ar₁ each independently may be the following Formulas 1-a, 1-b, 1-c, or a phenyl, etc.

According to one embodiment of the present disclosure, at least one of Ar₁ and R₁ to R₄ in Formula 1 may be represented by any one of the following Formulas 1-a to 1-c.

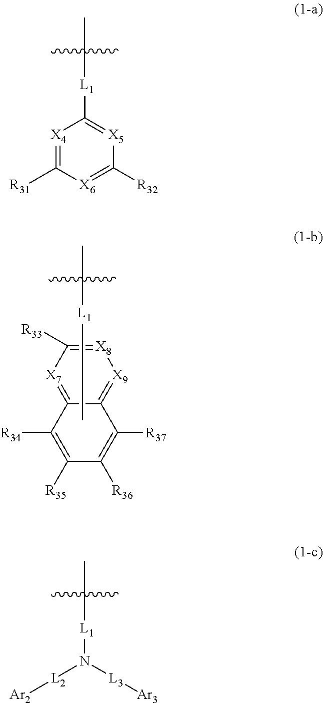

In Formulas 1-a to 1-c,

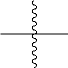

represents a site linked to Formula 1.

In Formulas 1-a to 1-c, L₁ to L₃ each independently represent a single bond, a substituted or unsubstituted (C₆-C₃₀)arylene, or a substituted or unsubstituted (3- to 30-membered)heteroarylene. According to one embodiment of the present disclosure, L₁ to L₃ each independently represent a single bond, or a substituted or unsubstituted (C₆-C₃₀)arylene. For example, L₁ to L₃ each independently may be a single bond, a phenylene, or a biphenylene unsubstituted or substituted with a cyano, etc.

In Formulas 1-a to 1-c, X₄ to X₉ each independently represent N or CR₃₈, with a proviso that at least one of X₄ to X₆ and at least one of X₇ to X₉ represent N.

In Formulas 1-a to 1-c, R₃₁ to R₃₈ each independently represent hydrogen, deuterium, a halogen, a cyano, a substituted or unsubstituted (C₁-C₃₀)alkyl, a substituted or unsubstituted (C₆-C₃₀)aryl, or a substituted or unsubstituted (3- to 30-membered)heteroaryl. According to one embodiment of the present disclosure, R₃₁ to R₃₈ each independently represent hydrogen, deuterium, a substituted or unsubstituted (C₆-C₃₀)aryl, a substituted or unsubstituted (3- to 30-membered)heteroaryl. According to another embodiment of the present disclosure, R₃₁ to R₃₈ each independently represent hydrogen, deuterium, a substituted or unsubstituted (C₆-C₃₀)aryl, or a substituted or unsubstituted (3- to 30-membered)heteroaryl. According to another embodiment of the present disclosure, R₃₁ to R₃₈ each independently represent hydrogen, deuterium, a substituted or unsubstituted (C₆-C₁₅)aryl, or a substituted or unsubstituted (3- to 23-membered)heteroaryl. For example, R₃₁ to R₃₈ each independently may be hydrogen; deuterium; a phneyl; a biphenyl; a naphthyl; a phenanthrenyl; a dibenzofuranyl unsubstituted or substituted with a phenyl; a dibenzothiophenyl; a carbazolyl; or a 23-membered heteroaryl containing nitrogen, etc.

With a proviso that in Formula 1-b, any one of X₇ to X₉, and R₃₃ to R₃₈ is linked to L₁.

In Formulas 1-a to 1-c, Ar₂ and Ar₃ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino. According to one embodiment of the present disclosure, Ar₂ and Ar₃ each independently represent hydrogen, deuterium, a substituted or unsubstituted (C₆-C₃₀)aryl, a substituted or unsubstituted (3- to 30-membered)heteroaryl, or a substituted or unsubstituted mono- or di(C₆-C₃₀)arylamino. According to another embodiment of the present disclosure, Ar₂ and Ar₃ each independently represent hydrogen, deuterium, a substituted or unsubstituted (C₆-C₂₅)aryl, or a substituted or unsubstituted (3-to 25-membered)heteroaryl. For example, Ar₂ and Ar₃ each independently may be a phenyl; a biphenyl; a naphthyl; a dimethylfluorenyl; a dimethylbenzofluorenyl; a dibenzofuranyl; a phenanthrooxazolyl; or a benzophenanthrofuranyl, etc.

According to one embodiment, the compound represented by Formula 1 may be at least one selected from the following compounds, but is not limited thereto.

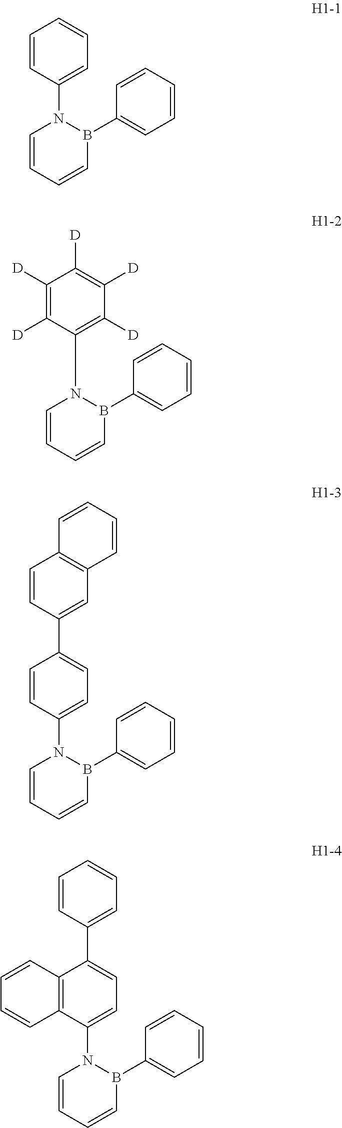

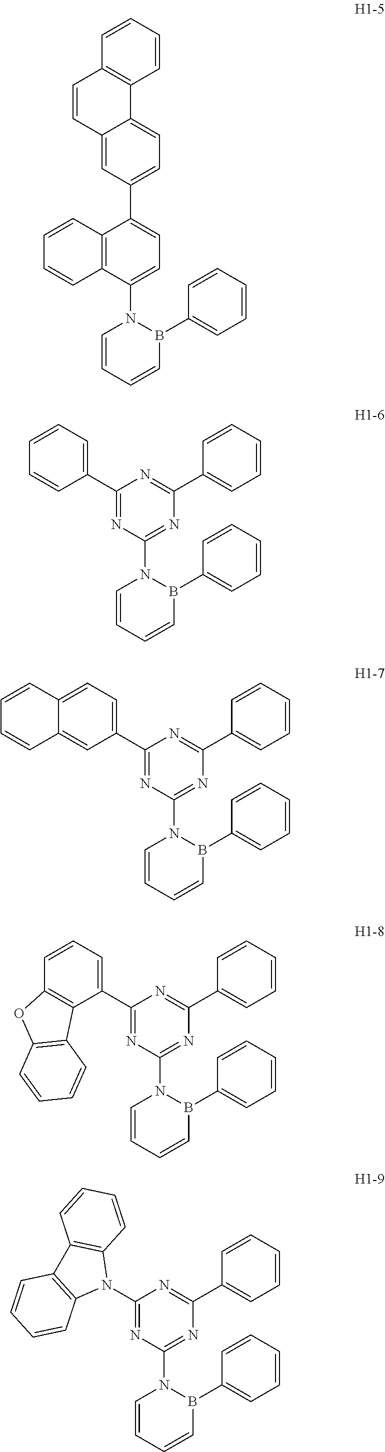 [SMILES: C1=CB(c2ccccc2)N(c2ccc(-c3ccc4c(ccc5ccccc54)c3)c3ccccc23)C=C1 ; C1=CB(c2ccccc2)N(c2nc(-c3ccccc3)nc(-c3ccccc3)n2)C=C1 ; C1=CB(c2ccccc2)N(c2nc(-c3ccccc3)nc(-c3ccc4ccccc4c3)n2)C=C1 ; C1=CB(c2ccccc2)N(c2nc(-c3ccccc3)nc(-c3cccc4oc5ccccc5c34)n2)C=C1 ; C1=CB(c2ccccc2)N(c2nc(-c3ccccc3)nc(-n3c4ccccc4c4ccccc43)n2)C=C1]

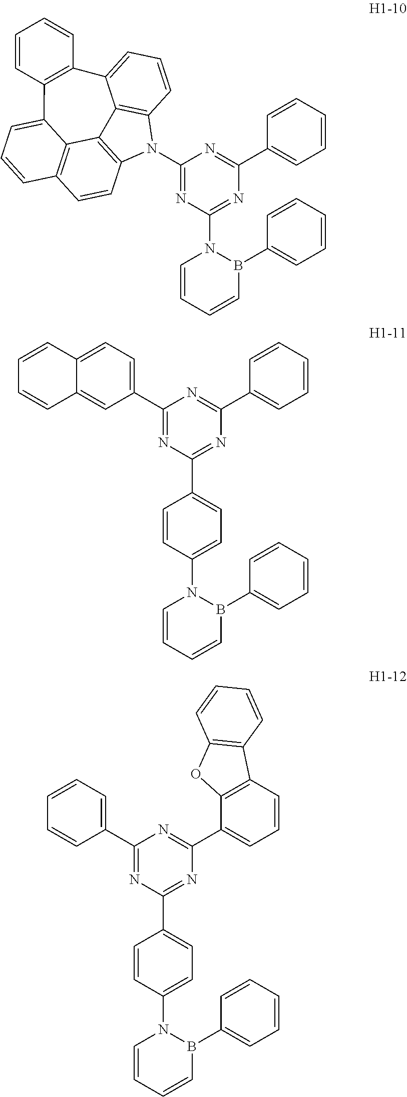

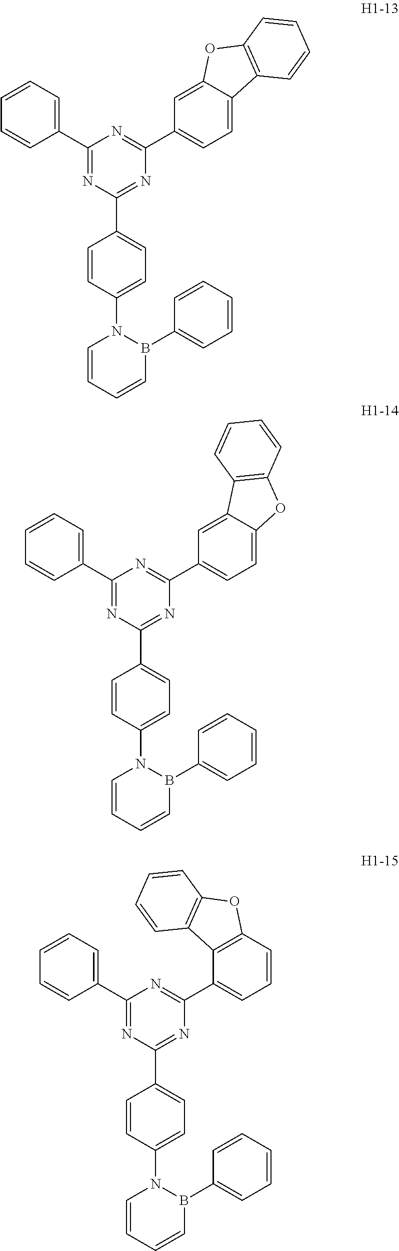

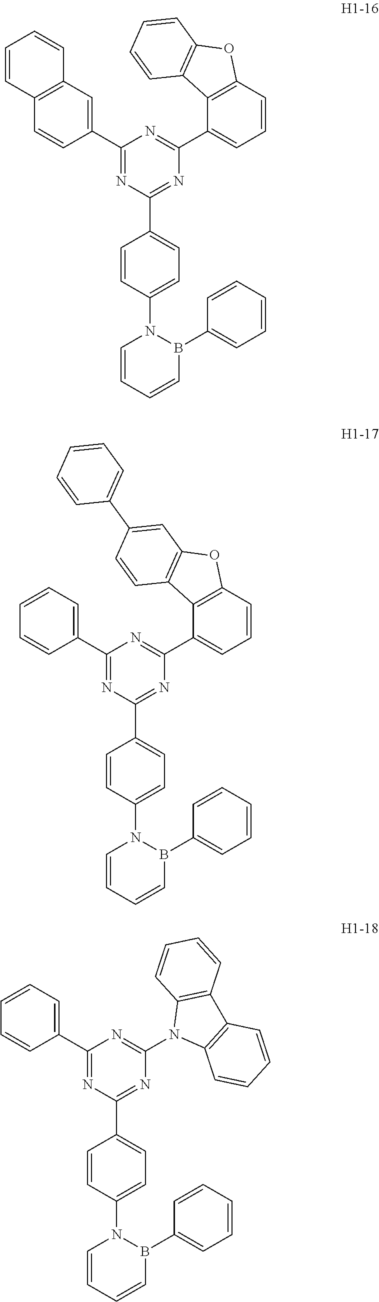 [SMILES: C1=CB(c2ccccc2)N(c2ccc(-c3nc(-c4ccc5ccccc5c4)nc(-c4cccc5oc6ccccc6c45)n3)cc2)C=C1 ; C1=CB(c2ccccc2)N(c2ccc(-c3nc(-c4ccccc4)nc(-c4cccc5oc6cc(-c7ccccc7)ccc6c45)n3)cc2)C=C1 ; C1=CB(c2ccccc2)N(c2ccc(-c3nc(-c4ccccc4)nc(-n4c5ccccc5c5ccccc54)n3)cc2)C=C1]

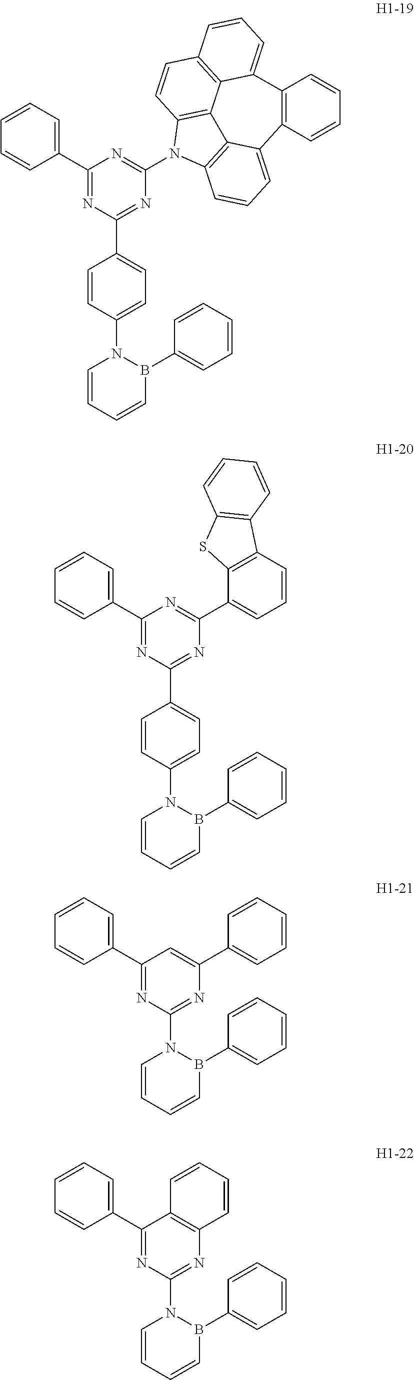 [SMILES: C1=CB(c2ccccc2)N(c2ccc(-c3nc(-c4ccccc4)nc(-n4c5cccc6c5c5c7c(cccc7ccc54)-c4ccccc4-6)n3)cc2)C=C1 ; C1=CB(c2ccccc2)N(c2ccc(-c3nc(-c4ccccc4)nc(-c4cccc5c4sc4ccccc45)n3)cc2)C=C1 ; C1=CB(c2ccccc2)N(c2nc(-c3ccccc3)cc(-c3ccccc3)n2)C=C1 ; C1=CB(c2ccccc2)N(c2nc(-c3ccccc3)c3ccccc3n2)C=C1]

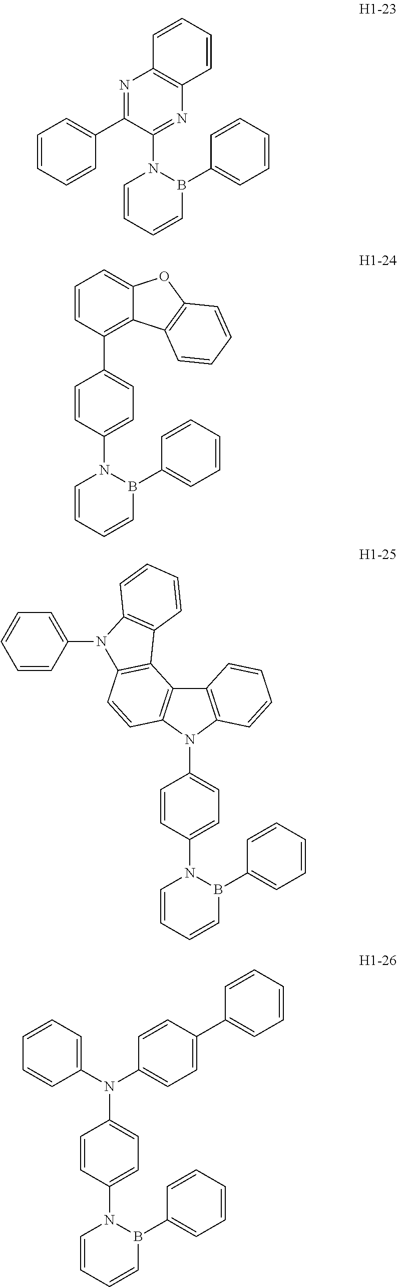

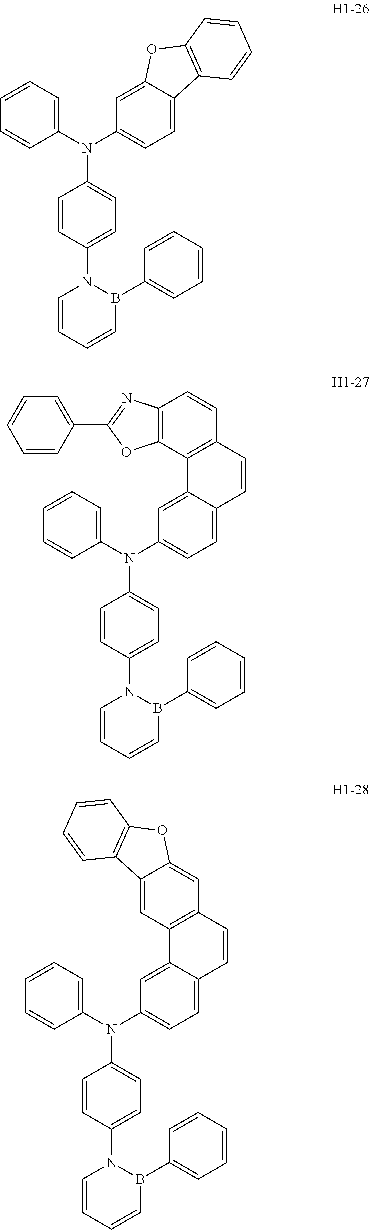

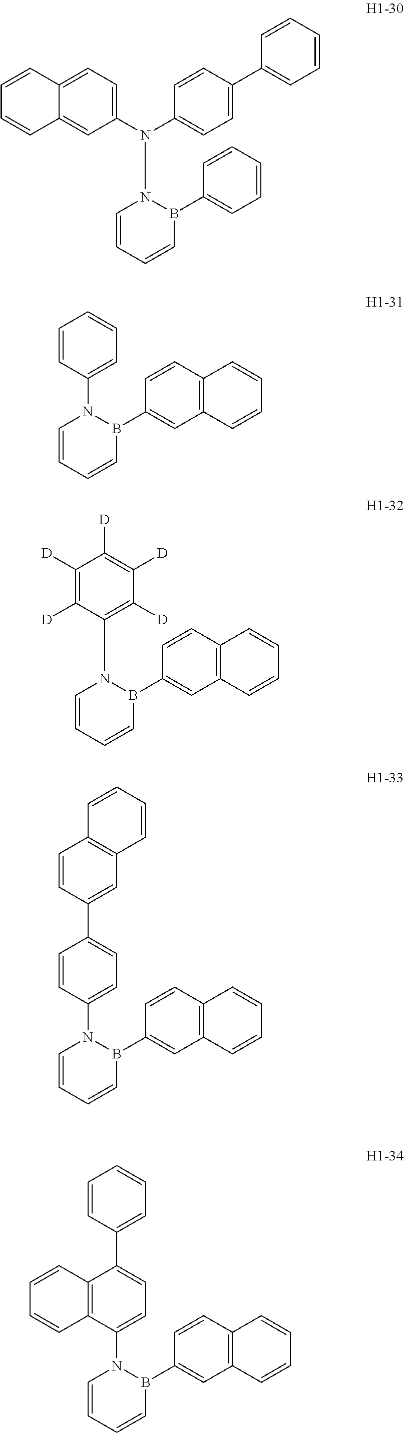

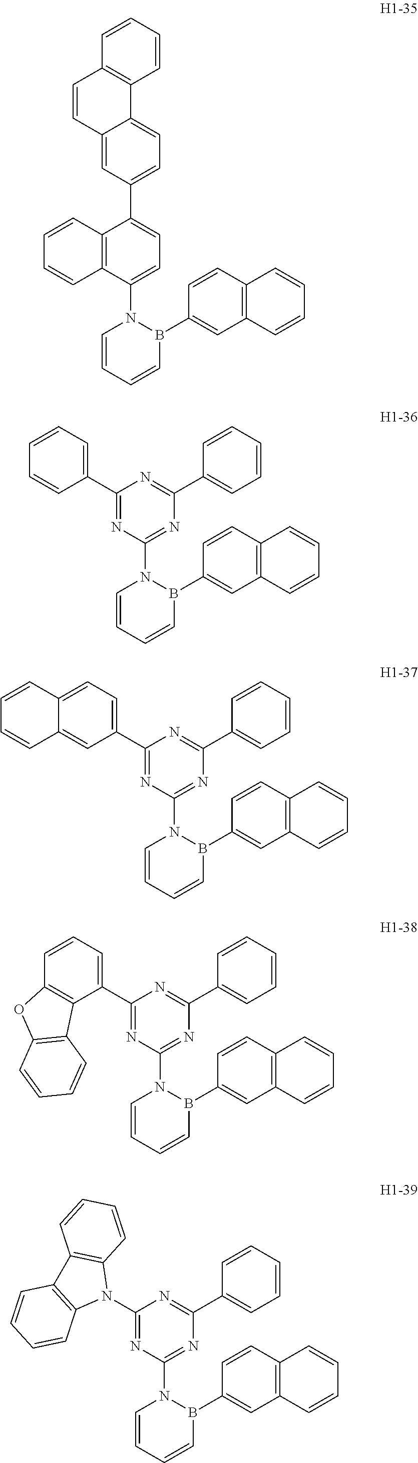 [SMILES: C1=CB(c2ccc3ccccc3c2)N(c2ccc(-c3ccc4c(ccc5ccccc54)c3)c3ccccc23)C=C1 ; C1=CB(c2ccc3ccccc3c2)N(c2nc(-c3ccccc3)nc(-c3ccccc3)n2)C=C1 ; C1=CB(c2ccc3ccccc3c2)N(c2nc(-c3ccccc3)nc(-c3ccc4ccccc4c3)n2)C=C1 ; C1=CB(c2ccc3ccccc3c2)N(c2nc(-c3ccccc3)nc(-c3cccc4oc5ccccc5c34)n2)C=C1 ; C1=CB(c2ccc3ccccc3c2)N(c2nc(-c3ccccc3)nc(-n3c4ccccc4c4ccccc43)n2)C=C1]

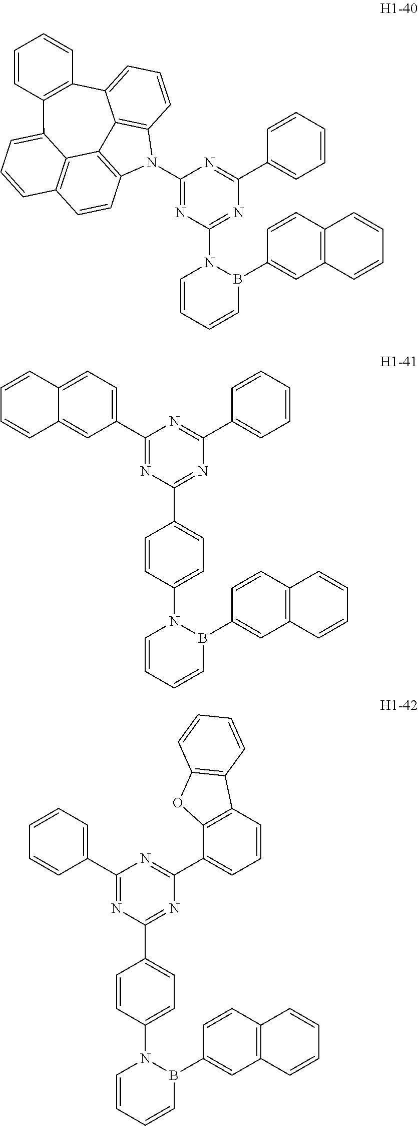

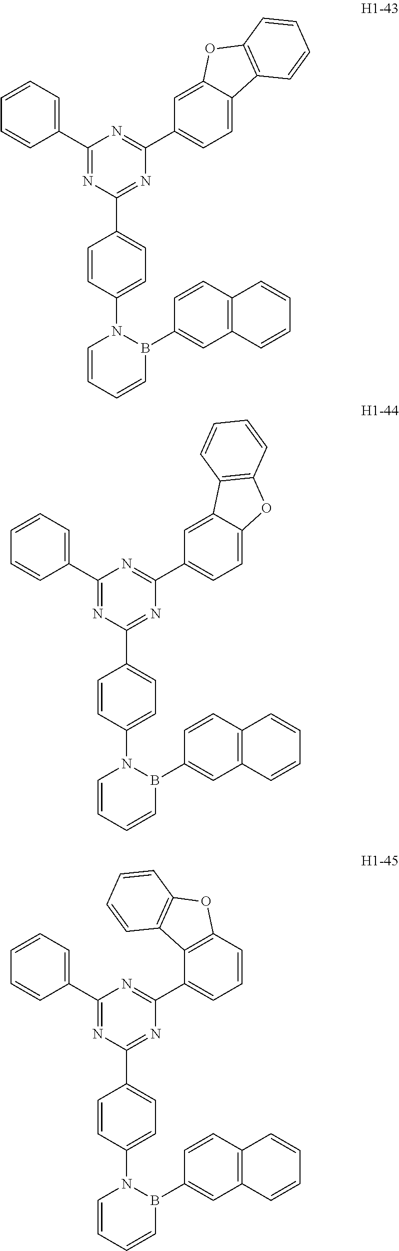

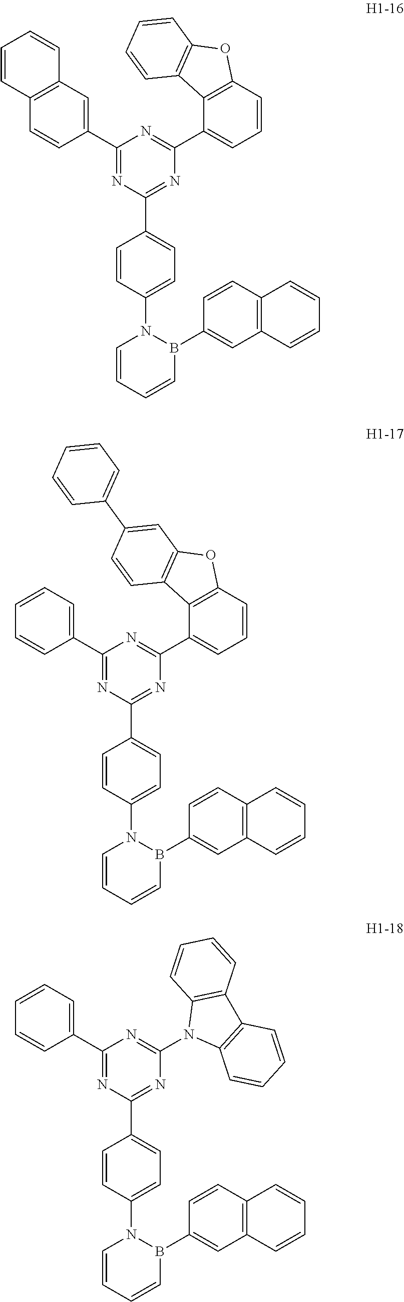 [SMILES: C1=CB(c2ccc3ccccc3c2)N(c2ccc(-c3nc(-c4ccc5ccccc5c4)nc(-c4cccc5oc6ccccc6c45)n3)cc2)C=C1 ; C1=CB(c2ccc3ccccc3c2)N(c2ccc(-c3nc(-c4ccccc4)nc(-c4cccc5oc6cc(-c7ccccc7)ccc6c45)n3)cc2)C=C1 ; C1=CB(c2ccc3ccccc3c2)N(c2ccc(-c3nc(-c4ccccc4)nc(-n4c5ccccc5c5ccccc54)n3)cc2)C=C1]

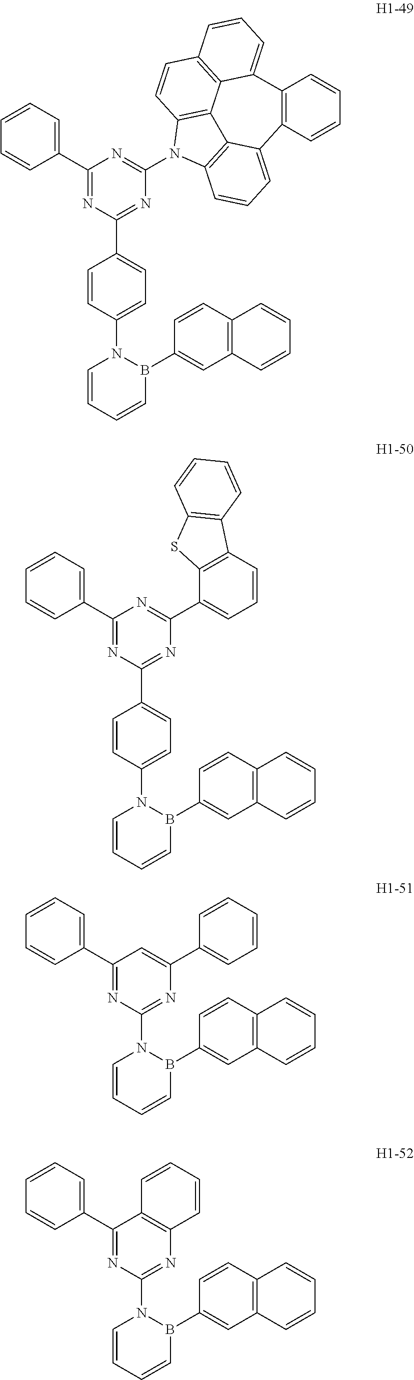 [SMILES: C1=CB(c2ccc3ccccc3c2)N(c2ccc(-c3nc(-c4ccccc4)nc(-n4c5cccc6c5c5c7c(cccc7ccc54)-c4ccccc4-6)n3)cc2)C=C1 ; C1=CB(c2ccc3ccccc3c2)N(c2ccc(-c3nc(-c4ccccc4)nc(-c4cccc5c4sc4ccccc45)n3)cc2)C=C1 ; C1=CB(c2ccc3ccccc3c2)N(c2nc(-c3ccccc3)cc(-c3ccccc3)n2)C=C1 ; C1=CB(c2ccc3ccccc3c2)N(c2nc(-c3ccccc3)c3ccccc3n2)C=C1]

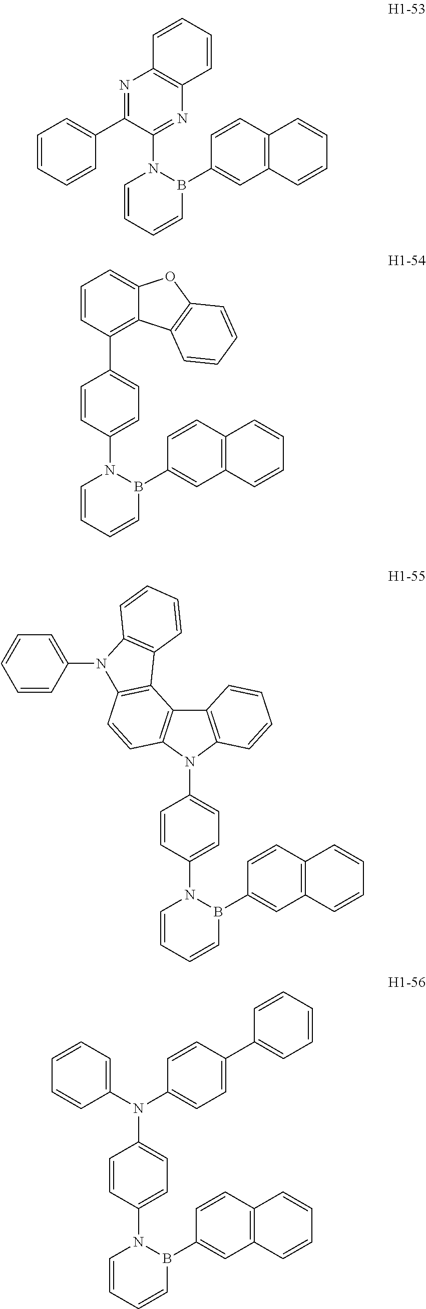

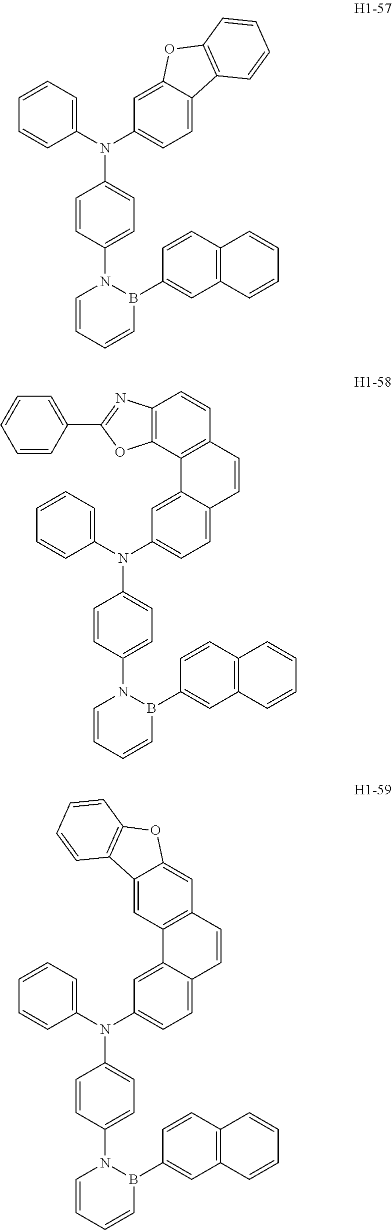

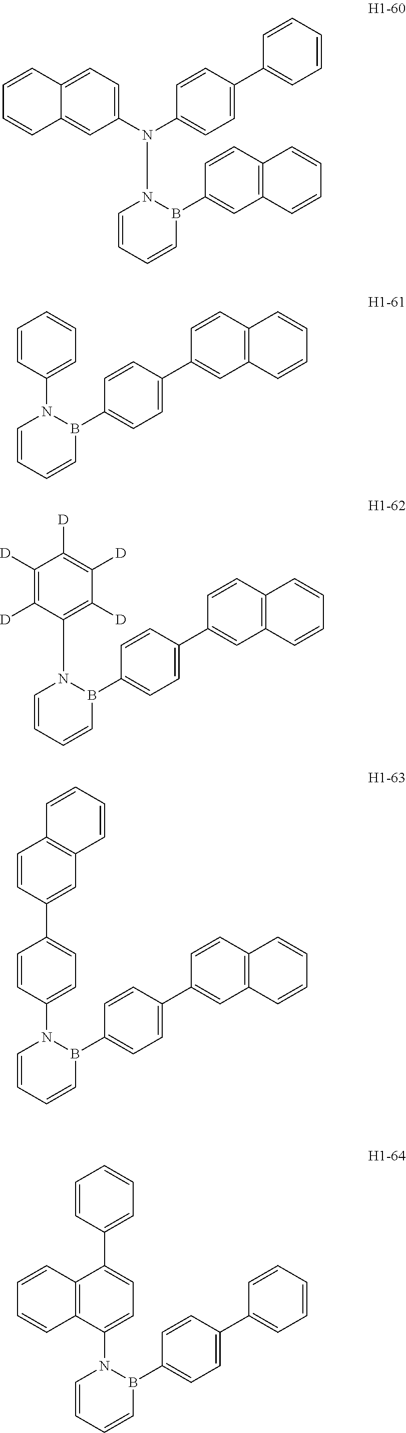

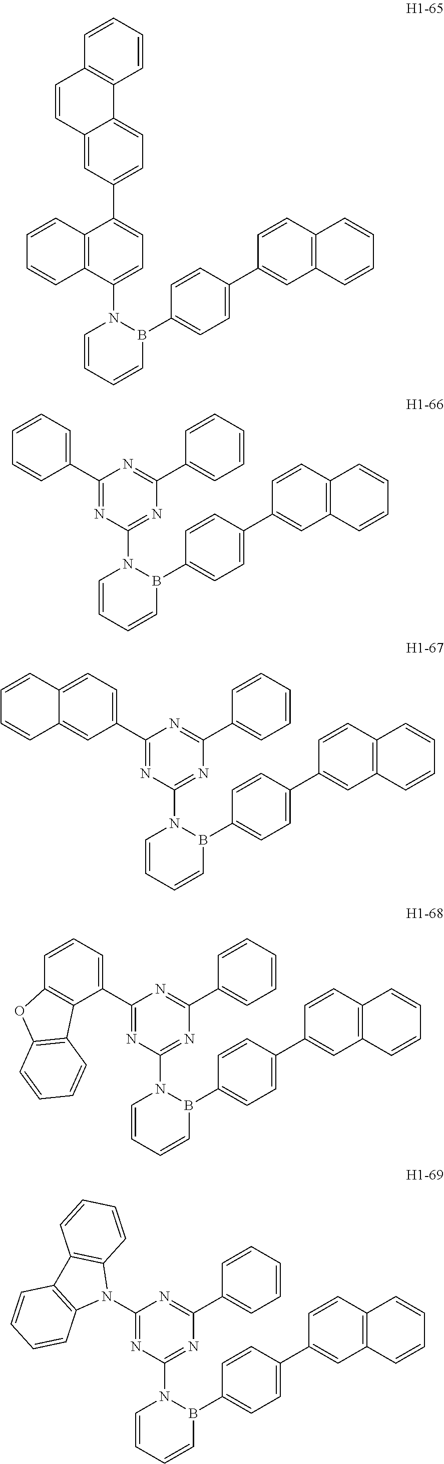 [SMILES: C1=CB(c2ccc(-c3ccc4ccccc4c3)cc2)N(c2ccc(-c3ccc4c(ccc5ccccc54)c3)c3ccccc23)C=C1 ; C1=CB(c2ccc(-c3ccc4ccccc4c3)cc2)N(c2nc(-c3ccccc3)nc(-c3ccccc3)n2)C=C1 ; C1=CB(c2ccc(-c3ccc4ccccc4c3)cc2)N(c2nc(-c3ccccc3)nc(-c3ccc4ccccc4c3)n2)C=C1 ; C1=CB(c2ccc(-c3ccc4ccccc4c3)cc2)N(c2nc(-c3ccccc3)nc(-c3cccc4oc5ccccc5c34)n2)C=C1 ; C1=CB(c2ccc(-c3ccc4ccccc4c3)cc2)N(c2nc(-c3ccccc3)nc(-n3c4ccccc4c4ccccc43)n2)C=C1]

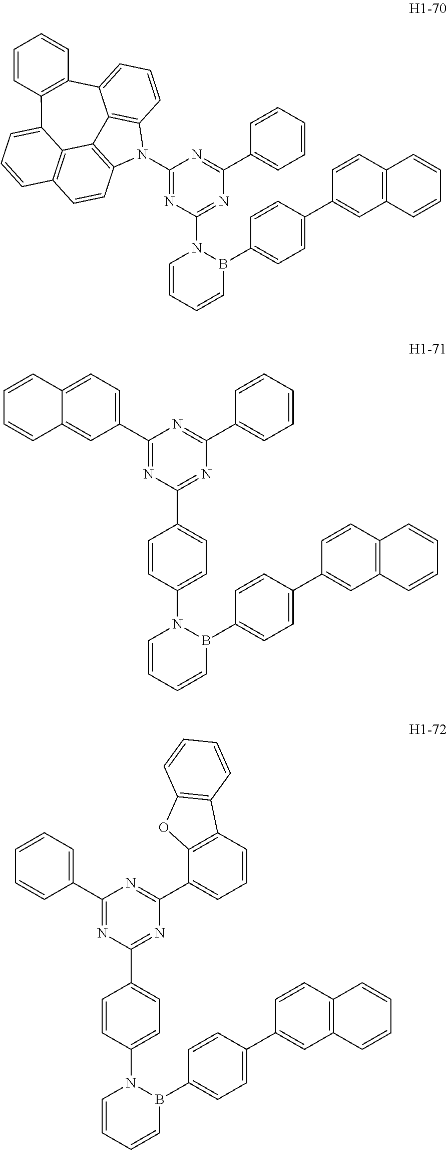 [SMILES: C1=CB(c2ccc(-c3ccc4ccccc4c3)cc2)N(c2nc(-c3ccccc3)nc(-n3c4cccc5c4c4c6c(cccc6ccc43)-c3ccccc3-5)n2)C=C1 ; C1=CB(c2ccc(-c3ccc4ccccc4c3)cc2)N(c2ccc(-c3nc(-c4ccccc4)nc(-c4ccc5ccccc5c4)n3)cc2)C=C1 ; C1=CB(c2ccc(-c3ccc4ccccc4c3)cc2)N(c2ccc(-c3nc(-c4ccccc4)nc(-c4cccc5c4oc4ccccc45)n3)cc2)C=C1]

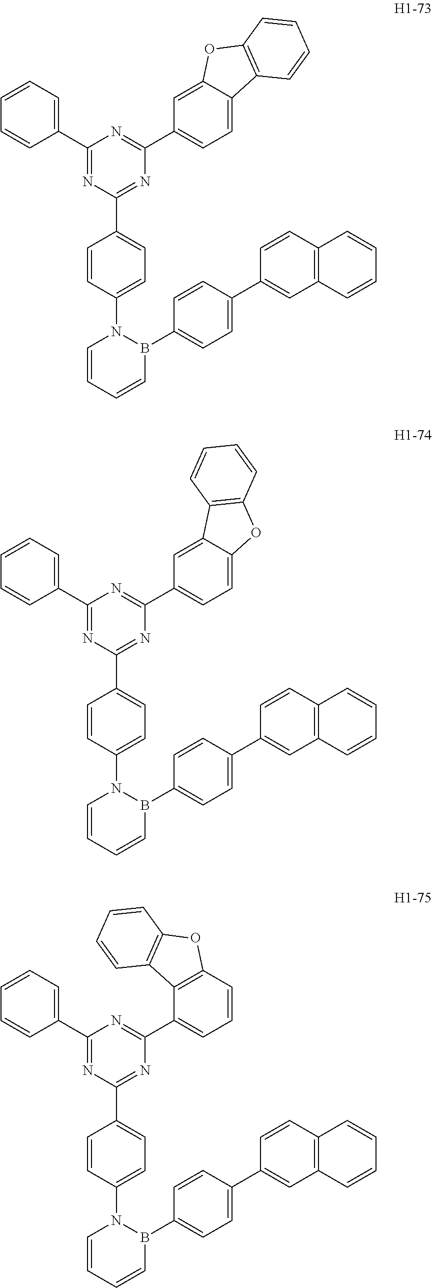 [SMILES: C1=CB(c2ccc(-c3ccc4ccccc4c3)cc2)N(c2ccc(-c3nc(-c4ccccc4)nc(-c4ccc5c(c4)oc4ccccc45)n3)cc2)C=C1 ; C1=CB(c2ccc(-c3ccc4ccccc4c3)cc2)N(c2ccc(-c3nc(-c4ccccc4)nc(-c4ccc5oc6ccccc6c5c4)n3)cc2)C=C1 ; C1=CB(c2ccc(-c3ccc4ccccc4c3)cc2)N(c2ccc(-c3nc(-c4ccccc4)nc(-c4cccc5oc6ccccc6c45)n3)cc2)C=C1]

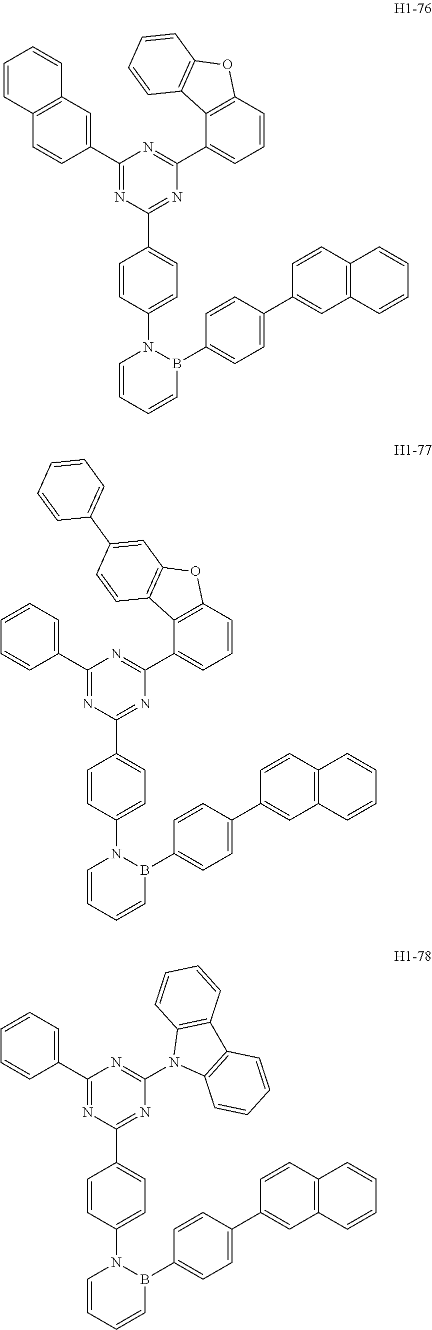 [SMILES: C1=CB(c2ccc(-c3ccc4ccccc4c3)cc2)N(c2ccc(-c3nc(-c4ccc5ccccc5c4)nc(-c4cccc5oc6ccccc6c45)n3)cc2)C=C1 ; C1=CB(c2ccc(-c3ccc4ccccc4c3)cc2)N(c2ccc(-c3nc(-c4ccccc4)nc(-c4cccc5oc6cc(-c7ccccc7)ccc6c45)n3)cc2)C=C1 ; C1=CB(c2ccc(-c3ccc4ccccc4c3)cc2)N(c2ccc(-c3nc(-c4ccccc4)nc(-n4c5ccccc5c5ccccc54)n3)cc2)C=C1]

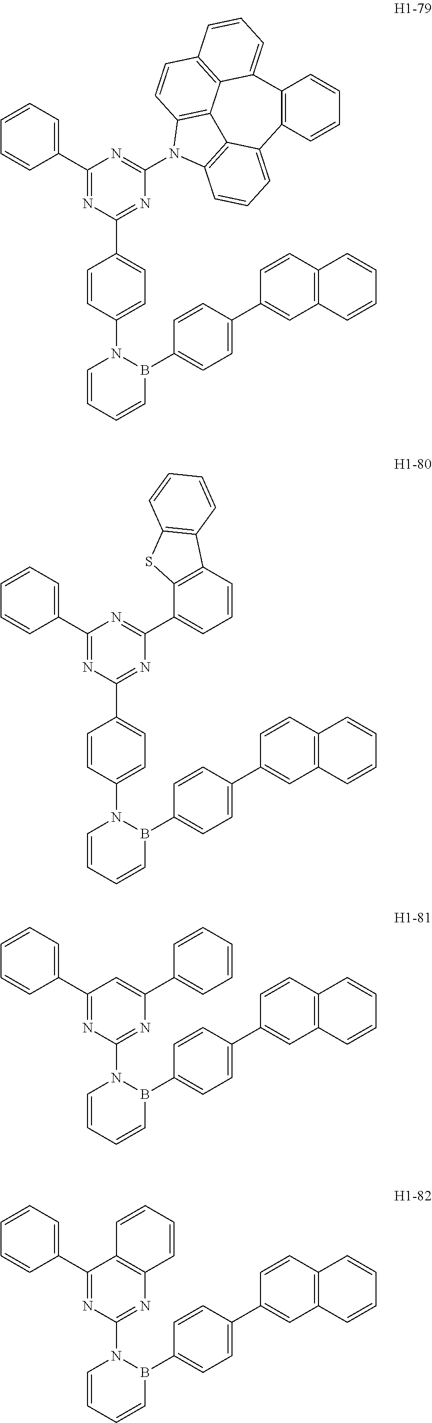 [SMILES: C1=CB(c2ccc(-c3ccc4ccccc4c3)cc2)N(c2ccc(-c3nc(-c4ccccc4)nc(-n4c5cccc6c5c5c7c(cccc7ccc54)-c4ccccc4-6)n3)cc2)C=C1 ; C1=CB(c2ccc(-c3ccc4ccccc4c3)cc2)N(c2ccc(-c3nc(-c4ccccc4)nc(-c4cccc5c4sc4ccccc45)n3)cc2)C=C1 ; C1=CB(c2ccc(-c3ccc4ccccc4c3)cc2)N(c2nc(-c3ccccc3)cc(-c3ccccc3)n2)C=C1 ; C1=CB(c2ccc(-c3ccc4ccccc4c3)cc2)N(c2nc(-c3ccccc3)c3ccccc3n2)C=C1]

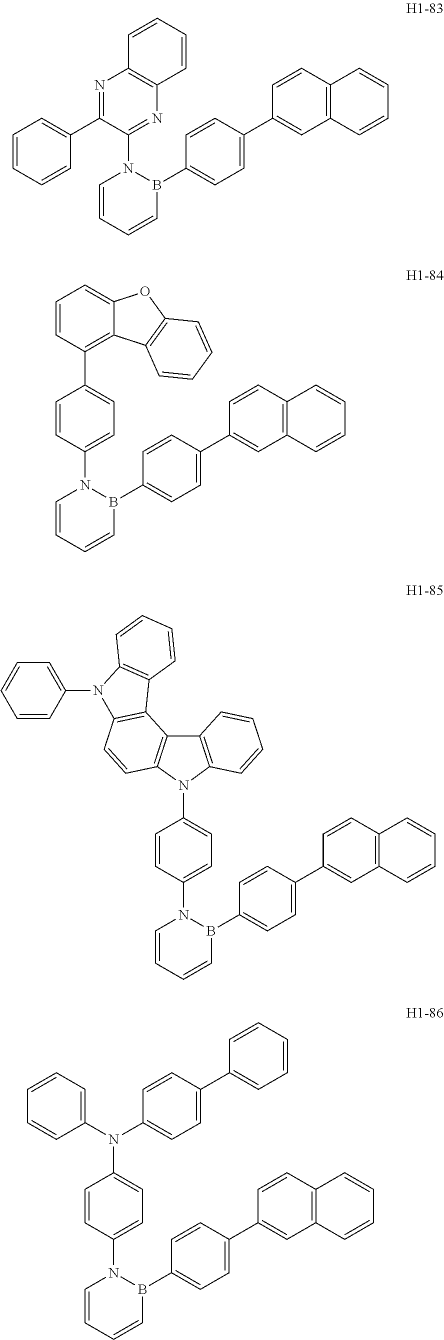 [SMILES: C1=CB(c2ccc(-c3ccc4ccccc4c3)cc2)N(c2nc3ccccc3nc2-c2ccccc2)C=C1 ; C1=CB(c2ccc(-c3ccc4ccccc4c3)cc2)N(c2ccc(-c3cccc4oc5ccccc5c34)cc2)C=C1 ; C1=CB(c2ccc(-c3ccc4ccccc4c3)cc2)N(c2ccc(-n3c4ccccc4c4c5c6ccccc6n(-c6ccccc6)c5ccc43)cc2)C=C1 ; C1=CB(c2ccc(-c3ccc4ccccc4c3)cc2)N(c2ccc(N(c3ccccc3)c3ccc(-c4ccccc4)cc3)cc2)C=C1]

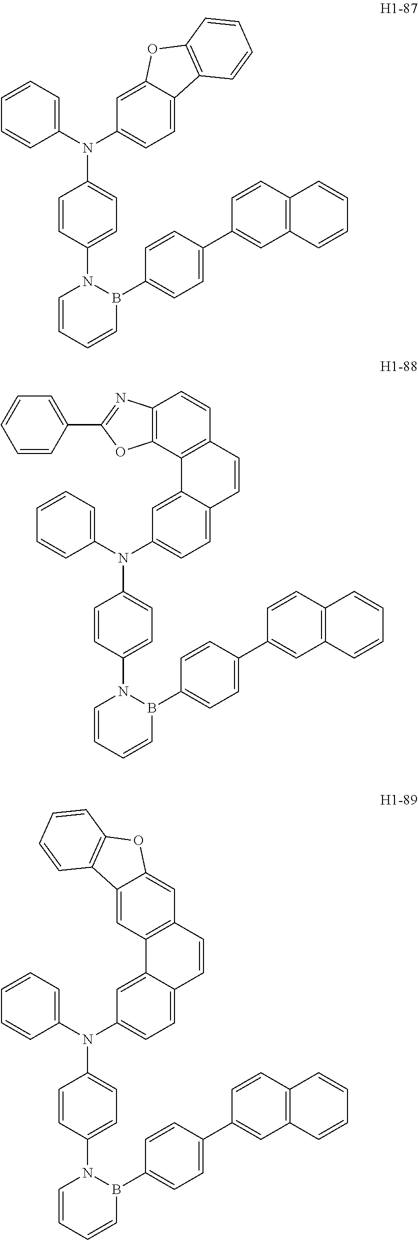 [SMILES: C1=CB(c2ccc(-c3ccc4ccccc4c3)cc2)N(c2ccc(N(c3ccccc3)c3ccc4c(c3)oc3ccccc34)cc2)C=C1 ; C1=CB(c2ccc(-c3ccc4ccccc4c3)cc2)N(c2ccc(N(c3ccccc3)c3ccc4ccc5ccc6nc(-c7ccccc7)oc6c5c4c3)cc2)C=C1 ; C1=CB(c2ccc(-c3ccc4ccccc4c3)cc2)N(c2ccc(N(c3ccccc3)c3ccc4ccc5cc6oc7ccccc7c6cc5c4c3)cc2)C=C1]

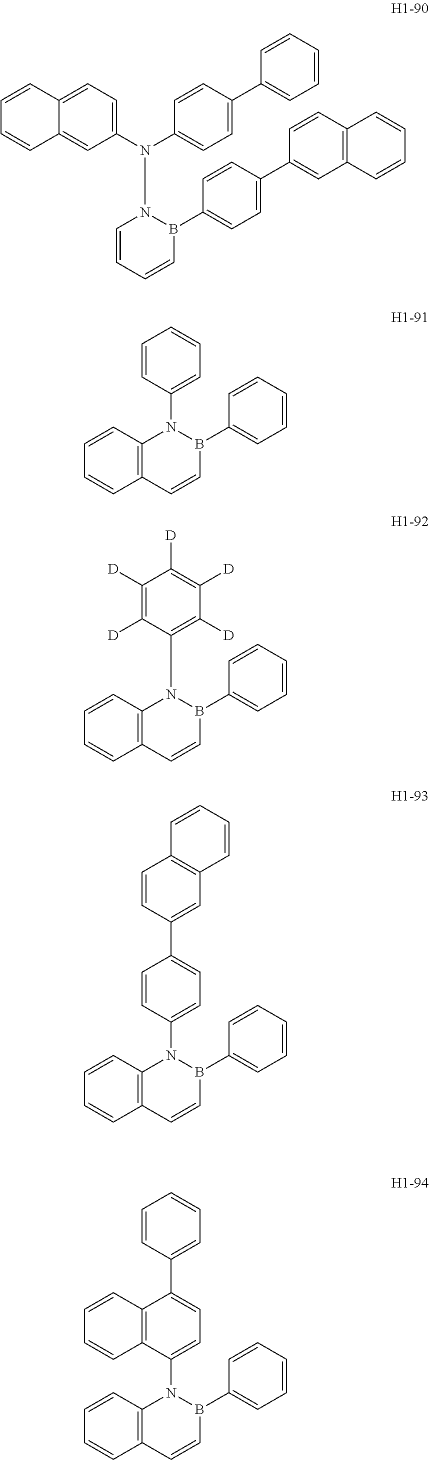

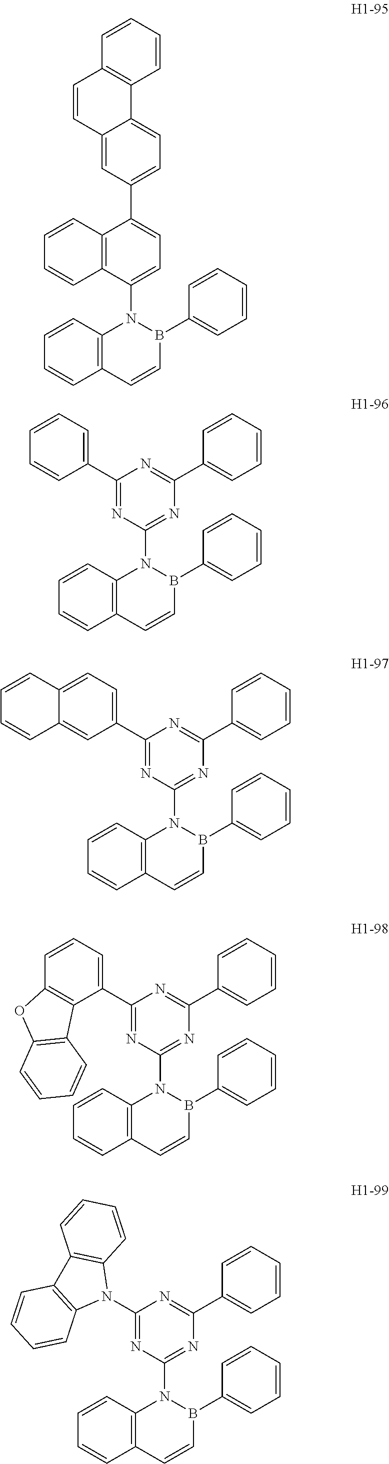

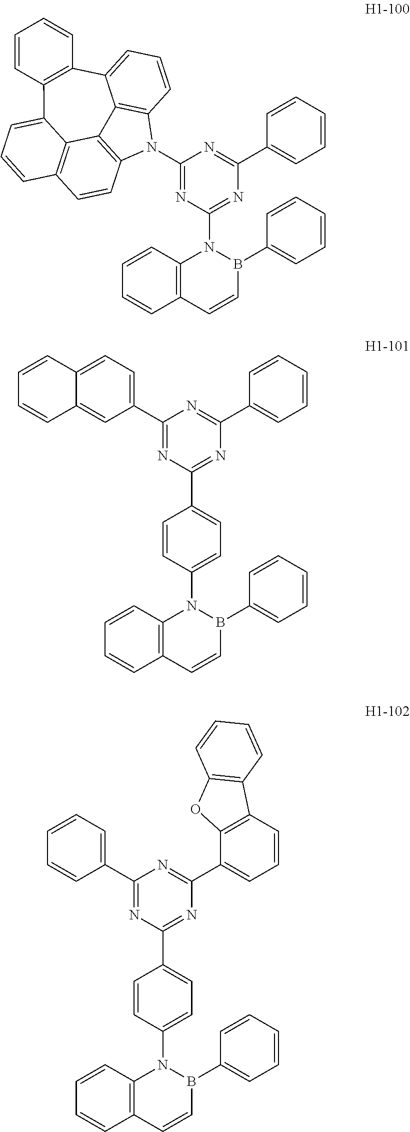 [SMILES: C1=Cc2ccccc2N(c2nc(-c3ccccc3)nc(-n3c4cccc5c4c4c6c(cccc6ccc43)-c3ccccc3-5)n2)B1c1ccccc1 ; C1=Cc2ccccc2N(c2ccc(-c3nc(-c4ccccc4)nc(-c4ccc5ccccc5c4)n3)cc2)B1c1ccccc1 ; C1=Cc2ccccc2N(c2ccc(-c3nc(-c4ccccc4)nc(-c4cccc5c4oc4ccccc45)n3)cc2)B1c1ccccc1]

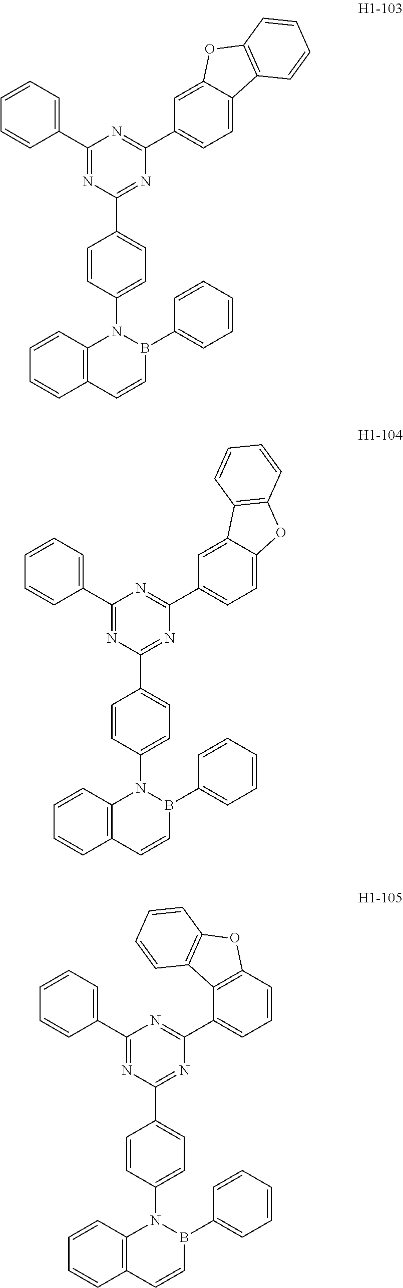 [SMILES: C1=Cc2ccccc2N(c2ccc(-c3nc(-c4ccccc4)nc(-c4ccc5c(c4)oc4ccccc45)n3)cc2)B1c1ccccc1 ; C1=Cc2ccccc2N(c2ccc(-c3nc(-c4ccccc4)nc(-c4ccc5oc6ccccc6c5c4)n3)cc2)B1c1ccccc1 ; C1=Cc2ccccc2N(c2ccc(-c3nc(-c4ccccc4)nc(-c4cccc5oc6ccccc6c45)n3)cc2)B1c1ccccc1]

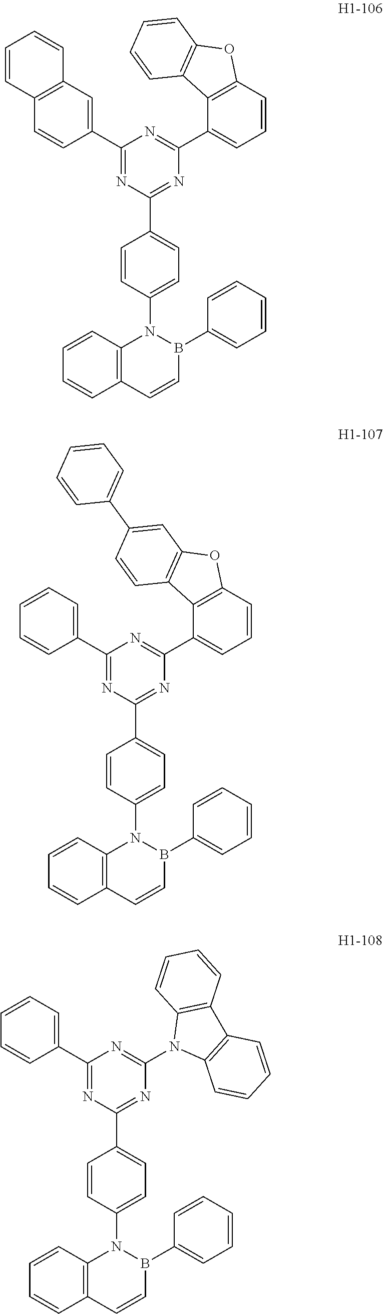 [SMILES: C1=Cc2ccccc2N(c2ccc(-c3nc(-c4ccc5ccccc5c4)nc(-c4cccc5oc6ccccc6c45)n3)cc2)B1c1ccccc1 ; C1=Cc2ccccc2N(c2ccc(-c3nc(-c4ccccc4)nc(-c4cccc5oc6cc(-c7ccccc7)ccc6c45)n3)cc2)B1c1ccccc1 ; C1=Cc2ccccc2N(c2ccc(-c3nc(-c4ccccc4)nc(-n4c5ccccc5c5ccccc54)n3)cc2)B1c1ccccc1]

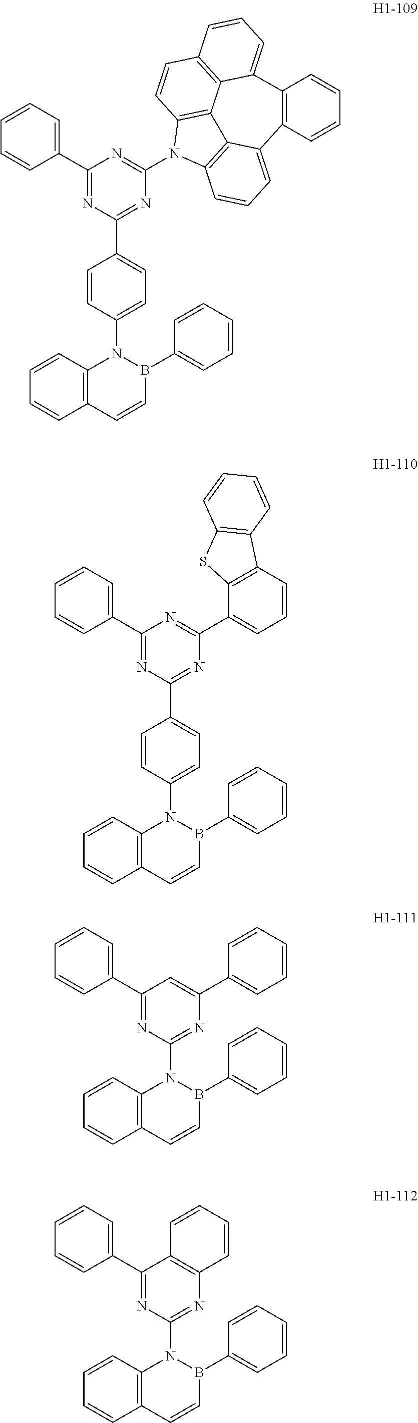 [SMILES: C1=Cc2ccccc2N(c2ccc(-c3nc(-c4ccccc4)nc(-n4c5cccc6c5c5c7c(cccc7ccc54)-c4ccccc4-6)n3)cc2)B1c1ccccc1 ; C1=Cc2ccccc2N(c2ccc(-c3nc(-c4ccccc4)nc(-c4cccc5c4sc4ccccc45)n3)cc2)B1c1ccccc1 ; C1=Cc2ccccc2N(c2nc(-c3ccccc3)cc(-c3ccccc3)n2)B1c1ccccc1 ; C1=Cc2ccccc2N(c2nc(-c3ccccc3)c3ccccc3n2)B1c1ccccc1]

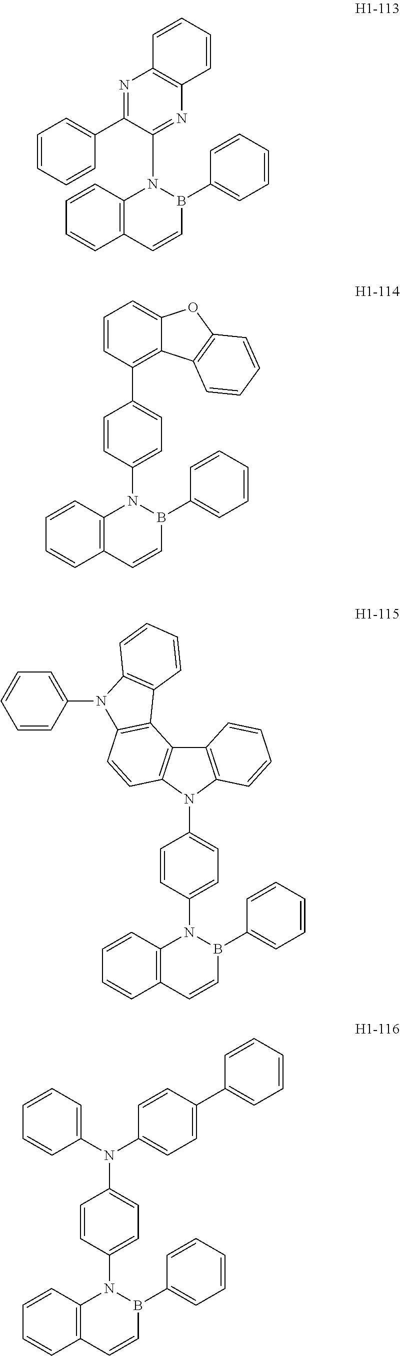 [SMILES: C1=Cc2ccccc2N(c2nc3ccccc3nc2-c2ccccc2)B1c1ccccc1 ; C1=Cc2ccccc2N(c2ccc(-c3cccc4oc5ccccc5c34)cc2)B1c1ccccc1 ; C1=Cc2ccccc2N(c2ccc(-n3c4ccccc4c4c5c6ccccc6n(-c6ccccc6)c5ccc43)cc2)B1c1ccccc1 ; C1=Cc2ccccc2N(c2ccc(N(c3ccccc3)c3ccc(-c4ccccc4)cc3)cc2)B1c1ccccc1]

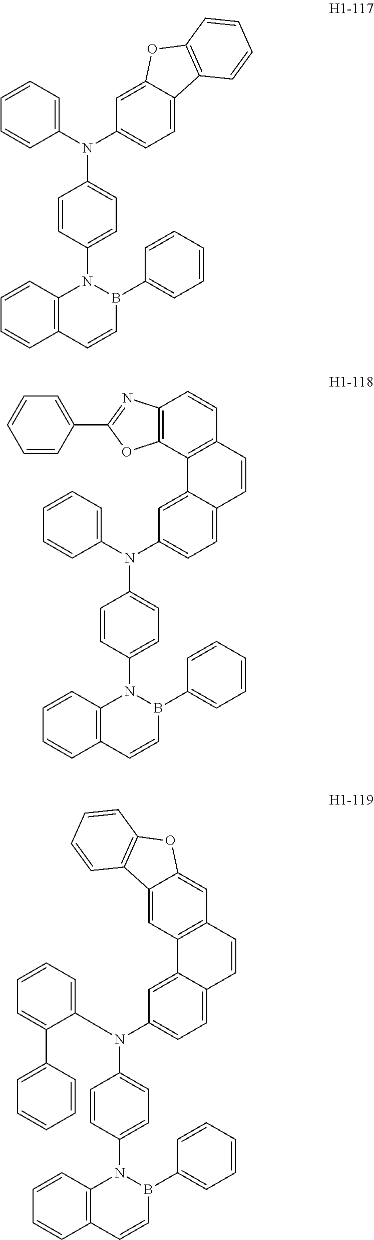 [SMILES: C1=Cc2ccccc2N(c2ccc(N(c3ccccc3)c3ccc4c(c3)oc3ccccc34)cc2)B1c1ccccc1 ; C1=Cc2ccccc2N(c2ccc(N(c3ccccc3)c3ccc4ccc5ccc6nc(-c7ccccc7)oc6c5c4c3)cc2)B1c1ccccc1 ; C1=Cc2ccccc2N(c2ccc(N(c3ccc4ccc5cc6oc7ccccc7c6cc5c4c3)c3ccccc3-c3ccccc3)cc2)B1c1ccccc1]

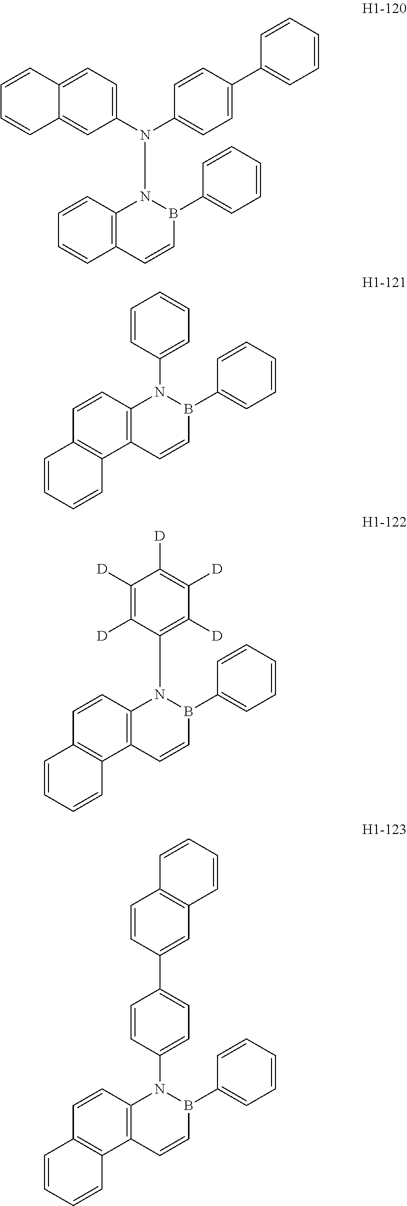

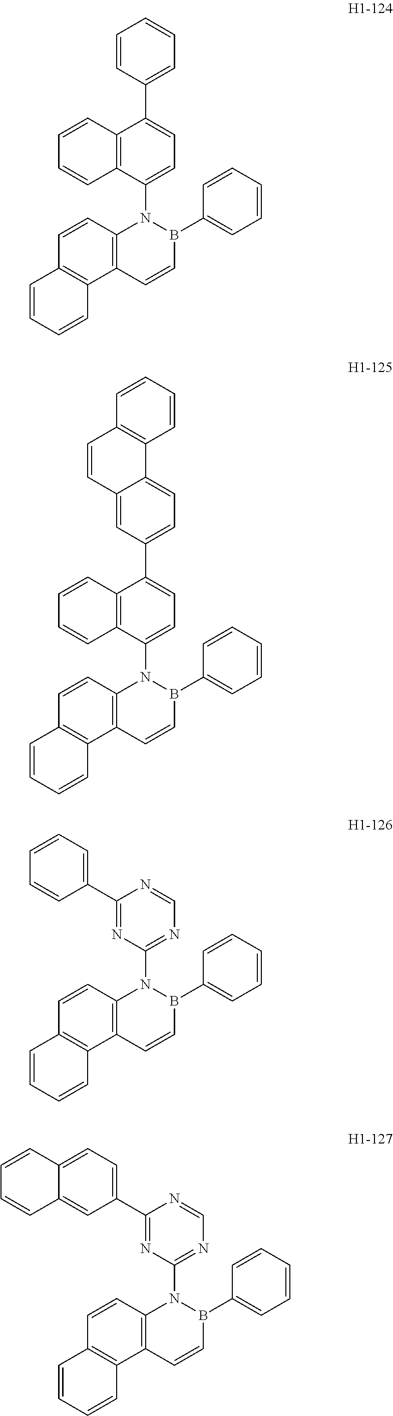

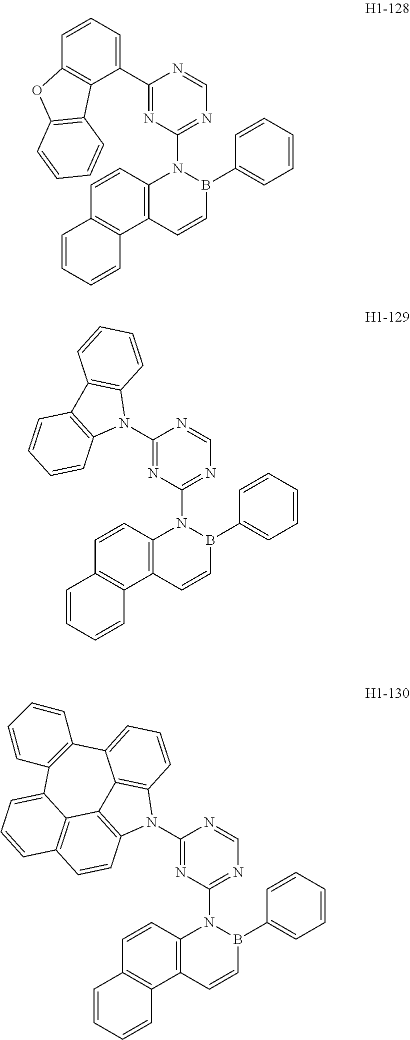

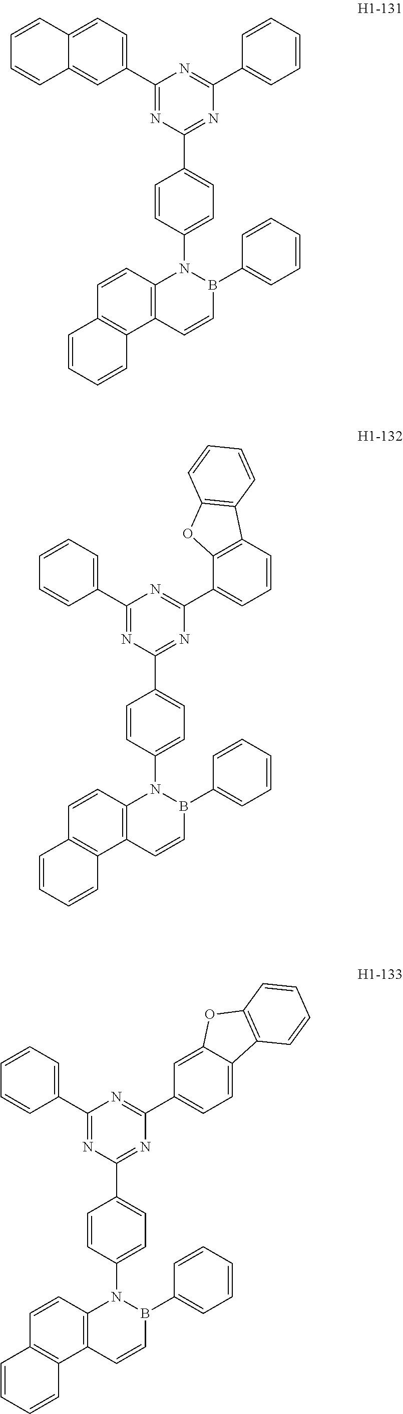 [SMILES: C1=Cc2c(ccc3ccccc23)N(c2ccc(-c3nc(-c4ccccc4)nc(-c4ccc5ccccc5c4)n3)cc2)B1c1ccccc1 ; C1=Cc2c(ccc3ccccc23)N(c2ccc(-c3nc(-c4ccccc4)nc(-c4cccc5c4oc4ccccc45)n3)cc2)B1c1ccccc1 ; C1=Cc2c(ccc3ccccc23)N(c2ccc(-c3nc(-c4ccccc4)nc(-c4ccc5c(c4)oc4ccccc45)n3)cc2)B1c1ccccc1]

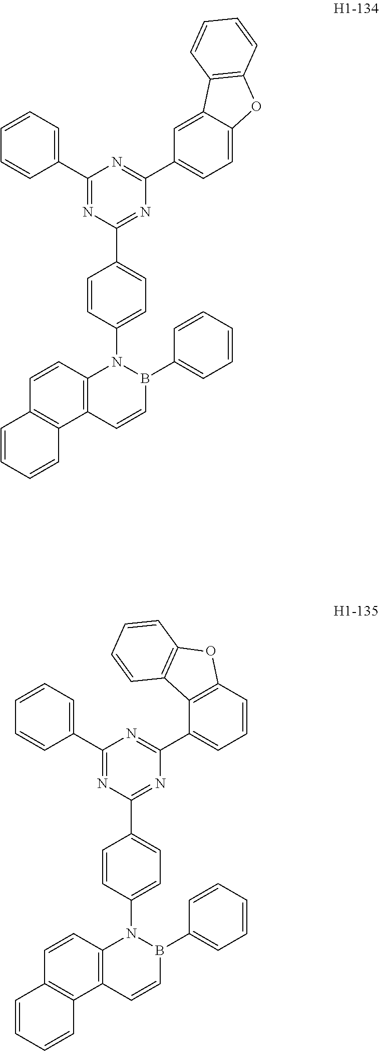 [SMILES: C1=Cc2c(ccc3ccccc23)N(c2ccc(-c3nc(-c4ccccc4)nc(-c4ccc5oc6ccccc6c5c4)n3)cc2)B1c1ccccc1 ; C1=Cc2c(ccc3ccccc23)N(c2ccc(-c3nc(-c4ccccc4)nc(-c4cccc5oc6ccccc6c45)n3)cc2)B1c1ccccc1]

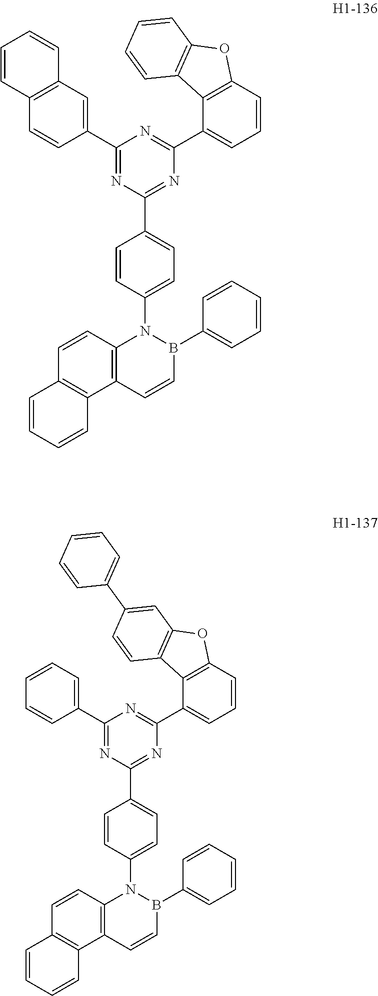 [SMILES: C1=Cc2c(ccc3ccccc23)N(c2ccc(-c3nc(-c4ccc5ccccc5c4)nc(-c4cccc5oc6ccccc6c45)n3)cc2)B1c1ccccc1 ; C1=Cc2c(ccc3ccccc23)N(c2ccc(-c3nc(-c4ccccc4)nc(-c4cccc5oc6cc(-c7ccccc7)ccc6c45)n3)cc2)B1c1ccccc1]

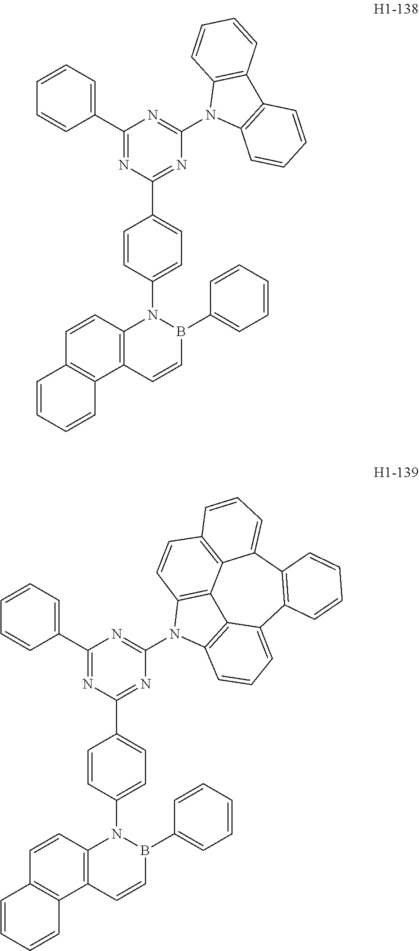 [SMILES: C1=Cc2c(ccc3ccccc23)N(c2ccc(-c3nc(-c4ccccc4)nc(-n4c5ccccc5c5ccccc54)n3)cc2)B1c1ccccc1 ; C1=Cc2c(ccc3ccccc23)N(c2ccc(-c3nc(-c4ccccc4)nc(-n4c5cccc6c5c5c7c(cccc7ccc54)-c4ccccc4-6)n3)cc2)B1c1ccccc1]

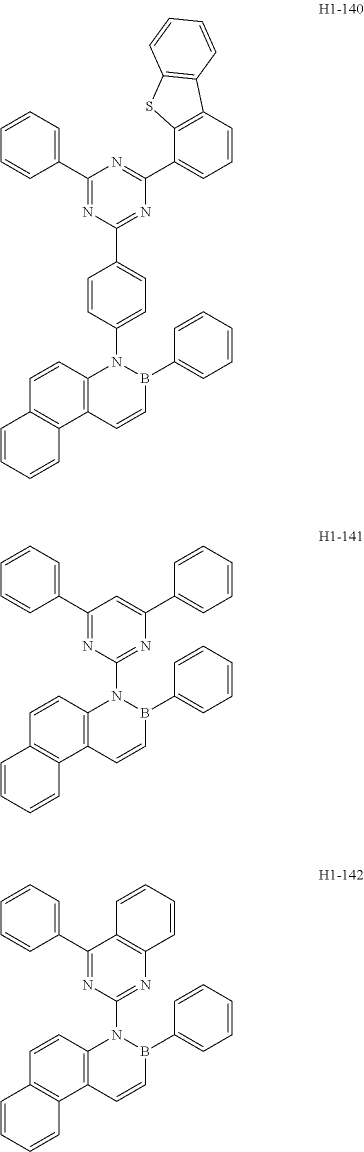 [SMILES: C1=Cc2c(ccc3ccccc23)N(c2ccc(-c3nc(-c4ccccc4)nc(-c4cccc5c4sc4ccccc45)n3)cc2)B1c1ccccc1 ; C1=Cc2c(ccc3ccccc23)N(c2nc(-c3ccccc3)cc(-c3ccccc3)n2)B1c1ccccc1 ; C1=Cc2c(ccc3ccccc23)N(c2nc(-c3ccccc3)c3ccccc3n2)B1c1ccccc1]

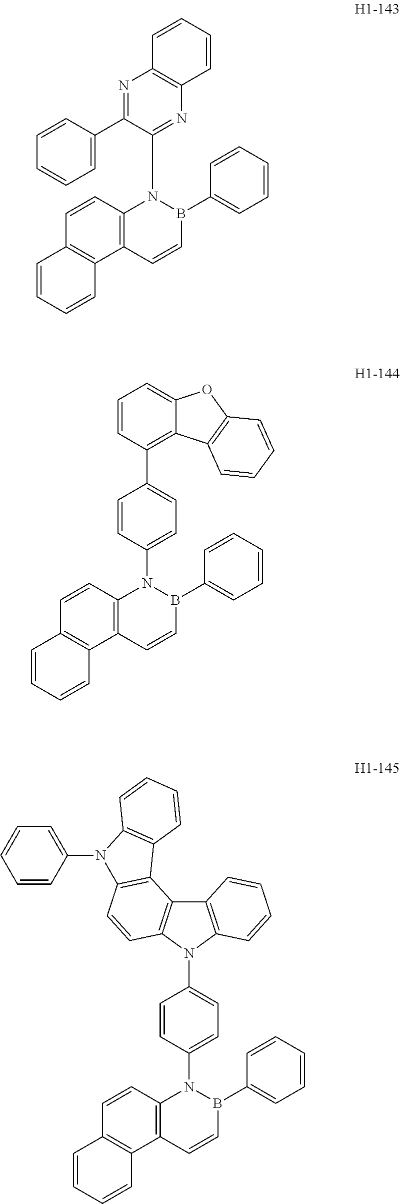 [SMILES: C1=Cc2c(ccc3ccccc23)N(c2nc3ccccc3nc2-c2ccccc2)B1c1ccccc1 ; C1=Cc2c(ccc3ccccc23)N(c2ccc(-c3cccc4oc5ccccc5c34)cc2)B1c1ccccc1 ; C1=Cc2c(ccc3ccccc23)N(c2ccc(-n3c4ccccc4c4c5c6ccccc6n(-c6ccccc6)c5ccc43)cc2)B1c1ccccc1]

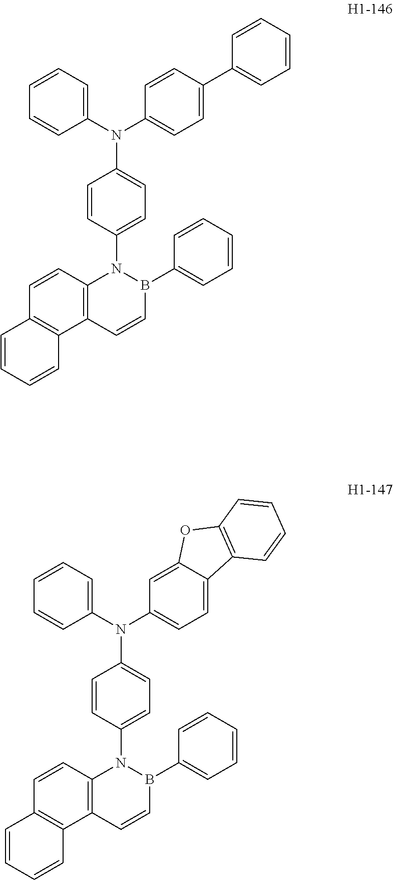 [SMILES: C1=Cc2c(ccc3ccccc23)N(c2ccc(N(c3ccccc3)c3ccc(-c4ccccc4)cc3)cc2)B1c1ccccc1 ; C1=Cc2c(ccc3ccccc23)N(c2ccc(N(c3ccccc3)c3ccc4c(c3)oc3ccccc34)cc2)B1c1ccccc1]

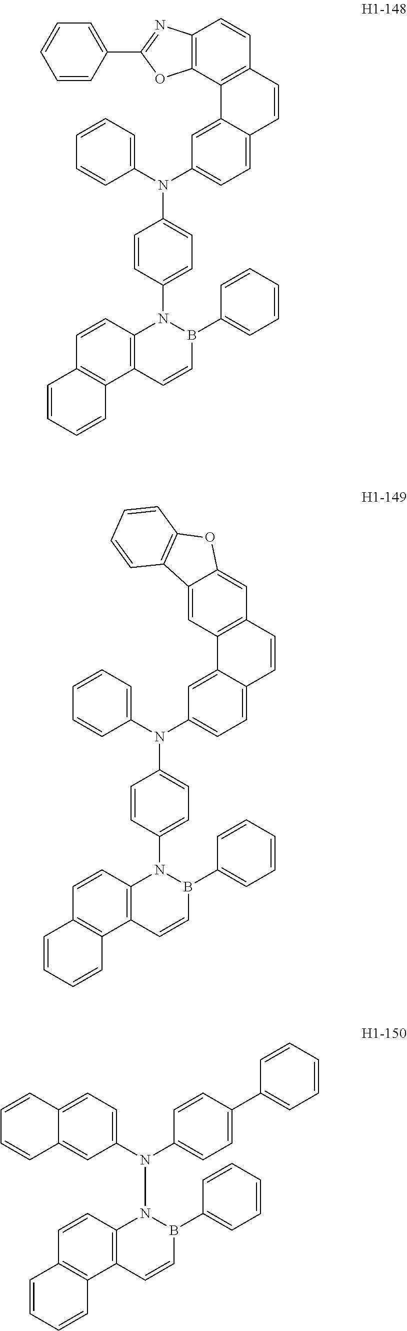 [SMILES: C1=Cc2c(ccc3ccccc23)N(c2ccc(N(c3ccccc3)c3ccc4ccc5ccc6nc(-c7ccccc7)oc6c5c4c3)cc2)B1c1ccccc1 ; C1=Cc2c(ccc3ccccc23)N(c2ccc(N(c3ccccc3)c3ccc4ccc5cc6oc7ccccc7c6cc5c4c3)cc2)B1c1ccccc1 ; C1=Cc2c(ccc3ccccc23)N(N(c2ccc(-c3ccccc3)cc2)c2ccc3ccccc3c2)B1c1ccccc1]

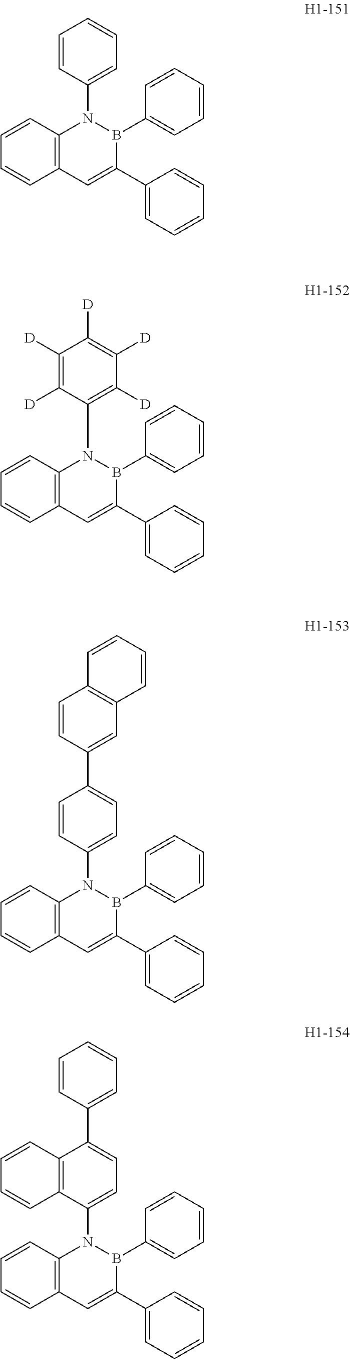 [SMILES: C1=C(c2ccccc2)B(c2ccccc2)N(c2ccccc2)c2ccccc21 ; [2H]c1c([2H])c([2H])c(N2B(c3ccccc3)C(c3ccccc3)=Cc3ccccc32)c([2H])c1[2H] ; C1=C(c2ccccc2)B(c2ccccc2)N(c2ccc(-c3ccc4ccccc4c3)cc2)c2ccccc21 ; C1=C(c2ccccc2)B(c2ccccc2)N(c2ccc(-c3ccccc3)c3ccccc23)c2ccccc21]

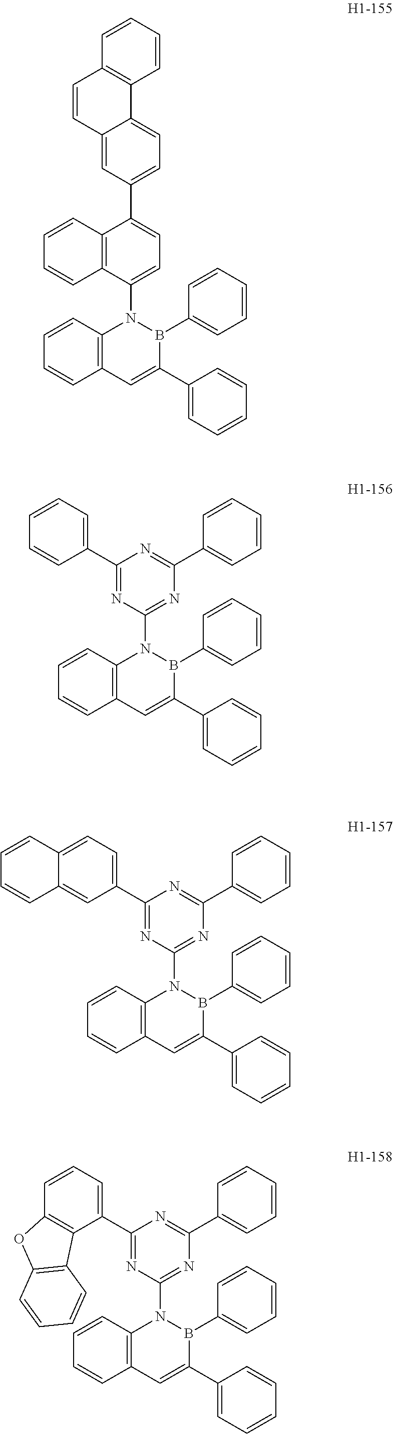 [SMILES: C1=C(c2ccccc2)B(c2ccccc2)N(c2ccc(-c3ccc4c(ccc5ccccc54)c3)c3ccccc23)c2ccccc21 ; C1=C(c2ccccc2)B(c2ccccc2)N(c2nc(-c3ccccc3)nc(-c3ccccc3)n2)c2ccccc21 ; C1=C(c2ccccc2)B(c2ccccc2)N(c2nc(-c3ccccc3)nc(-c3ccc4ccccc4c3)n2)c2ccccc21 ; C1=C(c2ccccc2)B(c2ccccc2)N(c2nc(-c3ccccc3)nc(-c3cccc4oc5ccccc5c34)n2)c2ccccc21]

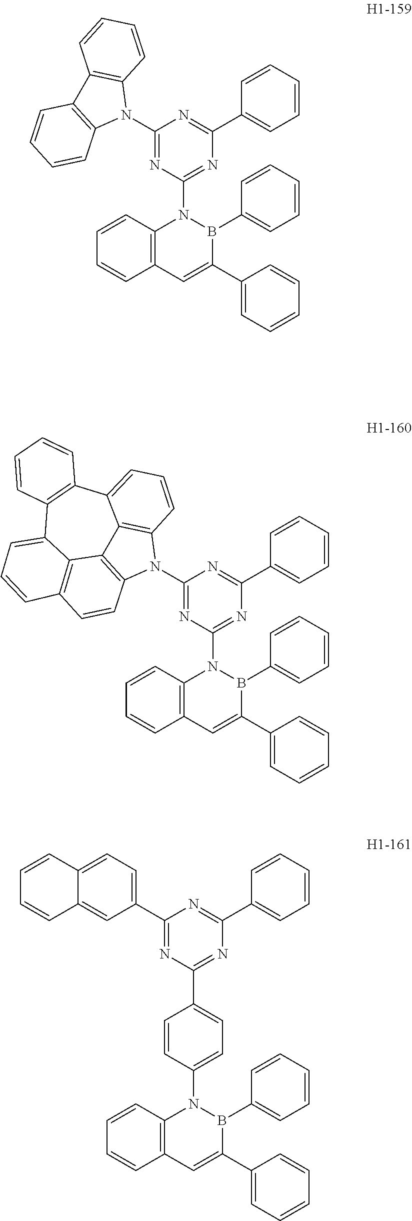 [SMILES: C1=C(c2ccccc2)B(c2ccccc2)N(c2nc(-c3ccccc3)nc(-n3c4ccccc4c4ccccc43)n2)c2ccccc21 ; C1=C(c2ccccc2)B(c2ccccc2)N(c2nc(-c3ccccc3)nc(-n3c4cccc5c4c4c6c(cccc6ccc43)-c3ccccc3-5)n2)c2ccccc21 ; C1=C(c2ccccc2)B(c2ccccc2)N(c2ccc(-c3nc(-c4ccccc4)nc(-c4ccc5ccccc5c4)n3)cc2)c2ccccc21]

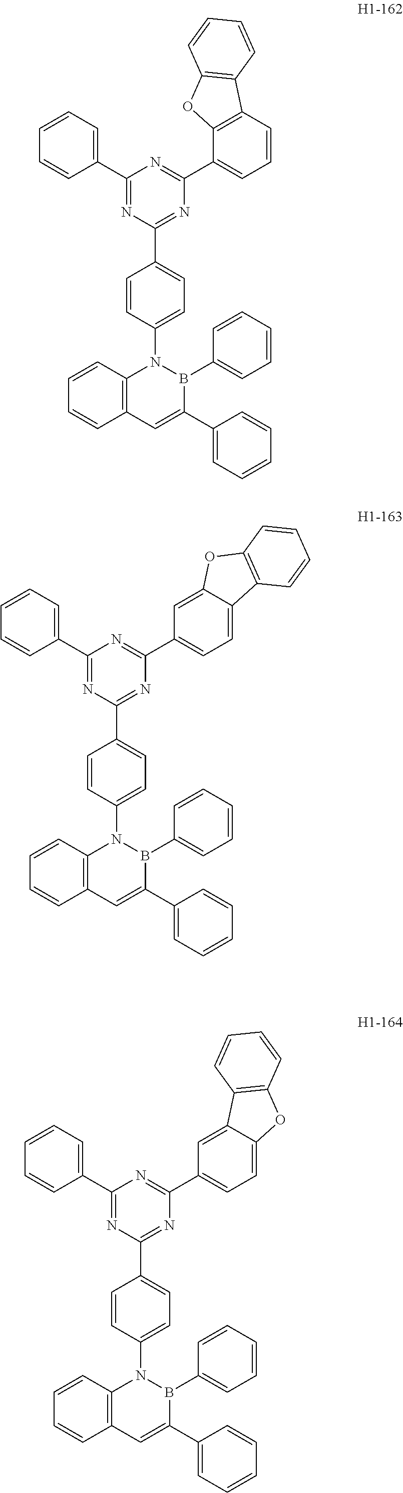 [SMILES: C1=C(c2ccccc2)B(c2ccccc2)N(c2ccc(-c3nc(-c4ccccc4)nc(-c4cccc5c4oc4ccccc45)n3)cc2)c2ccccc21 ; C1=C(c2ccccc2)B(c2ccccc2)N(c2ccc(-c3nc(-c4ccccc4)nc(-c4ccc5c(c4)oc4ccccc45)n3)cc2)c2ccccc21 ; C1=C(c2ccccc2)B(c2ccccc2)N(c2ccc(-c3nc(-c4ccccc4)nc(-c4ccc5oc6ccccc6c5c4)n3)cc2)c2ccccc21]

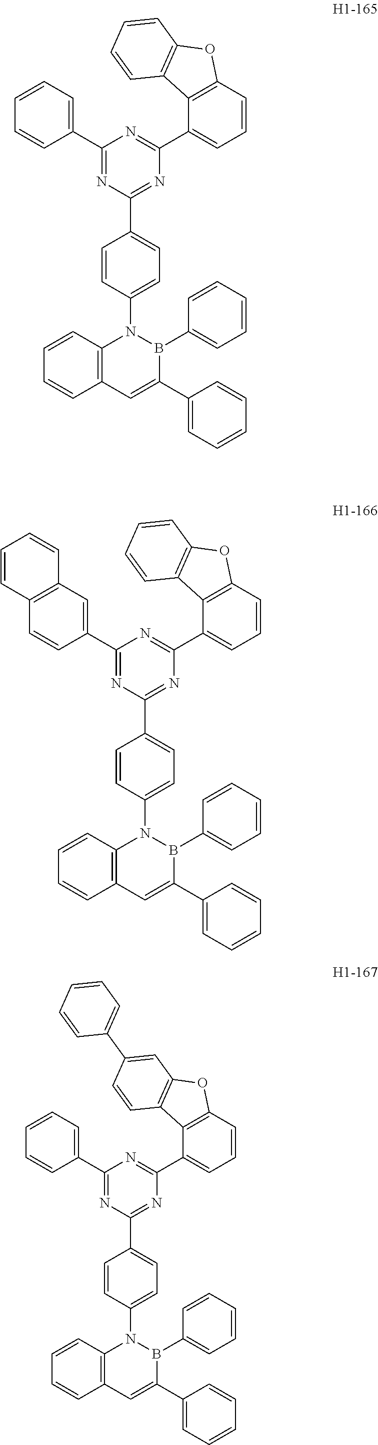 [SMILES: C1=C(c2ccccc2)B(c2ccccc2)N(c2ccc(-c3nc(-c4ccccc4)nc(-c4cccc5oc6ccccc6c45)n3)cc2)c2ccccc21 ; C1=C(c2ccccc2)B(c2ccccc2)N(c2ccc(-c3nc(-c4ccc5ccccc5c4)nc(-c4cccc5oc6ccccc6c45)n3)cc2)c2ccccc21 ; C1=C(c2ccccc2)B(c2ccccc2)N(c2ccc(-c3nc(-c4ccccc4)nc(-c4cccc5oc6cc(-c7ccccc7)ccc6c45)n3)cc2)c2ccccc21]

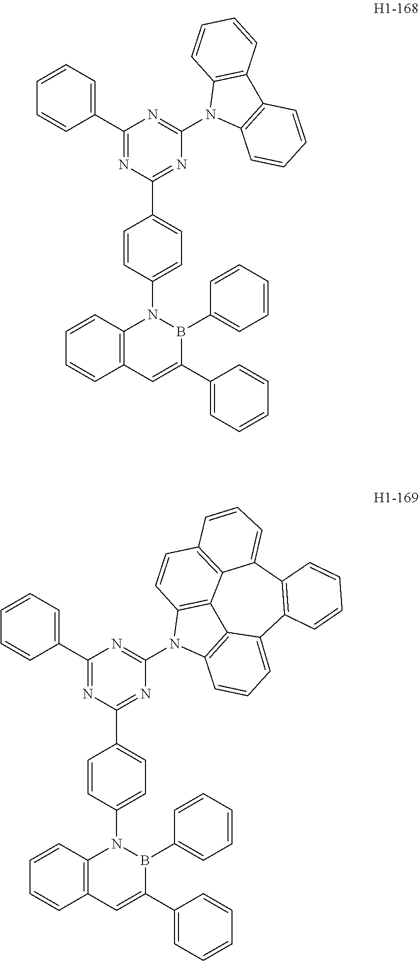 [SMILES: C1=C(c2ccccc2)B(c2ccccc2)N(c2ccc(-c3nc(-c4ccccc4)nc(-n4c5ccccc5c5ccccc54)n3)cc2)c2ccccc21 ; C1=C(c2ccccc2)B(c2ccccc2)N(c2ccc(-c3nc(-c4ccccc4)nc(-n4c5cccc6c5c5c7c(cccc7ccc54)-c4ccccc4-6)n3)cc2)c2ccccc21]

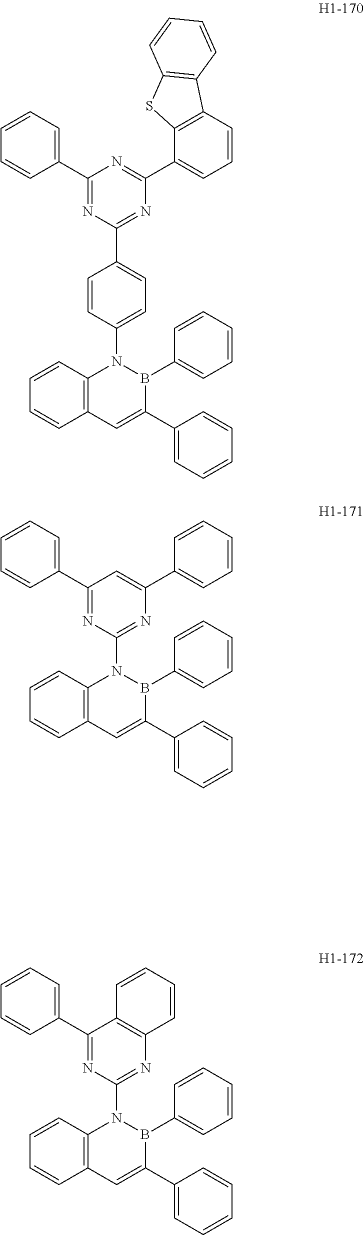

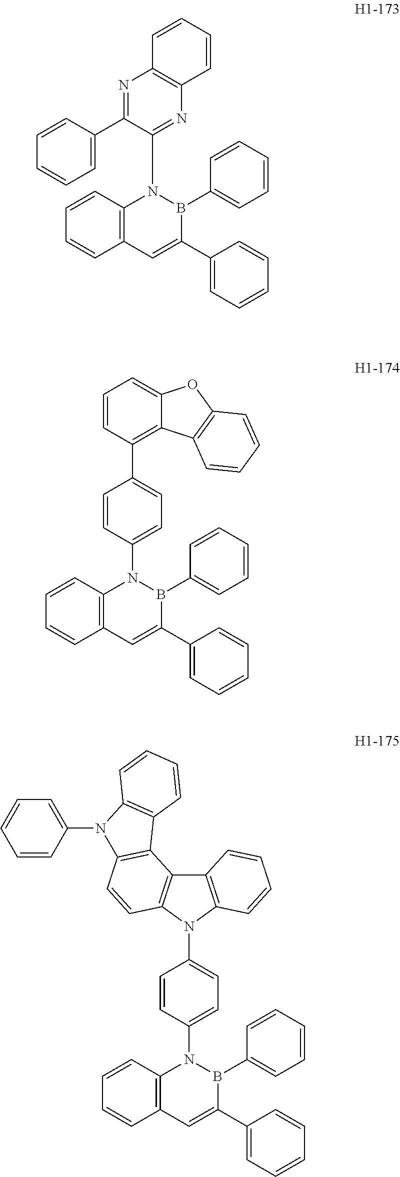 [SMILES: C1=C(c2ccccc2)B(c2ccccc2)N(c2nc3ccccc3nc2-c2ccccc2)c2ccccc21 ; C1=C(c2ccccc2)B(c2ccccc2)N(c2ccc(-c3cccc4oc5ccccc5c34)cc2)c2ccccc21 ; C1=C(c2ccccc2)B(c2ccccc2)N(c2ccc(-n3c4ccccc4c4c5c6ccccc6n(-c6ccccc6)c5ccc43)cc2)c2ccccc21]

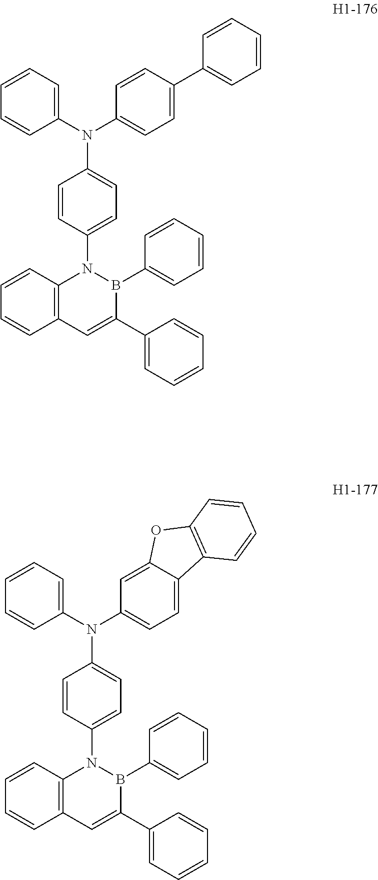 [SMILES: C1=C(c2ccccc2)B(c2ccccc2)N(c2ccc(N(c3ccccc3)c3ccc(-c4ccccc4)cc3)cc2)c2ccccc21 ; C1=C(c2ccccc2)B(c2ccccc2)N(c2ccc(N(c3ccccc3)c3ccc4c(c3)oc3ccccc34)cc2)c2ccccc21]

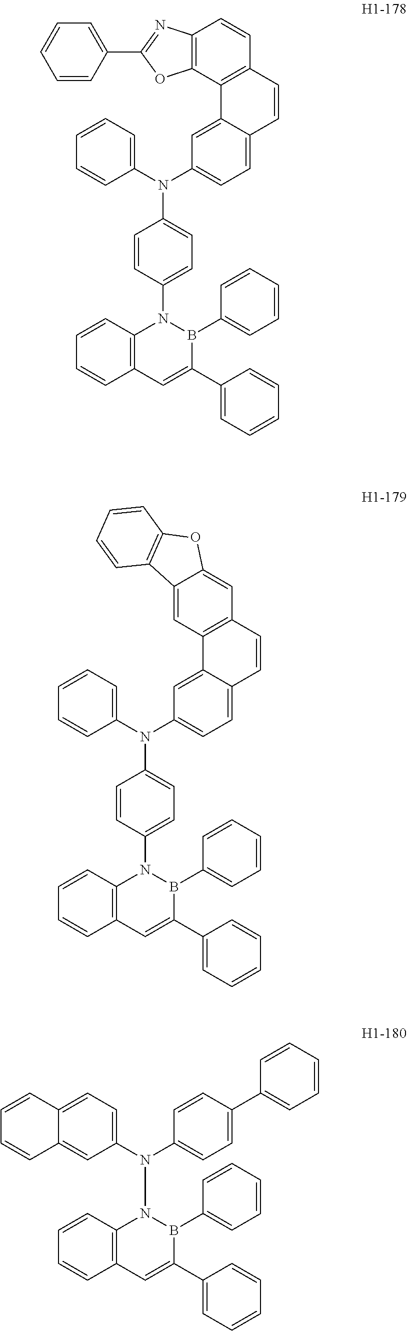 [SMILES: C1=C(c2ccccc2)B(c2ccccc2)N(c2ccc(N(c3ccccc3)c3ccc4ccc5ccc6nc(-c7ccccc7)oc6c5c4c3)cc2)c2ccccc21 ; C1=C(c2ccccc2)B(c2ccccc2)N(c2ccc(N(c3ccccc3)c3ccc4ccc5cc6oc7ccccc7c6cc5c4c3)cc2)c2ccccc21 ; C1=C(c2ccccc2)B(c2ccccc2)N(N(c2ccc(-c3ccccc3)cc2)c2ccc3ccccc3c2)c2ccccc21]

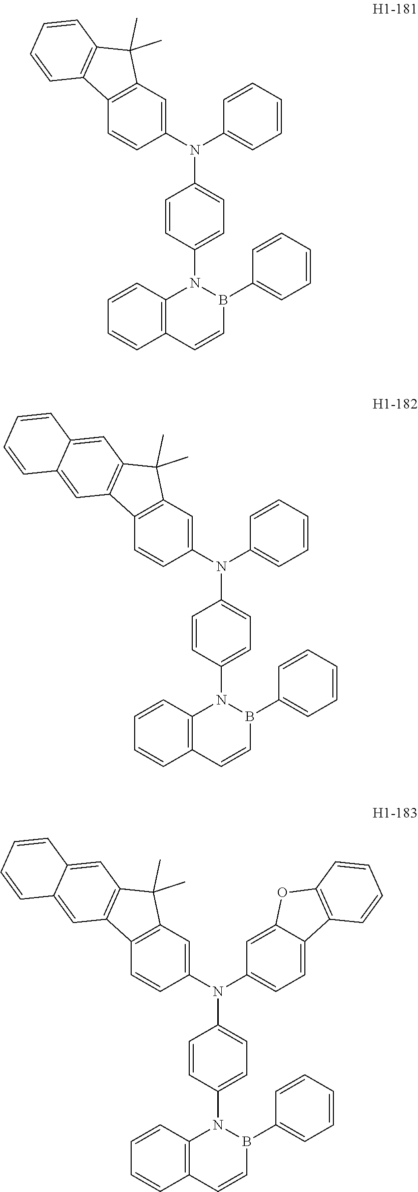 [SMILES: CC1(C)c2ccccc2-c2ccc(N(c3ccccc3)c3ccc(N4B(c5ccccc5)C=Cc5ccccc54)cc3)cc21 ; CC1(C)c2cc(N(c3ccccc3)c3ccc(N4B(c5ccccc5)C=Cc5ccccc54)cc3)ccc2-c2cc3ccccc3cc21 ; CC1(C)c2cc(N(c3ccc(N4B(c5ccccc5)C=Cc5ccccc54)cc3)c3ccc4c(c3)oc3ccccc34)ccc2-c2cc3ccccc3cc21]

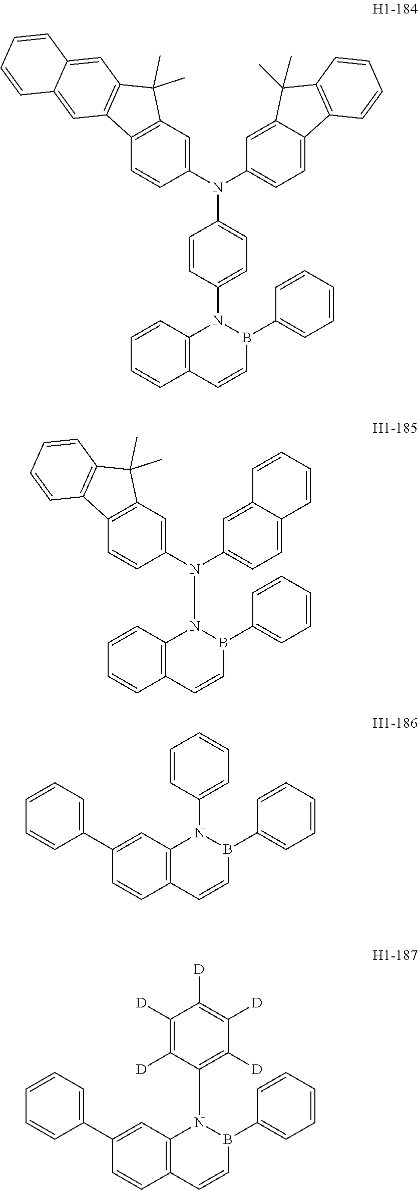

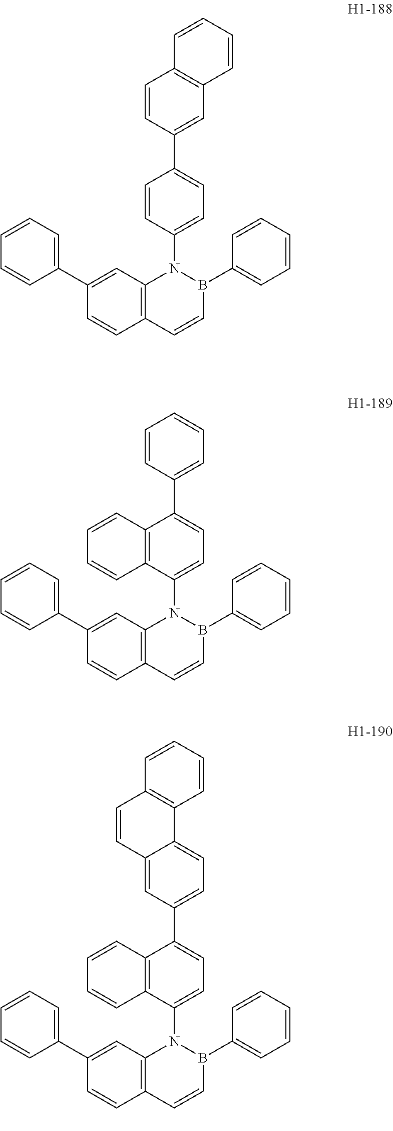

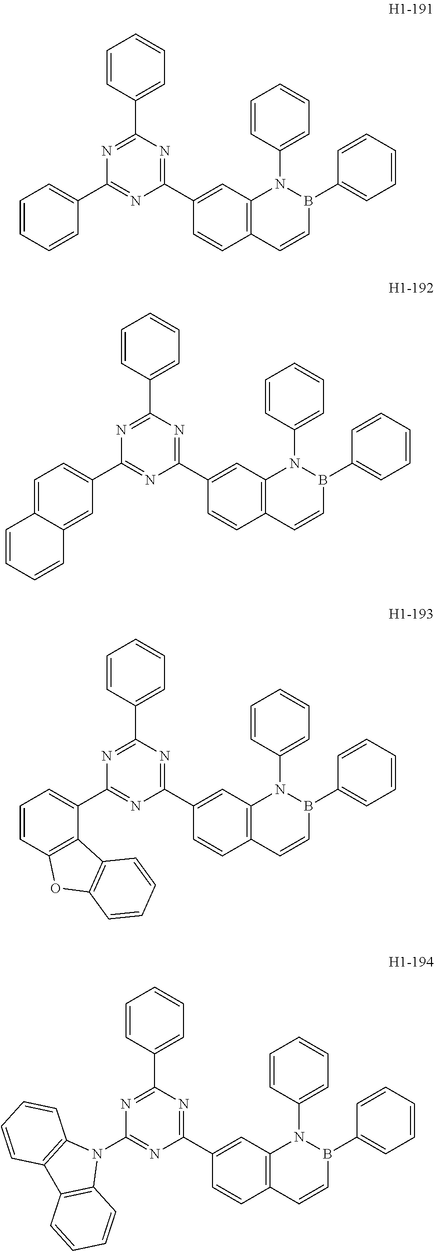 [SMILES: C1=Cc2ccc(-c3nc(-c4ccccc4)nc(-c4ccccc4)n3)cc2N(c2ccccc2)B1c1ccccc1 ; C1=Cc2ccc(-c3nc(-c4ccccc4)nc(-c4ccc5ccccc5c4)n3)cc2N(c2ccccc2)B1c1ccccc1 ; C1=Cc2ccc(-c3nc(-c4ccccc4)nc(-c4cccc5oc6ccccc6c45)n3)cc2N(c2ccccc2)B1c1ccccc1 ; C1=Cc2ccc(-c3nc(-c4ccccc4)nc(-n4c5ccccc5c5ccccc54)n3)cc2N(c2ccccc2)B1c1ccccc1]

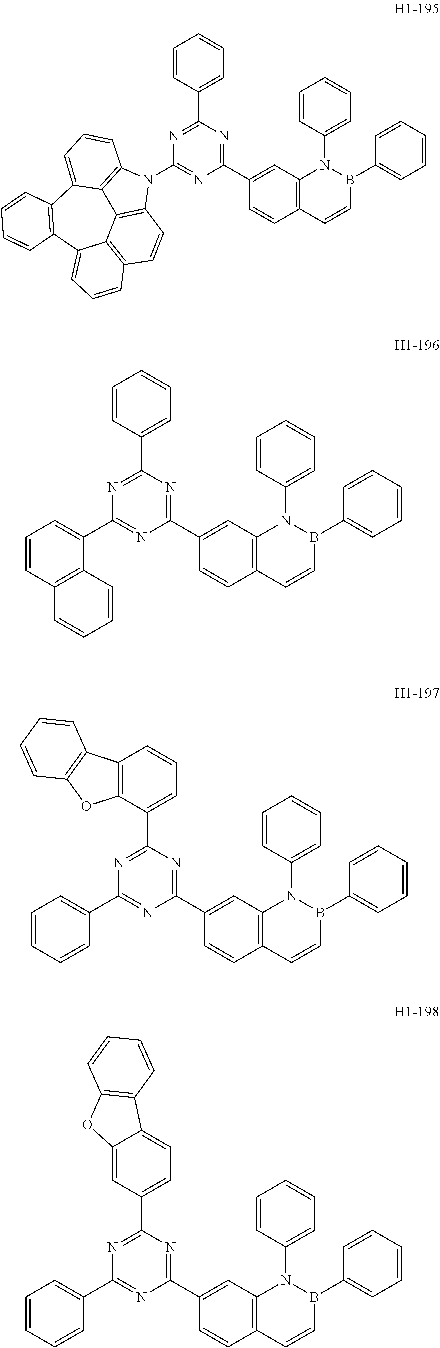 [SMILES: C1=Cc2ccc(-c3nc(-c4ccccc4)nc(-n4c5cccc6c5c5c7c(cccc7ccc54)-c4ccccc4-6)n3)cc2N(c2ccccc2)B1c1ccccc1 ; C1=Cc2ccc(-c3nc(-c4ccccc4)nc(-c4cccc5ccccc45)n3)cc2N(c2ccccc2)B1c1ccccc1 ; C1=Cc2ccc(-c3nc(-c4ccccc4)nc(-c4cccc5c4oc4ccccc45)n3)cc2N(c2ccccc2)B1c1ccccc1 ; C1=Cc2ccc(-c3nc(-c4ccccc4)nc(-c4ccc5c(c4)oc4ccccc45)n3)cc2N(c2ccccc2)B1c1ccccc1]

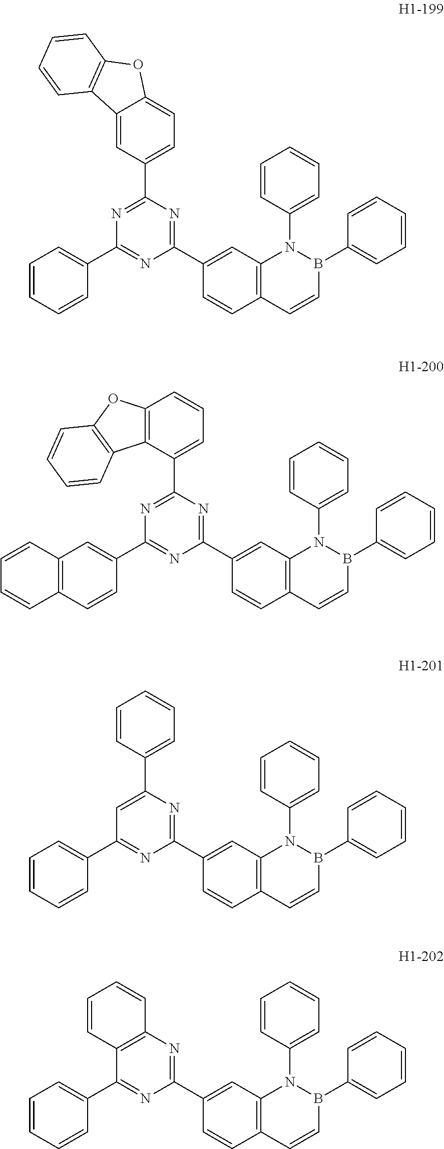 [SMILES: C1=Cc2ccc(-c3nc(-c4ccccc4)nc(-c4ccc5oc6ccccc6c5c4)n3)cc2N(c2ccccc2)B1c1ccccc1 ; C1=Cc2ccc(-c3nc(-c4ccc5ccccc5c4)nc(-c4cccc5oc6ccccc6c45)n3)cc2N(c2ccccc2)B1c1ccccc1 ; C1=Cc2ccc(-c3nc(-c4ccccc4)cc(-c4ccccc4)n3)cc2N(c2ccccc2)B1c1ccccc1 ; C1=Cc2ccc(-c3nc(-c4ccccc4)c4ccccc4n3)cc2N(c2ccccc2)B1c1ccccc1]

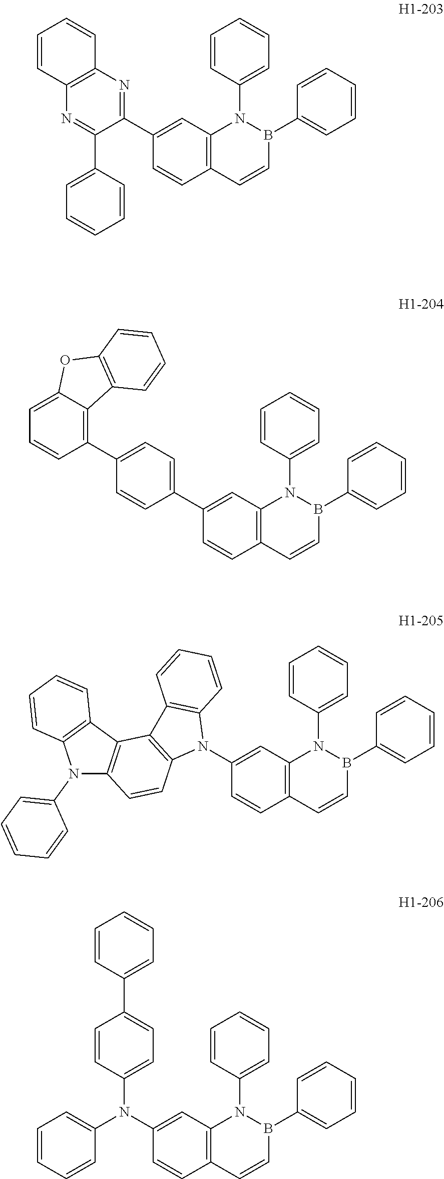 [SMILES: C1=Cc2ccc(-c3nc4ccccc4nc3-c3ccccc3)cc2N(c2ccccc2)B1c1ccccc1 ; C1=Cc2ccc(-c3ccc(-c4cccc5oc6ccccc6c45)cc3)cc2N(c2ccccc2)B1c1ccccc1 ; C1=Cc2ccc(-n3c4ccccc4c4c5c6ccccc6n(-c6ccccc6)c5ccc43)cc2N(c2ccccc2)B1c1ccccc1 ; C1=Cc2ccc(N(c3ccccc3)c3ccc(-c4ccccc4)cc3)cc2N(c2ccccc2)B1c1ccccc1]

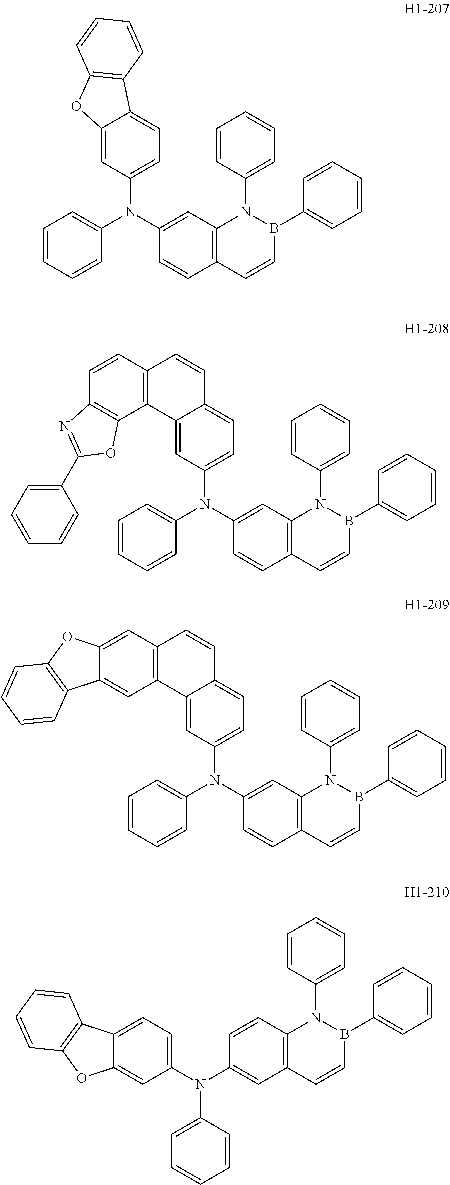 [SMILES: C1=Cc2ccc(N(c3ccccc3)c3ccc4c(c3)oc3ccccc34)cc2N(c2ccccc2)B1c1ccccc1 ; C1=Cc2ccc(N(c3ccccc3)c3ccc4ccc5ccc6nc(-c7ccccc7)oc6c5c4c3)cc2N(c2ccccc2)B1c1ccccc1 ; C1=Cc2ccc(N(c3ccccc3)c3ccc4ccc5cc6oc7ccccc7c6cc5c4c3)cc2N(c2ccccc2)B1c1ccccc1 ; C1=Cc2cc(N(c3ccccc3)c3ccc4c(c3)oc3ccccc34)ccc2N(c2ccccc2)B1c1ccccc1]

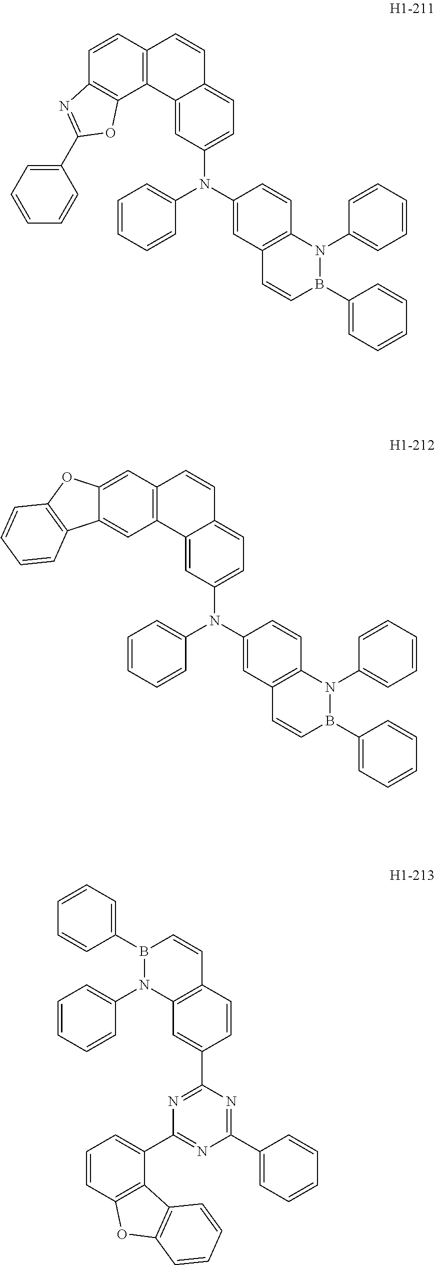 [SMILES: C1=Cc2cc(N(c3ccccc3)c3ccc4ccc5ccc6nc(-c7ccccc7)oc6c5c4c3)ccc2N(c2ccccc2)B1c1ccccc1 ; C1=Cc2cc(N(c3ccccc3)c3ccc4ccc5cc6oc7ccccc7c6cc5c4c3)ccc2N(c2ccccc2)B1c1ccccc1 ; C1=Cc2ccc(-c3nc(-c4ccccc4)nc(-c4cccc5oc6ccccc6c45)n3)cc2N(c2ccccc2)B1c1ccccc1]

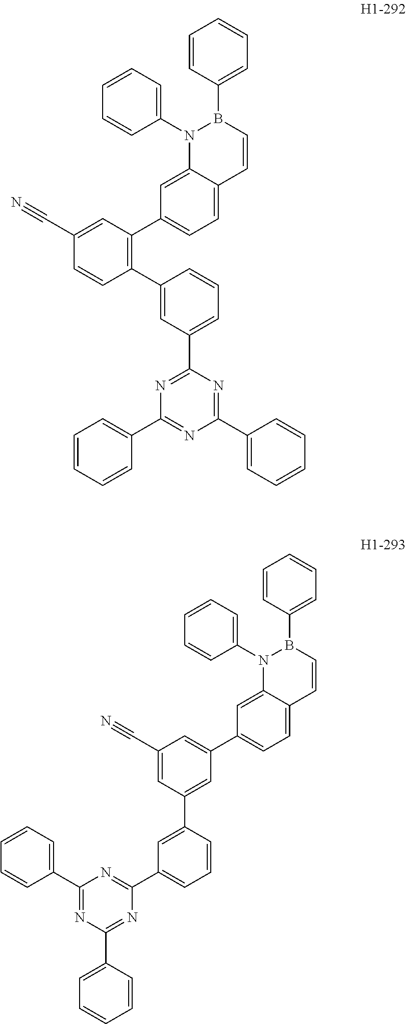 [SMILES: N#Cc1ccc(-c2cccc(-c3nc(-c4ccccc4)nc(-c4ccccc4)n3)c2)c(-c2ccc3c(c2)N(c2ccccc2)B(c2ccccc2)C=C3)c1 ; N#Cc1cc(-c2cccc(-c3nc(-c4ccccc4)nc(-c4ccccc4)n3)c2)cc(-c2ccc3c(c2)N(c2ccccc2)B(c2ccccc2)C=C3)c1]

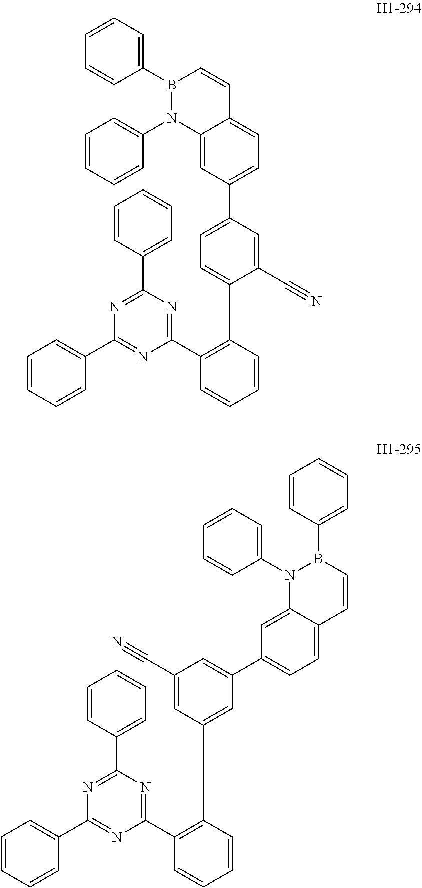 [SMILES: N#Cc1cc(-c2ccc3c(c2)N(c2ccccc2)B(c2ccccc2)C=C3)ccc1-c1ccccc1-c1nc(-c2ccccc2)nc(-c2ccccc2)n1 ; N#Cc1cc(-c2ccc3c(c2)N(c2ccccc2)B(c2ccccc2)C=C3)cc(-c2ccccc2-c2nc(-c3ccccc3)nc(-c3ccccc3)n2)c1]

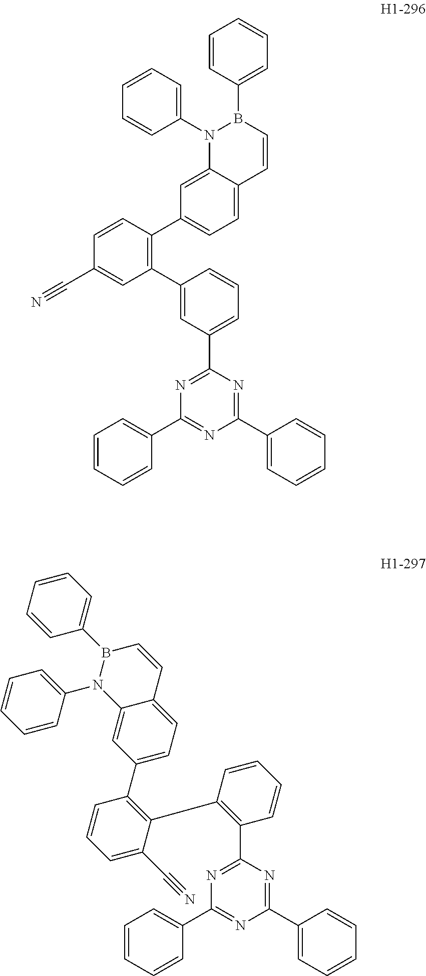 [SMILES: N#Cc1ccc(-c2ccc3c(c2)N(c2ccccc2)B(c2ccccc2)C=C3)c(-c2cccc(-c3nc(-c4ccccc4)nc(-c4ccccc4)n3)c2)c1 ; N#Cc1cccc(-c2ccc3c(c2)N(c2ccccc2)B(c2ccccc2)C=C3)c1-c1ccccc1-c1nc(-c2ccccc2)nc(-c2ccccc2)n1]

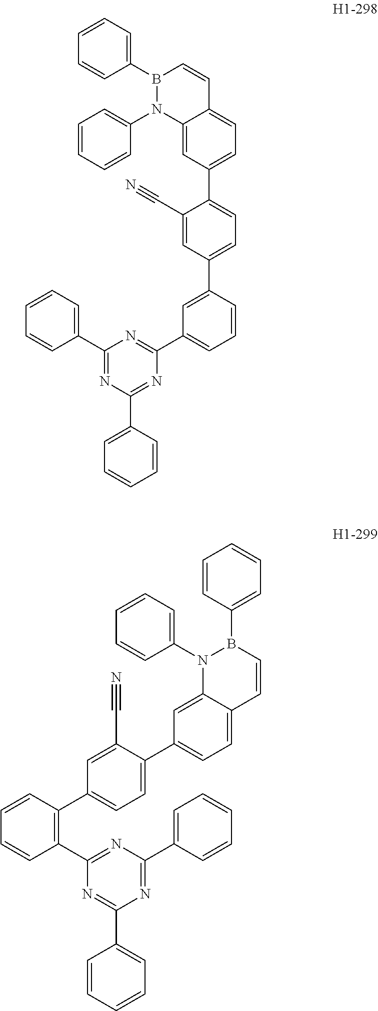 [SMILES: N#Cc1cc(-c2cccc(-c3nc(-c4ccccc4)nc(-c4ccccc4)n3)c2)ccc1-c1ccc2c(c1)N(c1ccccc1)B(c1ccccc1)C=C2 ; N#Cc1cc(-c2ccccc2-c2nc(-c3ccccc3)nc(-c3ccccc3)n2)ccc1-c1ccc2c(c1)N(c1ccccc1)B(c1ccccc1)C=C2]

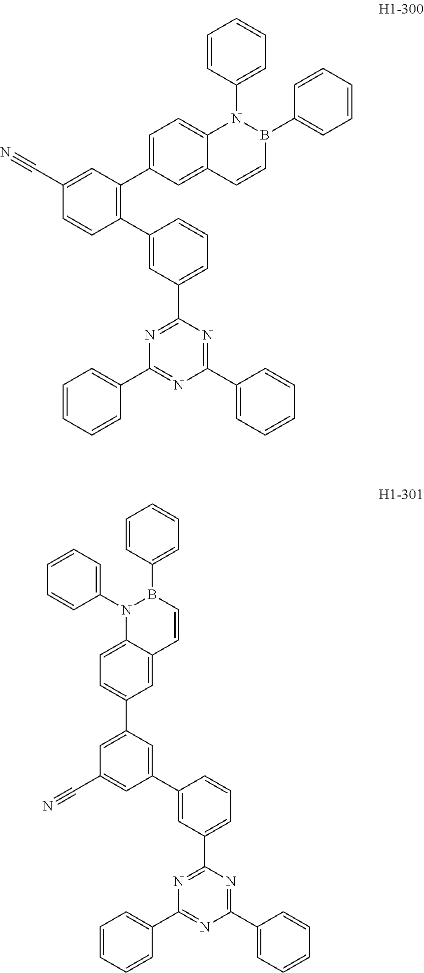 [SMILES: N#Cc1ccc(-c2cccc(-c3nc(-c4ccccc4)nc(-c4ccccc4)n3)c2)c(-c2ccc3c(c2)C=CB(c2ccccc2)N3c2ccccc2)c1 ; N#Cc1cc(-c2cccc(-c3nc(-c4ccccc4)nc(-c4ccccc4)n3)c2)cc(-c2ccc3c(c2)C=CB(c2ccccc2)N3c2ccccc2)c1]

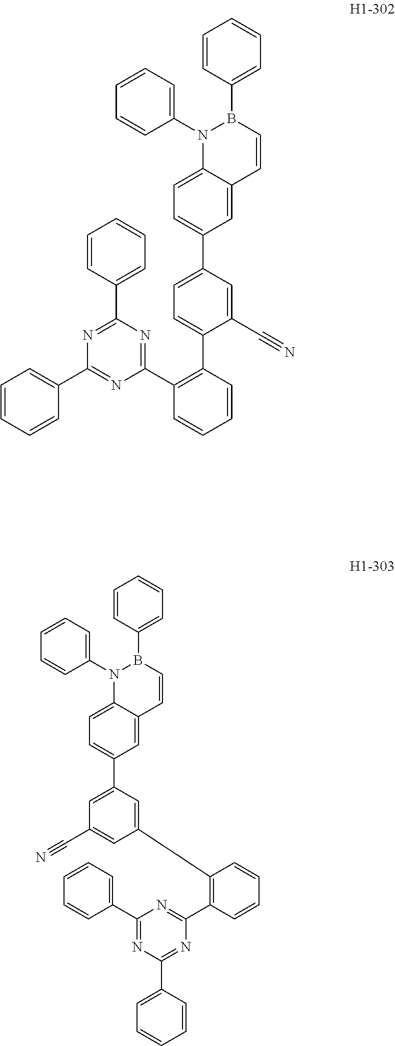 [SMILES: N#Cc1cc(-c2ccc3c(c2)C=CB(c2ccccc2)N3c2ccccc2)ccc1-c1ccccc1-c1nc(-c2ccccc2)nc(-c2ccccc2)n1 ; N#Cc1cc(-c2ccc3c(c2)C=CB(c2ccccc2)N3c2ccccc2)cc(-c2ccccc2-c2nc(-c3ccccc3)nc(-c3ccccc3)n2)c1]

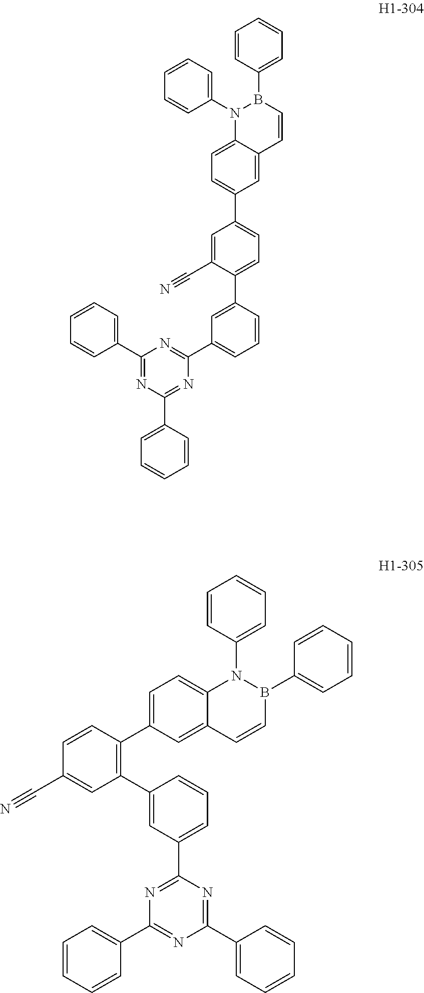 [SMILES: N#Cc1cc(-c2ccc3c(c2)C=CB(c2ccccc2)N3c2ccccc2)ccc1-c1cccc(-c2nc(-c3ccccc3)nc(-c3ccccc3)n2)c1 ; N#Cc1ccc(-c2ccc3c(c2)C=CB(c2ccccc2)N3c2ccccc2)c(-c2cccc(-c3nc(-c4ccccc4)nc(-c4ccccc4)n3)c2)c1]

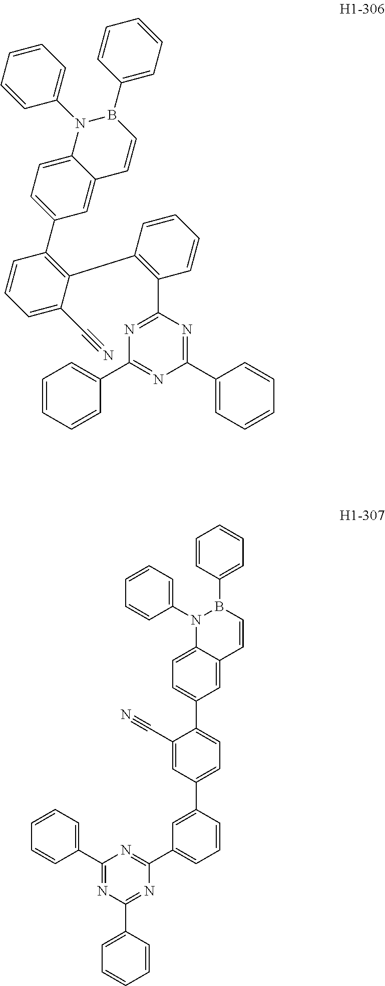 [SMILES: N#Cc1cccc(-c2ccc3c(c2)C=CB(c2ccccc2)N3c2ccccc2)c1-c1ccccc1-c1nc(-c2ccccc2)nc(-c2ccccc2)n1 ; N#Cc1cc(-c2cccc(-c3nc(-c4ccccc4)nc(-c4ccccc4)n3)c2)ccc1-c1ccc2c(c1)C=CB(c1ccccc1)N2c1ccccc1]

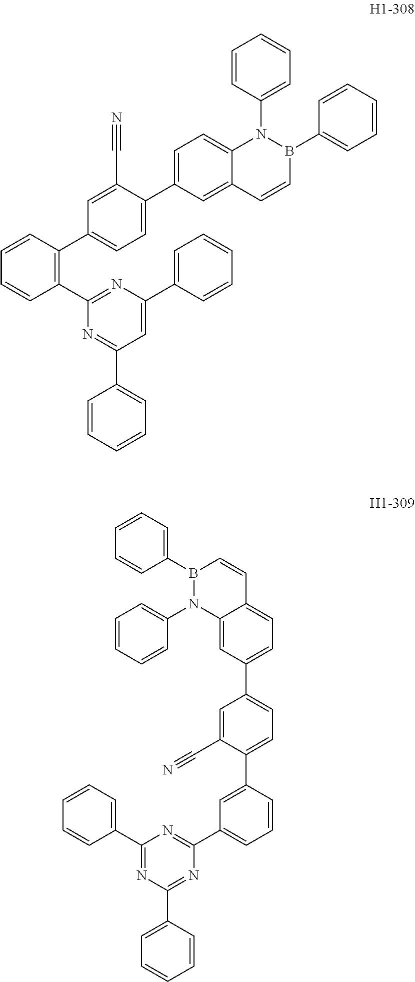 [SMILES: N#Cc1cc(-c2ccccc2-c2nc(-c3ccccc3)cc(-c3ccccc3)n2)ccc1-c1ccc2c(c1)C=CB(c1ccccc1)N2c1ccccc1 ; N#Cc1cc(-c2ccc3c(c2)N(c2ccccc2)B(c2ccccc2)C=C3)ccc1-c1cccc(-c2nc(-c3ccccc3)nc(-c3ccccc3)n2)c1]

In the compounds above, Dₙ means that n number of hydrogens are replaced with deuterium, and n represents an integer from 1 to the maximum number of hydrogens in the compound.

According to one embodiment of the present disclosure, a plurality of host materials, in which the second host compound is represented by any one of the following Formulas 2-1 and 2-2, is provided.

The compounds represented by Formulas 2-1 and 2-2 are described in more detail as follows.

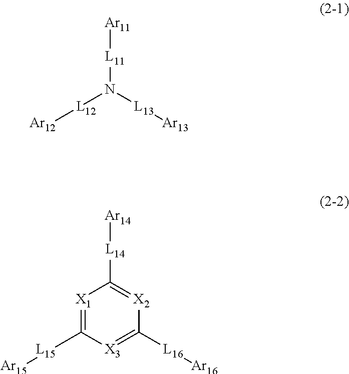

In Formulas 2-1 and 2-2, X₁ to X₃ each independently represent N or CR₁₁, with a proviso that at least one of X₁ to X₃ represents N. For example, all of X₁ to X₃ may be N.

In Formulas 2-1 and 2-2, L₁₁ to L₁₆ each independently represent a single bond, a substituted or unsubstituted (C₆-C₃₀)arylene, or a substituted or unsubstituted (3- to 30-membered)heteroarylene. According to one embodiment of the present disclosure, L₁₁ to L₁₆ each independently represent a single bond, a substituted or unsubstituted (C₆-C₂₅)arylene, or a substituted or unsubstituted (3- to 25-membered)heteroarylene. According to another embodiment of the present disclosure, L₁₁ to L₁₆ each independently represent a single bond, a substituted or unsubstituted (C₆-C₁₈)arylene, or a substituted or unsubstituted (3- to 15-membered)heteroarylene. For example, L₁₁ to L₁₆ each independently may be a single bond; a phenylene unsubstituted or substituted with a naphthyl or a dibenzofuranyl; a biphenylene; a terphenylene; a naphthylene unsubstituted or substituted with a phenyl; a phenanthrenylene; a dibenzofuranylene; a dibenzothiophenylene; or a carbazolene, etc.

In Formulas 2-1 and 2-2, Ar₁₁ to Ar₁₆ and R₁₁ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s). According to one embodiment of the present disclosure, Ar₁₁ to Ar₁₆ and R₁₁ each independently represent hydrogen, deuterium, a substituted or unsubstituted (C₆-C₃₀)aryl, a substituted or unsubstituted (3- to 30-membered)heteroaryl, a substituted or unsubstituted tri(C₆-C₃₀)arylsilyl, a substituted or unsubstituted mono- or di(C₆-C₃₀)arylamino, a substituted or unsubstituted mono- or di(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s). According to another embodiment of the present disclosure, Ar₁₁ to Ar₁₆ and R₁₁ each independently represent hydrogen, deuterium, a substituted or unsubstituted (C₆-C₃₀)aryl, or a substituted or unsubstituted (3- to 30-membered)heteroaryl; or may be linked to an adjacent substituent(s) to form a ring(s). For example, Ar₁₁ to Ar₁₃ each independently may be a phenyl unsubstituted or substituted with a methyl, a tert-butyl, a naphthyl unsubstituted or substituted with a phenyl, a phenanthrenyl, a fluoranthenyl, a dibenzofuranyl, a dibenzothiophenyl, a dibenzoselenophenyl, a pyridinyl unsubstituted or substituted with a phenyl, an anthracenyl, a benzimidazolyl unsubstituted or substituted with a phenyl, a diphenylamino, or a triphenylsilyl; a naphthyl unsubstituted or substituted with a phenyl, a biphenyl, or a naphthyl; a phenanthrenyl unsubstituted or substituted with a phenyl; an anthracenyl; a biphenyl unsubstituted or substituted with deuterium, a naphthyl, or a triphenylsilyl; a terphenyl; a quaterphenyl; a dimethylfluorenyl; a diphenylfluorenyl; a dimethylbenzofluorenyl; a diphenylbenzofluorenyl; a C₂₂aryl; a fluoranthenyl; a spirofluorenyl; a triphenylenyl; a dibenzofuranyl unsubstituted or substituted with a phenyl, a naphthyl, a pyridyl, or a biphenyl; a dibenzothiophenyl unsubstituted or substituted with a phenyl; a benzonaphthofuranyl; a benzonaphthothiophenyl; a carbazolyl unsubstituted or substituted with a phenyl, a biphenyl, or a naphthyl; a phenoxazinyl; a pyridyl unsubstituted or substituted with a phenyl; a benzimidazolyl unsubstituted or substituted with a phenyl; a benzofuropyridinyl; a dibenzoselenophenyl; a phenanthrooxazolyl unsubstituted or substituted with a phenyl, a pyrimidyl, or a biphenyl; or a phenanthrothiazolyl unsubstituted or substituted with a phenyl, etc. In addition, for example, Ar₁₄ to Ar₁₆ each independently may be a phenyl unsubstituted or substituted with deuterium, a naphthyl unsubstituted or substituted with a phenyl, a phenanthrenyl, or triphenylsilyl; a biphenyl unsubstituted or substituted with a phenyl; a terphenyl; a quaterphenyl; a naphthyl unsubstituted or substituted with a phenyl, a biphenyl, or a naphthyl; a phenanthrenyl unsubstituted or substituted with a phenyl or a naphthyl; a triphenylenyl; a benzophenanthrenyl; a fluoranthenyl; a dibenzofuranyl unsubstituted or substituted with deuterium, a phenyl unsubstituted or substituted with a naphthyl, a naphthyl unsubstituted or substituted with a phenyl, a phenanthrenyl, a biphenyl, or a triphenylenyl, etc.

According to one embodiment of the present disclosure, Ar₁₁ in Formula 2-1 above may be represented by the following Formula 2-1a.

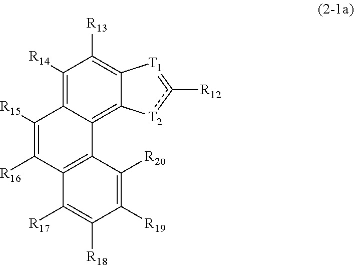

In Formula 2-1a, T₁ and T₂ each independently represent —N═, —NR₂₁—, —O—, or —S—, with a proviso that one of T₁ and T₂ represents —N═, and the other of T₁ and T₂ represents —NR₂₁—, —O—, or —S—.

In Formula 2-1a, R₁₂ to R₂₁ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring group of a (C₃-C₃₀) aliphatic ring(s) and a (C₆-C₃₀) aromatic ring(s), a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3-to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino; or may be linked to an adjacent substituent(s) to form a ring(s); with a proviso that any one of R₁₂ to R₂₁ is linked to L₁₁. According to one embodiment of the present disclosure, R₁₂ to R₂₁ each independently represent hydrogen, deuterium, a substituted or unsubstituted (C₆-C₃₀)aryl, a substituted or unsubstituted (3- to 30-membered)heteroaryl, a substituted or unsubstituted tri(C₆-C₃₀)arylsilyl, a substituted or unsubstituted fused ring group of a (C₃-C₃₀) aliphatic ring(s) and a (C₆-C₃₀) aromatic ring(s), a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino; or may be linked to an adjacent substituent(s) to form a ring(s); with a proviso that any one of R₁₂ to R₂₁ is linked to L₁₁. According to another embodiment of the present disclosure, R₁₂ to R₂₁ each independently represent hydrogen, deuterium, a substituted or unsubstituted (C₆-C₁₅)aryl, or a substituted or unsubstituted (3- to 15-membered)heteroaryl; or may be linked to an adjacent substituent(s) to form a ring(s); with a proviso that any one of R₁₂ to R₂₁ is linked to L₁₁. For example, R₁₂ to R₂₁ each independently may be linked to L₁₁; or may be hydrogen; a phenyl; a biphenyl; a naphthyl; a pyridinyl, etc.

According to one embodiment of the present disclosure, Ar₁₄ in Formula 2-2 above may be represented by the following Formula 2-2a.

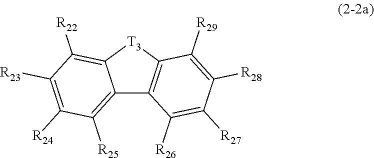

In Formula 2-2a, T₃ represents O or S.

In Formula 2-2a, R₂₂ to R₂₉ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, or a substituted or unsubstituted tri(C₆-C₃₀)arylsilyl; or may be linked to an adjacent substituent(s) to form a ring(s); with a proviso that any one of R₂₂ to R₂₉ is linked to L₁₄. According to one embodiment of the present disclosure, R₂₂ to R₂₉ each independently represent hydrogen, deuterium, a substituted or unsubstituted (C₆-C₃₀)aryl, or a substituted or unsubstituted (3-to 30-membered)heteroaryl; or may be linked to an adjacent substituent(s) to form a ring(s); with a proviso that any one of R₂₂ to R₂₉ is linked to L₁₄. According to another embodiment of the present disclosure, R₂₂ to R₂₉ each independently represent hydrogen, deuterium, or a substituted or unsubstituted (C₆-C₂₀)aryl; or may be linked to an adjacent substituent(s) to form a ring(s); with a proviso that any one of R₂₂ to R₂₉ is linked to L₁₄. For example, R₂₂ to R₂₉ each independently may be linked to L₁₄, or may be hydrogen; deuterium; a phenyl unsubstituted or substituted with a naphthyl; a naphthyl unsubstituted or substituted with a phenyl; a phenanthrenyl; a biphenyl; or a triphenylenyl, etc.

According to one embodiment, the compound represented by Formula 2-1 may be at least one selected from the following compounds, but is not limited thereto.

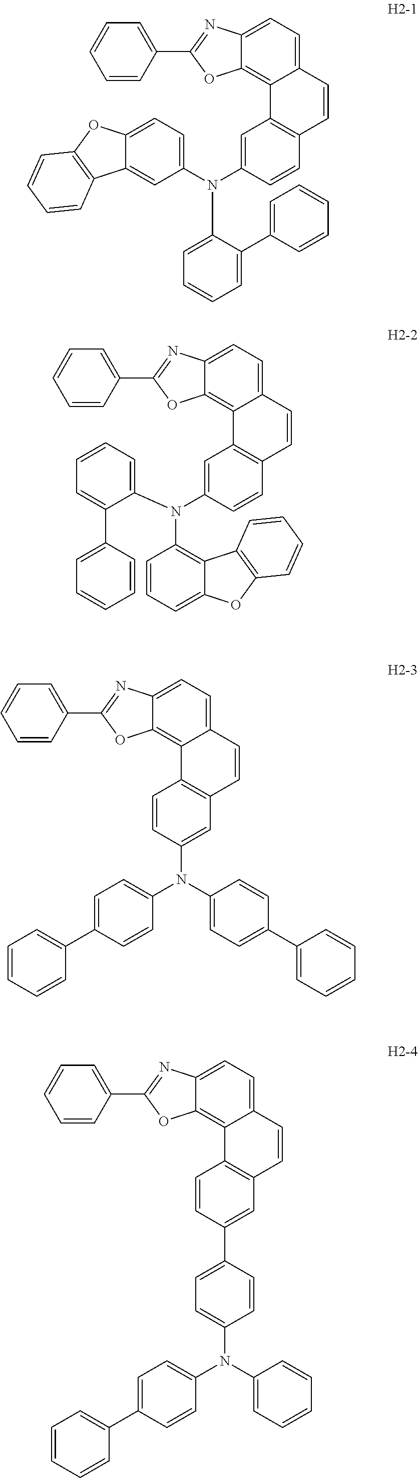 [SMILES: c1ccc(-c2nc3ccc4ccc5ccc(N(c6ccc7oc8ccccc8c7c6)c6ccccc6-c6ccccc6)cc5c4c3o2)cc1 ; c1ccc(-c2nc3ccc4ccc5ccc(N(c6ccccc6-c6ccccc6)c6cccc7oc8ccccc8c67)cc5c4c3o2)cc1 ; c1ccc(-c2ccc(N(c3ccc(-c4ccccc4)cc3)c3ccc4c(ccc5ccc6nc(-c7ccccc7)oc6c54)c3)cc2)cc1 ; c1ccc(-c2ccc(N(c3ccccc3)c3ccc(-c4ccc5c(ccc6ccc7nc(-c8ccccc8)oc7c65)c4)cc3)cc2)cc1]

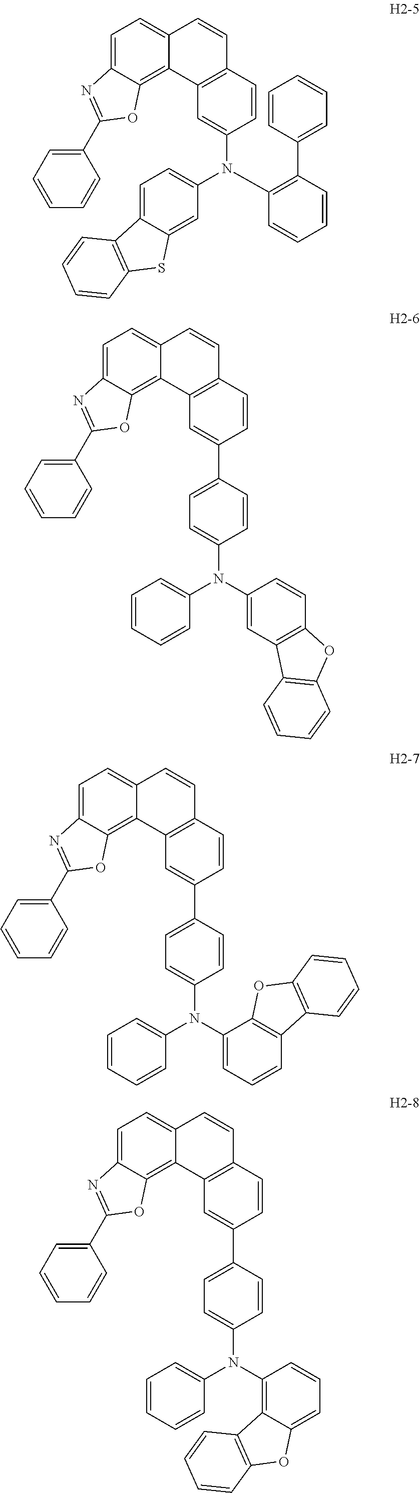

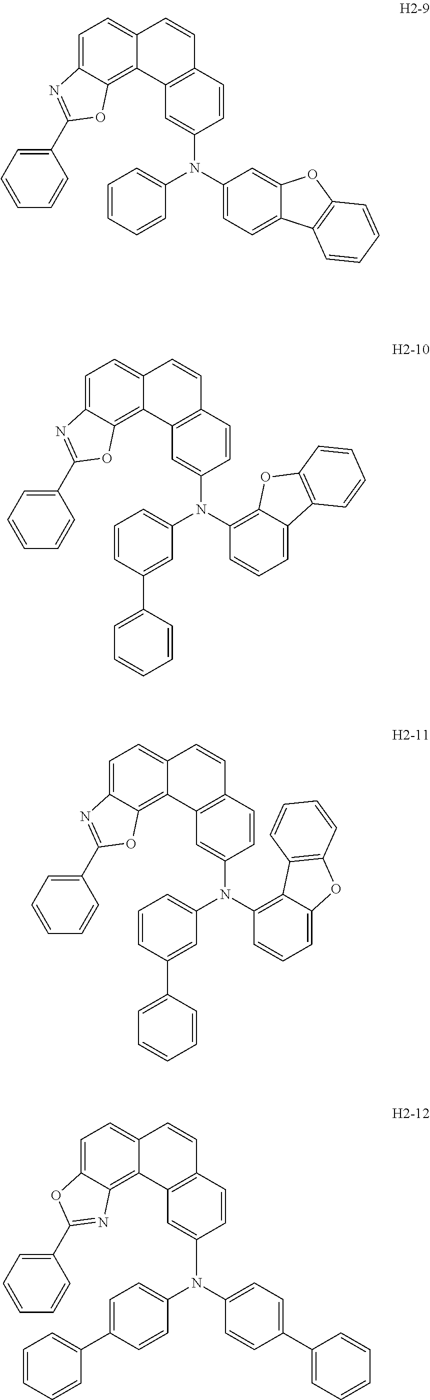 [SMILES: c1ccc(-c2nc3ccc4ccc5ccc(N(c6ccccc6)c6ccc7c(c6)oc6ccccc67)cc5c4c3o2)cc1 ; c1ccc(-c2cccc(N(c3ccc4ccc5ccc6nc(-c7ccccc7)oc6c5c4c3)c3cccc4c3oc3ccccc34)c2)cc1 ; c1ccc(-c2cccc(N(c3ccc4ccc5ccc6nc(-c7ccccc7)oc6c5c4c3)c3cccc4oc5ccccc5c34)c2)cc1 ; c1ccc(-c2ccc(N(c3ccc(-c4ccccc4)cc3)c3ccc4ccc5ccc6oc(-c7ccccc7)nc6c5c4c3)cc2)cc1]

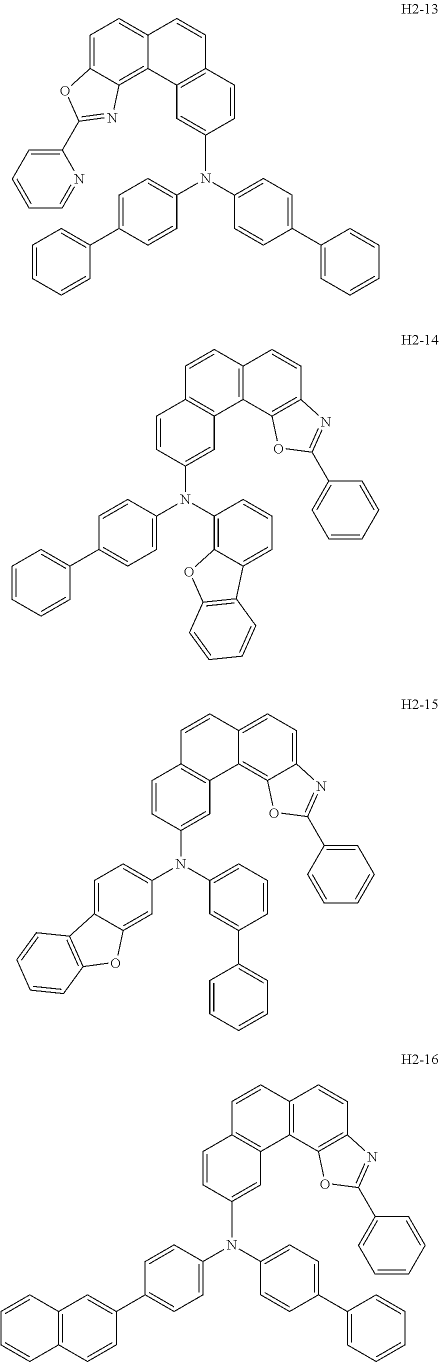

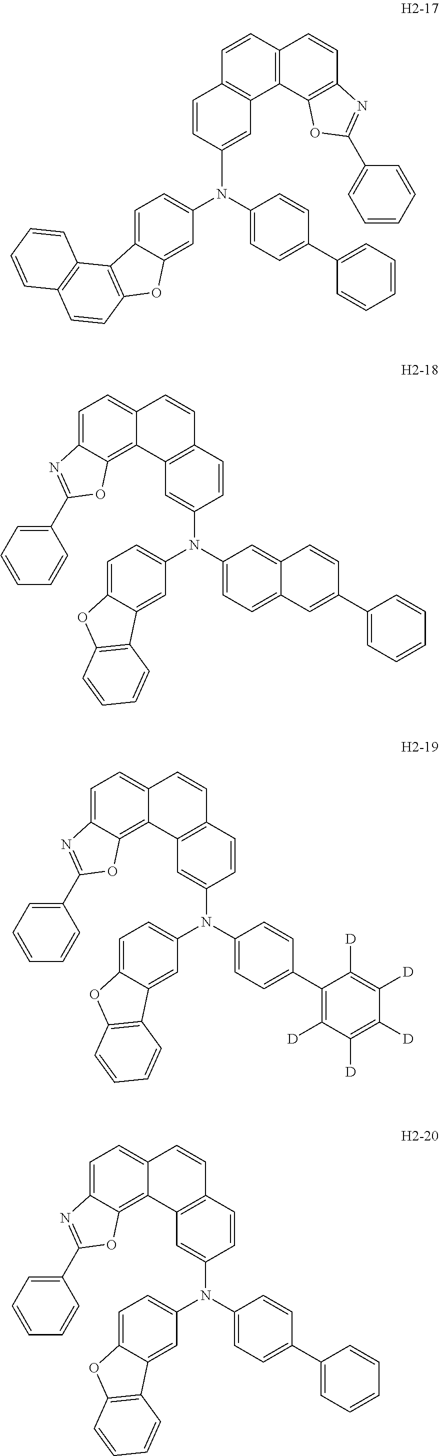

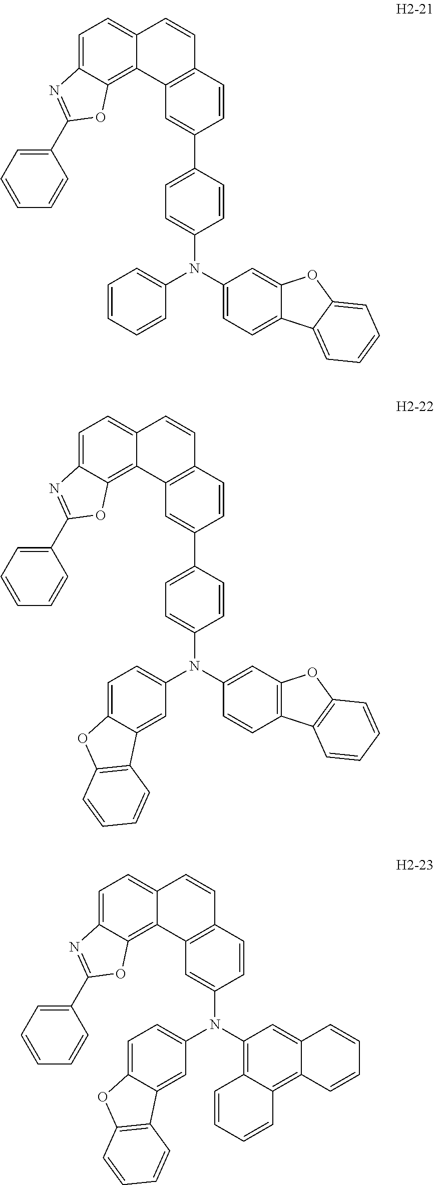 [SMILES: c1ccc(-c2nc3ccc4ccc5ccc(-c6ccc(N(c7ccccc7)c7ccc8c(c7)oc7ccccc78)cc6)cc5c4c3o2)cc1 ; c1ccc(-c2nc3ccc4ccc5ccc(-c6ccc(N(c7ccc8c(c7)oc7ccccc78)c7ccc8oc9ccccc9c8c7)cc6)cc5c4c3o2)cc1 ; c1ccc(-c2nc3ccc4ccc5ccc(N(c6ccc7oc8ccccc8c7c6)c6cc7ccccc7c7ccccc67)cc5c4c3o2)cc1]

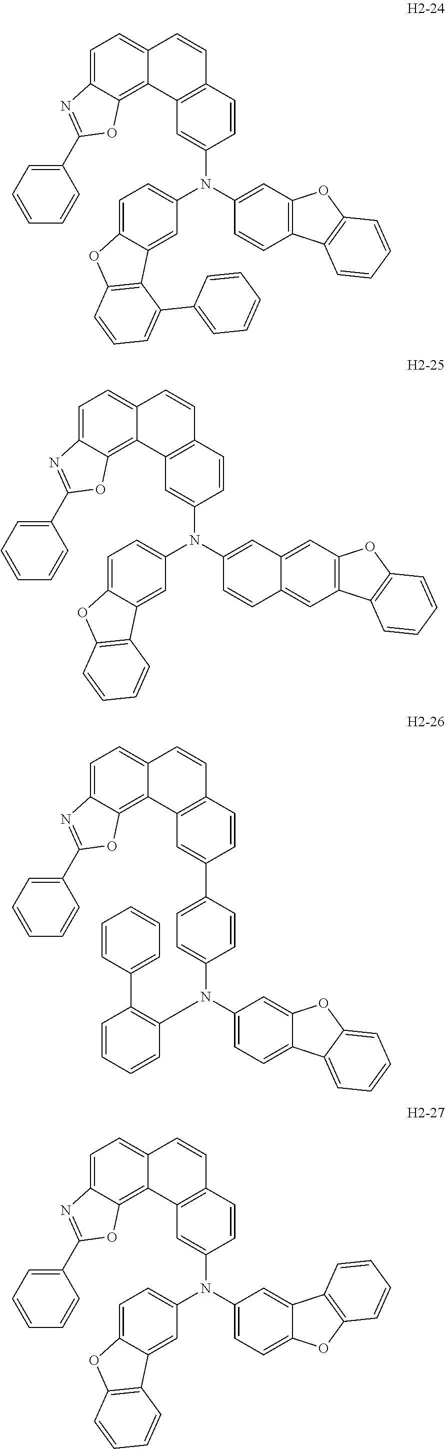

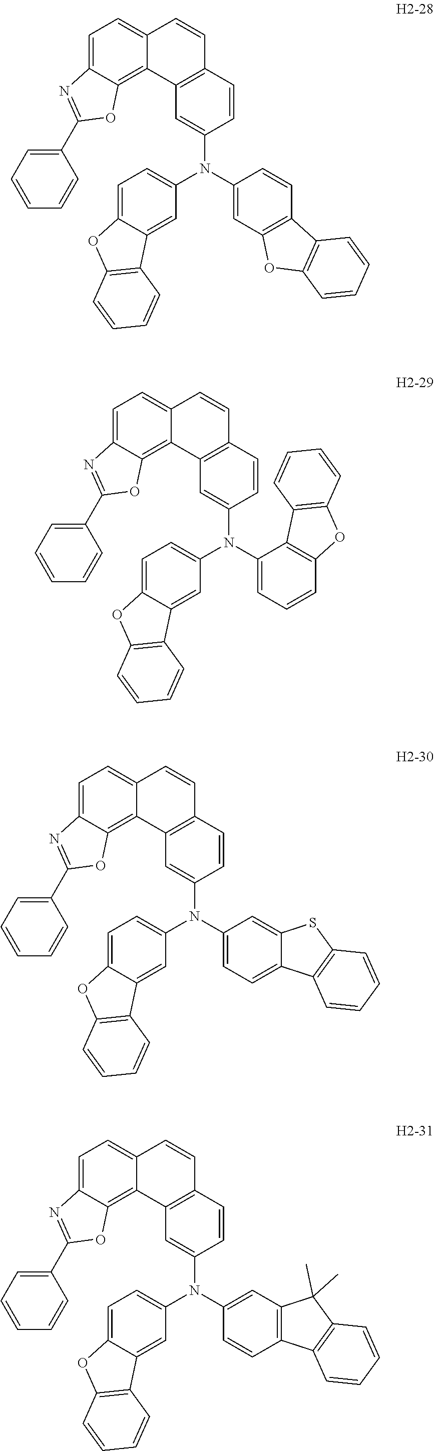 [SMILES: c1ccc(-c2nc3ccc4ccc5ccc(N(c6ccc7c(c6)oc6ccccc67)c6ccc7oc8ccccc8c7c6)cc5c4c3o2)cc1 ; c1ccc(-c2nc3ccc4ccc5ccc(N(c6ccc7oc8ccccc8c7c6)c6cccc7oc8ccccc8c67)cc5c4c3o2)cc1 ; c1ccc(-c2nc3ccc4ccc5ccc(N(c6ccc7c(c6)sc6ccccc67)c6ccc7oc8ccccc8c7c6)cc5c4c3o2)cc1 ; CC1(C)c2ccccc2-c2ccc(N(c3ccc4oc5ccccc5c4c3)c3ccc4ccc5ccc6nc(-c7ccccc7)oc6c5c4c3)cc21]

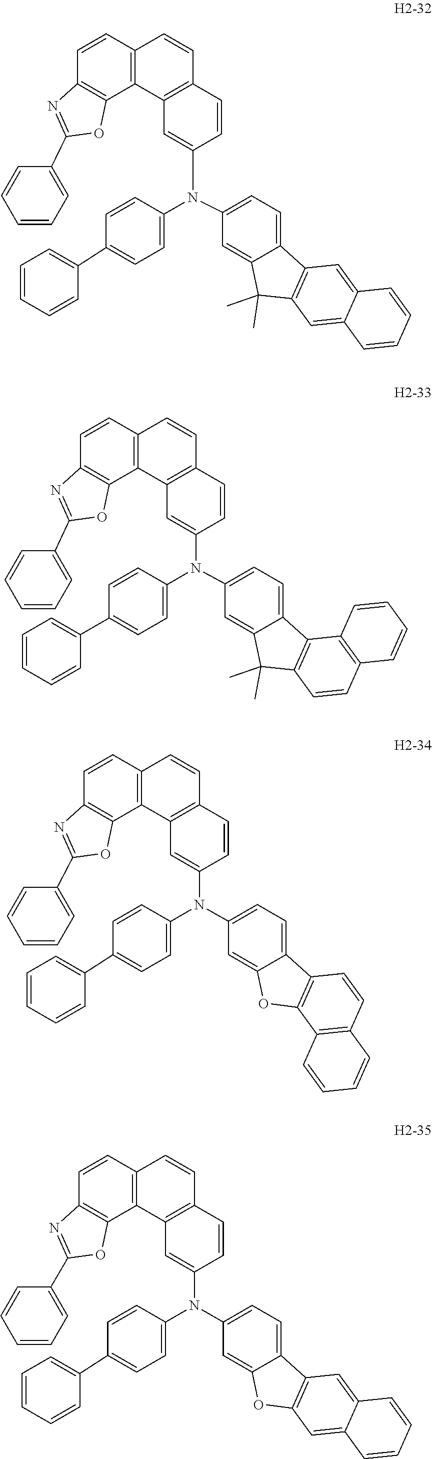 [SMILES: CC1(C)c2cc(N(c3ccc(-c4ccccc4)cc3)c3ccc4ccc5ccc6nc(-c7ccccc7)oc6c5c4c3)ccc2-c2cc3ccccc3cc21 ; CC1(C)c2cc(N(c3ccc(-c4ccccc4)cc3)c3ccc4ccc5ccc6nc(-c7ccccc7)oc6c5c4c3)ccc2-c2c1ccc1ccccc21 ; c1ccc(-c2ccc(N(c3ccc4c(c3)oc3c5ccccc5ccc43)c3ccc4ccc5ccc6nc(-c7ccccc7)oc6c5c4c3)cc2)cc1 ; c1ccc(-c2ccc(N(c3ccc4c(c3)oc3cc5ccccc5cc34)c3ccc4ccc5ccc6nc(-c7ccccc7)oc6c5c4c3)cc2)cc1]

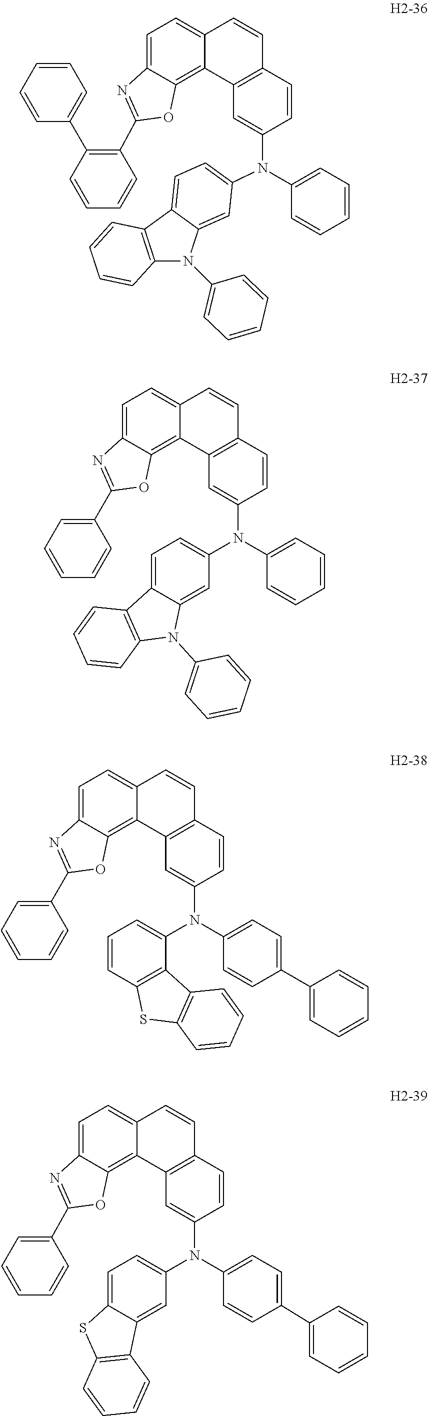 [SMILES: c1ccc(-c2ccccc2-c2nc3ccc4ccc5ccc(N(c6ccccc6)c6ccc7c8ccccc8n(-c8ccccc8)c7c6)cc5c4c3o2)cc1 ; c1ccc(-c2nc3ccc4ccc5ccc(N(c6ccccc6)c6ccc7c8ccccc8n(-c8ccccc8)c7c6)cc5c4c3o2)cc1 ; c1ccc(-c2ccc(N(c3ccc4ccc5ccc6nc(-c7ccccc7)oc6c5c4c3)c3cccc4sc5ccccc5c34)cc2)cc1 ; c1ccc(-c2ccc(N(c3ccc4sc5ccccc5c4c3)c3ccc4ccc5ccc6nc(-c7ccccc7)oc6c5c4c3)cc2)cc1]

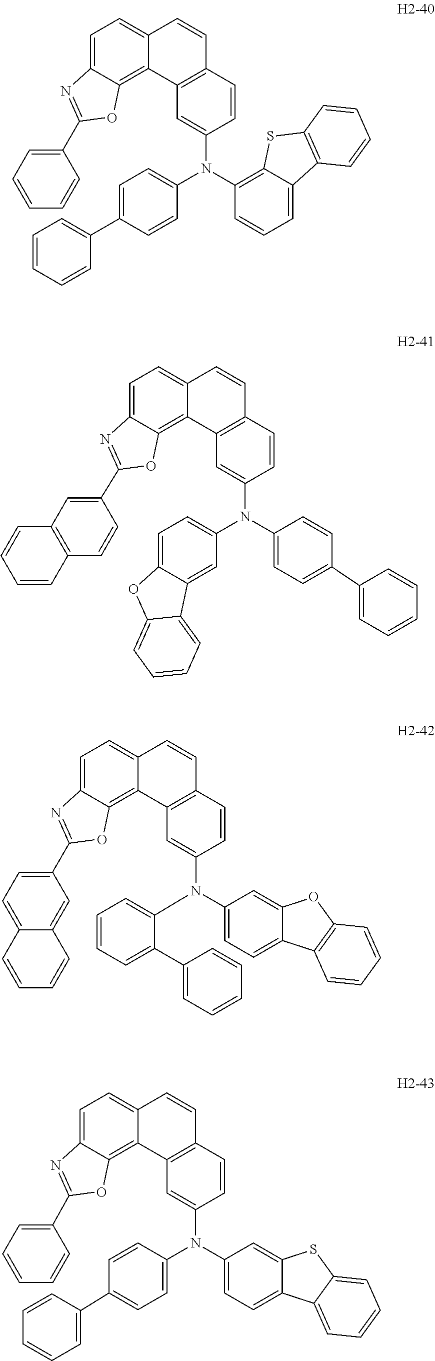 [SMILES: c1ccc(-c2ccc(N(c3ccc4ccc5ccc6nc(-c7ccccc7)oc6c5c4c3)c3cccc4c3sc3ccccc34)cc2)cc1 ; c1ccc(-c2ccc(N(c3ccc4oc5ccccc5c4c3)c3ccc4ccc5ccc6nc(-c7ccc8ccccc8c7)oc6c5c4c3)cc2)cc1 ; c1ccc(-c2ccccc2N(c2ccc3c(c2)oc2ccccc23)c2ccc3ccc4ccc5nc(-c6ccc7ccccc7c6)oc5c4c3c2)cc1 ; c1ccc(-c2ccc(N(c3ccc4c(c3)sc3ccccc34)c3ccc4ccc5ccc6nc(-c7ccccc7)oc6c5c4c3)cc2)cc1]

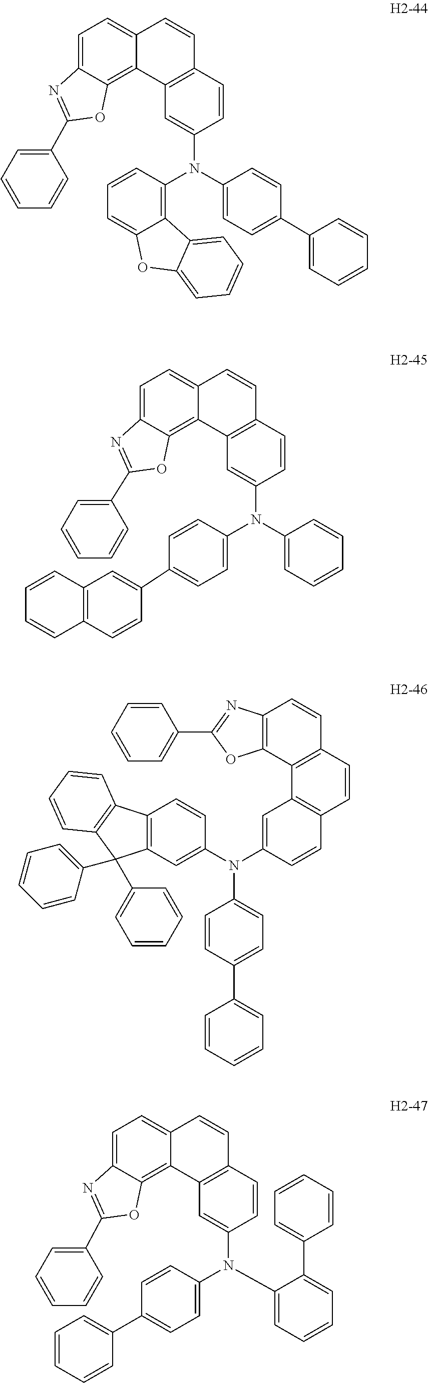 [SMILES: c1ccc(-c2ccc(N(c3ccc4ccc5ccc6nc(-c7ccccc7)oc6c5c4c3)c3cccc4oc5ccccc5c34)cc2)cc1 ; c1ccc(-c2nc3ccc4ccc5ccc(N(c6ccccc6)c6ccc(-c7ccc8ccccc8c7)cc6)cc5c4c3o2)cc1 ; c1ccc(-c2ccc(N(c3ccc4c(c3)C(c3ccccc3)(c3ccccc3)c3ccccc3-4)c3ccc4ccc5ccc6nc(-c7ccccc7)oc6c5c4c3)cc2)cc1 ; c1ccc(-c2ccc(N(c3ccc4ccc5ccc6nc(-c7ccccc7)oc6c5c4c3)c3ccccc3-c3ccccc3)cc2)cc1]

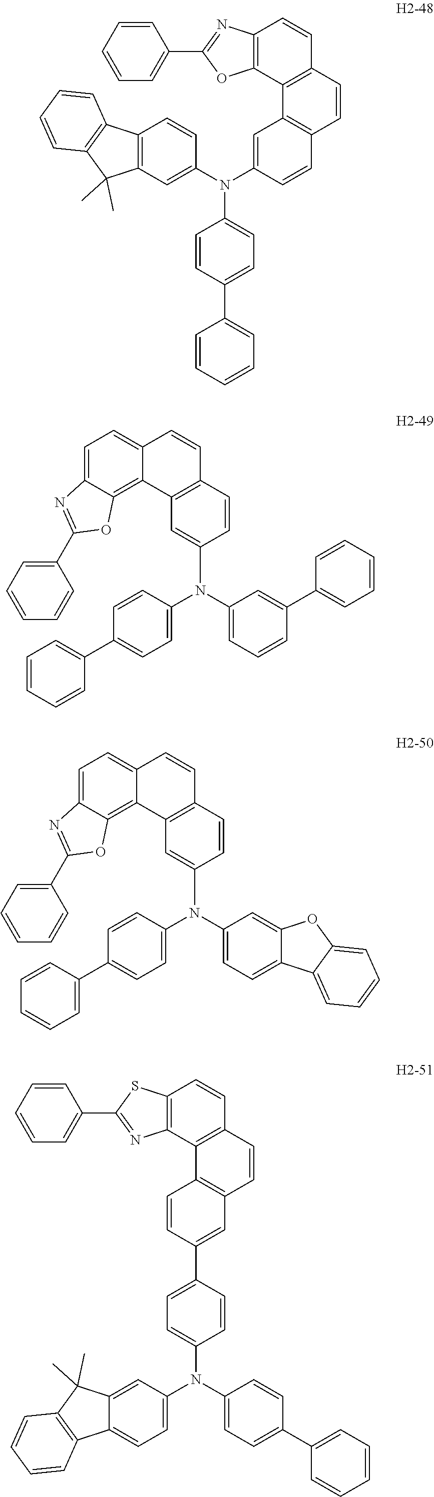 [SMILES: CC1(C)c2ccccc2-c2ccc(N(c3ccc(-c4ccccc4)cc3)c3ccc4ccc5ccc6nc(-c7ccccc7)oc6c5c4c3)cc21 ; c1ccc(-c2ccc(N(c3cccc(-c4ccccc4)c3)c3ccc4ccc5ccc6nc(-c7ccccc7)oc6c5c4c3)cc2)cc1 ; c1ccc(-c2ccc(N(c3ccc4c(c3)oc3ccccc34)c3ccc4ccc5ccc6nc(-c7ccccc7)oc6c5c4c3)cc2)cc1 ; CC1(C)c2ccccc2-c2ccc(N(c3ccc(-c4ccccc4)cc3)c3ccc(-c4ccc5c(ccc6ccc7sc(-c8ccccc8)nc7c65)c4)cc3)cc21]

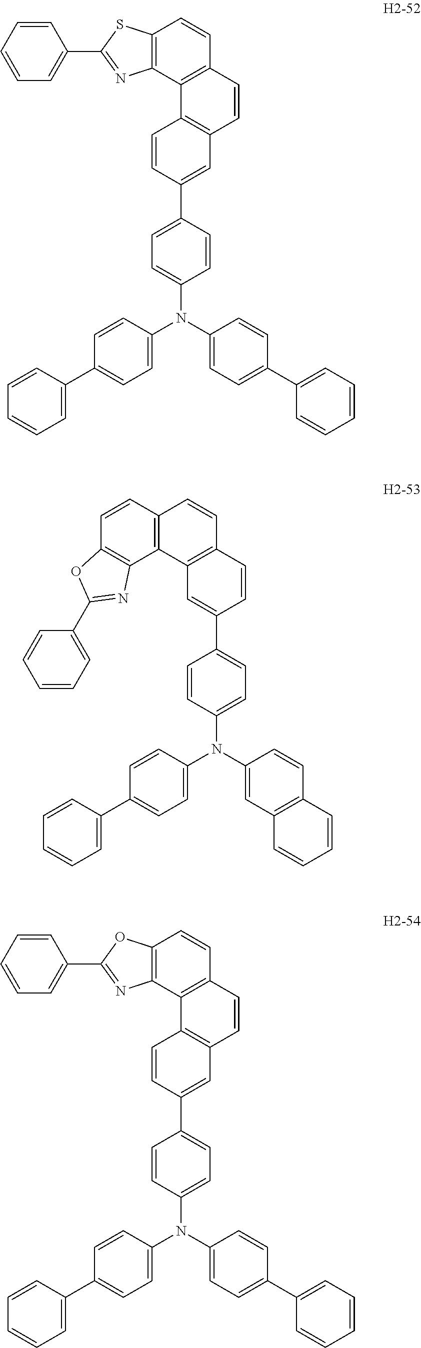 [SMILES: c1ccc(-c2ccc(N(c3ccc(-c4ccccc4)cc3)c3ccc(-c4ccc5c(ccc6ccc7sc(-c8ccccc8)nc7c65)c4)cc3)cc2)cc1 ; c1ccc(-c2ccc(N(c3ccc(-c4ccc5ccc6ccc7oc(-c8ccccc8)nc7c6c5c4)cc3)c3ccc4ccccc4c3)cc2)cc1 ; c1ccc(-c2ccc(N(c3ccc(-c4ccccc4)cc3)c3ccc(-c4ccc5c(ccc6ccc7oc(-c8ccccc8)nc7c65)c4)cc3)cc2)cc1]

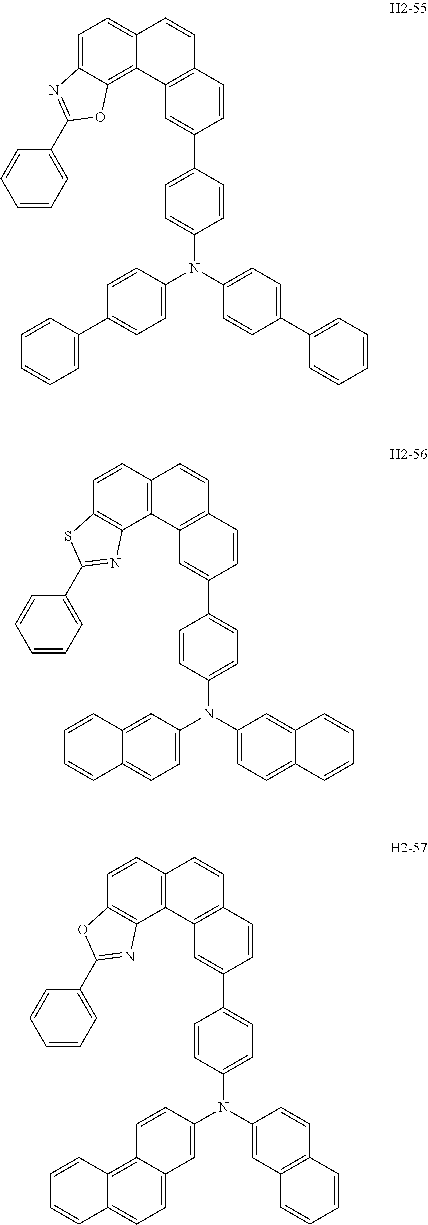 [SMILES: c1ccc(-c2ccc(N(c3ccc(-c4ccccc4)cc3)c3ccc(-c4ccc5ccc6ccc7nc(-c8ccccc8)oc7c6c5c4)cc3)cc2)cc1 ; c1ccc(-c2nc3c(ccc4ccc5ccc(-c6ccc(N(c7ccc8ccccc8c7)c7ccc8ccccc8c7)cc6)cc5c43)s2)cc1 ; c1ccc(-c2nc3c(ccc4ccc5ccc(-c6ccc(N(c7ccc8ccccc8c7)c7ccc8c(ccc9ccccc98)c7)cc6)cc5c43)o2)cc1]

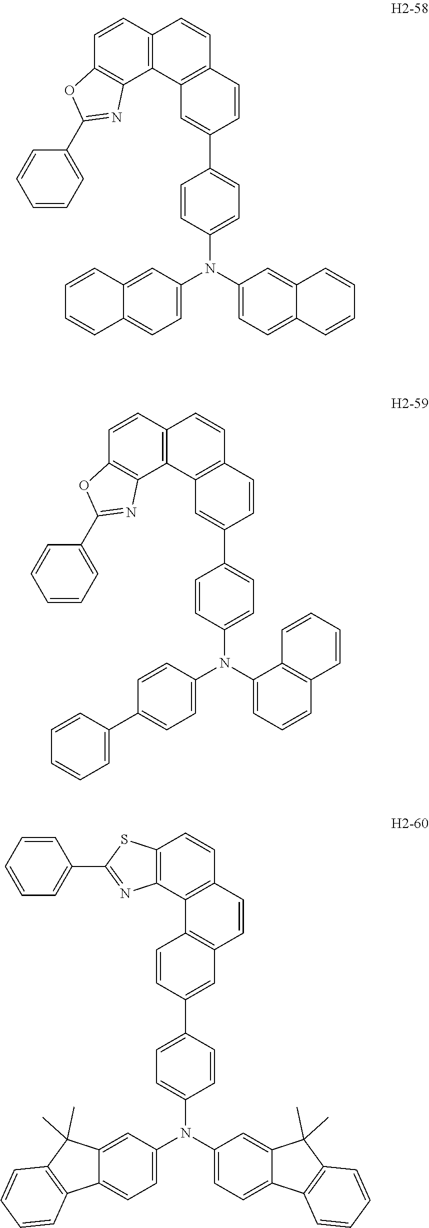 [SMILES: c1ccc(-c2nc3c(ccc4ccc5ccc(-c6ccc(N(c7ccc8ccccc8c7)c7ccc8ccccc8c7)cc6)cc5c43)o2)cc1 ; c1ccc(-c2ccc(N(c3ccc(-c4ccc5ccc6ccc7oc(-c8ccccc8)nc7c6c5c4)cc3)c3cccc4ccccc34)cc2)cc1 ; CC1(C)c2ccccc2-c2ccc(N(c3ccc(-c4ccc5c(ccc6ccc7sc(-c8ccccc8)nc7c65)c4)cc3)c3ccc4c(c3)C(C)(C)c3ccccc3-4)cc21]

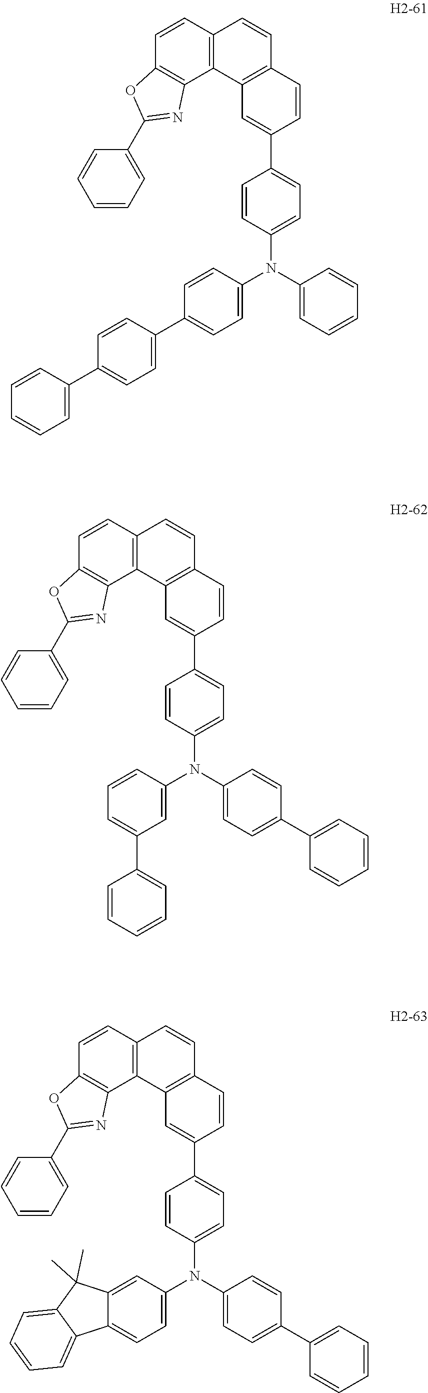 [SMILES: c1ccc(-c2ccc(-c3ccc(N(c4ccccc4)c4ccc(-c5ccc6ccc7ccc8oc(-c9ccccc9)nc8c7c6c5)cc4)cc3)cc2)cc1 ; c1ccc(-c2ccc(N(c3ccc(-c4ccc5ccc6ccc7oc(-c8ccccc8)nc7c6c5c4)cc3)c3cccc(-c4ccccc4)c3)cc2)cc1 ; CC1(C)c2ccccc2-c2ccc(N(c3ccc(-c4ccccc4)cc3)c3ccc(-c4ccc5ccc6ccc7oc(-c8ccccc8)nc7c6c5c4)cc3)cc21]

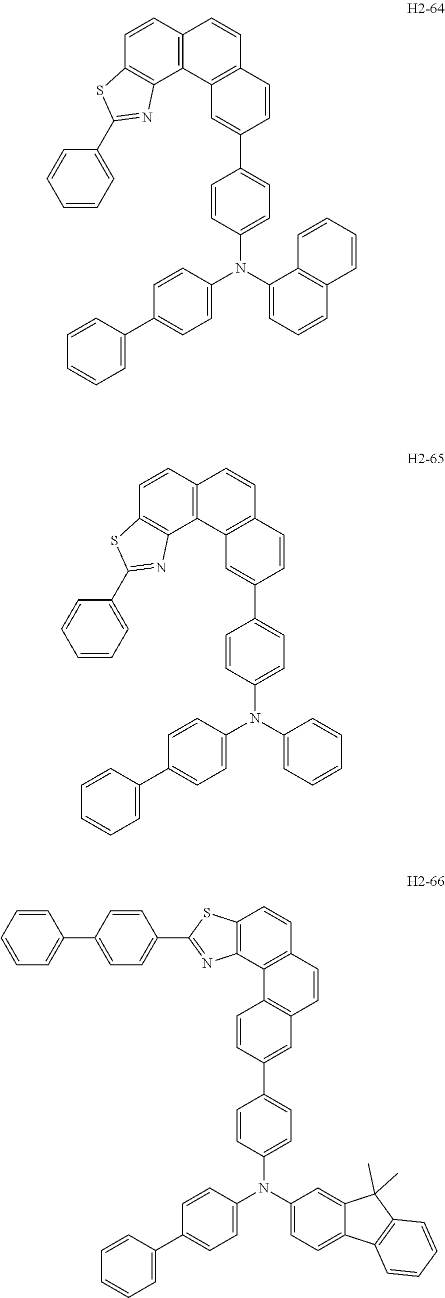 [SMILES: c1ccc(-c2ccc(N(c3ccc(-c4ccc5ccc6ccc7sc(-c8ccccc8)nc7c6c5c4)cc3)c3cccc4ccccc34)cc2)cc1 ; c1ccc(-c2ccc(N(c3ccccc3)c3ccc(-c4ccc5ccc6ccc7sc(-c8ccccc8)nc7c6c5c4)cc3)cc2)cc1 ; CC1(C)c2ccccc2-c2ccc(N(c3ccc(-c4ccccc4)cc3)c3ccc(-c4ccc5c(ccc6ccc7sc(-c8ccc(-c9ccccc9)cc8)nc7c65)c4)cc3)cc21]

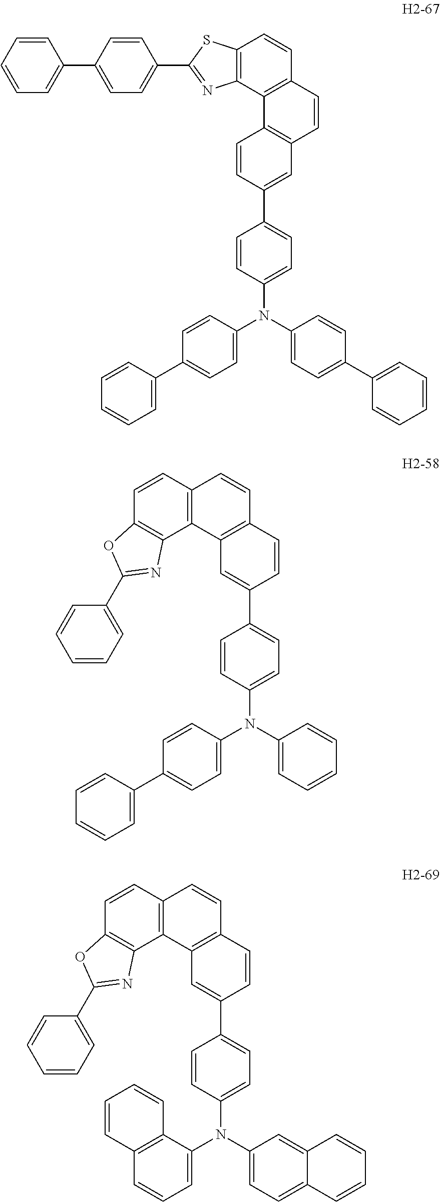 [SMILES: c1ccc(-c2ccc(-c3nc4c(ccc5ccc6cc(-c7ccc(N(c8ccc(-c9ccccc9)cc8)c8ccc(-c9ccccc9)cc8)cc7)ccc6c54)s3)cc2)cc1 ; c1ccc(-c2ccc(N(c3ccccc3)c3ccc(-c4ccc5ccc6ccc7oc(-c8ccccc8)nc7c6c5c4)cc3)cc2)cc1 ; c1ccc(-c2nc3c(ccc4ccc5ccc(-c6ccc(N(c7ccc8ccccc8c7)c7cccc8ccccc78)cc6)cc5c43)o2)cc1]

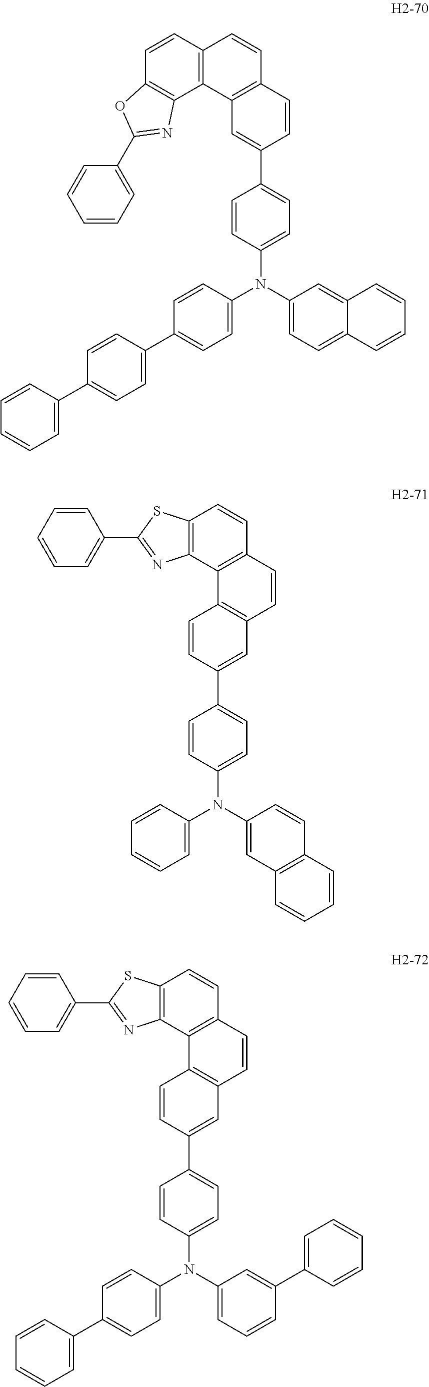 [SMILES: c1ccc(-c2ccc(-c3ccc(N(c4ccc(-c5ccc6ccc7ccc8oc(-c9ccccc9)nc8c7c6c5)cc4)c4ccc5ccccc5c4)cc3)cc2)cc1 ; c1ccc(-c2nc3c(ccc4ccc5cc(-c6ccc(N(c7ccccc7)c7ccc8ccccc8c7)cc6)ccc5c43)s2)cc1 ; c1ccc(-c2ccc(N(c3ccc(-c4ccc5c(ccc6ccc7sc(-c8ccccc8)nc7c65)c4)cc3)c3cccc(-c4ccccc4)c3)cc2)cc1]

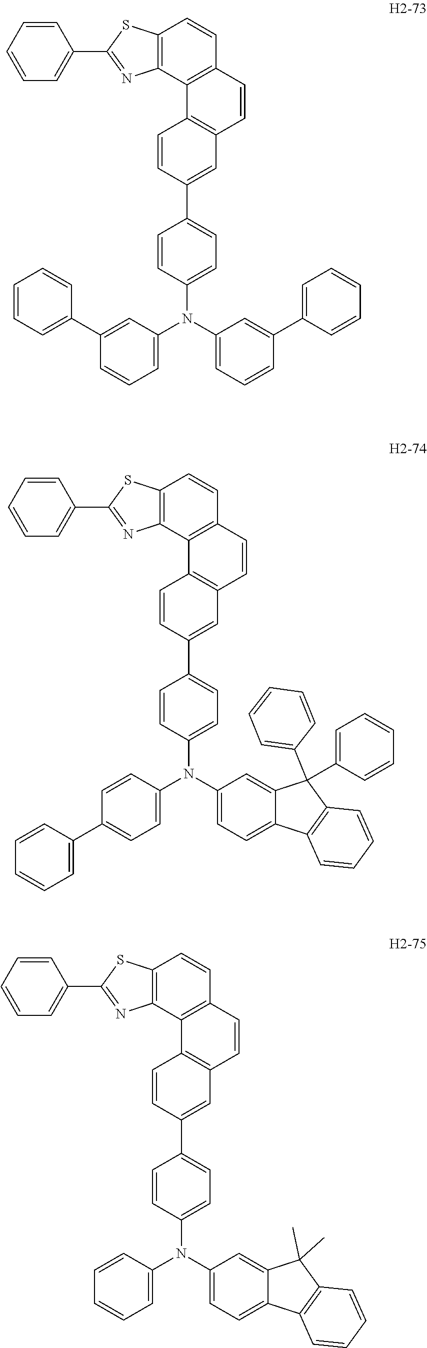 [SMILES: c1ccc(-c2cccc(N(c3ccc(-c4ccc5c(ccc6ccc7sc(-c8ccccc8)nc7c65)c4)cc3)c3cccc(-c4ccccc4)c3)c2)cc1 ; c1ccc(-c2ccc(N(c3ccc(-c4ccc5c(ccc6ccc7sc(-c8ccccc8)nc7c65)c4)cc3)c3ccc4c(c3)C(c3ccccc3)(c3ccccc3)c3ccccc3-4)cc2)cc1 ; CC1(C)c2ccccc2-c2ccc(N(c3ccccc3)c3ccc(-c4ccc5c(ccc6ccc7sc(-c8ccccc8)nc7c65)c4)cc3)cc21]

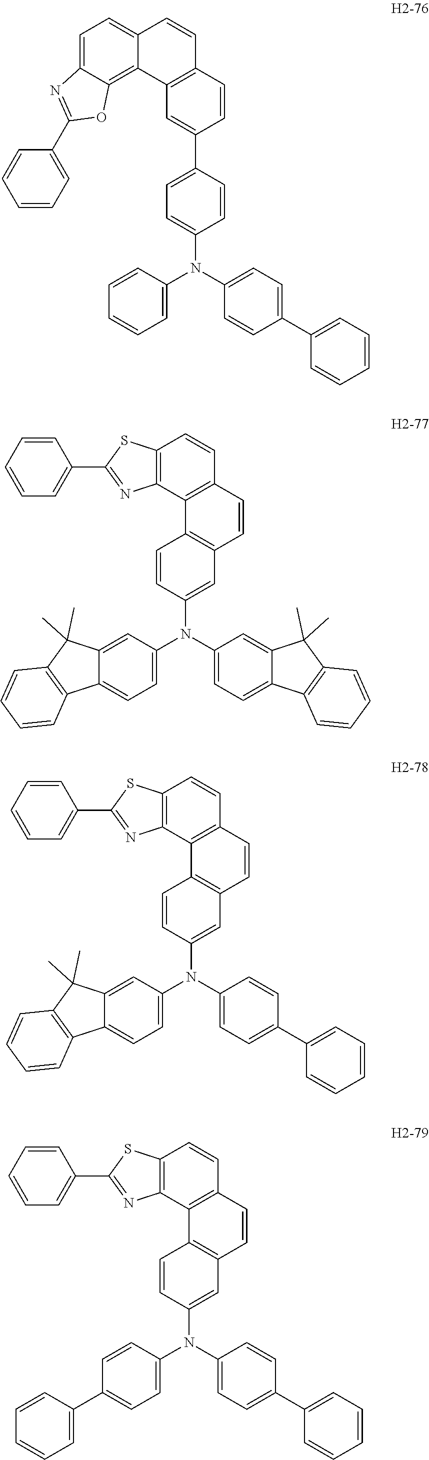 [SMILES: c1ccc(-c2ccc(N(c3ccccc3)c3ccc(-c4ccc5ccc6ccc7nc(-c8ccccc8)oc7c6c5c4)cc3)cc2)cc1 ; CC1(C)c2ccccc2-c2ccc(N(c3ccc4c(c3)C(C)(C)c3ccccc3-4)c3ccc4c(ccc5ccc6sc(-c7ccccc7)nc6c54)c3)cc21 ; CC1(C)c2ccccc2-c2ccc(N(c3ccc(-c4ccccc4)cc3)c3ccc4c(ccc5ccc6sc(-c7ccccc7)nc6c54)c3)cc21 ; c1ccc(-c2ccc(N(c3ccc(-c4ccccc4)cc3)c3ccc4c(ccc5ccc6sc(-c7ccccc7)nc6c54)c3)cc2)cc1]

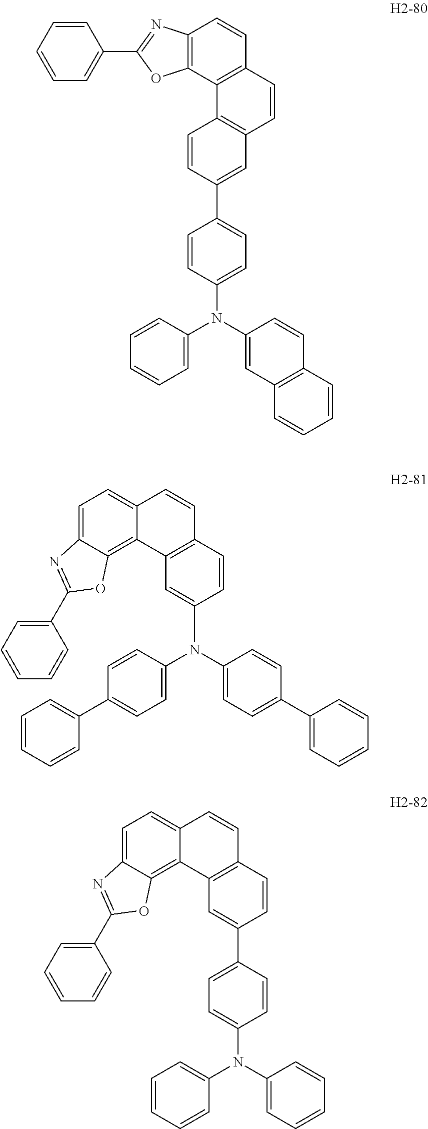 [SMILES: c1ccc(-c2nc3ccc4ccc5cc(-c6ccc(N(c7ccccc7)c7ccc8ccccc8c7)cc6)ccc5c4c3o2)cc1 ; c1ccc(-c2ccc(N(c3ccc(-c4ccccc4)cc3)c3ccc4ccc5ccc6nc(-c7ccccc7)oc6c5c4c3)cc2)cc1 ; c1ccc(-c2nc3ccc4ccc5ccc(-c6ccc(N(c7ccccc7)c7ccccc7)cc6)cc5c4c3o2)cc1]

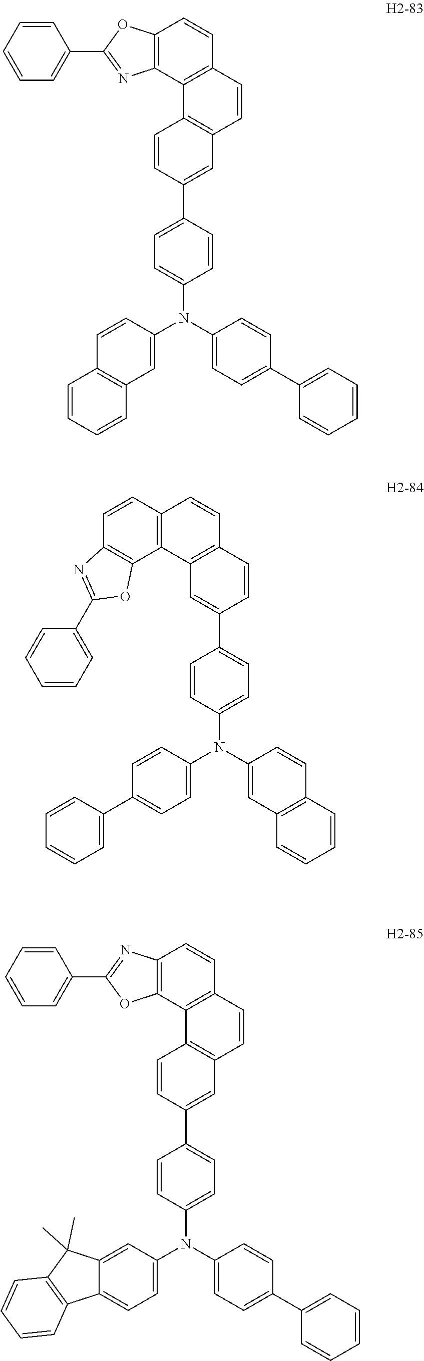 [SMILES: c1ccc(-c2ccc(N(c3ccc(-c4ccc5c(ccc6ccc7oc(-c8ccccc8)nc7c65)c4)cc3)c3ccc4ccccc4c3)cc2)cc1 ; c1ccc(-c2ccc(N(c3ccc(-c4ccc5ccc6ccc7nc(-c8ccccc8)oc7c6c5c4)cc3)c3ccc4ccccc4c3)cc2)cc1 ; CC1(C)c2ccccc2-c2ccc(N(c3ccc(-c4ccccc4)cc3)c3ccc(-c4ccc5c(ccc6ccc7nc(-c8ccccc8)oc7c65)c4)cc3)cc21]

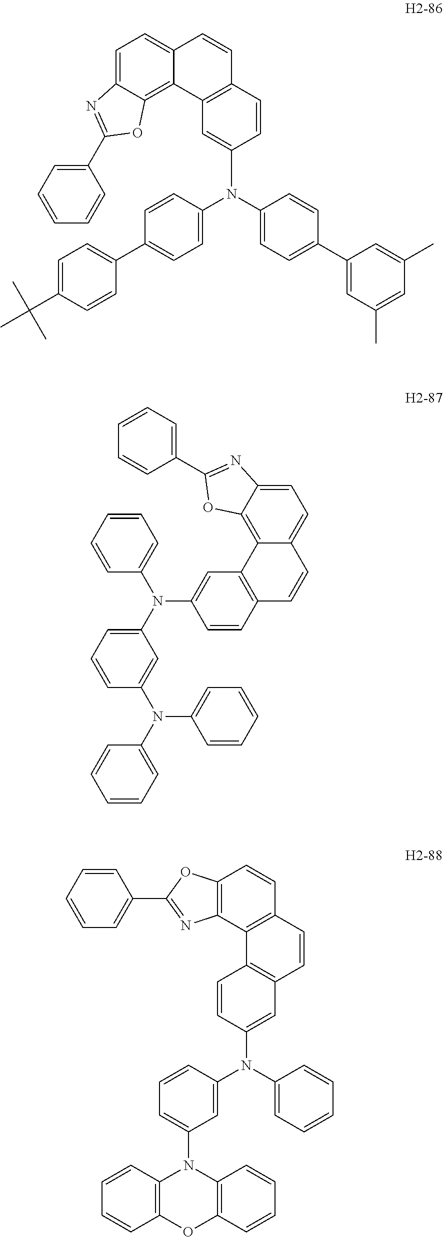 [SMILES: Cc1cc(C)cc(-c2ccc(N(c3ccc(-c4ccc(C(C)(C)C)cc4)cc3)c3ccc4ccc5ccc6nc(-c7ccccc7)oc6c5c4c3)cc2)c1 ; c1ccc(-c2nc3ccc4ccc5ccc(N(c6ccccc6)c6cccc(N(c7ccccc7)c7ccccc7)c6)cc5c4c3o2)cc1 ; c1ccc(-c2nc3c(ccc4ccc5cc(N(c6ccccc6)c6cccc(N7c8ccccc8Oc8ccccc87)c6)ccc5c43)o2)cc1]

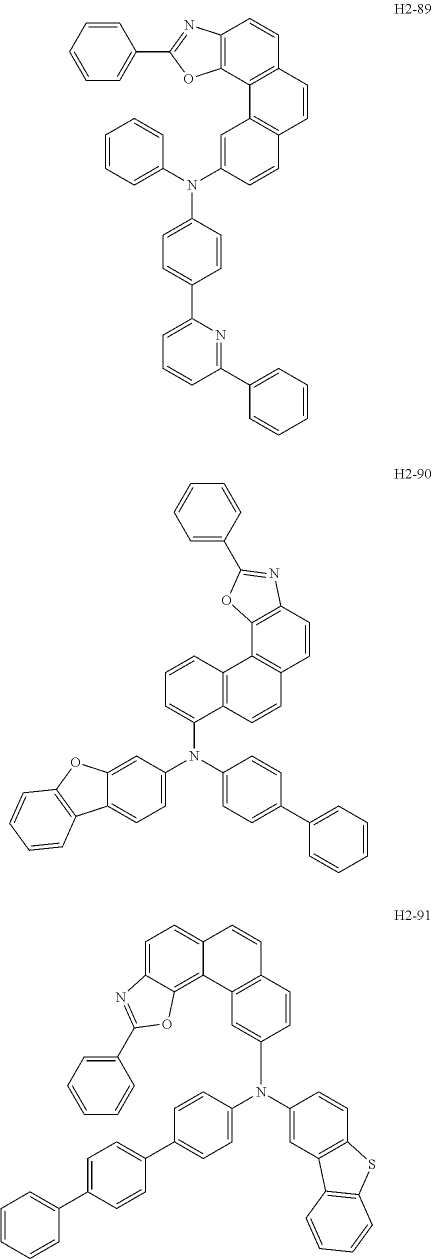 [SMILES: c1ccc(-c2cccc(-c3ccc(N(c4ccccc4)c4ccc5ccc6ccc7nc(-c8ccccc8)oc7c6c5c4)cc3)n2)cc1 ; c1ccc(-c2ccc(N(c3ccc4c(c3)oc3ccccc34)c3cccc4c3ccc3ccc5nc(-c6ccccc6)oc5c34)cc2)cc1 ; c1ccc(-c2ccc(-c3ccc(N(c4ccc5sc6ccccc6c5c4)c4ccc5ccc6ccc7nc(-c8ccccc8)oc7c6c5c4)cc3)cc2)cc1]

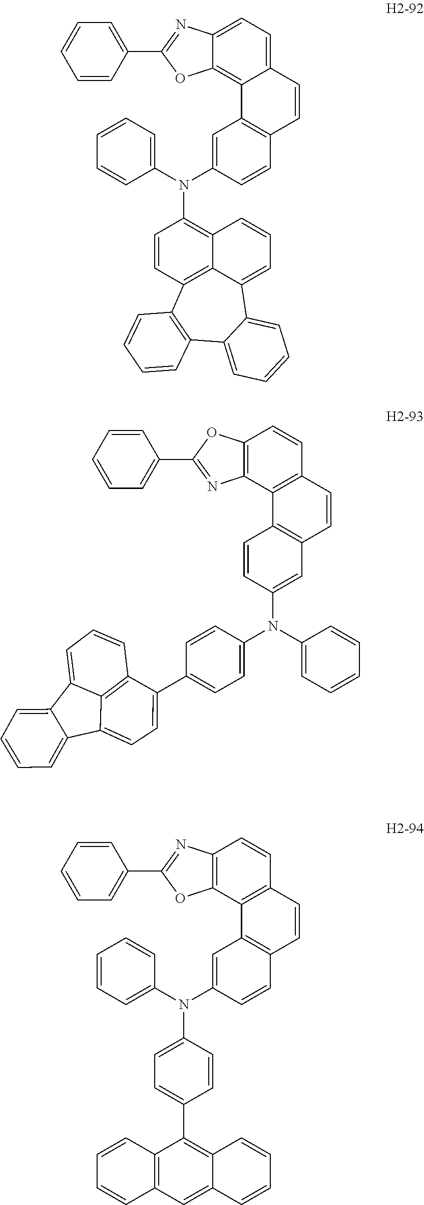

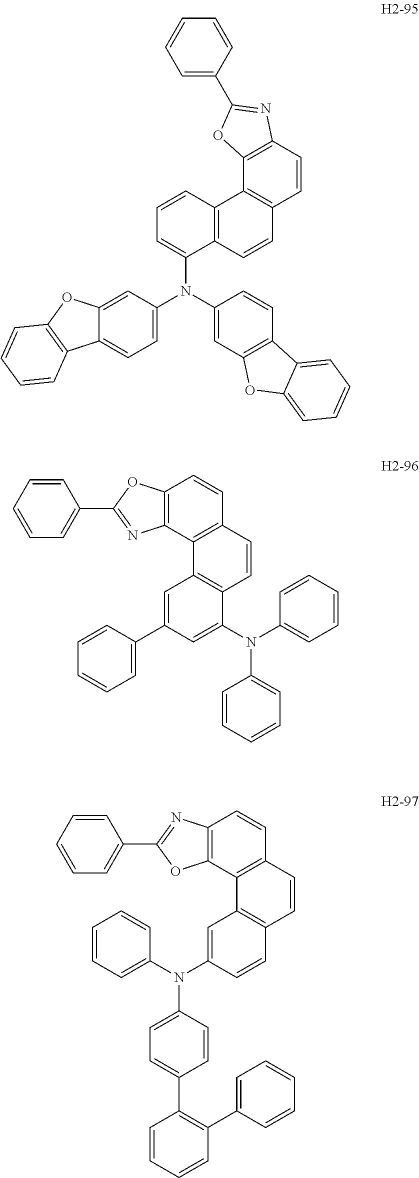 [SMILES: c1ccc(-c2nc3ccc4ccc5c(N(c6ccc7c(c6)oc6ccccc67)c6ccc7c(c6)oc6ccccc67)cccc5c4c3o2)cc1 ; c1ccc(-c2cc(N(c3ccccc3)c3ccccc3)c3ccc4ccc5oc(-c6ccccc6)nc5c4c3c2)cc1 ; c1ccc(-c2nc3ccc4ccc5ccc(N(c6ccccc6)c6ccc(-c7ccccc7-c7ccccc7)cc6)cc5c4c3o2)cc1]

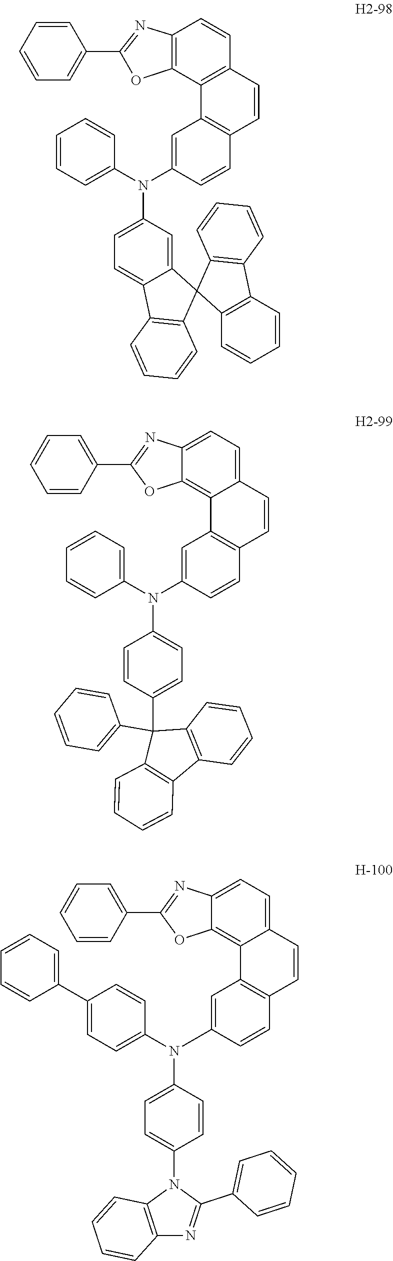

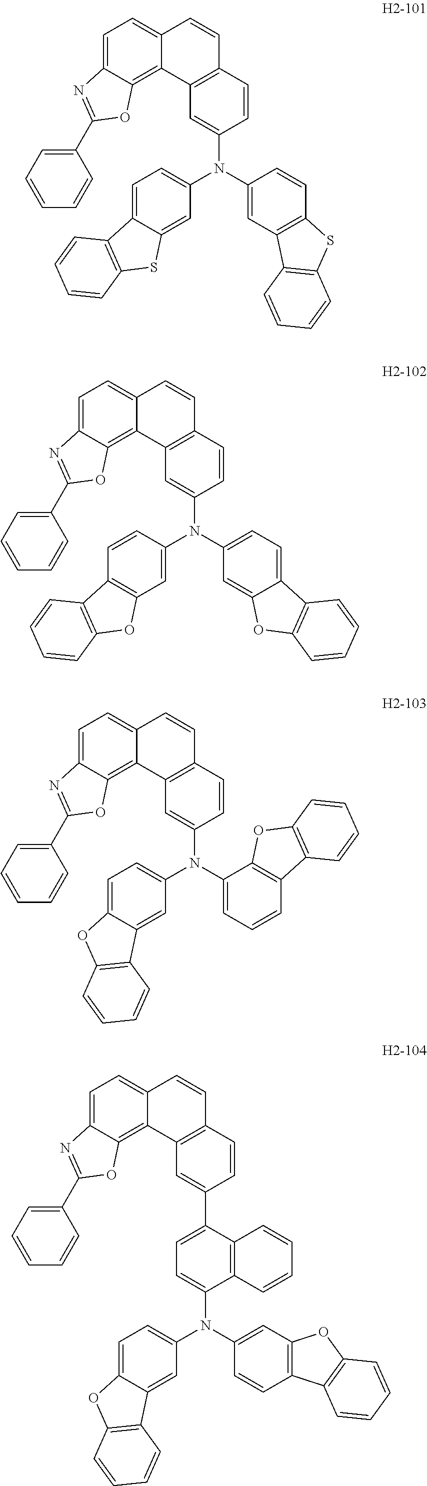 [SMILES: c1ccc(-c2nc3ccc4ccc5ccc(N(c6ccc7c(c6)sc6ccccc67)c6ccc7sc8ccccc8c7c6)cc5c4c3o2)cc1 ; c1ccc(-c2nc3ccc4ccc5ccc(N(c6ccc7c(c6)oc6ccccc67)c6ccc7c(c6)oc6ccccc67)cc5c4c3o2)cc1 ; c1ccc(-c2nc3ccc4ccc5ccc(N(c6ccc7oc8ccccc8c7c6)c6cccc7c6oc6ccccc67)cc5c4c3o2)cc1 ; c1ccc(-c2nc3ccc4ccc5ccc(-c6ccc(N(c7ccc8c(c7)oc7ccccc78)c7ccc8oc9ccccc9c8c7)c7ccccc67)cc5c4c3o2)cc1]

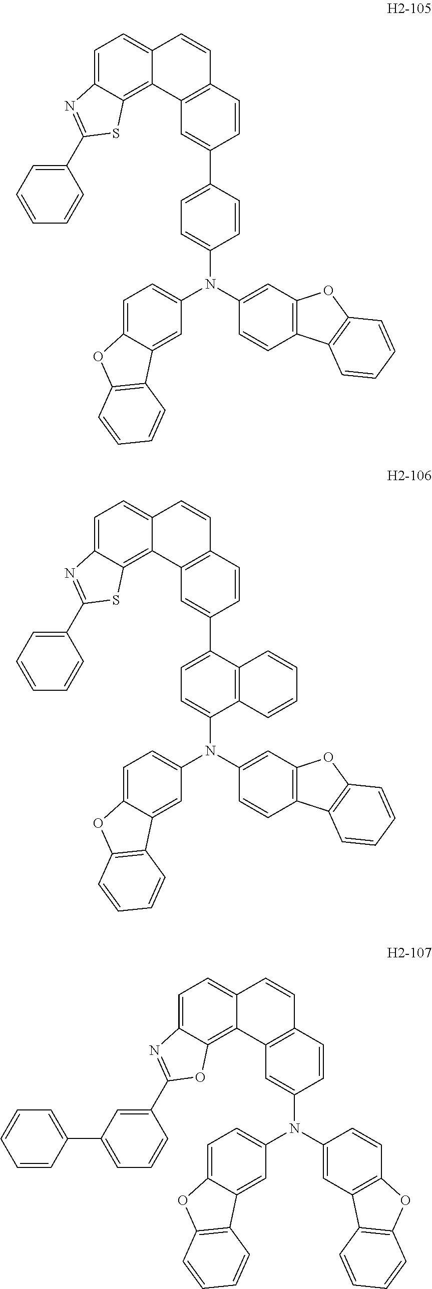 [SMILES: c1ccc(-c2nc3ccc4ccc5ccc(-c6ccc(N(c7ccc8c(c7)oc7ccccc78)c7ccc8oc9ccccc9c8c7)cc6)cc5c4c3s2)cc1 ; c1ccc(-c2nc3ccc4ccc5ccc(-c6ccc(N(c7ccc8c(c7)oc7ccccc78)c7ccc8oc9ccccc9c8c7)c7ccccc67)cc5c4c3s2)cc1 ; c1ccc(-c2cccc(-c3nc4ccc5ccc6ccc(N(c7ccc8oc9ccccc9c8c7)c7ccc8oc9ccccc9c8c7)cc6c5c4o3)c2)cc1]

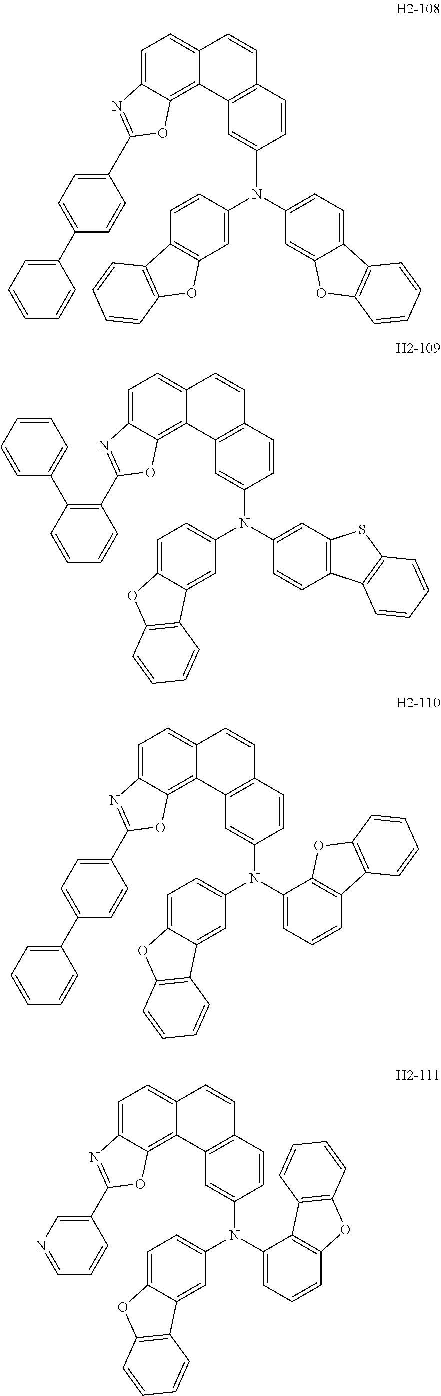 [SMILES: c1ccc(-c2ccc(-c3nc4ccc5ccc6ccc(N(c7ccc8c(c7)oc7ccccc78)c7ccc8c(c7)oc7ccccc78)cc6c5c4o3)cc2)cc1 ; c1ccc(-c2ccccc2-c2nc3ccc4ccc5ccc(N(c6ccc7c(c6)sc6ccccc67)c6ccc7oc8ccccc8c7c6)cc5c4c3o2)cc1 ; c1ccc(-c2ccc(-c3nc4ccc5ccc6ccc(N(c7ccc8oc9ccccc9c8c7)c7cccc8c7oc7ccccc78)cc6c5c4o3)cc2)cc1 ; c1cncc(-c2nc3ccc4ccc5ccc(N(c6ccc7oc8ccccc8c7c6)c6cccc7oc8ccccc8c67)cc5c4c3o2)c1]

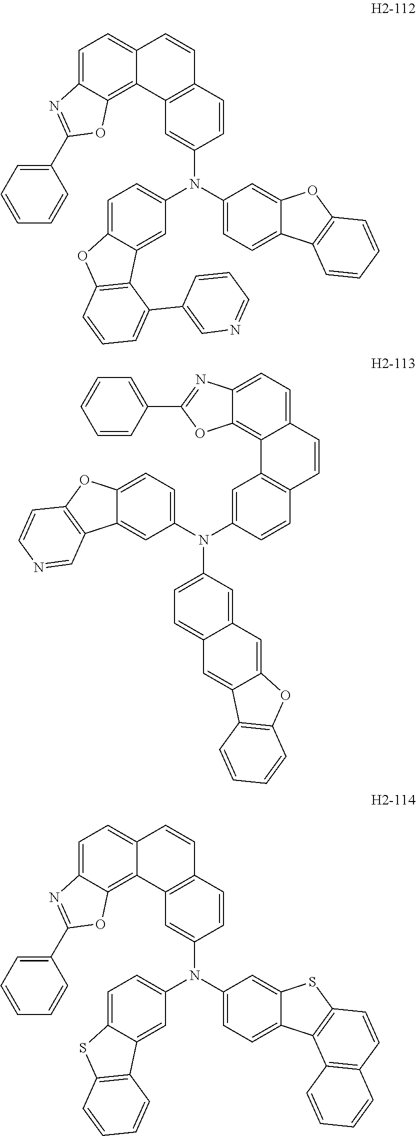

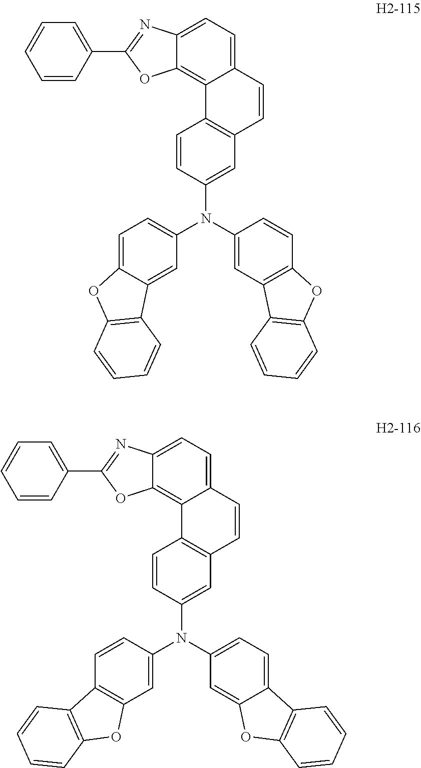 [SMILES: c1ccc(-c2nc3ccc4ccc5cc(N(c6ccc7oc8ccccc8c7c6)c6ccc7oc8ccccc8c7c6)ccc5c4c3o2)cc1 ; c1ccc(-c2nc3ccc4ccc5cc(N(c6ccc7c(c6)oc6ccccc67)c6ccc7c(c6)oc6ccccc67)ccc5c4c3o2)cc1]

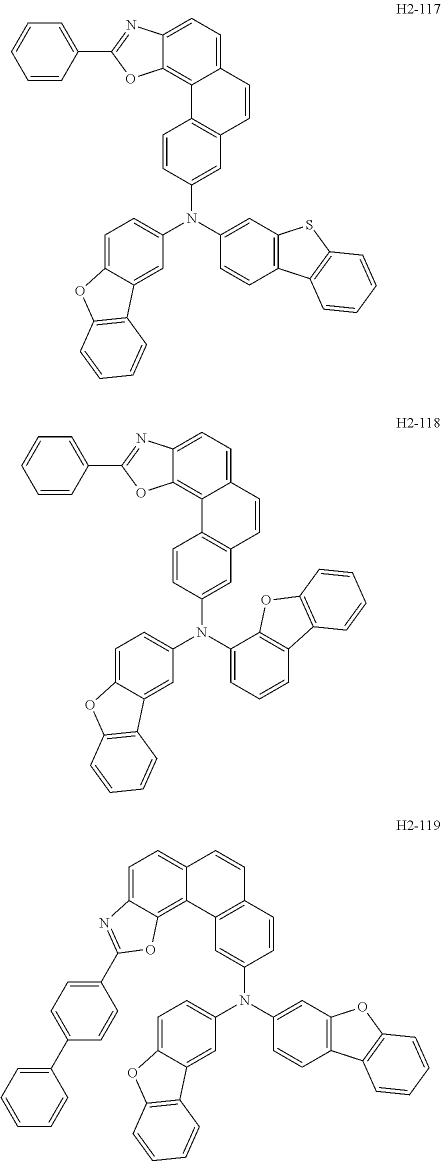 [SMILES: c1ccc(-c2nc3ccc4ccc5cc(N(c6ccc7c(c6)sc6ccccc67)c6ccc7oc8ccccc8c7c6)ccc5c4c3o2)cc1 ; c1ccc(-c2nc3ccc4ccc5cc(N(c6ccc7oc8ccccc8c7c6)c6cccc7c6oc6ccccc67)ccc5c4c3o2)cc1 ; c1ccc(-c2ccc(-c3nc4ccc5ccc6ccc(N(c7ccc8c(c7)oc7ccccc78)c7ccc8oc9ccccc9c8c7)cc6c5c4o3)cc2)cc1]

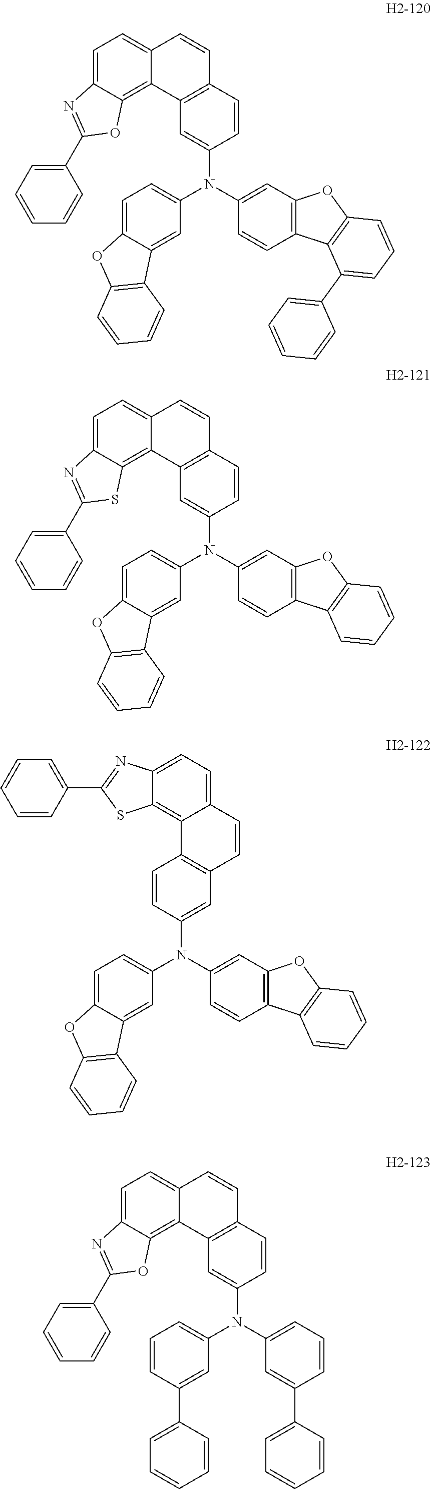 [SMILES: c1ccc(-c2nc3ccc4ccc5ccc(N(c6ccc7c(c6)oc6cccc(-c8ccccc8)c67)c6ccc7oc8ccccc8c7c6)cc5c4c3o2)cc1 ; c1ccc(-c2nc3ccc4ccc5ccc(N(c6ccc7c(c6)oc6ccccc67)c6ccc7oc8ccccc8c7c6)cc5c4c3s2)cc1 ; c1ccc(-c2nc3ccc4ccc5cc(N(c6ccc7c(c6)oc6ccccc67)c6ccc7oc8ccccc8c7c6)ccc5c4c3s2)cc1 ; c1ccc(-c2cccc(N(c3cccc(-c4ccccc4)c3)c3ccc4ccc5ccc6nc(-c7ccccc7)oc6c5c4c3)c2)cc1]

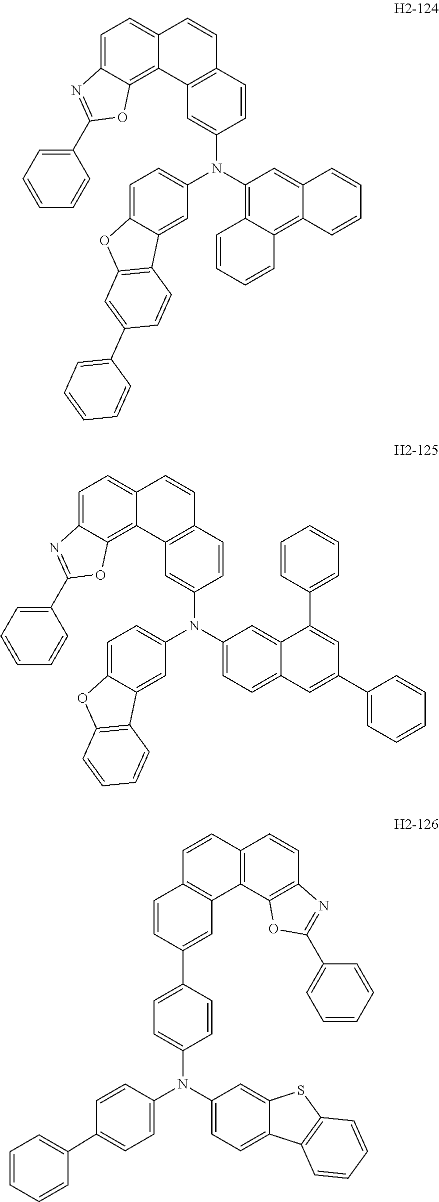 [SMILES: c1ccc(-c2ccc3c(c2)oc2ccc(N(c4ccc5ccc6ccc7nc(-c8ccccc8)oc7c6c5c4)c4cc5ccccc5c5ccccc45)cc23)cc1 ; c1ccc(-c2cc(-c3ccccc3)c3cc(N(c4ccc5oc6ccccc6c5c4)c4ccc5ccc6ccc7nc(-c8ccccc8)oc7c6c5c4)ccc3c2)cc1 ; Cc1c(/N=C(\O)c2ccccc2)ccc2ccc3ccc(-c4ccc(N(c5ccc(-c6ccccc6)cc5)c5ccc6c(c5)sc5ccccc56)cc4)cc3c12]

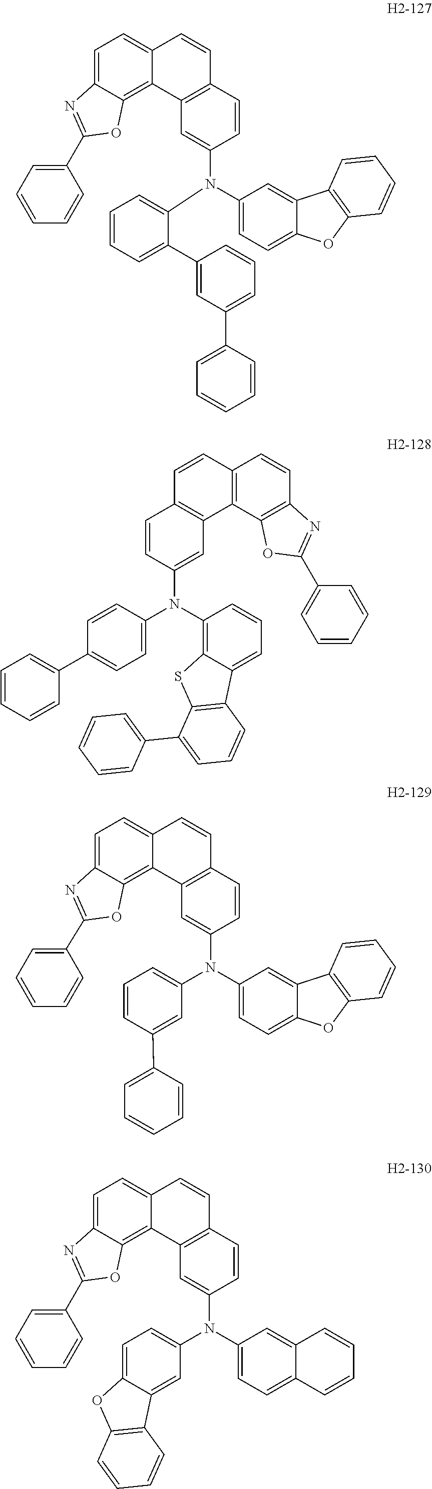 [SMILES: c1ccc(-c2cccc(-c3ccccc3N(c3ccc4oc5ccccc5c4c3)c3ccc4ccc5ccc6nc(-c7ccccc7)oc6c5c4c3)c2)cc1 ; c1ccc(-c2ccc(N(c3ccc4ccc5ccc6nc(-c7ccccc7)oc6c5c4c3)c3cccc4c3sc3c(-c5ccccc5)cccc34)cc2)cc1 ; c1ccc(-c2cccc(N(c3ccc4oc5ccccc5c4c3)c3ccc4ccc5ccc6nc(-c7ccccc7)oc6c5c4c3)c2)cc1 ; c1ccc(-c2nc3ccc4ccc5ccc(N(c6ccc7ccccc7c6)c6ccc7oc8ccccc8c7c6)cc5c4c3o2)cc1]

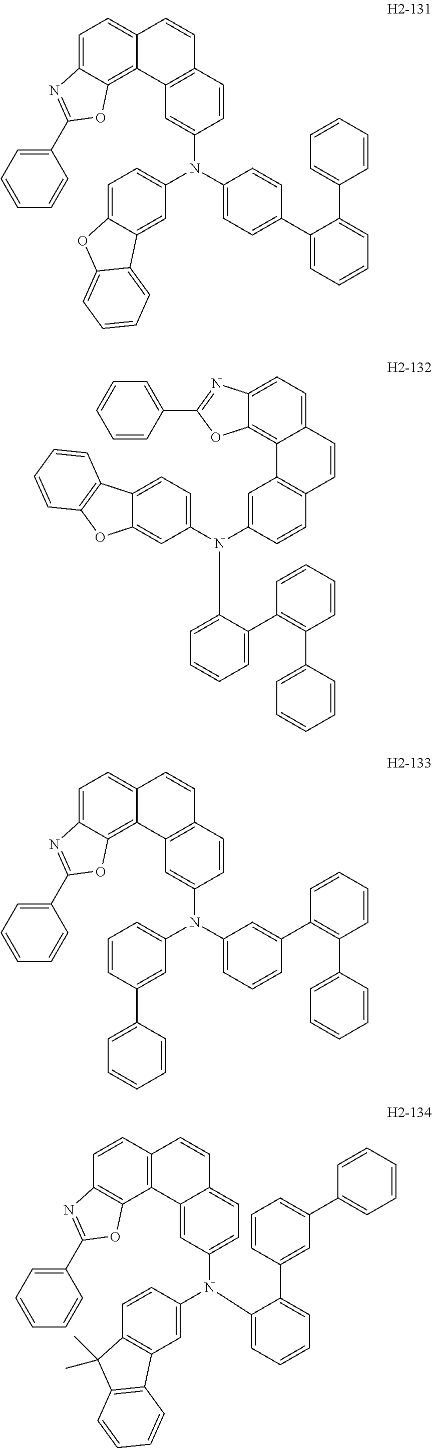 [SMILES: c1ccc(-c2nc3ccc4ccc5ccc(N(c6ccc(-c7ccccc7-c7ccccc7)cc6)c6ccc7oc8ccccc8c7c6)cc5c4c3o2)cc1 ; c1ccc(-c2nc3ccc4ccc5ccc(N(c6ccc7c(c6)oc6ccccc67)c6ccccc6-c6ccccc6-c6ccccc6)cc5c4c3o2)cc1 ; c1ccc(-c2cccc(N(c3cccc(-c4ccccc4-c4ccccc4)c3)c3ccc4ccc5ccc6nc(-c7ccccc7)oc6c5c4c3)c2)cc1 ; CC1(C)c2ccccc2-c2cc(N(c3ccc4ccc5ccc6nc(-c7ccccc7)oc6c5c4c3)c3ccccc3-c3cccc(-c4ccccc4)c3)ccc21]

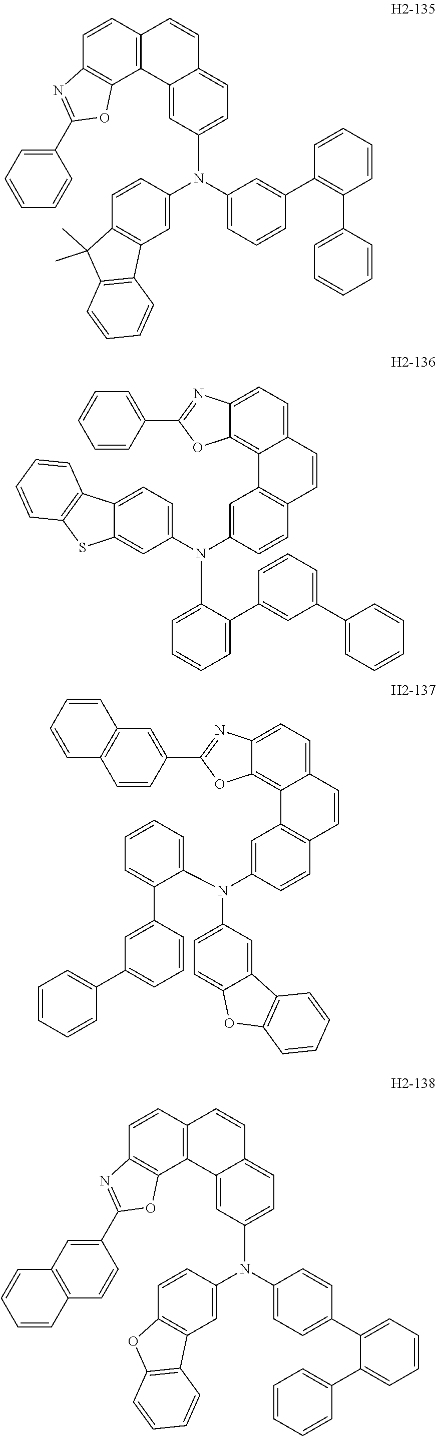 [SMILES: CC1(C)c2ccccc2-c2cc(N(c3cccc(-c4ccccc4-c4ccccc4)c3)c3ccc4ccc5ccc6nc(-c7ccccc7)oc6c5c4c3)ccc21 ; c1ccc(-c2cccc(-c3ccccc3N(c3ccc4c(c3)sc3ccccc34)c3ccc4ccc5ccc6nc(-c7ccccc7)oc6c5c4c3)c2)cc1 ; c1ccc(-c2cccc(-c3ccccc3N(c3ccc4oc5ccccc5c4c3)c3ccc4ccc5ccc6nc(-c7ccc8ccccc8c7)oc6c5c4c3)c2)cc1 ; c1ccc(-c2ccccc2-c2ccc(N(c3ccc4oc5ccccc5c4c3)c3ccc4ccc5ccc6nc(-c7ccc8ccccc8c7)oc6c5c4c3)cc2)cc1]

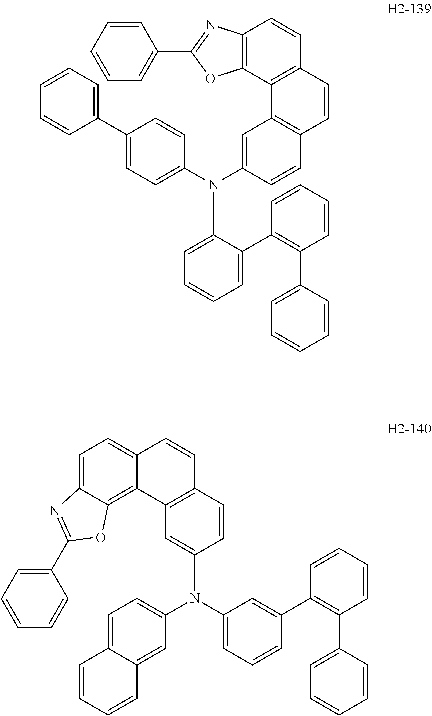 [SMILES: c1ccc(-c2ccc(N(c3ccc4ccc5ccc6nc(-c7ccccc7)oc6c5c4c3)c3ccccc3-c3ccccc3-c3ccccc3)cc2)cc1 ; c1ccc(-c2nc3ccc4ccc5ccc(N(c6cccc(-c7ccccc7-c7ccccc7)c6)c6ccc7ccccc7c6)cc5c4c3o2)cc1]

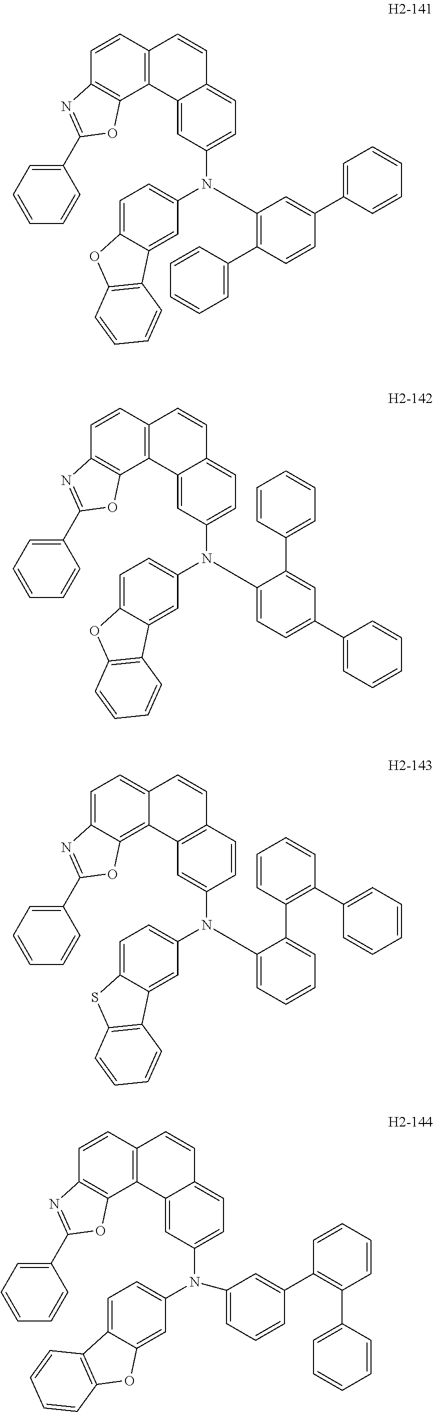 [SMILES: c1ccc(-c2ccc(-c3ccccc3)c(N(c3ccc4oc5ccccc5c4c3)c3ccc4ccc5ccc6nc(-c7ccccc7)oc6c5c4c3)c2)cc1 ; c1ccc(-c2ccc(N(c3ccc4oc5ccccc5c4c3)c3ccc4ccc5ccc6nc(-c7ccccc7)oc6c5c4c3)c(-c3ccccc3)c2)cc1 ; c1ccc(-c2nc3ccc4ccc5ccc(N(c6ccc7sc8ccccc8c7c6)c6ccccc6-c6ccccc6-c6ccccc6)cc5c4c3o2)cc1 ; c1ccc(-c2nc3ccc4ccc5ccc(N(c6cccc(-c7ccccc7-c7ccccc7)c6)c6ccc7c(c6)oc6ccccc67)cc5c4c3o2)cc1]

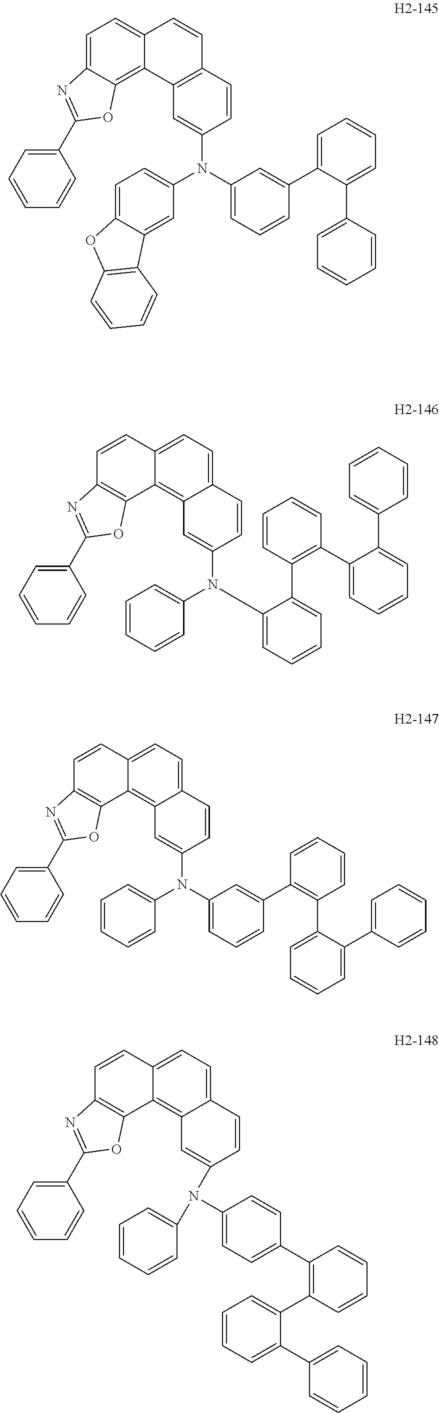 [SMILES: c1ccc(-c2nc3ccc4ccc5ccc(N(c6cccc(-c7ccccc7-c7ccccc7)c6)c6ccc7oc8ccccc8c7c6)cc5c4c3o2)cc1 ; c1ccc(-c2nc3ccc4ccc5ccc(N(c6ccccc6)c6ccccc6-c6ccccc6-c6ccccc6-c6ccccc6)cc5c4c3o2)cc1 ; c1ccc(-c2nc3ccc4ccc5ccc(N(c6ccccc6)c6cccc(-c7ccccc7-c7ccccc7-c7ccccc7)c6)cc5c4c3o2)cc1 ; c1ccc(-c2nc3ccc4ccc5ccc(N(c6ccccc6)c6ccc(-c7ccccc7-c7ccccc7-c7ccccc7)cc6)cc5c4c3o2)cc1]

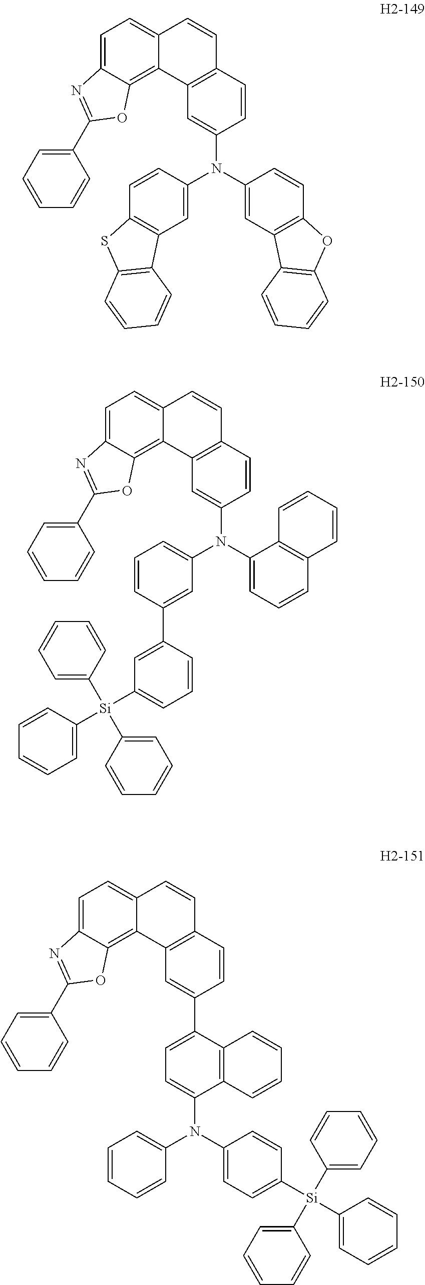 [SMILES: c1ccc(-c2nc3ccc4ccc5ccc(N(c6ccc7oc8ccccc8c7c6)c6ccc7sc8ccccc8c7c6)cc5c4c3o2)cc1 ; c1ccc(-c2nc3ccc4ccc5ccc(N(c6cccc(-c7cccc([Si](c8ccccc8)(c8ccccc8)c8ccccc8)c7)c6)c6cccc7ccccc67)cc5c4c3o2)cc1 ; c1ccc(-c2nc3ccc4ccc5ccc(-c6ccc(N(c7ccccc7)c7ccc([Si](c8ccccc8)(c8ccccc8)c8ccccc8)cc7)c7ccccc67)cc5c4c3o2)cc1]

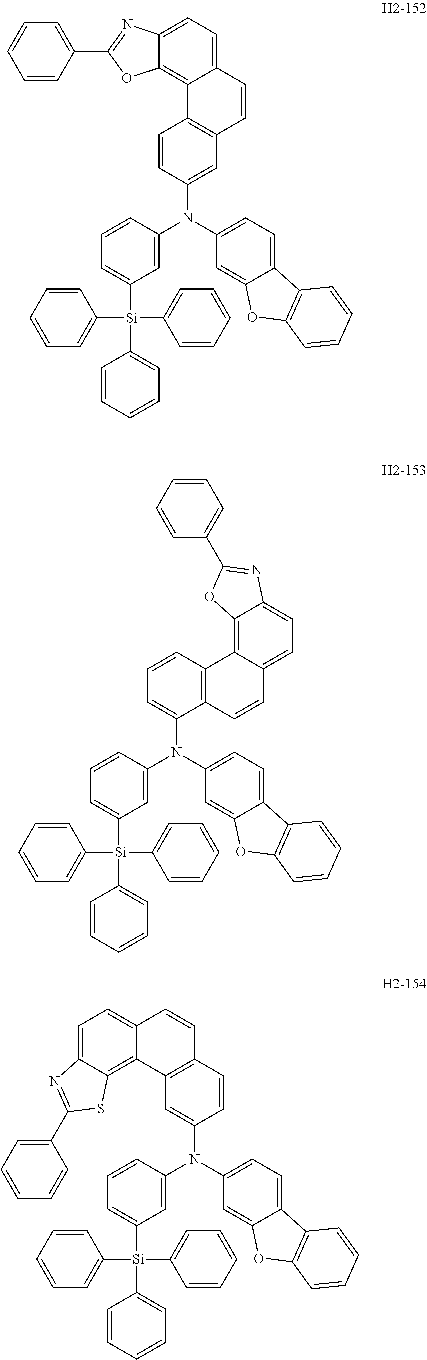 [SMILES: c1ccc(-c2nc3ccc4ccc5cc(N(c6cccc([Si](c7ccccc7)(c7ccccc7)c7ccccc7)c6)c6ccc7c(c6)oc6ccccc67)ccc5c4c3o2)cc1 ; c1ccc(-c2nc3ccc4ccc5c(N(c6cccc([Si](c7ccccc7)(c7ccccc7)c7ccccc7)c6)c6ccc7c(c6)oc6ccccc67)cccc5c4c3o2)cc1 ; c1ccc(-c2nc3ccc4ccc5ccc(N(c6cccc([Si](c7ccccc7)(c7ccccc7)c7ccccc7)c6)c6ccc7c(c6)oc6ccccc67)cc5c4c3s2)cc1]

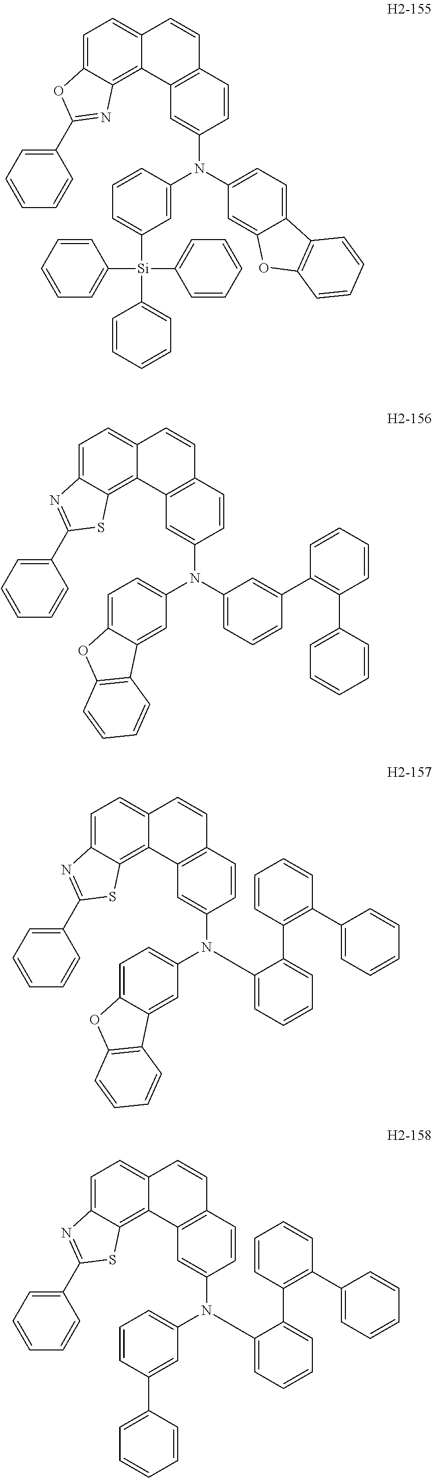 [SMILES: c1ccc(-c2nc3c(ccc4ccc5ccc(N(c6cccc([Si](c7ccccc7)(c7ccccc7)c7ccccc7)c6)c6ccc7c(c6)oc6ccccc67)cc5c43)o2)cc1 ; c1ccc(-c2nc3ccc4ccc5ccc(N(c6cccc(-c7ccccc7-c7ccccc7)c6)c6ccc7oc8ccccc8c7c6)cc5c4c3s2)cc1 ; c1ccc(-c2nc3ccc4ccc5ccc(N(c6ccc7oc8ccccc8c7c6)c6ccccc6-c6ccccc6-c6ccccc6)cc5c4c3s2)cc1 ; c1ccc(-c2cccc(N(c3ccc4ccc5ccc6nc(-c7ccccc7)sc6c5c4c3)c3ccccc3-c3ccccc3-c3ccccc3)c2)cc1]

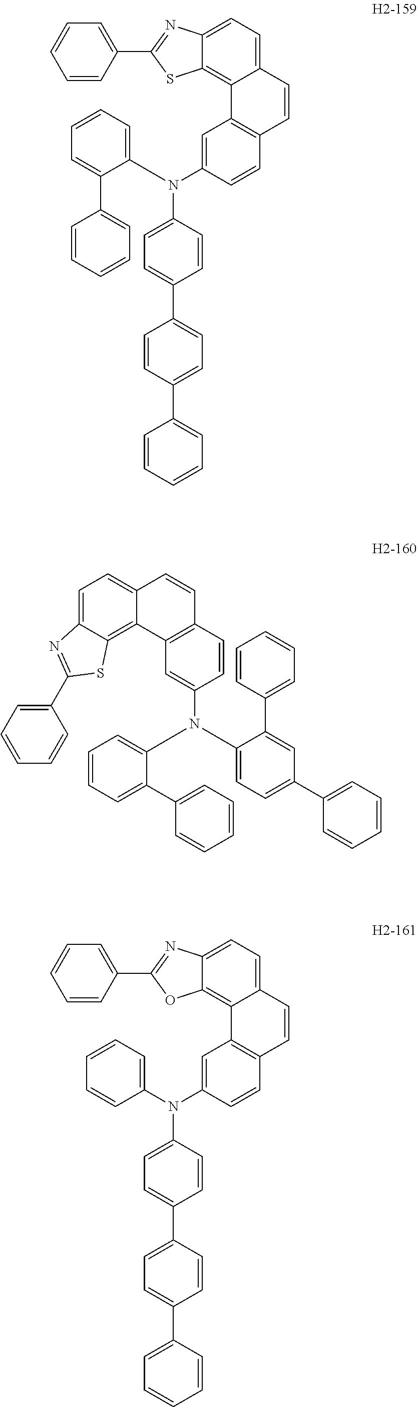 [SMILES: c1ccc(-c2ccc(-c3ccc(N(c4ccc5ccc6ccc7nc(-c8ccccc8)sc7c6c5c4)c4ccccc4-c4ccccc4)cc3)cc2)cc1 ; c1ccc(-c2ccc(N(c3ccc4ccc5ccc6nc(-c7ccccc7)sc6c5c4c3)c3ccccc3-c3ccccc3)c(-c3ccccc3)c2)cc1 ; c1ccc(-c2ccc(-c3ccc(N(c4ccccc4)c4ccc5ccc6ccc7nc(-c8ccccc8)oc7c6c5c4)cc3)cc2)cc1]

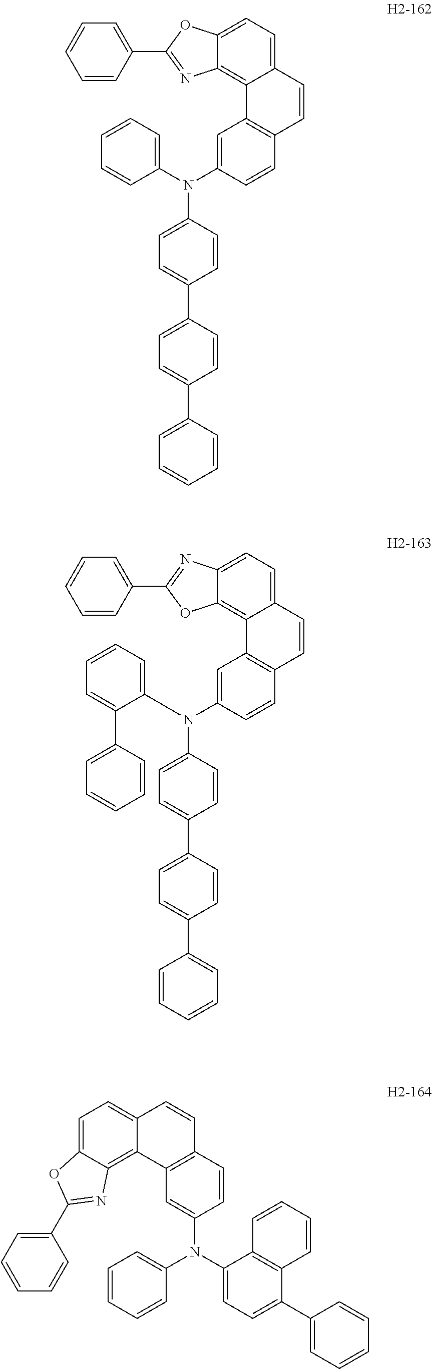 [SMILES: c1ccc(-c2ccc(-c3ccc(N(c4ccccc4)c4ccc5ccc6ccc7oc(-c8ccccc8)nc7c6c5c4)cc3)cc2)cc1 ; c1ccc(-c2ccc(-c3ccc(N(c4ccc5ccc6ccc7nc(-c8ccccc8)oc7c6c5c4)c4ccccc4-c4ccccc4)cc3)cc2)cc1 ; c1ccc(-c2nc3c(ccc4ccc5ccc(N(c6ccccc6)c6ccc(-c7ccccc7)c7ccccc67)cc5c43)o2)cc1]

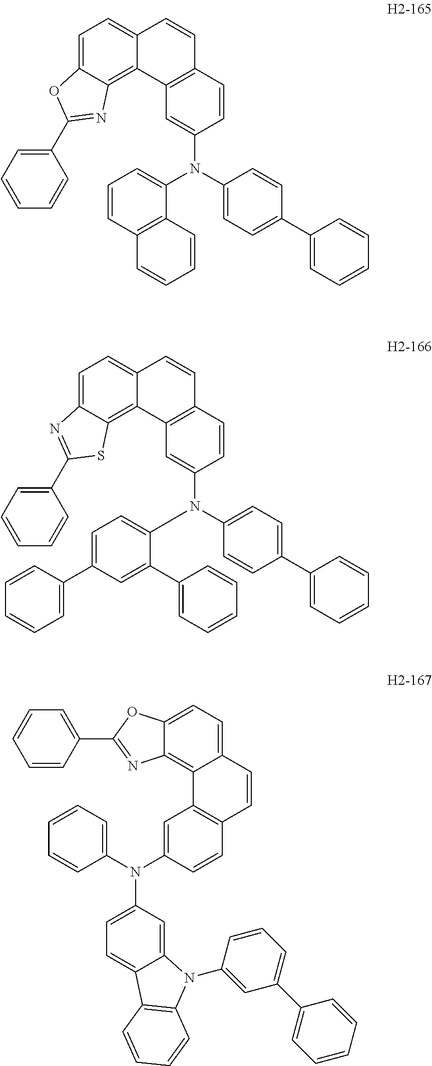 [SMILES: c1ccc(-c2ccc(N(c3ccc4ccc5ccc6oc(-c7ccccc7)nc6c5c4c3)c3cccc4ccccc34)cc2)cc1 ; c1ccc(-c2ccc(N(c3ccc4ccc5ccc6nc(-c7ccccc7)sc6c5c4c3)c3ccc(-c4ccccc4)cc3-c3ccccc3)cc2)cc1 ; c1ccc(-c2cccc(-n3c4ccccc4c4ccc(N(c5ccccc5)c5ccc6ccc7ccc8oc(-c9ccccc9)nc8c7c6c5)cc43)c2)cc1]

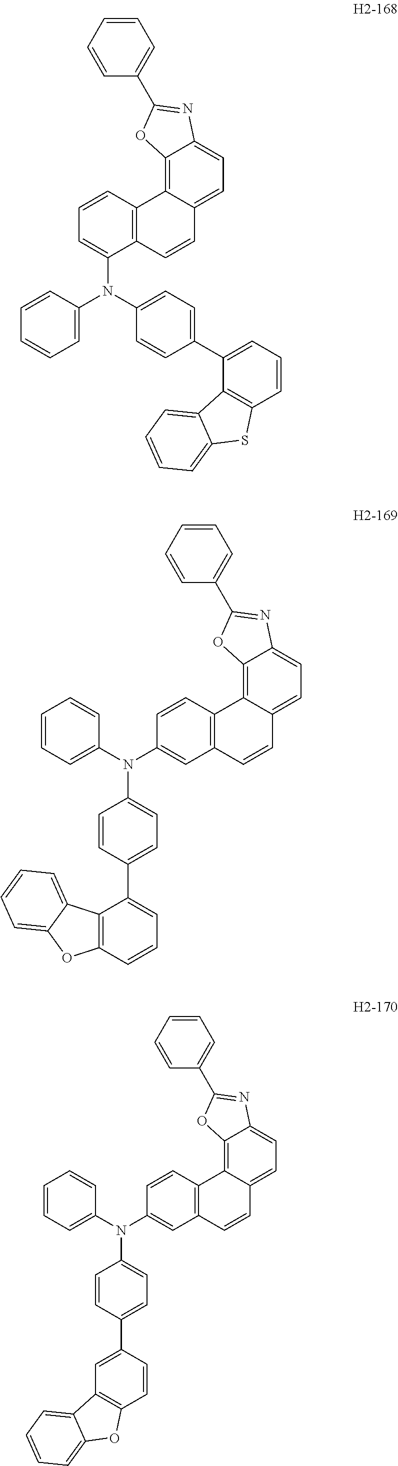 [SMILES: c1ccc(-c2nc3ccc4ccc5c(N(c6ccccc6)c6ccc(-c7cccc8sc9ccccc9c78)cc6)cccc5c4c3o2)cc1 ; c1ccc(-c2nc3ccc4ccc5cc(N(c6ccccc6)c6ccc(-c7cccc8oc9ccccc9c78)cc6)ccc5c4c3o2)cc1 ; c1ccc(-c2nc3ccc4ccc5cc(N(c6ccccc6)c6ccc(-c7ccc8oc9ccccc9c8c7)cc6)ccc5c4c3o2)cc1]

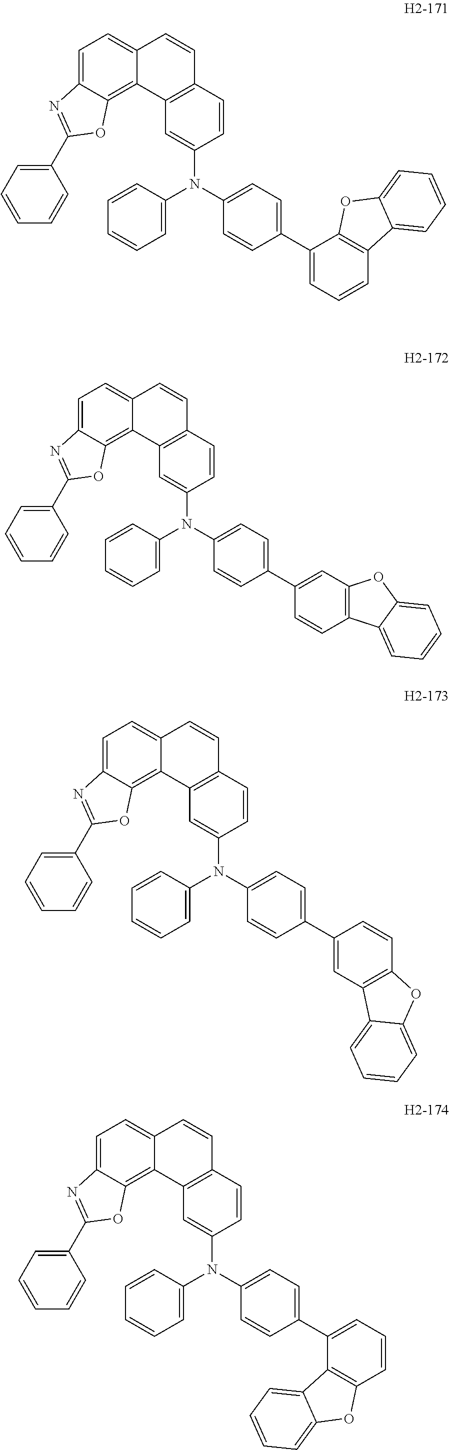 [SMILES: c1ccc(-c2nc3ccc4ccc5ccc(N(c6ccccc6)c6ccc(-c7cccc8c7oc7ccccc78)cc6)cc5c4c3o2)cc1 ; c1ccc(-c2nc3ccc4ccc5ccc(N(c6ccccc6)c6ccc(-c7ccc8c(c7)oc7ccccc78)cc6)cc5c4c3o2)cc1 ; c1ccc(-c2nc3ccc4ccc5ccc(N(c6ccccc6)c6ccc(-c7ccc8oc9ccccc9c8c7)cc6)cc5c4c3o2)cc1 ; c1ccc(-c2nc3ccc4ccc5ccc(N(c6ccccc6)c6ccc(-c7cccc8oc9ccccc9c78)cc6)cc5c4c3o2)cc1]

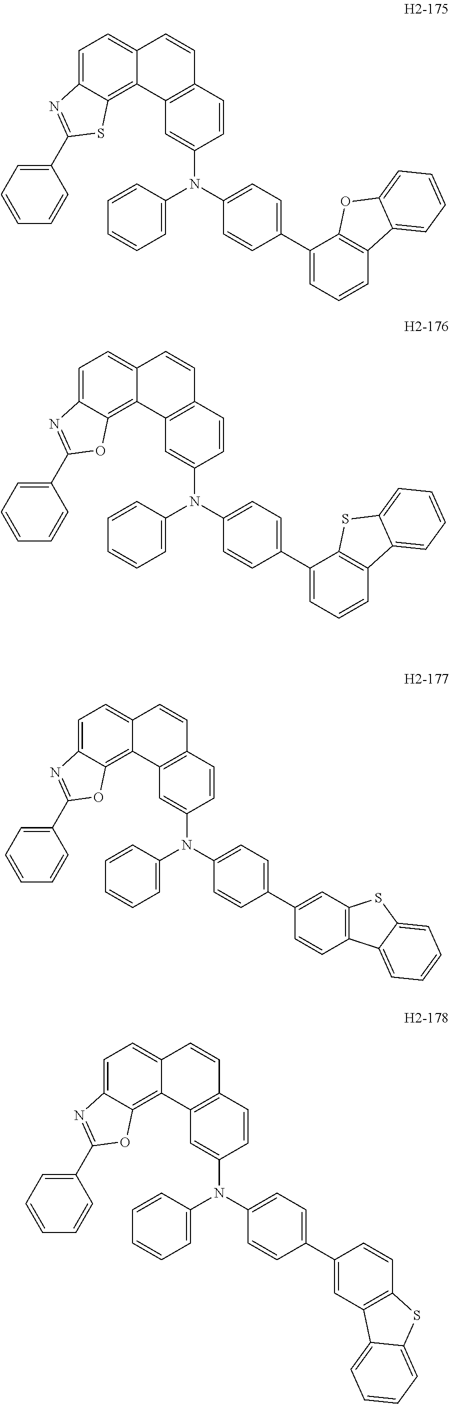 [SMILES: c1ccc(-c2nc3ccc4ccc5ccc(N(c6ccccc6)c6ccc(-c7cccc8c7oc7ccccc78)cc6)cc5c4c3s2)cc1 ; c1ccc(-c2nc3ccc4ccc5ccc(N(c6ccccc6)c6ccc(-c7cccc8c7sc7ccccc78)cc6)cc5c4c3o2)cc1 ; c1ccc(-c2nc3ccc4ccc5ccc(N(c6ccccc6)c6ccc(-c7ccc8c(c7)sc7ccccc78)cc6)cc5c4c3o2)cc1 ; c1ccc(-c2nc3ccc4ccc5ccc(N(c6ccccc6)c6ccc(-c7ccc8sc9ccccc9c8c7)cc6)cc5c4c3o2)cc1]

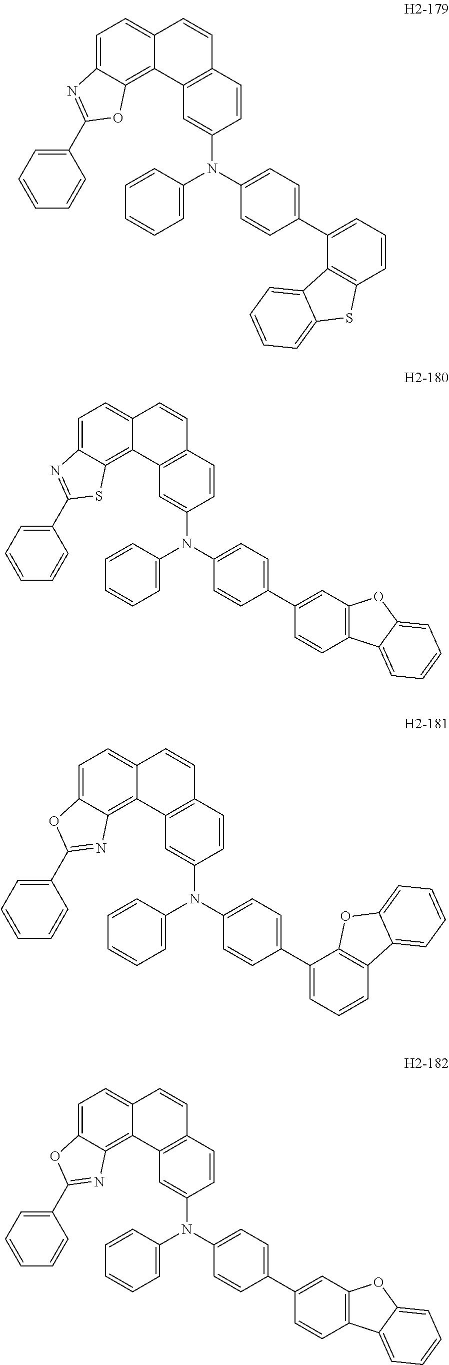 [SMILES: c1ccc(-c2nc3ccc4ccc5ccc(N(c6ccccc6)c6ccc(-c7cccc8sc9ccccc9c78)cc6)cc5c4c3o2)cc1 ; c1ccc(-c2nc3ccc4ccc5ccc(N(c6ccccc6)c6ccc(-c7ccc8c(c7)oc7ccccc78)cc6)cc5c4c3s2)cc1 ; c1ccc(-c2nc3c(ccc4ccc5ccc(N(c6ccccc6)c6ccc(-c7cccc8c7oc7ccccc78)cc6)cc5c43)o2)cc1 ; c1ccc(-c2nc3c(ccc4ccc5ccc(N(c6ccccc6)c6ccc(-c7ccc8c(c7)oc7ccccc78)cc6)cc5c43)o2)cc1]

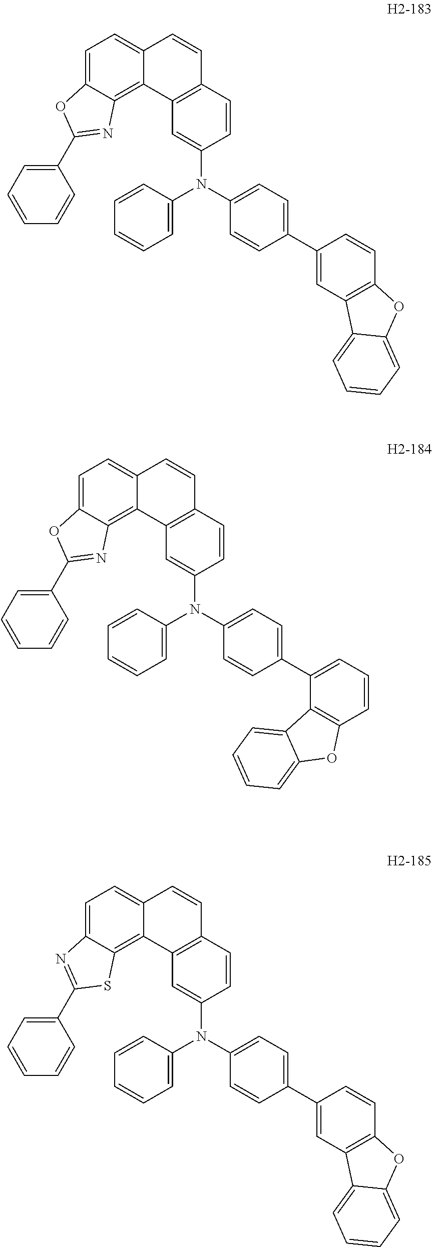 [SMILES: c1ccc(-c2nc3c(ccc4ccc5ccc(N(c6ccccc6)c6ccc(-c7ccc8oc9ccccc9c8c7)cc6)cc5c43)o2)cc1 ; c1ccc(-c2nc3c(ccc4ccc5ccc(N(c6ccccc6)c6ccc(-c7cccc8oc9ccccc9c78)cc6)cc5c43)o2)cc1 ; c1ccc(-c2nc3ccc4ccc5ccc(N(c6ccccc6)c6ccc(-c7ccc8oc9ccccc9c8c7)cc6)cc5c4c3s2)cc1]

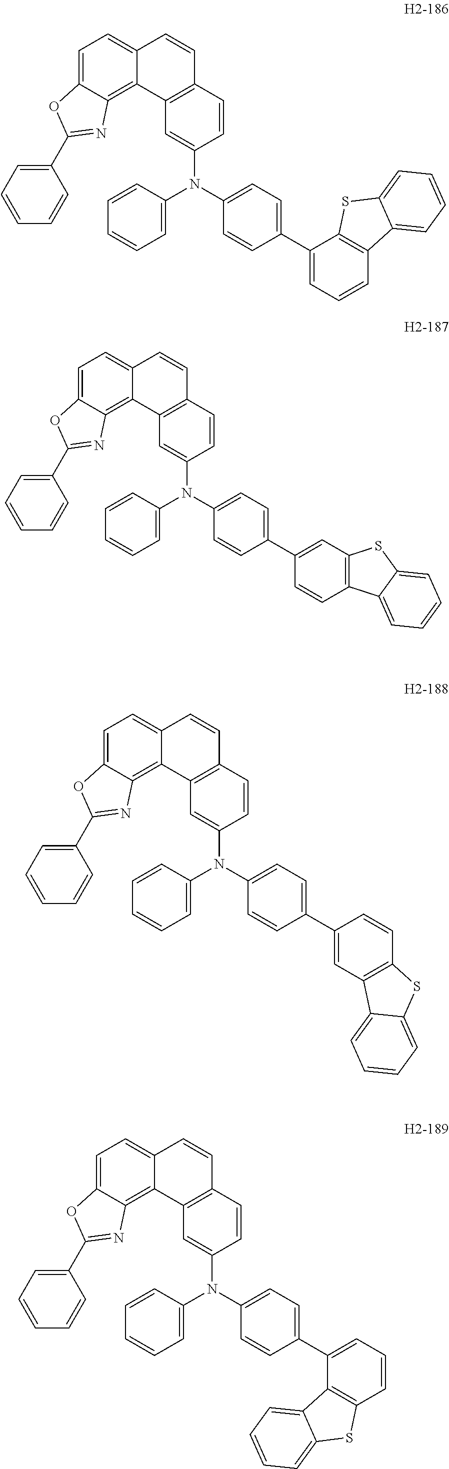 [SMILES: c1ccc(-c2nc3c(ccc4ccc5ccc(N(c6ccccc6)c6ccc(-c7cccc8c7sc7ccccc78)cc6)cc5c43)o2)cc1 ; c1ccc(-c2nc3c(ccc4ccc5ccc(N(c6ccccc6)c6ccc(-c7ccc8c(c7)sc7ccccc78)cc6)cc5c43)o2)cc1 ; c1ccc(-c2nc3c(ccc4ccc5ccc(N(c6ccccc6)c6ccc(-c7ccc8sc9ccccc9c8c7)cc6)cc5c43)o2)cc1 ; c1ccc(-c2nc3c(ccc4ccc5ccc(N(c6ccccc6)c6ccc(-c7cccc8sc9ccccc9c78)cc6)cc5c43)o2)cc1]

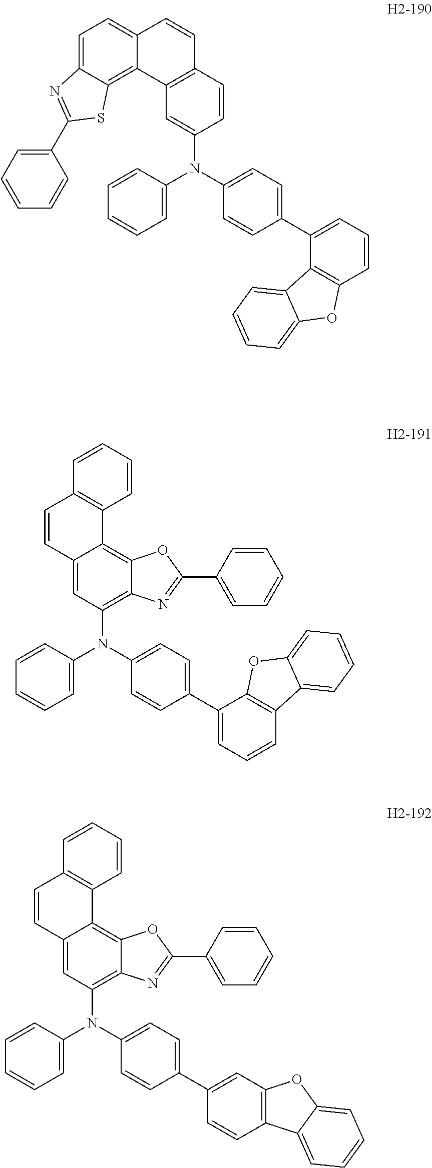 [SMILES: c1ccc(-c2nc3ccc4ccc5ccc(N(c6ccccc6)c6ccc(-c7cccc8oc9ccccc9c78)cc6)cc5c4c3s2)cc1 ; c1ccc(-c2nc3c(N(c4ccccc4)c4ccc(-c5cccc6c5oc5ccccc56)cc4)cc4ccc5ccccc5c4c3o2)cc1 ; c1ccc(-c2nc3c(N(c4ccccc4)c4ccc(-c5ccc6c(c5)oc5ccccc56)cc4)cc4ccc5ccccc5c4c3o2)cc1]

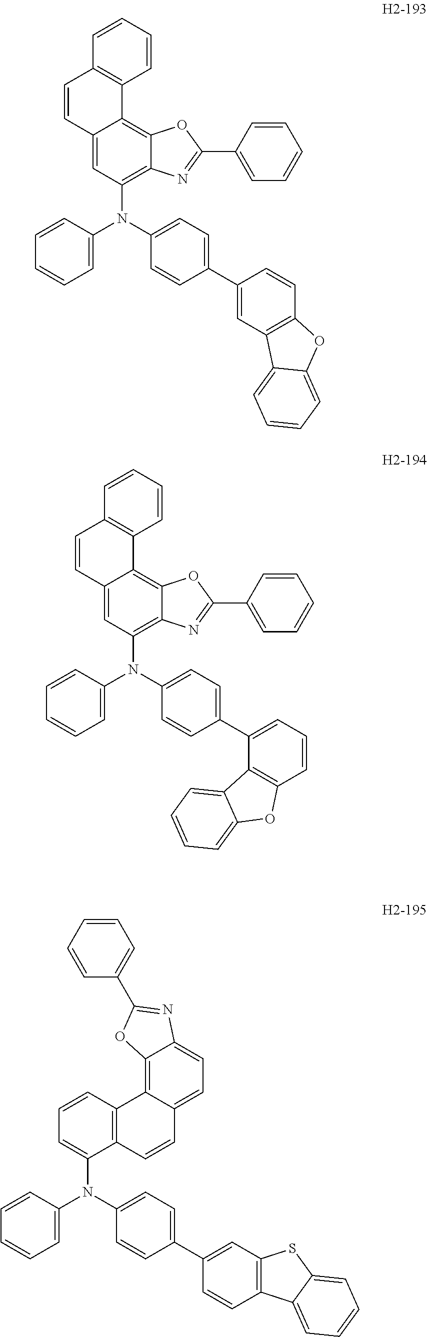 [SMILES: c1ccc(-c2nc3c(N(c4ccccc4)c4ccc(-c5ccc6oc7ccccc7c6c5)cc4)cc4ccc5ccccc5c4c3o2)cc1 ; c1ccc(-c2nc3c(N(c4ccccc4)c4ccc(-c5cccc6oc7ccccc7c56)cc4)cc4ccc5ccccc5c4c3o2)cc1 ; c1ccc(-c2nc3ccc4ccc5c(N(c6ccccc6)c6ccc(-c7ccc8c(c7)sc7ccccc78)cc6)cccc5c4c3o2)cc1]

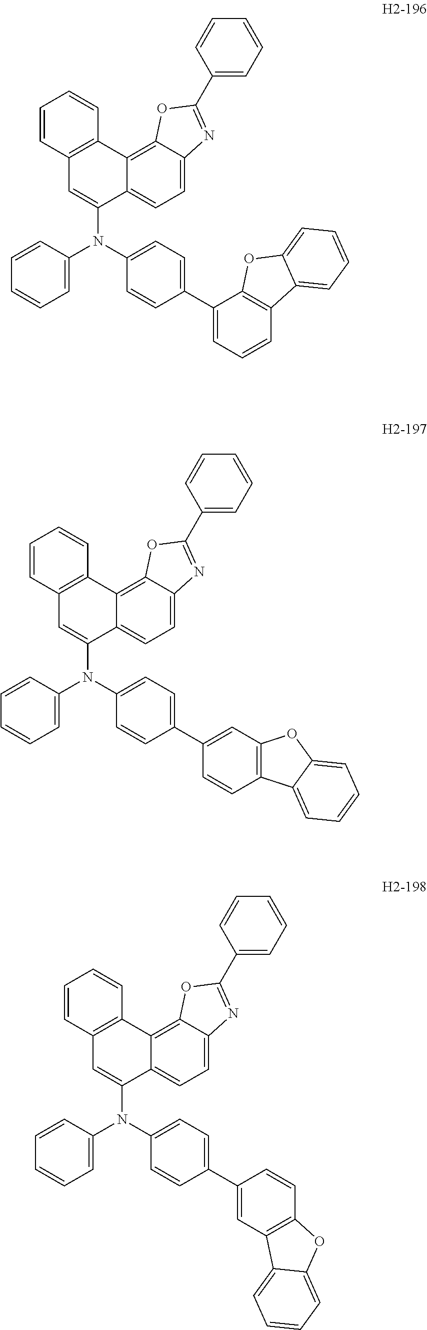 [SMILES: c1ccc(-c2nc3ccc4c(N(c5ccccc5)c5ccc(-c6cccc7c6oc6ccccc67)cc5)cc5ccccc5c4c3o2)cc1 ; c1ccc(-c2nc3ccc4c(N(c5ccccc5)c5ccc(-c6ccc7c(c6)oc6ccccc67)cc5)cc5ccccc5c4c3o2)cc1 ; c1ccc(-c2nc3ccc4c(N(c5ccccc5)c5ccc(-c6ccc7oc8ccccc8c7c6)cc5)cc5ccccc5c4c3o2)cc1]

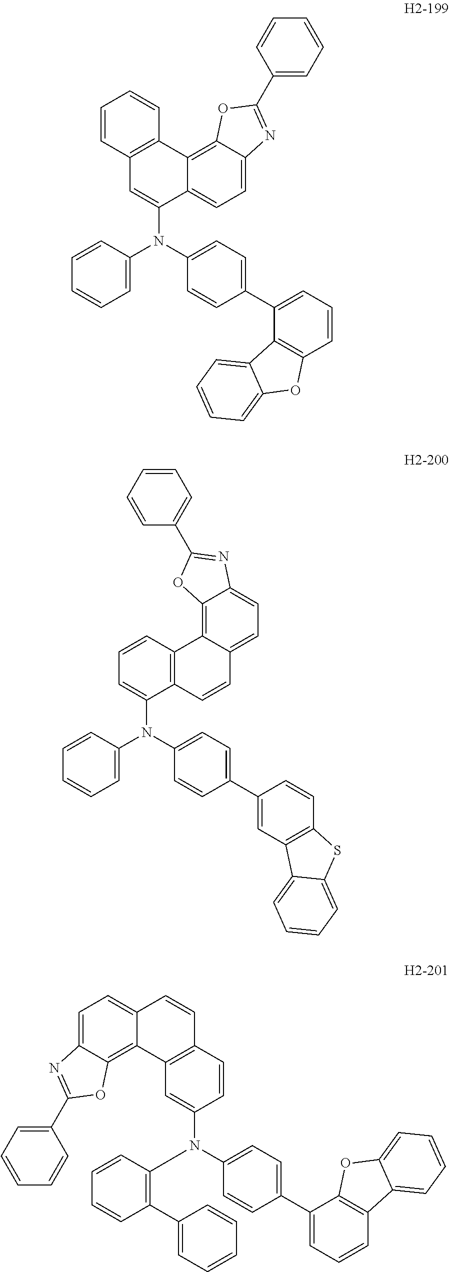 [SMILES: c1ccc(-c2nc3ccc4c(N(c5ccccc5)c5ccc(-c6cccc7oc8ccccc8c67)cc5)cc5ccccc5c4c3o2)cc1 ; c1ccc(-c2nc3ccc4ccc5c(N(c6ccccc6)c6ccc(-c7ccc8sc9ccccc9c8c7)cc6)cccc5c4c3o2)cc1 ; c1ccc(-c2nc3ccc4ccc5ccc(N(c6ccc(-c7cccc8c7oc7ccccc78)cc6)c6ccccc6-c6ccccc6)cc5c4c3o2)cc1]

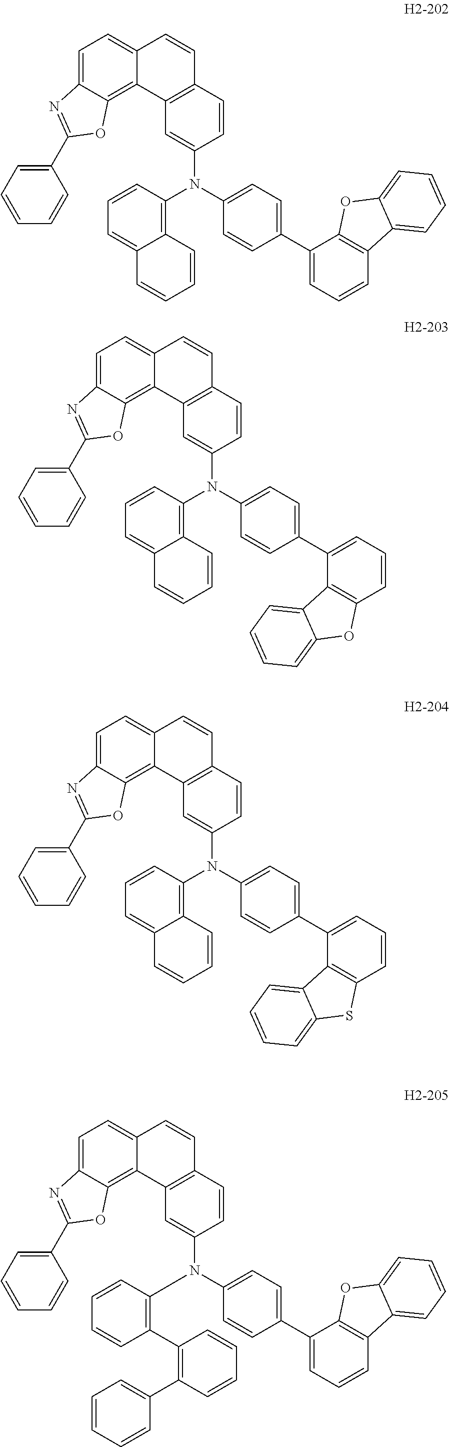

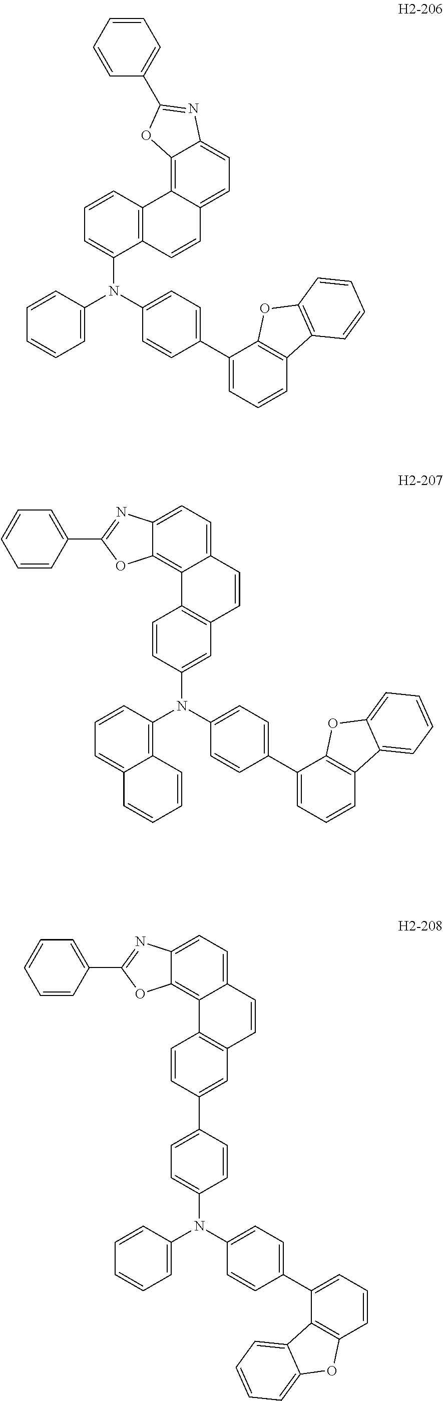 [SMILES: c1ccc(-c2nc3ccc4ccc5c(N(c6ccccc6)c6ccc(-c7cccc8c7oc7ccccc78)cc6)cccc5c4c3o2)cc1 ; c1ccc(-c2nc3ccc4ccc5cc(N(c6ccc(-c7cccc8c7oc7ccccc78)cc6)c6cccc7ccccc67)ccc5c4c3o2)cc1 ; c1ccc(-c2nc3ccc4ccc5cc(-c6ccc(N(c7ccccc7)c7ccc(-c8cccc9oc%10ccccc%10c89)cc7)cc6)ccc5c4c3o2)cc1]

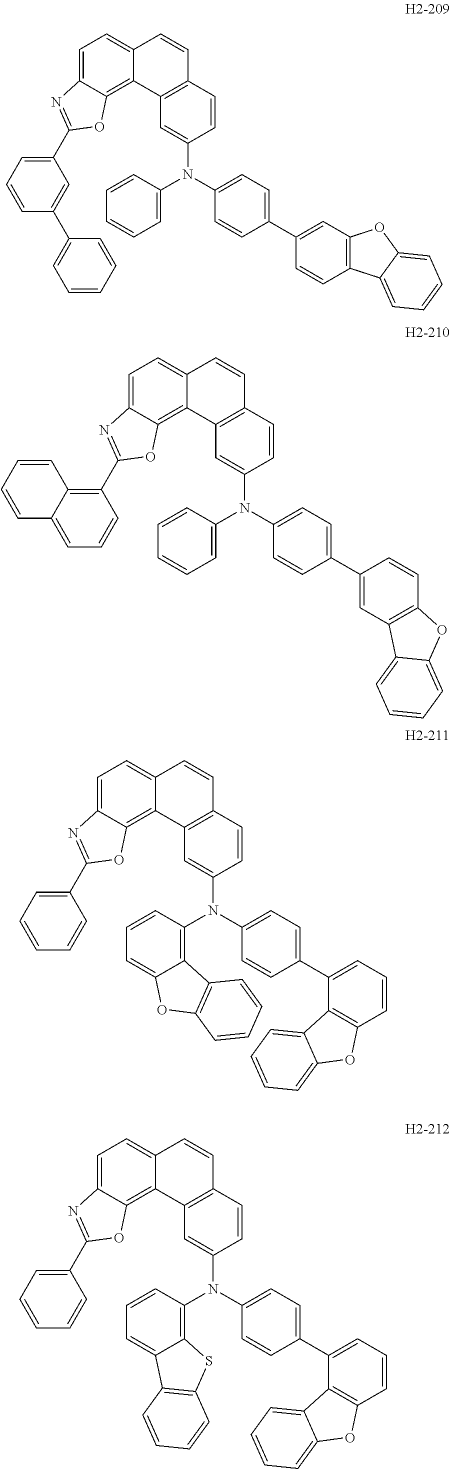 [SMILES: c1ccc(-c2cccc(-c3nc4ccc5ccc6ccc(N(c7ccccc7)c7ccc(-c8ccc9c(c8)oc8ccccc89)cc7)cc6c5c4o3)c2)cc1 ; c1ccc(N(c2ccc(-c3ccc4oc5ccccc5c4c3)cc2)c2ccc3ccc4ccc5nc(-c6cccc7ccccc67)oc5c4c3c2)cc1 ; c1ccc(-c2nc3ccc4ccc5ccc(N(c6ccc(-c7cccc8oc9ccccc9c78)cc6)c6cccc7oc8ccccc8c67)cc5c4c3o2)cc1 ; c1ccc(-c2nc3ccc4ccc5ccc(N(c6ccc(-c7cccc8oc9ccccc9c78)cc6)c6cccc7c6sc6ccccc67)cc5c4c3o2)cc1]

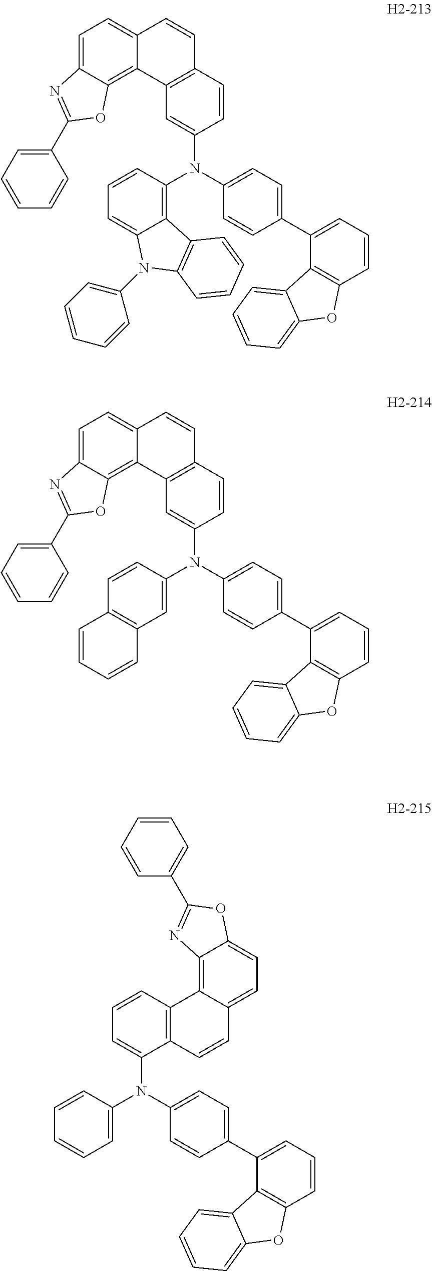 [SMILES: c1ccc(-c2nc3ccc4ccc5ccc(N(c6ccc(-c7cccc8oc9ccccc9c78)cc6)c6cccc7c6c6ccccc6n7-c6ccccc6)cc5c4c3o2)cc1 ; c1ccc(-c2nc3ccc4ccc5ccc(N(c6ccc(-c7cccc8oc9ccccc9c78)cc6)c6ccc7ccccc7c6)cc5c4c3o2)cc1 ; c1ccc(-c2nc3c(ccc4ccc5c(N(c6ccccc6)c6ccc(-c7cccc8oc9ccccc9c78)cc6)cccc5c43)o2)cc1]

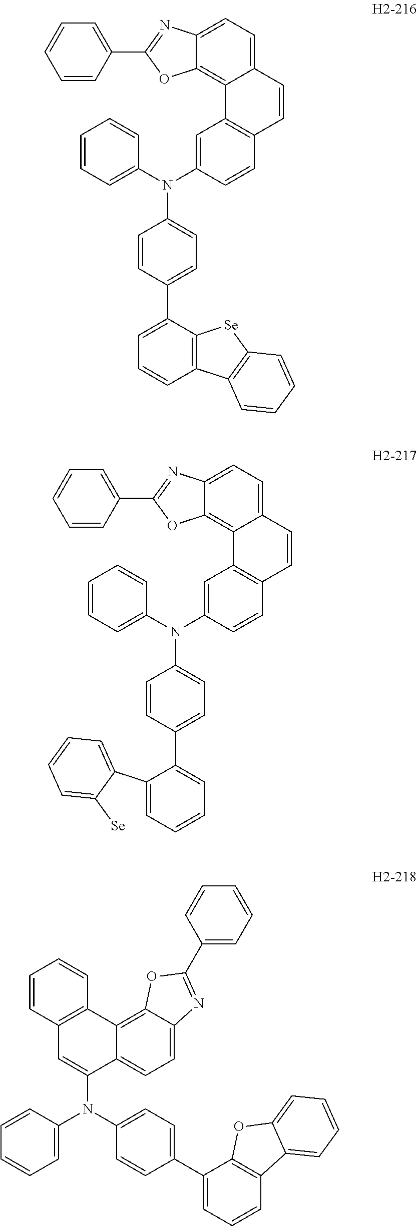

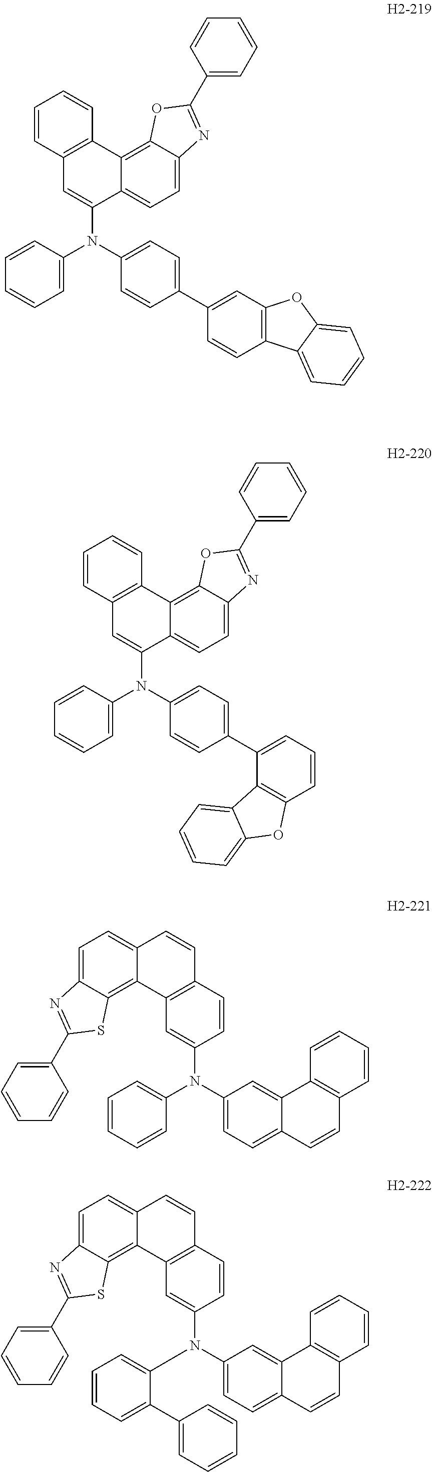 [SMILES: c1ccc(-c2nc3ccc4c(N(c5ccccc5)c5ccc(-c6ccc7c(c6)oc6ccccc67)cc5)cc5ccccc5c4c3o2)cc1 ; c1ccc(-c2nc3ccc4c(N(c5ccccc5)c5ccc(-c6cccc7oc8ccccc8c67)cc5)cc5ccccc5c4c3o2)cc1 ; c1ccc(-c2nc3ccc4ccc5ccc(N(c6ccccc6)c6ccc7ccc8ccccc8c7c6)cc5c4c3s2)cc1 ; c1ccc(-c2nc3ccc4ccc5ccc(N(c6ccc7ccc8ccccc8c7c6)c6ccccc6-c6ccccc6)cc5c4c3s2)cc1]

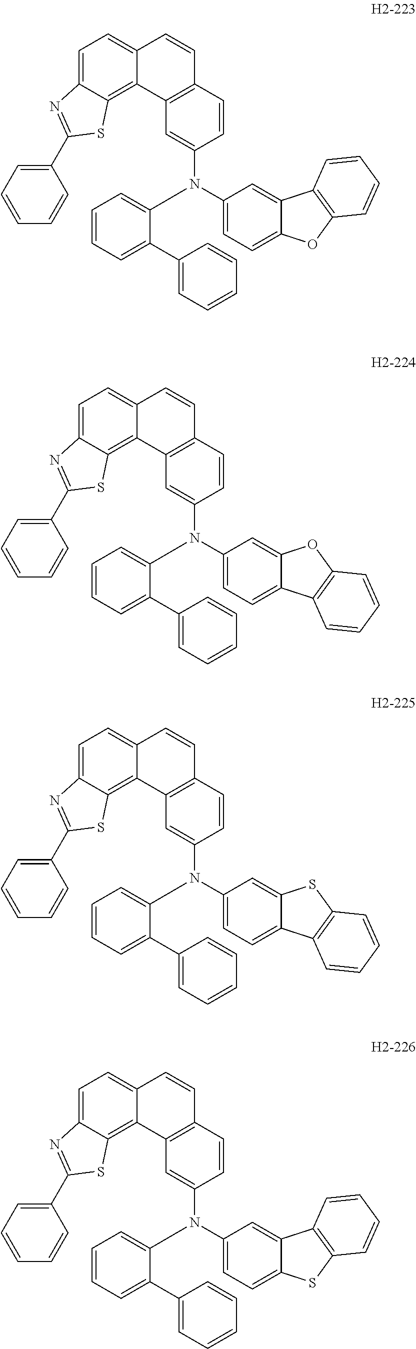 [SMILES: c1ccc(-c2nc3ccc4ccc5ccc(N(c6ccc7oc8ccccc8c7c6)c6ccccc6-c6ccccc6)cc5c4c3s2)cc1 ; c1ccc(-c2nc3ccc4ccc5ccc(N(c6ccc7c(c6)oc6ccccc67)c6ccccc6-c6ccccc6)cc5c4c3s2)cc1 ; c1ccc(-c2nc3ccc4ccc5ccc(N(c6ccc7c(c6)sc6ccccc67)c6ccccc6-c6ccccc6)cc5c4c3s2)cc1 ; c1ccc(-c2nc3ccc4ccc5ccc(N(c6ccc7sc8ccccc8c7c6)c6ccccc6-c6ccccc6)cc5c4c3s2)cc1]

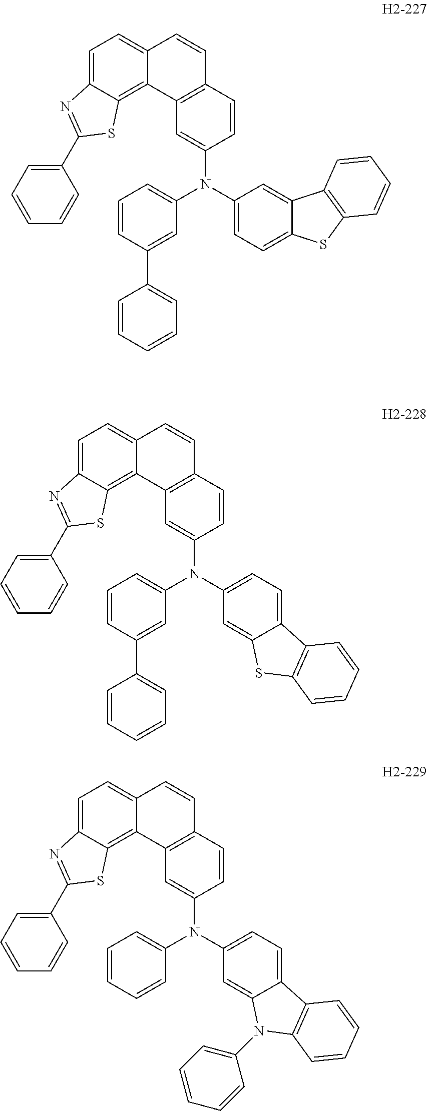 [SMILES: c1ccc(-c2cccc(N(c3ccc4sc5ccccc5c4c3)c3ccc4ccc5ccc6nc(-c7ccccc7)sc6c5c4c3)c2)cc1 ; c1ccc(-c2cccc(N(c3ccc4c(c3)sc3ccccc34)c3ccc4ccc5ccc6nc(-c7ccccc7)sc6c5c4c3)c2)cc1 ; c1ccc(-c2nc3ccc4ccc5ccc(N(c6ccccc6)c6ccc7c8ccccc8n(-c8ccccc8)c7c6)cc5c4c3s2)cc1]

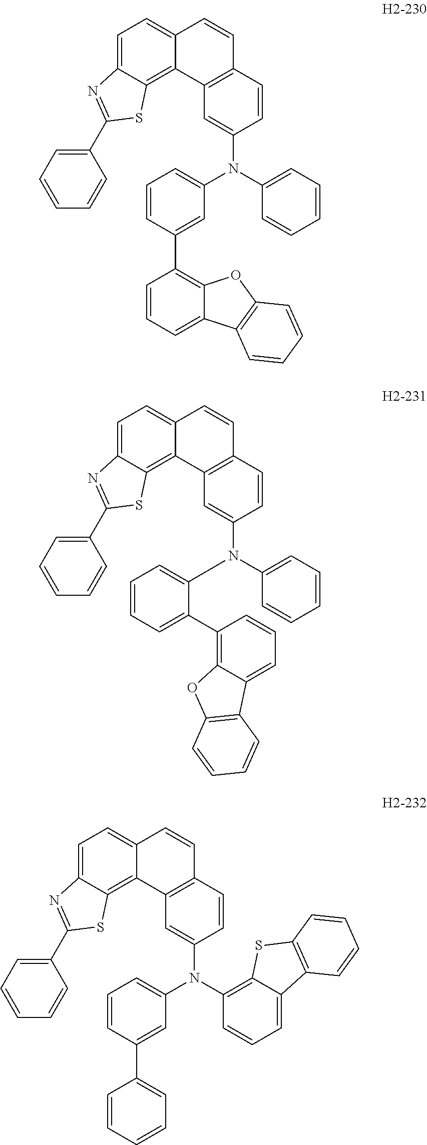 [SMILES: c1ccc(-c2nc3ccc4ccc5ccc(N(c6ccccc6)c6cccc(-c7cccc8c7oc7ccccc78)c6)cc5c4c3s2)cc1 ; c1ccc(-c2nc3ccc4ccc5ccc(N(c6ccccc6)c6ccccc6-c6cccc7c6oc6ccccc67)cc5c4c3s2)cc1 ; c1ccc(-c2cccc(N(c3ccc4ccc5ccc6nc(-c7ccccc7)sc6c5c4c3)c3cccc4c3sc3ccccc34)c2)cc1]

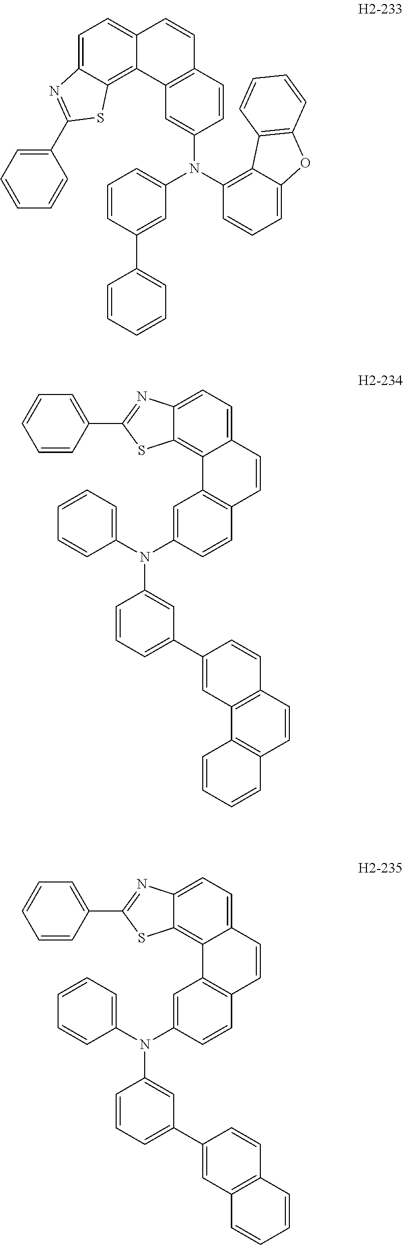 [SMILES: c1ccc(-c2cccc(N(c3ccc4ccc5ccc6nc(-c7ccccc7)sc6c5c4c3)c3cccc4oc5ccccc5c34)c2)cc1 ; c1ccc(-c2nc3ccc4ccc5ccc(N(c6ccccc6)c6cccc(-c7ccc8ccc9ccccc9c8c7)c6)cc5c4c3s2)cc1 ; c1ccc(-c2nc3ccc4ccc5ccc(N(c6ccccc6)c6cccc(-c7ccc8ccccc8c7)c6)cc5c4c3s2)cc1]

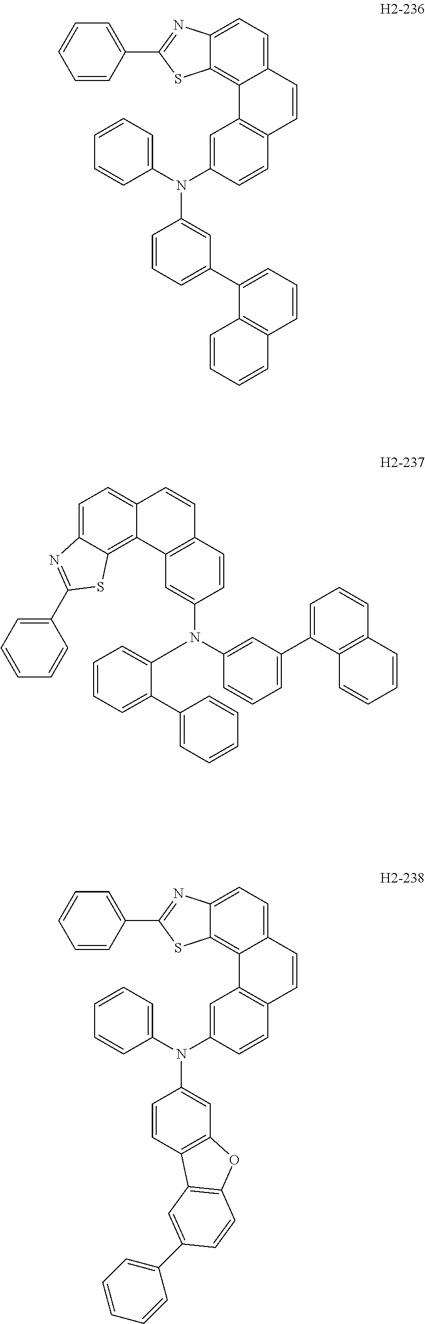 [SMILES: c1ccc(-c2nc3ccc4ccc5ccc(N(c6ccccc6)c6cccc(-c7cccc8ccccc78)c6)cc5c4c3s2)cc1 ; c1ccc(-c2nc3ccc4ccc5ccc(N(c6cccc(-c7cccc8ccccc78)c6)c6ccccc6-c6ccccc6)cc5c4c3s2)cc1 ; c1ccc(-c2ccc3oc4cc(N(c5ccccc5)c5ccc6ccc7ccc8nc(-c9ccccc9)sc8c7c6c5)ccc4c3c2)cc1]

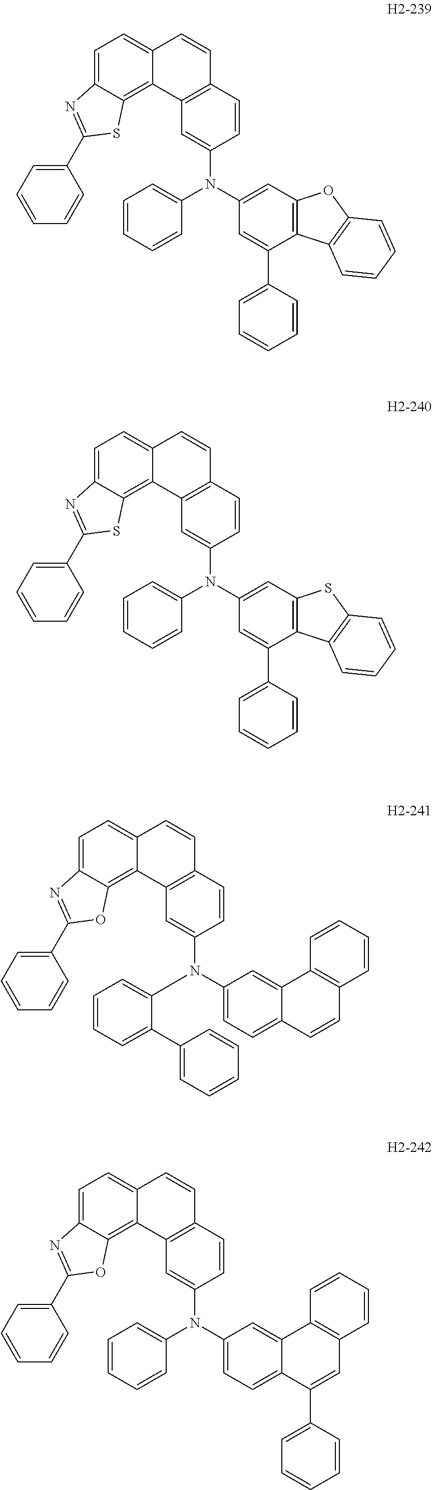 [SMILES: c1ccc(-c2nc3ccc4ccc5ccc(N(c6ccccc6)c6cc(-c7ccccc7)c7c(c6)oc6ccccc67)cc5c4c3s2)cc1 ; c1ccc(-c2nc3ccc4ccc5ccc(N(c6ccccc6)c6cc(-c7ccccc7)c7c(c6)sc6ccccc67)cc5c4c3s2)cc1 ; c1ccc(-c2nc3ccc4ccc5ccc(N(c6ccc7ccc8ccccc8c7c6)c6ccccc6-c6ccccc6)cc5c4c3o2)cc1 ; c1ccc(-c2nc3ccc4ccc5ccc(N(c6ccccc6)c6ccc7c(-c8ccccc8)cc8ccccc8c7c6)cc5c4c3o2)cc1]

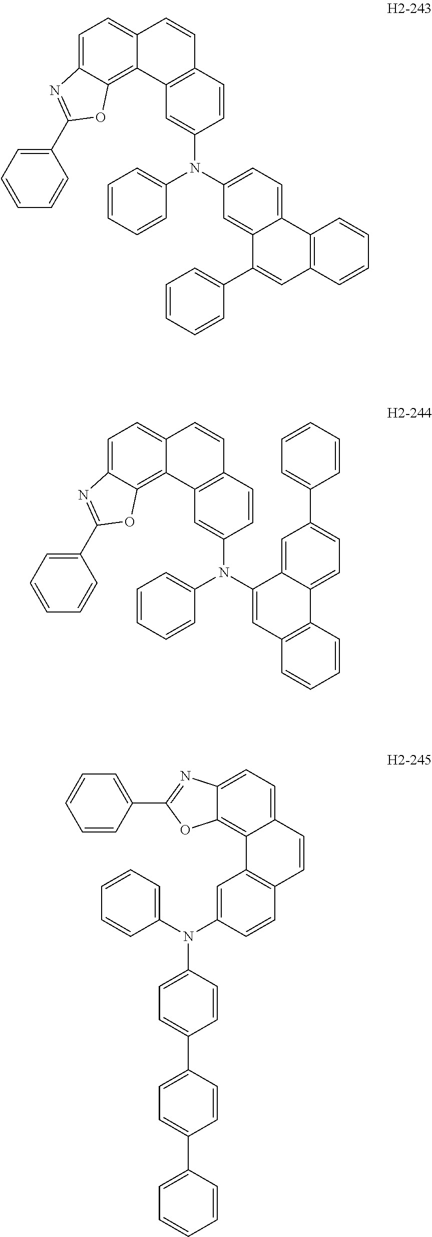 [SMILES: c1ccc(-c2nc3ccc4ccc5ccc(N(c6ccccc6)c6ccc7c(c6)c(-c6ccccc6)cc6ccccc67)cc5c4c3o2)cc1 ; c1ccc(-c2ccc3c(c2)c(N(c2ccccc2)c2ccc4ccc5ccc6nc(-c7ccccc7)oc6c5c4c2)cc2ccccc23)cc1 ; c1ccc(-c2ccc(-c3ccc(N(c4ccccc4)c4ccc5ccc6ccc7nc(-c8ccccc8)oc7c6c5c4)cc3)cc2)cc1]

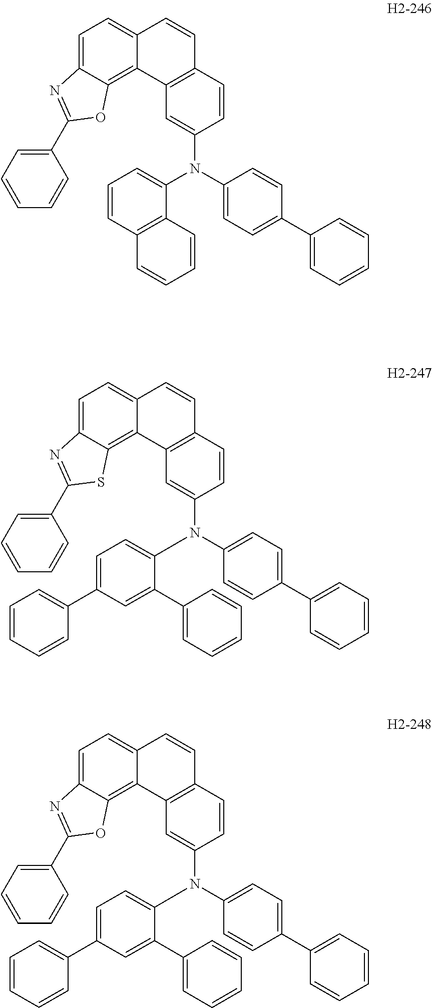 [SMILES: c1ccc(-c2ccc(N(c3ccc4ccc5ccc6nc(-c7ccccc7)oc6c5c4c3)c3cccc4ccccc34)cc2)cc1 ; c1ccc(-c2ccc(N(c3ccc4ccc5ccc6nc(-c7ccccc7)sc6c5c4c3)c3ccc(-c4ccccc4)cc3-c3ccccc3)cc2)cc1 ; c1ccc(-c2ccc(N(c3ccc4ccc5ccc6nc(-c7ccccc7)oc6c5c4c3)c3ccc(-c4ccccc4)cc3-c3ccccc3)cc2)cc1]

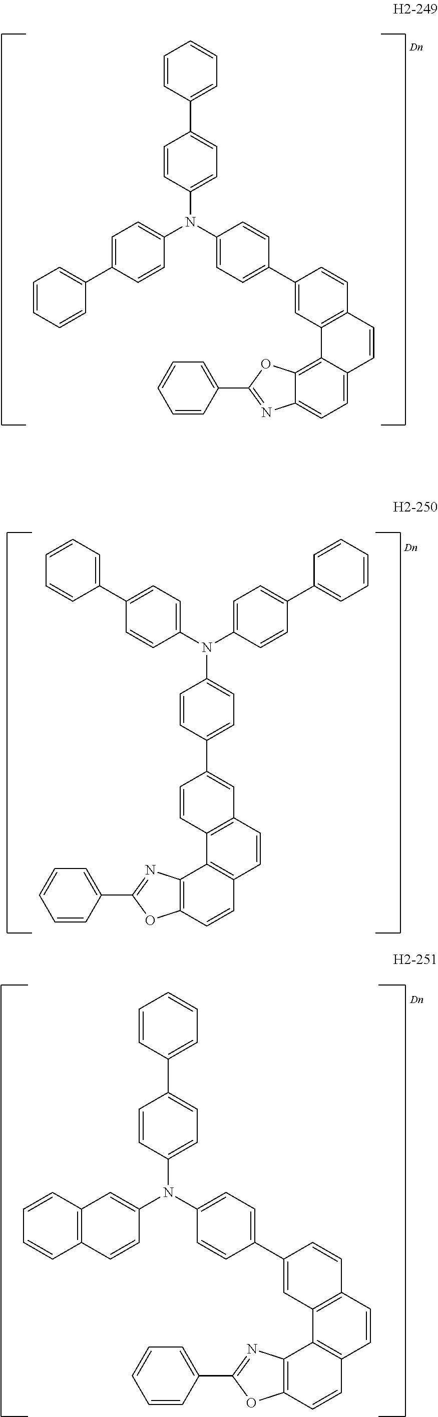

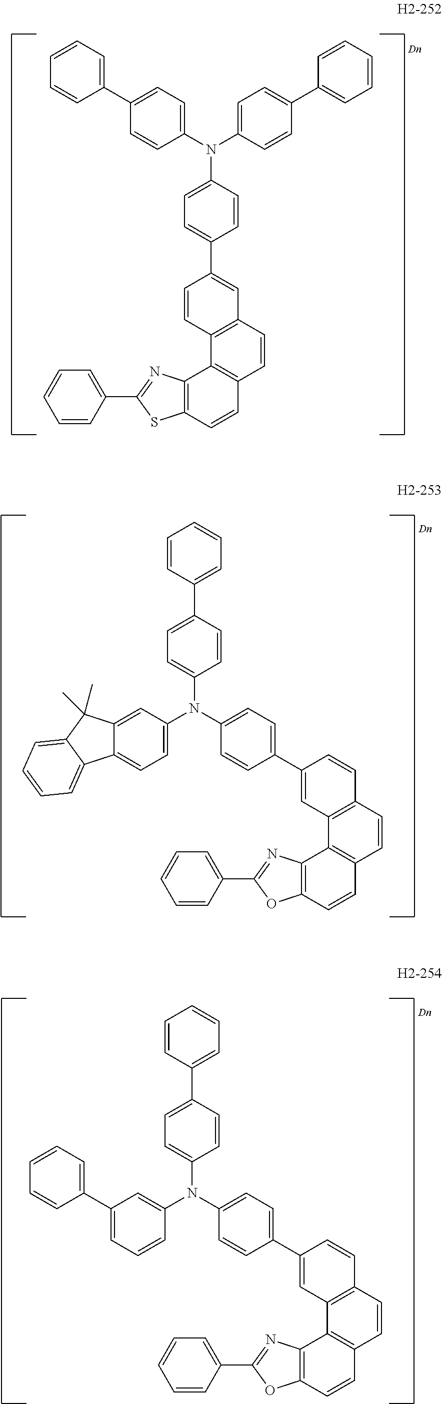

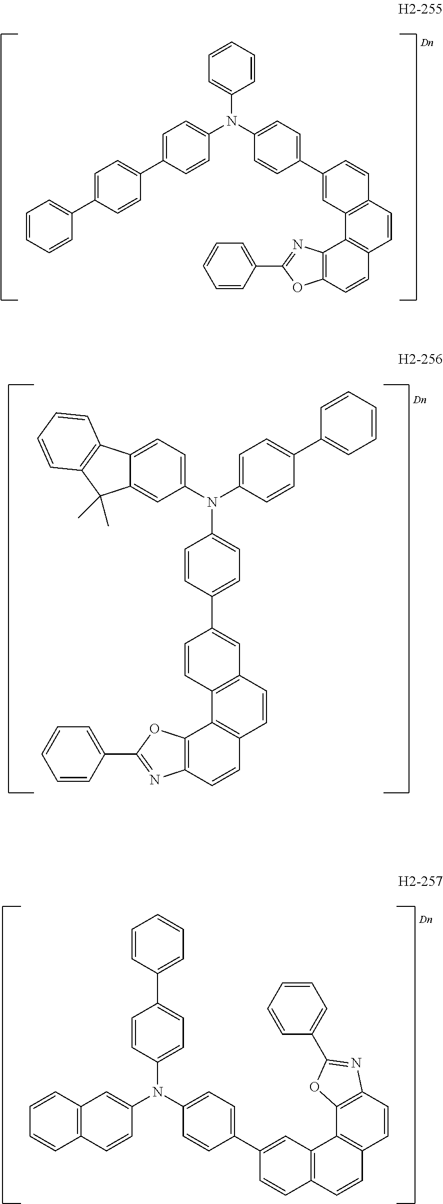

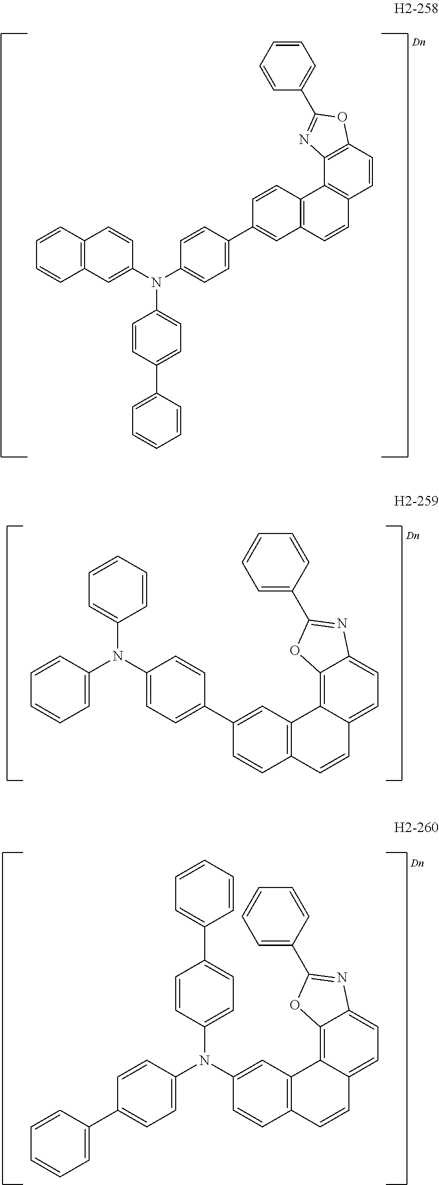

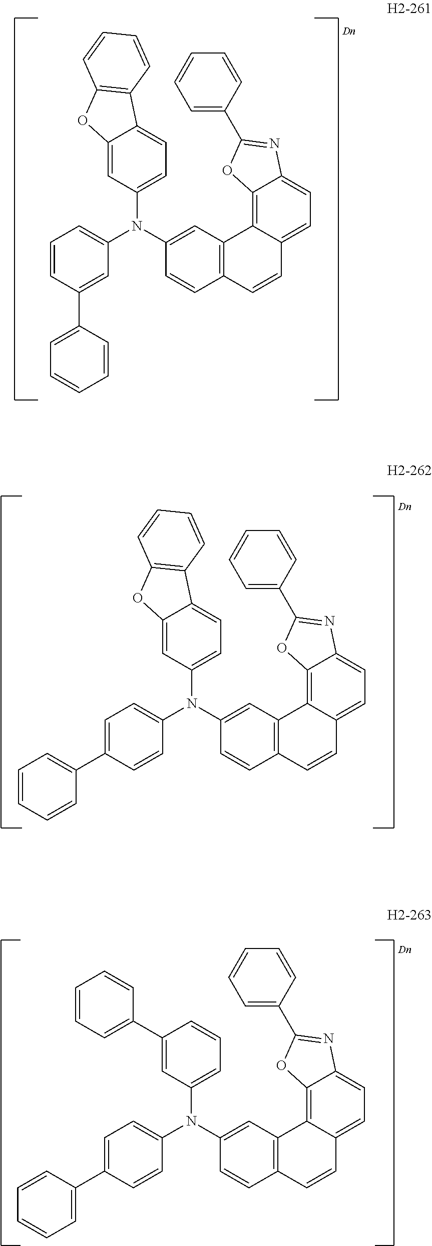

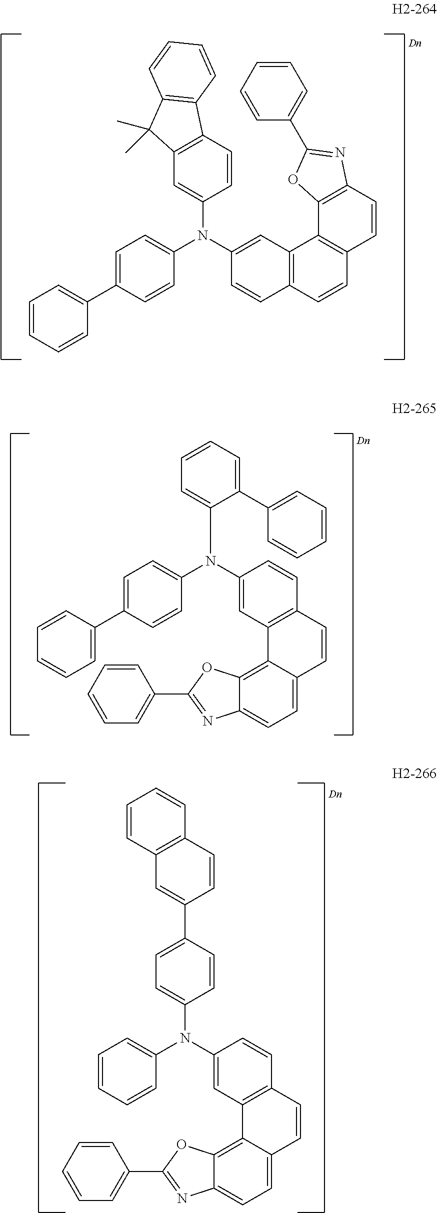

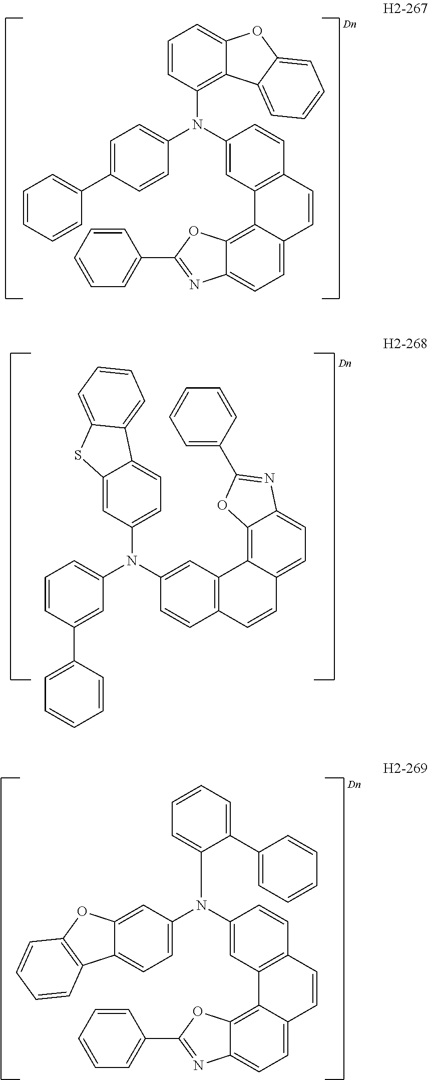

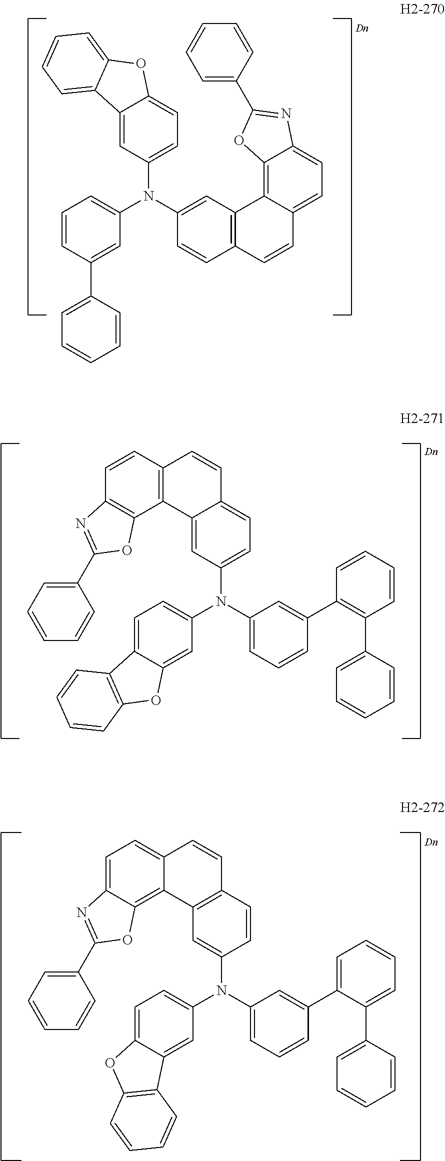

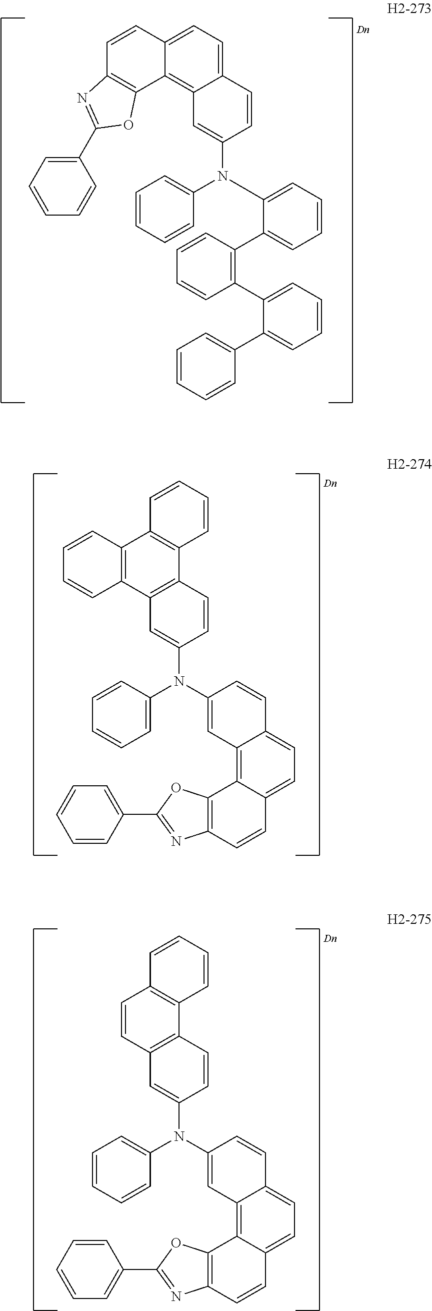

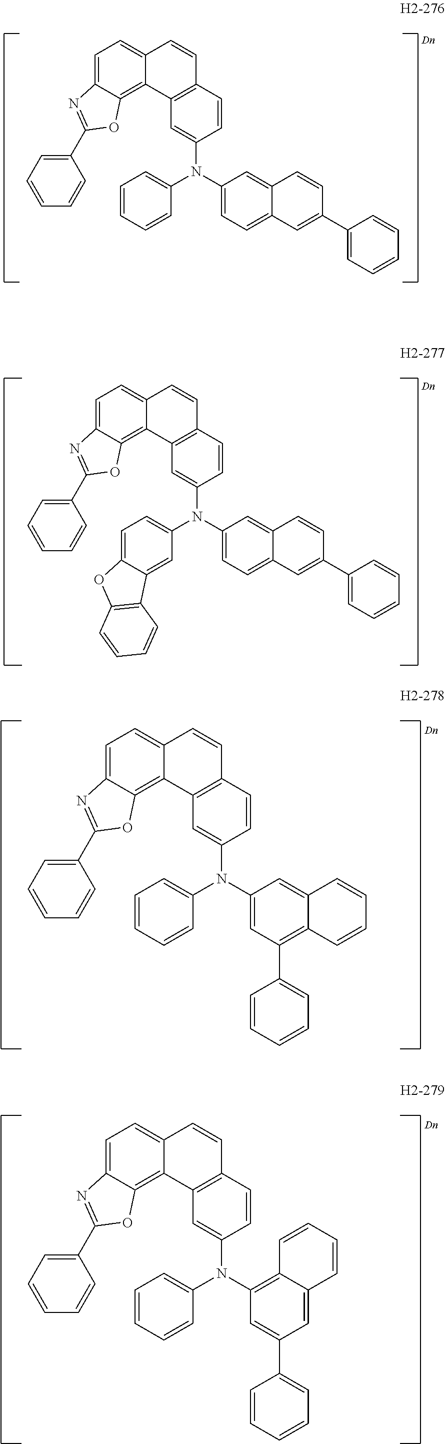

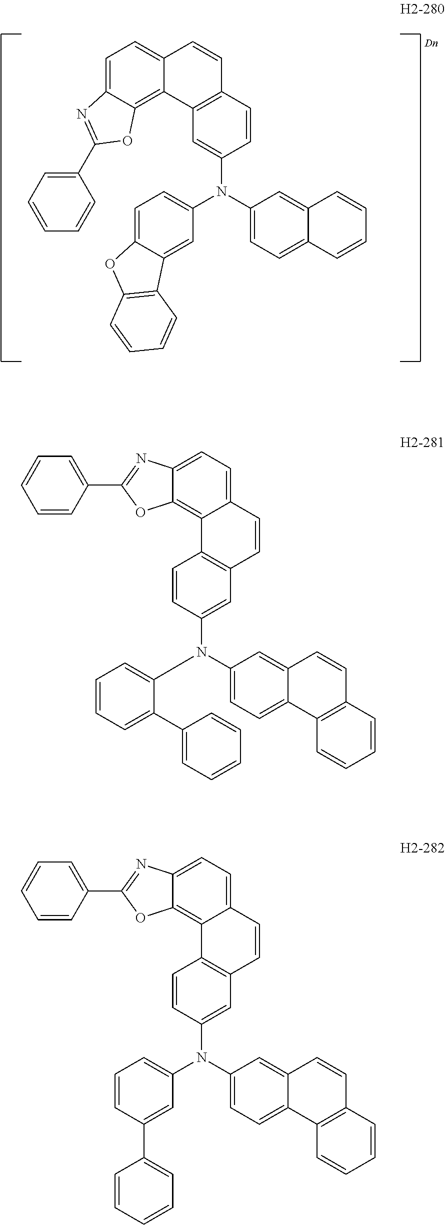

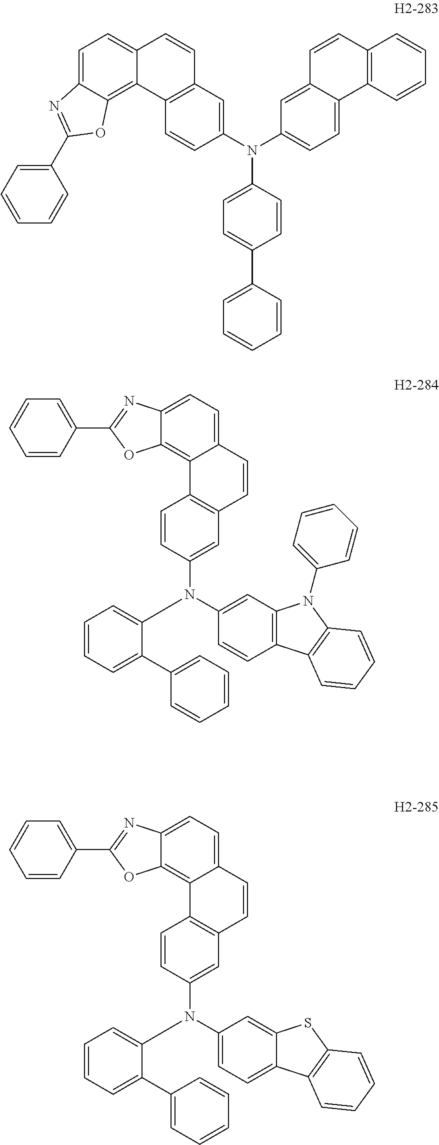 [SMILES: c1ccc(-c2ccc(N(c3ccc4c(ccc5ccccc54)c3)c3ccc4c(ccc5ccc6nc(-c7ccccc7)oc6c54)c3)cc2)cc1 ; c1ccc(-c2nc3ccc4ccc5cc(N(c6ccc7c8ccccc8n(-c8ccccc8)c7c6)c6ccccc6-c6ccccc6)ccc5c4c3o2)cc1 ; c1ccc(-c2nc3ccc4ccc5cc(N(c6ccc7c(c6)sc6ccccc67)c6ccccc6-c6ccccc6)ccc5c4c3o2)cc1]

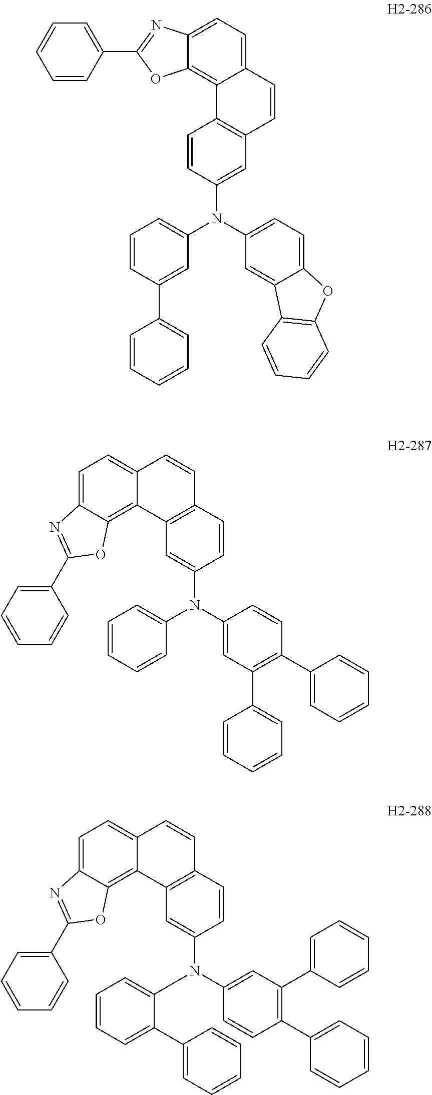 [SMILES: c1ccc(-c2cccc(N(c3ccc4c(ccc5ccc6nc(-c7ccccc7)oc6c54)c3)c3ccc4oc5ccccc5c4c3)c2)cc1 ; c1ccc(-c2nc3ccc4ccc5ccc(N(c6ccccc6)c6ccc(-c7ccccc7)c(-c7ccccc7)c6)cc5c4c3o2)cc1 ; c1ccc(-c2nc3ccc4ccc5ccc(N(c6ccc(-c7ccccc7)c(-c7ccccc7)c6)c6ccccc6-c6ccccc6)cc5c4c3o2)cc1]

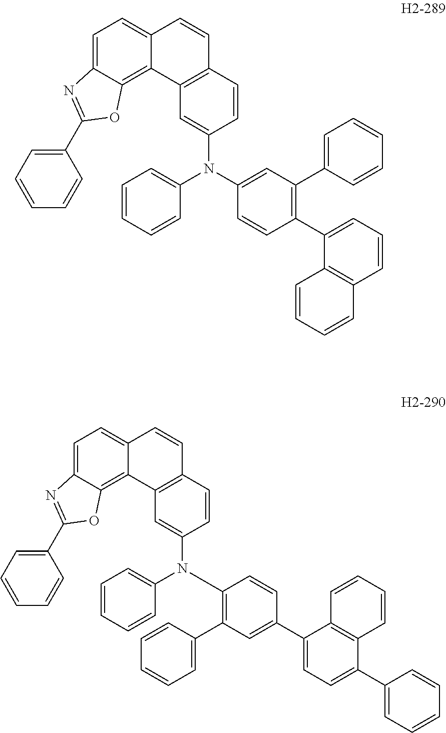 [SMILES: c1ccc(-c2nc3ccc4ccc5ccc(N(c6ccccc6)c6ccc(-c7cccc8ccccc78)c(-c7ccccc7)c6)cc5c4c3o2)cc1 ; c1ccc(-c2nc3ccc4ccc5ccc(N(c6ccccc6)c6ccc(-c7ccc(-c8ccccc8)c8ccccc78)cc6-c6ccccc6)cc5c4c3o2)cc1]

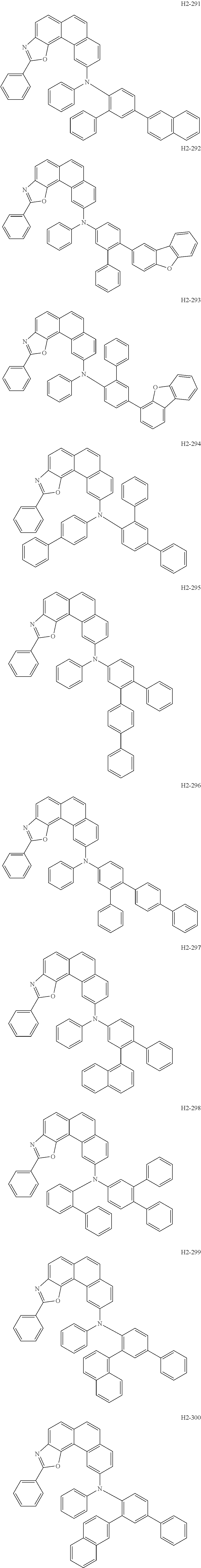

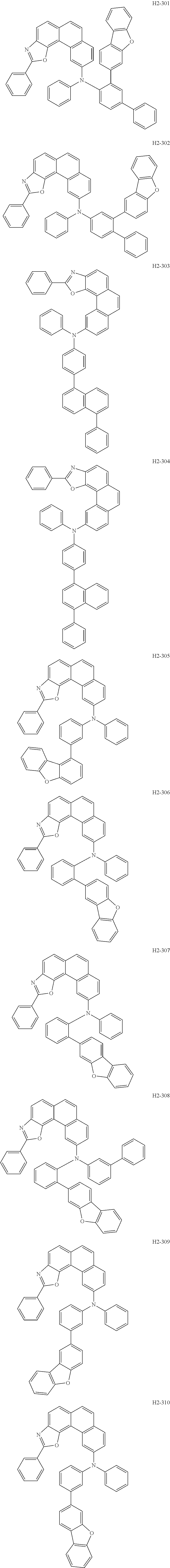

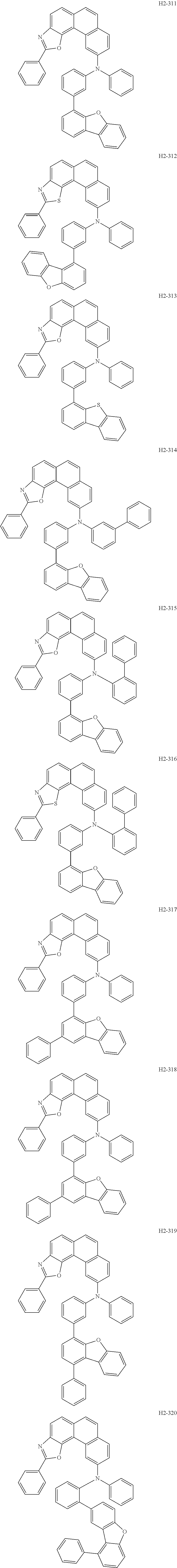

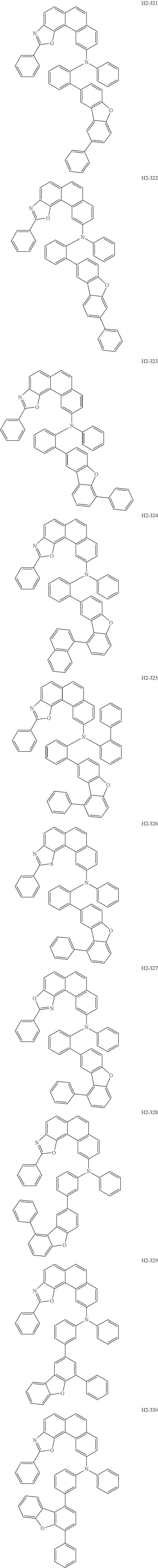

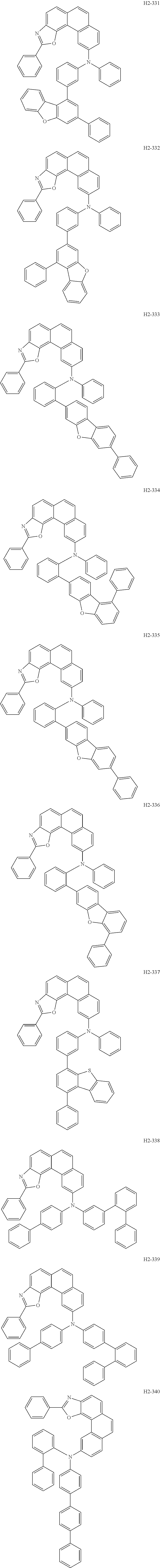

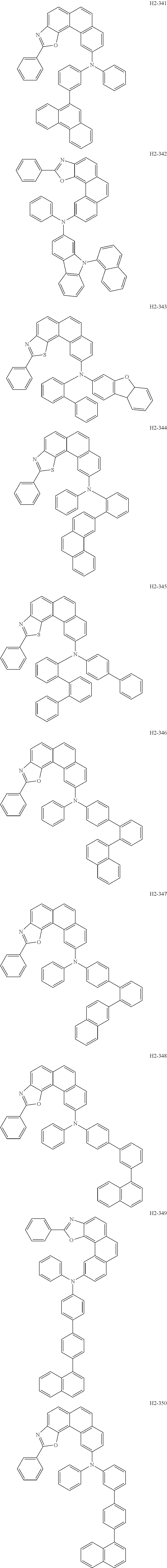

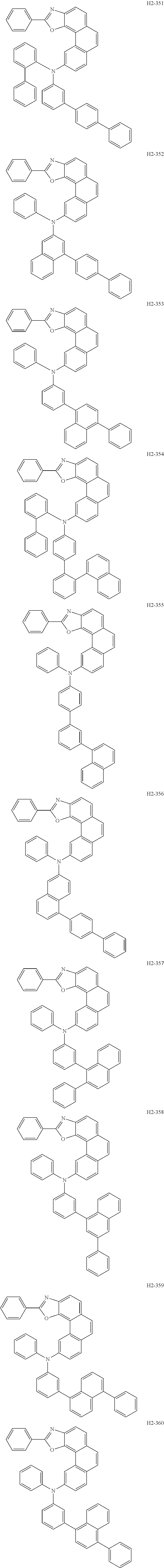

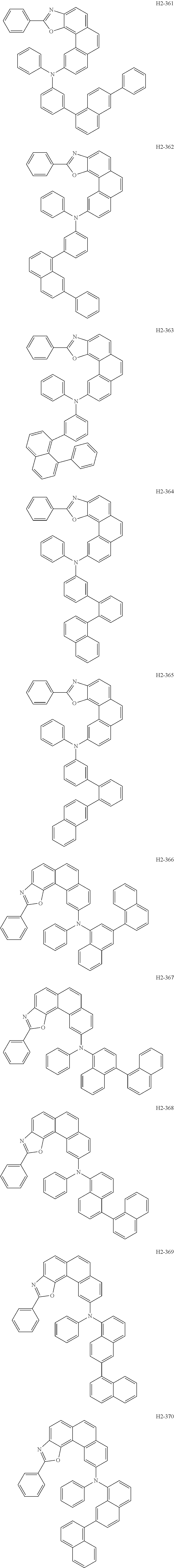

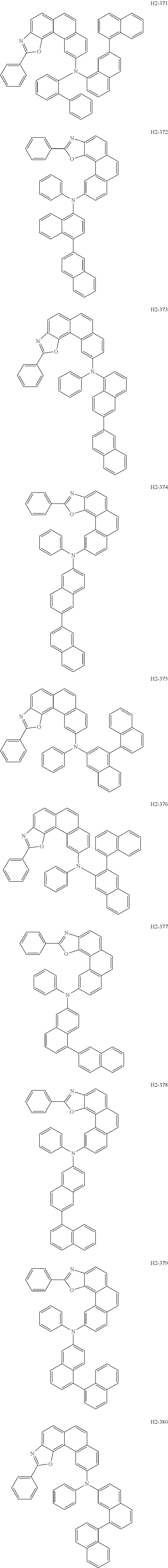

[chemical structure]

In the compounds above, Dₙ means that n number of hydrogens are replaced with deuterium, and n represents an integer from 1 to the maximum number of hydrogens in the compound.

According to one embodiment, the compound represented by Formula 2-2 may be at least one selected from the following compounds, but is not limited thereto.

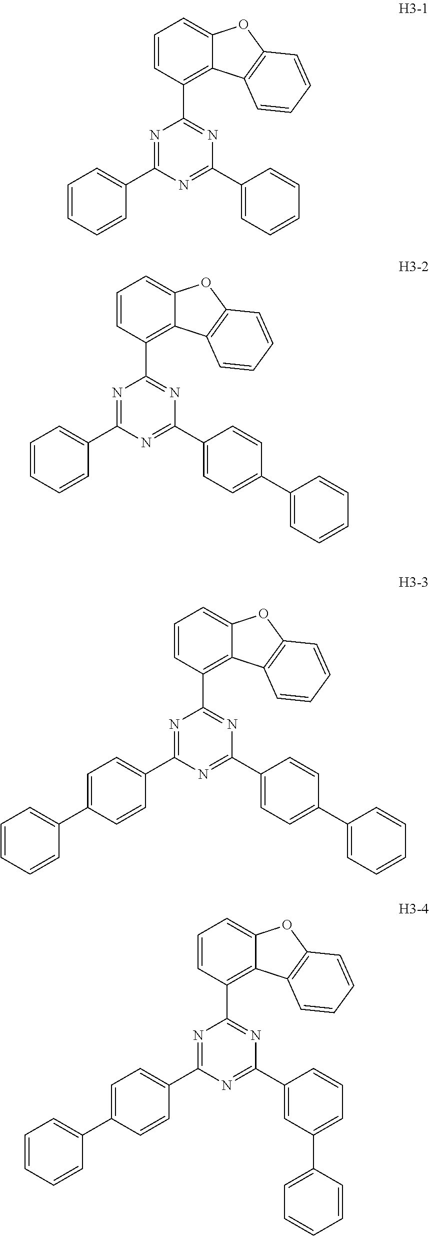 [SMILES: c1ccc(-c2nc(-c3ccccc3)nc(-c3cccc4oc5ccccc5c34)n2)cc1 ; c1ccc(-c2ccc(-c3nc(-c4ccccc4)nc(-c4cccc5oc6ccccc6c45)n3)cc2)cc1 ; c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4cccc(-c5ccccc5)c4)nc(-c4cccc5oc6ccccc6c45)n3)cc2)cc1]

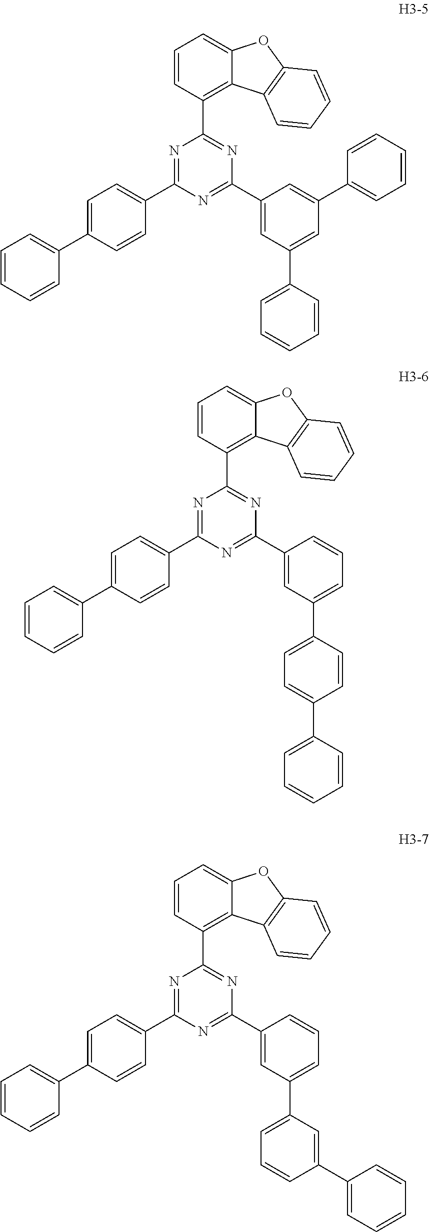

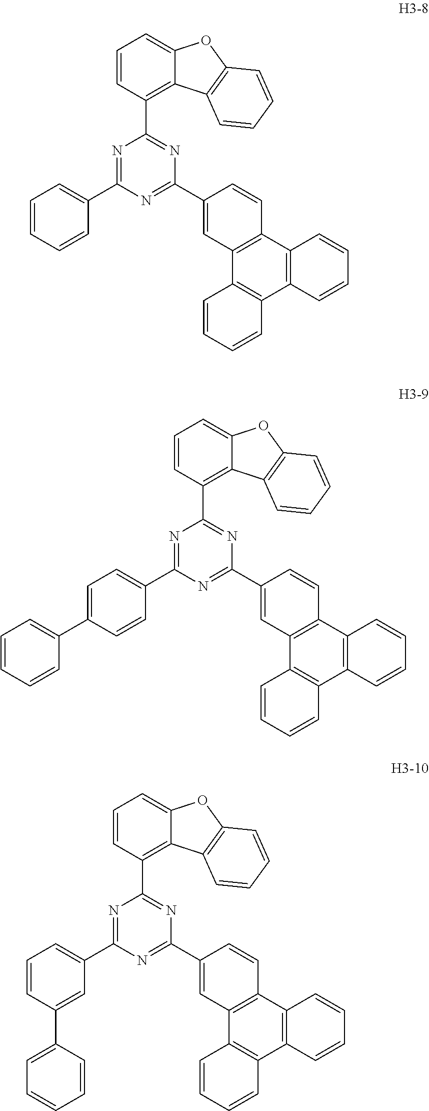 [SMILES: c1ccc(-c2nc(-c3ccc4c5ccccc5c5ccccc5c4c3)nc(-c3cccc4oc5ccccc5c34)n2)cc1 ; c1ccc(-c2ccc(-c3nc(-c4ccc5c6ccccc6c6ccccc6c5c4)nc(-c4cccc5oc6ccccc6c45)n3)cc2)cc1 ; c1ccc(-c2cccc(-c3nc(-c4ccc5c6ccccc6c6ccccc6c5c4)nc(-c4cccc5oc6ccccc6c45)n3)c2)cc1]

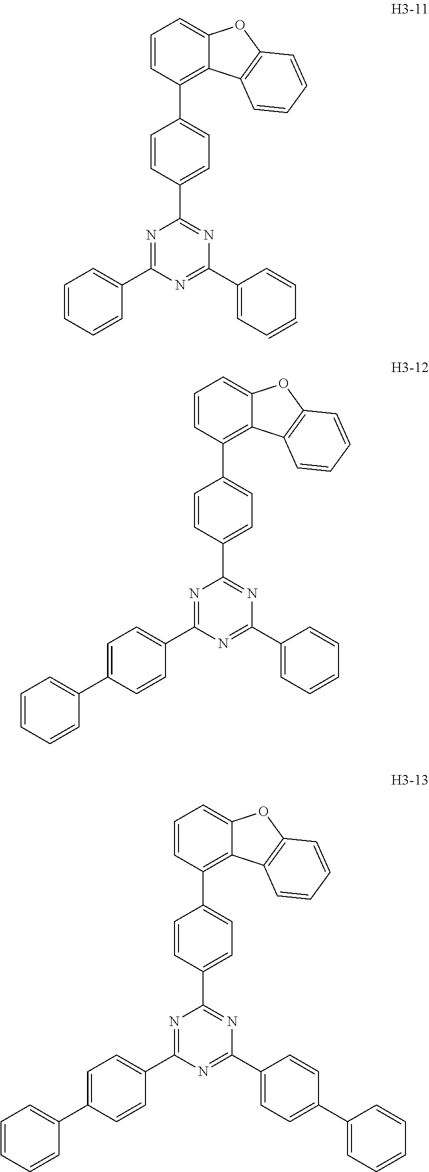 [SMILES: c1ccc(-c2nc(-c3ccccc3)nc(-c3ccc(-c4cccc5oc6ccccc6c45)cc3)n2)cc1 ; c1ccc(-c2ccc(-c3nc(-c4ccccc4)nc(-c4ccc(-c5cccc6oc7ccccc7c56)cc4)n3)cc2)cc1 ; c1ccc(-c2ccc(-c3nc(-c4ccc(-c5ccccc5)cc4)nc(-c4ccc(-c5cccc6oc7ccccc7c56)cc4)n3)cc2)cc1]

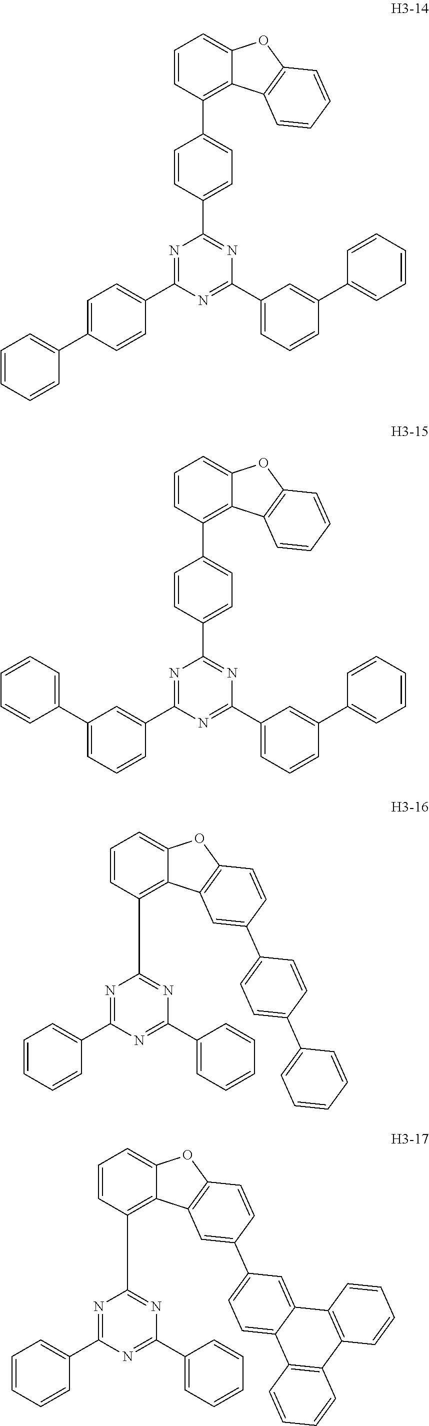 [SMILES: c1ccc(-c2ccc(-c3nc(-c4ccc(-c5cccc6oc7ccccc7c56)cc4)nc(-c4cccc(-c5ccccc5)c4)n3)cc2)cc1 ; c1ccc(-c2cccc(-c3nc(-c4ccc(-c5cccc6oc7ccccc7c56)cc4)nc(-c4cccc(-c5ccccc5)c4)n3)c2)cc1 ; c1ccc(-c2ccc(-c3ccc4oc5cccc(-c6nc(-c7ccccc7)nc(-c7ccccc7)n6)c5c4c3)cc2)cc1 ; c1ccc(-c2nc(-c3ccccc3)nc(-c3cccc4oc5ccc(-c6ccc7c8ccccc8c8ccccc8c7c6)cc5c34)n2)cc1]

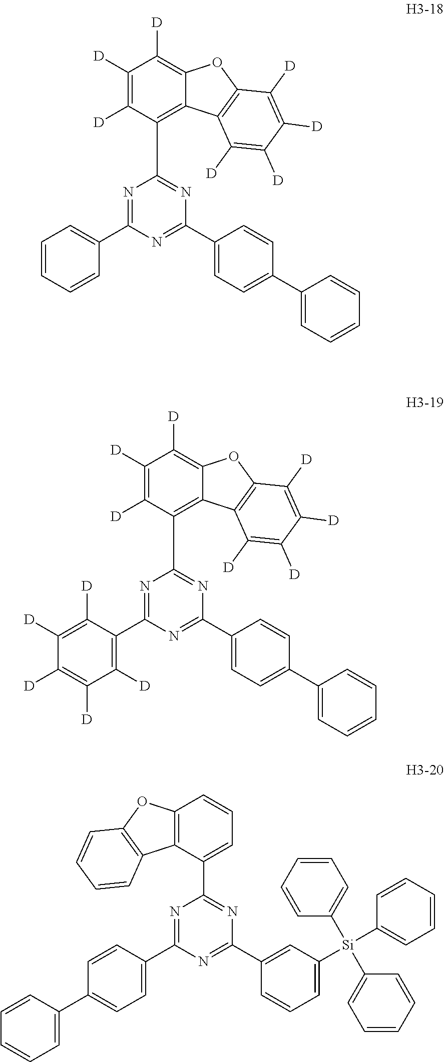 [SMILES: [2H]c1c([2H])c([2H])c2c(oc3c([2H])c([2H])c([2H])c(-c4nc(-c5ccccc5)nc(-c5ccc(-c6ccccc6)cc5)n4)c32)c1[2H] ; [2H]c1c([2H])c([2H])c(-c2nc(-c3ccc(-c4ccccc4)cc3)nc(-c3c([2H])c([2H])c([2H])c4oc5c([2H])c([2H])c([2H])c([2H])c5c34)n2)c([2H])c1[2H] ; c1ccc(-c2ccc(-c3nc(-c4cccc([Si](c5ccccc5)(c5ccccc5)c5ccccc5)c4)nc(-c4cccc5oc6ccccc6c45)n3)cc2)cc1]

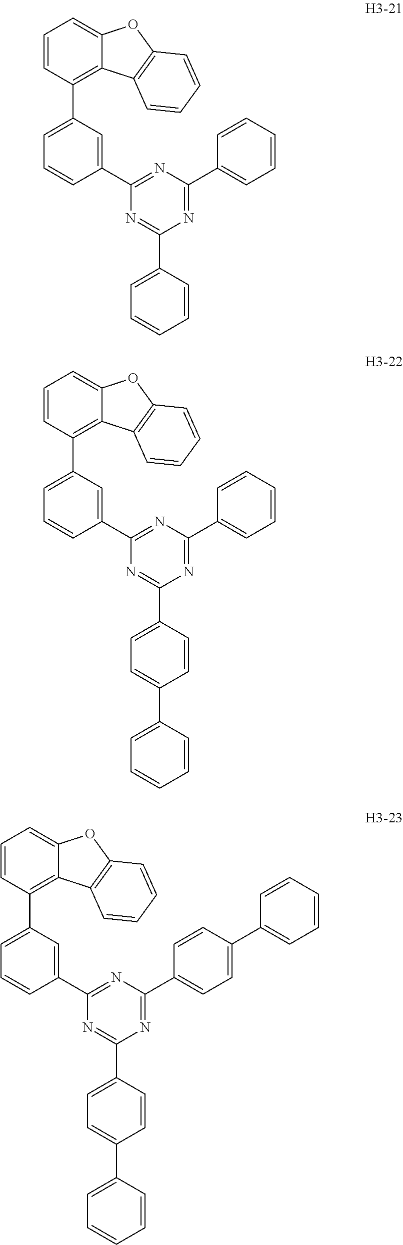 [SMILES: c1ccc(-c2nc(-c3ccccc3)nc(-c3cccc(-c4cccc5oc6ccccc6c45)c3)n2)cc1 ; c1ccc(-c2ccc(-c3nc(-c4ccccc4)nc(-c4cccc(-c5cccc6oc7ccccc7c56)c4)n3)cc2)cc1 ; c1ccc(-c2ccc(-c3nc(-c4ccc(-c5ccccc5)cc4)nc(-c4cccc(-c5cccc6oc7ccccc7c56)c4)n3)cc2)cc1]

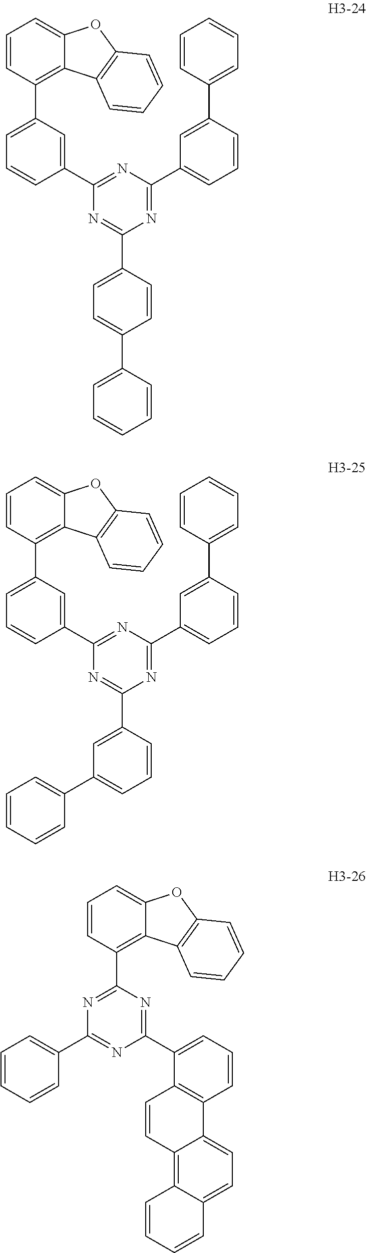 [SMILES: c1ccc(-c2ccc(-c3nc(-c4cccc(-c5ccccc5)c4)nc(-c4cccc(-c5cccc6oc7ccccc7c56)c4)n3)cc2)cc1 ; c1ccc(-c2cccc(-c3nc(-c4cccc(-c5ccccc5)c4)nc(-c4cccc(-c5cccc6oc7ccccc7c56)c4)n3)c2)cc1 ; c1ccc(-c2nc(-c3cccc4c3ccc3c5ccccc5ccc43)nc(-c3cccc4oc5ccccc5c34)n2)cc1]

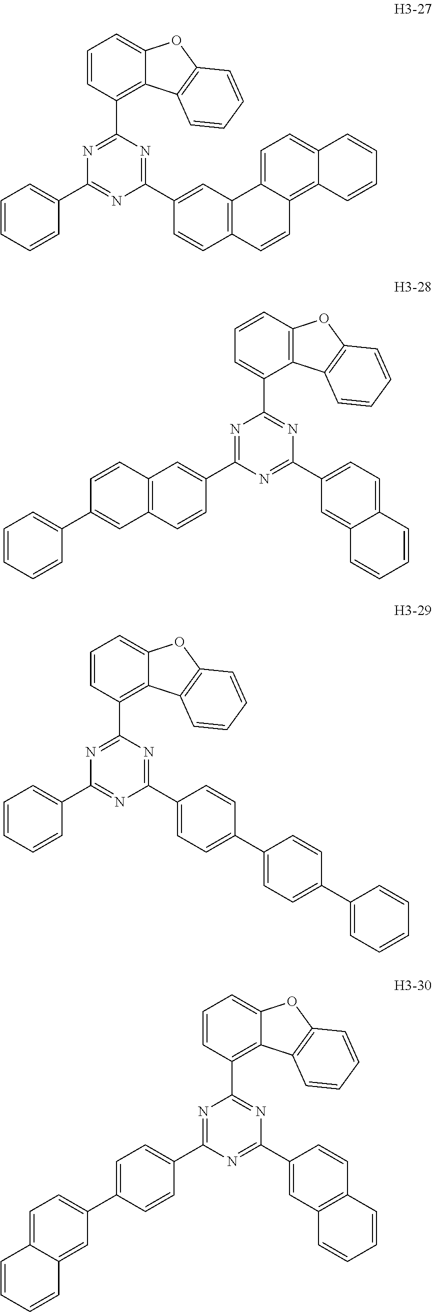 [SMILES: c1ccc(-c2nc(-c3ccc4ccc5c6ccccc6ccc5c4c3)nc(-c3cccc4oc5ccccc5c34)n2)cc1 ; c1ccc(-c2ccc3cc(-c4nc(-c5ccc6ccccc6c5)nc(-c5cccc6oc7ccccc7c56)n4)ccc3c2)cc1 ; c1ccc(-c2ccc(-c3ccc(-c4nc(-c5ccccc5)nc(-c5cccc6oc7ccccc7c56)n4)cc3)cc2)cc1 ; c1ccc2cc(-c3ccc(-c4nc(-c5ccc6ccccc6c5)nc(-c5cccc6oc7ccccc7c56)n4)cc3)ccc2c1]

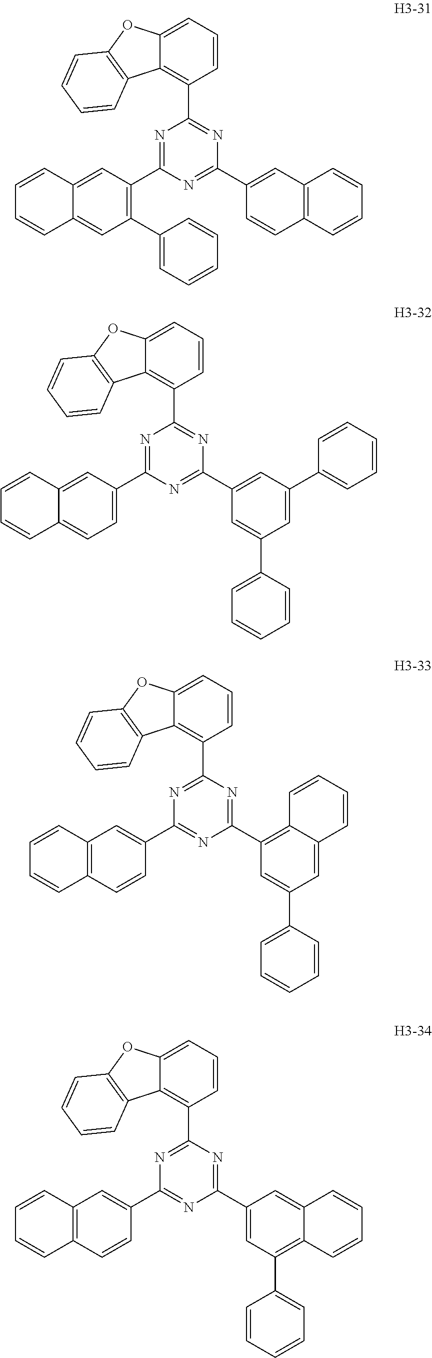

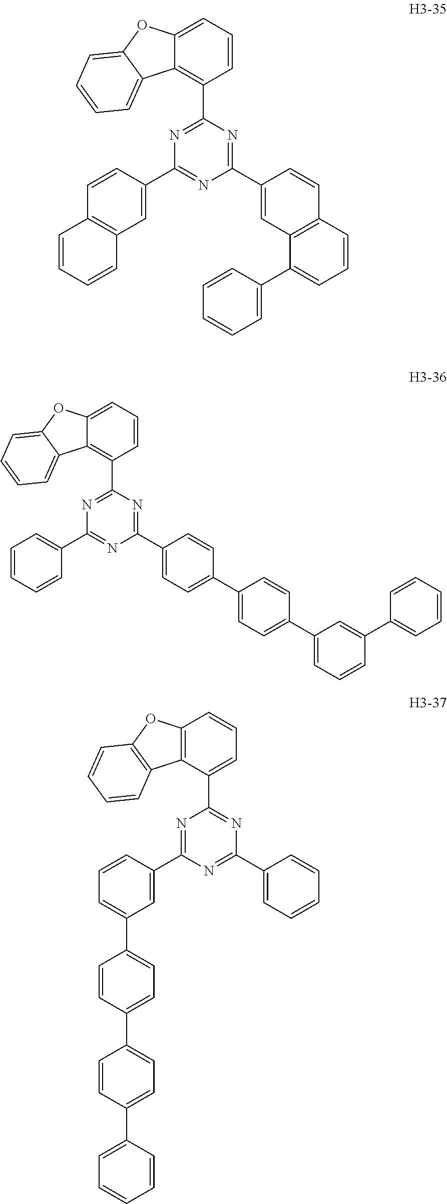 [SMILES: c1ccc(-c2cccc3ccc(-c4nc(-c5ccc6ccccc6c5)nc(-c5cccc6oc7ccccc7c56)n4)cc23)cc1 ; c1ccc(-c2cccc(-c3ccc(-c4ccc(-c5nc(-c6ccccc6)nc(-c6cccc7oc8ccccc8c67)n5)cc4)cc3)c2)cc1 ; c1ccc(-c2ccc(-c3ccc(-c4cccc(-c5nc(-c6ccccc6)nc(-c6cccc7oc8ccccc8c67)n5)c4)cc3)cc2)cc1]

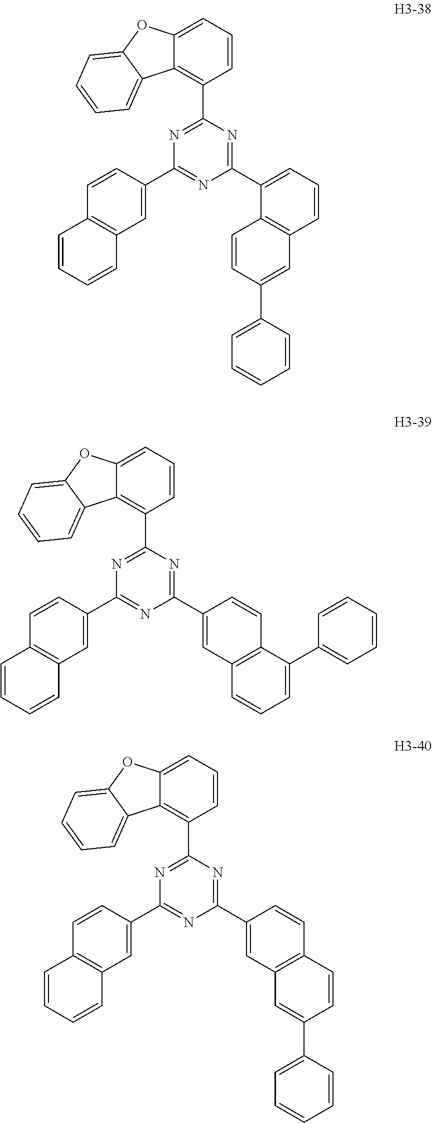 [SMILES: c1ccc(-c2ccc3c(-c4nc(-c5ccc6ccccc6c5)nc(-c5cccc6oc7ccccc7c56)n4)cccc3c2)cc1 ; c1ccc(-c2cccc3cc(-c4nc(-c5ccc6ccccc6c5)nc(-c5cccc6oc7ccccc7c56)n4)ccc23)cc1 ; c1ccc(-c2ccc3ccc(-c4nc(-c5ccc6ccccc6c5)nc(-c5cccc6oc7ccccc7c56)n4)cc3c2)cc1]

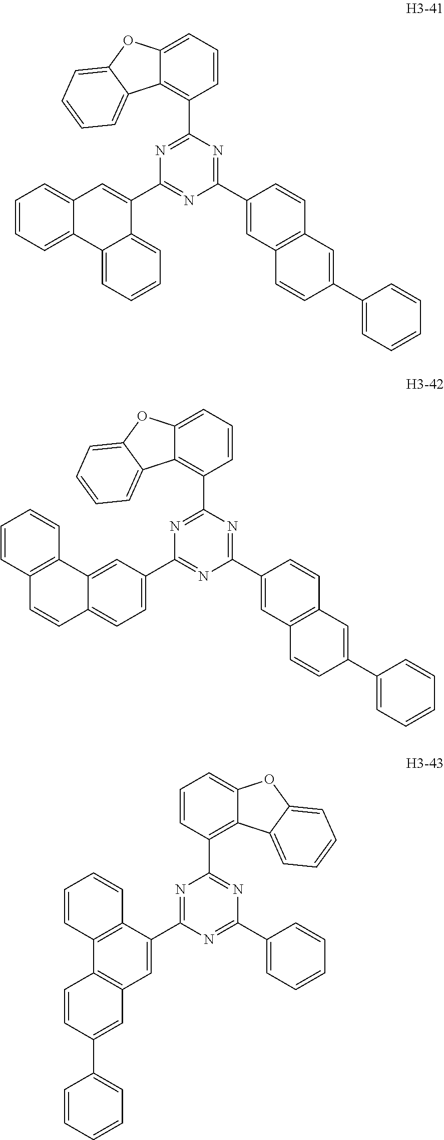 [SMILES: c1ccc(-c2ccc3cc(-c4nc(-c5cc6ccccc6c6ccccc56)nc(-c5cccc6oc7ccccc7c56)n4)ccc3c2)cc1 ; c1ccc(-c2ccc3cc(-c4nc(-c5ccc6ccc7ccccc7c6c5)nc(-c5cccc6oc7ccccc7c56)n4)ccc3c2)cc1 ; c1ccc(-c2ccc3c(c2)cc(-c2nc(-c4ccccc4)nc(-c4cccc5oc6ccccc6c45)n2)c2ccccc23)cc1]

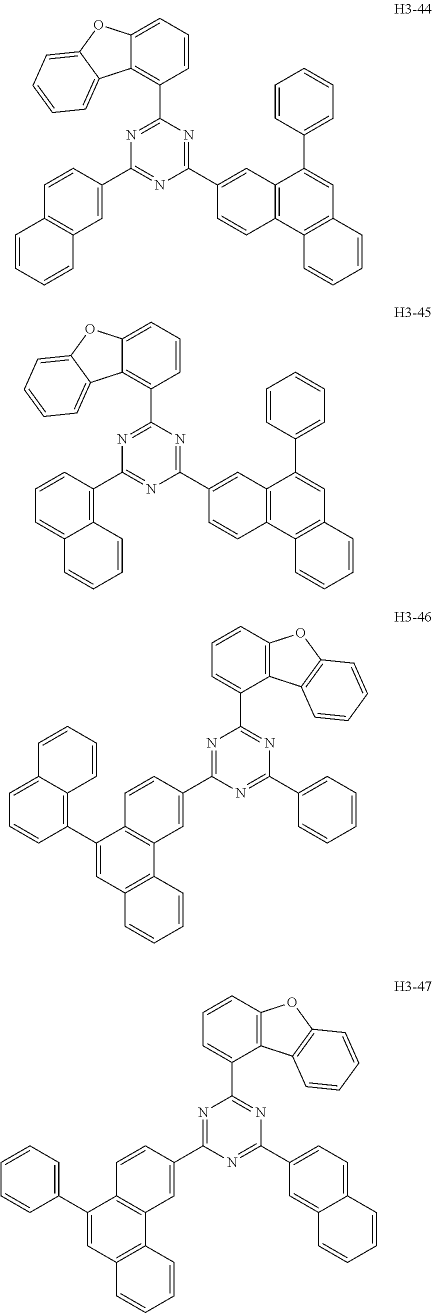 [SMILES: c1ccc(-c2cc3ccccc3c3ccc(-c4nc(-c5ccc6ccccc6c5)nc(-c5cccc6oc7ccccc7c56)n4)cc23)cc1 ; c1ccc(-c2cc3ccccc3c3ccc(-c4nc(-c5cccc6ccccc56)nc(-c5cccc6oc7ccccc7c56)n4)cc23)cc1 ; c1ccc(-c2nc(-c3ccc4c(-c5cccc6ccccc56)cc5ccccc5c4c3)nc(-c3cccc4oc5ccccc5c34)n2)cc1 ; c1ccc(-c2cc3ccccc3c3cc(-c4nc(-c5ccc6ccccc6c5)nc(-c5cccc6oc7ccccc7c56)n4)ccc23)cc1]

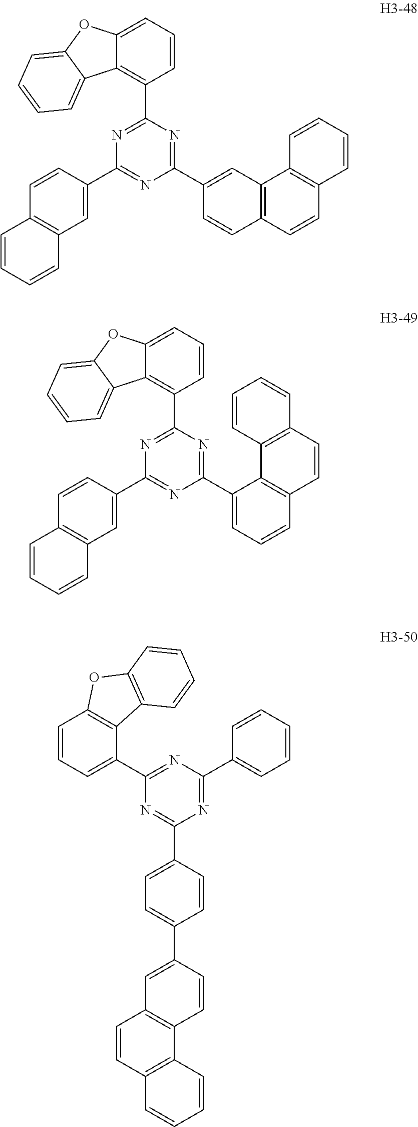 [SMILES: c1ccc2cc(-c3nc(-c4ccc5ccc6ccccc6c5c4)nc(-c4cccc5oc6ccccc6c45)n3)ccc2c1 ; c1ccc2cc(-c3nc(-c4cccc5ccc6ccccc6c45)nc(-c4cccc5oc6ccccc6c45)n3)ccc2c1 ; c1ccc(-c2nc(-c3ccc(-c4ccc5c(ccc6ccccc65)c4)cc3)nc(-c3cccc4oc5ccccc5c34)n2)cc1]

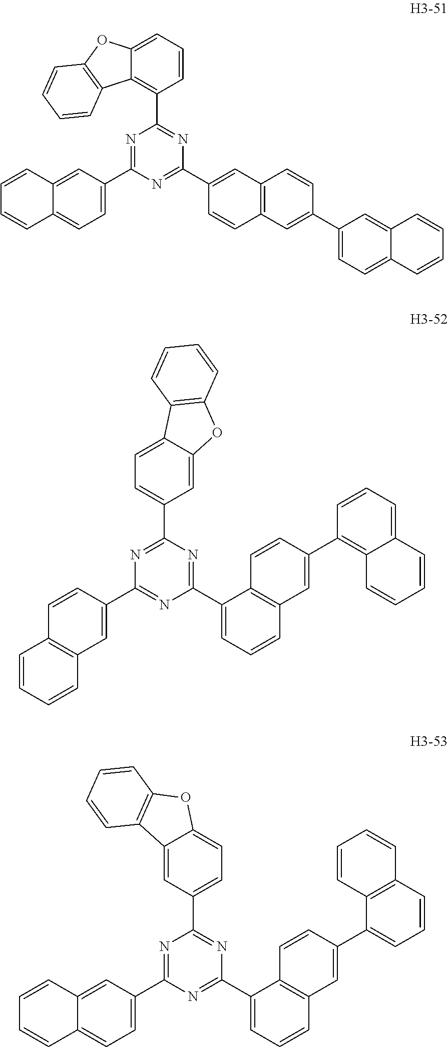 [SMILES: c1ccc2cc(-c3ccc4cc(-c5nc(-c6ccc7ccccc7c6)nc(-c6cccc7oc8ccccc8c67)n5)ccc4c3)ccc2c1 ; c1ccc2cc(-c3nc(-c4ccc5c(c4)oc4ccccc45)nc(-c4cccc5cc(-c6cccc7ccccc67)ccc45)n3)ccc2c1 ; c1ccc2cc(-c3nc(-c4ccc5oc6ccccc6c5c4)nc(-c4cccc5cc(-c6cccc7ccccc67)ccc45)n3)ccc2c1]

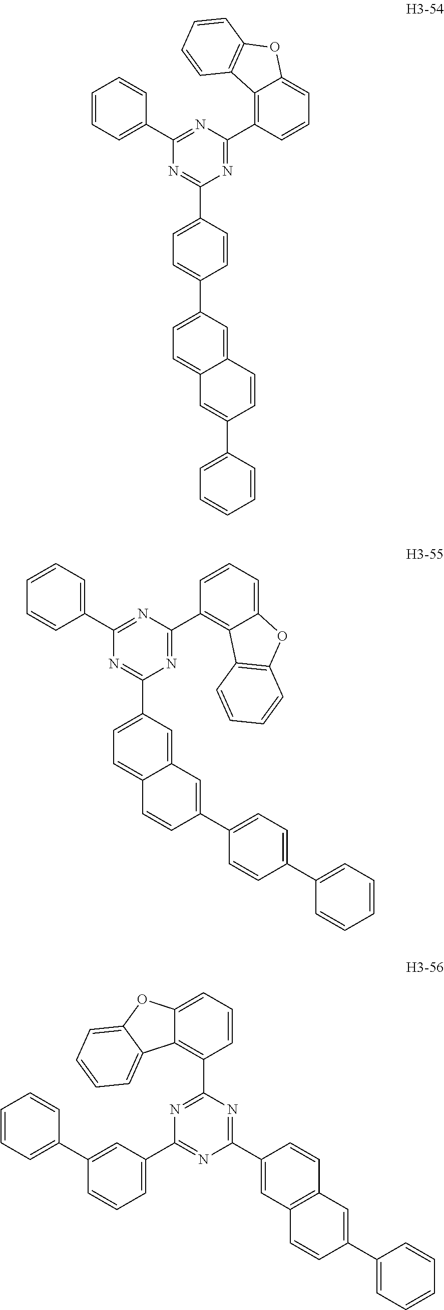 [SMILES: c1ccc(-c2ccc3cc(-c4ccc(-c5nc(-c6ccccc6)nc(-c6cccc7oc8ccccc8c67)n5)cc4)ccc3c2)cc1 ; c1ccc(-c2ccc(-c3ccc4ccc(-c5nc(-c6ccccc6)nc(-c6cccc7oc8ccccc8c67)n5)cc4c3)cc2)cc1 ; c1ccc(-c2cccc(-c3nc(-c4ccc5cc(-c6ccccc6)ccc5c4)nc(-c4cccc5oc6ccccc6c45)n3)c2)cc1]

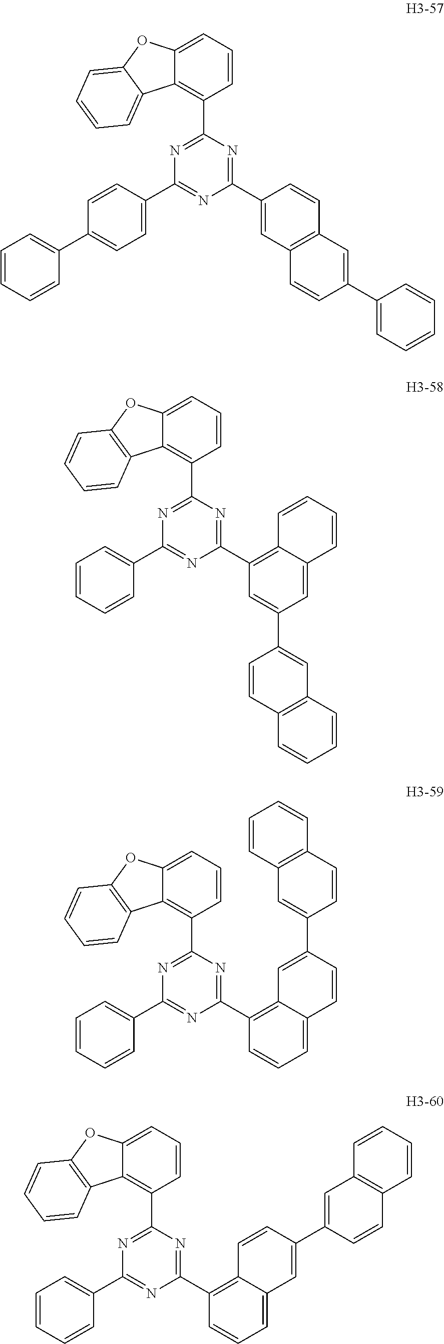 [SMILES: c1ccc(-c2ccc(-c3nc(-c4ccc5cc(-c6ccccc6)ccc5c4)nc(-c4cccc5oc6ccccc6c45)n3)cc2)cc1 ; c1ccc(-c2nc(-c3cc(-c4ccc5ccccc5c4)cc4ccccc34)nc(-c3cccc4oc5ccccc5c34)n2)cc1 ; c1ccc(-c2nc(-c3cccc4ccc(-c5ccc6ccccc6c5)cc34)nc(-c3cccc4oc5ccccc5c34)n2)cc1 ; c1ccc(-c2nc(-c3cccc4cc(-c5ccc6ccccc6c5)ccc34)nc(-c3cccc4oc5ccccc5c34)n2)cc1]

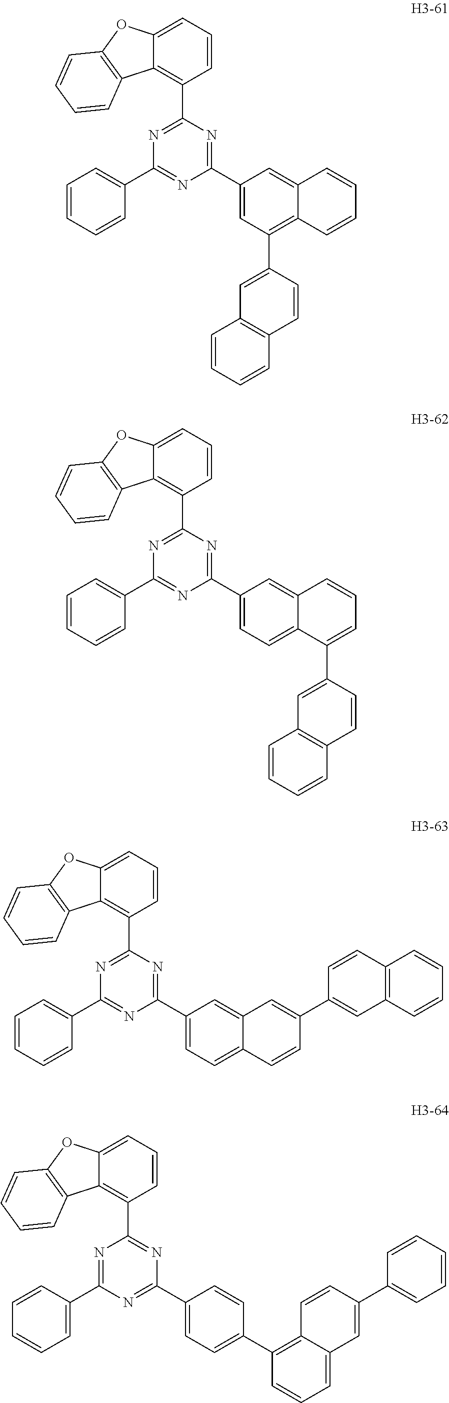 [SMILES: c1ccc(-c2nc(-c3cc(-c4ccc5ccccc5c4)c4ccccc4c3)nc(-c3cccc4oc5ccccc5c34)n2)cc1 ; c1ccc(-c2nc(-c3ccc4c(-c5ccc6ccccc6c5)cccc4c3)nc(-c3cccc4oc5ccccc5c34)n2)cc1 ; c1ccc(-c2nc(-c3ccc4ccc(-c5ccc6ccccc6c5)cc4c3)nc(-c3cccc4oc5ccccc5c34)n2)cc1 ; c1ccc(-c2ccc3c(-c4ccc(-c5nc(-c6ccccc6)nc(-c6cccc7oc8ccccc8c67)n5)cc4)cccc3c2)cc1]

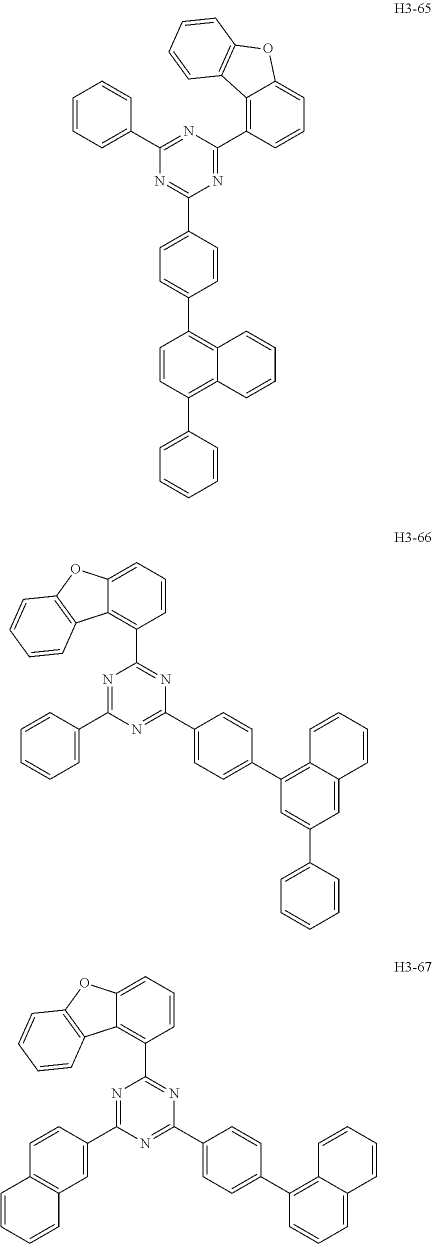 [SMILES: c1ccc(-c2nc(-c3ccc(-c4ccc(-c5ccccc5)c5ccccc45)cc3)nc(-c3cccc4oc5ccccc5c34)n2)cc1 ; c1ccc(-c2cc(-c3ccc(-c4nc(-c5ccccc5)nc(-c5cccc6oc7ccccc7c56)n4)cc3)c3ccccc3c2)cc1 ; c1ccc2cc(-c3nc(-c4ccc(-c5cccc6ccccc56)cc4)nc(-c4cccc5oc6ccccc6c45)n3)ccc2c1]

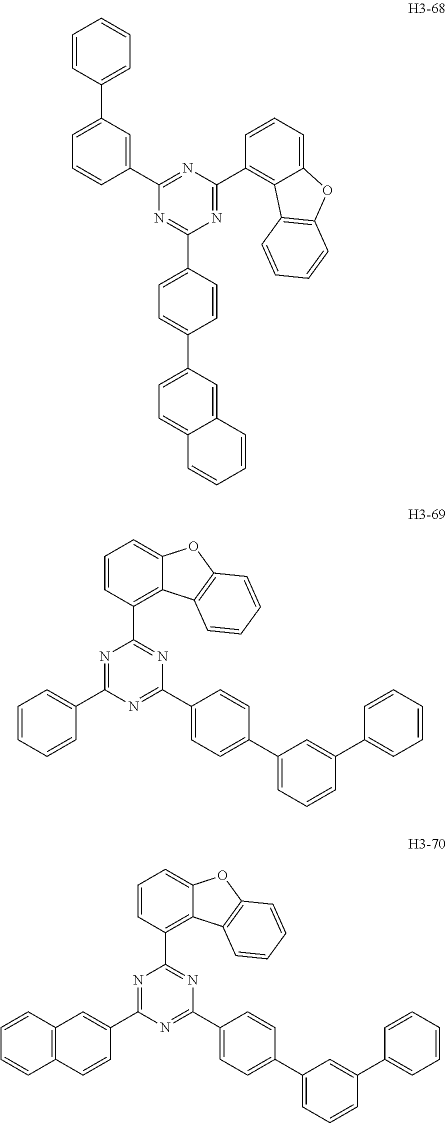 [SMILES: c1ccc(-c2cccc(-c3nc(-c4ccc(-c5ccc6ccccc6c5)cc4)nc(-c4cccc5oc6ccccc6c45)n3)c2)cc1 ; c1ccc(-c2cccc(-c3ccc(-c4nc(-c5ccccc5)nc(-c5cccc6oc7ccccc7c56)n4)cc3)c2)cc1 ; c1ccc(-c2cccc(-c3ccc(-c4nc(-c5ccc6ccccc6c5)nc(-c5cccc6oc7ccccc7c56)n4)cc3)c2)cc1]

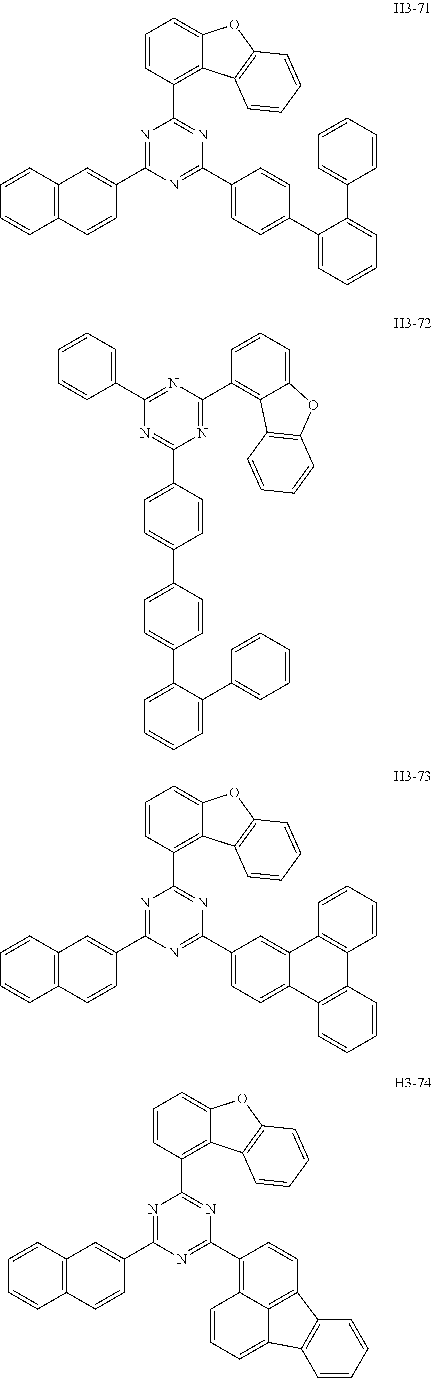

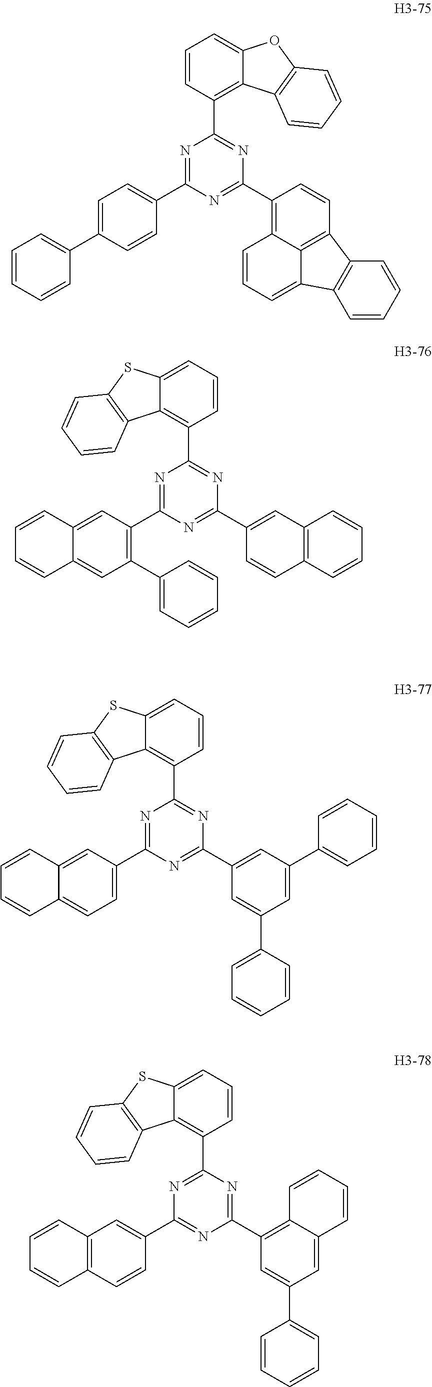 [SMILES: c1ccc(-c2ccc(-c3nc(-c4ccc5c6c(cccc46)-c4ccccc4-5)nc(-c4cccc5oc6ccccc6c45)n3)cc2)cc1 ; c1ccc(-c2cc3ccccc3cc2-c2nc(-c3ccc4ccccc4c3)nc(-c3cccc4sc5ccccc5c34)n2)cc1 ; c1ccc(-c2cc(-c3ccccc3)cc(-c3nc(-c4ccc5ccccc5c4)nc(-c4cccc5sc6ccccc6c45)n3)c2)cc1 ; c1ccc(-c2cc(-c3nc(-c4ccc5ccccc5c4)nc(-c4cccc5sc6ccccc6c45)n3)c3ccccc3c2)cc1]

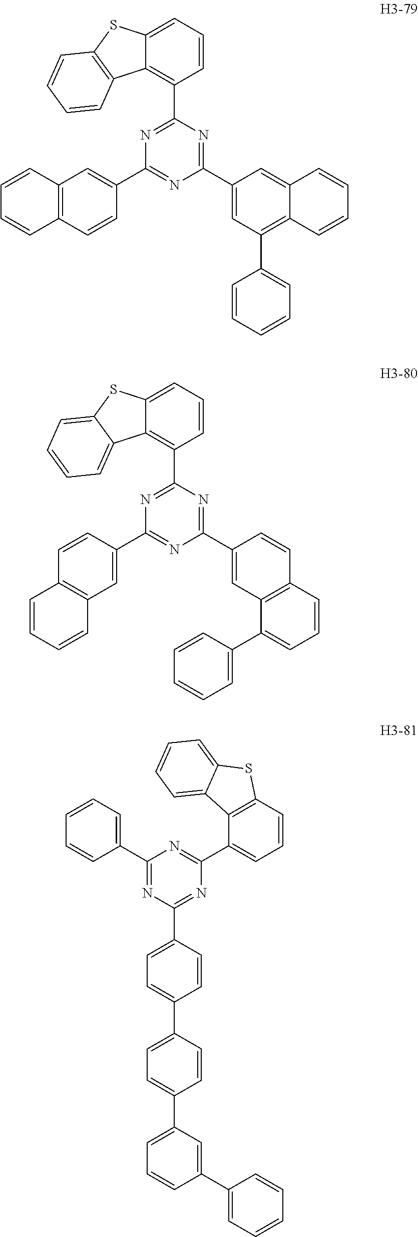

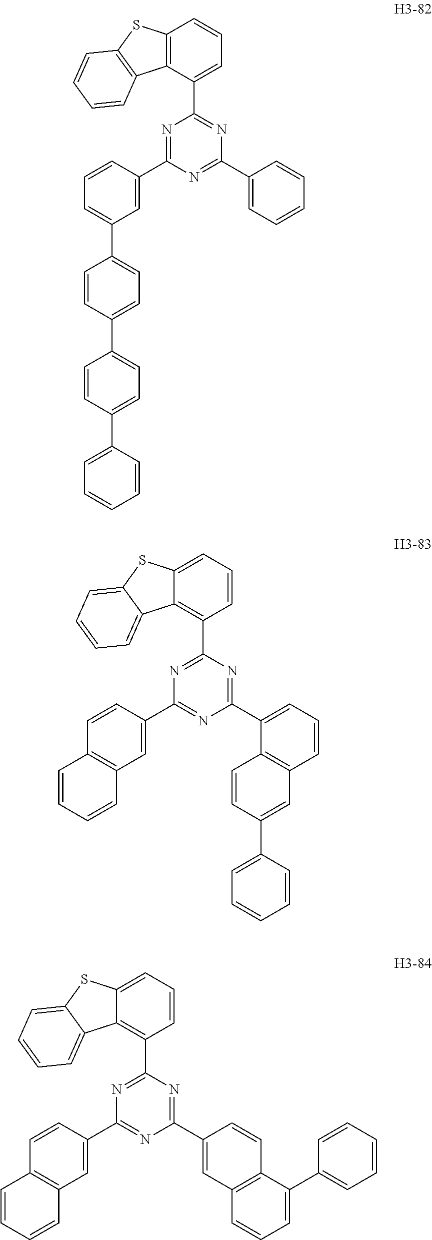 [SMILES: c1ccc(-c2ccc(-c3ccc(-c4cccc(-c5nc(-c6ccccc6)nc(-c6cccc7sc8ccccc8c67)n5)c4)cc3)cc2)cc1 ; c1ccc(-c2ccc3c(-c4nc(-c5ccc6ccccc6c5)nc(-c5cccc6sc7ccccc7c56)n4)cccc3c2)cc1 ; c1ccc(-c2cccc3cc(-c4nc(-c5ccc6ccccc6c5)nc(-c5cccc6sc7ccccc7c56)n4)ccc23)cc1]

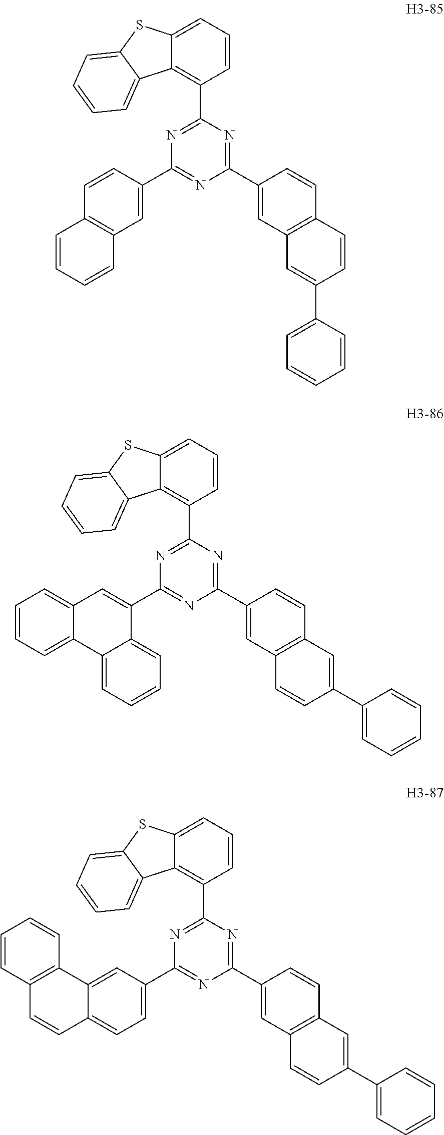 [SMILES: c1ccc(-c2ccc3ccc(-c4nc(-c5ccc6ccccc6c5)nc(-c5cccc6sc7ccccc7c56)n4)cc3c2)cc1 ; c1ccc(-c2ccc3cc(-c4nc(-c5cc6ccccc6c6ccccc56)nc(-c5cccc6sc7ccccc7c56)n4)ccc3c2)cc1 ; c1ccc(-c2ccc3cc(-c4nc(-c5ccc6ccc7ccccc7c6c5)nc(-c5cccc6sc7ccccc7c56)n4)ccc3c2)cc1]

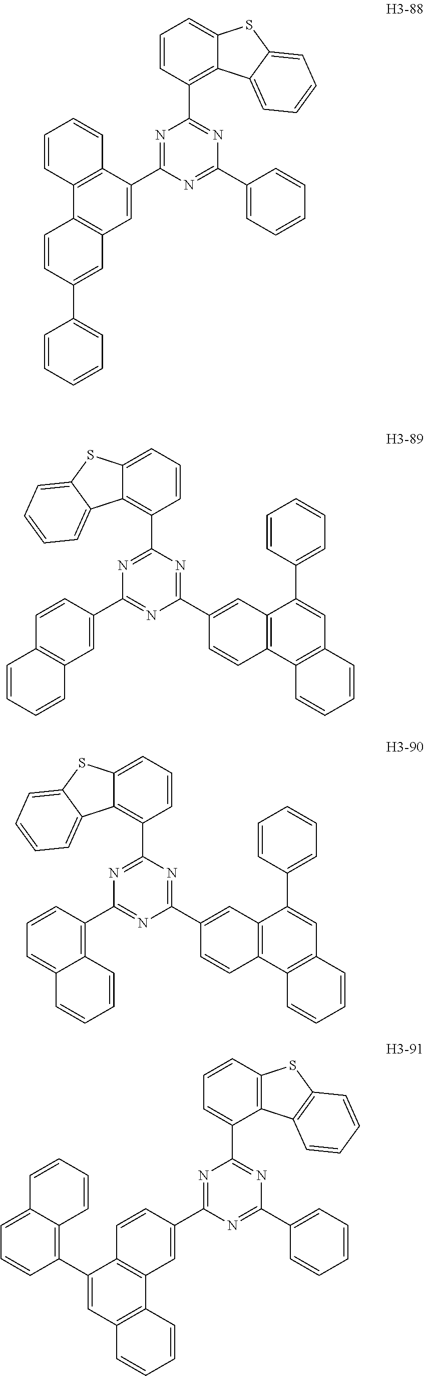 [SMILES: c1ccc(-c2ccc3c(c2)cc(-c2nc(-c4ccccc4)nc(-c4cccc5sc6ccccc6c45)n2)c2ccccc23)cc1 ; c1ccc(-c2cc3ccccc3c3ccc(-c4nc(-c5ccc6ccccc6c5)nc(-c5cccc6sc7ccccc7c56)n4)cc23)cc1 ; c1ccc(-c2cc3ccccc3c3ccc(-c4nc(-c5cccc6ccccc56)nc(-c5cccc6sc7ccccc7c56)n4)cc23)cc1 ; c1ccc(-c2nc(-c3ccc4c(-c5cccc6ccccc56)cc5ccccc5c4c3)nc(-c3cccc4sc5ccccc5c34)n2)cc1]

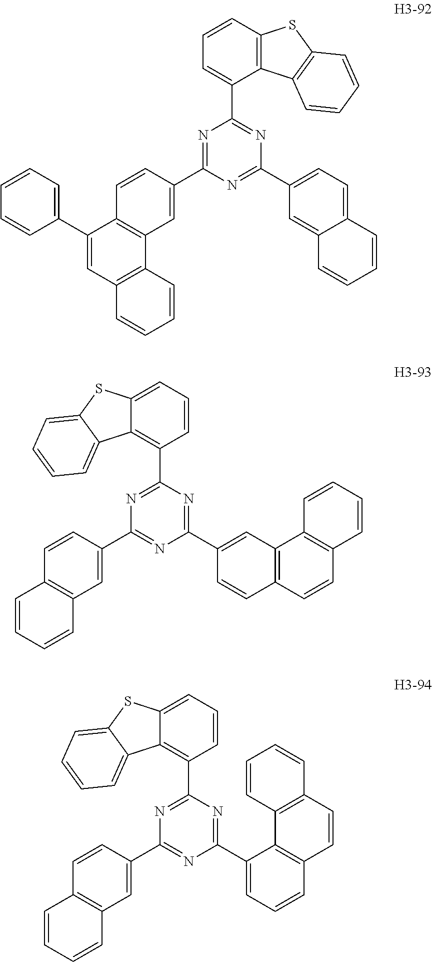 [SMILES: c1ccc(-c2cc3ccccc3c3cc(-c4nc(-c5ccc6ccccc6c5)nc(-c5cccc6sc7ccccc7c56)n4)ccc23)cc1 ; c1ccc2cc(-c3nc(-c4ccc5ccc6ccccc6c5c4)nc(-c4cccc5sc6ccccc6c45)n3)ccc2c1 ; c1ccc2cc(-c3nc(-c4cccc5ccc6ccccc6c45)nc(-c4cccc5sc6ccccc6c45)n3)ccc2c1]

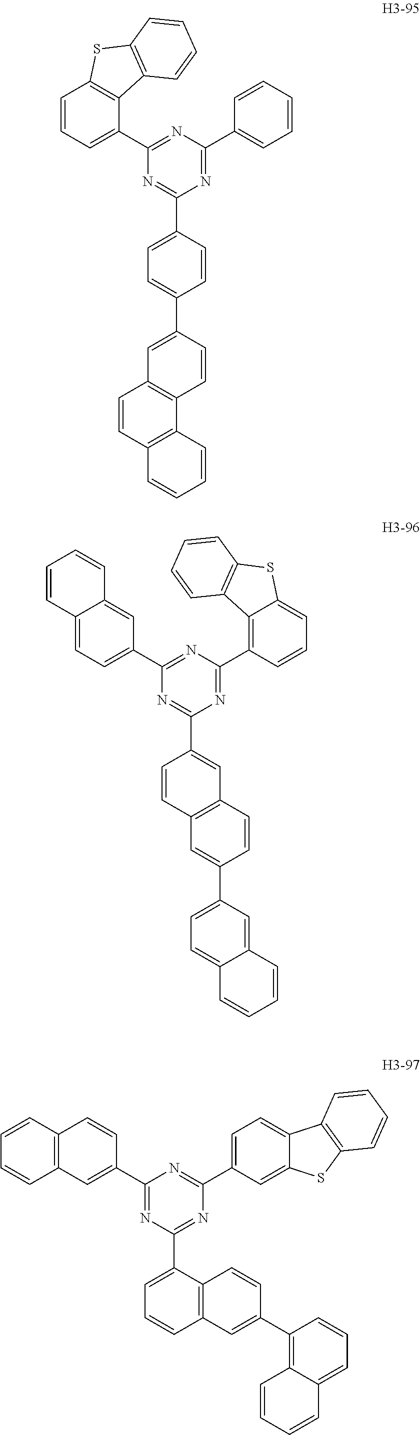

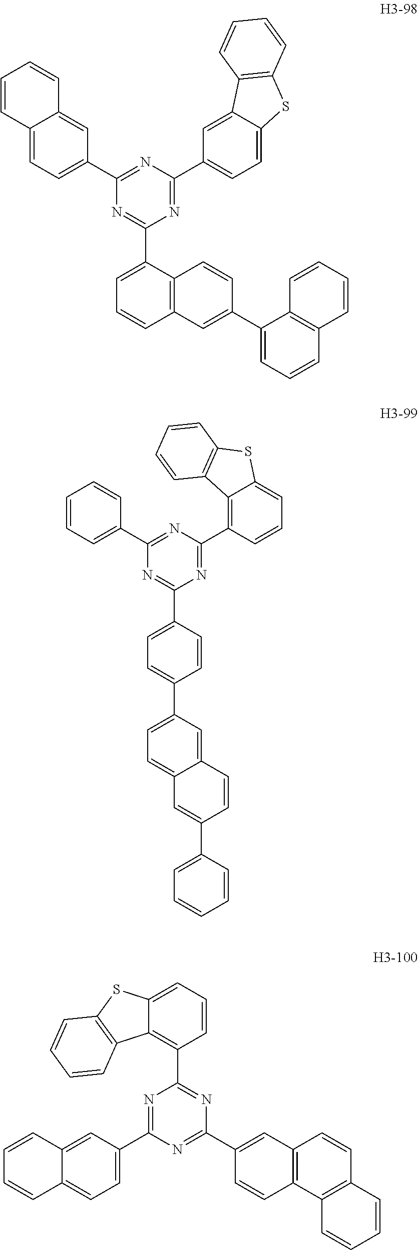 [SMILES: c1ccc2cc(-c3nc(-c4ccc5sc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6cccc7sc8ccccc8c67)n5)cc4)ccc3c2)cc1 ; c1ccc2cc(-c3nc(-c4ccc5c(ccc6ccccc65)c4)nc(-c4cccc5sc6ccccc6c45)n3)ccc2c1]

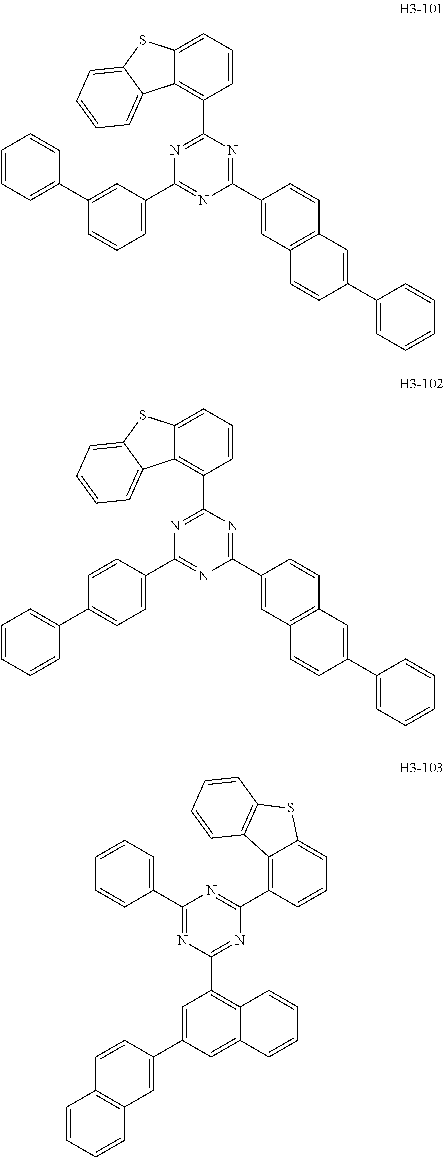 [SMILES: c1ccc(-c2cccc(-c3nc(-c4ccc5cc(-c6ccccc6)ccc5c4)nc(-c4cccc5sc6ccccc6c45)n3)c2)cc1 ; c1ccc(-c2ccc(-c3nc(-c4ccc5cc(-c6ccccc6)ccc5c4)nc(-c4cccc5sc6ccccc6c45)n3)cc2)cc1 ; c1ccc(-c2nc(-c3cc(-c4ccc5ccccc5c4)cc4ccccc34)nc(-c3cccc4sc5ccccc5c34)n2)cc1]

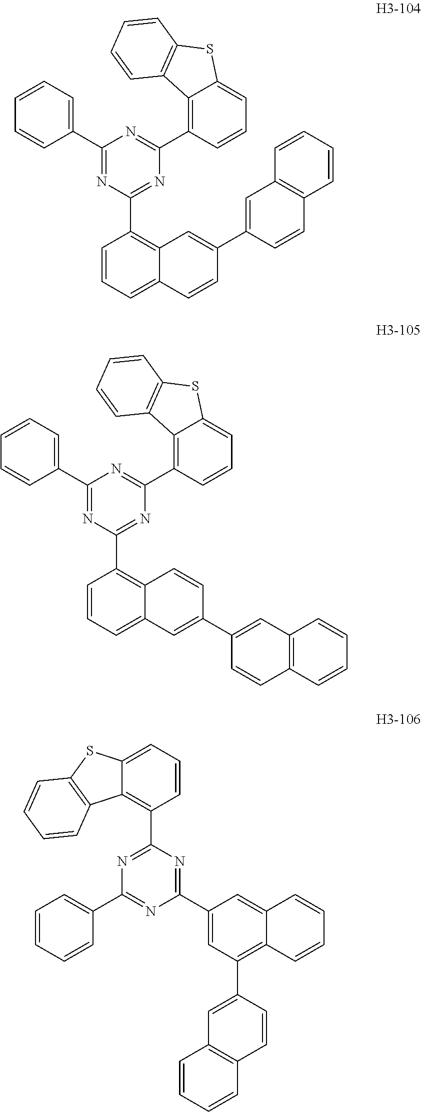 [SMILES: c1ccc(-c2nc(-c3cccc4ccc(-c5ccc6ccccc6c5)cc34)nc(-c3cccc4sc5ccccc5c34)n2)cc1 ; c1ccc(-c2nc(-c3cccc4cc(-c5ccc6ccccc6c5)ccc34)nc(-c3cccc4sc5ccccc5c34)n2)cc1 ; c1ccc(-c2nc(-c3cc(-c4ccc5ccccc5c4)c4ccccc4c3)nc(-c3cccc4sc5ccccc5c34)n2)cc1]

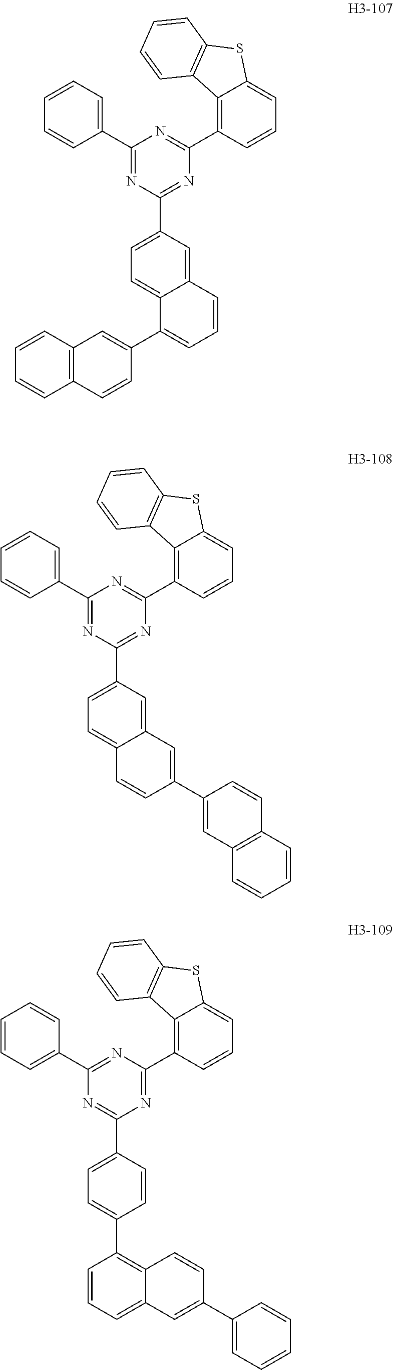 [SMILES: c1ccc(-c2nc(-c3ccc4c(-c5ccc6ccccc6c5)cccc4c3)nc(-c3cccc4sc5ccccc5c34)n2)cc1 ; c1ccc(-c2nc(-c3ccc4ccc(-c5ccc6ccccc6c5)cc4c3)nc(-c3cccc4sc5ccccc5c34)n2)cc1 ; c1ccc(-c2ccc3c(-c4ccc(-c5nc(-c6ccccc6)nc(-c6cccc7sc8ccccc8c67)n5)cc4)cccc3c2)cc1]

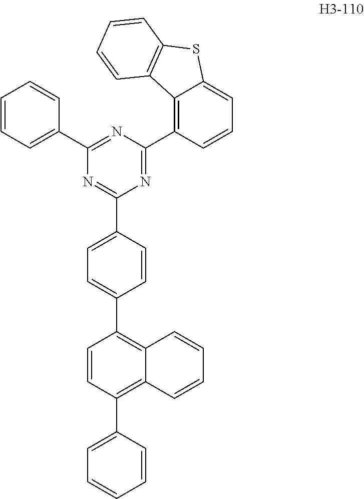 [SMILES: c1ccc(-c2nc(-c3ccc(-c4ccc(-c5ccccc5)c5ccccc45)cc3)nc(-c3cccc4sc5ccccc5c34)n2)cc1]

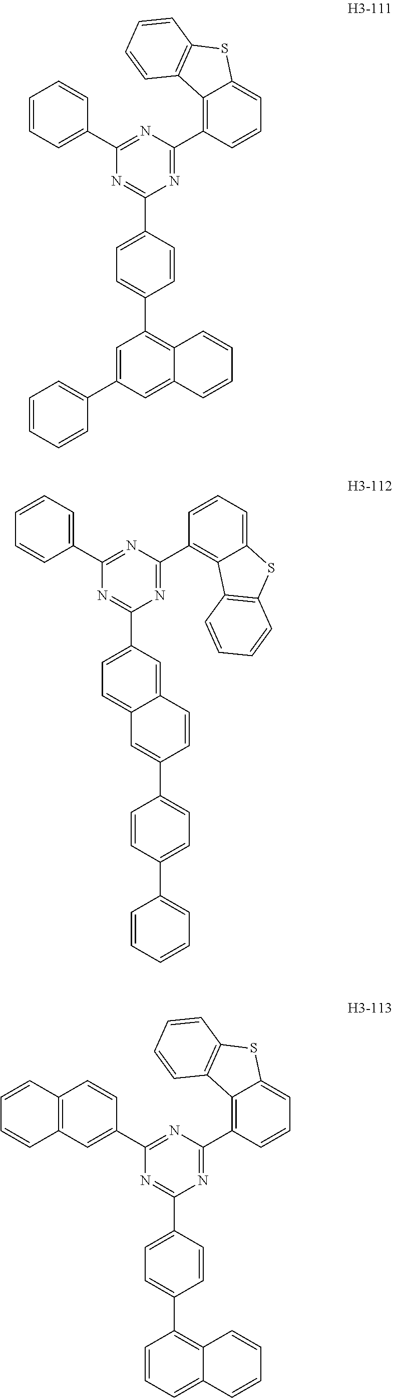 [SMILES: c1ccc(-c2cc(-c3ccc(-c4nc(-c5ccccc5)nc(-c5cccc6sc7ccccc7c56)n4)cc3)c3ccccc3c2)cc1 ; c1ccc(-c2ccc(-c3ccc4cc(-c5nc(-c6ccccc6)nc(-c6cccc7sc8ccccc8c67)n5)ccc4c3)cc2)cc1 ; c1ccc2cc(-c3nc(-c4ccc(-c5cccc6ccccc56)cc4)nc(-c4cccc5sc6ccccc6c45)n3)ccc2c1]

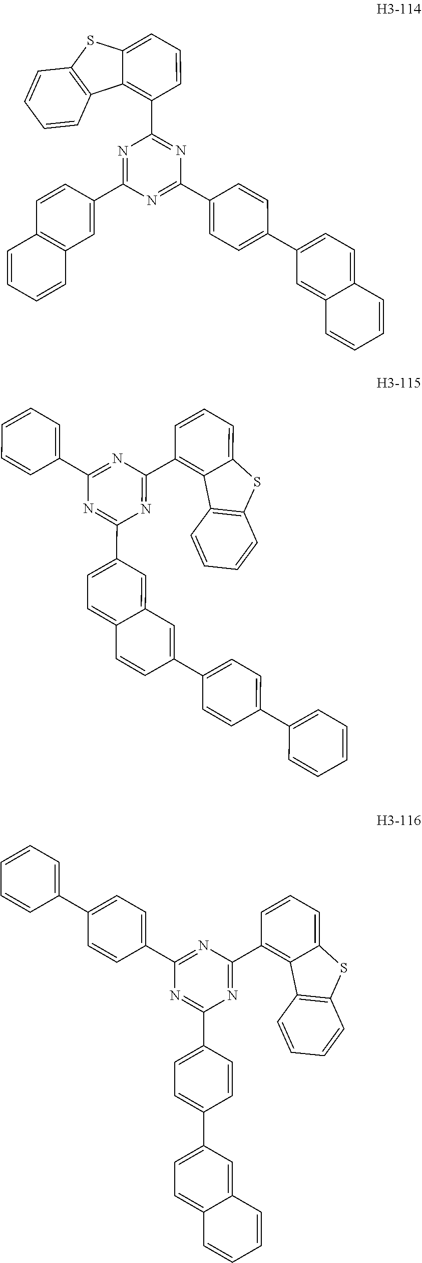 [SMILES: c1ccc2cc(-c3ccc(-c4nc(-c5ccc6ccccc6c5)nc(-c5cccc6sc7ccccc7c56)n4)cc3)ccc2c1 ; c1ccc(-c2ccc(-c3ccc4ccc(-c5nc(-c6ccccc6)nc(-c6cccc7sc8ccccc8c67)n5)cc4c3)cc2)cc1 ; c1ccc(-c2ccc(-c3nc(-c4ccc(-c5ccc6ccccc6c5)cc4)nc(-c4cccc5sc6ccccc6c45)n3)cc2)cc1]

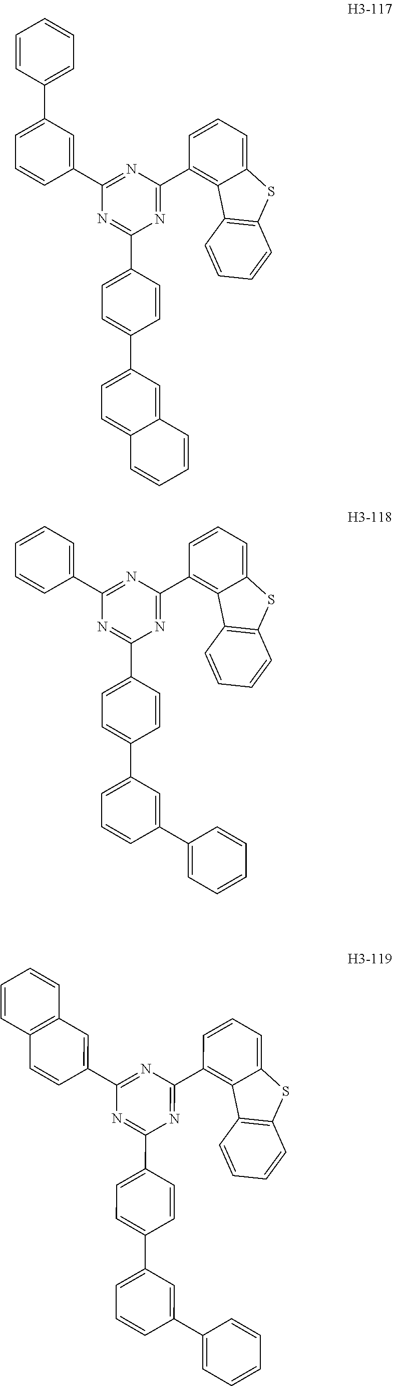 [SMILES: c1ccc(-c2cccc(-c3nc(-c4ccc(-c5ccc6ccccc6c5)cc4)nc(-c4cccc5sc6ccccc6c45)n3)c2)cc1 ; c1ccc(-c2cccc(-c3ccc(-c4nc(-c5ccccc5)nc(-c5cccc6sc7ccccc7c56)n4)cc3)c2)cc1 ; c1ccc(-c2cccc(-c3ccc(-c4nc(-c5ccc6ccccc6c5)nc(-c5cccc6sc7ccccc7c56)n4)cc3)c2)cc1]

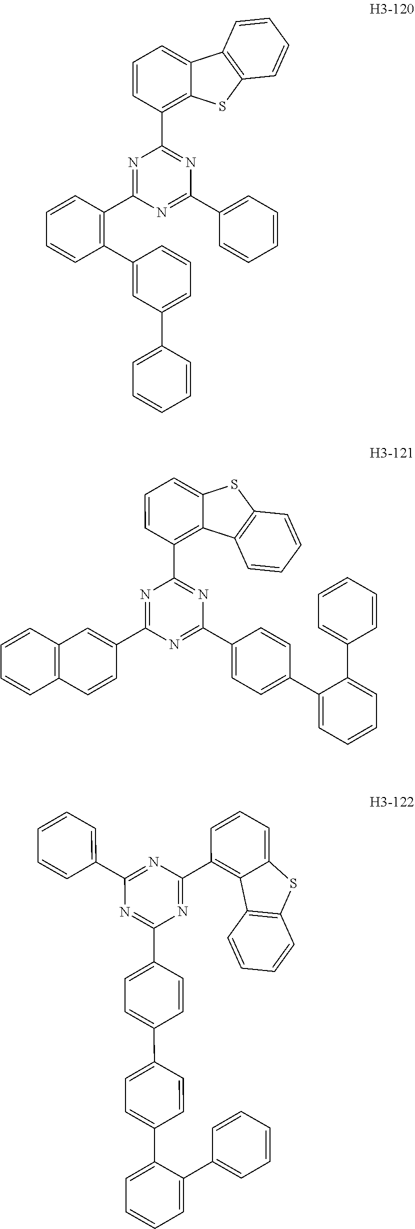 [SMILES: c1ccc(-c2cccc(-c3ccccc3-c3nc(-c4ccccc4)nc(-c4cccc5c4sc4ccccc45)n3)c2)cc1 ; c1ccc(-c2ccccc2-c2ccc(-c3nc(-c4ccc5ccccc5c4)nc(-c4cccc5sc6ccccc6c45)n3)cc2)cc1 ; c1ccc(-c2nc(-c3ccc(-c4ccc(-c5ccccc5-c5ccccc5)cc4)cc3)nc(-c3cccc4sc5ccccc5c34)n2)cc1]

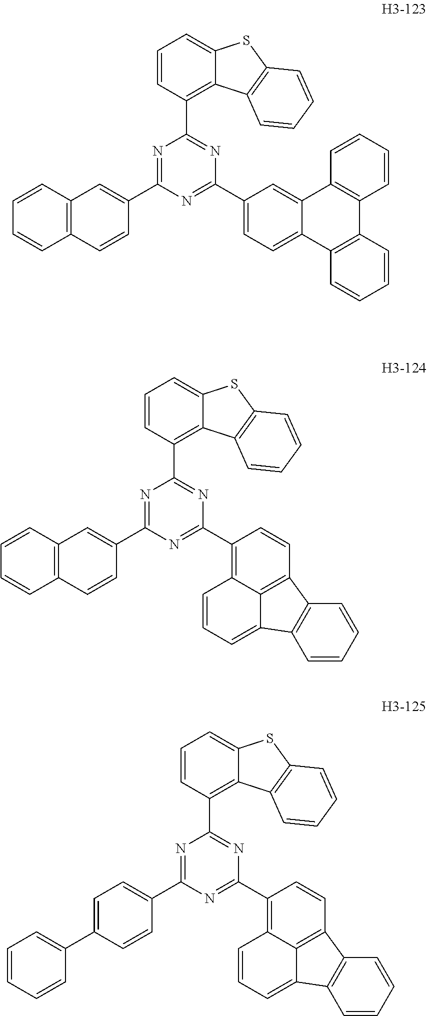 [SMILES: c1ccc2cc(-c3nc(-c4ccc5c6ccccc6c6ccccc6c5c4)nc(-c4cccc5sc6ccccc6c45)n3)ccc2c1 ; c1ccc2c(c1)-c1cccc3c(-c4nc(-c5ccc6ccccc6c5)nc(-c5cccc6sc7ccccc7c56)n4)ccc-2c13 ; c1ccc(-c2ccc(-c3nc(-c4ccc5c6c(cccc46)-c4ccccc4-5)nc(-c4cccc5sc6ccccc6c45)n3)cc2)cc1]

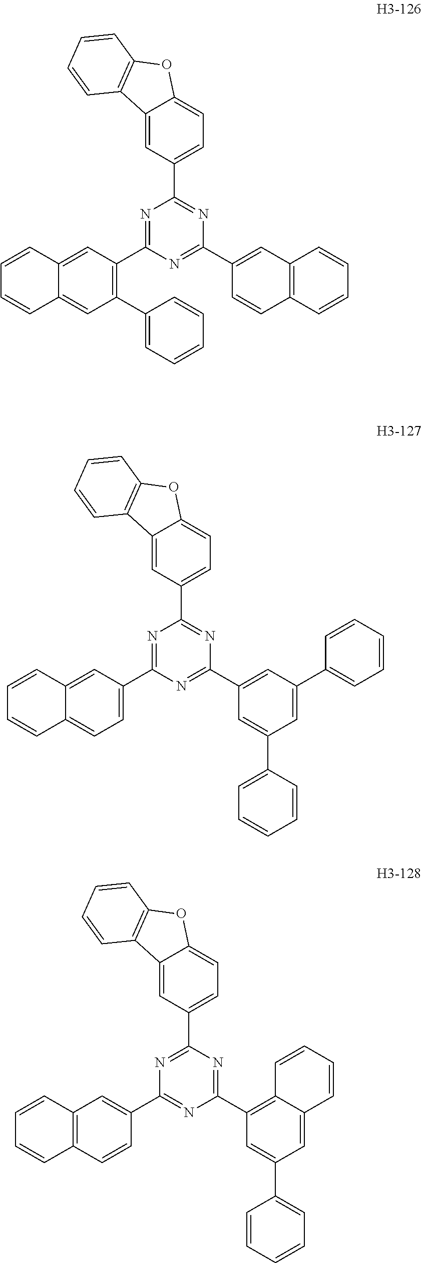 [SMILES: c1ccc(-c2cc3ccccc3cc2-c2nc(-c3ccc4ccccc4c3)nc(-c3ccc4oc5ccccc5c4c3)n2)cc1 ; c1ccc(-c2cc(-c3ccccc3)cc(-c3nc(-c4ccc5ccccc5c4)nc(-c4ccc5oc6ccccc6c5c4)n3)c2)cc1 ; c1ccc(-c2cc(-c3nc(-c4ccc5ccccc5c4)nc(-c4ccc5oc6ccccc6c5c4)n3)c3ccccc3c2)cc1]

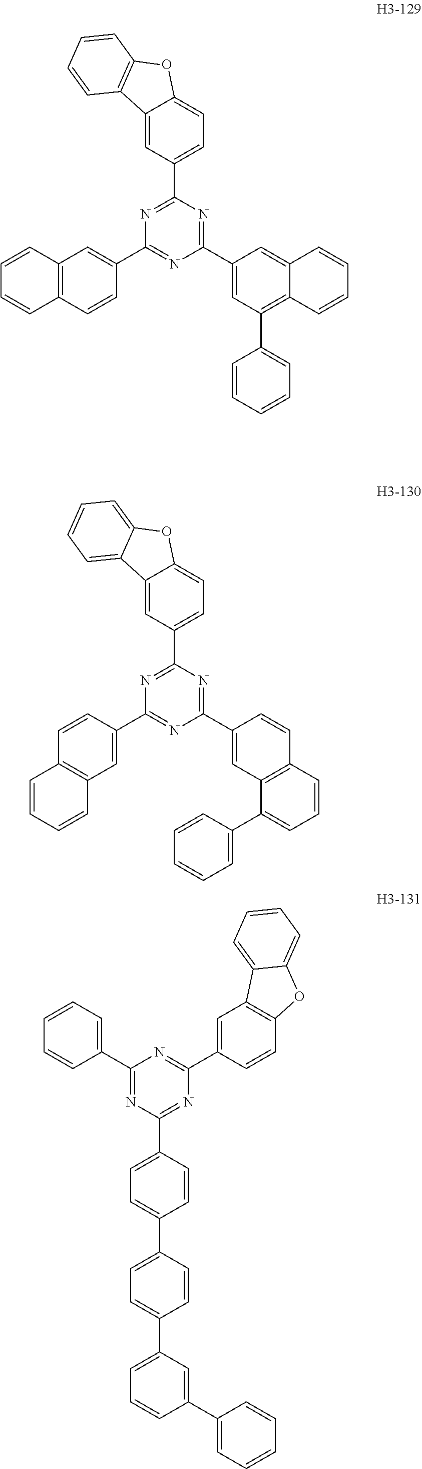 [SMILES: c1ccc(-c2cc(-c3nc(-c4ccc5ccccc5c4)nc(-c4ccc5oc6ccccc6c5c4)n3)cc3ccccc23)cc1 ; c1ccc(-c2cccc3ccc(-c4nc(-c5ccc6ccccc6c5)nc(-c5ccc6oc7ccccc7c6c5)n4)cc23)cc1 ; c1ccc(-c2cccc(-c3ccc(-c4ccc(-c5nc(-c6ccccc6)nc(-c6ccc7oc8ccccc8c7c6)n5)cc4)cc3)c2)cc1]

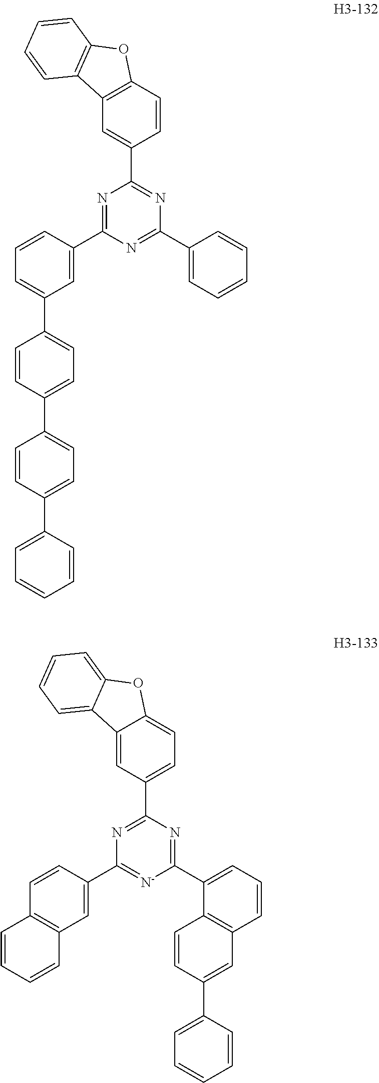

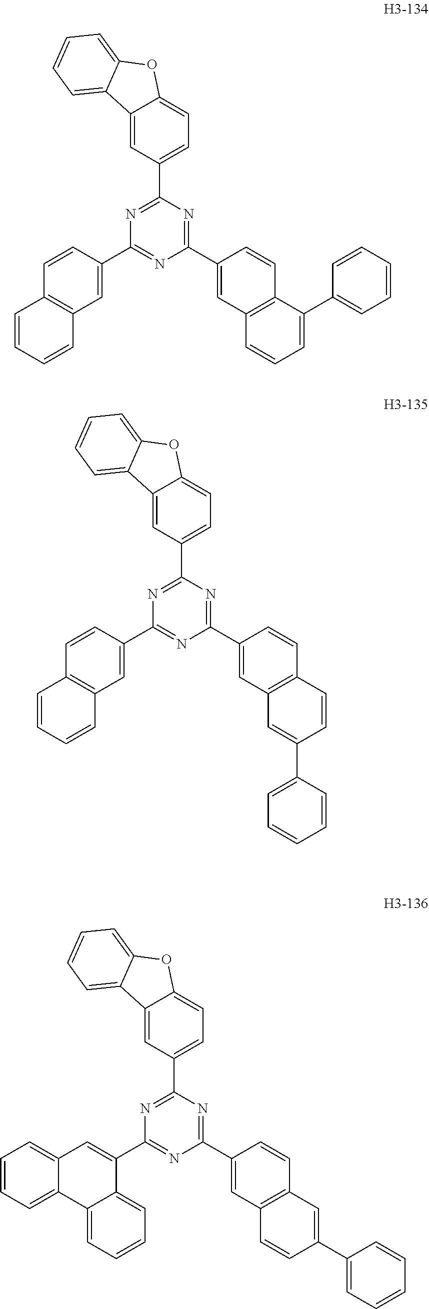 [SMILES: c1ccc(-c2cccc3cc(-c4nc(-c5ccc6ccccc6c5)nc(-c5ccc6oc7ccccc7c6c5)n4)ccc23)cc1 ; c1ccc(-c2ccc3ccc(-c4nc(-c5ccc6ccccc6c5)nc(-c5ccc6oc7ccccc7c6c5)n4)cc3c2)cc1 ; c1ccc(-c2ccc3cc(-c4nc(-c5ccc6oc7ccccc7c6c5)nc(-c5cc6ccccc6c6ccccc56)n4)ccc3c2)cc1]

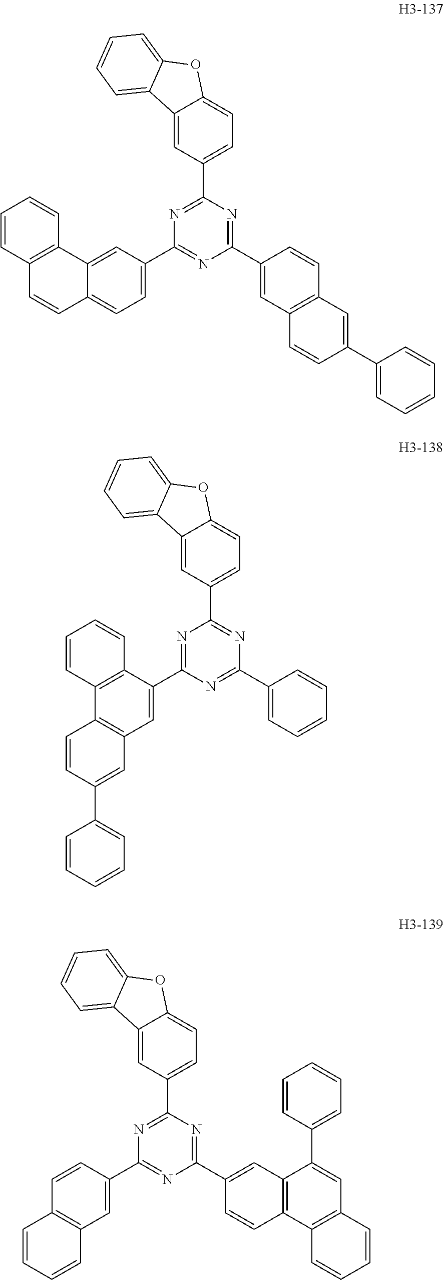 [SMILES: c1ccc(-c2ccc3cc(-c4nc(-c5ccc6ccc7ccccc7c6c5)nc(-c5ccc6oc7ccccc7c6c5)n4)ccc3c2)cc1 ; c1ccc(-c2ccc3c(c2)cc(-c2nc(-c4ccccc4)nc(-c4ccc5oc6ccccc6c5c4)n2)c2ccccc23)cc1 ; c1ccc(-c2cc3ccccc3c3ccc(-c4nc(-c5ccc6ccccc6c5)nc(-c5ccc6oc7ccccc7c6c5)n4)cc23)cc1]

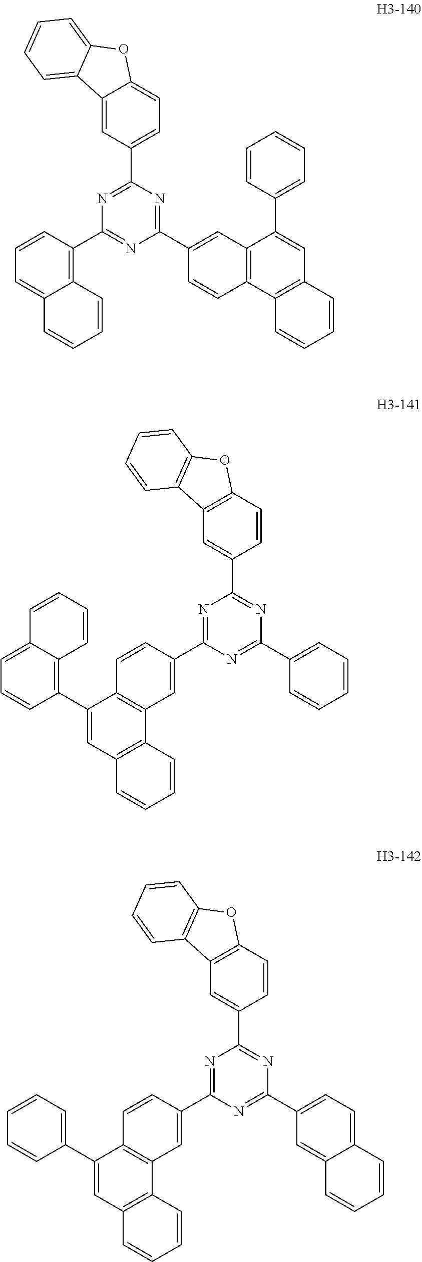 [SMILES: c1ccc(-c2cc3ccccc3c3ccc(-c4nc(-c5ccc6oc7ccccc7c6c5)nc(-c5cccc6ccccc56)n4)cc23)cc1 ; c1ccc(-c2nc(-c3ccc4oc5ccccc5c4c3)nc(-c3ccc4c(-c5cccc6ccccc56)cc5ccccc5c4c3)n2)cc1 ; c1ccc(-c2cc3ccccc3c3cc(-c4nc(-c5ccc6ccccc6c5)nc(-c5ccc6oc7ccccc7c6c5)n4)ccc23)cc1]

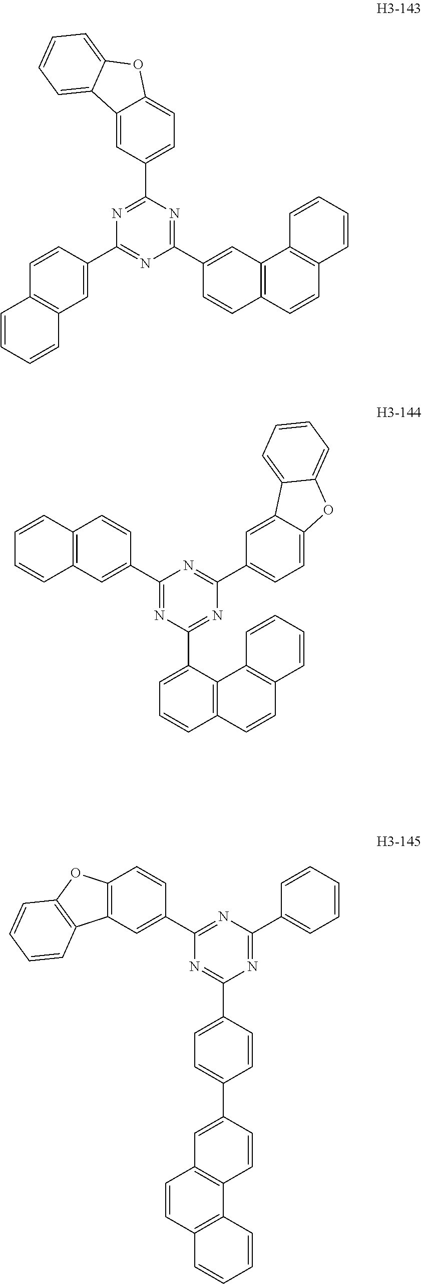 [SMILES: c1ccc2cc(-c3nc(-c4ccc5ccc6ccccc6c5c4)nc(-c4ccc5oc6ccccc6c5c4)n3)ccc2c1 ; c1ccc2cc(-c3nc(-c4ccc5oc6ccccc6c5c4)nc(-c4cccc5ccc6ccccc6c45)n3)ccc2c1 ; c1ccc(-c2nc(-c3ccc(-c4ccc5c(ccc6ccccc65)c4)cc3)nc(-c3ccc4oc5ccccc5c4c3)n2)cc1]

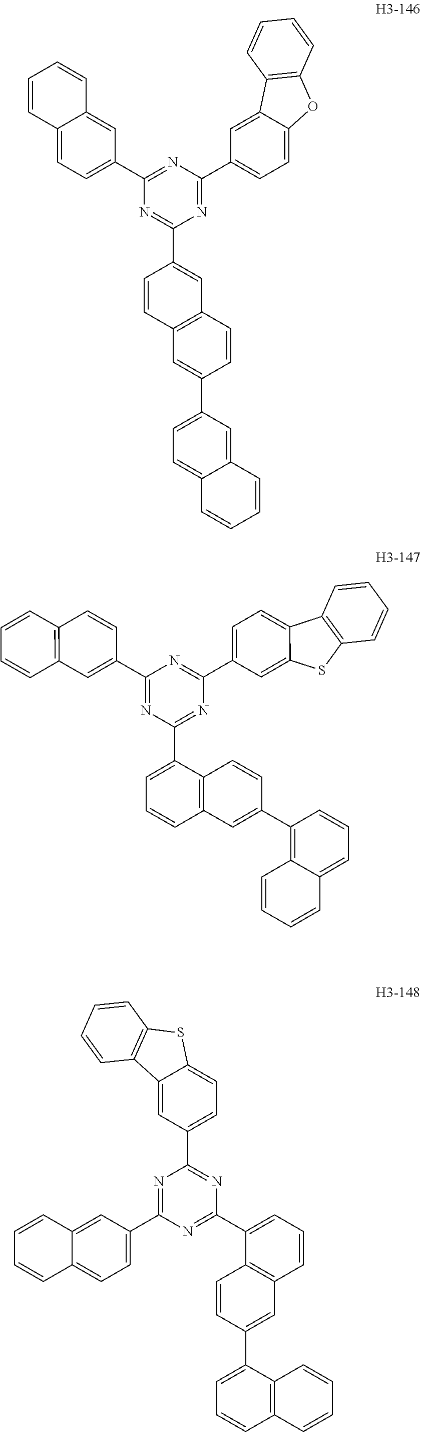 [SMILES: c1ccc2cc(-c3ccc4cc(-c5nc(-c6ccc7ccccc7c6)nc(-c6ccc7oc8ccccc8c7c6)n5)ccc4c3)ccc2c1 ; c1ccc2cc(-c3nc(-c4ccc5c(c4)sc4ccccc45)nc(-c4cccc5cc(-c6cccc7ccccc67)ccc45)n3)ccc2c1 ; c1ccc2cc(-c3nc(-c4ccc5sc6ccccc6c5c4)nc(-c4cccc5cc(-c6cccc7ccccc67)ccc45)n3)ccc2c1]

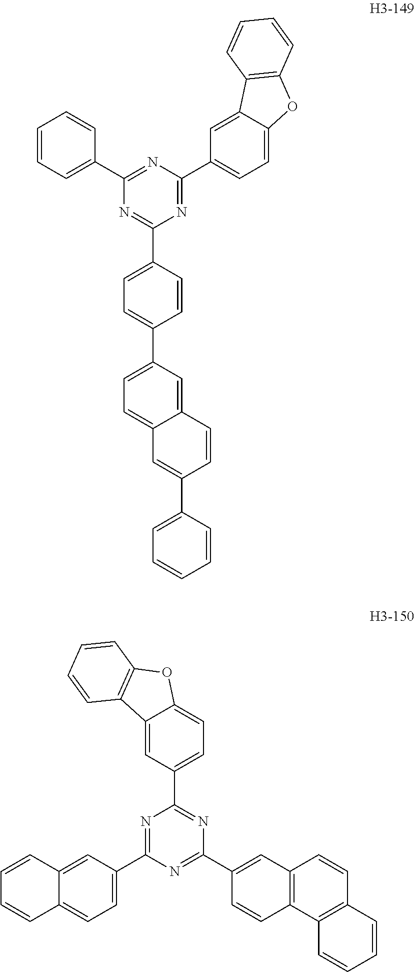 [SMILES: c1ccc(-c2ccc3cc(-c4ccc(-c5nc(-c6ccccc6)nc(-c6ccc7oc8ccccc8c7c6)n5)cc4)ccc3c2)cc1 ; c1ccc2cc(-c3nc(-c4ccc5c(ccc6ccccc65)c4)nc(-c4ccc5oc6ccccc6c5c4)n3)ccc2c1]

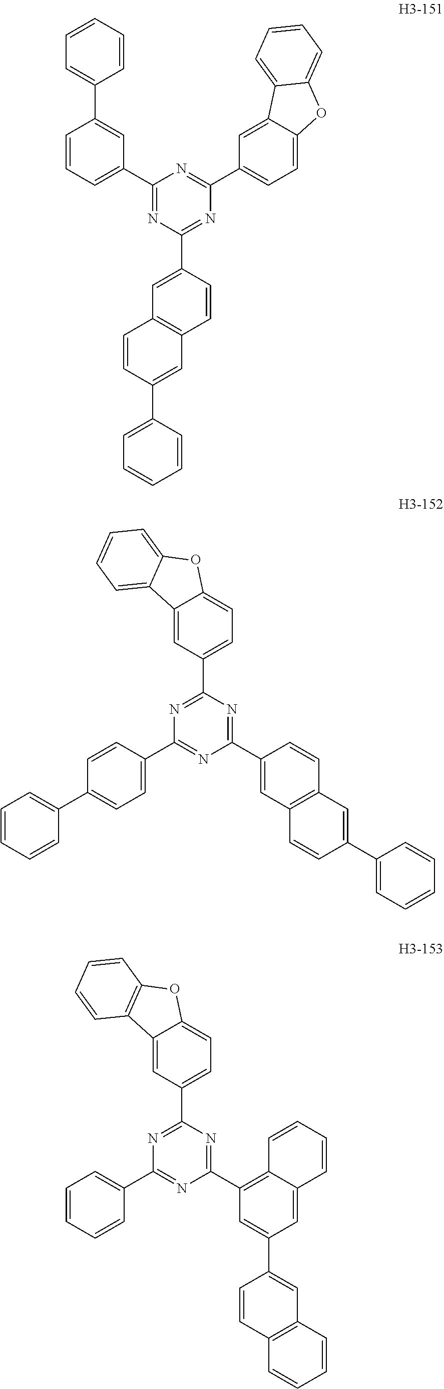

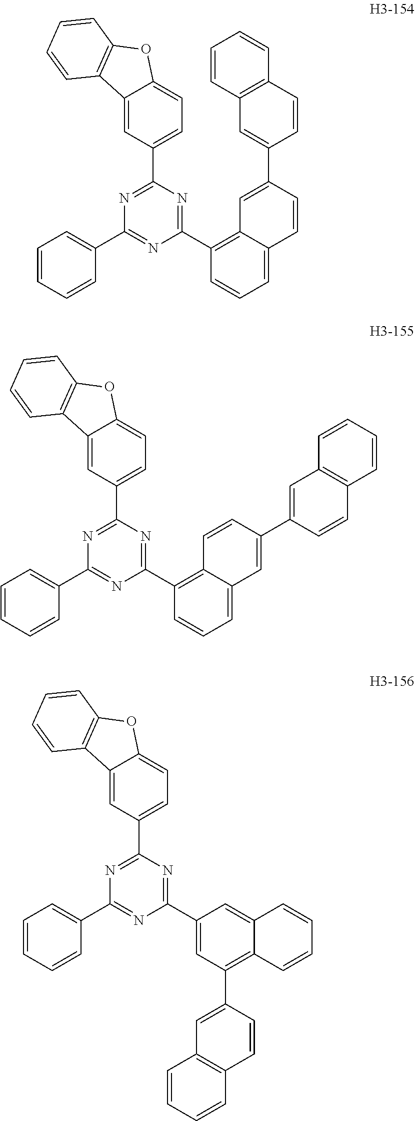 [SMILES: c1ccc(-c2nc(-c3ccc4oc5ccccc5c4c3)nc(-c3cccc4ccc(-c5ccc6ccccc6c5)cc34)n2)cc1 ; c1ccc(-c2nc(-c3ccc4oc5ccccc5c4c3)nc(-c3cccc4cc(-c5ccc6ccccc6c5)ccc34)n2)cc1 ; c1ccc(-c2nc(-c3cc(-c4ccc5ccccc5c4)c4ccccc4c3)nc(-c3ccc4oc5ccccc5c4c3)n2)cc1]

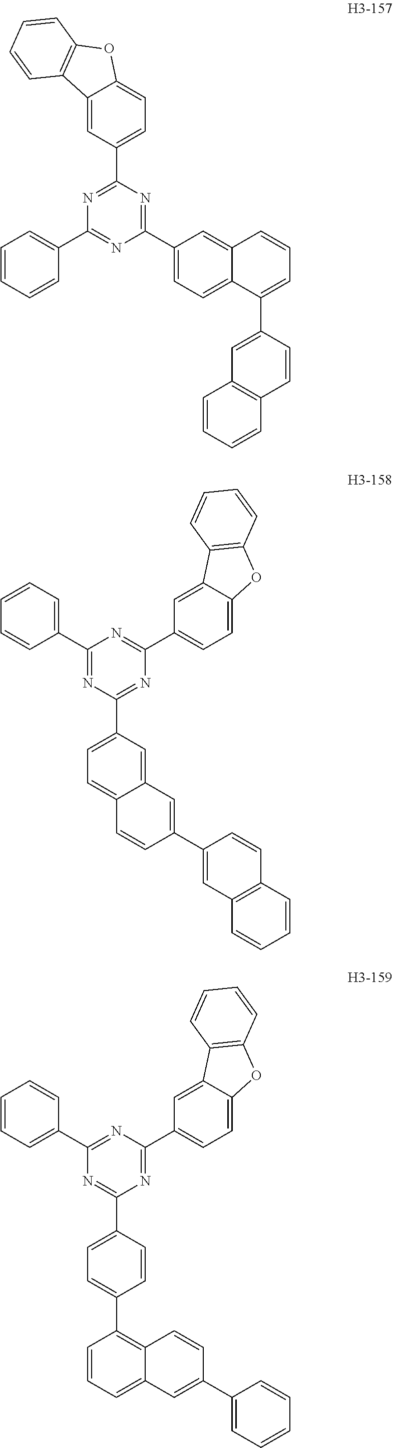

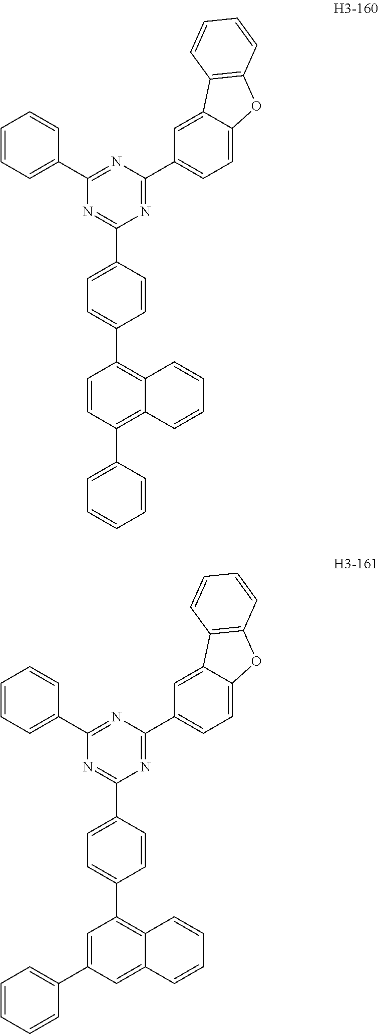 [SMILES: c1ccc(-c2nc(-c3ccc(-c4ccc(-c5ccccc5)c5ccccc45)cc3)nc(-c3ccc4oc5ccccc5c4c3)n2)cc1 ; c1ccc(-c2cc(-c3ccc(-c4nc(-c5ccccc5)nc(-c5ccc6oc7ccccc7c6c5)n4)cc3)c3ccccc3c2)cc1]

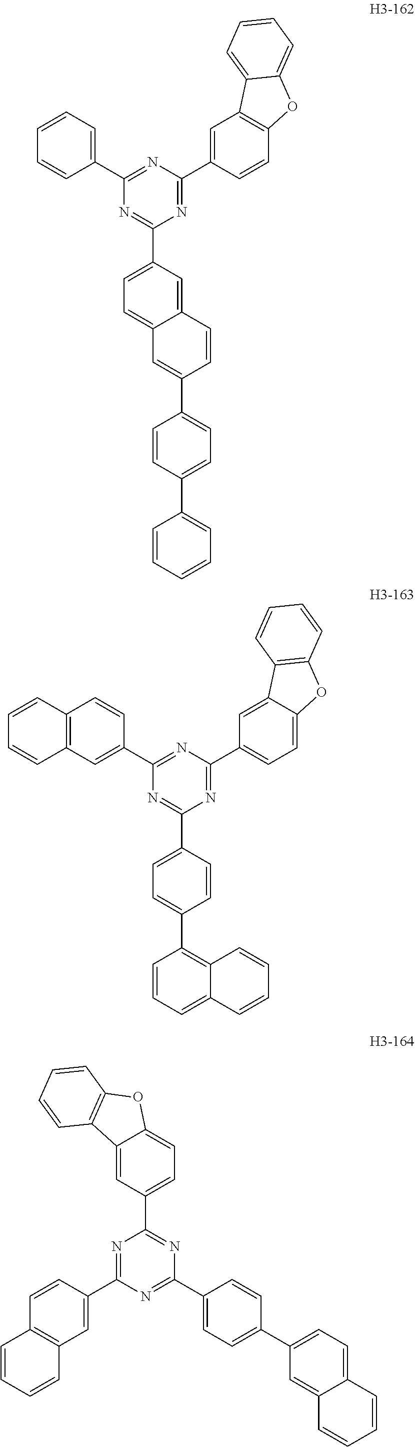 [SMILES: c1ccc(-c2ccc(-c3ccc4cc(-c5nc(-c6ccccc6)nc(-c6ccc7oc8ccccc8c7c6)n5)ccc4c3)cc2)cc1 ; c1ccc2cc(-c3nc(-c4ccc(-c5cccc6ccccc56)cc4)nc(-c4ccc5oc6ccccc6c5c4)n3)ccc2c1 ; c1ccc2cc(-c3ccc(-c4nc(-c5ccc6ccccc6c5)nc(-c5ccc6oc7ccccc7c6c5)n4)cc3)ccc2c1]

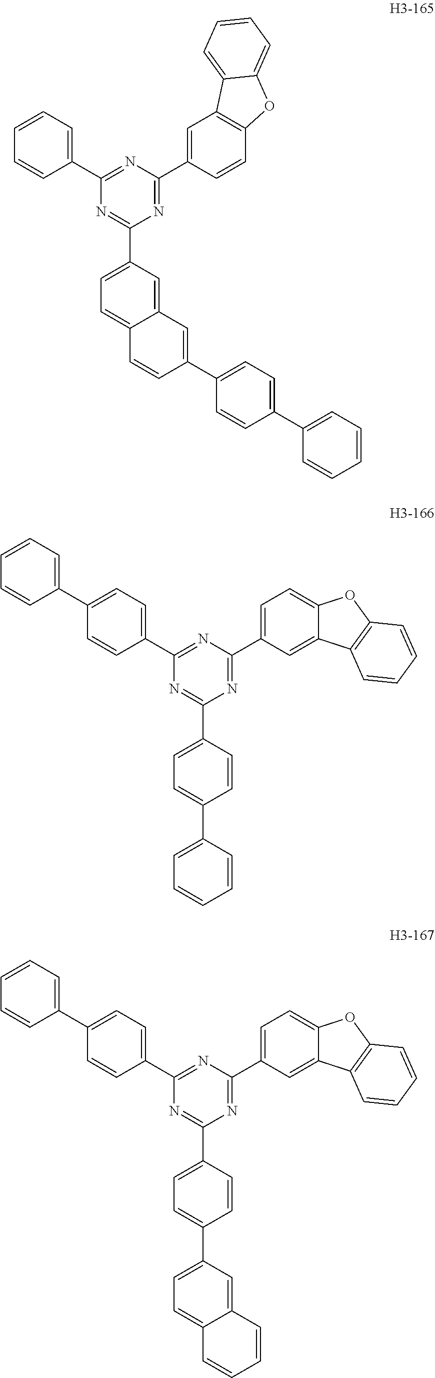 [SMILES: c1ccc(-c2ccc(-c3ccc4ccc(-c5nc(-c6ccccc6)nc(-c6ccc7oc8ccccc8c7c6)n5)cc4c3)cc2)cc1 ; c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccc6ccccc6c5)cc4)nc(-c4ccc5oc6ccccc6c5c4)n3)cc2)cc1]

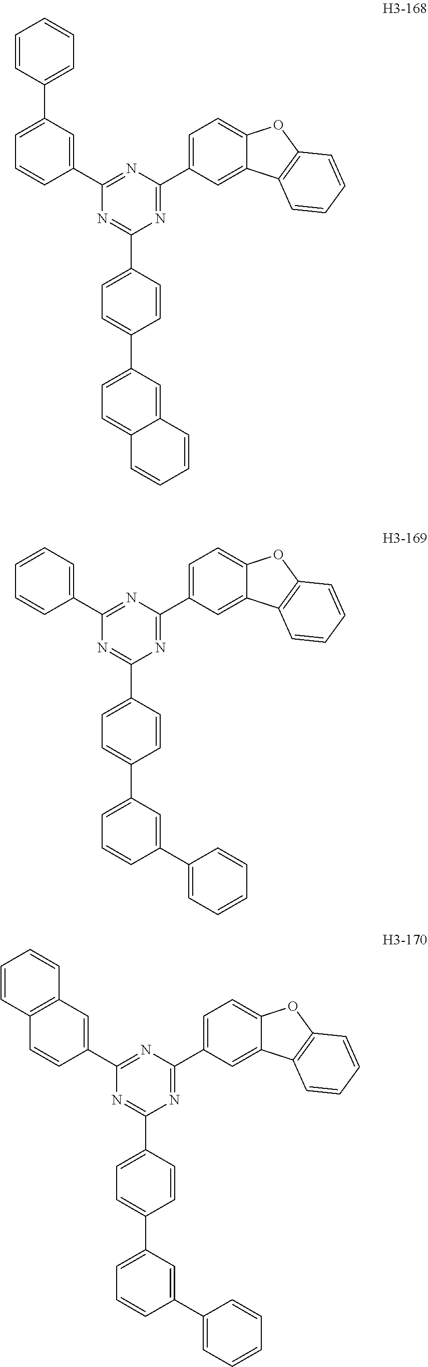 [SMILES: c1ccc(-c2cccc(-c3nc(-c4ccc(-c5ccc6ccccc6c5)cc4)nc(-c4ccc5oc6ccccc6c5c4)n3)c2)cc1 ; c1ccc(-c2cccc(-c3ccc(-c4nc(-c5ccccc5)nc(-c5ccc6oc7ccccc7c6c5)n4)cc3)c2)cc1 ; c1ccc(-c2cccc(-c3ccc(-c4nc(-c5ccc6ccccc6c5)nc(-c5ccc6oc7ccccc7c6c5)n4)cc3)c2)cc1]

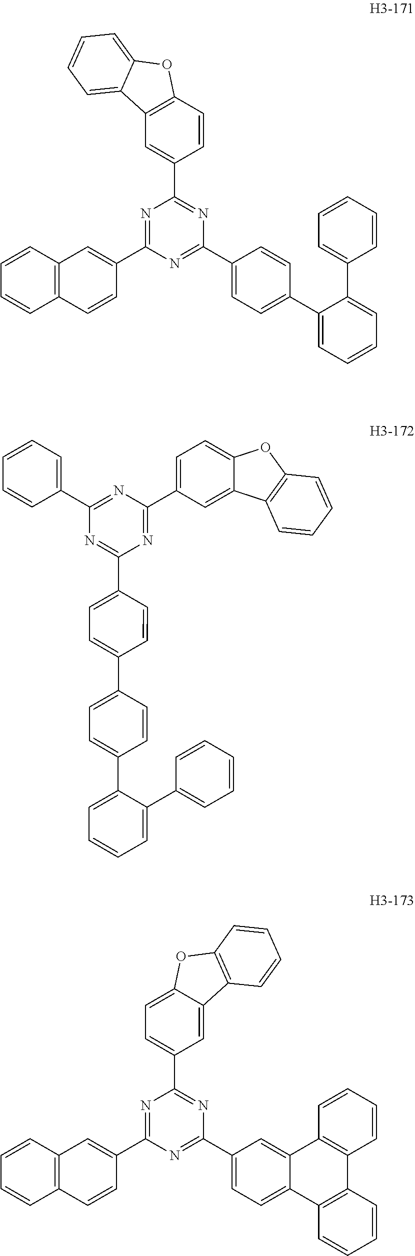 [SMILES: c1ccc(-c2ccccc2-c2ccc(-c3nc(-c4ccc5ccccc5c4)nc(-c4ccc5oc6ccccc6c5c4)n3)cc2)cc1 ; c1ccc(-c2nc(-c3ccc(-c4ccc(-c5ccccc5-c5ccccc5)cc4)cc3)nc(-c3ccc4oc5ccccc5c4c3)n2)cc1 ; c1ccc2cc(-c3nc(-c4ccc5oc6ccccc6c5c4)nc(-c4ccc5c6ccccc6c6ccccc6c5c4)n3)ccc2c1]

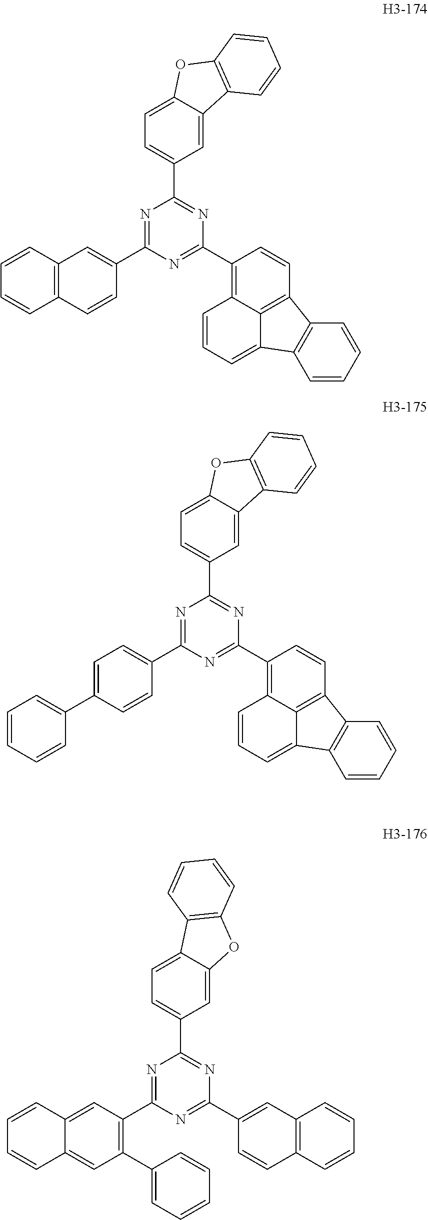 [SMILES: c1ccc2c(c1)-c1cccc3c(-c4nc(-c5ccc6ccccc6c5)nc(-c5ccc6oc7ccccc7c6c5)n4)ccc-2c13 ; c1ccc(-c2ccc(-c3nc(-c4ccc5oc6ccccc6c5c4)nc(-c4ccc5c6c(cccc46)-c4ccccc4-5)n3)cc2)cc1 ; c1ccc(-c2cc3ccccc3cc2-c2nc(-c3ccc4ccccc4c3)nc(-c3ccc4c(c3)oc3ccccc34)n2)cc1]

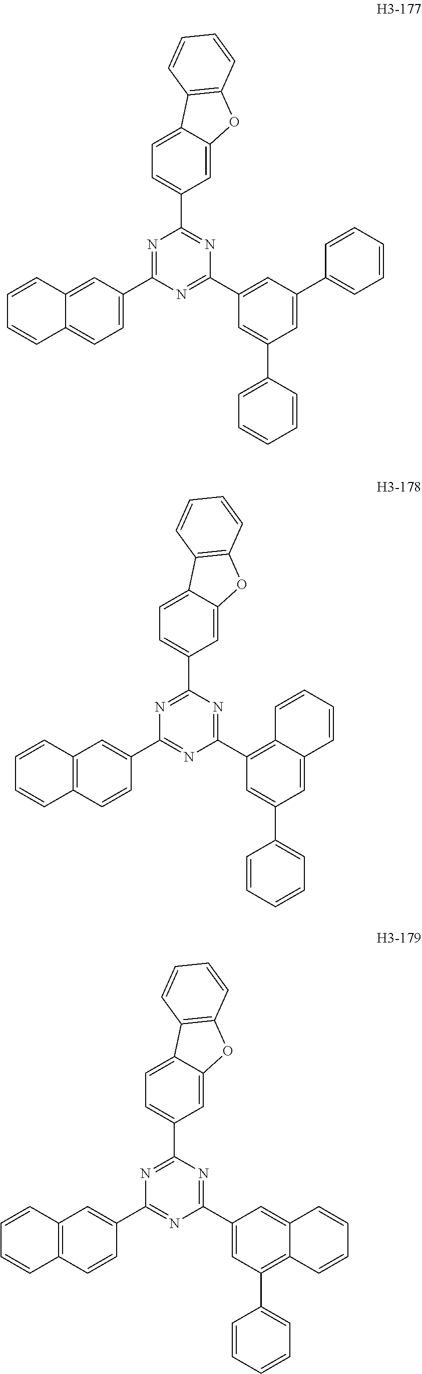 [SMILES: c1ccc(-c2cc(-c3ccccc3)cc(-c3nc(-c4ccc5ccccc5c4)nc(-c4ccc5c(c4)oc4ccccc45)n3)c2)cc1 ; c1ccc(-c2cc(-c3nc(-c4ccc5ccccc5c4)nc(-c4ccc5c(c4)oc4ccccc45)n3)c3ccccc3c2)cc1 ; c1ccc(-c2cc(-c3nc(-c4ccc5ccccc5c4)nc(-c4ccc5c(c4)oc4ccccc45)n3)cc3ccccc23)cc1]

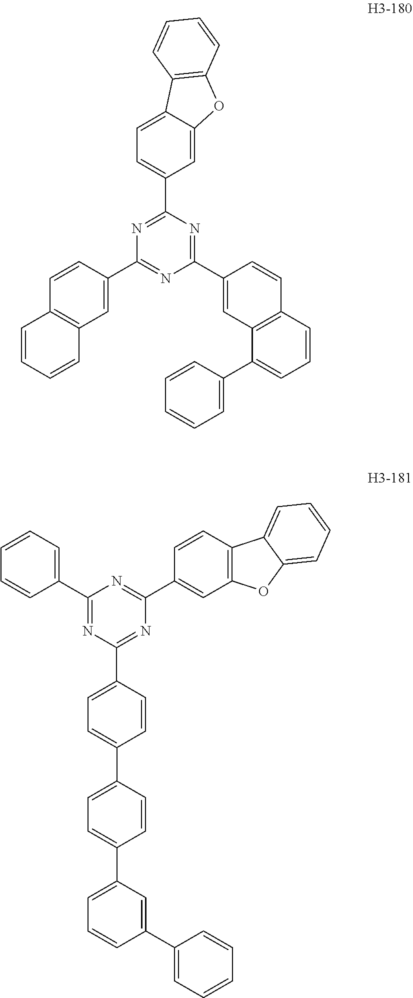 [SMILES: c1ccc(-c2cccc3ccc(-c4nc(-c5ccc6ccccc6c5)nc(-c5ccc6c(c5)oc5ccccc56)n4)cc23)cc1 ; c1ccc(-c2cccc(-c3ccc(-c4ccc(-c5nc(-c6ccccc6)nc(-c6ccc7c(c6)oc6ccccc67)n5)cc4)cc3)c2)cc1]

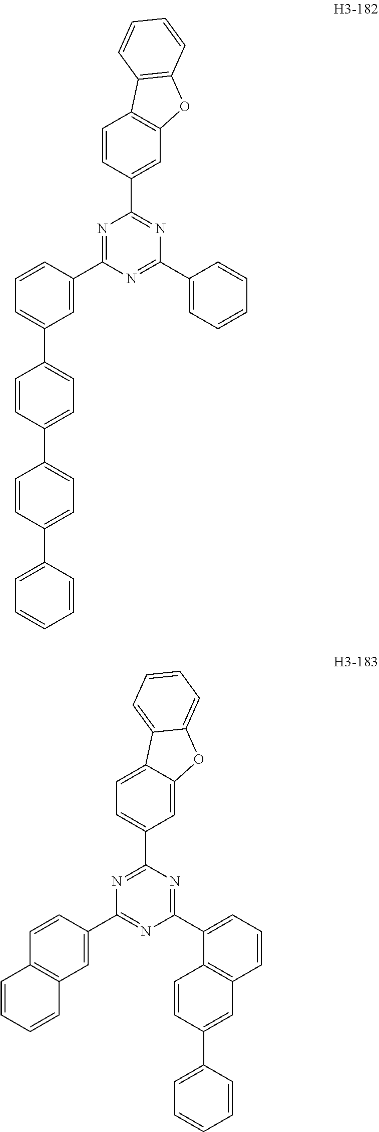 [SMILES: c1ccc(-c2ccc(-c3ccc(-c4cccc(-c5nc(-c6ccccc6)nc(-c6ccc7c(c6)oc6ccccc67)n5)c4)cc3)cc2)cc1 ; c1ccc(-c2ccc3c(-c4nc(-c5ccc6ccccc6c5)nc(-c5ccc6c(c5)oc5ccccc56)n4)cccc3c2)cc1]

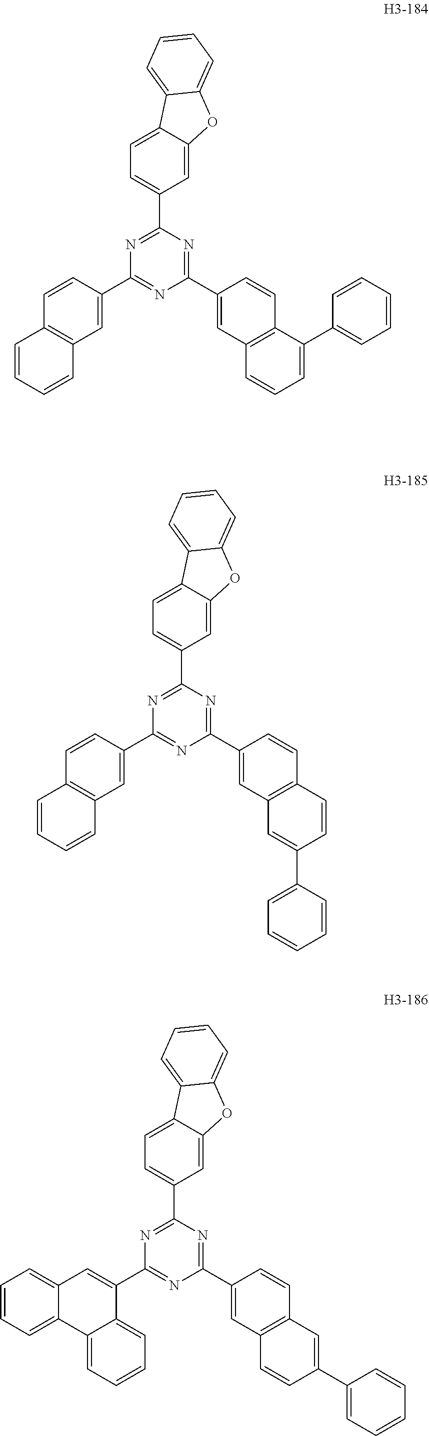 [SMILES: c1ccc(-c2cccc3cc(-c4nc(-c5ccc6ccccc6c5)nc(-c5ccc6c(c5)oc5ccccc56)n4)ccc23)cc1 ; c1ccc(-c2ccc3ccc(-c4nc(-c5ccc6ccccc6c5)nc(-c5ccc6c(c5)oc5ccccc56)n4)cc3c2)cc1 ; c1ccc(-c2ccc3cc(-c4nc(-c5ccc6c(c5)oc5ccccc56)nc(-c5cc6ccccc6c6ccccc56)n4)ccc3c2)cc1]

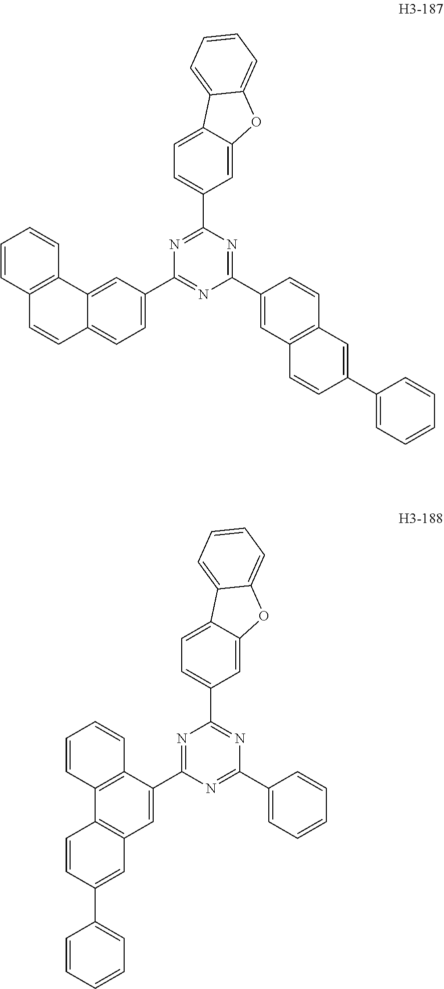 [SMILES: c1ccc(-c2ccc3cc(-c4nc(-c5ccc6c(c5)oc5ccccc56)nc(-c5ccc6ccc7ccccc7c6c5)n4)ccc3c2)cc1 ; c1ccc(-c2ccc3c(c2)cc(-c2nc(-c4ccccc4)nc(-c4ccc5c(c4)oc4ccccc45)n2)c2ccccc23)cc1]

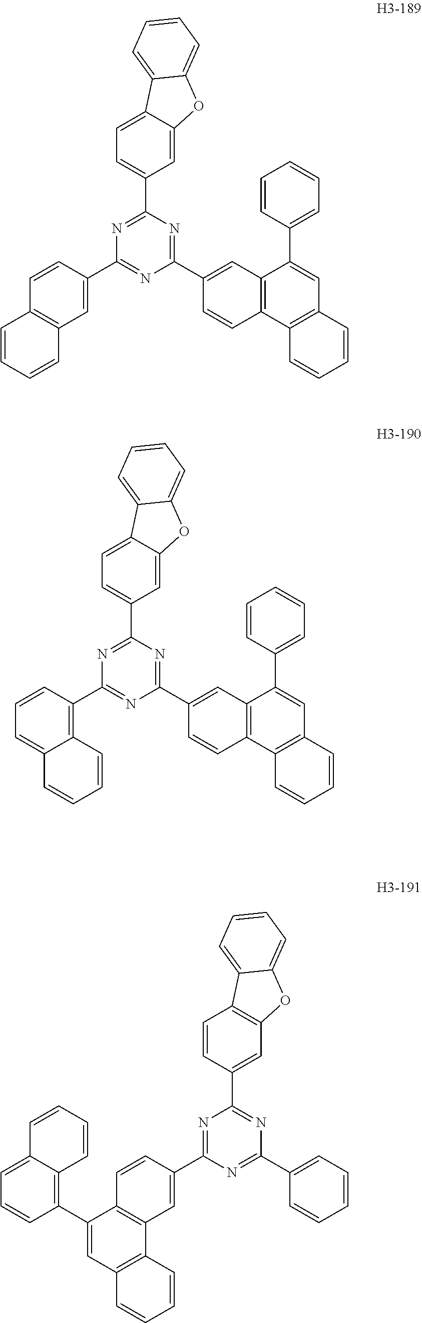 [SMILES: c1ccc(-c2cc3ccccc3c3ccc(-c4nc(-c5ccc6ccccc6c5)nc(-c5ccc6c(c5)oc5ccccc56)n4)cc23)cc1 ; c1ccc(-c2cc3ccccc3c3ccc(-c4nc(-c5ccc6c(c5)oc5ccccc56)nc(-c5cccc6ccccc56)n4)cc23)cc1 ; c1ccc(-c2nc(-c3ccc4c(c3)oc3ccccc34)nc(-c3ccc4c(-c5cccc6ccccc56)cc5ccccc5c4c3)n2)cc1]

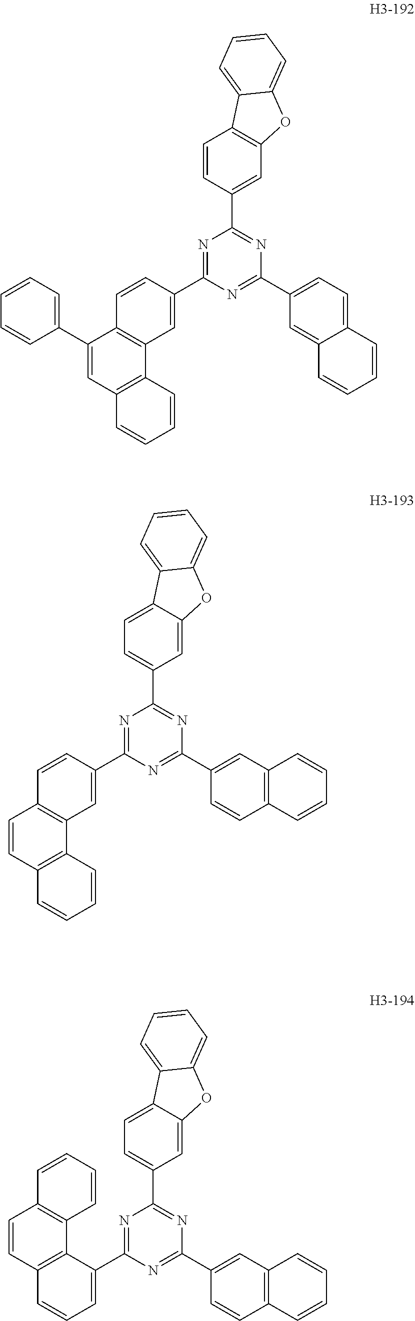 [SMILES: c1ccc(-c2cc3ccccc3c3cc(-c4nc(-c5ccc6ccccc6c5)nc(-c5ccc6c(c5)oc5ccccc56)n4)ccc23)cc1 ; c1ccc2cc(-c3nc(-c4ccc5c(c4)oc4ccccc45)nc(-c4ccc5ccc6ccccc6c5c4)n3)ccc2c1 ; c1ccc2cc(-c3nc(-c4ccc5c(c4)oc4ccccc45)nc(-c4cccc5ccc6ccccc6c45)n3)ccc2c1]

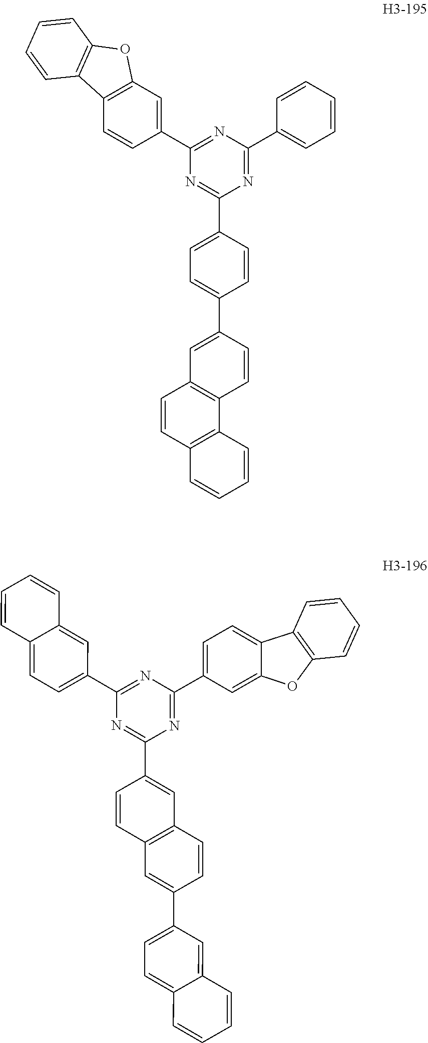 [SMILES: c1ccc(-c2nc(-c3ccc(-c4ccc5c(ccc6ccccc65)c4)cc3)nc(-c3ccc4c(c3)oc3ccccc34)n2)cc1 ; c1ccc2cc(-c3ccc4cc(-c5nc(-c6ccc7ccccc7c6)nc(-c6ccc7c(c6)oc6ccccc67)n5)ccc4c3)ccc2c1]

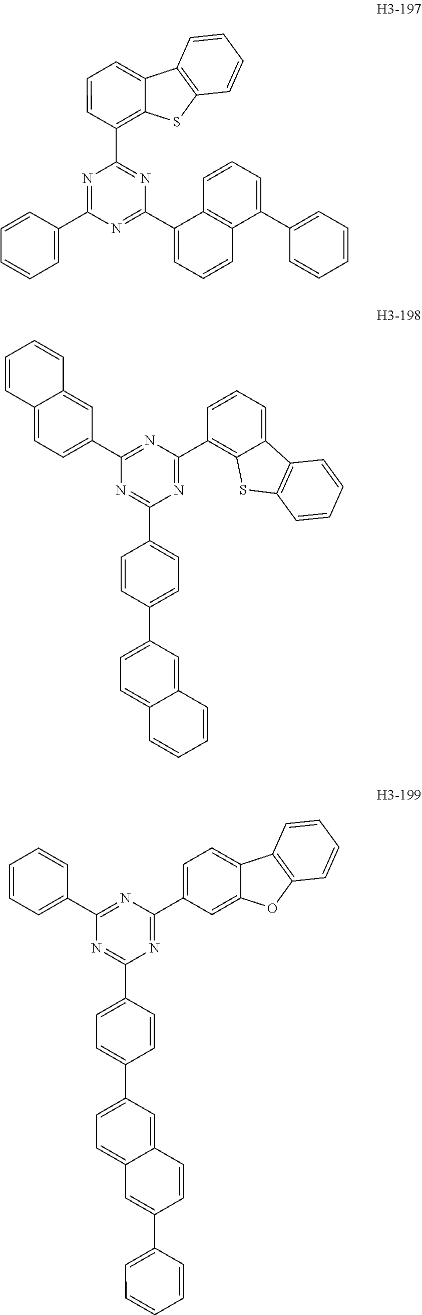 [SMILES: c1ccc(-c2nc(-c3cccc4c(-c5ccccc5)cccc34)nc(-c3cccc4c3sc3ccccc34)n2)cc1 ; c1ccc2cc(-c3ccc(-c4nc(-c5ccc6ccccc6c5)nc(-c5cccc6c5sc5ccccc56)n4)cc3)ccc2c1 ; c1ccc(-c2ccc3cc(-c4ccc(-c5nc(-c6ccccc6)nc(-c6ccc7c(c6)oc6ccccc67)n5)cc4)ccc3c2)cc1]

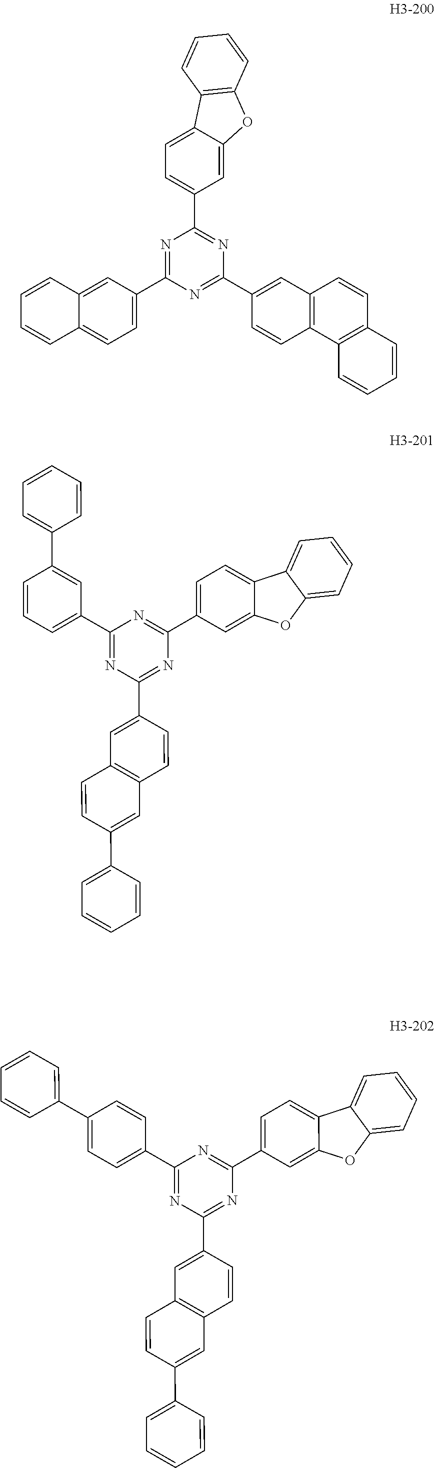 [SMILES: c1ccc2cc(-c3nc(-c4ccc5c(ccc6ccccc65)c4)nc(-c4ccc5c(c4)oc4ccccc45)n3)ccc2c1 ; c1ccc(-c2cccc(-c3nc(-c4ccc5cc(-c6ccccc6)ccc5c4)nc(-c4ccc5c(c4)oc4ccccc45)n3)c2)cc1 ; c1ccc(-c2ccc(-c3nc(-c4ccc5cc(-c6ccccc6)ccc5c4)nc(-c4ccc5c(c4)oc4ccccc45)n3)cc2)cc1]

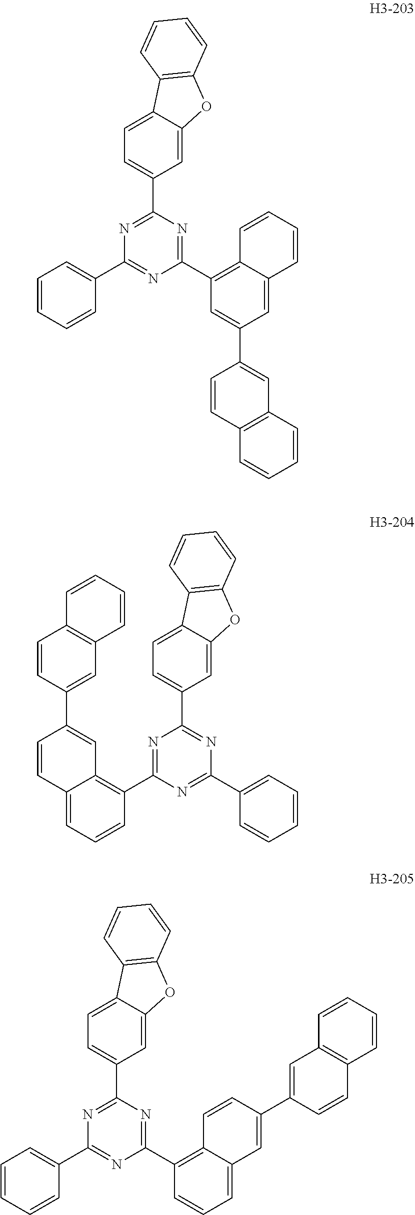 [SMILES: c1ccc(-c2nc(-c3ccc4c(c3)oc3ccccc34)nc(-c3cc(-c4ccc5ccccc5c4)cc4ccccc34)n2)cc1 ; c1ccc(-c2nc(-c3ccc4c(c3)oc3ccccc34)nc(-c3cccc4ccc(-c5ccc6ccccc6c5)cc34)n2)cc1 ; c1ccc(-c2nc(-c3ccc4c(c3)oc3ccccc34)nc(-c3cccc4cc(-c5ccc6ccccc6c5)ccc34)n2)cc1]

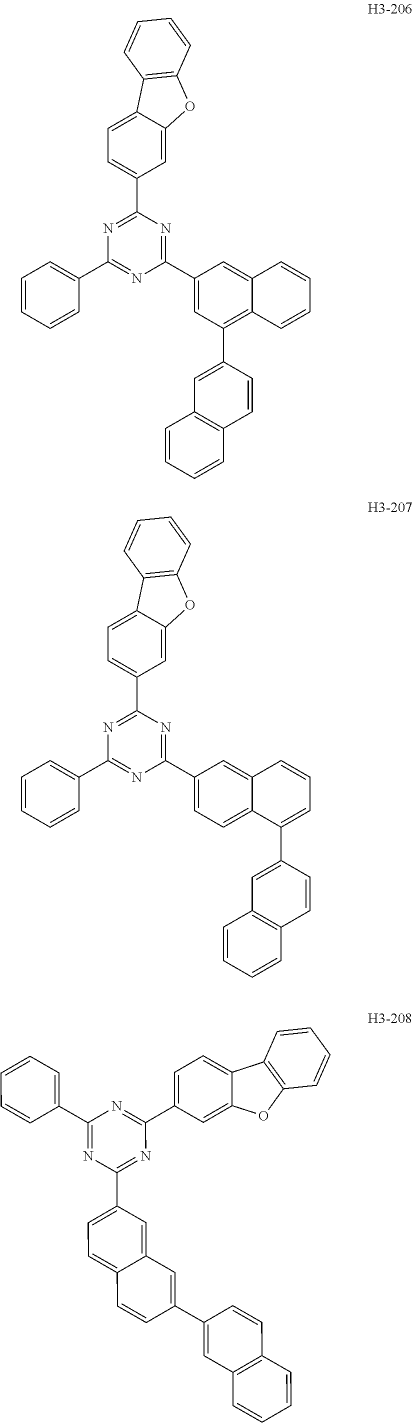

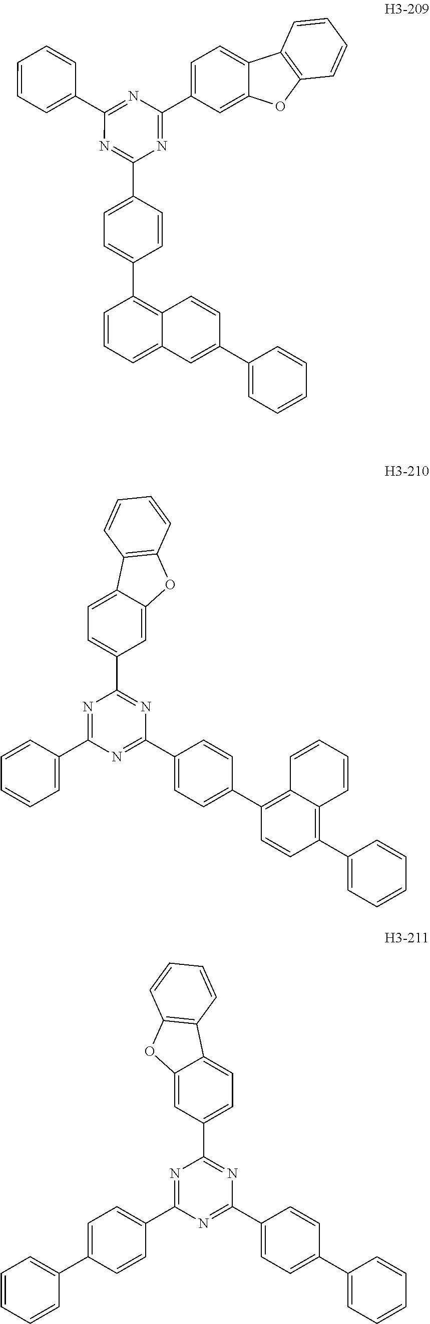 [SMILES: c1ccc(-c2ccc3c(-c4ccc(-c5nc(-c6ccccc6)nc(-c6ccc7c(c6)oc6ccccc67)n5)cc4)cccc3c2)cc1 ; c1ccc(-c2nc(-c3ccc(-c4ccc(-c5ccccc5)c5ccccc45)cc3)nc(-c3ccc4c(c3)oc3ccccc34)n2)cc1 ; c1ccc(-c2ccc(-c3nc(-c4ccc(-c5ccccc5)cc4)nc(-c4ccc5c(c4)oc4ccccc45)n3)cc2)cc1]

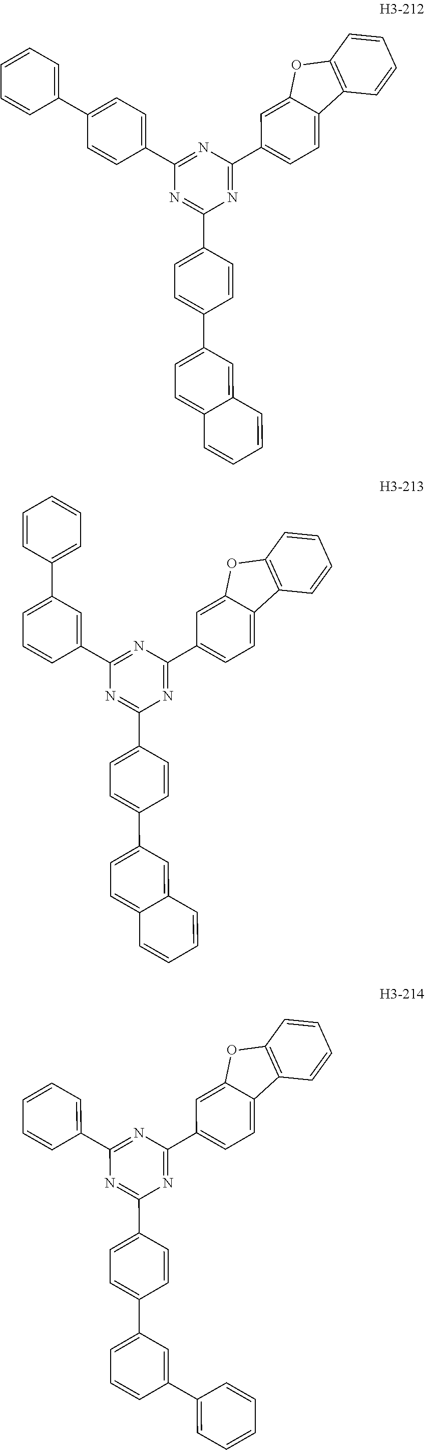 [SMILES: c1ccc(-c2ccc(-c3nc(-c4ccc(-c5ccc6ccccc6c5)cc4)nc(-c4ccc5c(c4)oc4ccccc45)n3)cc2)cc1 ; c1ccc(-c2cccc(-c3nc(-c4ccc(-c5ccc6ccccc6c5)cc4)nc(-c4ccc5c(c4)oc4ccccc45)n3)c2)cc1 ; c1ccc(-c2cccc(-c3ccc(-c4nc(-c5ccccc5)nc(-c5ccc6c(c5)oc5ccccc56)n4)cc3)c2)cc1]

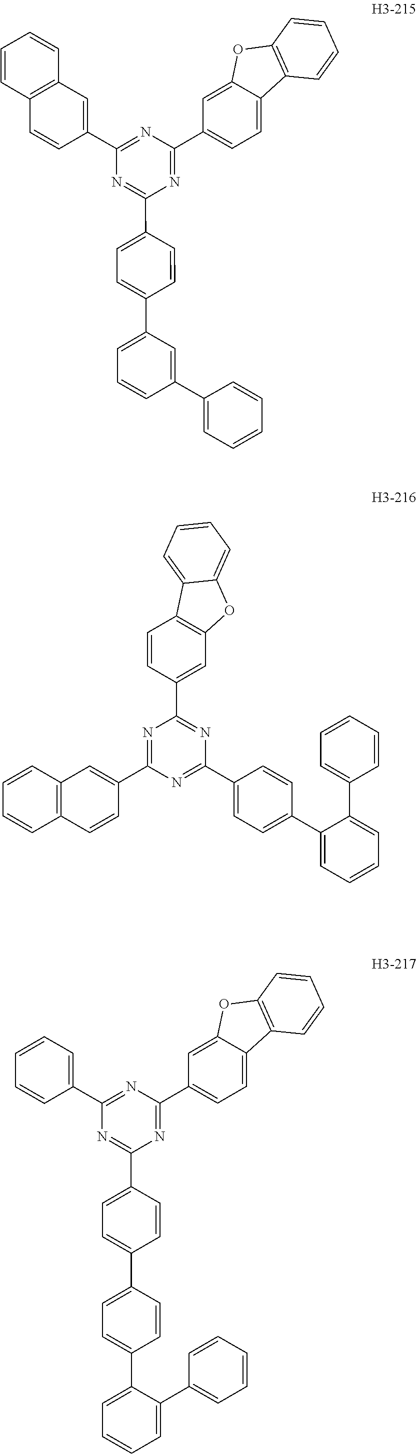 [SMILES: c1ccc(-c2cccc(-c3ccc(-c4nc(-c5ccc6ccccc6c5)nc(-c5ccc6c(c5)oc5ccccc56)n4)cc3)c2)cc1 ; c1ccc(-c2ccccc2-c2ccc(-c3nc(-c4ccc5ccccc5c4)nc(-c4ccc5c(c4)oc4ccccc45)n3)cc2)cc1 ; c1ccc(-c2nc(-c3ccc(-c4ccc(-c5ccccc5-c5ccccc5)cc4)cc3)nc(-c3ccc4c(c3)oc3ccccc34)n2)cc1]

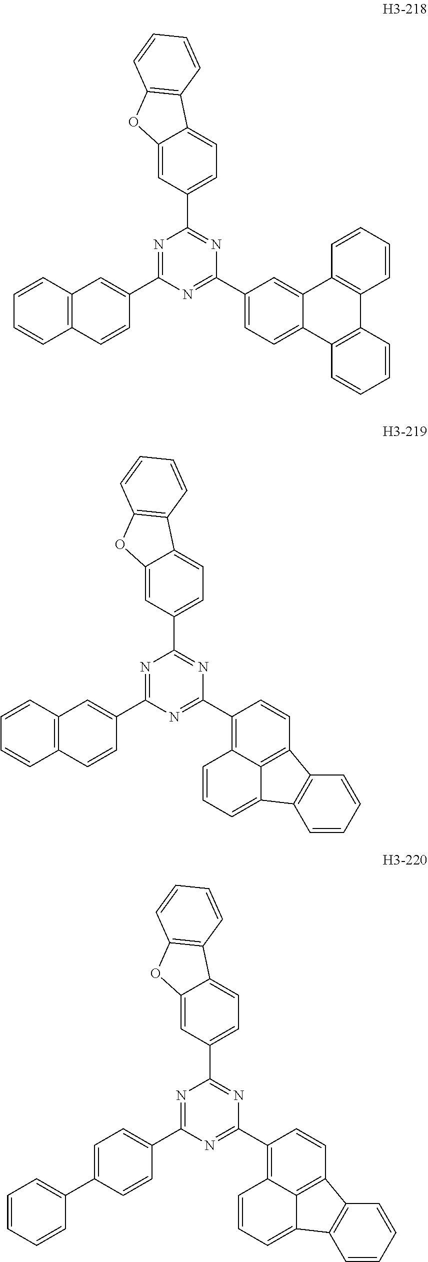 [SMILES: c1ccc2cc(-c3nc(-c4ccc5c(c4)oc4ccccc45)nc(-c4ccc5c6ccccc6c6ccccc6c5c4)n3)ccc2c1 ; c1ccc2c(c1)-c1cccc3c(-c4nc(-c5ccc6ccccc6c5)nc(-c5ccc6c(c5)oc5ccccc56)n4)ccc-2c13 ; c1ccc(-c2ccc(-c3nc(-c4ccc5c(c4)oc4ccccc45)nc(-c4ccc5c6c(cccc46)-c4ccccc4-5)n3)cc2)cc1]

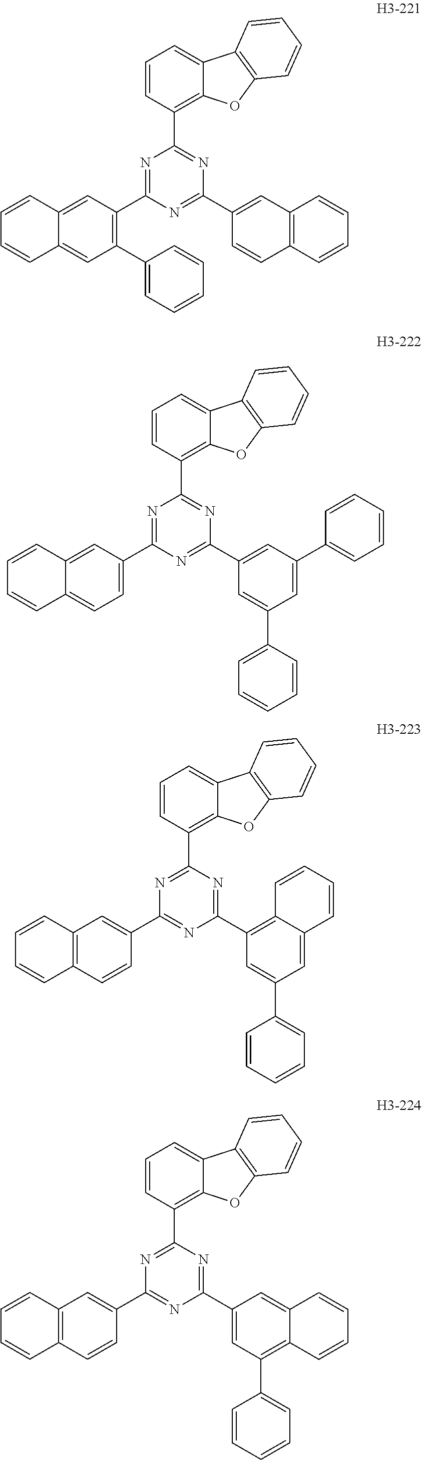

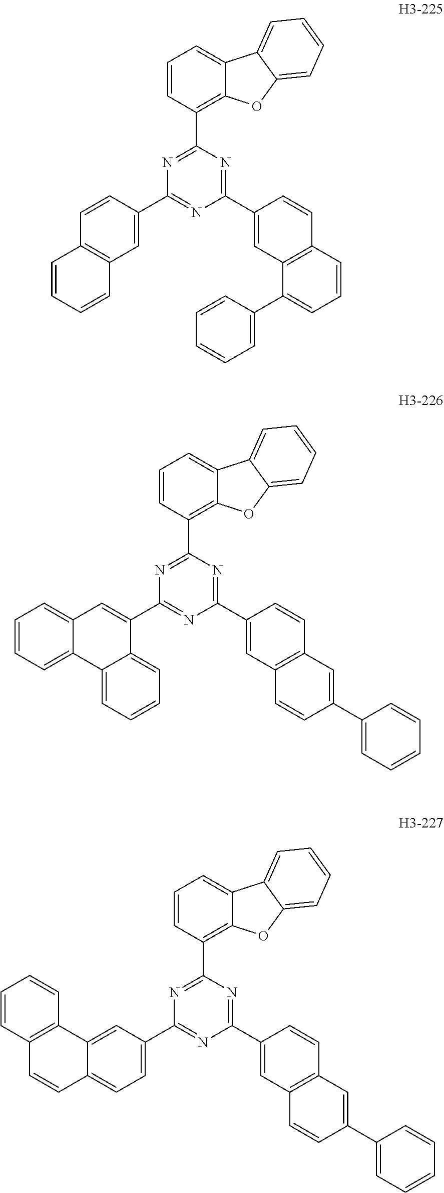 [SMILES: c1ccc(-c2cccc3ccc(-c4nc(-c5ccc6ccccc6c5)nc(-c5cccc6c5oc5ccccc56)n4)cc23)cc1 ; c1ccc(-c2ccc3cc(-c4nc(-c5cc6ccccc6c6ccccc56)nc(-c5cccc6c5oc5ccccc56)n4)ccc3c2)cc1 ; c1ccc(-c2ccc3cc(-c4nc(-c5ccc6ccc7ccccc7c6c5)nc(-c5cccc6c5oc5ccccc56)n4)ccc3c2)cc1]

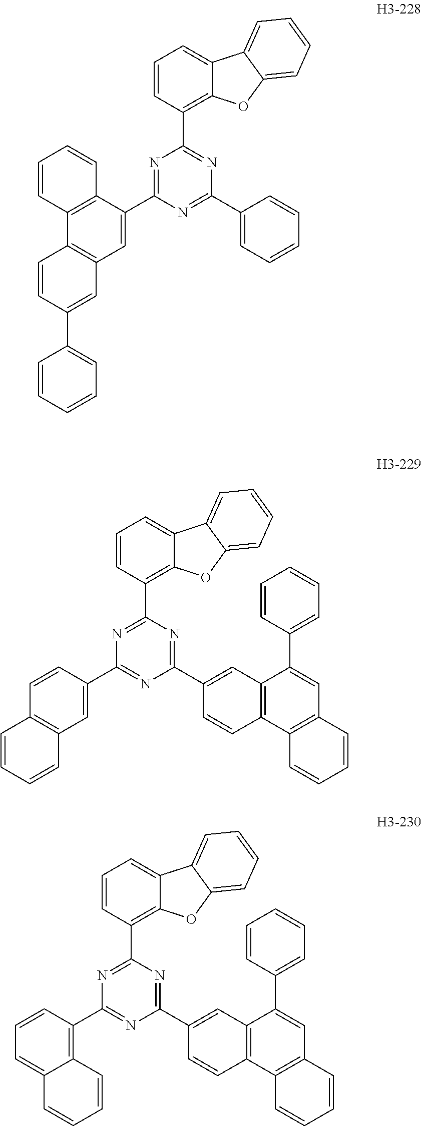 [SMILES: c1ccc(-c2ccc3c(c2)cc(-c2nc(-c4ccccc4)nc(-c4cccc5c4oc4ccccc45)n2)c2ccccc23)cc1 ; c1ccc(-c2cc3ccccc3c3ccc(-c4nc(-c5ccc6ccccc6c5)nc(-c5cccc6c5oc5ccccc56)n4)cc23)cc1 ; c1ccc(-c2cc3ccccc3c3ccc(-c4nc(-c5cccc6ccccc56)nc(-c5cccc6c5oc5ccccc56)n4)cc23)cc1]

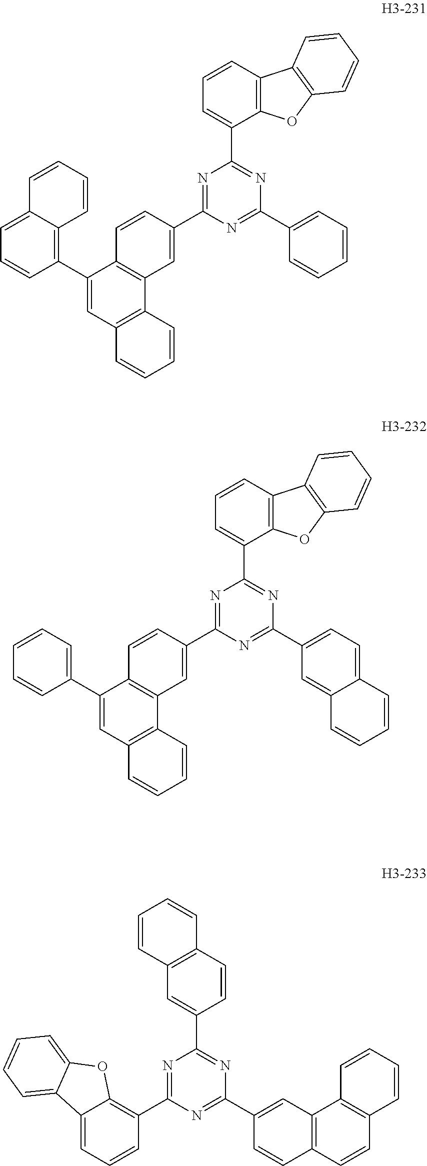 [SMILES: c1ccc(-c2nc(-c3ccc4c(-c5cccc6ccccc56)cc5ccccc5c4c3)nc(-c3cccc4c3oc3ccccc34)n2)cc1 ; c1ccc(-c2cc3ccccc3c3cc(-c4nc(-c5ccc6ccccc6c5)nc(-c5cccc6c5oc5ccccc56)n4)ccc23)cc1 ; c1ccc2cc(-c3nc(-c4ccc5ccc6ccccc6c5c4)nc(-c4cccc5c4oc4ccccc45)n3)ccc2c1]

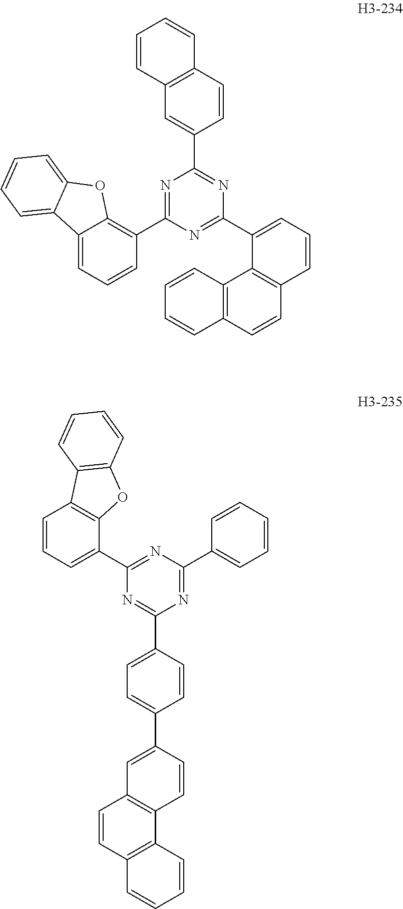 [SMILES: c1ccc2cc(-c3nc(-c4cccc5c4oc4ccccc45)nc(-c4cccc5ccc6ccccc6c45)n3)ccc2c1 ; c1ccc(-c2nc(-c3ccc(-c4ccc5c(ccc6ccccc65)c4)cc3)nc(-c3cccc4c3oc3ccccc34)n2)cc1]

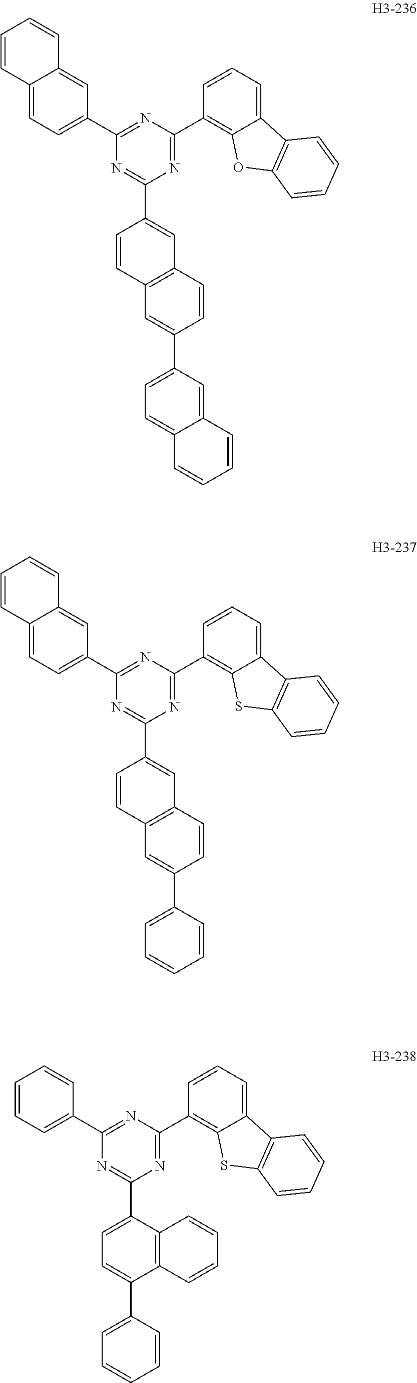 [SMILES: c1ccc2cc(-c3ccc4cc(-c5nc(-c6ccc7ccccc7c6)nc(-c6cccc7c6oc6ccccc67)n5)ccc4c3)ccc2c1 ; c1ccc(-c2ccc3cc(-c4nc(-c5ccc6ccccc6c5)nc(-c5cccc6c5sc5ccccc56)n4)ccc3c2)cc1 ; c1ccc(-c2nc(-c3ccc(-c4ccccc4)c4ccccc34)nc(-c3cccc4c3sc3ccccc34)n2)cc1]

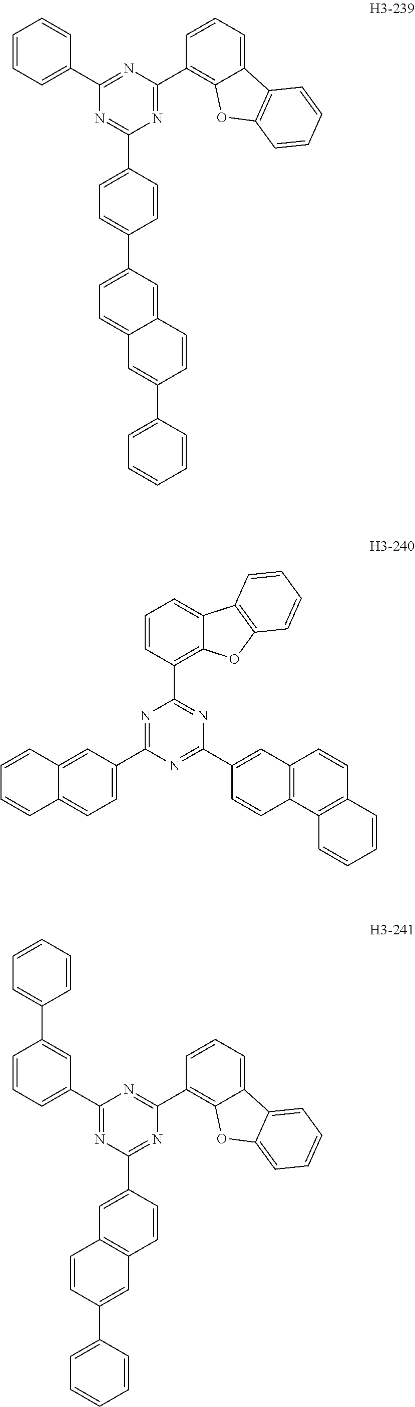 [SMILES: c1ccc(-c2ccc3cc(-c4ccc(-c5nc(-c6ccccc6)nc(-c6cccc7c6oc6ccccc67)n5)cc4)ccc3c2)cc1 ; c1ccc2cc(-c3nc(-c4ccc5c(ccc6ccccc65)c4)nc(-c4cccc5c4oc4ccccc45)n3)ccc2c1 ; c1ccc(-c2cccc(-c3nc(-c4ccc5cc(-c6ccccc6)ccc5c4)nc(-c4cccc5c4oc4ccccc45)n3)c2)cc1]

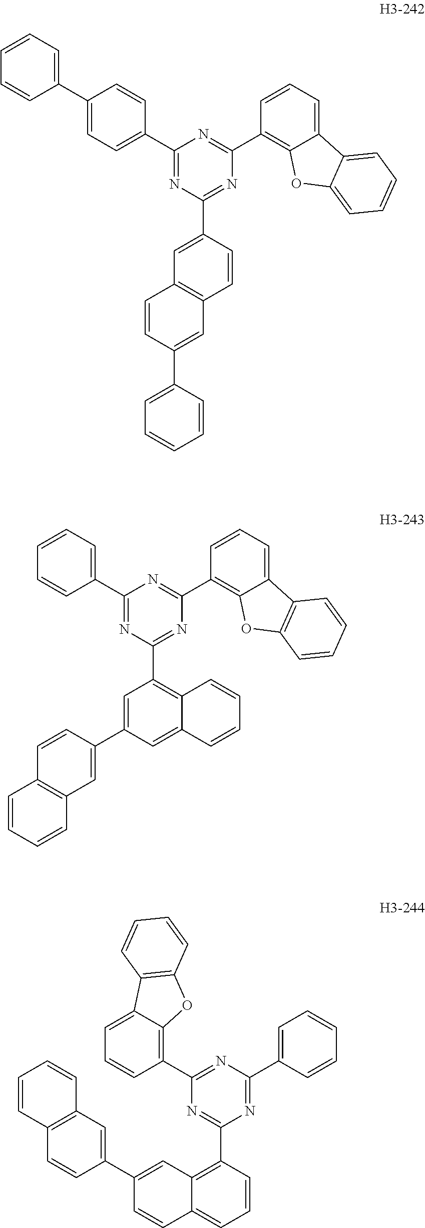 [SMILES: c1ccc(-c2ccc(-c3nc(-c4ccc5cc(-c6ccccc6)ccc5c4)nc(-c4cccc5c4oc4ccccc45)n3)cc2)cc1 ; c1ccc(-c2nc(-c3cc(-c4ccc5ccccc5c4)cc4ccccc34)nc(-c3cccc4c3oc3ccccc34)n2)cc1 ; c1ccc(-c2nc(-c3cccc4ccc(-c5ccc6ccccc6c5)cc34)nc(-c3cccc4c3oc3ccccc34)n2)cc1]

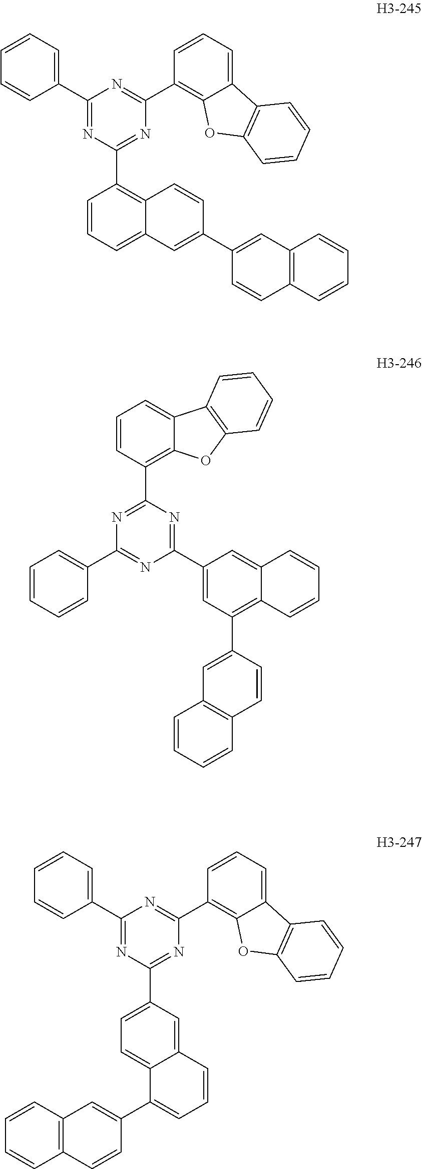 [SMILES: c1ccc(-c2nc(-c3cccc4cc(-c5ccc6ccccc6c5)ccc34)nc(-c3cccc4c3oc3ccccc34)n2)cc1 ; c1ccc(-c2nc(-c3cc(-c4ccc5ccccc5c4)c4ccccc4c3)nc(-c3cccc4c3oc3ccccc34)n2)cc1 ; c1ccc(-c2nc(-c3ccc4c(-c5ccc6ccccc6c5)cccc4c3)nc(-c3cccc4c3oc3ccccc34)n2)cc1]

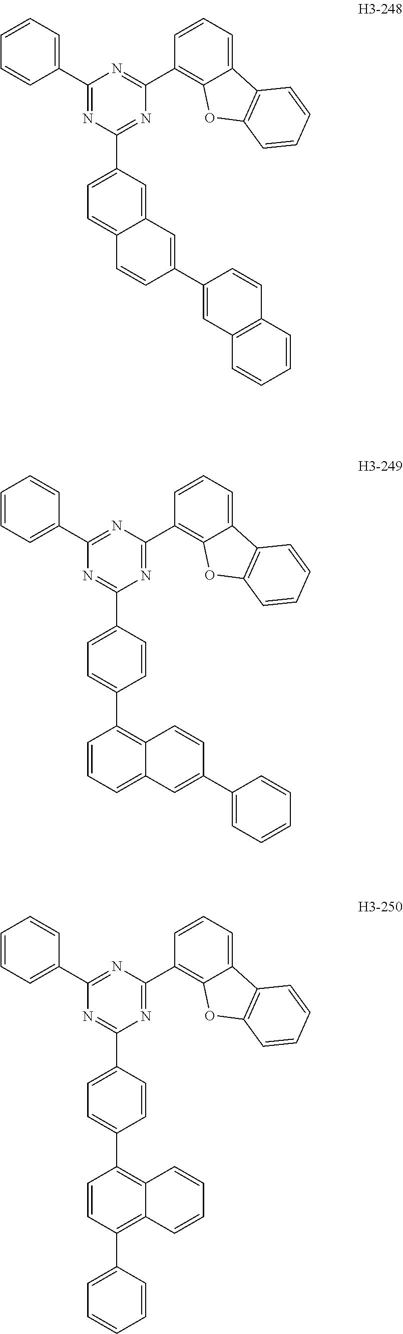 [SMILES: c1ccc(-c2nc(-c3ccc4ccc(-c5ccc6ccccc6c5)cc4c3)nc(-c3cccc4c3oc3ccccc34)n2)cc1 ; c1ccc(-c2ccc3c(-c4ccc(-c5nc(-c6ccccc6)nc(-c6cccc7c6oc6ccccc67)n5)cc4)cccc3c2)cc1 ; c1ccc(-c2nc(-c3ccc(-c4ccc(-c5ccccc5)c5ccccc45)cc3)nc(-c3cccc4c3oc3ccccc34)n2)cc1]

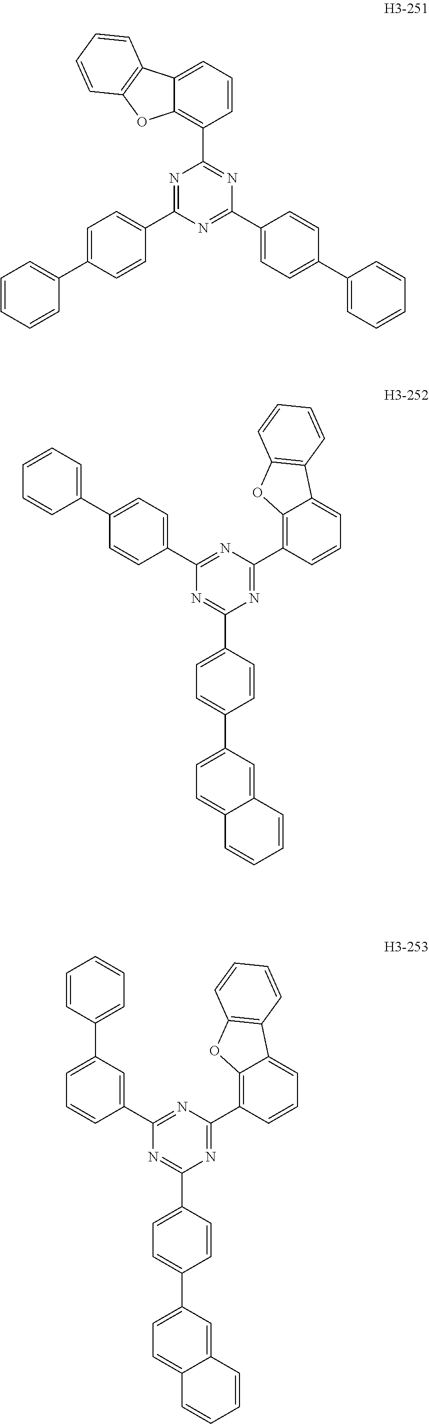 [SMILES: c1ccc(-c2ccc(-c3nc(-c4ccc(-c5ccccc5)cc4)nc(-c4cccc5c4oc4ccccc45)n3)cc2)cc1 ; c1ccc(-c2ccc(-c3nc(-c4ccc(-c5ccc6ccccc6c5)cc4)nc(-c4cccc5c4oc4ccccc45)n3)cc2)cc1 ; c1ccc(-c2cccc(-c3nc(-c4ccc(-c5ccc6ccccc6c5)cc4)nc(-c4cccc5c4oc4ccccc45)n3)c2)cc1]

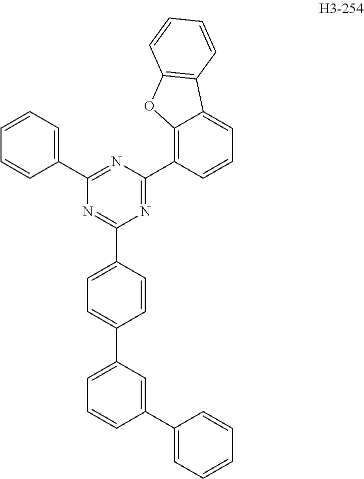 [SMILES: c1ccc(-c2cccc(-c3ccc(-c4nc(-c5ccccc5)nc(-c5cccc6c5oc5ccccc56)n4)cc3)c2)cc1]

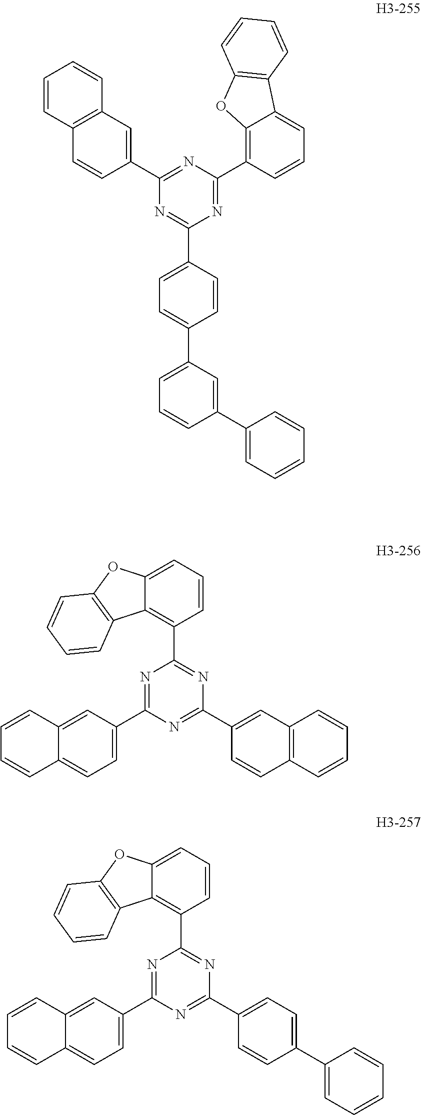 [SMILES: c1ccc(-c2cccc(-c3ccc(-c4nc(-c5ccc6ccccc6c5)nc(-c5cccc6c5oc5ccccc56)n4)cc3)c2)cc1 ; c1ccc2cc(-c3nc(-c4ccc5ccccc5c4)nc(-c4cccc5oc6ccccc6c45)n3)ccc2c1 ; c1ccc(-c2ccc(-c3nc(-c4ccc5ccccc5c4)nc(-c4cccc5oc6ccccc6c45)n3)cc2)cc1]

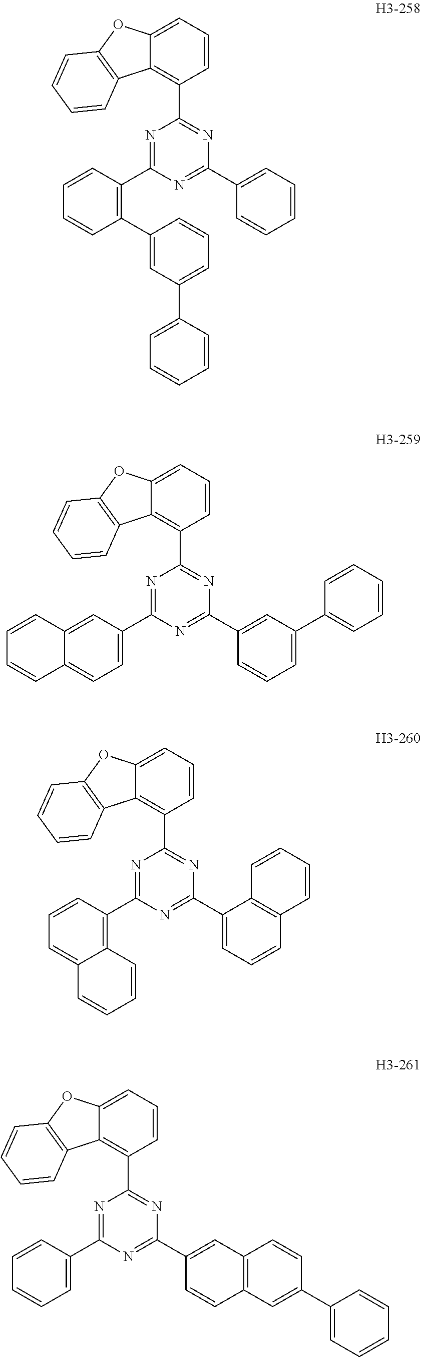 [SMILES: c1ccc(-c2cccc(-c3ccccc3-c3nc(-c4ccccc4)nc(-c4cccc5oc6ccccc6c45)n3)c2)cc1 ; c1ccc(-c2cccc(-c3nc(-c4ccc5ccccc5c4)nc(-c4cccc5oc6ccccc6c45)n3)c2)cc1 ; c1ccc2c(-c3nc(-c4cccc5ccccc45)nc(-c4cccc5oc6ccccc6c45)n3)cccc2c1 ; c1ccc(-c2ccc3cc(-c4nc(-c5ccccc5)nc(-c5cccc6oc7ccccc7c56)n4)ccc3c2)cc1]

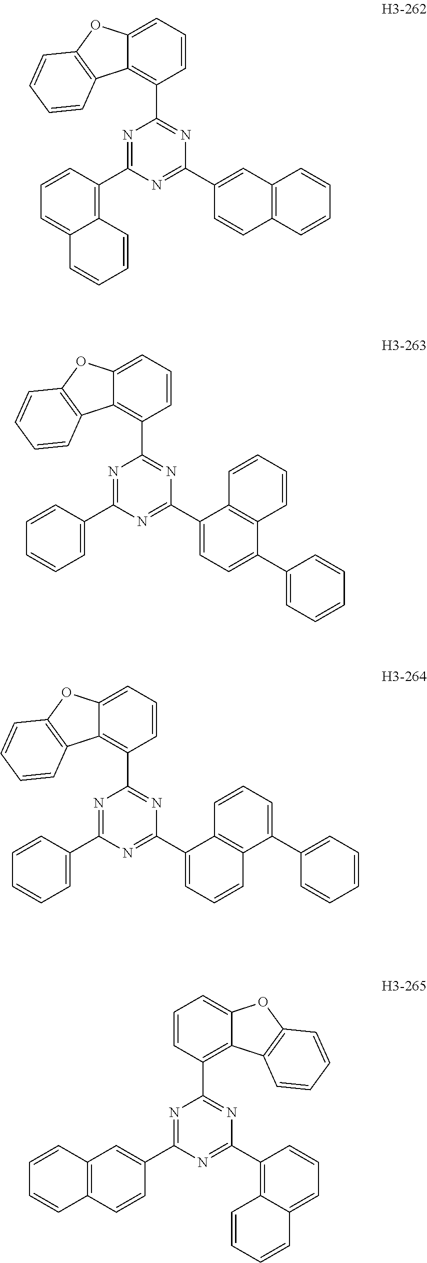 [SMILES: c1ccc2cc(-c3nc(-c4cccc5ccccc45)nc(-c4cccc5oc6ccccc6c45)n3)ccc2c1 ; c1ccc(-c2nc(-c3ccc(-c4ccccc4)c4ccccc34)nc(-c3cccc4oc5ccccc5c34)n2)cc1 ; c1ccc(-c2nc(-c3cccc4c(-c5ccccc5)cccc34)nc(-c3cccc4oc5ccccc5c34)n2)cc1 ; c1ccc2cc(-c3nc(-c4cccc5ccccc45)nc(-c4cccc5oc6ccccc6c45)n3)ccc2c1]

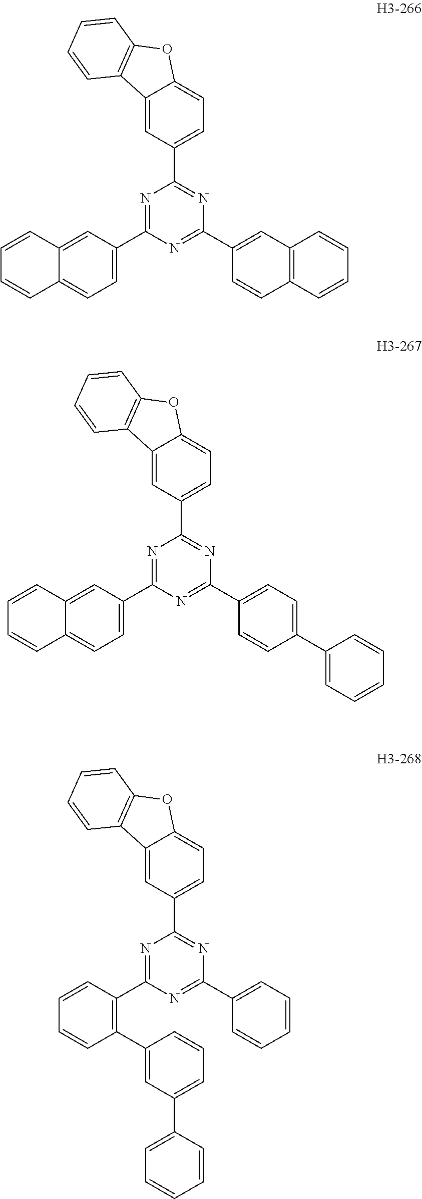 [SMILES: c1ccc2cc(-c3nc(-c4ccc5ccccc5c4)nc(-c4ccc5oc6ccccc6c5c4)n3)ccc2c1 ; c1ccc(-c2ccc(-c3nc(-c4ccc5ccccc5c4)nc(-c4ccc5oc6ccccc6c5c4)n3)cc2)cc1 ; c1ccc(-c2cccc(-c3ccccc3-c3nc(-c4ccccc4)nc(-c4ccc5oc6ccccc6c5c4)n3)c2)cc1]

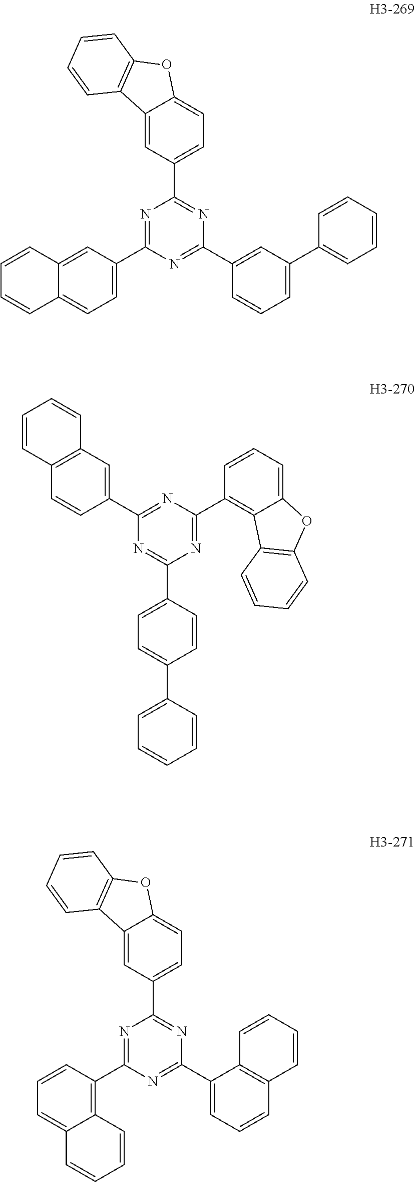 [SMILES: c1ccc(-c2cccc(-c3nc(-c4ccc5ccccc5c4)nc(-c4ccc5oc6ccccc6c5c4)n3)c2)cc1 ; c1ccc(-c2ccc(-c3nc(-c4ccc5ccccc5c4)nc(-c4cccc5oc6ccccc6c45)n3)cc2)cc1 ; c1ccc2c(-c3nc(-c4ccc5oc6ccccc6c5c4)nc(-c4cccc5ccccc45)n3)cccc2c1]

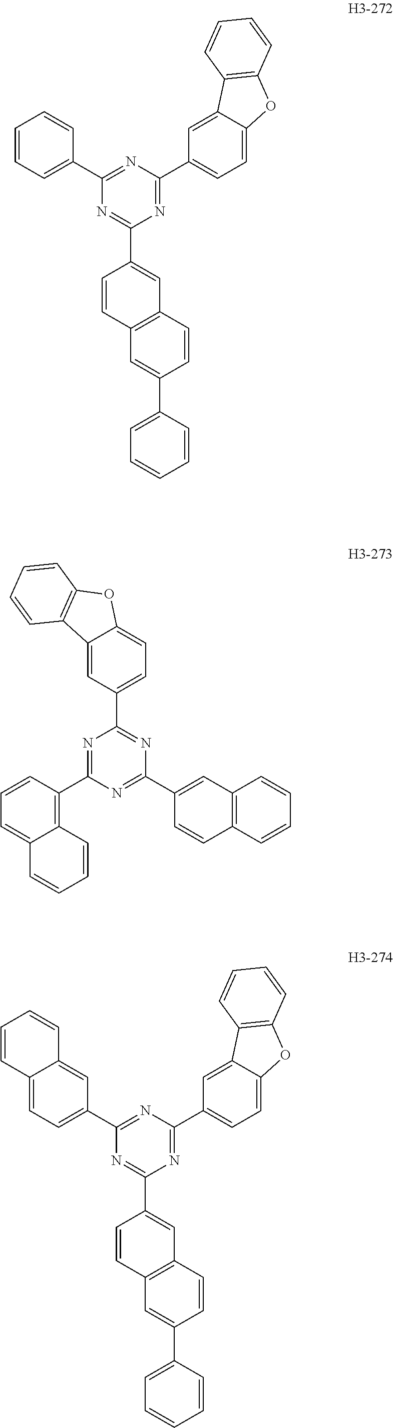 [SMILES: c1ccc(-c2ccc3cc(-c4nc(-c5ccccc5)nc(-c5ccc6oc7ccccc7c6c5)n4)ccc3c2)cc1 ; c1ccc2cc(-c3nc(-c4ccc5oc6ccccc6c5c4)nc(-c4cccc5ccccc45)n3)ccc2c1 ; c1ccc(-c2ccc3cc(-c4nc(-c5ccc6ccccc6c5)nc(-c5ccc6oc7ccccc7c6c5)n4)ccc3c2)cc1]

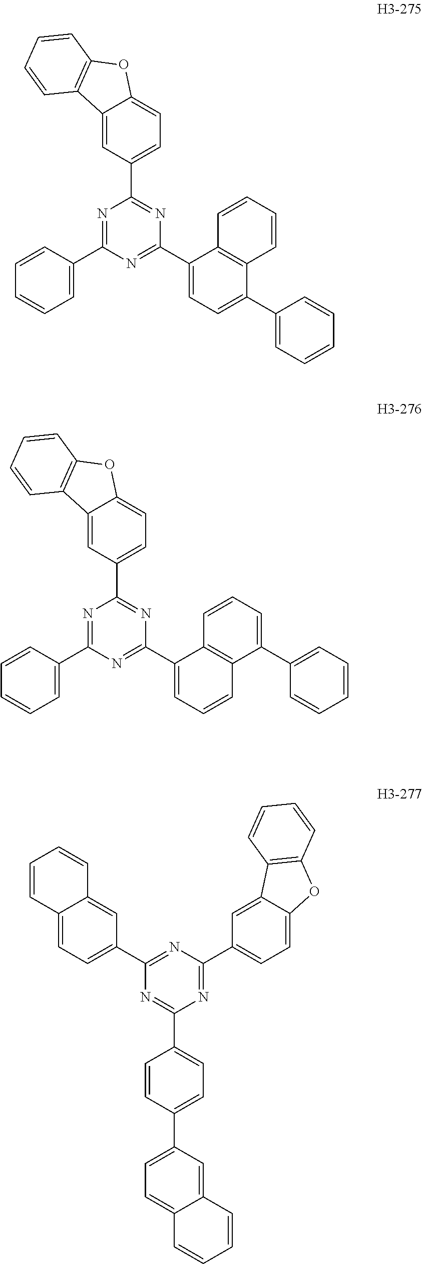 [SMILES: c1ccc(-c2nc(-c3ccc4oc5ccccc5c4c3)nc(-c3ccc(-c4ccccc4)c4ccccc34)n2)cc1 ; c1ccc(-c2nc(-c3ccc4oc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6oc7ccccc7c6c5)n4)cc3)ccc2c1]

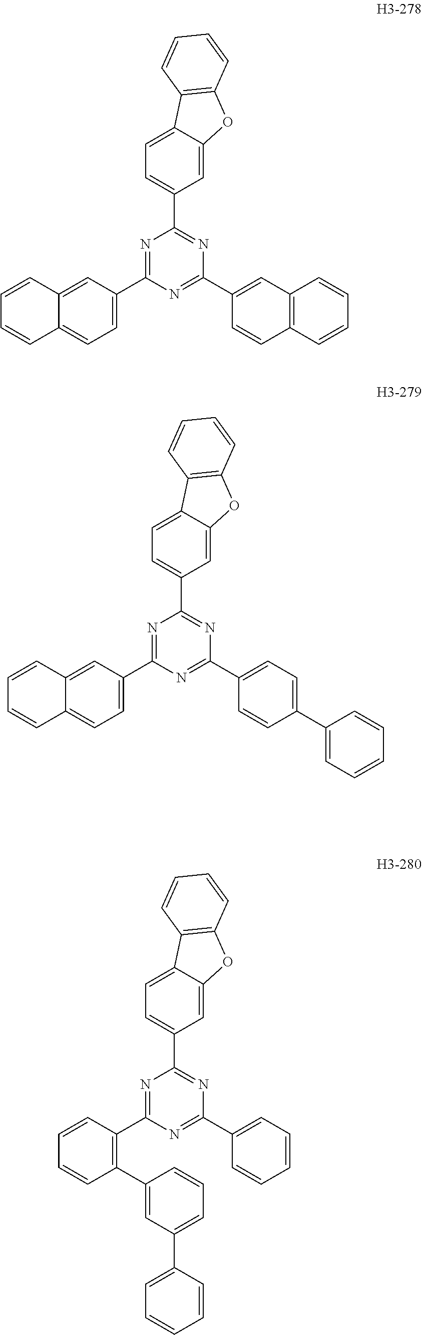 [SMILES: c1ccc2cc(-c3nc(-c4ccc5ccccc5c4)nc(-c4ccc5c(c4)oc4ccccc45)n3)ccc2c1 ; c1ccc(-c2ccc(-c3nc(-c4ccc5ccccc5c4)nc(-c4ccc5c(c4)oc4ccccc45)n3)cc2)cc1 ; c1ccc(-c2cccc(-c3ccccc3-c3nc(-c4ccccc4)nc(-c4ccc5c(c4)oc4ccccc45)n3)c2)cc1]

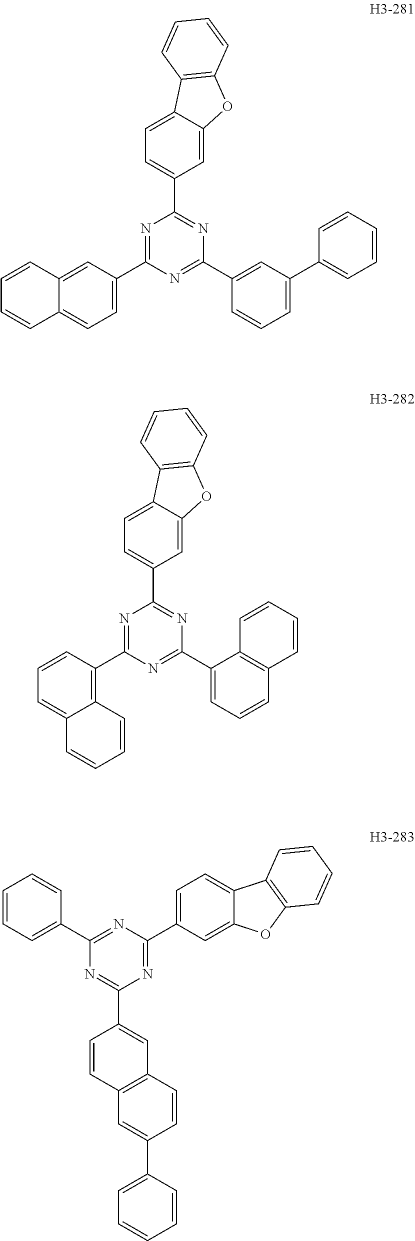 [SMILES: c1ccc(-c2cccc(-c3nc(-c4ccc5ccccc5c4)nc(-c4ccc5c(c4)oc4ccccc45)n3)c2)cc1 ; c1ccc2c(-c3nc(-c4ccc5c(c4)oc4ccccc45)nc(-c4cccc5ccccc45)n3)cccc2c1 ; c1ccc(-c2ccc3cc(-c4nc(-c5ccccc5)nc(-c5ccc6c(c5)oc5ccccc56)n4)ccc3c2)cc1]

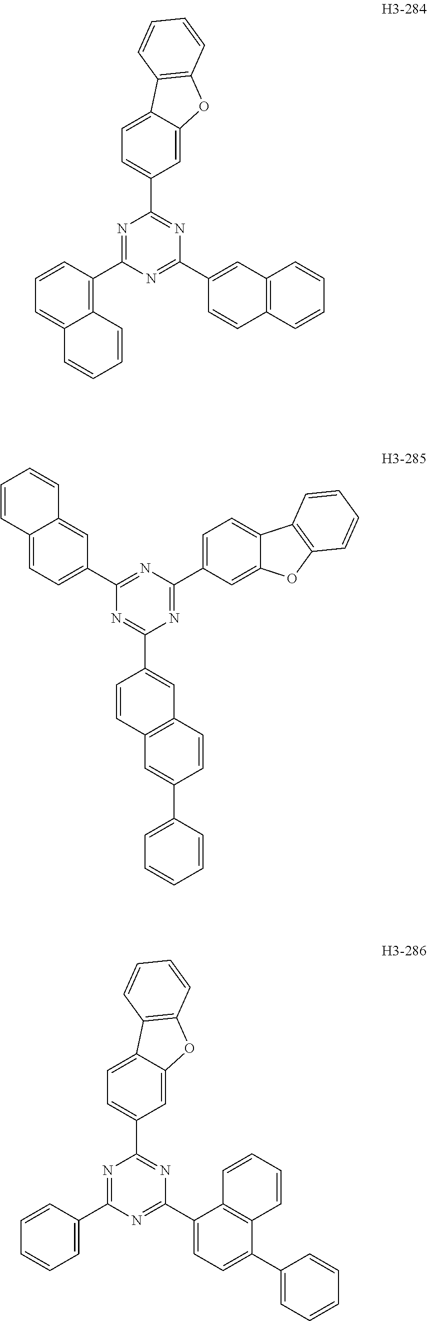 [SMILES: c1ccc2cc(-c3nc(-c4ccc5c(c4)oc4ccccc45)nc(-c4cccc5ccccc45)n3)ccc2c1 ; c1ccc(-c2ccc3cc(-c4nc(-c5ccc6ccccc6c5)nc(-c5ccc6c(c5)oc5ccccc56)n4)ccc3c2)cc1 ; c1ccc(-c2nc(-c3ccc4c(c3)oc3ccccc34)nc(-c3ccc(-c4ccccc4)c4ccccc34)n2)cc1]

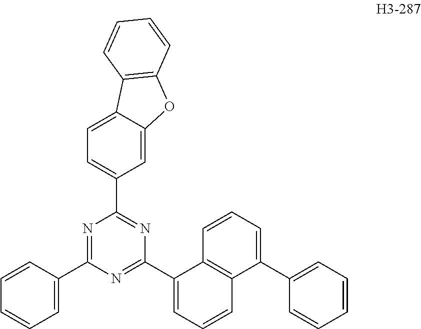 [SMILES: c1ccc(-c2nc(-c3ccc4c(c3)oc3ccccc34)nc(-c3cccc4c(-c5ccccc5)cccc34)n2)cc1]

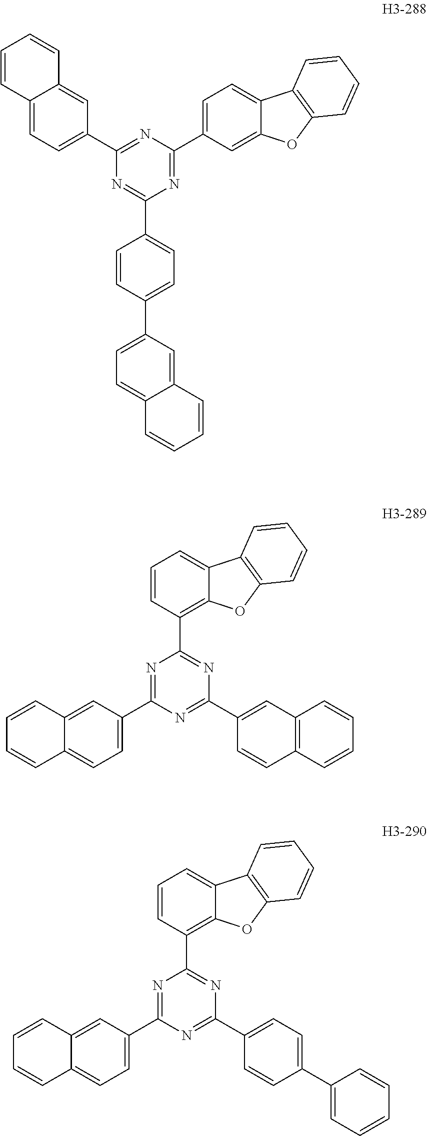 [SMILES: c1ccc2cc(-c3ccc(-c4nc(-c5ccc6ccccc6c5)nc(-c5ccc6c(c5)oc5ccccc56)n4)cc3)ccc2c1 ; c1ccc2cc(-c3nc(-c4ccc5ccccc5c4)nc(-c4cccc5c4oc4ccccc45)n3)ccc2c1 ; c1ccc(-c2ccc(-c3nc(-c4ccc5ccccc5c4)nc(-c4cccc5c4oc4ccccc45)n3)cc2)cc1]

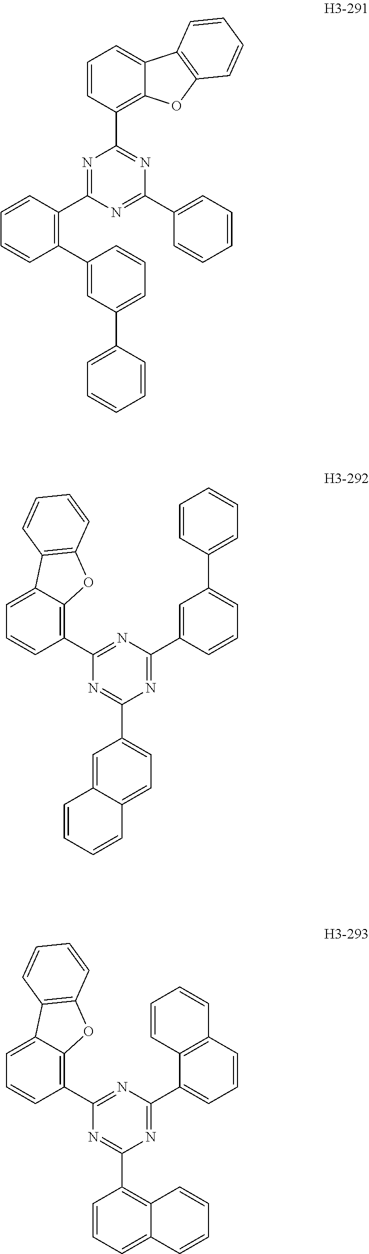 [SMILES: c1ccc(-c2cccc(-c3ccccc3-c3nc(-c4ccccc4)nc(-c4cccc5c4oc4ccccc45)n3)c2)cc1 ; c1ccc(-c2cccc(-c3nc(-c4ccc5ccccc5c4)nc(-c4cccc5c4oc4ccccc45)n3)c2)cc1 ; c1ccc2c(-c3nc(-c4cccc5ccccc45)nc(-c4cccc5c4oc4ccccc45)n3)cccc2c1]

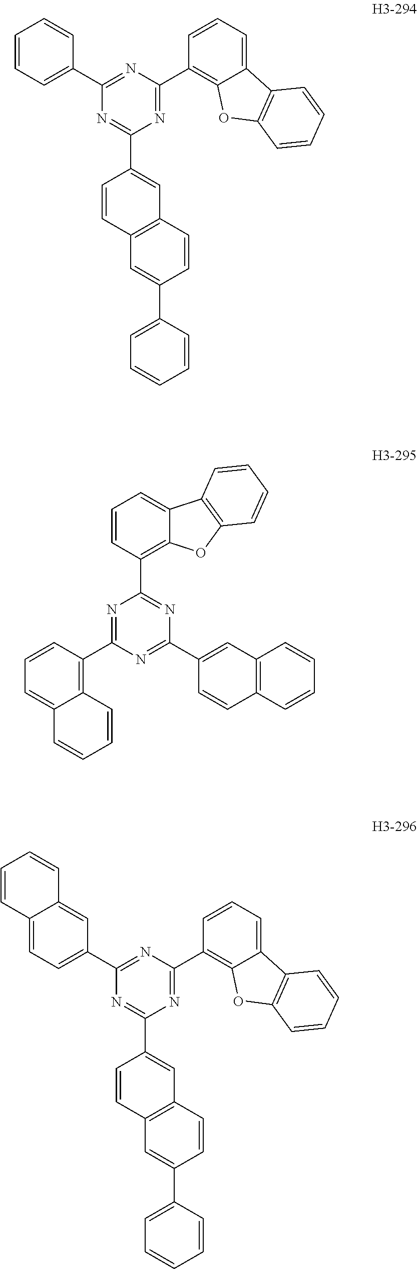 [SMILES: c1ccc(-c2ccc3cc(-c4nc(-c5ccccc5)nc(-c5cccc6c5oc5ccccc56)n4)ccc3c2)cc1 ; c1ccc2cc(-c3nc(-c4cccc5ccccc45)nc(-c4cccc5c4oc4ccccc45)n3)ccc2c1 ; c1ccc(-c2ccc3cc(-c4nc(-c5ccc6ccccc6c5)nc(-c5cccc6c5oc5ccccc56)n4)ccc3c2)cc1]

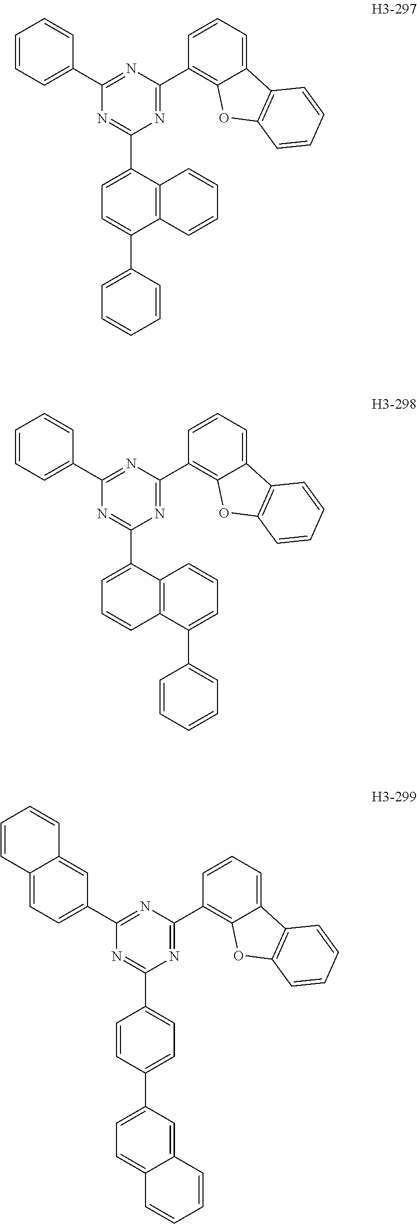 [SMILES: c1ccc(-c2nc(-c3ccc(-c4ccccc4)c4ccccc34)nc(-c3cccc4c3oc3ccccc34)n2)cc1 ; c1ccc(-c2nc(-c3cccc4c(-c5ccccc5)cccc34)nc(-c3cccc4c3oc3ccccc34)n2)cc1 ; c1ccc2cc(-c3ccc(-c4nc(-c5ccc6ccccc6c5)nc(-c5cccc6c5oc5ccccc56)n4)cc3)ccc2c1]

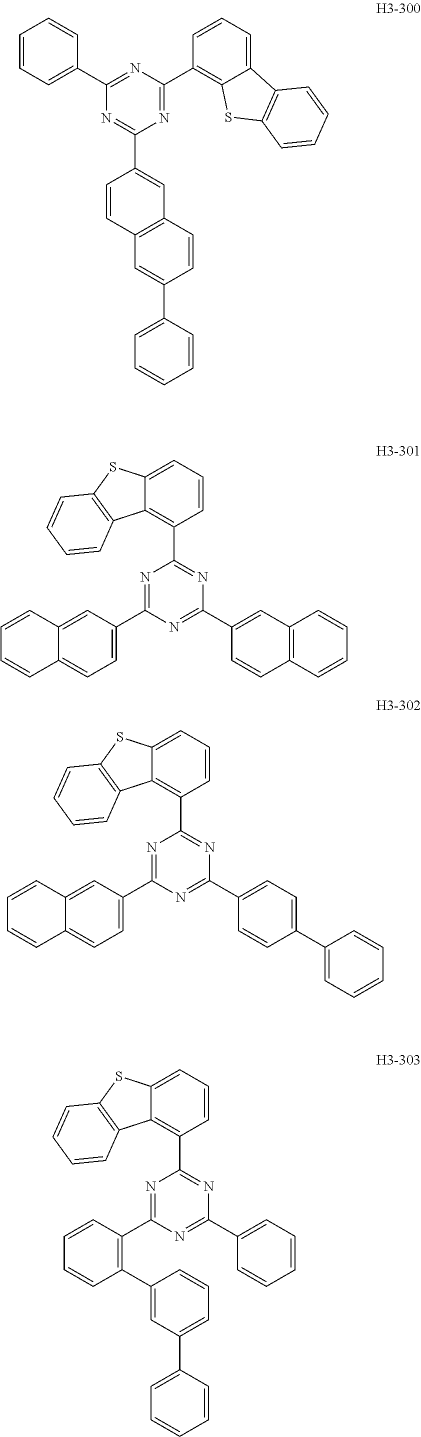 [SMILES: c1ccc(-c2ccc3cc(-c4nc(-c5ccccc5)nc(-c5cccc6c5sc5ccccc56)n4)ccc3c2)cc1 ; c1ccc2cc(-c3nc(-c4ccc5ccccc5c4)nc(-c4cccc5sc6ccccc6c45)n3)ccc2c1 ; c1ccc(-c2ccc(-c3nc(-c4ccc5ccccc5c4)nc(-c4cccc5sc6ccccc6c45)n3)cc2)cc1 ; c1ccc(-c2cccc(-c3ccccc3-c3nc(-c4ccccc4)nc(-c4cccc5sc6ccccc6c45)n3)c2)cc1]

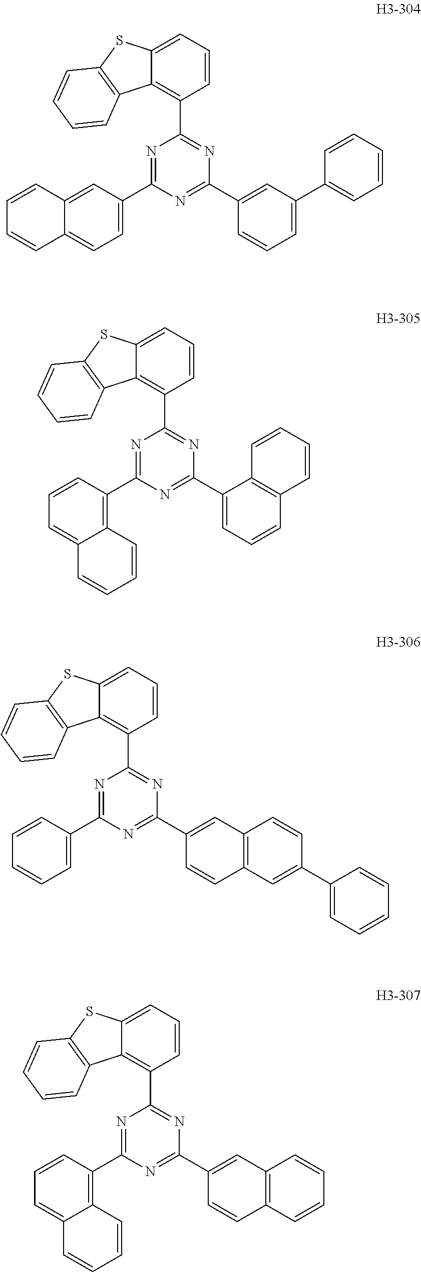 [SMILES: c1ccc(-c2cccc(-c3nc(-c4ccc5ccccc5c4)nc(-c4cccc5sc6ccccc6c45)n3)c2)cc1 ; c1ccc2c(-c3nc(-c4cccc5ccccc45)nc(-c4cccc5sc6ccccc6c45)n3)cccc2c1 ; c1ccc(-c2ccc3cc(-c4nc(-c5ccccc5)nc(-c5cccc6sc7ccccc7c56)n4)ccc3c2)cc1 ; c1ccc2cc(-c3nc(-c4cccc5ccccc45)nc(-c4cccc5sc6ccccc6c45)n3)ccc2c1]

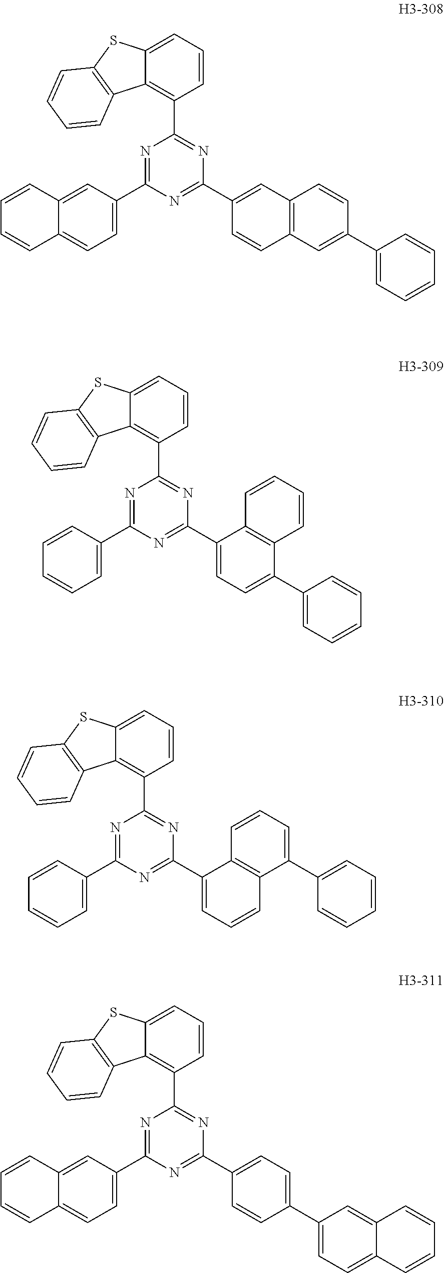 [SMILES: c1ccc(-c2ccc3cc(-c4nc(-c5ccc6ccccc6c5)nc(-c5cccc6sc7ccccc7c56)n4)ccc3c2)cc1 ; c1ccc(-c2nc(-c3ccc(-c4ccccc4)c4ccccc34)nc(-c3cccc4sc5ccccc5c34)n2)cc1 ; c1ccc(-c2nc(-c3cccc4c(-c5ccccc5)cccc34)nc(-c3cccc4sc5ccccc5c34)n2)cc1 ; c1ccc2cc(-c3ccc(-c4nc(-c5ccc6ccccc6c5)nc(-c5cccc6sc7ccccc7c56)n4)cc3)ccc2c1]

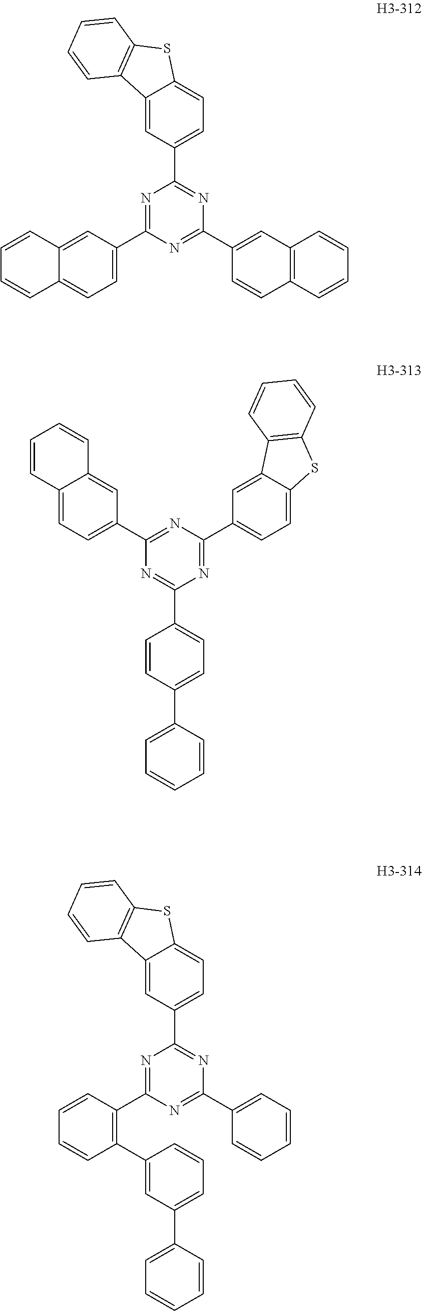 [SMILES: c1ccc2cc(-c3nc(-c4ccc5ccccc5c4)nc(-c4ccc5sc6ccccc6c5c4)n3)ccc2c1 ; c1ccc(-c2ccc(-c3nc(-c4ccc5ccccc5c4)nc(-c4ccc5sc6ccccc6c5c4)n3)cc2)cc1 ; c1ccc(-c2cccc(-c3ccccc3-c3nc(-c4ccccc4)nc(-c4ccc5sc6ccccc6c5c4)n3)c2)cc1]

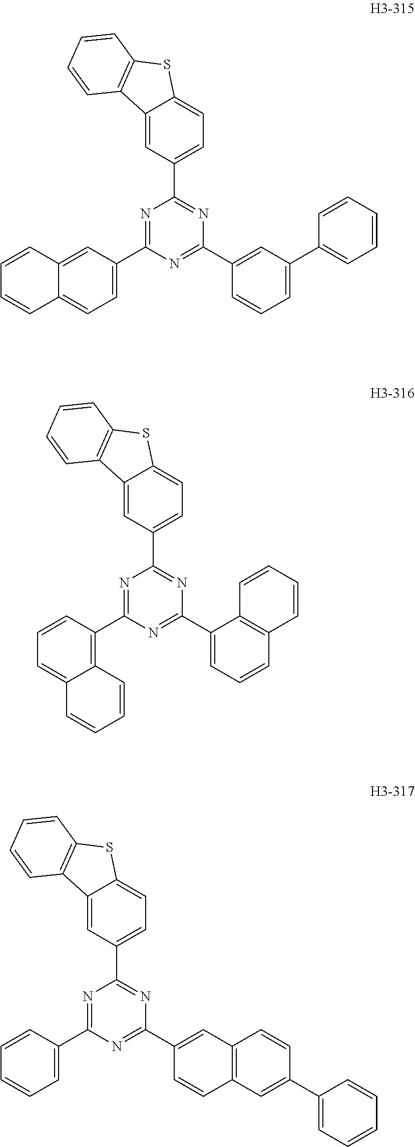 [SMILES: c1ccc(-c2cccc(-c3nc(-c4ccc5ccccc5c4)nc(-c4ccc5sc6ccccc6c5c4)n3)c2)cc1 ; c1ccc2c(-c3nc(-c4ccc5sc6ccccc6c5c4)nc(-c4cccc5ccccc45)n3)cccc2c1 ; c1ccc(-c2ccc3cc(-c4nc(-c5ccccc5)nc(-c5ccc6sc7ccccc7c6c5)n4)ccc3c2)cc1]

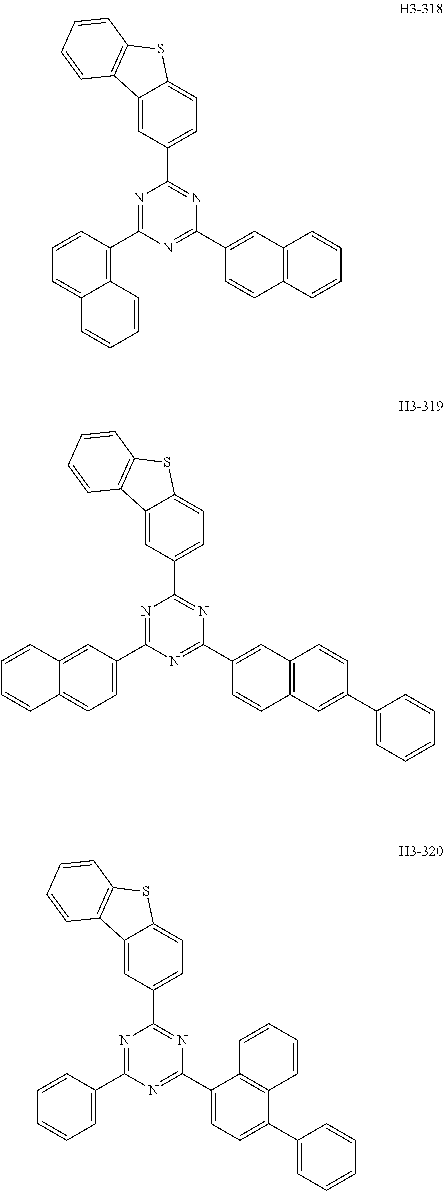 [SMILES: c1ccc2cc(-c3nc(-c4ccc5sc6ccccc6c5c4)nc(-c4cccc5ccccc45)n3)ccc2c1 ; c1ccc(-c2ccc3cc(-c4nc(-c5ccc6ccccc6c5)nc(-c5ccc6sc7ccccc7c6c5)n4)ccc3c2)cc1 ; c1ccc(-c2nc(-c3ccc4sc5ccccc5c4c3)nc(-c3ccc(-c4ccccc4)c4ccccc34)n2)cc1]

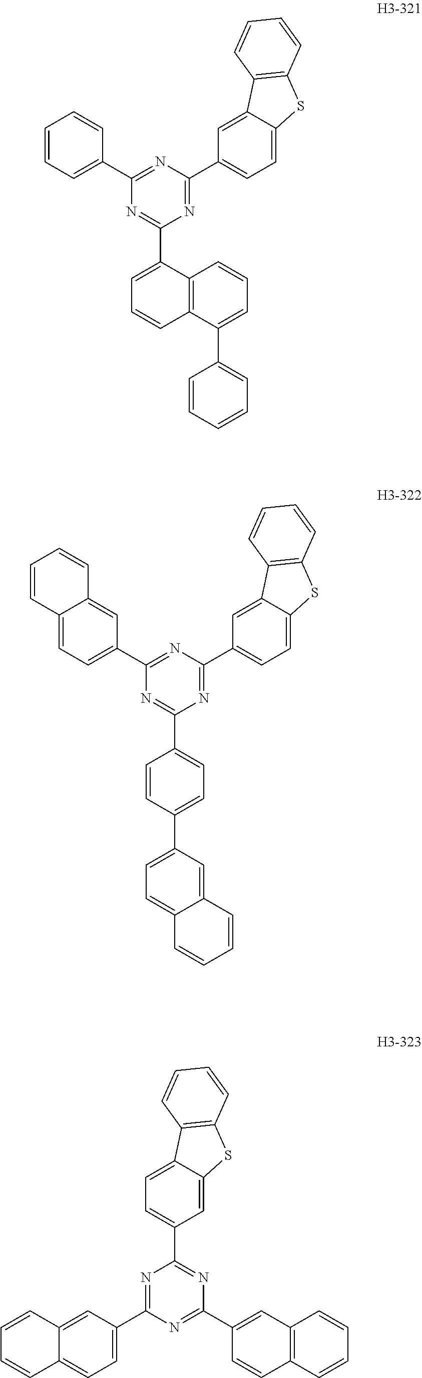 [SMILES: c1ccc(-c2nc(-c3ccc4sc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6sc7ccccc7c6c5)n4)cc3)ccc2c1 ; c1ccc2cc(-c3nc(-c4ccc5ccccc5c4)nc(-c4ccc5c(c4)sc4ccccc45)n3)ccc2c1]

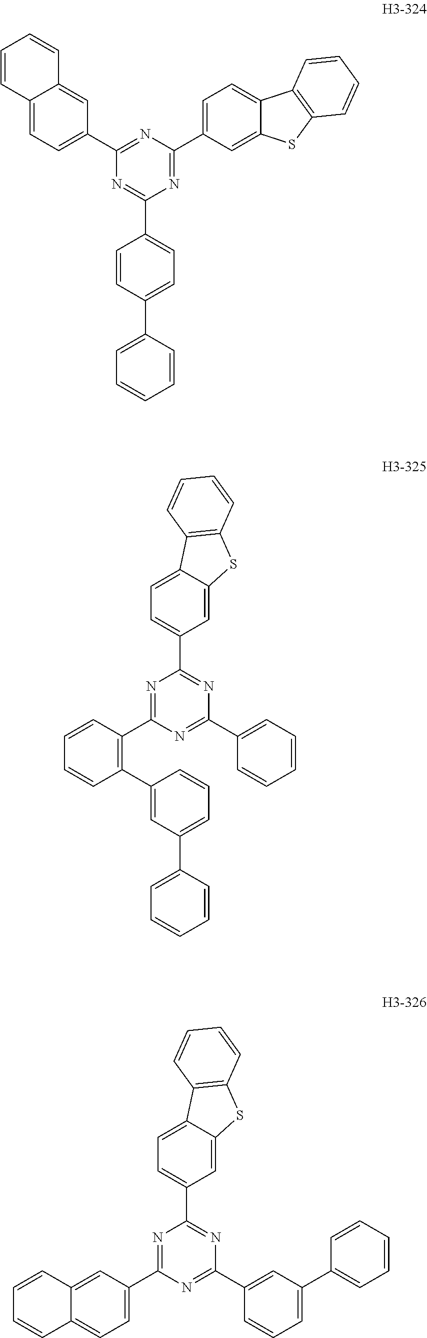 [SMILES: c1ccc(-c2ccc(-c3nc(-c4ccc5ccccc5c4)nc(-c4ccc5c(c4)sc4ccccc45)n3)cc2)cc1 ; c1ccc(-c2cccc(-c3ccccc3-c3nc(-c4ccccc4)nc(-c4ccc5c(c4)sc4ccccc45)n3)c2)cc1 ; c1ccc(-c2cccc(-c3nc(-c4ccc5ccccc5c4)nc(-c4ccc5c(c4)sc4ccccc45)n3)c2)cc1]

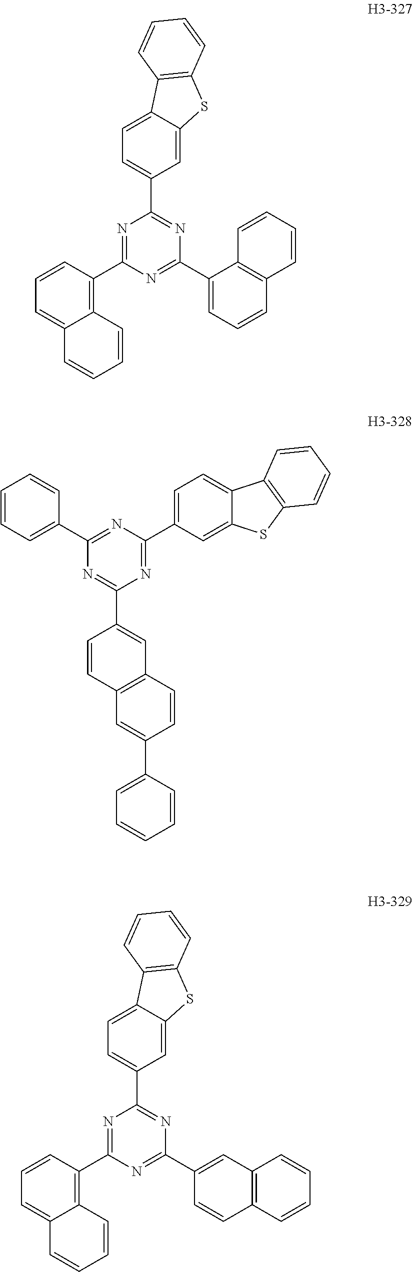 [SMILES: c1ccc2c(-c3nc(-c4ccc5c(c4)sc4ccccc45)nc(-c4cccc5ccccc45)n3)cccc2c1 ; c1ccc(-c2ccc3cc(-c4nc(-c5ccccc5)nc(-c5ccc6c(c5)sc5ccccc56)n4)ccc3c2)cc1 ; c1ccc2cc(-c3nc(-c4ccc5c(c4)sc4ccccc45)nc(-c4cccc5ccccc45)n3)ccc2c1]

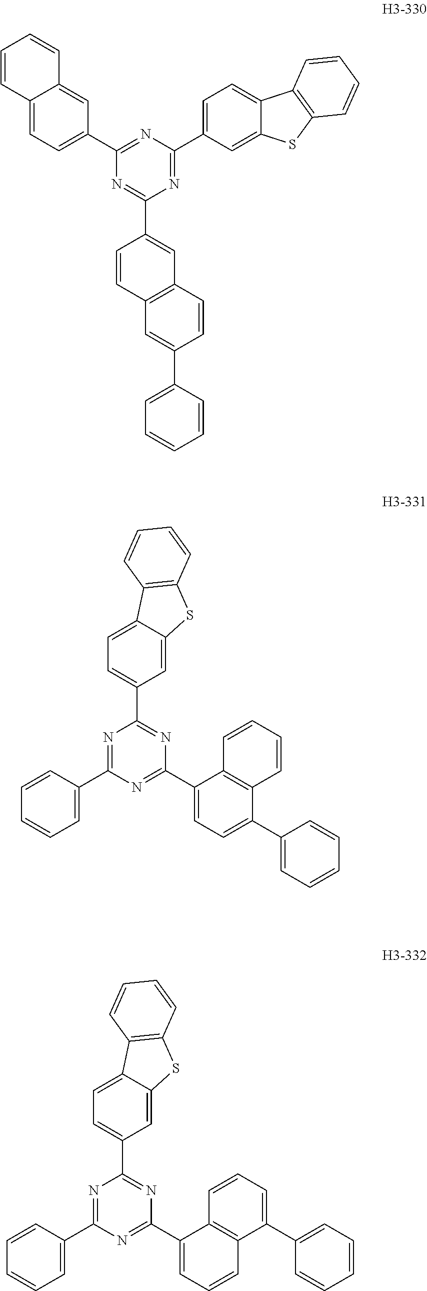 [SMILES: c1ccc(-c2ccc3cc(-c4nc(-c5ccc6ccccc6c5)nc(-c5ccc6c(c5)sc5ccccc56)n4)ccc3c2)cc1 ; c1ccc(-c2nc(-c3ccc4c(c3)sc3ccccc34)nc(-c3ccc(-c4ccccc4)c4ccccc34)n2)cc1 ; c1ccc(-c2nc(-c3ccc4c(c3)sc3ccccc34)nc(-c3cccc4c(-c5ccccc5)cccc34)n2)cc1]

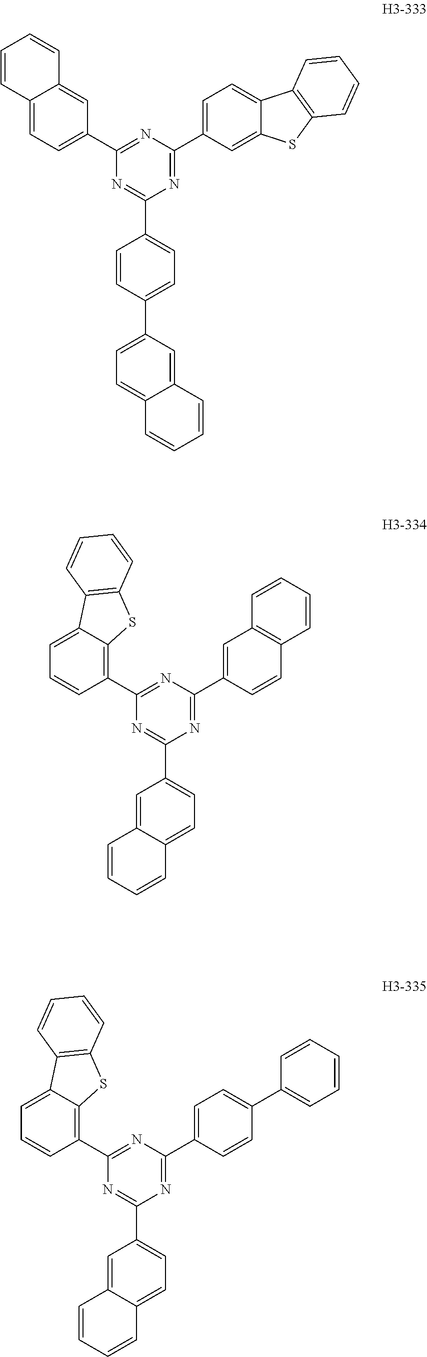 [SMILES: c1ccc2cc(-c3ccc(-c4nc(-c5ccc6ccccc6c5)nc(-c5ccc6c(c5)sc5ccccc56)n4)cc3)ccc2c1 ; c1ccc2cc(-c3nc(-c4ccc5ccccc5c4)nc(-c4cccc5c4sc4ccccc45)n3)ccc2c1 ; c1ccc(-c2ccc(-c3nc(-c4ccc5ccccc5c4)nc(-c4cccc5c4sc4ccccc45)n3)cc2)cc1]

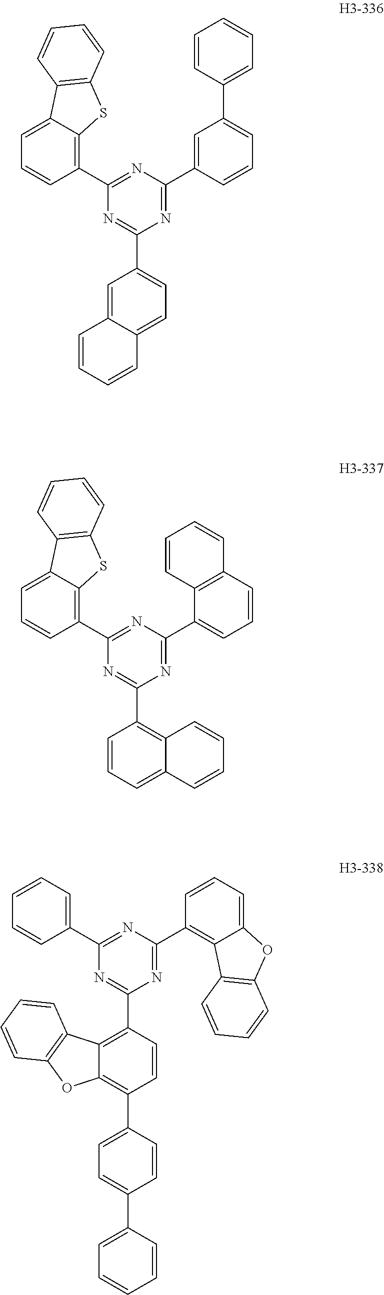 [SMILES: c1ccc(-c2cccc(-c3nc(-c4ccc5ccccc5c4)nc(-c4cccc5c4sc4ccccc45)n3)c2)cc1 ; c1ccc2c(-c3nc(-c4cccc5ccccc45)nc(-c4cccc5c4sc4ccccc45)n3)cccc2c1 ; c1ccc(-c2ccc(-c3ccc(-c4nc(-c5ccccc5)nc(-c5cccc6oc7ccccc7c56)n4)c4c3oc3ccccc34)cc2)cc1]

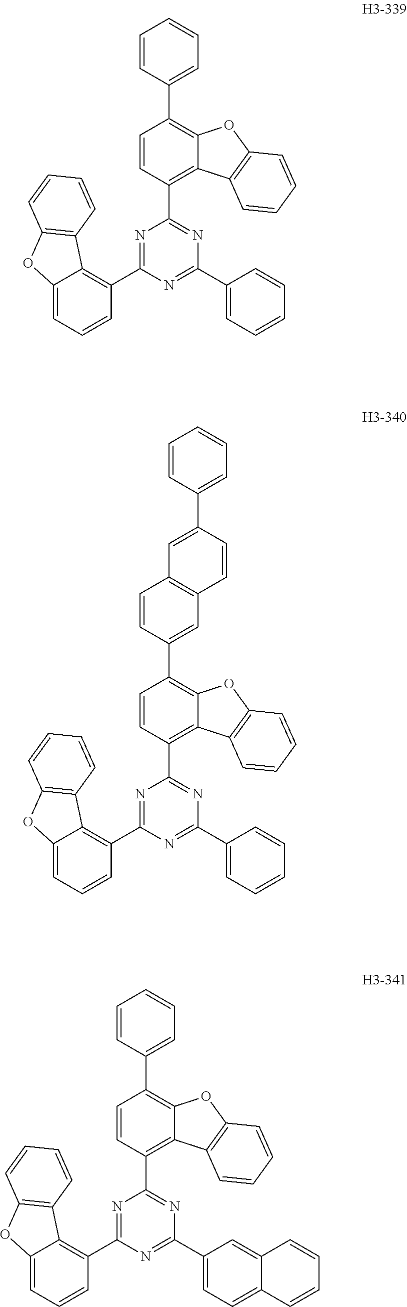 [SMILES: c1ccc(-c2nc(-c3cccc4oc5ccccc5c34)nc(-c3ccc(-c4ccccc4)c4oc5ccccc5c34)n2)cc1 ; c1ccc(-c2ccc3cc(-c4ccc(-c5nc(-c6ccccc6)nc(-c6cccc7oc8ccccc8c67)n5)c5c4oc4ccccc45)ccc3c2)cc1 ; c1ccc(-c2ccc(-c3nc(-c4ccc5ccccc5c4)nc(-c4cccc5oc6ccccc6c45)n3)c3c2oc2ccccc23)cc1]

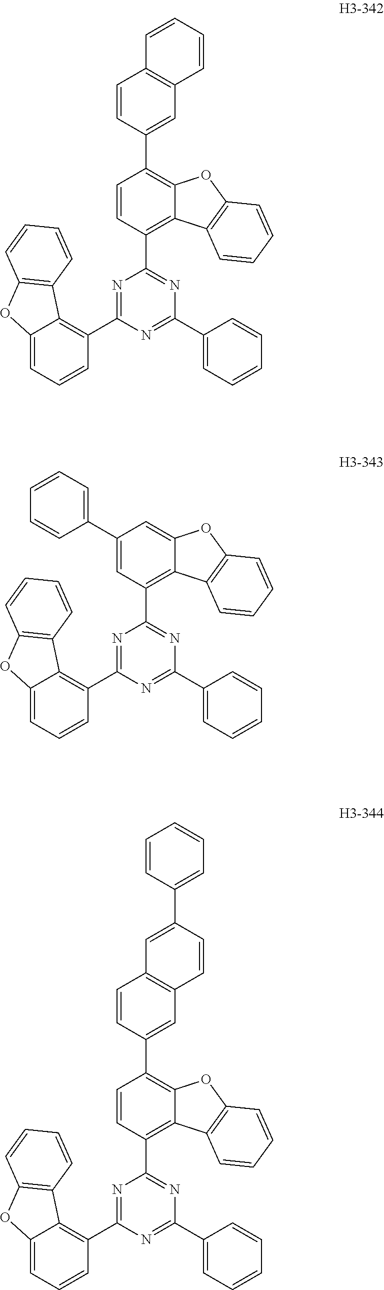 [SMILES: c1ccc(-c2nc(-c3cccc4oc5ccccc5c34)nc(-c3ccc(-c4ccc5ccccc5c4)c4oc5ccccc5c34)n2)cc1 ; c1ccc(-c2cc(-c3nc(-c4ccccc4)nc(-c4cccc5oc6ccccc6c45)n3)c3c(c2)oc2ccccc23)cc1 ; c1ccc(-c2ccc3cc(-c4ccc(-c5nc(-c6ccccc6)nc(-c6cccc7oc8ccccc8c67)n5)c5c4oc4ccccc45)ccc3c2)cc1]

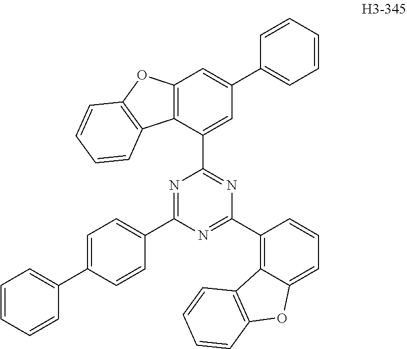 [SMILES: c1ccc(-c2ccc(-c3nc(-c4cccc5oc6ccccc6c45)nc(-c4cc(-c5ccccc5)cc5oc6ccccc6c45)n3)cc2)cc1]

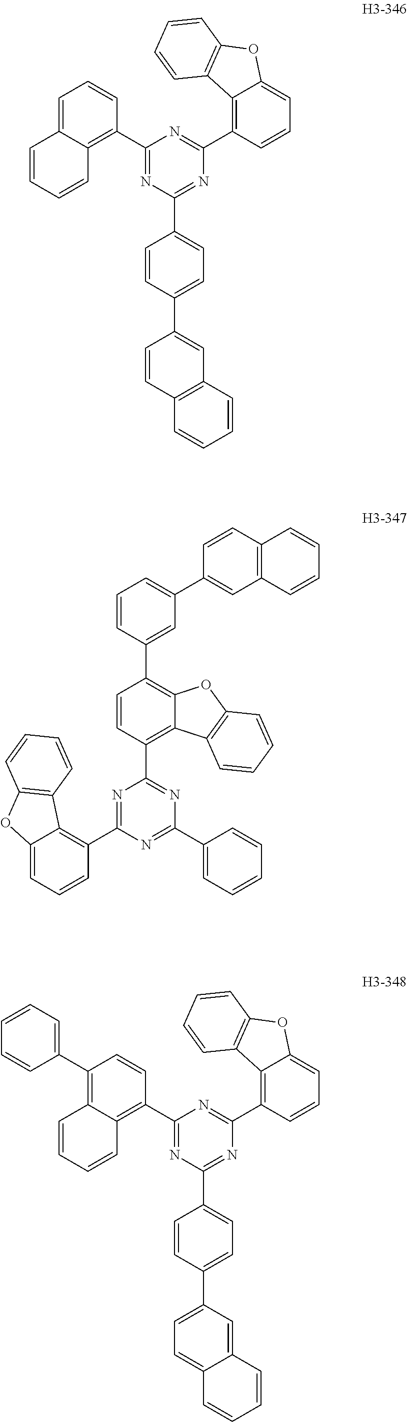 [SMILES: c1ccc2cc(-c3ccc(-c4nc(-c5cccc6ccccc56)nc(-c5cccc6oc7ccccc7c56)n4)cc3)ccc2c1 ; c1ccc(-c2nc(-c3cccc4oc5ccccc5c34)nc(-c3ccc(-c4cccc(-c5ccc6ccccc6c5)c4)c4oc5ccccc5c34)n2)cc1 ; c1ccc(-c2ccc(-c3nc(-c4ccc(-c5ccc6ccccc6c5)cc4)nc(-c4cccc5oc6ccccc6c45)n3)c3ccccc23)cc1]

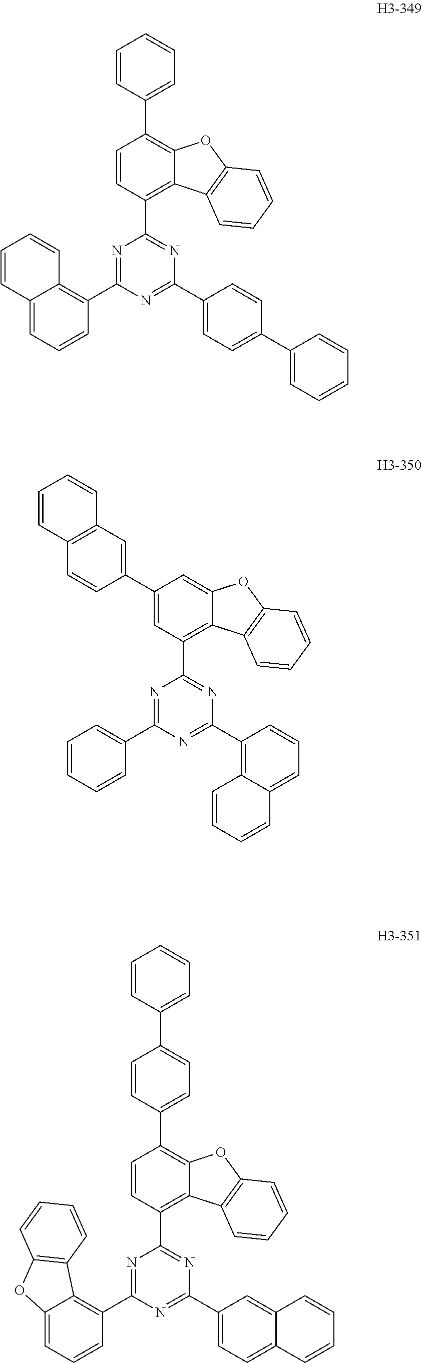 [SMILES: c1ccc(-c2ccc(-c3nc(-c4cccc5ccccc45)nc(-c4ccc(-c5ccccc5)c5oc6ccccc6c45)n3)cc2)cc1 ; c1ccc(-c2nc(-c3cccc4ccccc34)nc(-c3cc(-c4ccc5ccccc5c4)cc4oc5ccccc5c34)n2)cc1 ; c1ccc(-c2ccc(-c3ccc(-c4nc(-c5ccc6ccccc6c5)nc(-c5cccc6oc7ccccc7c56)n4)c4c3oc3ccccc34)cc2)cc1]

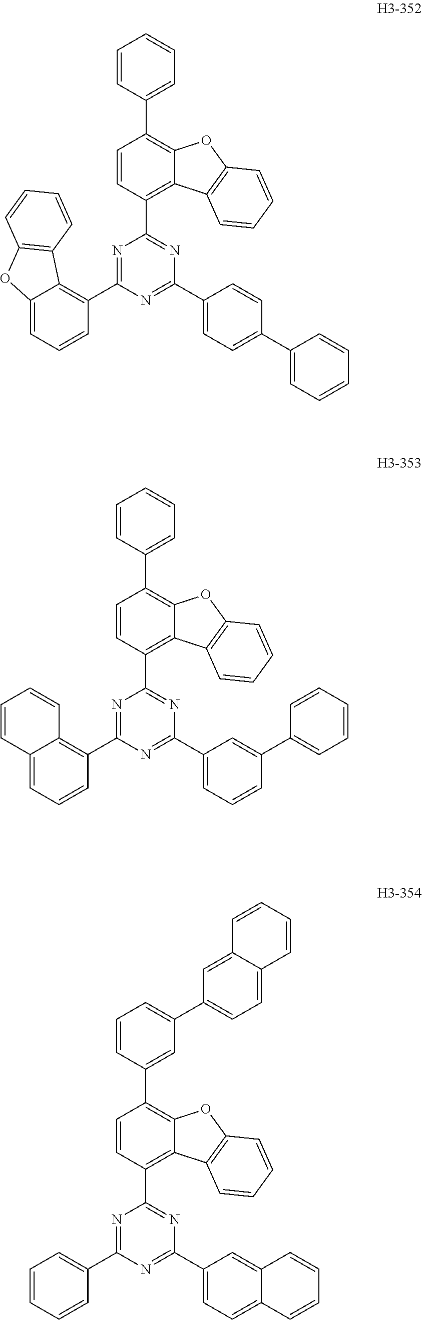 [SMILES: c1ccc(-c2ccc(-c3nc(-c4cccc5oc6ccccc6c45)nc(-c4ccc(-c5ccccc5)c5oc6ccccc6c45)n3)cc2)cc1 ; c1ccc(-c2cccc(-c3nc(-c4cccc5ccccc45)nc(-c4ccc(-c5ccccc5)c5oc6ccccc6c45)n3)c2)cc1 ; c1ccc(-c2nc(-c3ccc4ccccc4c3)nc(-c3ccc(-c4cccc(-c5ccc6ccccc6c5)c4)c4oc5ccccc5c34)n2)cc1]

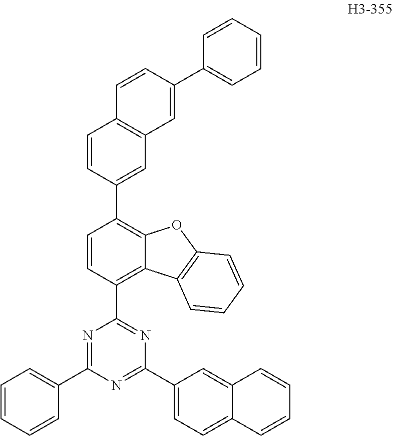 [SMILES: c1ccc(-c2ccc3ccc(-c4ccc(-c5nc(-c6ccccc6)nc(-c6ccc7ccccc7c6)n5)c5c4oc4ccccc45)cc3c2)cc1]

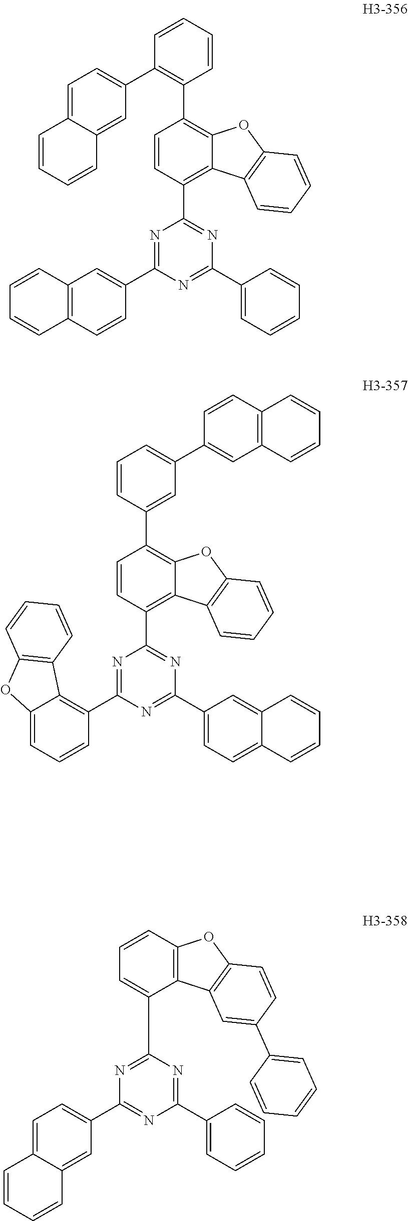 [SMILES: c1ccc(-c2nc(-c3ccc4ccccc4c3)nc(-c3ccc(-c4ccccc4-c4ccc5ccccc5c4)c4oc5ccccc5c34)n2)cc1 ; c1cc(-c2ccc3ccccc3c2)cc(-c2ccc(-c3nc(-c4ccc5ccccc5c4)nc(-c4cccc5oc6ccccc6c45)n3)c3c2oc2ccccc23)c1 ; c1ccc(-c2ccc3oc4cccc(-c5nc(-c6ccccc6)nc(-c6ccc7ccccc7c6)n5)c4c3c2)cc1]

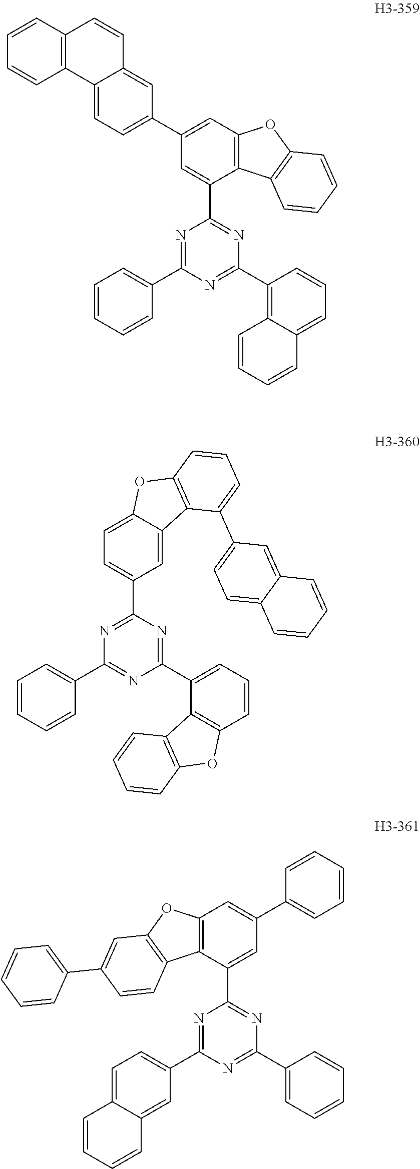 [SMILES: c1ccc(-c2nc(-c3cccc4ccccc34)nc(-c3cc(-c4ccc5c(ccc6ccccc65)c4)cc4oc5ccccc5c34)n2)cc1 ; c1ccc(-c2nc(-c3ccc4oc5cccc(-c6ccc7ccccc7c6)c5c4c3)nc(-c3cccc4oc5ccccc5c34)n2)cc1 ; c1ccc(-c2ccc3c(c2)oc2cc(-c4ccccc4)cc(-c4nc(-c5ccccc5)nc(-c5ccc6ccccc6c5)n4)c23)cc1]

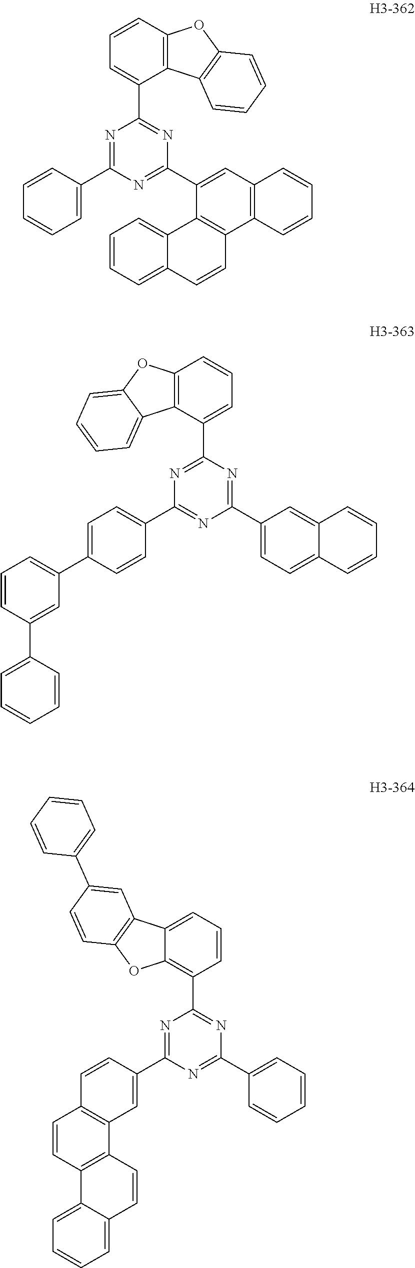 [SMILES: c1ccc(-c2nc(-c3cccc4oc5ccccc5c34)nc(-c3cc4ccccc4c4ccc5ccccc5c34)n2)cc1 ; c1ccc(-c2cccc(-c3ccc(-c4nc(-c5ccc6ccccc6c5)nc(-c5cccc6oc7ccccc7c56)n4)cc3)c2)cc1 ; c1ccc(-c2ccc3oc4c(-c5nc(-c6ccccc6)nc(-c6ccc7ccc8c9ccccc9ccc8c7c6)n5)cccc4c3c2)cc1]

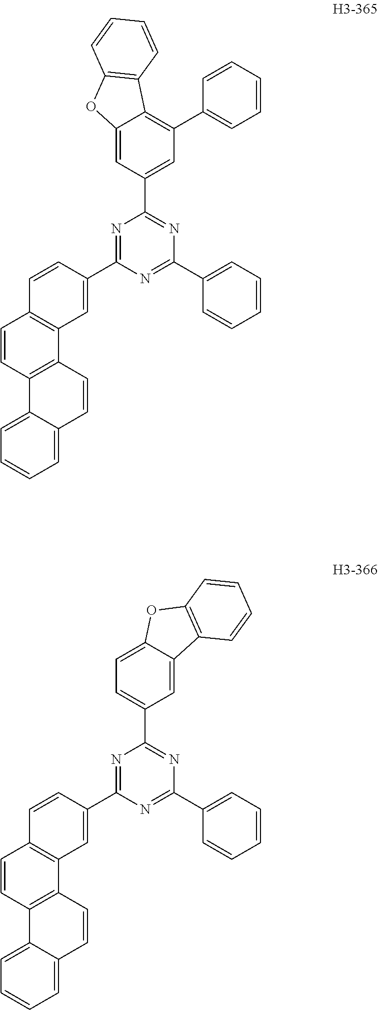 [SMILES: c1ccc(-c2nc(-c3cc(-c4ccccc4)c4c(c3)oc3ccccc34)nc(-c3ccc4ccc5c6ccccc6ccc5c4c3)n2)cc1 ; c1ccc(-c2nc(-c3ccc4ccc5c6ccccc6ccc5c4c3)nc(-c3ccc4oc5ccccc5c4c3)n2)cc1]

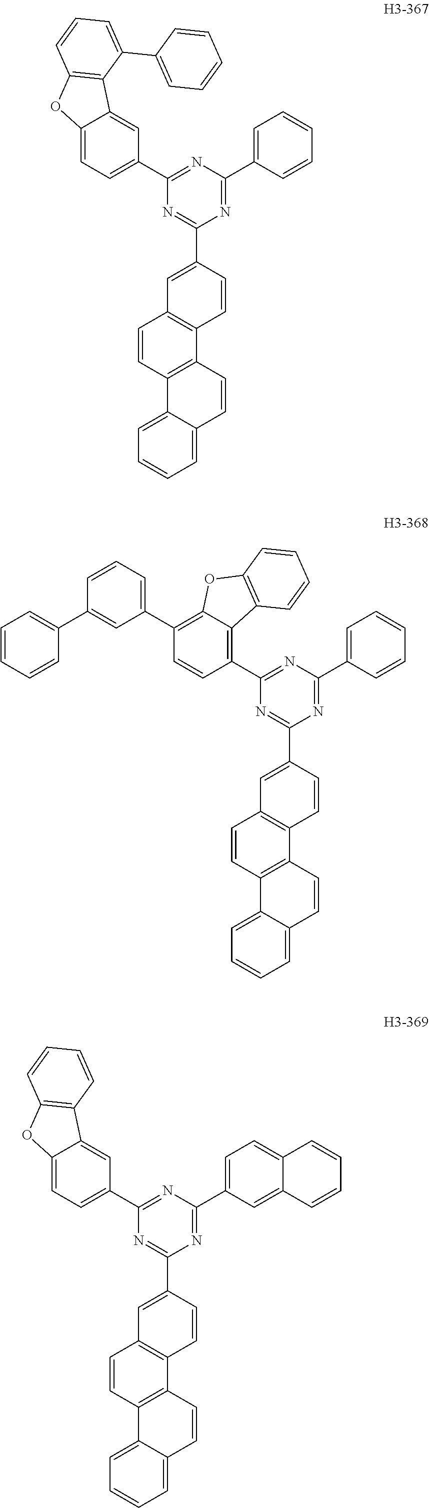 [SMILES: c1ccc(-c2nc(-c3ccc4c(ccc5c6ccccc6ccc45)c3)nc(-c3ccc4oc5cccc(-c6ccccc6)c5c4c3)n2)cc1 ; c1ccc(-c2cccc(-c3ccc(-c4nc(-c5ccccc5)nc(-c5ccc6c(ccc7c8ccccc8ccc67)c5)n4)c4c3oc3ccccc34)c2)cc1 ; c1ccc2cc(-c3nc(-c4ccc5c(ccc6c7ccccc7ccc56)c4)nc(-c4ccc5oc6ccccc6c5c4)n3)ccc2c1]

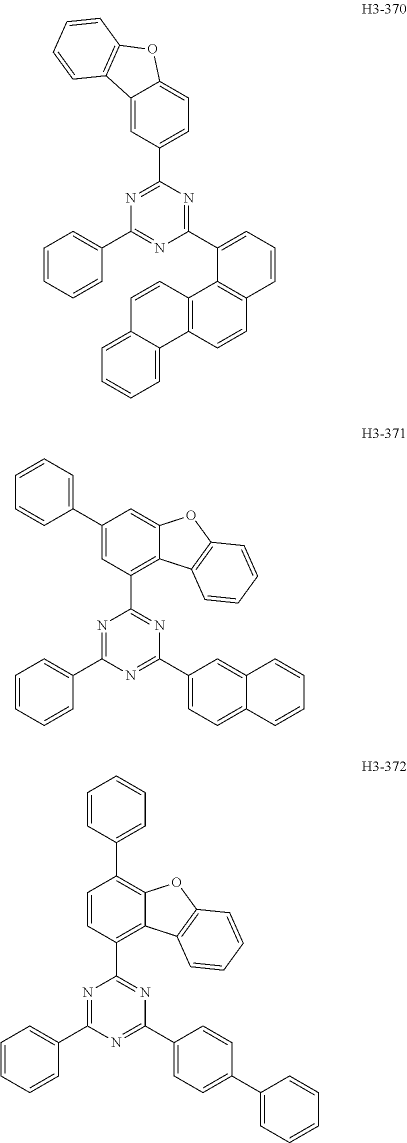 [SMILES: c1ccc(-c2nc(-c3ccc4oc5ccccc5c4c3)nc(-c3cccc4ccc5c6ccccc6ccc5c34)n2)cc1 ; c1ccc(-c2cc(-c3nc(-c4ccccc4)nc(-c4ccc5ccccc5c4)n3)c3c(c2)oc2ccccc23)cc1 ; c1ccc(-c2ccc(-c3nc(-c4ccccc4)nc(-c4ccc(-c5ccccc5)c5oc6ccccc6c45)n3)cc2)cc1]

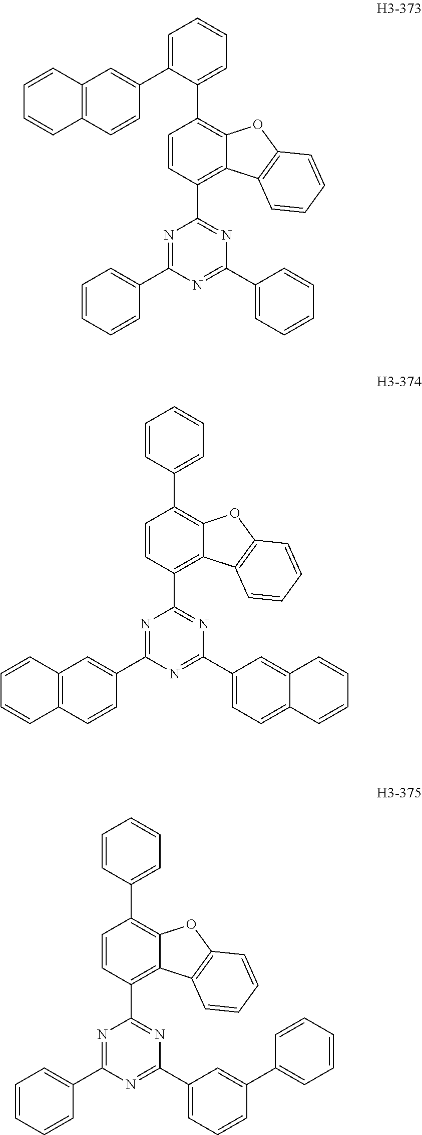 [SMILES: c1ccc(-c2nc(-c3ccccc3)nc(-c3ccc(-c4ccccc4-c4ccc5ccccc5c4)c4oc5ccccc5c34)n2)cc1 ; c1ccc(-c2ccc(-c3nc(-c4ccc5ccccc5c4)nc(-c4ccc5ccccc5c4)n3)c3c2oc2ccccc23)cc1 ; c1ccc(-c2cccc(-c3nc(-c4ccccc4)nc(-c4ccc(-c5ccccc5)c5oc6ccccc6c45)n3)c2)cc1]

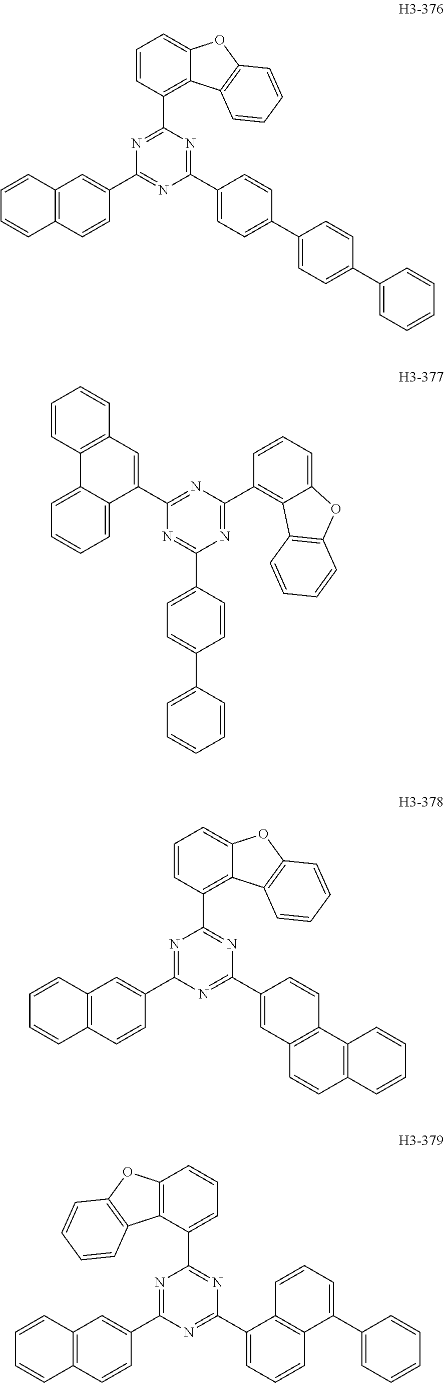 [SMILES: c1ccc(-c2ccc(-c3ccc(-c4nc(-c5ccc6ccccc6c5)nc(-c5cccc6oc7ccccc7c56)n4)cc3)cc2)cc1 ; c1ccc(-c2ccc(-c3nc(-c4cc5ccccc5c5ccccc45)nc(-c4cccc5oc6ccccc6c45)n3)cc2)cc1 ; c1ccc2cc(-c3nc(-c4ccc5c(ccc6ccccc65)c4)nc(-c4cccc5oc6ccccc6c45)n3)ccc2c1 ; c1ccc(-c2cccc3c(-c4nc(-c5ccc6ccccc6c5)nc(-c5cccc6oc7ccccc7c56)n4)cccc23)cc1]

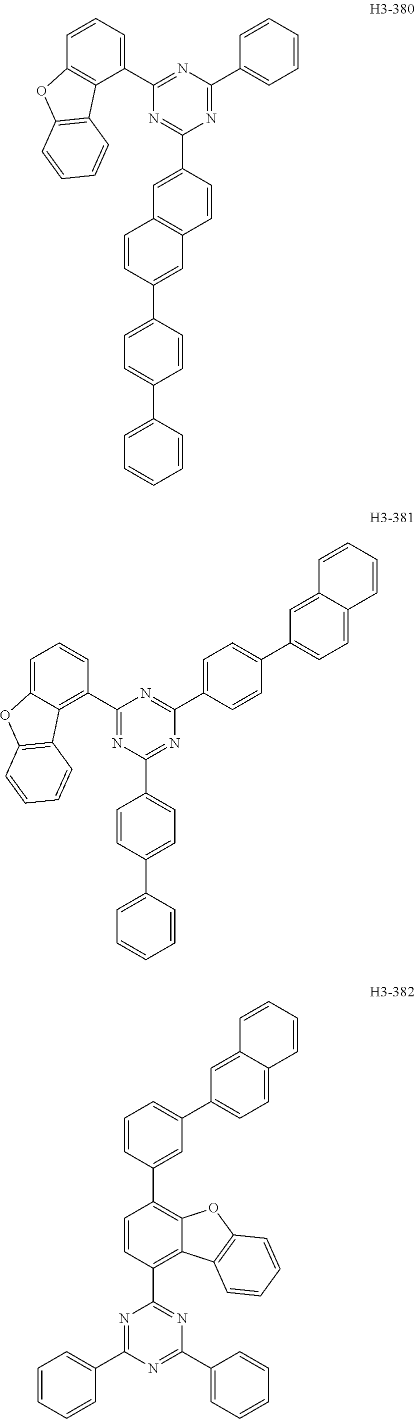 [SMILES: c1ccc(-c2ccc(-c3ccc4cc(-c5nc(-c6ccccc6)nc(-c6cccc7oc8ccccc8c67)n5)ccc4c3)cc2)cc1 ; c1ccc(-c2ccc(-c3nc(-c4ccc(-c5ccc6ccccc6c5)cc4)nc(-c4cccc5oc6ccccc6c45)n3)cc2)cc1 ; c1ccc(-c2nc(-c3ccccc3)nc(-c3ccc(-c4cccc(-c5ccc6ccccc6c5)c4)c4oc5ccccc5c34)n2)cc1]

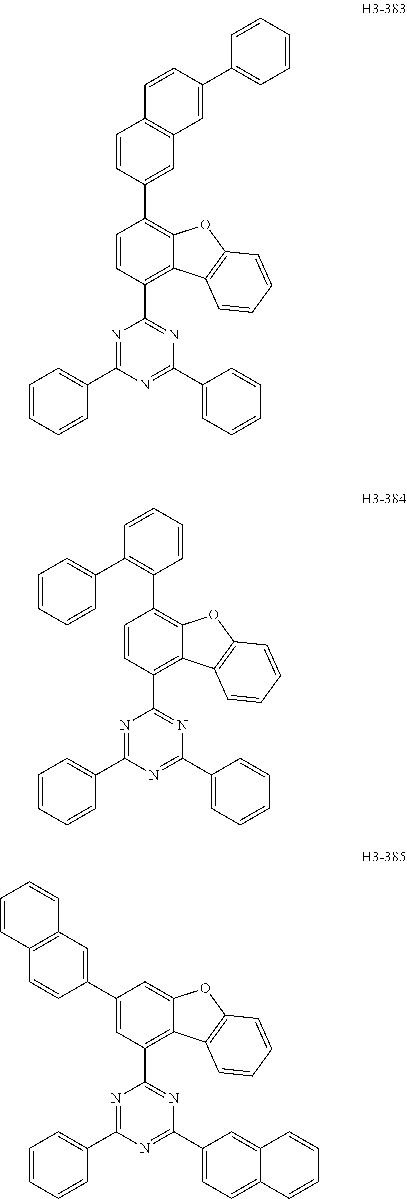 [SMILES: c1ccc(-c2ccc3ccc(-c4ccc(-c5nc(-c6ccccc6)nc(-c6ccccc6)n5)c5c4oc4ccccc45)cc3c2)cc1 ; c1ccc(-c2nc(-c3ccccc3)nc(-c3ccc(-c4ccccc4-c4ccccc4)c4oc5ccccc5c34)n2)cc1 ; c1ccc(-c2nc(-c3ccc4ccccc4c3)nc(-c3cc(-c4ccc5ccccc5c4)cc4oc5ccccc5c34)n2)cc1]

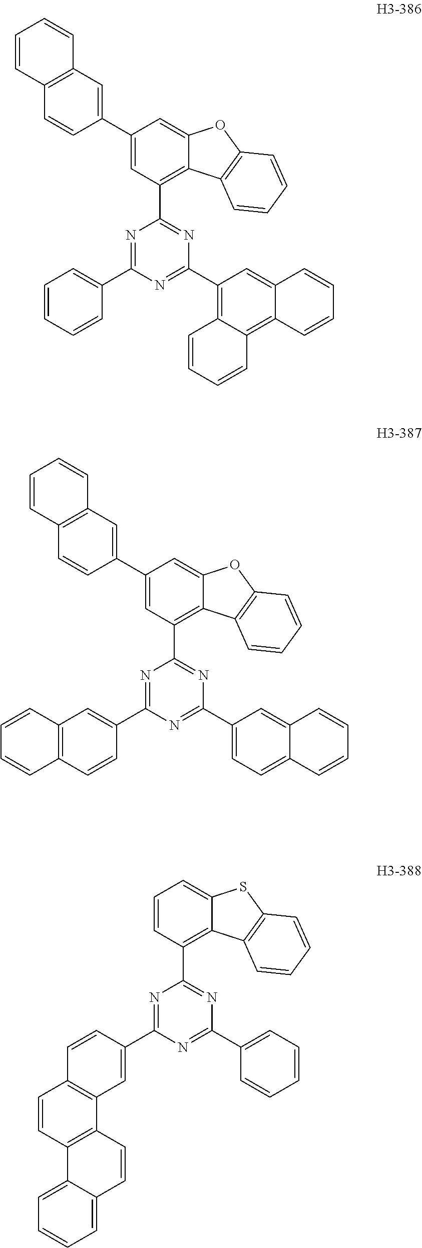 [SMILES: c1ccc(-c2nc(-c3cc4ccccc4c4ccccc34)nc(-c3cc(-c4ccc5ccccc5c4)cc4oc5ccccc5c34)n2)cc1 ; c1ccc2cc(-c3cc(-c4nc(-c5ccc6ccccc6c5)nc(-c5ccc6ccccc6c5)n4)c4c(c3)oc3ccccc34)ccc2c1 ; c1ccc(-c2nc(-c3ccc4ccc5c6ccccc6ccc5c4c3)nc(-c3cccc4sc5ccccc5c34)n2)cc1]

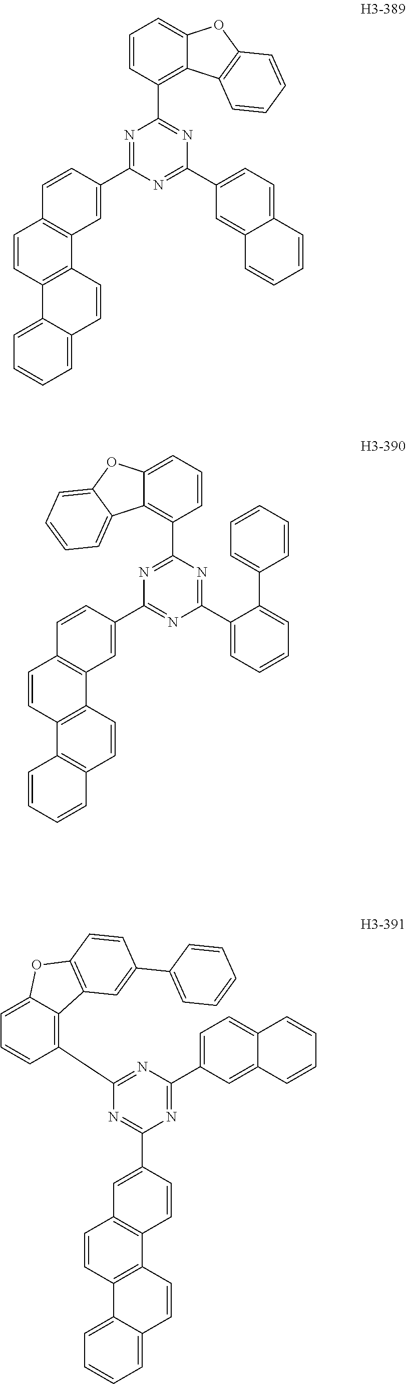 [SMILES: c1ccc2cc(-c3nc(-c4ccc5ccc6c7ccccc7ccc6c5c4)nc(-c4cccc5oc6ccccc6c45)n3)ccc2c1 ; c1ccc(-c2ccccc2-c2nc(-c3ccc4ccc5c6ccccc6ccc5c4c3)nc(-c3cccc4oc5ccccc5c34)n2)cc1 ; c1ccc(-c2ccc3oc4cccc(-c5nc(-c6ccc7ccccc7c6)nc(-c6ccc7c(ccc8c9ccccc9ccc78)c6)n5)c4c3c2)cc1]

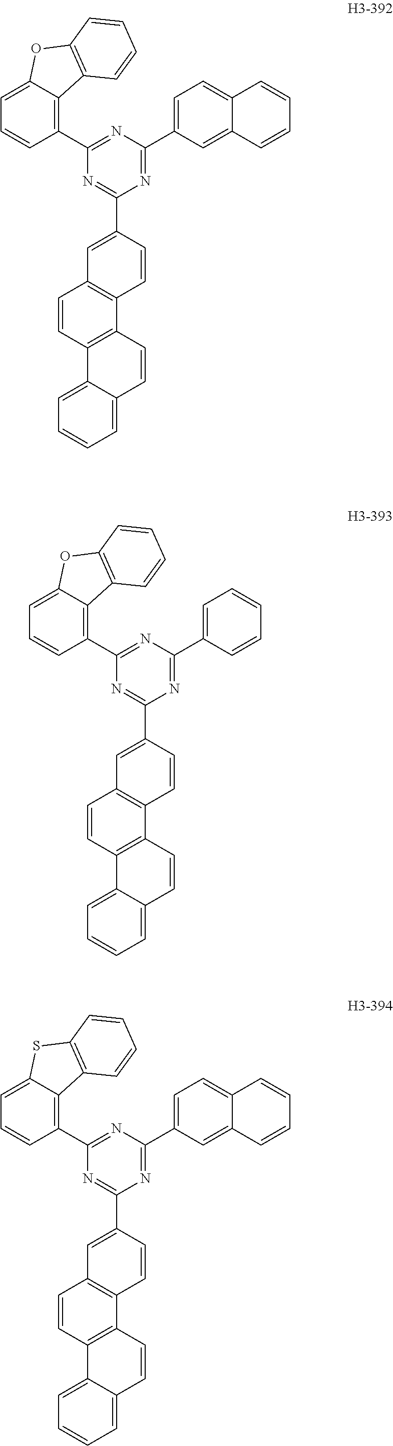 [SMILES: c1ccc2cc(-c3nc(-c4ccc5c(ccc6c7ccccc7ccc56)c4)nc(-c4cccc5oc6ccccc6c45)n3)ccc2c1 ; c1ccc(-c2nc(-c3ccc4c(ccc5c6ccccc6ccc45)c3)nc(-c3cccc4oc5ccccc5c34)n2)cc1 ; c1ccc2cc(-c3nc(-c4ccc5c(ccc6c7ccccc7ccc56)c4)nc(-c4cccc5sc6ccccc6c45)n3)ccc2c1]

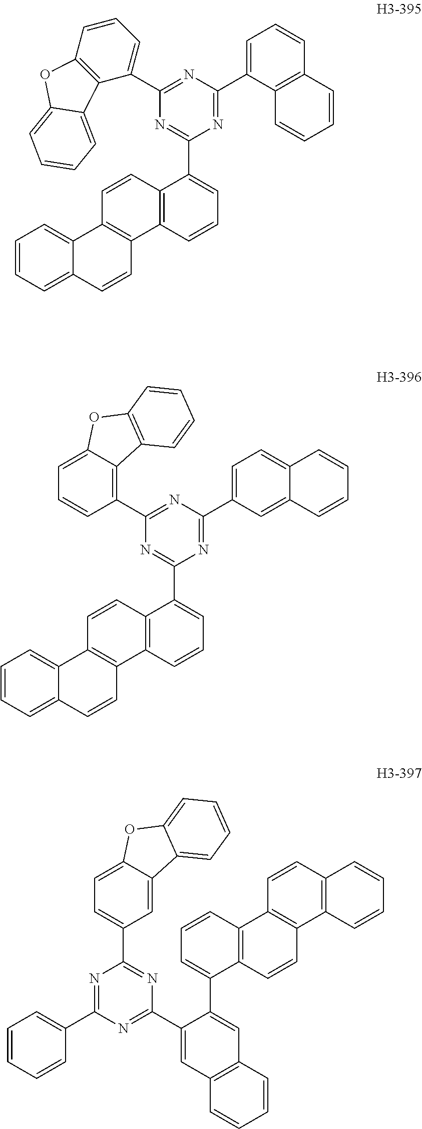 [SMILES: c1ccc2c(-c3nc(-c4cccc5c4ccc4c6ccccc6ccc54)nc(-c4cccc5oc6ccccc6c45)n3)cccc2c1 ; c1ccc2cc(-c3nc(-c4cccc5c4ccc4c6ccccc6ccc54)nc(-c4cccc5oc6ccccc6c45)n3)ccc2c1 ; c1ccc(-c2nc(-c3ccc4oc5ccccc5c4c3)nc(-c3cc4ccccc4cc3-c3cccc4c3ccc3c5ccccc5ccc43)n2)cc1]

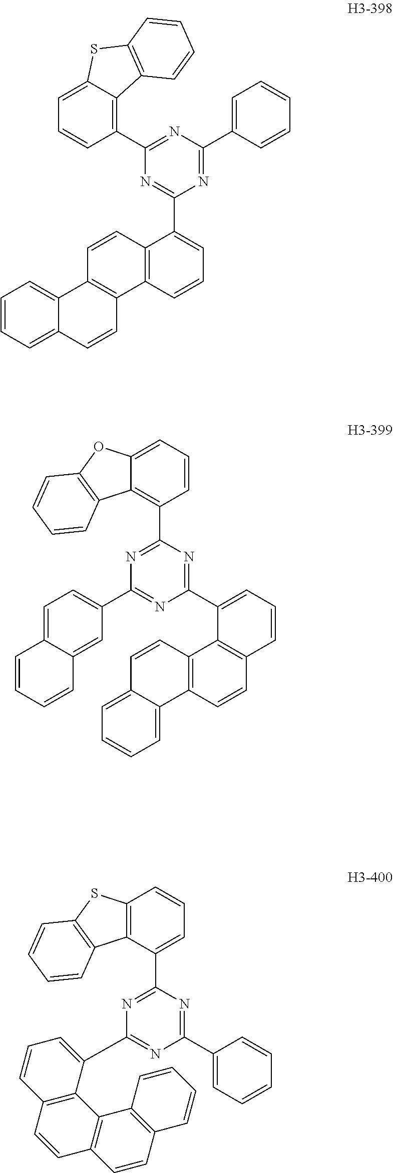 [SMILES: c1ccc(-c2nc(-c3cccc4c3ccc3c5ccccc5ccc43)nc(-c3cccc4sc5ccccc5c34)n2)cc1 ; c1ccc2cc(-c3nc(-c4cccc5ccc6c7ccccc7ccc6c45)nc(-c4cccc5oc6ccccc6c45)n3)ccc2c1 ; c1ccc(-c2nc(-c3cccc4sc5ccccc5c34)nc(-c3cccc4ccc5ccc6ccccc6c5c34)n2)cc1]

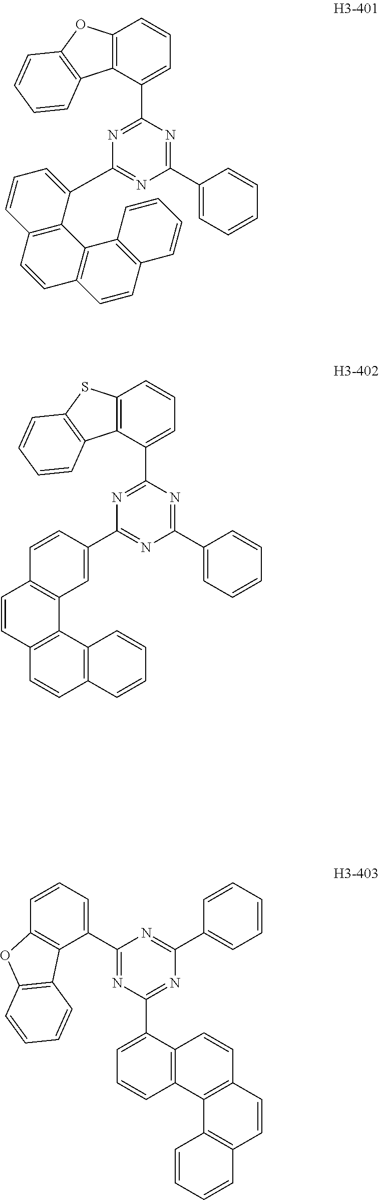 [SMILES: c1ccc(-c2nc(-c3cccc4oc5ccccc5c34)nc(-c3cccc4ccc5ccc6ccccc6c5c34)n2)cc1 ; c1ccc(-c2nc(-c3ccc4ccc5ccc6ccccc6c5c4c3)nc(-c3cccc4sc5ccccc5c34)n2)cc1 ; c1ccc(-c2nc(-c3cccc4c3ccc3ccc5ccccc5c34)nc(-c3cccc4oc5ccccc5c34)n2)cc1]

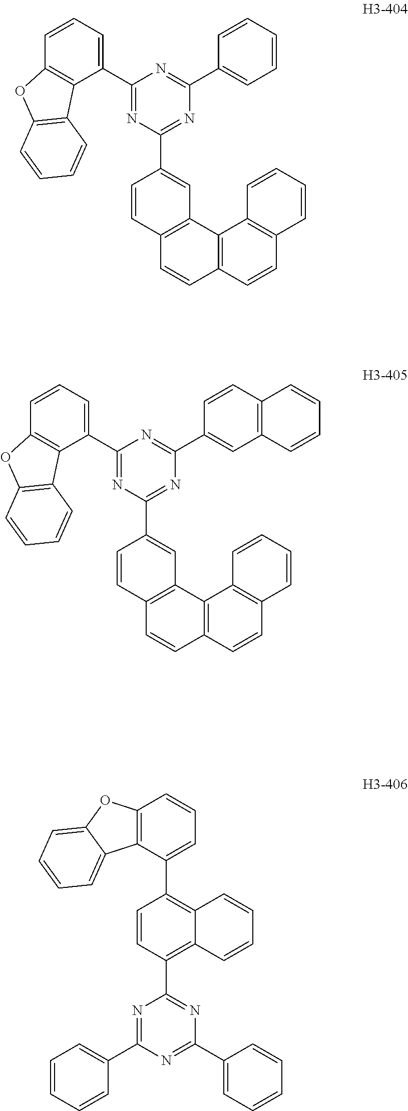 [SMILES: c1ccc(-c2nc(-c3ccc4ccc5ccc6ccccc6c5c4c3)nc(-c3cccc4oc5ccccc5c34)n2)cc1 ; c1ccc2cc(-c3nc(-c4ccc5ccc6ccc7ccccc7c6c5c4)nc(-c4cccc5oc6ccccc6c45)n3)ccc2c1 ; c1ccc(-c2nc(-c3ccccc3)nc(-c3ccc(-c4cccc5oc6ccccc6c45)c4ccccc34)n2)cc1]

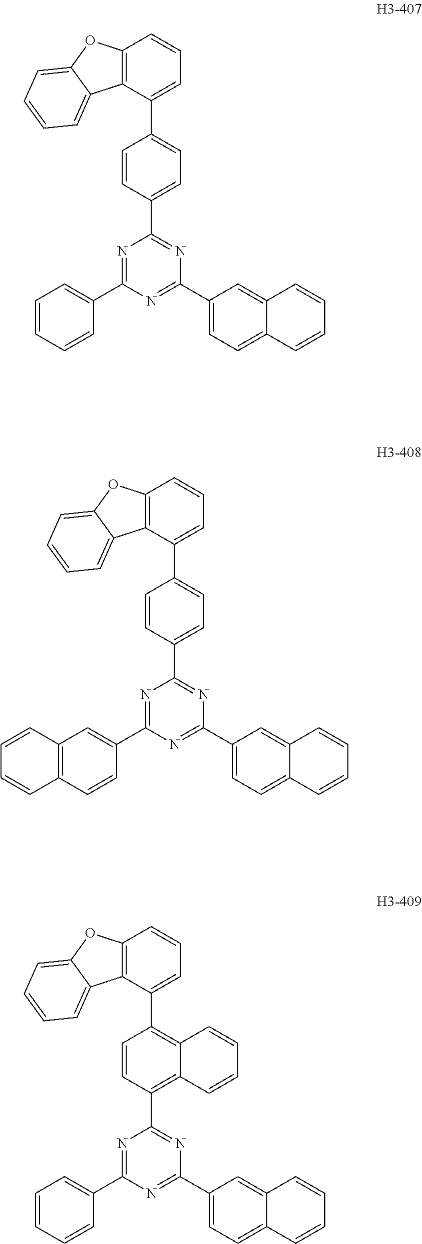 [SMILES: c1ccc(-c2nc(-c3ccc(-c4cccc5oc6ccccc6c45)cc3)nc(-c3ccc4ccccc4c3)n2)cc1 ; c1ccc2cc(-c3nc(-c4ccc(-c5cccc6oc7ccccc7c56)cc4)nc(-c4ccc5ccccc5c4)n3)ccc2c1 ; c1ccc(-c2nc(-c3ccc4ccccc4c3)nc(-c3ccc(-c4cccc5oc6ccccc6c45)c4ccccc34)n2)cc1]

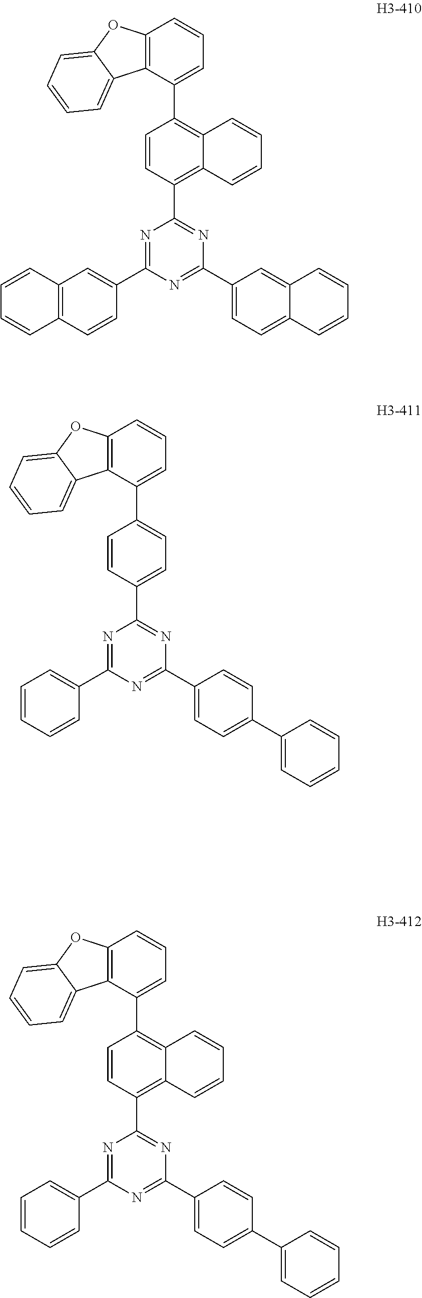 [SMILES: c1ccc2cc(-c3nc(-c4ccc5ccccc5c4)nc(-c4ccc(-c5cccc6oc7ccccc7c56)c5ccccc45)n3)ccc2c1 ; c1ccc(-c2ccc(-c3nc(-c4ccccc4)nc(-c4ccc(-c5cccc6oc7ccccc7c56)cc4)n3)cc2)cc1 ; c1ccc(-c2ccc(-c3nc(-c4ccccc4)nc(-c4ccc(-c5cccc6oc7ccccc7c56)c5ccccc45)n3)cc2)cc1]

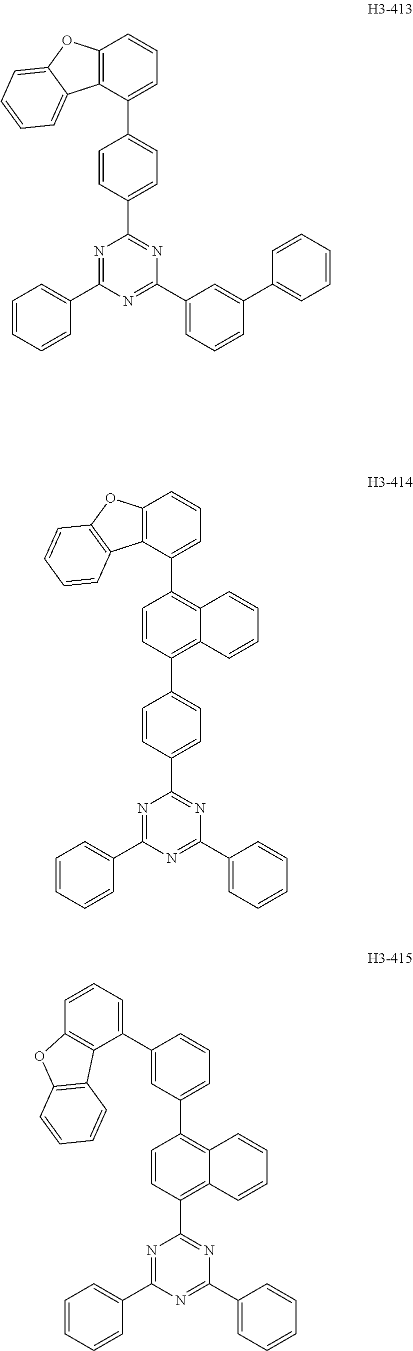 [SMILES: c1ccc(-c2cccc(-c3nc(-c4ccccc4)nc(-c4ccc(-c5cccc6oc7ccccc7c56)cc4)n3)c2)cc1 ; c1ccc(-c2nc(-c3ccccc3)nc(-c3ccc(-c4ccc(-c5cccc6oc7ccccc7c56)c5ccccc45)cc3)n2)cc1 ; c1ccc(-c2nc(-c3ccccc3)nc(-c3ccc(-c4cccc(-c5cccc6oc7ccccc7c56)c4)c4ccccc34)n2)cc1]

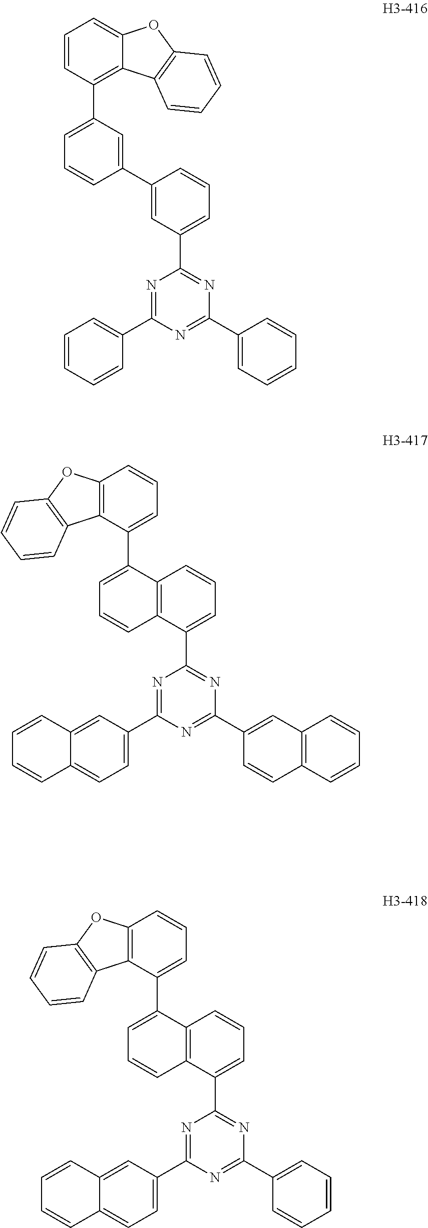 [SMILES: c1ccc(-c2nc(-c3ccccc3)nc(-c3cccc(-c4cccc(-c5cccc6oc7ccccc7c56)c4)c3)n2)cc1 ; c1ccc2cc(-c3nc(-c4ccc5ccccc5c4)nc(-c4cccc5c(-c6cccc7oc8ccccc8c67)cccc45)n3)ccc2c1 ; c1ccc(-c2nc(-c3ccc4ccccc4c3)nc(-c3cccc4c(-c5cccc6oc7ccccc7c56)cccc34)n2)cc1]

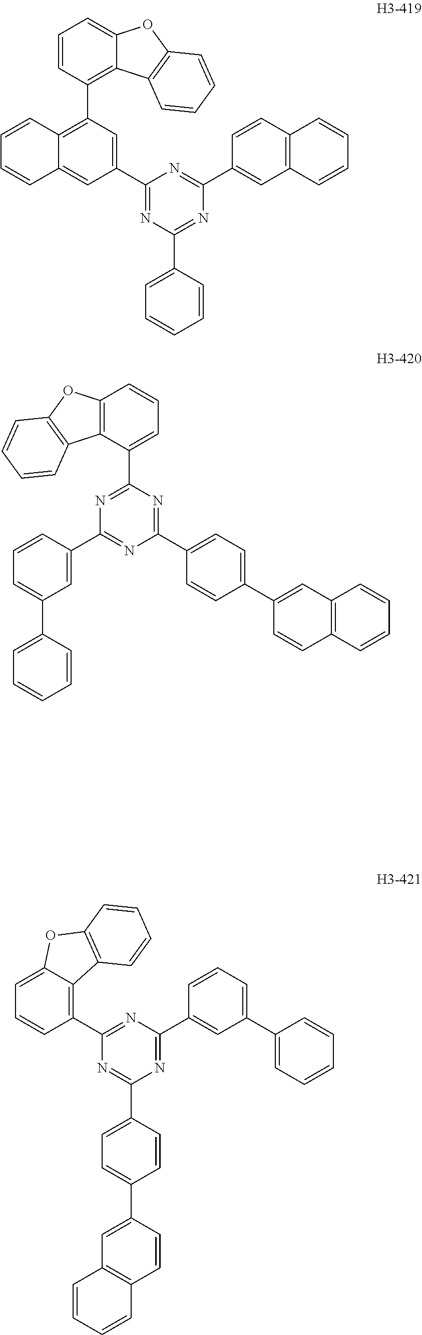 [SMILES: c1ccc(-c2nc(-c3ccc4ccccc4c3)nc(-c3cc(-c4cccc5oc6ccccc6c45)c4ccccc4c3)n2)cc1 ; c1ccc(-c2cccc(-c3nc(-c4ccc(-c5ccc6ccccc6c5)cc4)nc(-c4cccc5oc6ccccc6c45)n3)c2)cc1 ; c1ccc(-c2cccc(-c3nc(-c4ccc(-c5ccc6ccccc6c5)cc4)nc(-c4cccc5oc6ccccc6c45)n3)c2)cc1]

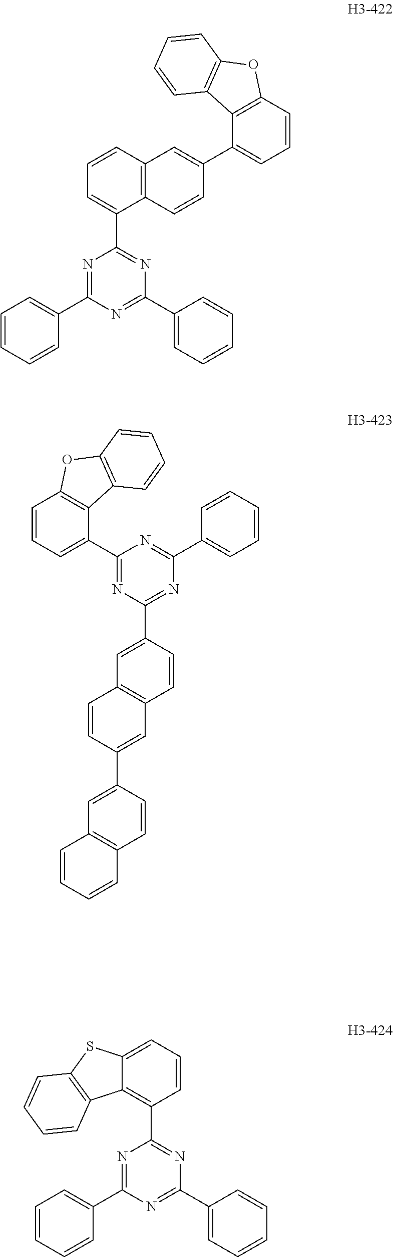 [SMILES: c1ccc(-c2nc(-c3ccccc3)nc(-c3cccc4cc(-c5cccc6oc7ccccc7c56)ccc34)n2)cc1 ; c1ccc(-c2nc(-c3ccc4cc(-c5ccc6ccccc6c5)ccc4c3)nc(-c3cccc4oc5ccccc5c34)n2)cc1 ; c1ccc(-c2nc(-c3ccccc3)nc(-c3cccc4sc5ccccc5c34)n2)cc1]

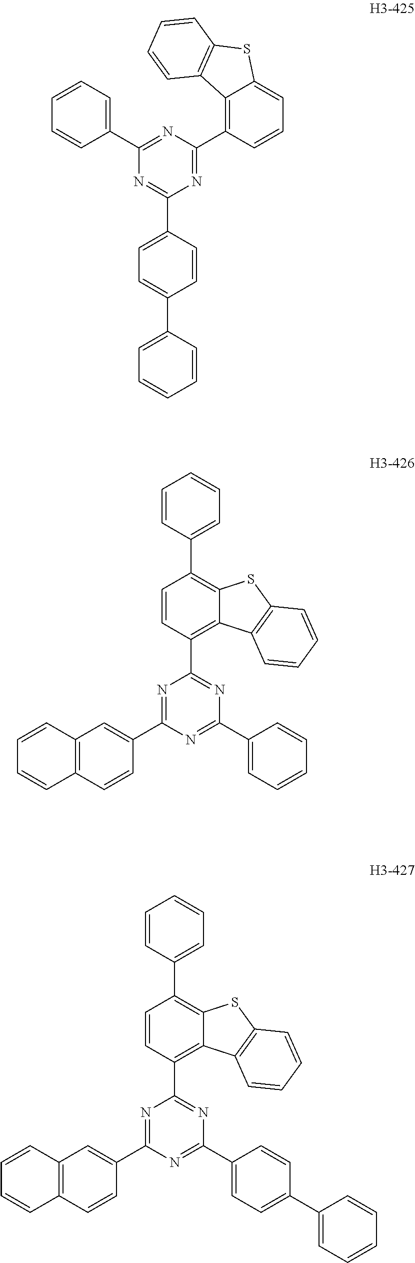 [SMILES: c1ccc(-c2ccc(-c3nc(-c4ccccc4)nc(-c4cccc5sc6ccccc6c45)n3)cc2)cc1 ; c1ccc(-c2nc(-c3ccc4ccccc4c3)nc(-c3ccc(-c4ccccc4)c4sc5ccccc5c34)n2)cc1 ; c1ccc(-c2ccc(-c3nc(-c4ccc5ccccc5c4)nc(-c4ccc(-c5ccccc5)c5sc6ccccc6c45)n3)cc2)cc1]

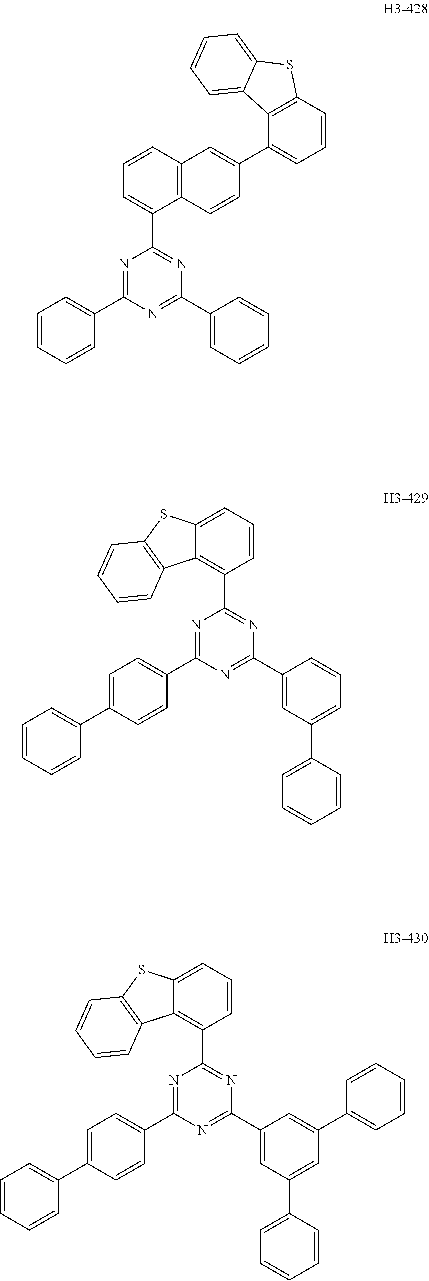 [SMILES: c1ccc(-c2nc(-c3ccccc3)nc(-c3cccc4cc(-c5cccc6sc7ccccc7c56)ccc34)n2)cc1 ; c1ccc(-c2ccc(-c3nc(-c4cccc(-c5ccccc5)c4)nc(-c4cccc5sc6ccccc6c45)n3)cc2)cc1 ; c1ccc(-c2ccc(-c3nc(-c4cc(-c5ccccc5)cc(-c5ccccc5)c4)nc(-c4cccc5sc6ccccc6c45)n3)cc2)cc1]

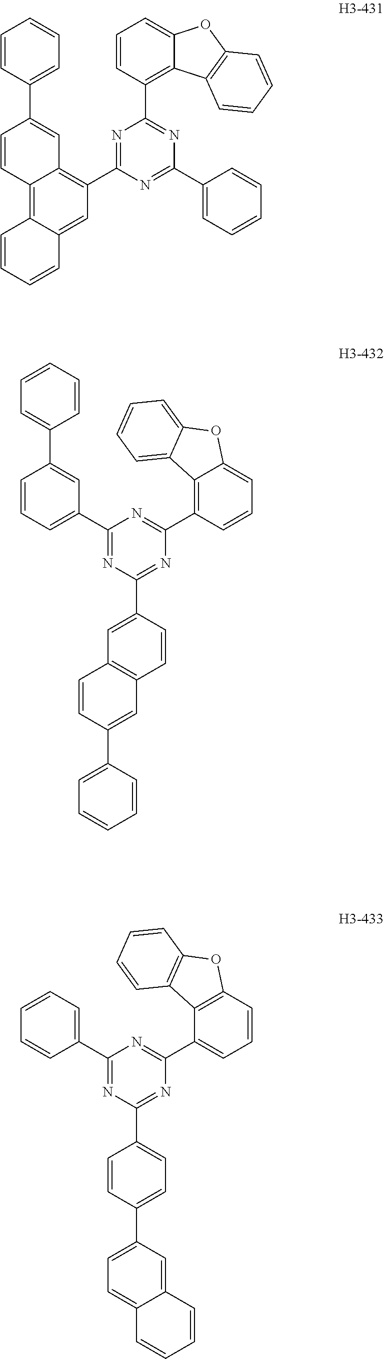 [SMILES: c1ccc(-c2ccc3c(c2)c(-c2nc(-c4ccccc4)nc(-c4cccc5oc6ccccc6c45)n2)cc2ccccc23)cc1 ; c1ccc(-c2cccc(-c3nc(-c4ccc5cc(-c6ccccc6)ccc5c4)nc(-c4cccc5oc6ccccc6c45)n3)c2)cc1 ; c1ccc(-c2nc(-c3ccc(-c4ccc5ccccc5c4)cc3)nc(-c3cccc4oc5ccccc5c34)n2)cc1]

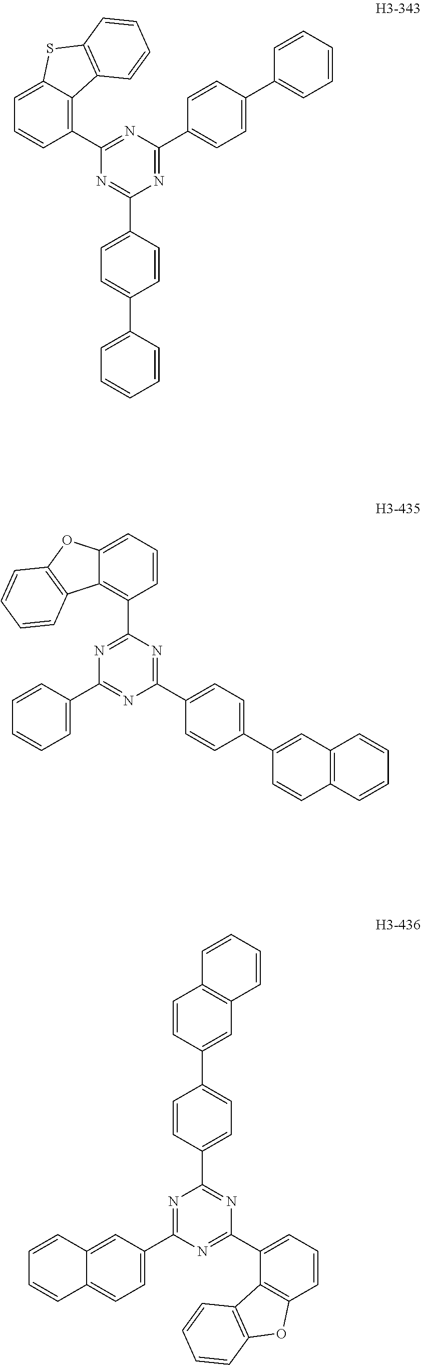 [SMILES: c1ccc(-c2ccc(-c3nc(-c4ccc(-c5ccccc5)cc4)nc(-c4cccc5sc6ccccc6c45)n3)cc2)cc1 ; c1ccc(-c2nc(-c3ccc(-c4ccc5ccccc5c4)cc3)nc(-c3cccc4oc5ccccc5c34)n2)cc1 ; c1ccc2cc(-c3ccc(-c4nc(-c5ccc6ccccc6c5)nc(-c5cccc6oc7ccccc7c56)n4)cc3)ccc2c1]

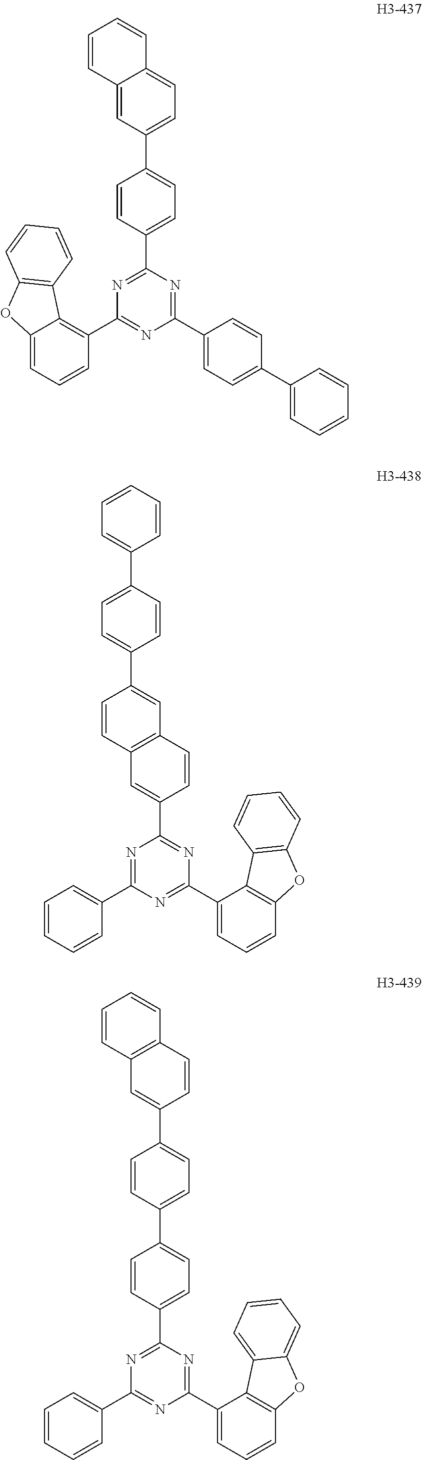 [SMILES: c1ccc(-c2ccc(-c3nc(-c4ccc(-c5ccc6ccccc6c5)cc4)nc(-c4cccc5oc6ccccc6c45)n3)cc2)cc1 ; c1ccc(-c2ccc(-c3ccc4cc(-c5nc(-c6ccccc6)nc(-c6cccc7oc8ccccc8c67)n5)ccc4c3)cc2)cc1 ; c1ccc(-c2nc(-c3ccc(-c4ccc(-c5ccc6ccccc6c5)cc4)cc3)nc(-c3cccc4oc5ccccc5c34)n2)cc1]

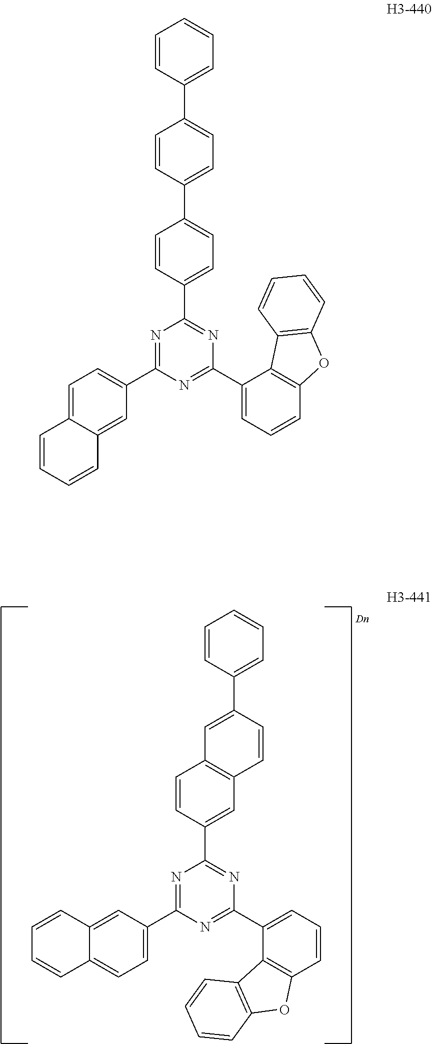

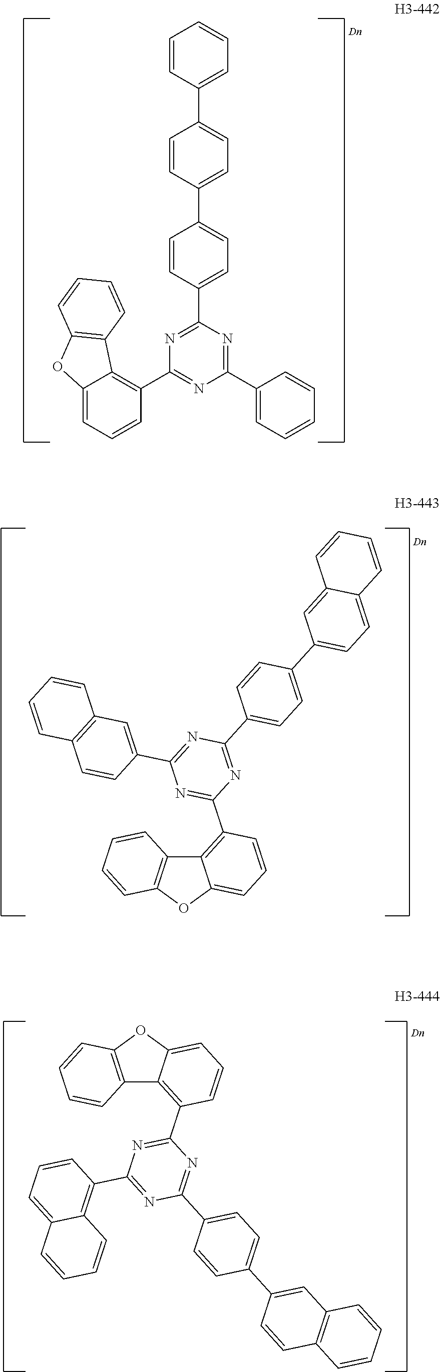

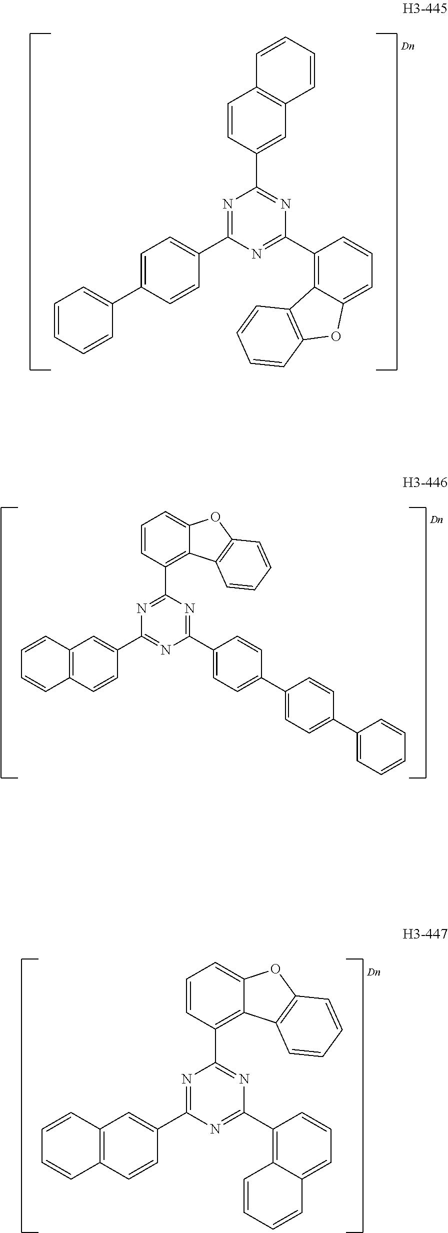

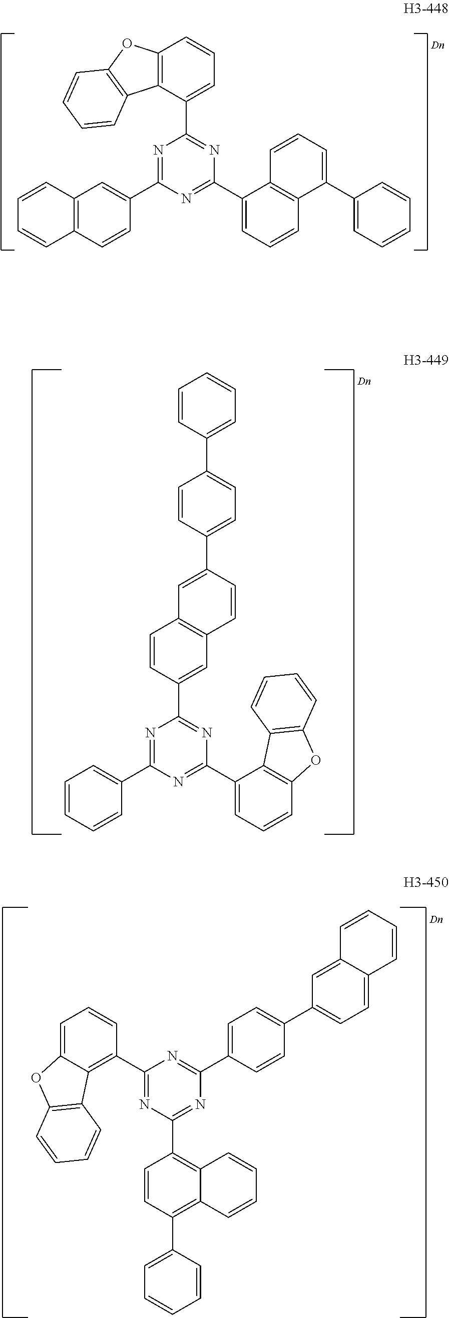

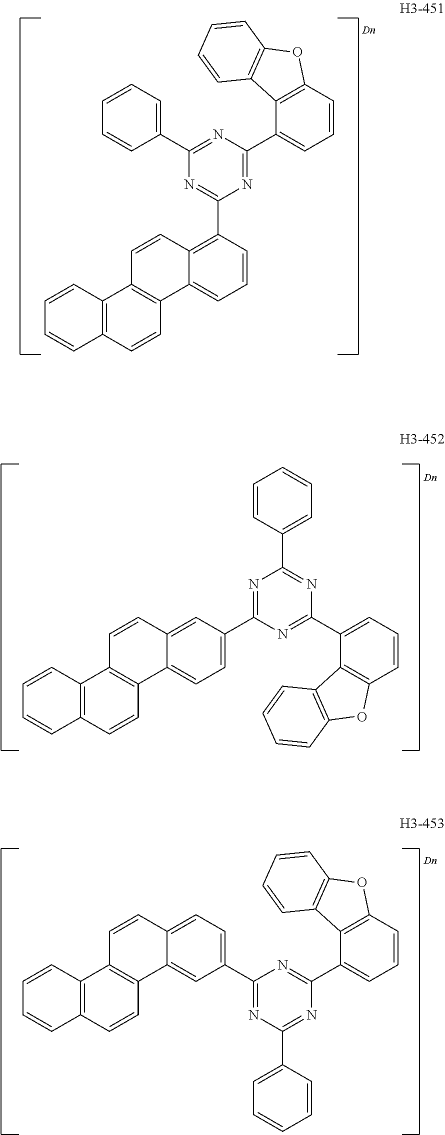

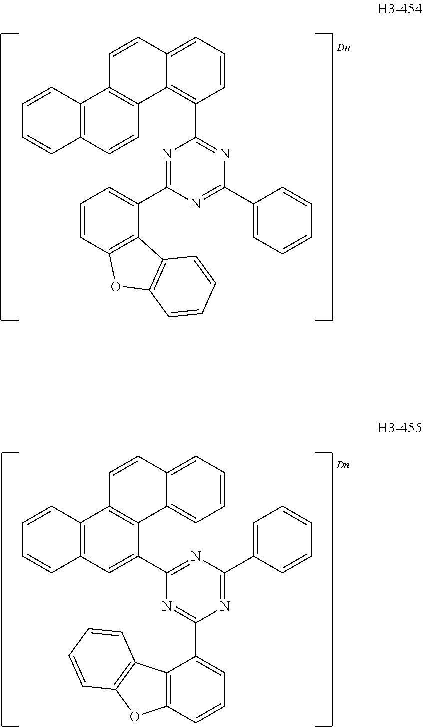

In the compounds above, Dₙ means that n number of hydrogens are replaced with deuterium, and n represents an integer from 1 to the maximum number of hydrogens in the compound.

According to one embodiment of the present disclosure, the plurality of host materials of the present disclosure may comprise a phosphorescent host material.

According to one embodiment of the present disclosure, the present disclosure provides an organic electroluminescent device comprising a first electrode; a second electrode; and at least one light-emitting layer between the first and second electrodes, wherein the at least one light-emitting layer may comprise the plurality of host materials of claim 1.

According to one embodiment of the present disclosure, the present disclosure provides an organic electroluminescent device in which the light-emitting layer emits red light.

According to another embodiment of the present disclosure, the present disclosure provides an organic electroluminescent compound represented by Formula 1, and an organic electroluminescent device comprising the same.

In Formula 1′, ring A is not present, or represents a substituted or unsubstituted benzene, or a substituted or unsubstituted naphthalene.

In Formula 1′, Ar₁ and R₁ to R₄ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s); with a proviso that it is excluded that Ar₁ and R₁, and R₂ and R₃ are linked to form a ring(s);
with a proviso that if ring A represents a substituted or unsubstituted benzene, R₂ represents a phenyl unsubstituted or substituted with deuterium, or Ar₁ represents a substituted or unsubstituted (C₆-C₃₀)aryl, a substituted or unsubstituted (3- to 30-membered)heteroaryl, a substituted or unsubstituted mono- or di(C₆-C₃₀)arylamino, or a substituted or unsubstituted (C₆-C₃₀)aryl(3- to 30-membered)heteroarylamino.

According to one embodiment of the present disclosure, Formula 1′ may be represented by any one of the following Formulas 1′-1 to 1′-3.

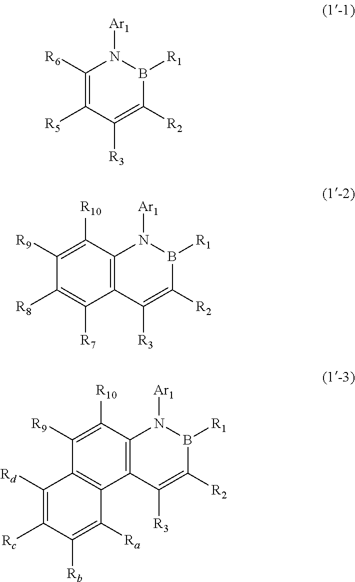

In Formulas 1′-1 to 1′-3, Ar₁, R₁ to R₃, R₅ to R₁₀, and Rₐ to R_{d} each independently represent hydrogen, deuterium, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino, with a proviso that at least one of Ar₁, R₁, R₂, R₃, R₅, and R₆ in Formula 1′-1, at least one of Ar₁, R₁ to R₃, and R₇ to R₁₀ in Formula 1′-2, and at least one of Ar₁, R₁ to R₃, R₉, R₁₀, and Rₐ to R_{d} in Formula 1′-3 are each represented by one of Formulas 1′-a to 1′-d. According to one embodiment of the present disclosure, Ar₁, R₁ to R₃, R₅ to R₁₀, and Rₐ to R_{d} each independently are represented by any one of the following Formulas 1′-a to 1′-d, or represent hydrogen, deuterium, a substituted or unsubstituted (C₆-C₂₀)aryl, a substituted or unsubstituted (3- to 20-membered)heteroaryl, a substituted or unsubstituted mono- or di(C₆-C₂₀)arylamino, a substituted or unsubstituted mono- or di(3- to 20-membered)heteroarylamino, or a substituted or unsubstituted (C₆-C₂₀)aryl(3- to 20-membered)heteroarylamino. For example, Ar₁, R₁ to R₃, R₅ to R₁₀, and Rₐ to R_{d} each independently may be represented by any one of the following Formulas 1′-a to 1′-d, or represent, or represent hydrogen; a phenyl unsubstituted or substituted with a naphthyl or a dibenzofuranyl; a naphthyl; an indolocarbazolyl substituted with a phenyl; a triazinyl substituted with a phenyl, a naphthyl, a dibenzofuranyl, a carbazolyl, or a 23-membered heteroaryl containing nitrogen; a pyrimidinyl substituted with a phenyl; a quinazolinyl substituted with a phenyl; a quinoxalinyl substituted with a phenyl; a phenylbiphenylamino; a phenyldibenzofuranylamino; a phenanthrooxazolyl phenylamino; or a benzophenanthrofuranyl phenylamino, etc.

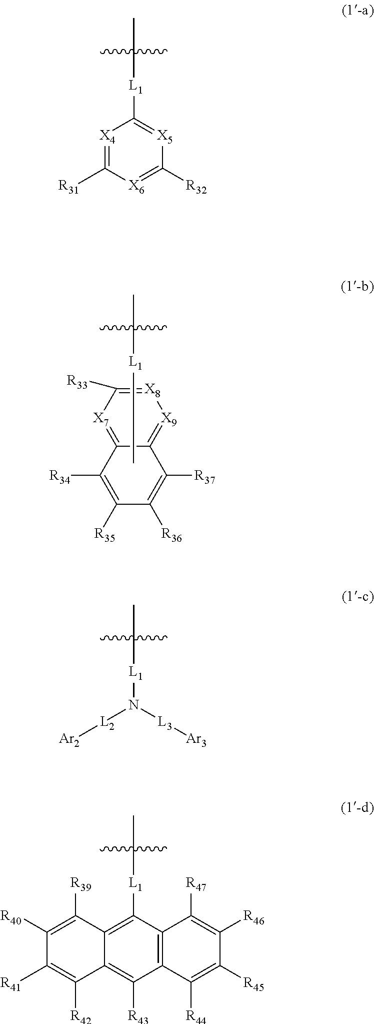

In Formulas 1′-a to 1′-d,

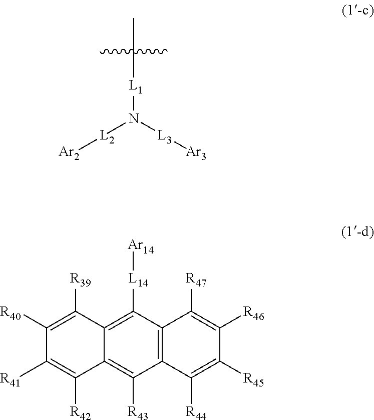

each independently represents a site linked to Formulas 1′-1 to 1′-3.

In Formulas 1′-a to 1′-d, L₁ to L₃ each independently represent a single bond, a substituted or unsubstituted (C₆-C₃₀)arylene, or a substituted or unsubstituted (3- to 30-membered)heteroarylene. According to one embodiment of the present disclosure, L₁ to L₃ each independently represent a single bond, or a substituted or unsubstituted (C₆-C₃₀)arylene. For example, L₁ to L₃ each independently may be a single bond, a phenylene, or a biphenylene unsubstituted or substituted with a cyano, etc.

In Formulas 1′-a to 1′-d, X₄ to X₉ each independently represent N or CR₃₈, with a proviso that at least one of X₄ to X₆ and at least one of X₇ to X₉ represent N.

In Formulas 1′-a to 1′-d, R₃₁ to R₄₇ each independently represent hydrogen, deuterium, a halogen, a cyano, a substituted or unsubstituted (C₁-C₃₀)alkyl, a substituted or unsubstituted (C₆-C₃₀)aryl, or a substituted or unsubstituted (3- to 30-membered)heteroaryl. According to one embodiment of the present disclosure, R₃₁ to R₄₇ each independently represent hydrogen, deuterium, a substituted or unsubstituted (C₆-C₃₀)aryl, or a substituted or unsubstituted (3- to 30-membered)heteroaryl. According to another embodiment of the present disclosure, R₃₁ to R₄₇ each independently represent hydrogen, deuterium, a substituted or unsubstituted (C₆-C₃₀)aryl, or a substituted or unsubstituted (3- to 30-membered)heteroaryl. According to another embodiment of the present disclosure, R₃₁ to R₄₇ each independently represent hydrogen, deuterium, a substituted or unsubstituted (C₆-C₁₅)aryl, or a substituted or unsubstituted (3- to 23-membered)heteroaryl. For example, R₃₁ to R₄₇ each independently may be hydrogen; deuterium; a phenyl; a biphenyl; a naphthyl; a phenanthrenyl; a dibenzofuranyl unsubstituted or substituted with a phenyl; a dibenzothiophenyl; a carbazolyl; or a 23-membered heteroaryl containing nitrogen, etc.

With a proviso that in Formula 1′-b, any one of X₇ to X₉, and R₃₃ to R₃₈ is linked to L₁.

In Formulas 1′-a to 1′-d, Ar₂ and Ar₃ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino. According to one embodiment of the present disclosure, Ar₂ and Ar₃ each independently represent hydrogen, deuterium, a substituted or unsubstituted (C₆-C₃₀)aryl, a substituted or unsubstituted (3- to 30-membered)heteroaryl, or a substituted or unsubstituted mono- or di(C₆-C₃₀)arylamino. According to another embodiment of the present disclosure, Ar₂ and Ar₃ each independently represent hydrogen, deuterium, a substituted or unsubstituted (C₆-C₂₅)aryl, or a substituted or unsubstituted (3-to 25-membered)heteroaryl. For example, Ar₂ and Ar₃ each independently may be a phenyl; a biphenyl; a naphthyl; a dimethylfluorenyl; a dimethylbenzofluorenyl; a dibenzofuranyl; a phenanthrooxazolyl; or a benzophenanthrofuranyl, etc.

According to one embodiment of the present disclosure, the present disclosure provides an organic electroluminescent compound wherein Ar₁ in Formula 1′-2 is represented by any one of Formulas 1′-a to 1′-d.

According to one embodiment of the present disclosure, the present disclosure provides an organic electroluminescent compound wherein if any one of R₂, R₃, and R₇ to R₉ in Formula 1′-2 is represented by Formula 1′-a, at least one of R₃₁ and R₃₂ represents a substituted or unsubstituted (3- to 30-membered)heteroaryl.

According to one embodiment of the present disclosure, the present disclosure provides an organic electroluminescent compound wherein if any one of R₂, R₃, and R₇ to R₉ in Formula 1′-2 is represented by Formula 1′-c, at least one of Ar₂ and Ar₃ represents a substituted or unsubstituted (3- to 30-membered)heteroaryl containing O or S, or a substituted or unsubstituted (3- to 30-membered)heteroaryl containing N, O, or S and having four or more rings.

According to one embodiment of the present disclosure, the present disclosure provides an organic electroluminescent compound wherein any one of R₇ to R₁₀ in Formula 1′-2 is represented by Formula 1′-d.

According to one embodiment of the present disclosure, the present disclosure provides an organic electroluminescent compound wherein L₁ in Formulas 1′-a to 1′-d represents a (C₆-C₃₀)arylene substituted with at least one cyano, or a (3- to 30-membered)heteroarylene substituted with at least one cyano, and any one of R₇ to R₁₀ is represented by Formula 1′-d.

The compound represented by Formula 1′ may be selected from the following compounds, but is not limited thereto.

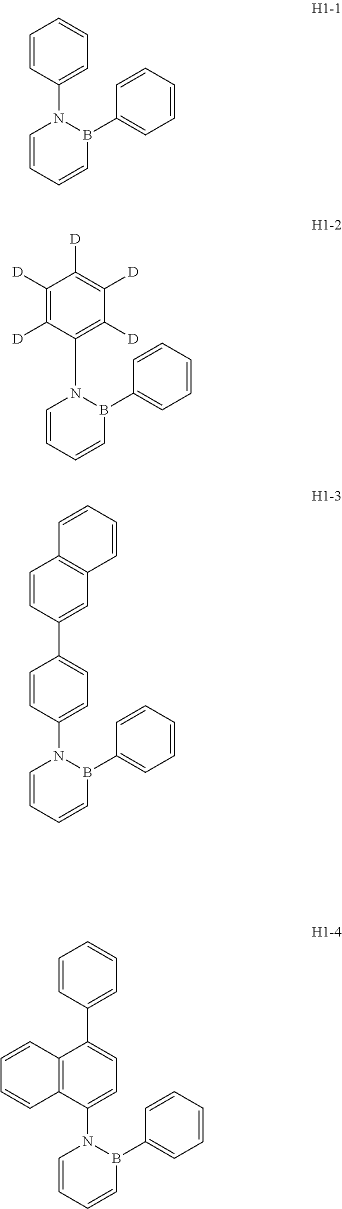 [SMILES: C1=CB(c2ccccc2)N(c2ccccc2)C=C1 ; [2H]c1c([2H])c([2H])c(N2C=CC=CB2c2ccccc2)c([2H])c1[2H] ; C1=CB(c2ccccc2)N(c2ccc(-c3ccc4ccccc4c3)cc2)C=C1 ; C1=CB(c2ccccc2)N(c2ccc(-c3ccccc3)c3ccccc23)C=C1]

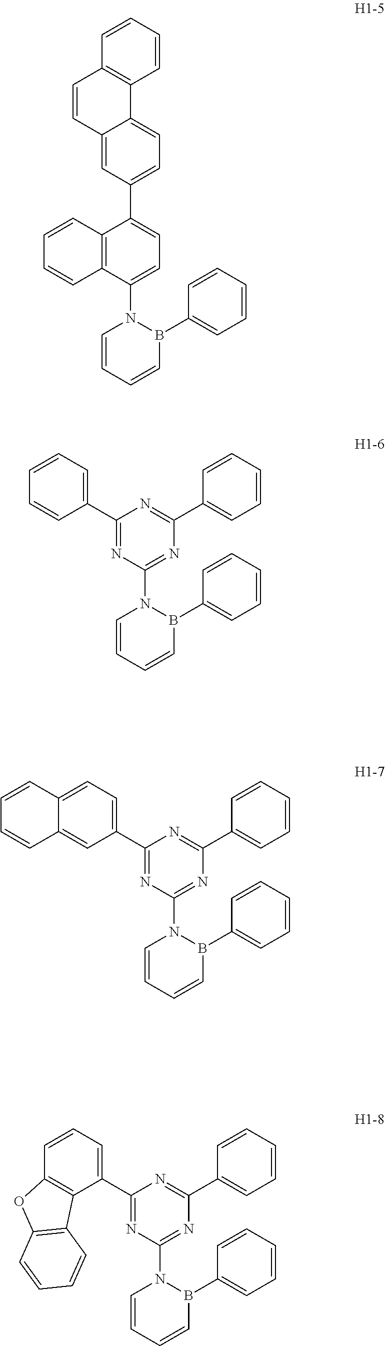 [SMILES: C1=CB(c2ccccc2)N(c2ccc(-c3ccc4c(ccc5ccccc54)c3)c3ccccc23)C=C1 ; C1=CB(c2ccccc2)N(c2nc(-c3ccccc3)nc(-c3ccccc3)n2)C=C1 ; C1=CB(c2ccccc2)N(c2nc(-c3ccccc3)nc(-c3ccc4ccccc4c3)n2)C=C1 ; C1=CB(c2ccccc2)N(c2nc(-c3ccccc3)nc(-c3cccc4oc5ccccc5c34)n2)C=C1]

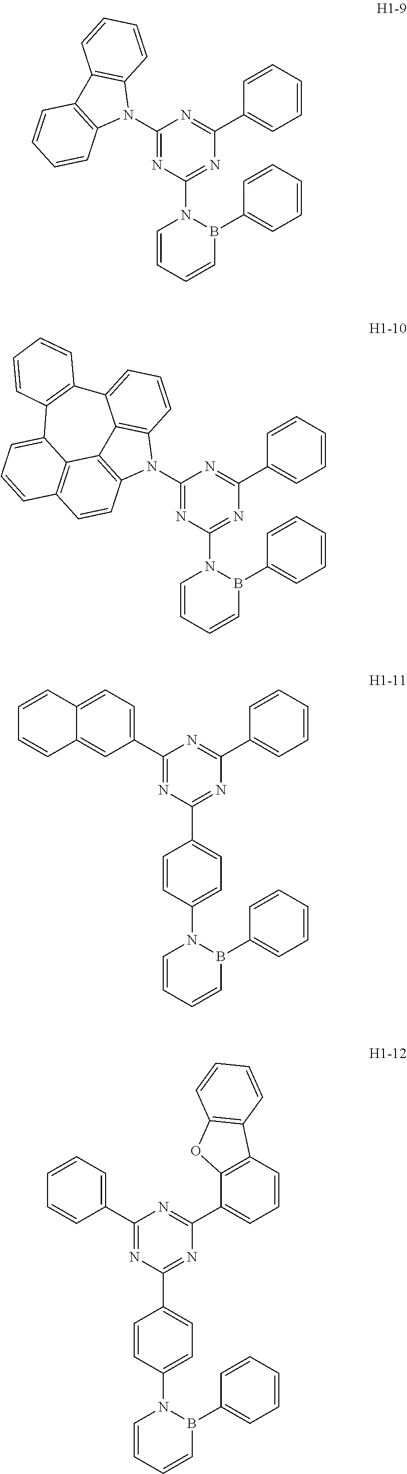 [SMILES: C1=CB(c2ccccc2)N(c2nc(-c3ccccc3)nc(-n3c4ccccc4c4ccccc43)n2)C=C1 ; C1=CB(c2ccccc2)N(c2nc(-c3ccccc3)nc(-n3c4cccc5c4c4c6c(cccc6ccc43)-c3ccccc3-5)n2)C=C1 ; C1=CB(c2ccccc2)N(c2ccc(-c3nc(-c4ccccc4)nc(-c4ccc5ccccc5c4)n3)cc2)C=C1 ; C1=CB(c2ccccc2)N(c2ccc(-c3nc(-c4ccccc4)nc(-c4cccc5c4oc4ccccc45)n3)cc2)C=C1]

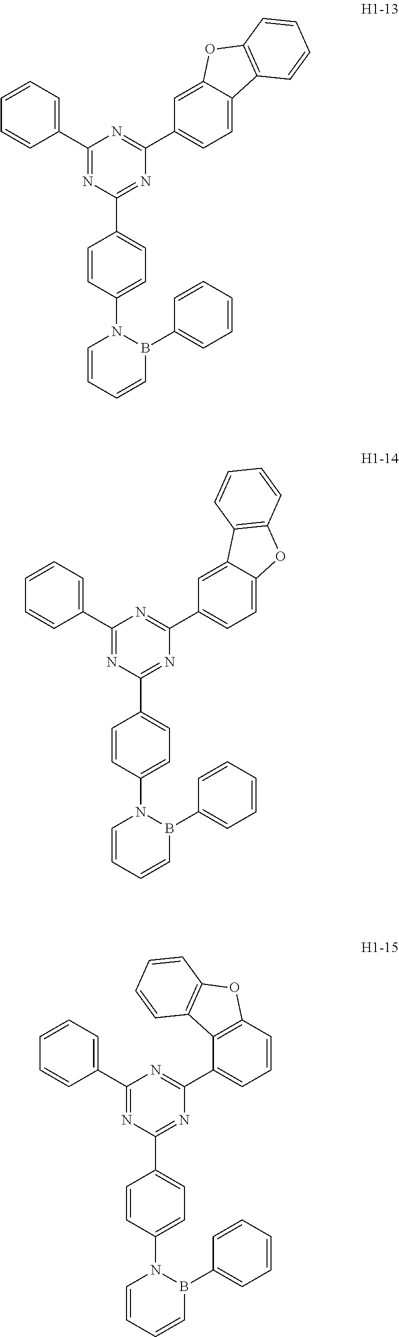 [SMILES: C1=CB(c2ccccc2)N(c2ccc(-c3nc(-c4ccccc4)nc(-c4ccc5c(c4)oc4ccccc45)n3)cc2)C=C1 ; C1=CB(c2ccccc2)N(c2ccc(-c3nc(-c4ccccc4)nc(-c4ccc5oc6ccccc6c5c4)n3)cc2)C=C1 ; C1=CB(c2ccccc2)N(c2ccc(-c3nc(-c4ccccc4)nc(-c4cccc5oc6ccccc6c45)n3)cc2)C=C1]

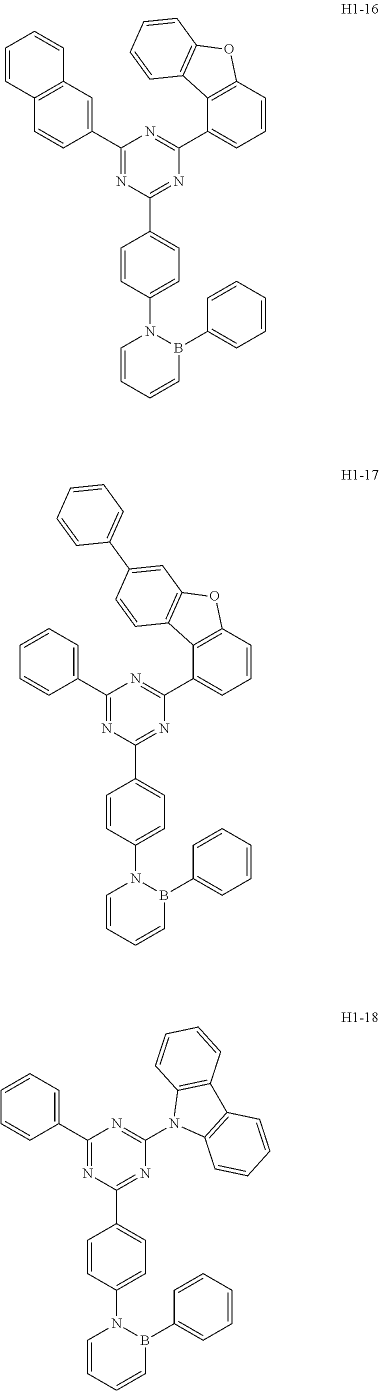 [SMILES: C1=CB(c2ccccc2)N(c2ccc(-c3nc(-c4ccc5ccccc5c4)nc(-c4cccc5oc6ccccc6c45)n3)cc2)C=C1 ; C1=CB(c2ccccc2)N(c2ccc(-c3nc(-c4ccccc4)nc(-c4cccc5oc6cc(-c7ccccc7)ccc6c45)n3)cc2)C=C1 ; C1=CB(c2ccccc2)N(c2ccc(-c3nc(-c4ccccc4)nc(-n4c5ccccc5c5ccccc54)n3)cc2)C=C1]

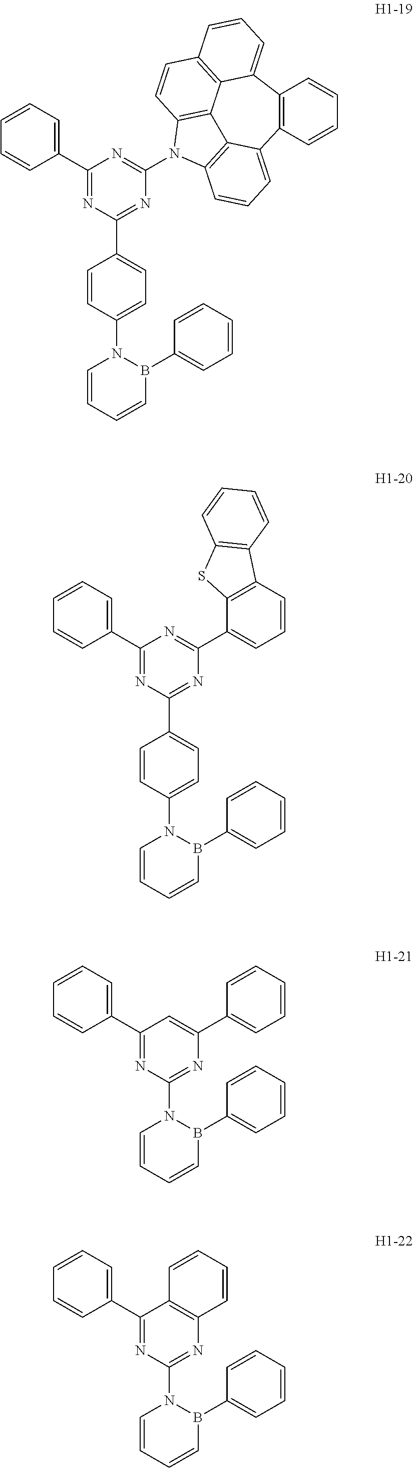 [SMILES: C1=CB(c2ccccc2)N(c2ccc(-c3nc(-c4ccccc4)nc(-n4c5cccc6c5c5c7c(cccc7ccc54)-c4ccccc4-6)n3)cc2)C=C1 ; C1=CB(c2ccccc2)N(c2ccc(-c3nc(-c4ccccc4)nc(-c4cccc5c4sc4ccccc45)n3)cc2)C=C1 ; C1=CB(c2ccccc2)N(c2nc(-c3ccccc3)cc(-c3ccccc3)n2)C=C1 ; C1=CB(c2ccccc2)N(c2nc(-c3ccccc3)c3ccccc3n2)C=C1]

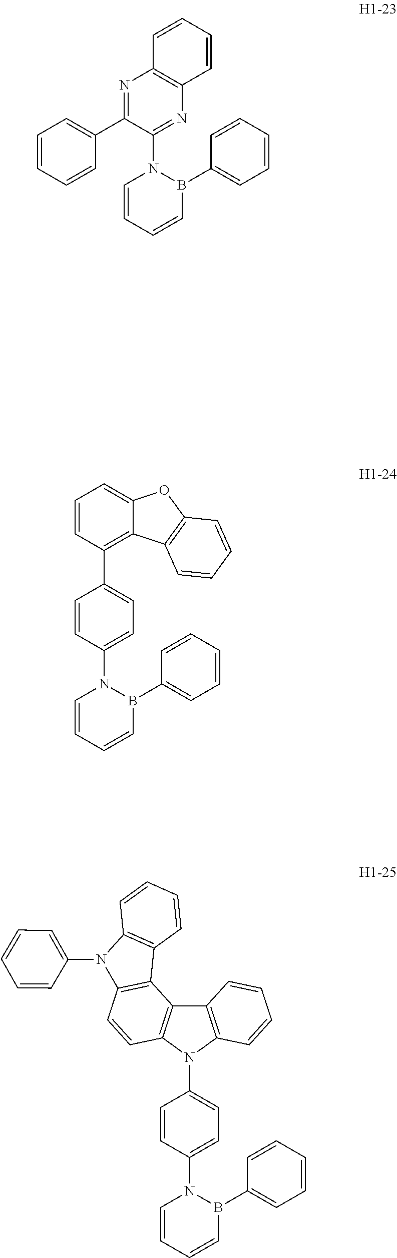 [SMILES: C1=CB(c2ccccc2)N(c2nc3ccccc3nc2-c2ccccc2)C=C1 ; C1=CB(c2ccccc2)N(c2ccc(-c3cccc4oc5ccccc5c34)cc2)C=C1 ; C1=CB(c2ccccc2)N(c2ccc(-n3c4ccccc4c4c5c6ccccc6n(-c6ccccc6)c5ccc43)cc2)C=C1]

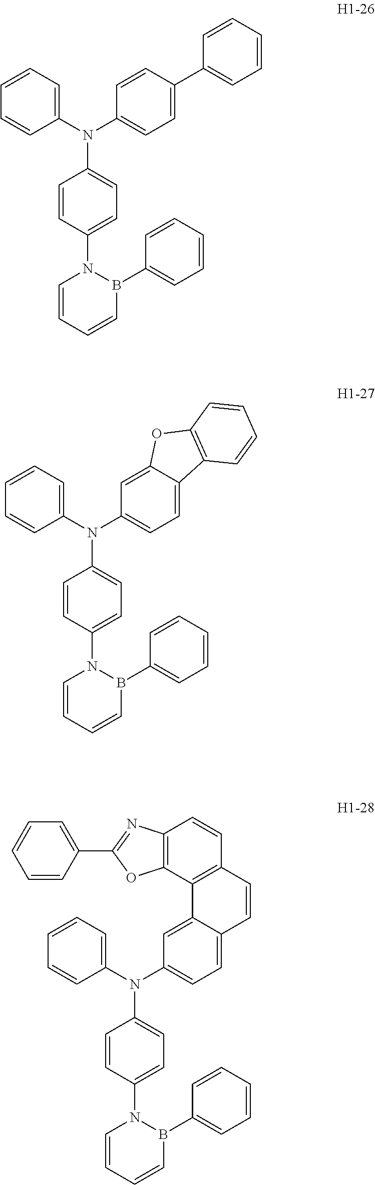 [SMILES: C1=CB(c2ccccc2)N(c2ccc(N(c3ccccc3)c3ccc(-c4ccccc4)cc3)cc2)C=C1 ; C1=CB(c2ccccc2)N(c2ccc(N(c3ccccc3)c3ccc4c(c3)oc3ccccc34)cc2)C=C1 ; C1=CB(c2ccccc2)N(c2ccc(N(c3ccccc3)c3ccc4ccc5ccc6nc(-c7ccccc7)oc6c5c4c3)cc2)C=C1]

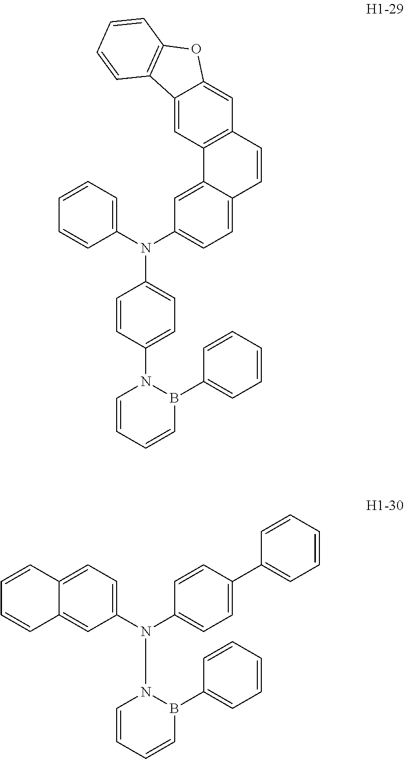 [SMILES: C1=CB(c2ccccc2)N(c2ccc(N(c3ccccc3)c3ccc4ccc5cc6oc7ccccc7c6cc5c4c3)cc2)C=C1 ; C1=CB(c2ccccc2)N(N(c2ccc(-c3ccccc3)cc2)c2ccc3ccccc3c2)C=C1]

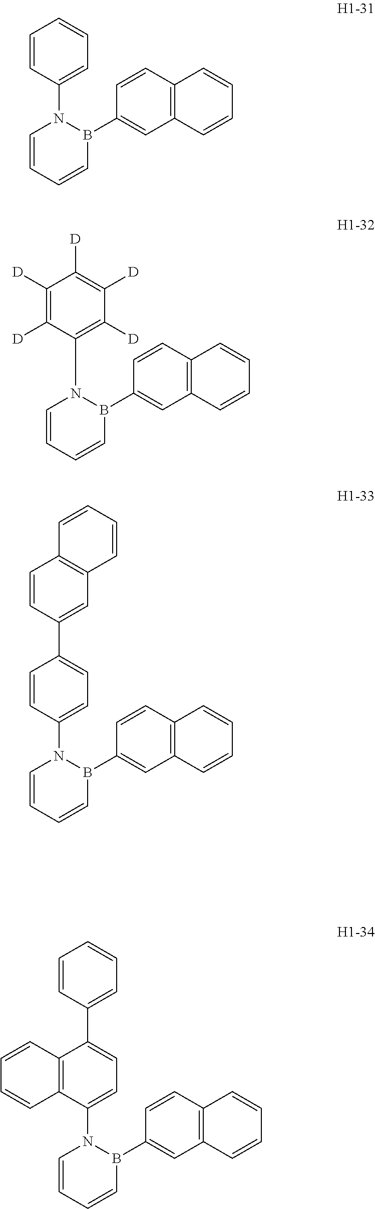 [SMILES: C1=CB(c2ccc3ccccc3c2)N(c2ccccc2)C=C1 ; [2H]c1c([2H])c([2H])c(N2C=CC=CB2c2ccc3ccccc3c2)c([2H])c1[2H] ; C1=CB(c2ccc3ccccc3c2)N(c2ccc(-c3ccc4ccccc4c3)cc2)C=C1 ; C1=CB(c2ccc3ccccc3c2)N(c2ccc(-c3ccccc3)c3ccccc23)C=C1]

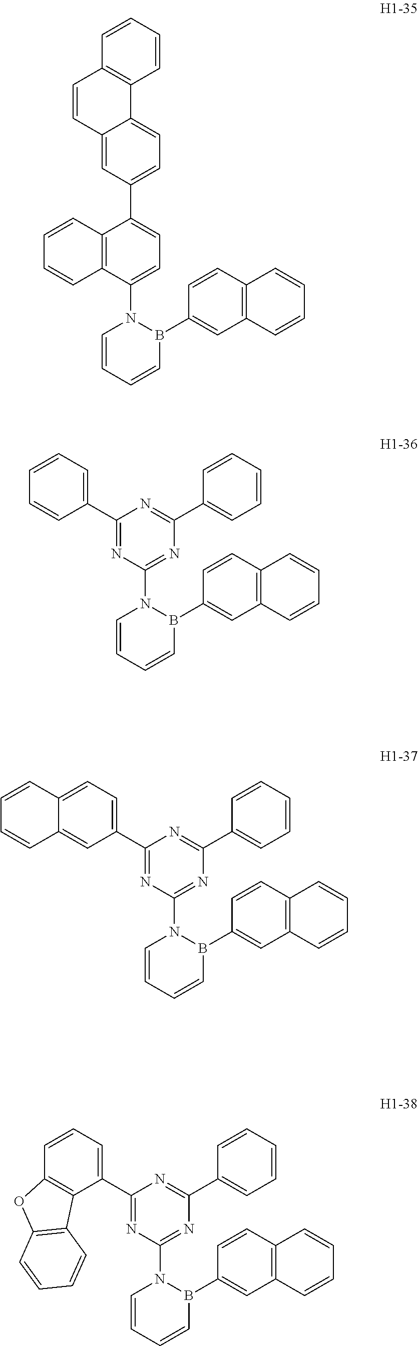 [SMILES: C1=CB(c2ccc3ccccc3c2)N(c2ccc(-c3ccc4c(ccc5ccccc54)c3)c3ccccc23)C=C1 ; C1=CB(c2ccc3ccccc3c2)N(c2nc(-c3ccccc3)nc(-c3ccccc3)n2)C=C1 ; C1=CB(c2ccc3ccccc3c2)N(c2nc(-c3ccccc3)nc(-c3ccc4ccccc4c3)n2)C=C1 ; C1=CB(c2ccc3ccccc3c2)N(c2nc(-c3ccccc3)nc(-c3cccc4oc5ccccc5c34)n2)C=C1]

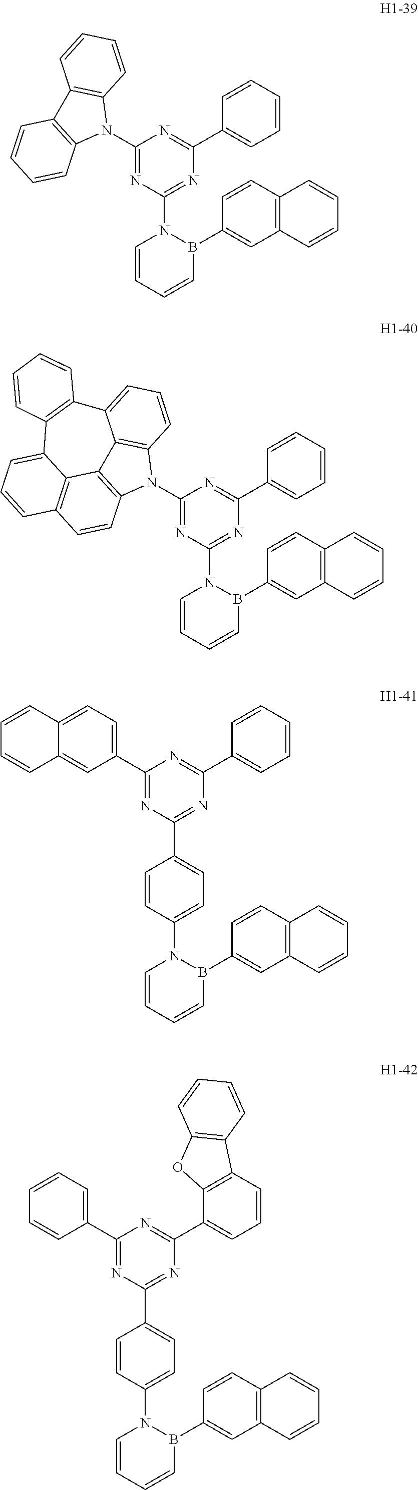 [SMILES: C1=CB(c2ccc3ccccc3c2)N(c2nc(-c3ccccc3)nc(-n3c4ccccc4c4ccccc43)n2)C=C1 ; C1=CB(c2ccc3ccccc3c2)N(c2nc(-c3ccccc3)nc(-n3c4cccc5c4c4c6c(cccc6ccc43)-c3ccccc3-5)n2)C=C1 ; C1=CB(c2ccc3ccccc3c2)N(c2ccc(-c3nc(-c4ccccc4)nc(-c4ccc5ccccc5c4)n3)cc2)C=C1 ; C1=CB(c2ccc3ccccc3c2)N(c2ccc(-c3nc(-c4ccccc4)nc(-c4cccc5c4oc4ccccc45)n3)cc2)C=C1]

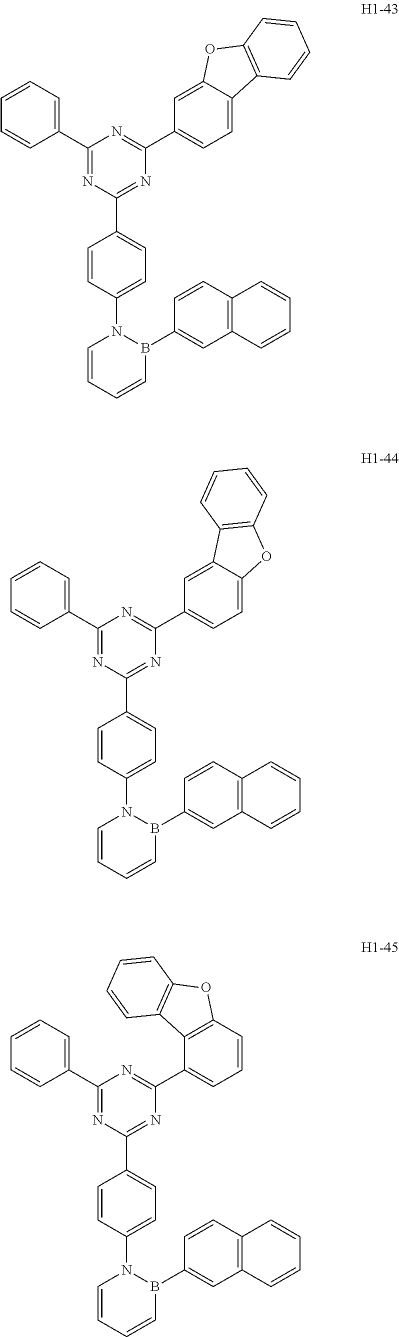 [SMILES: C1=CB(c2ccc3ccccc3c2)N(c2ccc(-c3nc(-c4ccccc4)nc(-c4ccc5c(c4)oc4ccccc45)n3)cc2)C=C1 ; C1=CB(c2ccc3ccccc3c2)N(c2ccc(-c3nc(-c4ccccc4)nc(-c4ccc5oc6ccccc6c5c4)n3)cc2)C=C1 ; C1=CB(c2ccc3ccccc3c2)N(c2ccc(-c3nc(-c4ccccc4)nc(-c4cccc5oc6ccccc6c45)n3)cc2)C=C1]

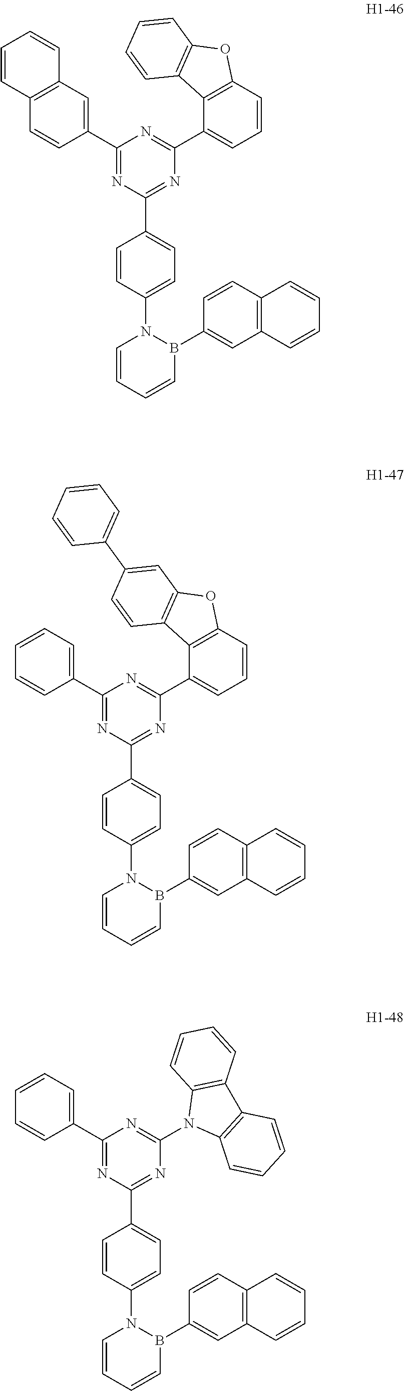 [SMILES: C1=CB(c2ccc3ccccc3c2)N(c2ccc(-c3nc(-c4ccc5ccccc5c4)nc(-c4cccc5oc6ccccc6c45)n3)cc2)C=C1 ; C1=CB(c2ccc3ccccc3c2)N(c2ccc(-c3nc(-c4ccccc4)nc(-c4cccc5oc6cc(-c7ccccc7)ccc6c45)n3)cc2)C=C1 ; C1=CB(c2ccc3ccccc3c2)N(c2ccc(-c3nc(-c4ccccc4)nc(-n4c5ccccc5c5ccccc54)n3)cc2)C=C1]

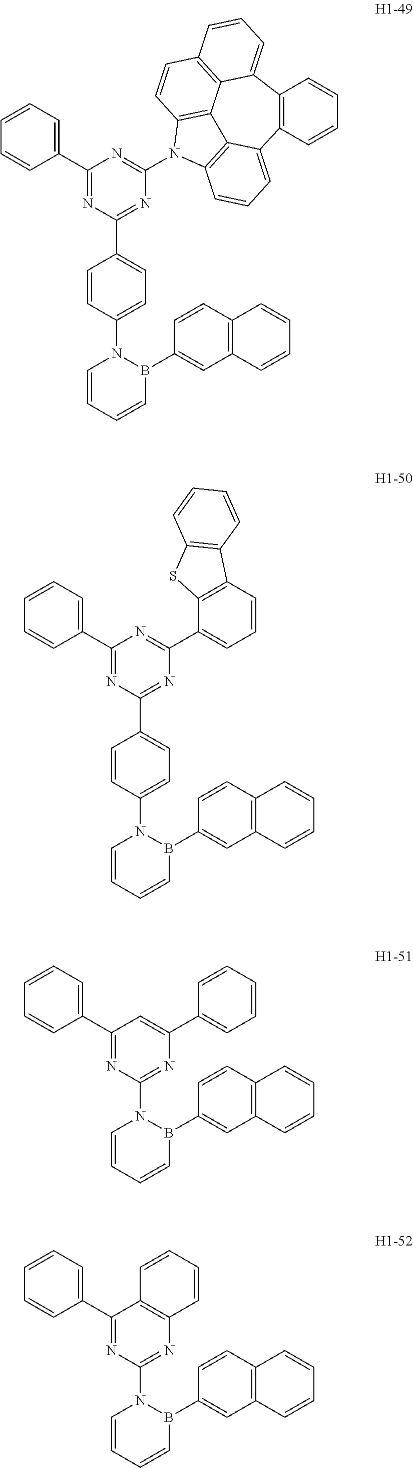 [SMILES: C1=CB(c2ccc3ccccc3c2)N(c2ccc(-c3nc(-c4ccccc4)nc(-n4c5cccc6c5c5c7c(cccc7ccc54)-c4ccccc4-6)n3)cc2)C=C1 ; C1=CB(c2ccc3ccccc3c2)N(c2ccc(-c3nc(-c4ccccc4)nc(-c4cccc5c4sc4ccccc45)n3)cc2)C=C1 ; C1=CB(c2ccc3ccccc3c2)N(c2nc(-c3ccccc3)cc(-c3ccccc3)n2)C=C1 ; C1=CB(c2ccc3ccccc3c2)N(c2nc(-c3ccccc3)c3ccccc3n2)C=C1]

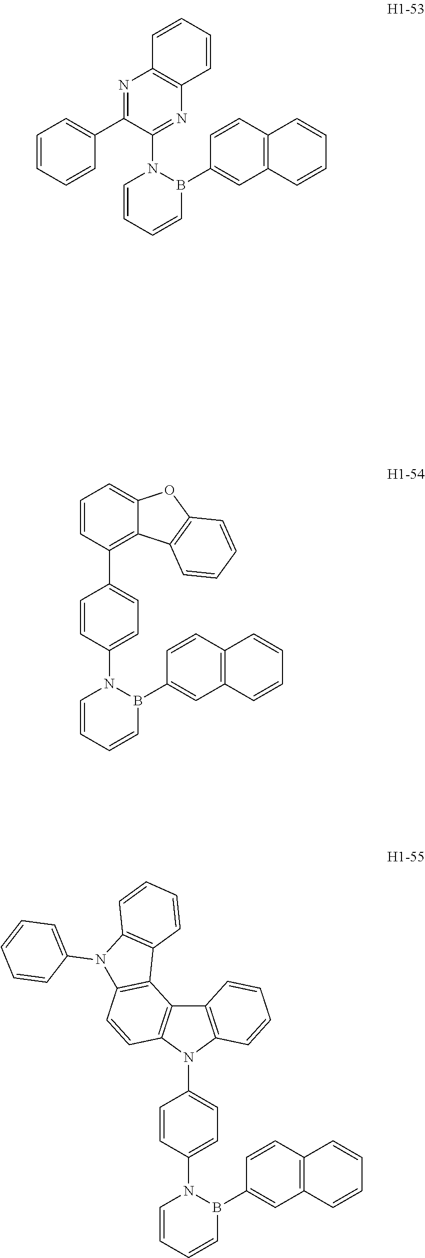 [SMILES: C1=CB(c2ccc3ccccc3c2)N(c2nc3ccccc3nc2-c2ccccc2)C=C1 ; C1=CB(c2ccc3ccccc3c2)N(c2ccc(-c3cccc4oc5ccccc5c34)cc2)C=C1 ; C1=CB(c2ccc3ccccc3c2)N(c2ccc(-n3c4ccccc4c4c5c6ccccc6n(-c6ccccc6)c5ccc43)cc2)C=C1]

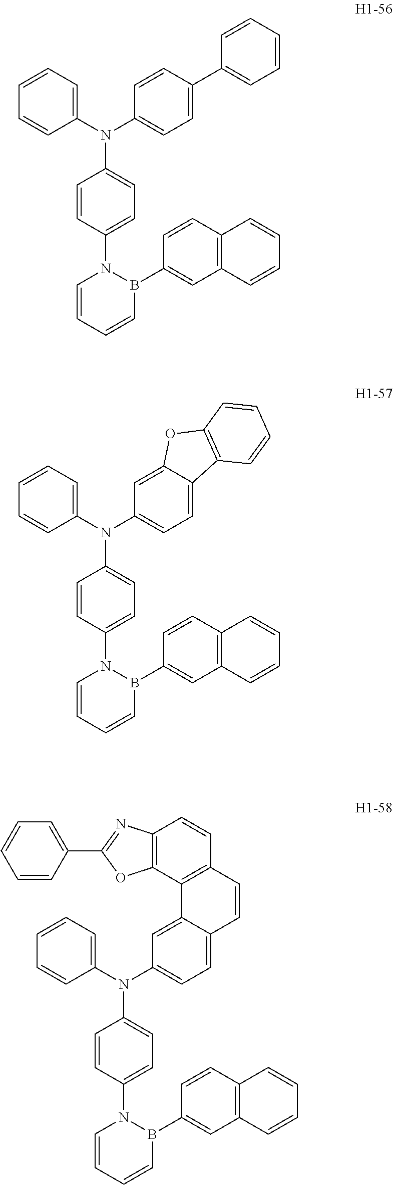 [SMILES: C1=CB(c2ccc3ccccc3c2)N(c2ccc(N(c3ccccc3)c3ccc(-c4ccccc4)cc3)cc2)C=C1 ; C1=CB(c2ccc3ccccc3c2)N(c2ccc(N(c3ccccc3)c3ccc4c(c3)oc3ccccc34)cc2)C=C1 ; C1=CB(c2ccc3ccccc3c2)N(c2ccc(N(c3ccccc3)c3ccc4ccc5ccc6nc(-c7ccccc7)oc6c5c4c3)cc2)C=C1]

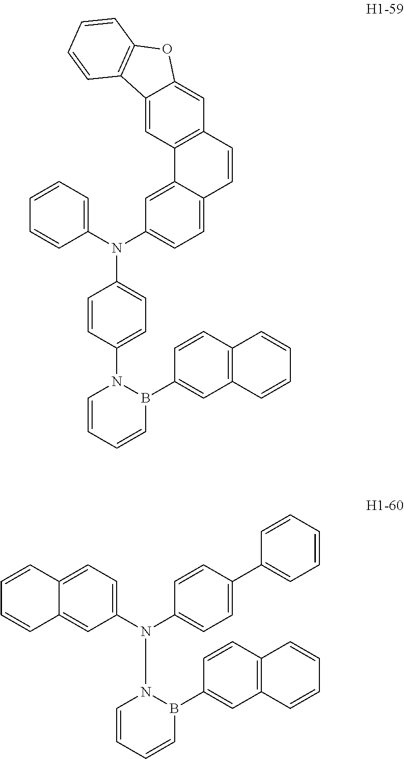 [SMILES: C1=CB(c2ccc3ccccc3c2)N(c2ccc(N(c3ccccc3)c3ccc4ccc5cc6oc7ccccc7c6cc5c4c3)cc2)C=C1 ; C1=CB(c2ccc3ccccc3c2)N(N(c2ccc(-c3ccccc3)cc2)c2ccc3ccccc3c2)C=C1]

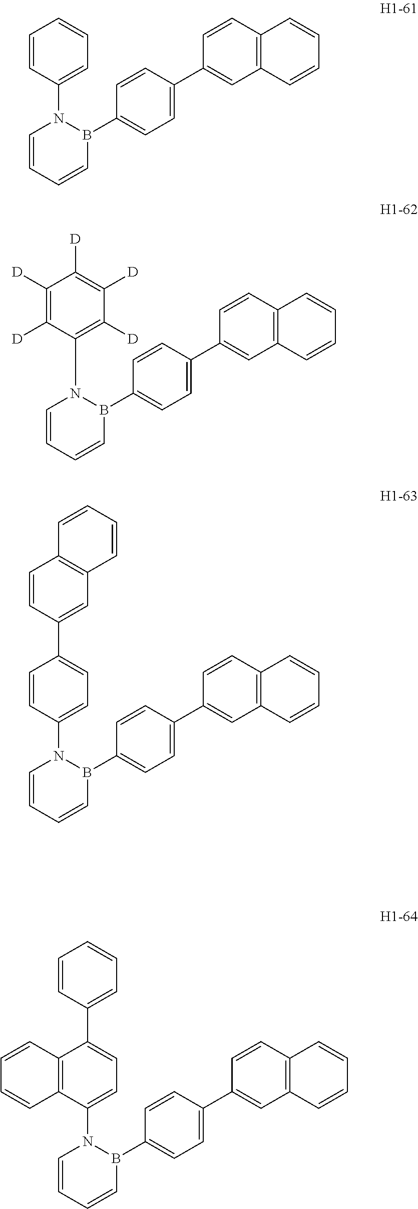 [SMILES: C1=CB(c2ccc(-c3ccc4ccccc4c3)cc2)N(c2ccccc2)C=C1 ; [2H]c1c([2H])c([2H])c(N2C=CC=CB2c2ccc(-c3ccc4ccccc4c3)cc2)c([2H])c1[2H] ; C1=CB(c2ccc(-c3ccc4ccccc4c3)cc2)N(c2ccc(-c3ccc4ccccc4c3)cc2)C=C1 ; C1=CB(c2ccc(-c3ccc4ccccc4c3)cc2)N(c2ccc(-c3ccccc3)c3ccccc23)C=C1]

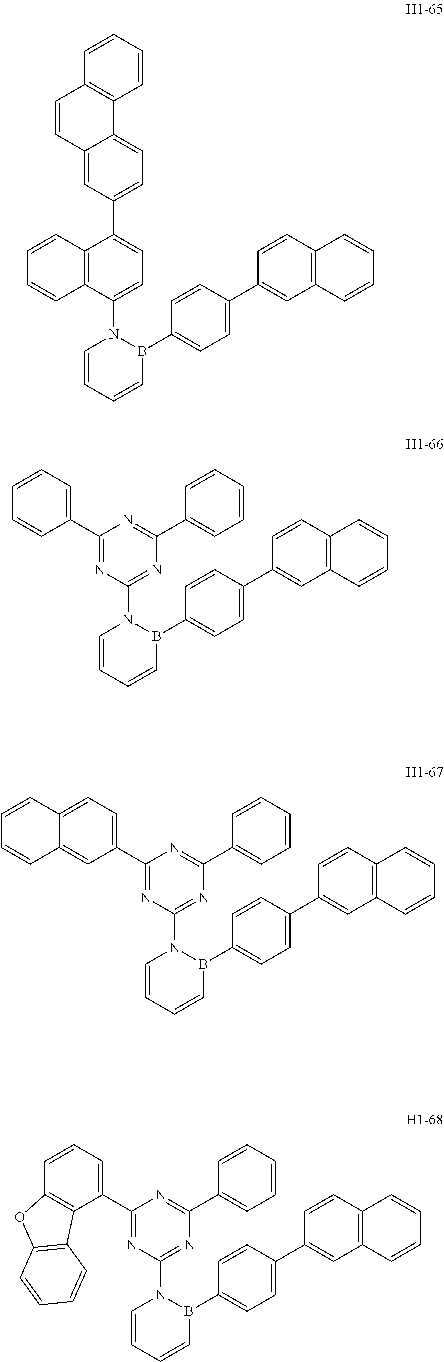 [SMILES: C1=CB(c2ccc(-c3ccc4ccccc4c3)cc2)N(c2ccc(-c3ccc4c(ccc5ccccc54)c3)c3ccccc23)C=C1 ; C1=CB(c2ccc(-c3ccc4ccccc4c3)cc2)N(c2nc(-c3ccccc3)nc(-c3ccccc3)n2)C=C1 ; C1=CB(c2ccc(-c3ccc4ccccc4c3)cc2)N(c2nc(-c3ccccc3)nc(-c3ccc4ccccc4c3)n2)C=C1 ; C1=CB(c2ccc(-c3ccc4ccccc4c3)cc2)N(c2nc(-c3ccccc3)nc(-c3cccc4oc5ccccc5c34)n2)C=C1]

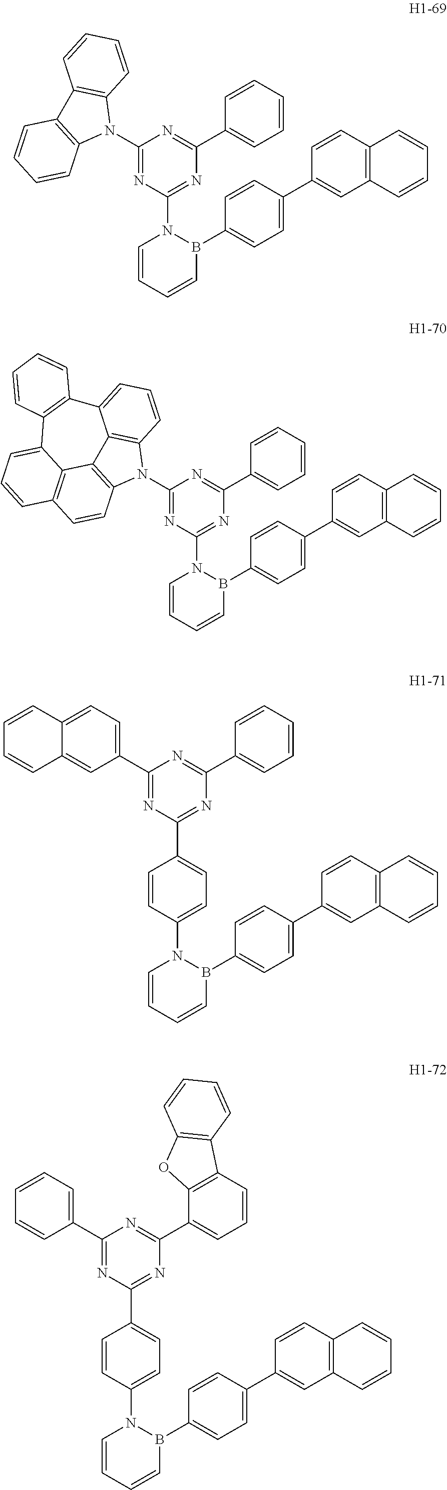 [SMILES: C1=CB(c2ccc(-c3ccc4ccccc4c3)cc2)N(c2nc(-c3ccccc3)nc(-n3c4ccccc4c4ccccc43)n2)C=C1 ; C1=CB(c2ccc(-c3ccc4ccccc4c3)cc2)N(c2nc(-c3ccccc3)nc(-n3c4cccc5c4c4c6c(cccc6ccc43)-c3ccccc3-5)n2)C=C1 ; C1=CB(c2ccc(-c3ccc4ccccc4c3)cc2)N(c2ccc(-c3nc(-c4ccccc4)nc(-c4ccc5ccccc5c4)n3)cc2)C=C1 ; C1=CB(c2ccc(-c3ccc4ccccc4c3)cc2)N(c2ccc(-c3nc(-c4ccccc4)nc(-c4cccc5c4oc4ccccc45)n3)cc2)C=C1]

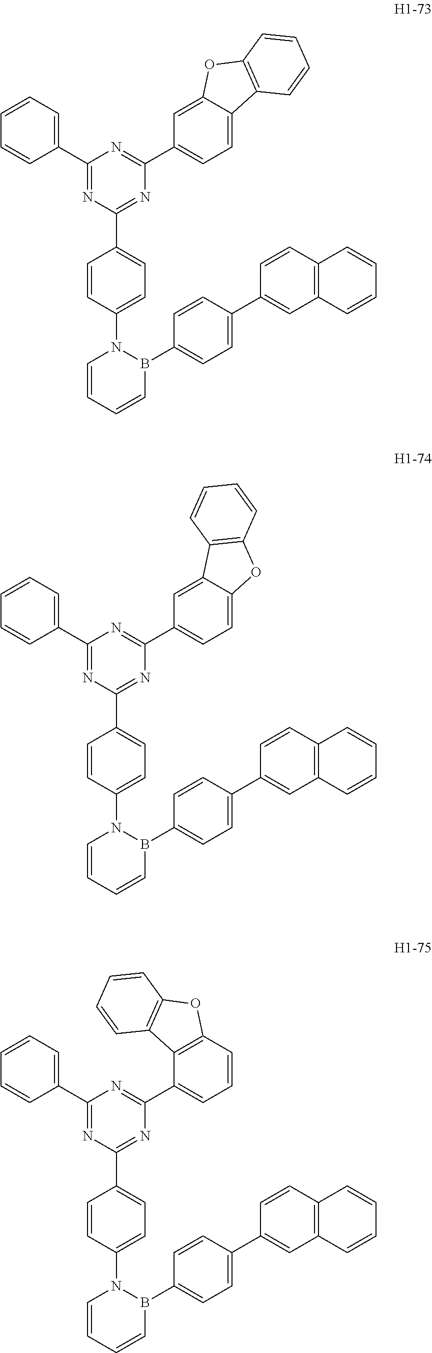 [SMILES: C1=CB(c2ccc(-c3ccc4ccccc4c3)cc2)N(c2ccc(-c3nc(-c4ccccc4)nc(-c4ccc5c(c4)oc4ccccc45)n3)cc2)C=C1 ; C1=CB(c2ccc(-c3ccc4ccccc4c3)cc2)N(c2ccc(-c3nc(-c4ccccc4)nc(-c4ccc5oc6ccccc6c5c4)n3)cc2)C=C1 ; C1=CB(c2ccc(-c3ccc4ccccc4c3)cc2)N(c2ccc(-c3nc(-c4ccccc4)nc(-c4cccc5oc6ccccc6c45)n3)cc2)C=C1]

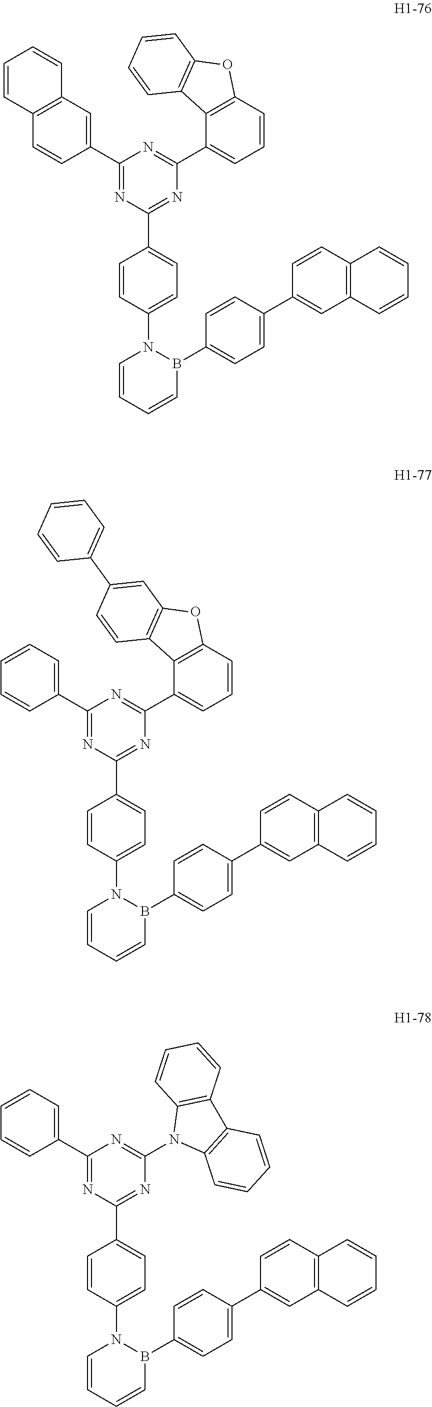 [SMILES: C1=CB(c2ccc(-c3ccc4ccccc4c3)cc2)N(c2ccc(-c3nc(-c4ccc5ccccc5c4)nc(-c4cccc5oc6ccccc6c45)n3)cc2)C=C1 ; C1=CB(c2ccc(-c3ccc4ccccc4c3)cc2)N(c2ccc(-c3nc(-c4ccccc4)nc(-c4cccc5oc6cc(-c7ccccc7)ccc6c45)n3)cc2)C=C1 ; C1=CB(c2ccc(-c3ccc4ccccc4c3)cc2)N(c2ccc(-c3nc(-c4ccccc4)nc(-n4c5ccccc5c5ccccc54)n3)cc2)C=C1]

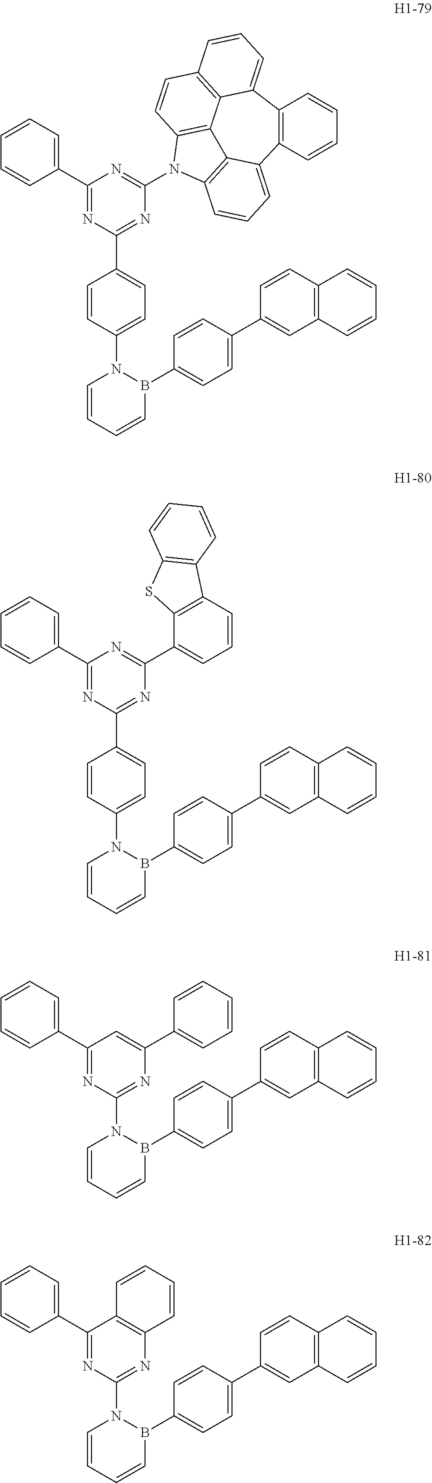 [SMILES: C1=CB(c2ccc(-c3ccc4ccccc4c3)cc2)N(c2ccc(-c3nc(-c4ccccc4)nc(-n4c5cccc6c5c5c7c(cccc7ccc54)-c4ccccc4-6)n3)cc2)C=C1 ; C1=CB(c2ccc(-c3ccc4ccccc4c3)cc2)N(c2ccc(-c3nc(-c4ccccc4)nc(-c4cccc5c4sc4ccccc45)n3)cc2)C=C1 ; C1=CB(c2ccc(-c3ccc4ccccc4c3)cc2)N(c2nc(-c3ccccc3)cc(-c3ccccc3)n2)C=C1 ; C1=CB(c2ccc(-c3ccc4ccccc4c3)cc2)N(c2nc(-c3ccccc3)c3ccccc3n2)C=C1]

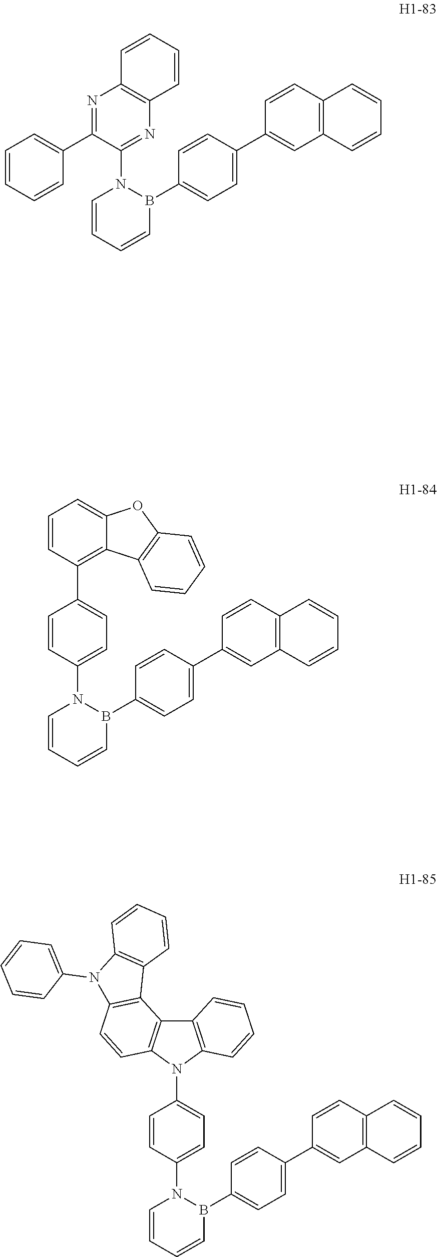 [SMILES: C1=CB(c2ccc(-c3ccc4ccccc4c3)cc2)N(c2nc3ccccc3nc2-c2ccccc2)C=C1 ; C1=CB(c2ccc(-c3ccc4ccccc4c3)cc2)N(c2ccc(-c3cccc4oc5ccccc5c34)cc2)C=C1 ; C1=CB(c2ccc(-c3ccc4ccccc4c3)cc2)N(c2ccc(-n3c4ccccc4c4c5c6ccccc6n(-c6ccccc6)c5ccc43)cc2)C=C1]

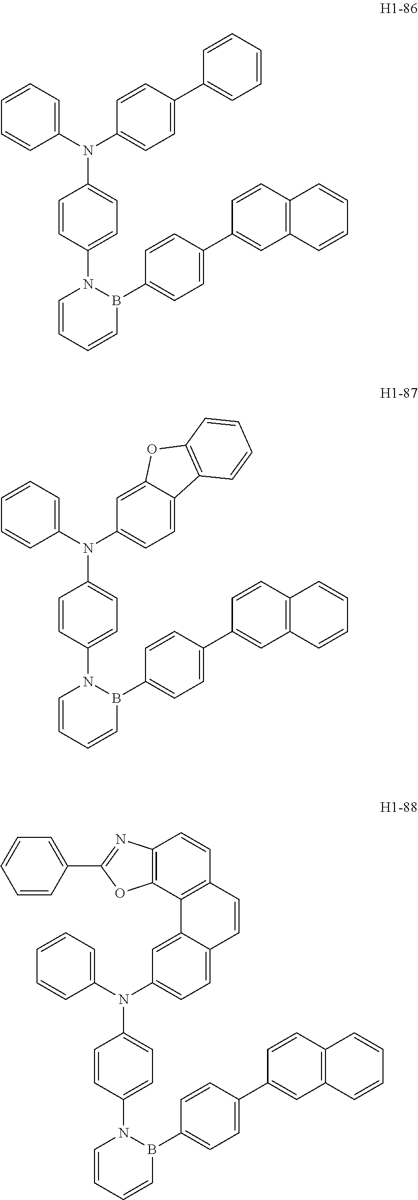 [SMILES: C1=CB(c2ccc(-c3ccc4ccccc4c3)cc2)N(c2ccc(N(c3ccccc3)c3ccc(-c4ccccc4)cc3)cc2)C=C1 ; C1=CB(c2ccc(-c3ccc4ccccc4c3)cc2)N(c2ccc(N(c3ccccc3)c3ccc4c(c3)oc3ccccc34)cc2)C=C1 ; C1=CB(c2ccc(-c3ccc4ccccc4c3)cc2)N(c2ccc(N(c3ccccc3)c3ccc4ccc5ccc6nc(-c7ccccc7)oc6c5c4c3)cc2)C=C1]

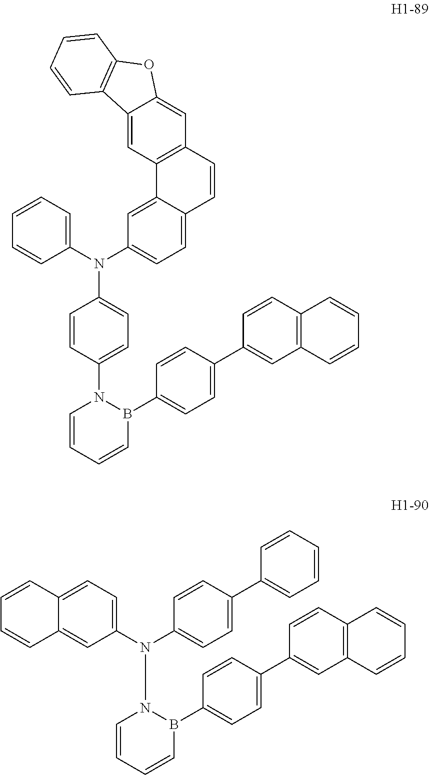 [SMILES: C1=CB(c2ccc(-c3ccc4ccccc4c3)cc2)N(c2ccc(N(c3ccccc3)c3ccc4ccc5cc6oc7ccccc7c6cc5c4c3)cc2)C=C1 ; C1=CB(c2ccc(-c3ccc4ccccc4c3)cc2)N(N(c2ccc(-c3ccccc3)cc2)c2ccc3ccccc3c2)C=C1]

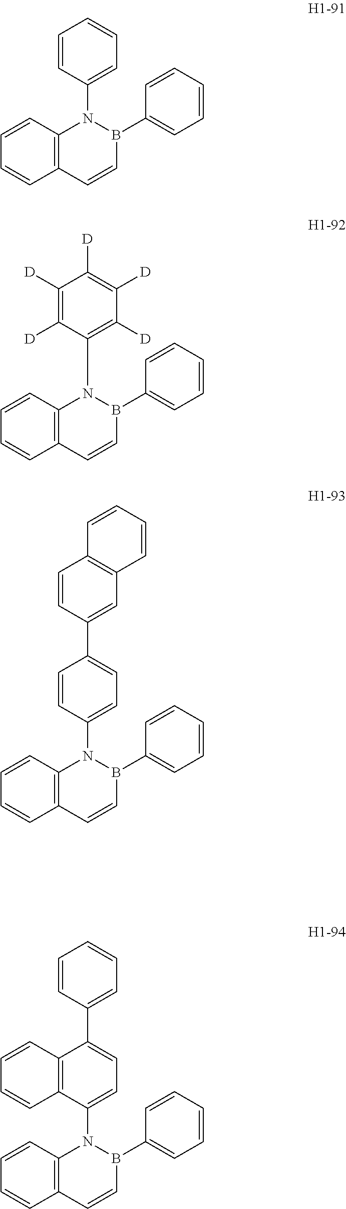 [SMILES: C1=Cc2ccccc2N(c2ccccc2)B1c1ccccc1 ; [2H]c1c([2H])c([2H])c(N2B(c3ccccc3)C=Cc3ccccc32)c([2H])c1[2H] ; C1=Cc2ccccc2N(c2ccc(-c3ccc4ccccc4c3)cc2)B1c1ccccc1 ; C1=Cc2ccccc2N(c2ccc(-c3ccccc3)c3ccccc23)B1c1ccccc1]

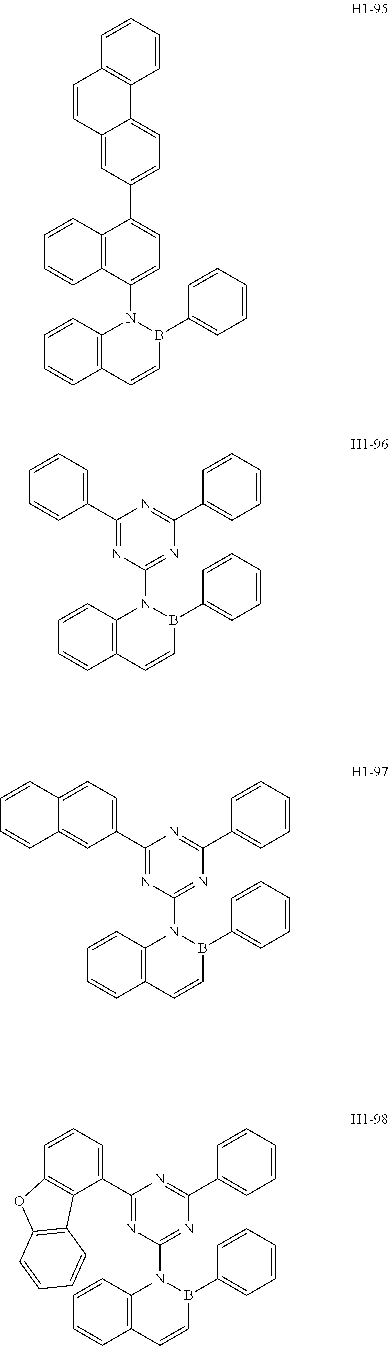 [SMILES: C1=Cc2ccccc2N(c2ccc(-c3ccc4c(ccc5ccccc54)c3)c3ccccc23)B1c1ccccc1 ; C1=Cc2ccccc2N(c2nc(-c3ccccc3)nc(-c3ccccc3)n2)B1c1ccccc1 ; C1=Cc2ccccc2N(c2nc(-c3ccccc3)nc(-c3ccc4ccccc4c3)n2)B1c1ccccc1 ; C1=Cc2ccccc2N(c2nc(-c3ccccc3)nc(-c3cccc4oc5ccccc5c34)n2)B1c1ccccc1]

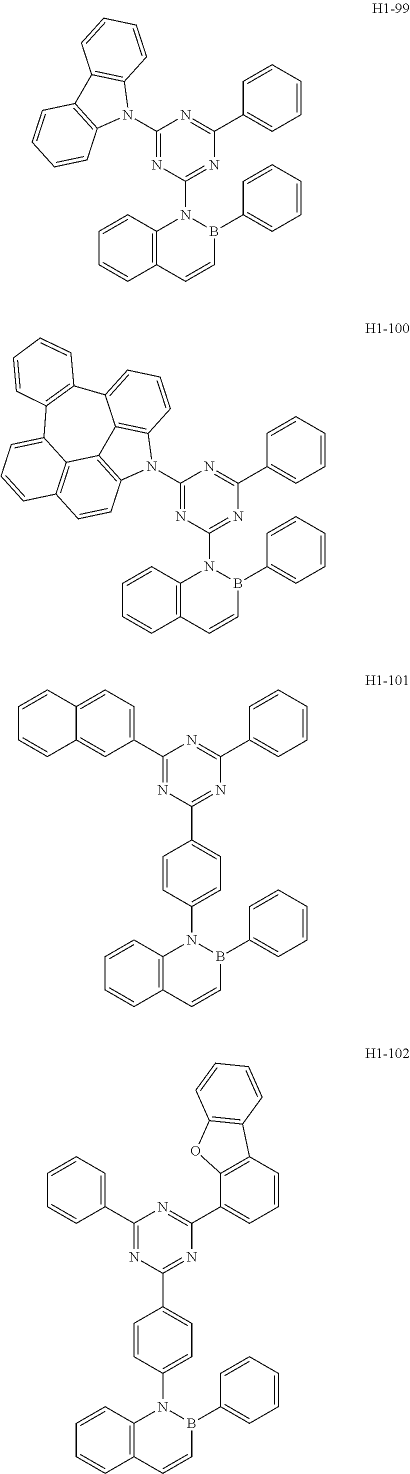 [SMILES: C1=Cc2ccccc2N(c2nc(-c3ccccc3)nc(-n3c4ccccc4c4ccccc43)n2)B1c1ccccc1 ; C1=Cc2ccccc2N(c2nc(-c3ccccc3)nc(-n3c4cccc5c4c4c6c(cccc6ccc43)-c3ccccc3-5)n2)B1c1ccccc1 ; C1=Cc2ccccc2N(c2ccc(-c3nc(-c4ccccc4)nc(-c4ccc5ccccc5c4)n3)cc2)B1c1ccccc1 ; C1=Cc2ccccc2N(c2ccc(-c3nc(-c4ccccc4)nc(-c4cccc5c4oc4ccccc45)n3)cc2)B1c1ccccc1]

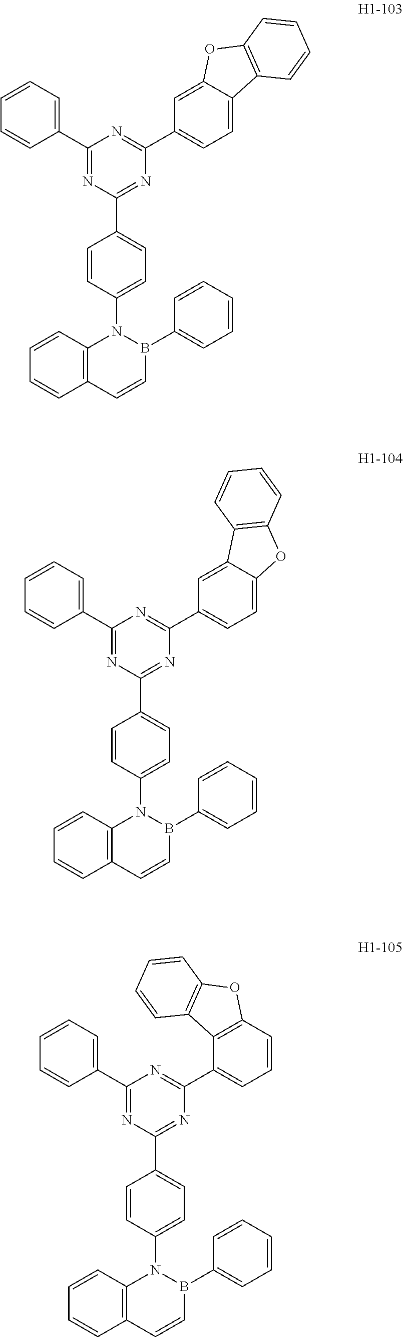 [SMILES: C1=Cc2ccccc2N(c2ccc(-c3nc(-c4ccccc4)nc(-c4ccc5c(c4)oc4ccccc45)n3)cc2)B1c1ccccc1 ; C1=Cc2ccccc2N(c2ccc(-c3nc(-c4ccccc4)nc(-c4ccc5oc6ccccc6c5c4)n3)cc2)B1c1ccccc1 ; C1=Cc2ccccc2N(c2ccc(-c3nc(-c4ccccc4)nc(-c4cccc5oc6ccccc6c45)n3)cc2)B1c1ccccc1]

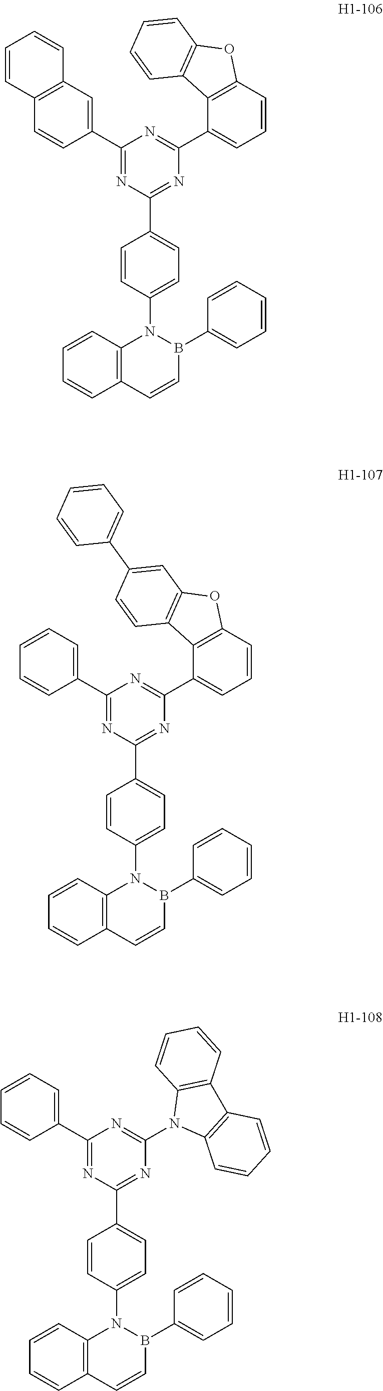 [SMILES: C1=Cc2ccccc2N(c2ccc(-c3nc(-c4ccc5ccccc5c4)nc(-c4cccc5oc6ccccc6c45)n3)cc2)B1c1ccccc1 ; C1=Cc2ccccc2N(c2ccc(-c3nc(-c4ccccc4)nc(-c4cccc5oc6cc(-c7ccccc7)ccc6c45)n3)cc2)B1c1ccccc1 ; C1=Cc2ccccc2N(c2ccc(-c3nc(-c4ccccc4)nc(-n4c5ccccc5c5ccccc54)n3)cc2)B1c1ccccc1]

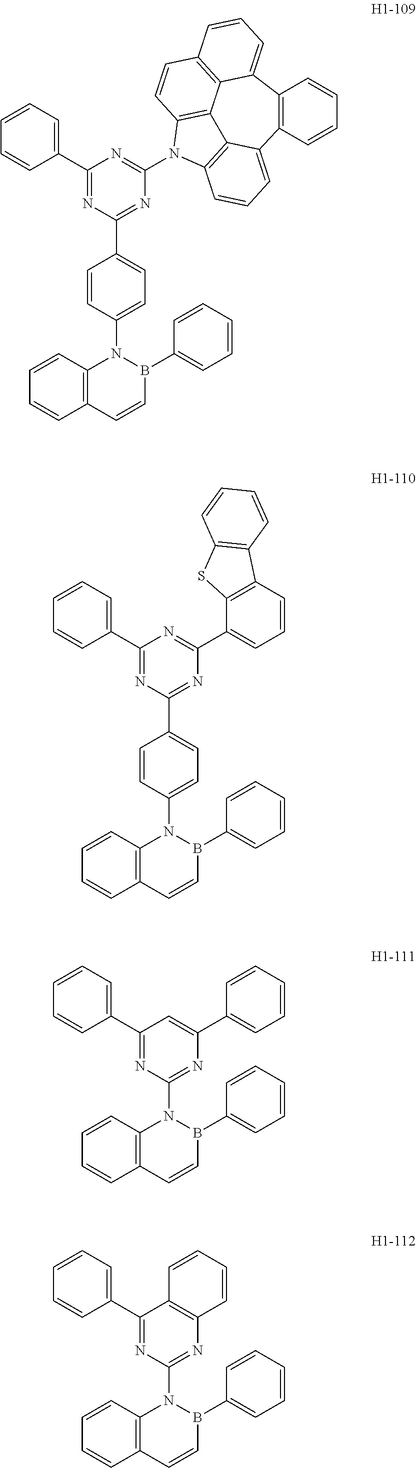 [SMILES: C1=Cc2ccccc2N(c2ccc(-c3nc(-c4ccccc4)nc(-n4c5cccc6c5c5c7c(cccc7ccc54)-c4ccccc4-6)n3)cc2)B1c1ccccc1 ; C1=Cc2ccccc2N(c2ccc(-c3nc(-c4ccccc4)nc(-c4cccc5c4sc4ccccc45)n3)cc2)B1c1ccccc1 ; C1=Cc2ccccc2N(c2nc(-c3ccccc3)cc(-c3ccccc3)n2)B1c1ccccc1 ; C1=Cc2ccccc2N(c2nc(-c3ccccc3)c3ccccc3n2)B1c1ccccc1]

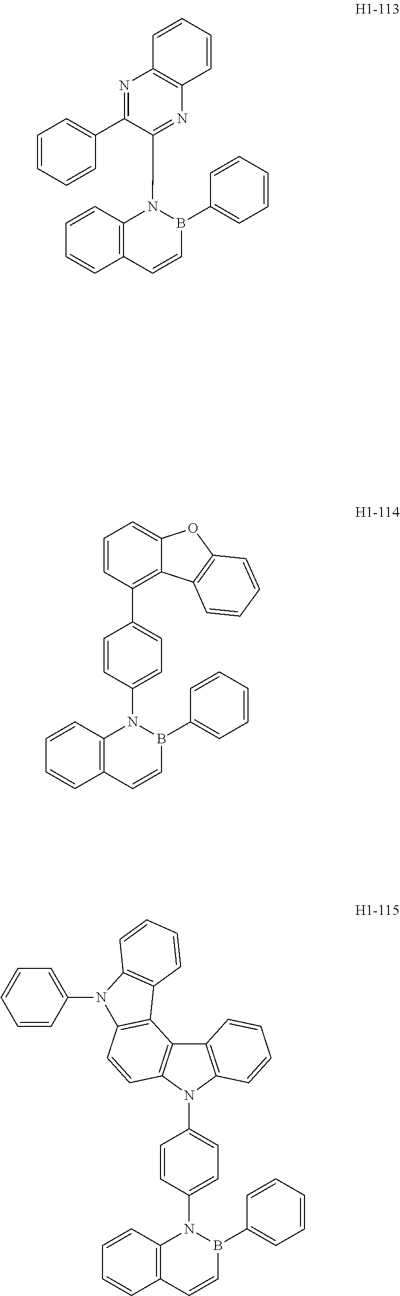 [SMILES: C1=Cc2ccccc2N(c2nc3ccccc3nc2-c2ccccc2)B1c1ccccc1 ; C1=Cc2ccccc2N(c2ccc(-c3cccc4oc5ccccc5c34)cc2)B1c1ccccc1 ; C1=Cc2ccccc2N(c2ccc(-n3c4ccccc4c4c5c6ccccc6n(-c6ccccc6)c5ccc43)cc2)B1c1ccccc1]

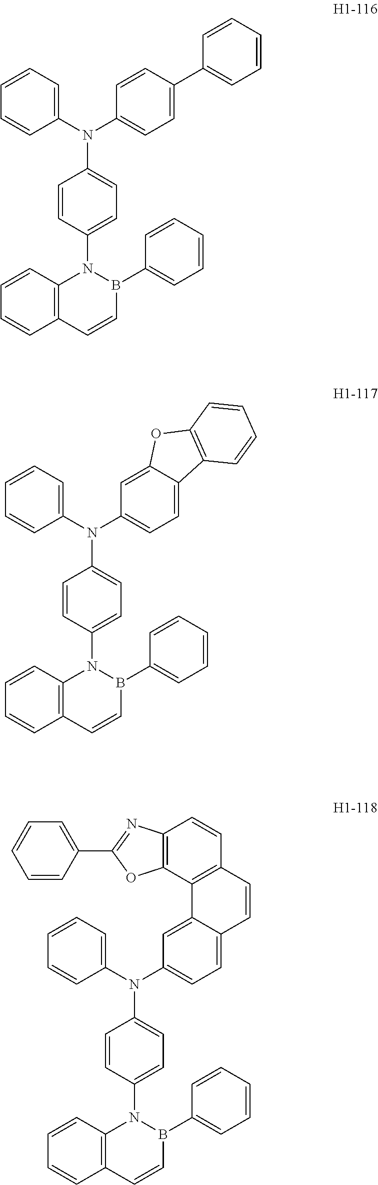 [SMILES: C1=Cc2ccccc2N(c2ccc(N(c3ccccc3)c3ccc(-c4ccccc4)cc3)cc2)B1c1ccccc1 ; C1=Cc2ccccc2N(c2ccc(N(c3ccccc3)c3ccc4c(c3)oc3ccccc34)cc2)B1c1ccccc1 ; C1=Cc2ccccc2N(c2ccc(N(c3ccccc3)c3ccc4ccc5ccc6nc(-c7ccccc7)oc6c5c4c3)cc2)B1c1ccccc1]

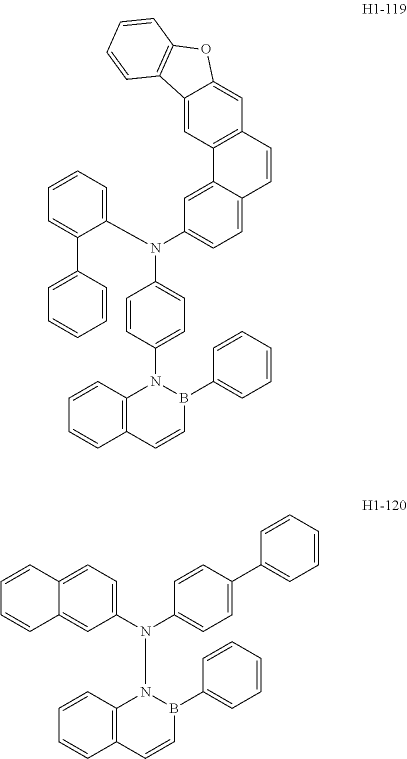 [SMILES: C1=Cc2ccccc2N(c2ccc(N(c3ccc4ccc5cc6oc7ccccc7c6cc5c4c3)c3ccccc3-c3ccccc3)cc2)B1c1ccccc1 ; C1=Cc2ccccc2N(N(c2ccc(-c3ccccc3)cc2)c2ccc3ccccc3c2)B1c1ccccc1]

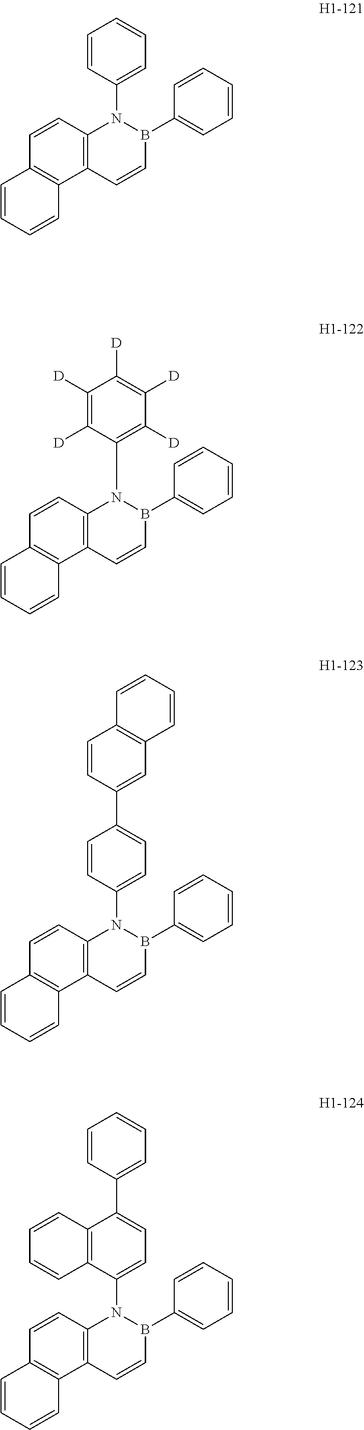 [SMILES: C1=Cc2c(ccc3ccccc23)N(c2ccccc2)B1c1ccccc1 ; [2H]c1c([2H])c([2H])c(N2B(c3ccccc3)C=Cc3c2ccc2ccccc32)c([2H])c1[2H] ; C1=Cc2c(ccc3ccccc23)N(c2ccc(-c3ccc4ccccc4c3)cc2)B1c1ccccc1 ; C1=Cc2c(ccc3ccccc23)N(c2ccc(-c3ccccc3)c3ccccc23)B1c1ccccc1]

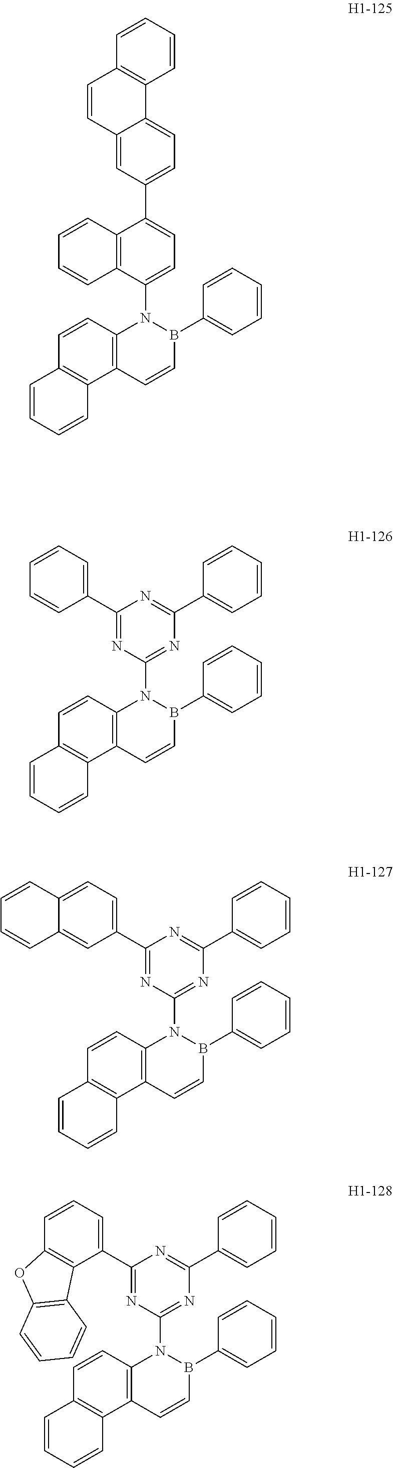 [SMILES: C1=Cc2c(ccc3ccccc23)N(c2ccc(-c3ccc4c(ccc5ccccc54)c3)c3ccccc23)B1c1ccccc1 ; C1=Cc2c(ccc3ccccc23)N(c2nc(-c3ccccc3)nc(-c3ccccc3)n2)B1c1ccccc1 ; C1=Cc2c(ccc3ccccc23)N(c2nc(-c3ccccc3)nc(-c3ccc4ccccc4c3)n2)B1c1ccccc1 ; C1=Cc2c(ccc3ccccc23)N(c2nc(-c3ccccc3)nc(-c3cccc4oc5ccccc5c34)n2)B1c1ccccc1]

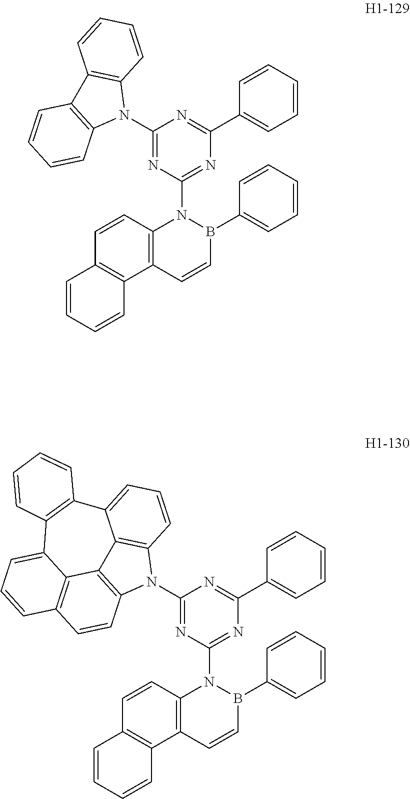 [SMILES: C1=Cc2c(ccc3ccccc23)N(c2nc(-c3ccccc3)nc(-n3c4ccccc4c4ccccc43)n2)B1c1ccccc1 ; C1=Cc2c(ccc3ccccc23)N(c2nc(-c3ccccc3)nc(-n3c4cccc5c4c4c6c(cccc6ccc43)-c3ccccc3-5)n2)B1c1ccccc1]

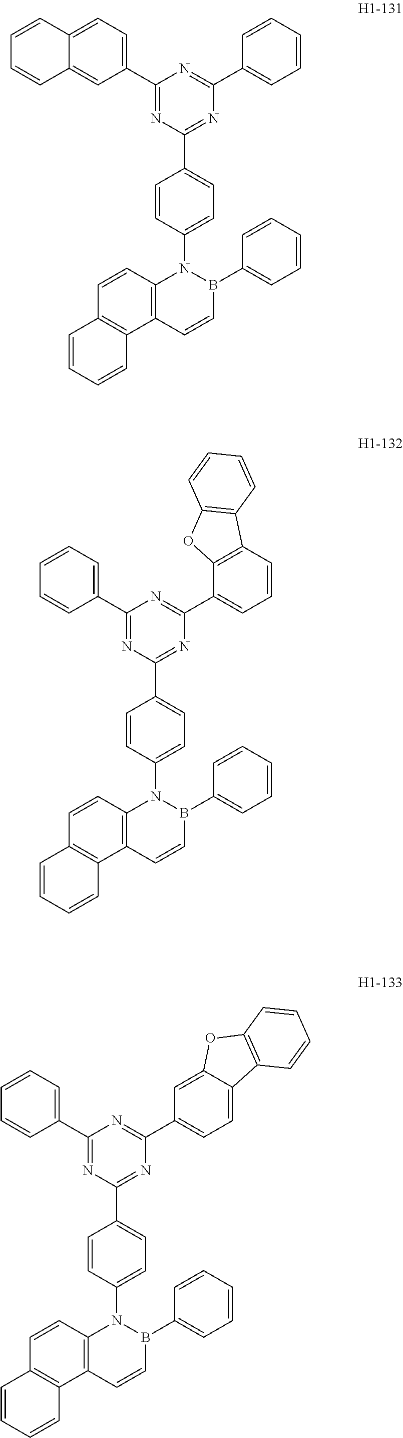 [SMILES: C1=Cc2c(ccc3ccccc23)N(c2ccc(-c3nc(-c4ccccc4)nc(-c4ccc5ccccc5c4)n3)cc2)B1c1ccccc1 ; C1=Cc2c(ccc3ccccc23)N(c2ccc(-c3nc(-c4ccccc4)nc(-c4cccc5c4oc4ccccc45)n3)cc2)B1c1ccccc1 ; C1=Cc2c(ccc3ccccc23)N(c2ccc(-c3nc(-c4ccccc4)nc(-c4ccc5c(c4)oc4ccccc45)n3)cc2)B1c1ccccc1]

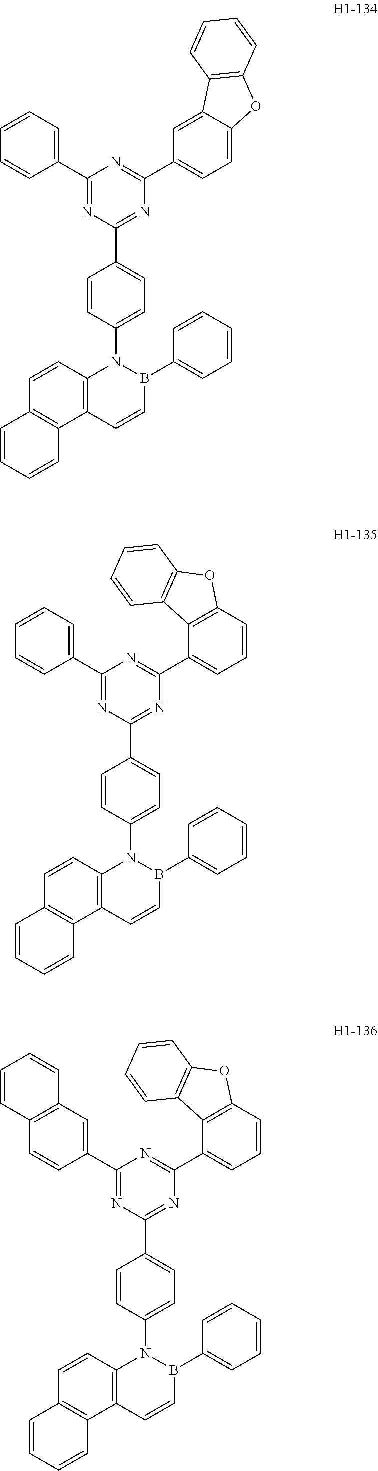 [SMILES: C1=Cc2c(ccc3ccccc23)N(c2ccc(-c3nc(-c4ccccc4)nc(-c4ccc5oc6ccccc6c5c4)n3)cc2)B1c1ccccc1 ; C1=Cc2c(ccc3ccccc23)N(c2ccc(-c3nc(-c4ccccc4)nc(-c4cccc5oc6ccccc6c45)n3)cc2)B1c1ccccc1 ; C1=Cc2c(ccc3ccccc23)N(c2ccc(-c3nc(-c4ccc5ccccc5c4)nc(-c4cccc5oc6ccccc6c45)n3)cc2)B1c1ccccc1]

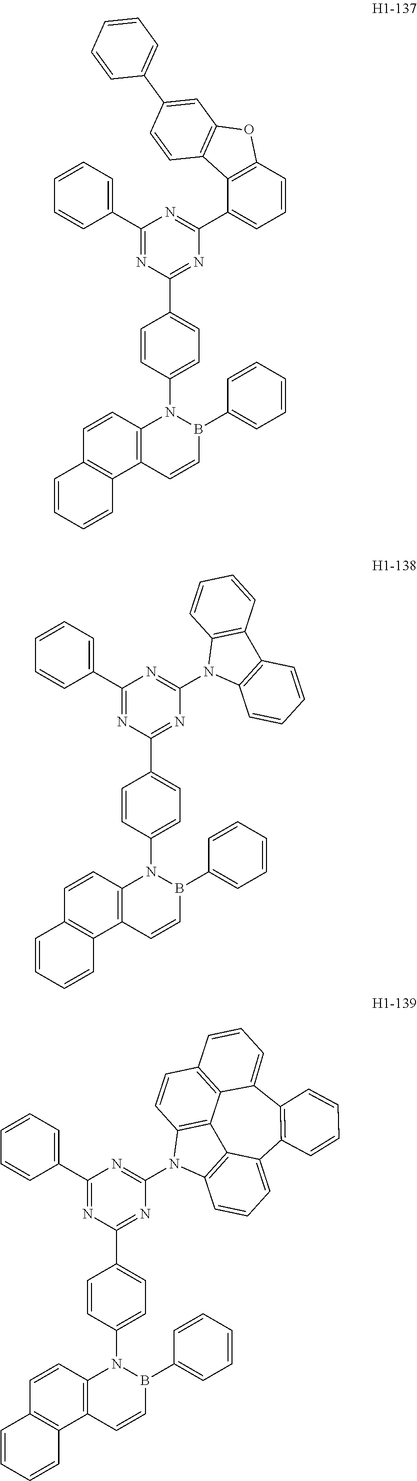 [SMILES: C1=Cc2c(ccc3ccccc23)N(c2ccc(-c3nc(-c4ccccc4)nc(-c4cccc5oc6cc(-c7ccccc7)ccc6c45)n3)cc2)B1c1ccccc1 ; C1=Cc2c(ccc3ccccc23)N(c2ccc(-c3nc(-c4ccccc4)nc(-n4c5ccccc5c5ccccc54)n3)cc2)B1c1ccccc1 ; C1=Cc2c(ccc3ccccc23)N(c2ccc(-c3nc(-c4ccccc4)nc(-n4c5cccc6c5c5c7c(cccc7ccc54)-c4ccccc4-6)n3)cc2)B1c1ccccc1]

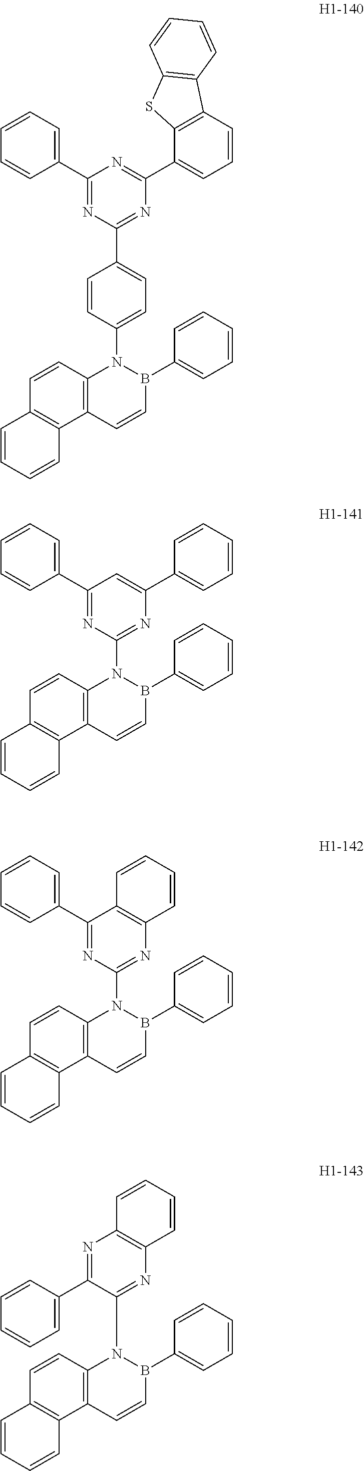

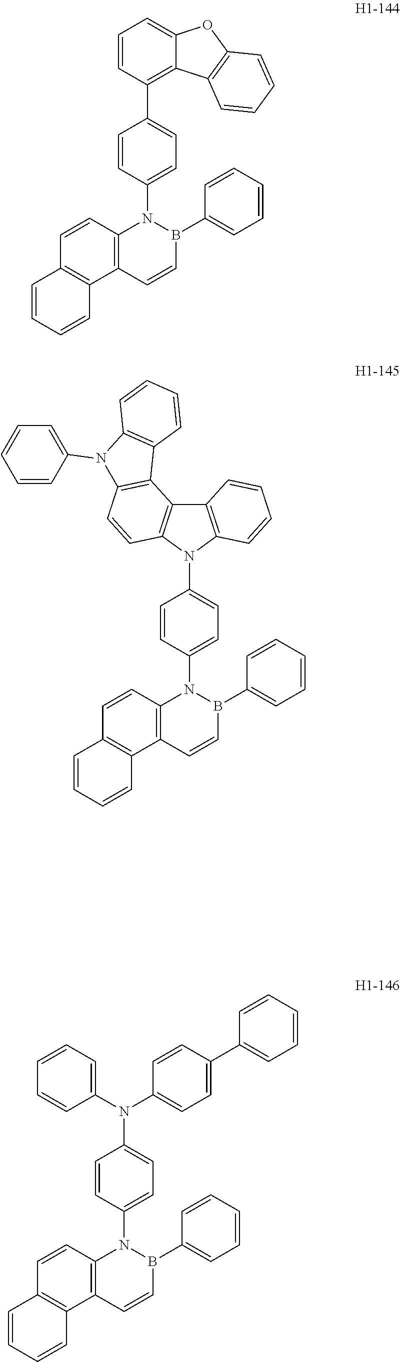 [SMILES: C1=Cc2c(ccc3ccccc23)N(c2ccc(-c3cccc4oc5ccccc5c34)cc2)B1c1ccccc1 ; C1=Cc2c(ccc3ccccc23)N(c2ccc(-n3c4ccccc4c4c5c6ccccc6n(-c6ccccc6)c5ccc43)cc2)B1c1ccccc1 ; C1=Cc2c(ccc3ccccc23)N(c2ccc(N(c3ccccc3)c3ccc(-c4ccccc4)cc3)cc2)B1c1ccccc1]

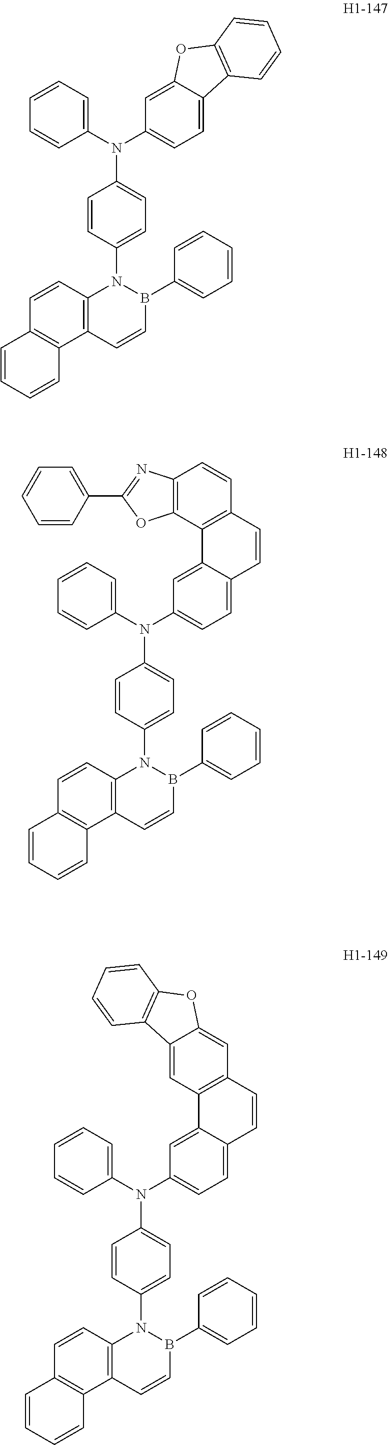 [SMILES: C1=Cc2c(ccc3ccccc23)N(c2ccc(N(c3ccccc3)c3ccc4c(c3)oc3ccccc34)cc2)B1c1ccccc1 ; C1=Cc2c(ccc3ccccc23)N(c2ccc(N(c3ccccc3)c3ccc4ccc5ccc6nc(-c7ccccc7)oc6c5c4c3)cc2)B1c1ccccc1 ; C1=Cc2c(ccc3ccccc23)N(c2ccc(N(c3ccccc3)c3ccc4ccc5cc6oc7ccccc7c6cc5c4c3)cc2)B1c1ccccc1]

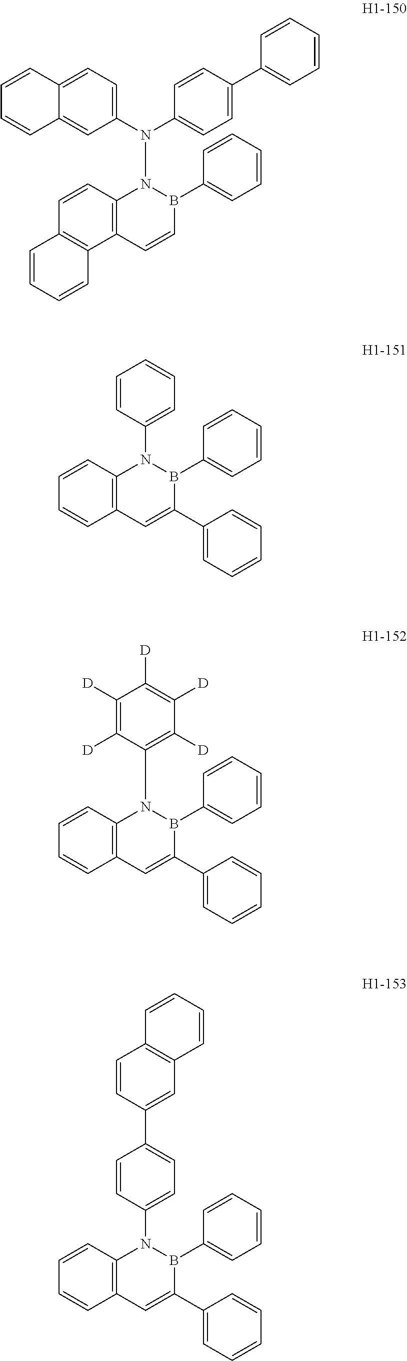 [SMILES: C1=Cc2c(ccc3ccccc23)N(N(c2ccc(-c3ccccc3)cc2)c2ccc3ccccc3c2)B1c1ccccc1 ; C1=C(c2ccccc2)B(c2ccccc2)N(c2ccccc2)c2ccccc21 ; [2H]c1c([2H])c([2H])c(N2B(c3ccccc3)C(c3ccccc3)=Cc3ccccc32)c([2H])c1[2H] ; C1=C(c2ccccc2)B(c2ccccc2)N(c2ccc(-c3ccc4ccccc4c3)cc2)c2ccccc21]

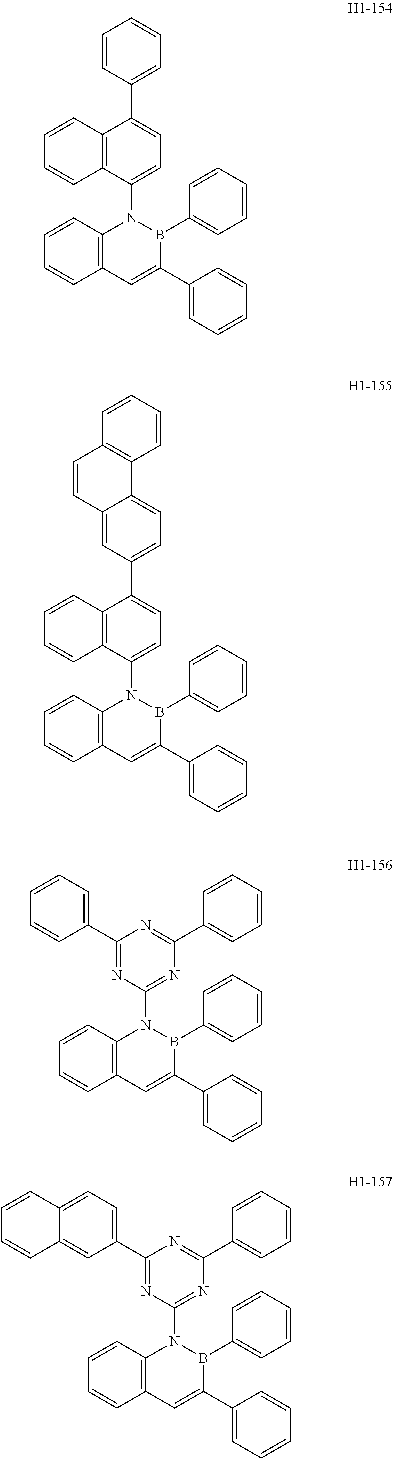 [SMILES: C1=C(c2ccccc2)B(c2ccccc2)N(c2ccc(-c3ccccc3)c3ccccc23)c2ccccc21 ; C1=C(c2ccccc2)B(c2ccccc2)N(c2ccc(-c3ccc4c(ccc5ccccc54)c3)c3ccccc23)c2ccccc21 ; C1=C(c2ccccc2)B(c2ccccc2)N(c2nc(-c3ccccc3)nc(-c3ccccc3)n2)c2ccccc21 ; C1=C(c2ccccc2)B(c2ccccc2)N(c2nc(-c3ccccc3)nc(-c3ccc4ccccc4c3)n2)c2ccccc21]

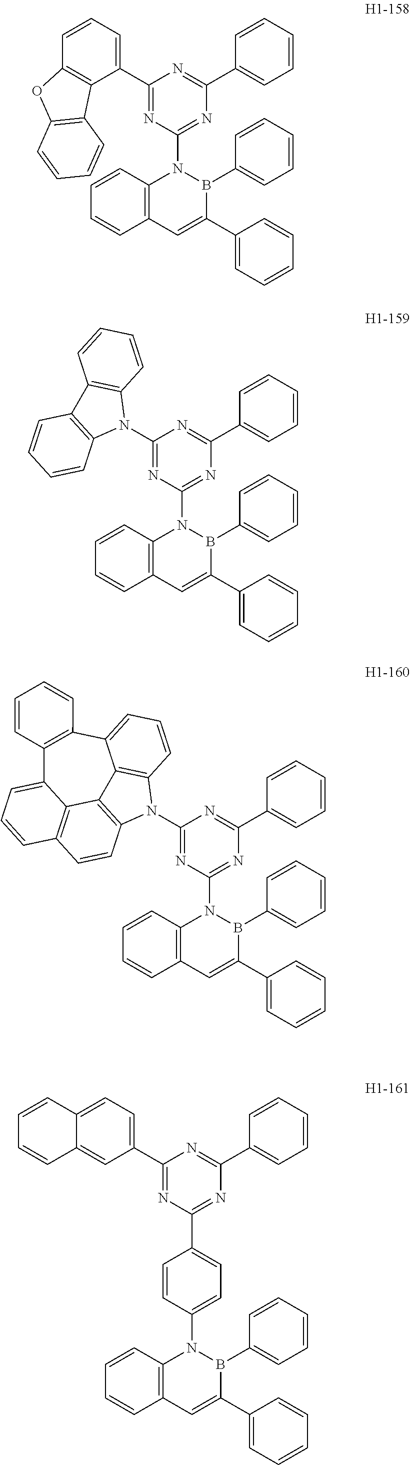 [SMILES: C1=C(c2ccccc2)B(c2ccccc2)N(c2nc(-c3ccccc3)nc(-c3cccc4oc5ccccc5c34)n2)c2ccccc21 ; C1=C(c2ccccc2)B(c2ccccc2)N(c2nc(-c3ccccc3)nc(-n3c4ccccc4c4ccccc43)n2)c2ccccc21 ; C1=C(c2ccccc2)B(c2ccccc2)N(c2nc(-c3ccccc3)nc(-n3c4cccc5c4c4c6c(cccc6ccc43)-c3ccccc3-5)n2)c2ccccc21 ; C1=C(c2ccccc2)B(c2ccccc2)N(c2ccc(-c3nc(-c4ccccc4)nc(-c4ccc5ccccc5c4)n3)cc2)c2ccccc21]

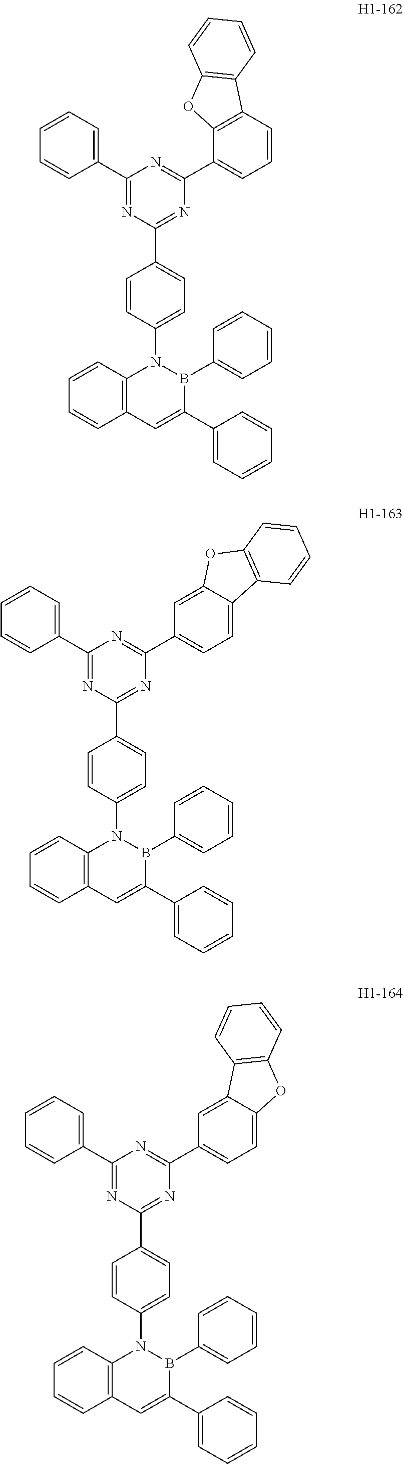 [SMILES: C1=C(c2ccccc2)B(c2ccccc2)N(c2ccc(-c3nc(-c4ccccc4)nc(-c4cccc5c4oc4ccccc45)n3)cc2)c2ccccc21 ; C1=C(c2ccccc2)B(c2ccccc2)N(c2ccc(-c3nc(-c4ccccc4)nc(-c4ccc5c(c4)oc4ccccc45)n3)cc2)c2ccccc21 ; C1=C(c2ccccc2)B(c2ccccc2)N(c2ccc(-c3nc(-c4ccccc4)nc(-c4ccc5oc6ccccc6c5c4)n3)cc2)c2ccccc21]

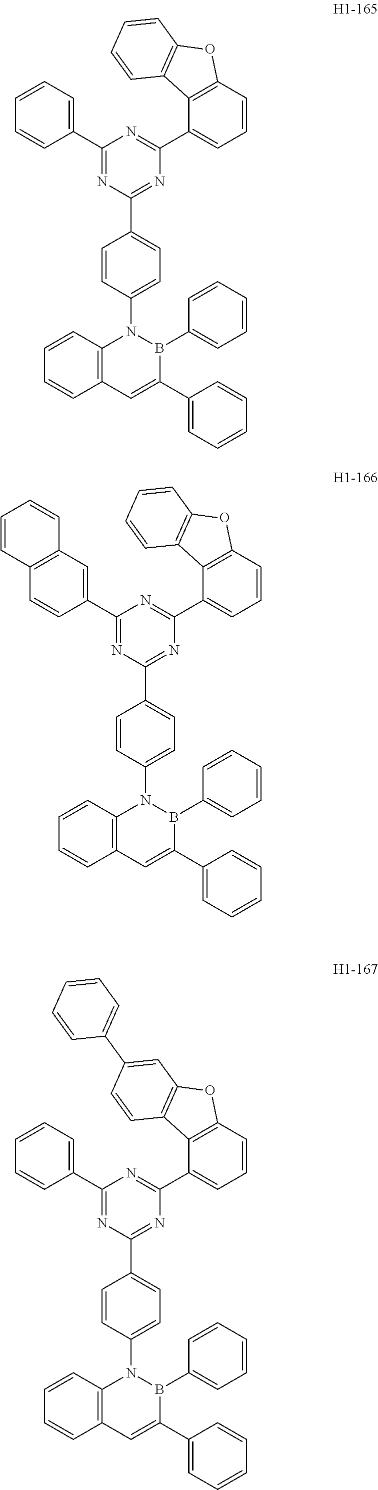 [SMILES: C1=C(c2ccccc2)B(c2ccccc2)N(c2ccc(-c3nc(-c4ccccc4)nc(-c4cccc5oc6ccccc6c45)n3)cc2)c2ccccc21 ; C1=C(c2ccccc2)B(c2ccccc2)N(c2ccc(-c3nc(-c4ccc5ccccc5c4)nc(-c4cccc5oc6ccccc6c45)n3)cc2)c2ccccc21 ; C1=C(c2ccccc2)B(c2ccccc2)N(c2ccc(-c3nc(-c4ccccc4)nc(-c4cccc5oc6cc(-c7ccccc7)ccc6c45)n3)cc2)c2ccccc21]

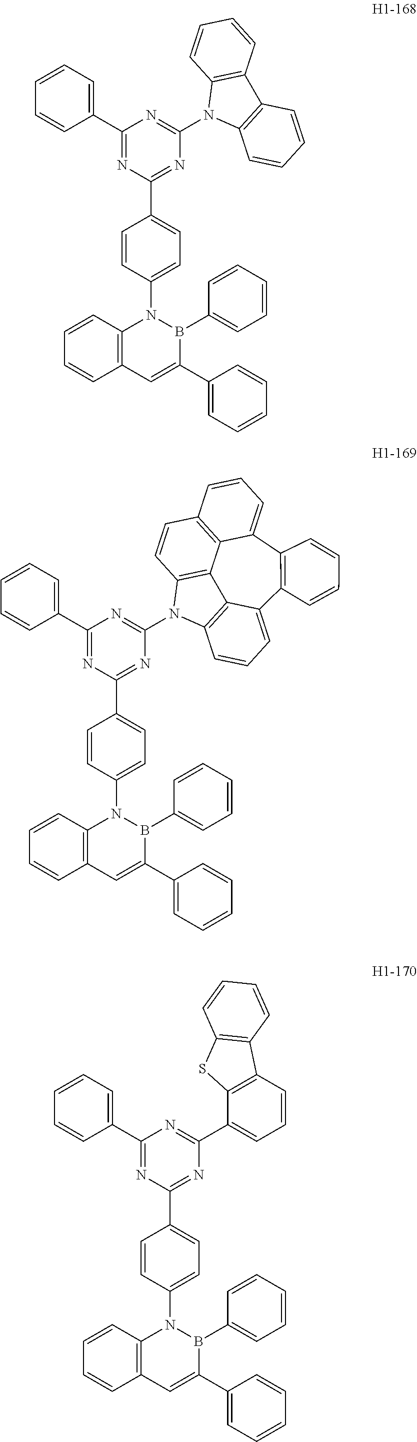

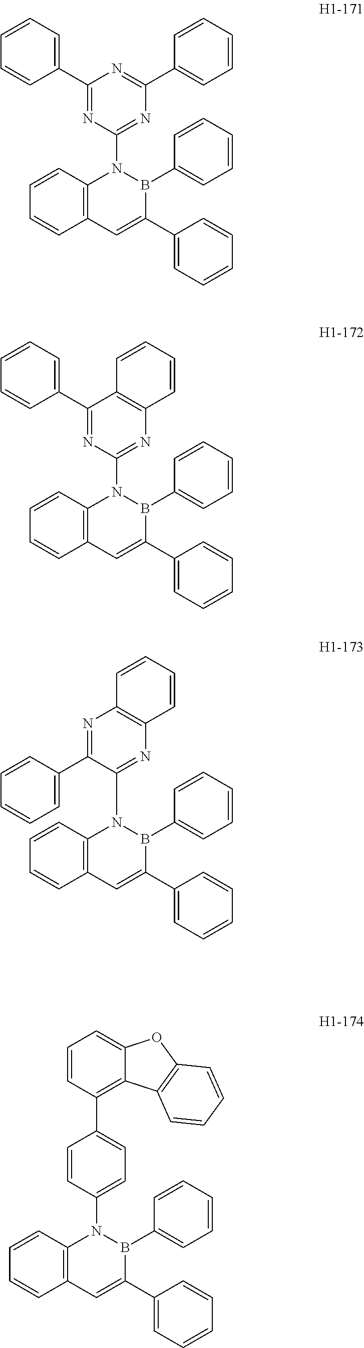 [SMILES: C1=C(c2ccccc2)B(c2ccccc2)N(c2nc(-c3ccccc3)nc(-c3ccccc3)n2)c2ccccc21 ; C1=C(c2ccccc2)B(c2ccccc2)N(c2nc(-c3ccccc3)c3ccccc3n2)c2ccccc21 ; C1=C(c2ccccc2)B(c2ccccc2)N(c2nc3ccccc3nc2-c2ccccc2)c2ccccc21 ; C1=C(c2ccccc2)B(c2ccccc2)N(c2ccc(-c3cccc4oc5ccccc5c34)cc2)c2ccccc21]

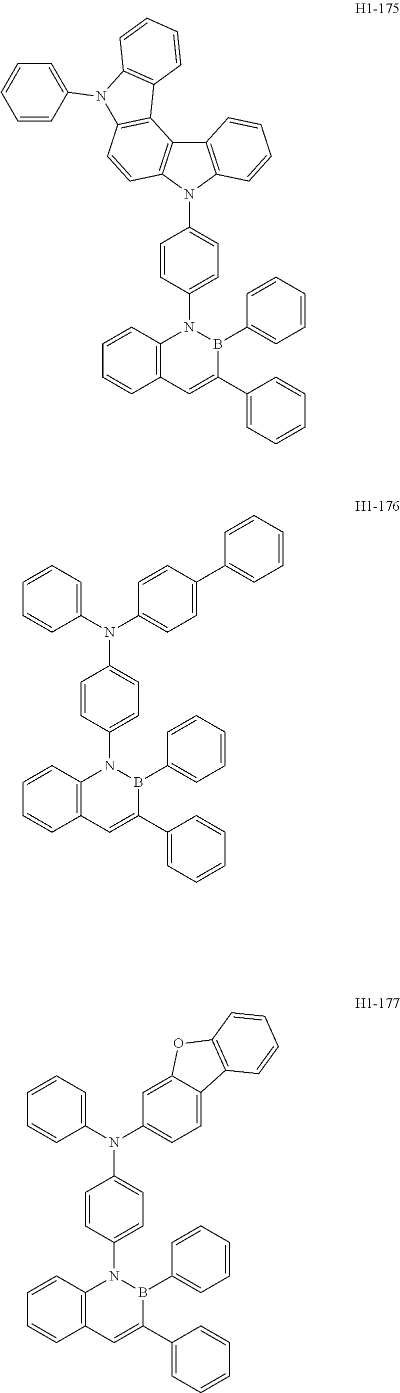 [SMILES: C1=C(c2ccccc2)B(c2ccccc2)N(c2ccc(-n3c4ccccc4c4c5c6ccccc6n(-c6ccccc6)c5ccc43)cc2)c2ccccc21 ; C1=C(c2ccccc2)B(c2ccccc2)N(c2ccc(N(c3ccccc3)c3ccc(-c4ccccc4)cc3)cc2)c2ccccc21 ; C1=C(c2ccccc2)B(c2ccccc2)N(c2ccc(N(c3ccccc3)c3ccc4c(c3)oc3ccccc34)cc2)c2ccccc21]

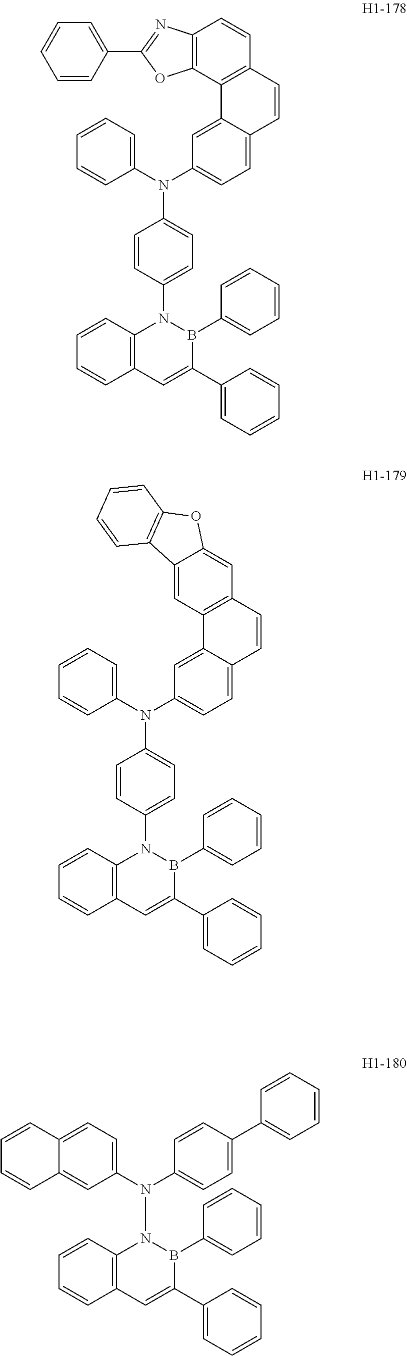 [SMILES: C1=C(c2ccccc2)B(c2ccccc2)N(c2ccc(N(c3ccccc3)c3ccc4ccc5ccc6nc(-c7ccccc7)oc6c5c4c3)cc2)c2ccccc21 ; C1=C(c2ccccc2)B(c2ccccc2)N(c2ccc(N(c3ccccc3)c3ccc4ccc5cc6oc7ccccc7c6cc5c4c3)cc2)c2ccccc21 ; C1=C(c2ccccc2)B(c2ccccc2)N(N(c2ccc(-c3ccccc3)cc2)c2ccc3ccccc3c2)c2ccccc21]

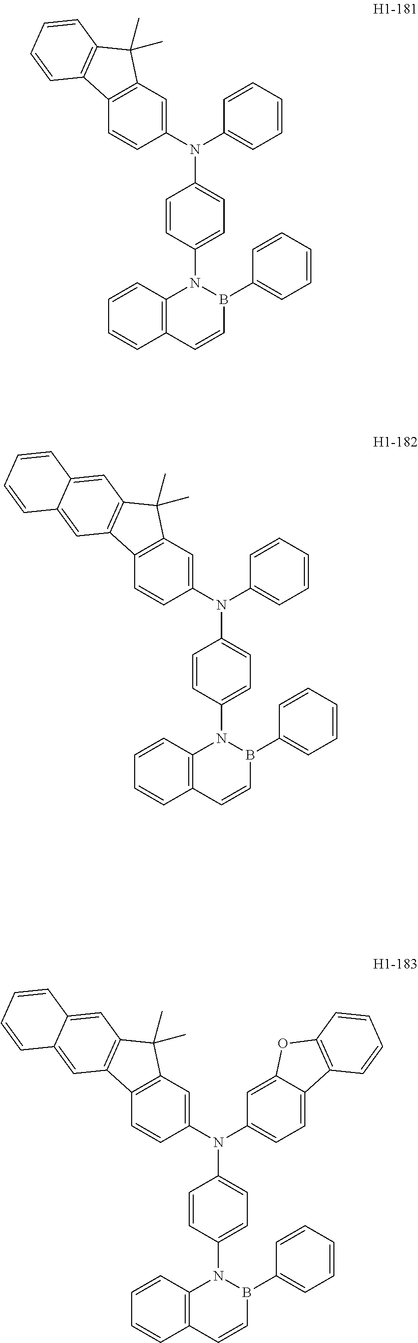 [SMILES: CC1(C)c2ccccc2-c2ccc(N(c3ccccc3)c3ccc(N4B(c5ccccc5)C=Cc5ccccc54)cc3)cc21 ; CC1(C)c2cc(N(c3ccccc3)c3ccc(N4B(c5ccccc5)C=Cc5ccccc54)cc3)ccc2-c2cc3ccccc3cc21 ; CC1(C)c2cc(N(c3ccc(N4B(c5ccccc5)C=Cc5ccccc54)cc3)c3ccc4c(c3)oc3ccccc34)ccc2-c2cc3ccccc3cc21]

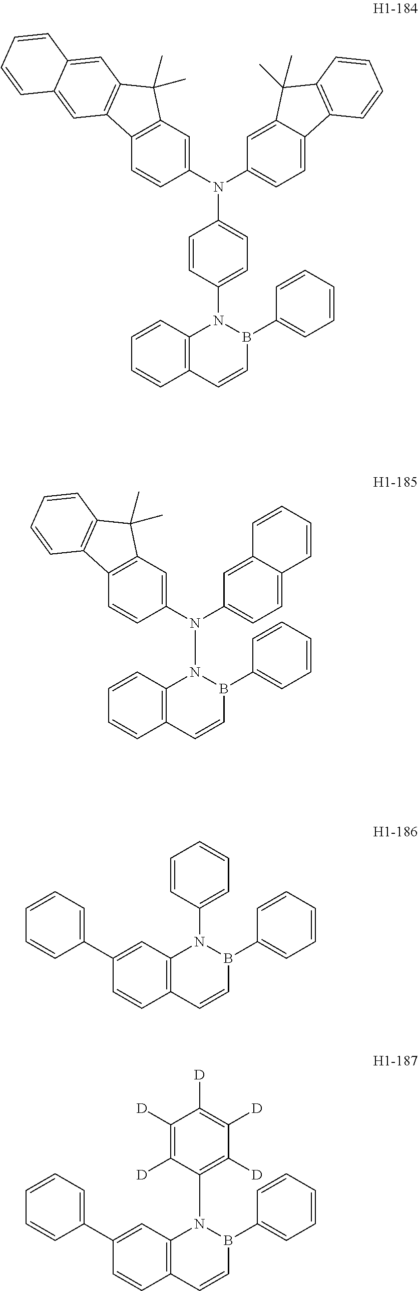 [SMILES: CC1(C)c2ccccc2-c2ccc(N(c3ccc(N4B(c5ccccc5)C=Cc5ccccc54)cc3)c3ccc4c(c3)C(C)(C)c3cc5ccccc5cc3-4)cc21 ; CC1(C)c2ccccc2-c2ccc(N(c3ccc4ccccc4c3)N3B(c4ccccc4)C=Cc4ccccc43)cc21 ; C1=Cc2ccc(-c3ccccc3)cc2N(c2ccccc2)B1c1ccccc1 ; [2H]c1c([2H])c([2H])c(N2B(c3ccccc3)C=Cc3ccc(-c4ccccc4)cc32)c([2H])c1[2H]]

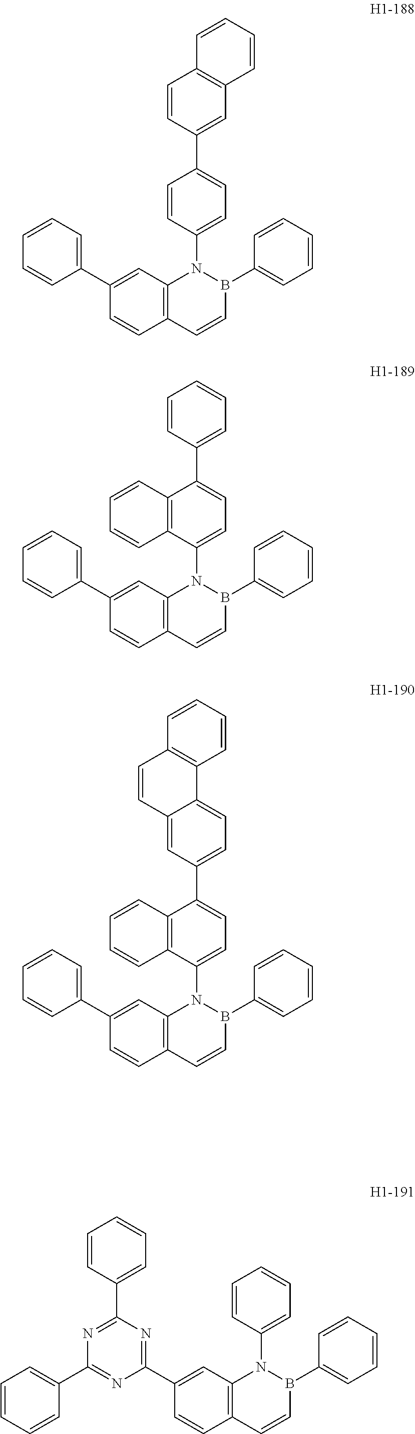

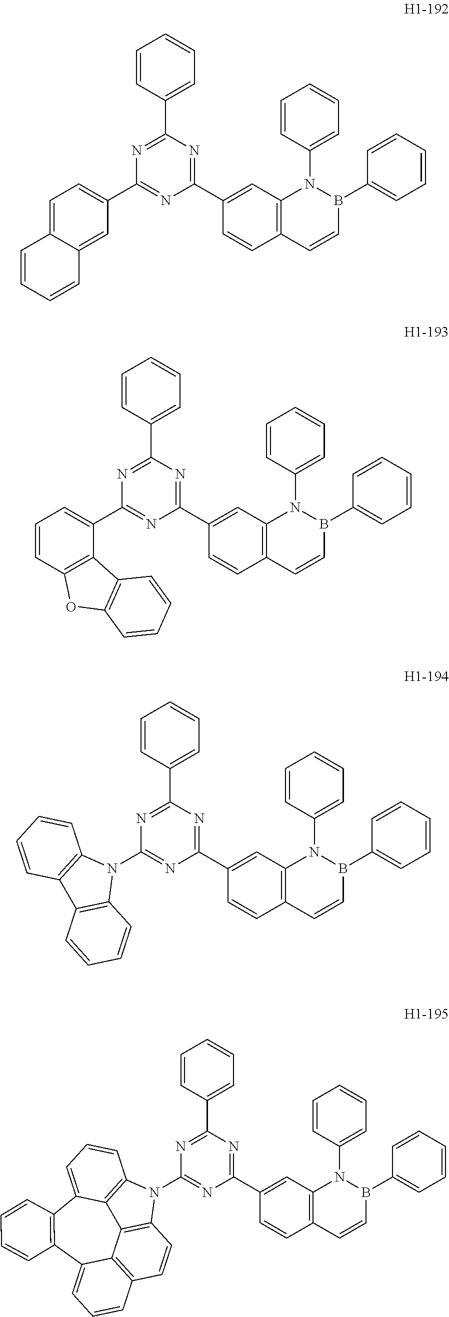 [SMILES: C1=Cc2ccc(-c3nc(-c4ccccc4)nc(-c4ccc5ccccc5c4)n3)cc2N(c2ccccc2)B1c1ccccc1 ; C1=Cc2ccc(-c3nc(-c4ccccc4)nc(-c4cccc5oc6ccccc6c45)n3)cc2N(c2ccccc2)B1c1ccccc1 ; C1=Cc2ccc(-c3nc(-c4ccccc4)nc(-n4c5ccccc5c5ccccc54)n3)cc2N(c2ccccc2)B1c1ccccc1 ; C1=Cc2ccc(-c3nc(-c4ccccc4)nc(-n4c5cccc6c5c5c7c(cccc7ccc54)-c4ccccc4-6)n3)cc2N(c2ccccc2)B1c1ccccc1]

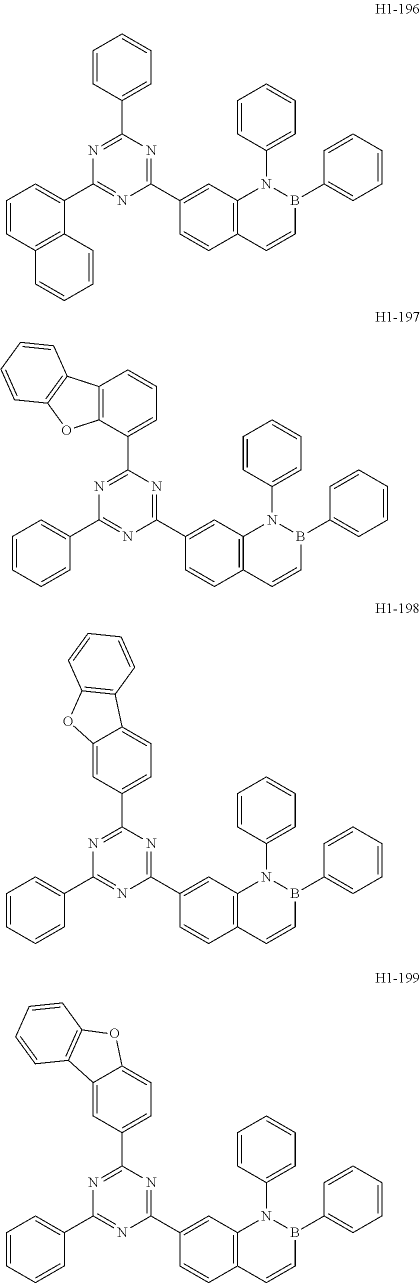

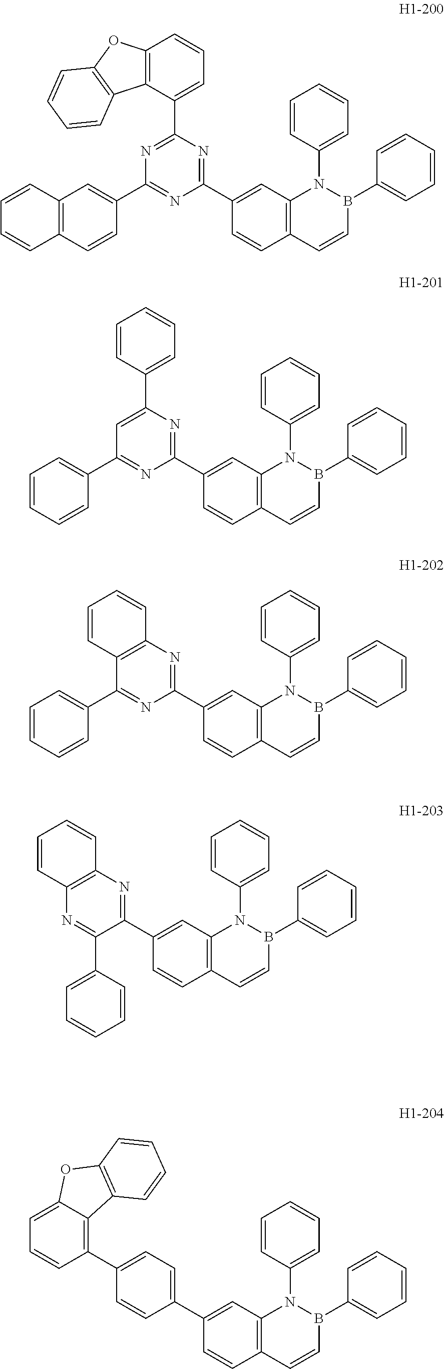 [SMILES: C1=Cc2ccc(-c3nc(-c4ccc5ccccc5c4)nc(-c4cccc5oc6ccccc6c45)n3)cc2N(c2ccccc2)B1c1ccccc1 ; C1=Cc2ccc(-c3nc(-c4ccccc4)cc(-c4ccccc4)n3)cc2N(c2ccccc2)B1c1ccccc1 ; C1=Cc2ccc(-c3nc(-c4ccccc4)c4ccccc4n3)cc2N(c2ccccc2)B1c1ccccc1 ; C1=Cc2ccc(-c3nc4ccccc4nc3-c3ccccc3)cc2N(c2ccccc2)B1c1ccccc1 ; C1=Cc2ccc(-c3ccc(-c4cccc5oc6ccccc6c45)cc3)cc2N(c2ccccc2)B1c1ccccc1]

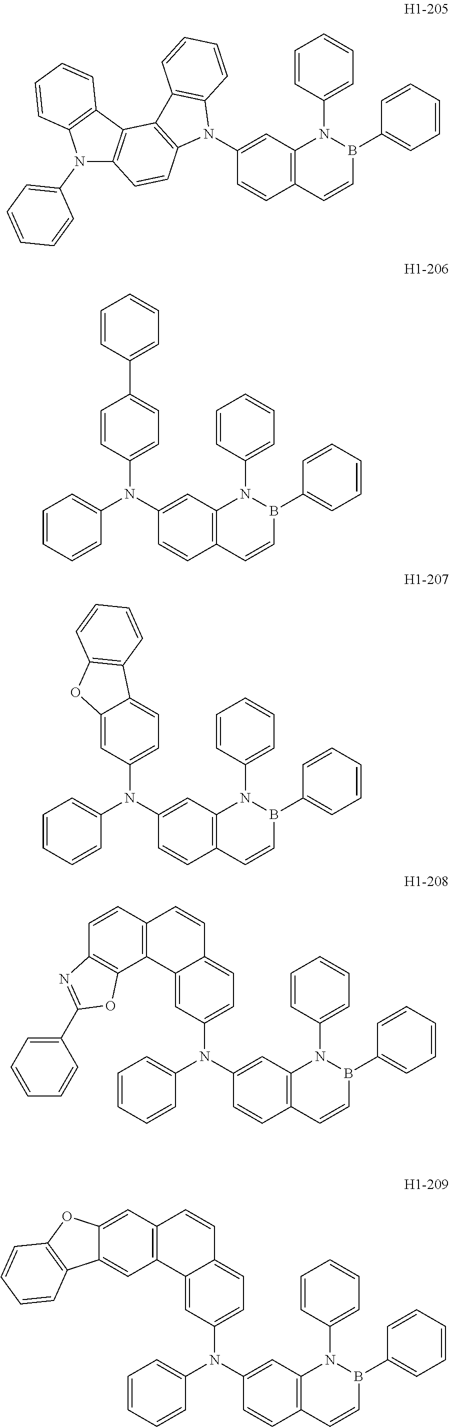

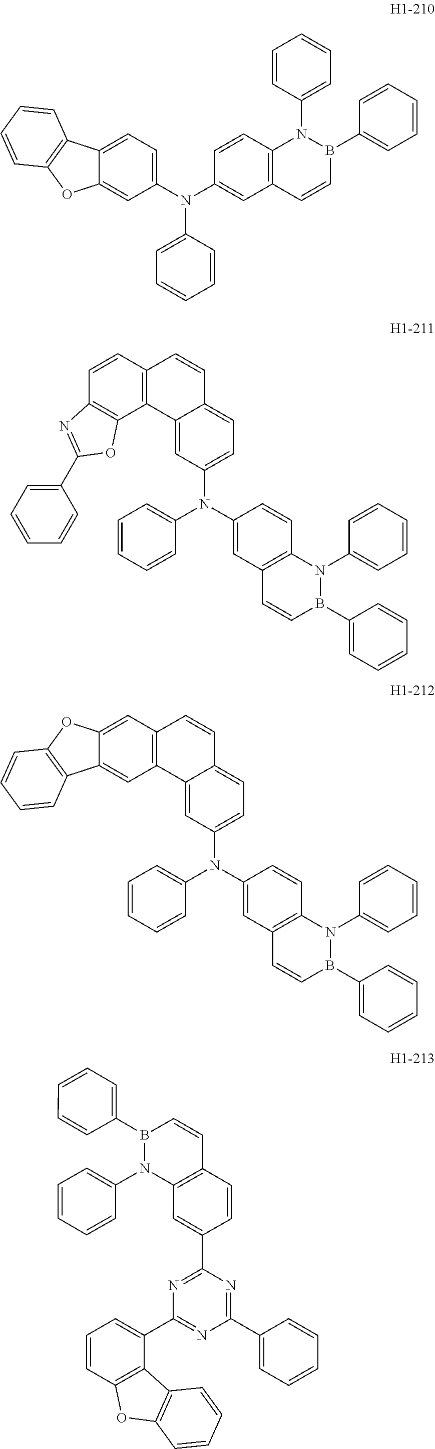 [SMILES: C1=Cc2cc(N(c3ccccc3)c3ccc4c(c3)oc3ccccc34)ccc2N(c2ccccc2)B1c1ccccc1 ; C1=Cc2cc(N(c3ccccc3)c3ccc4ccc5ccc6nc(-c7ccccc7)oc6c5c4c3)ccc2N(c2ccccc2)B1c1ccccc1 ; C1=Cc2cc(N(c3ccccc3)c3ccc4ccc5cc6oc7ccccc7c6cc5c4c3)ccc2N(c2ccccc2)B1c1ccccc1 ; C1=Cc2ccc(-c3nc(-c4ccccc4)nc(-c4cccc5oc6ccccc6c45)n3)cc2N(c2ccccc2)B1c1ccccc1]

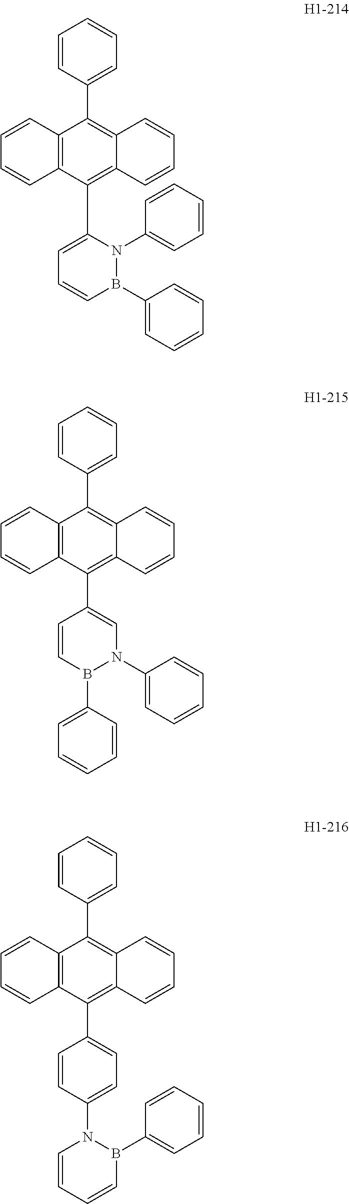 [SMILES: C1=CB(c2ccccc2)N(c2ccccc2)C(c2c3ccccc3c(-c3ccccc3)c3ccccc23)=C1 ; C1=CC(c2c3ccccc3c(-c3ccccc3)c3ccccc23)=CN(c2ccccc2)B1c1ccccc1 ; C1=CB(c2ccccc2)N(c2ccc(-c3c4ccccc4c(-c4ccccc4)c4ccccc34)cc2)C=C1]

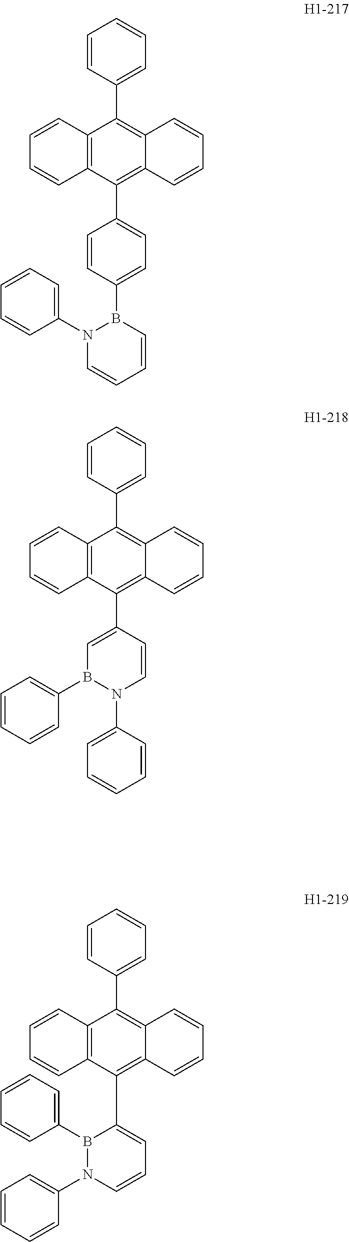

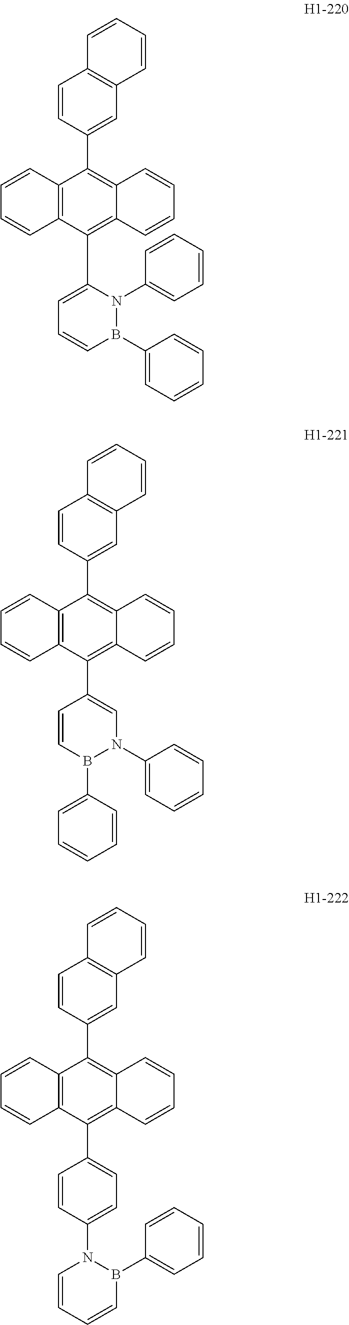 [SMILES: C1=CB(c2ccccc2)N(c2ccccc2)C(c2c3ccccc3c(-c3ccc4ccccc4c3)c3ccccc23)=C1 ; C1=CC(c2c3ccccc3c(-c3ccc4ccccc4c3)c3ccccc23)=CN(c2ccccc2)B1c1ccccc1 ; C1=CB(c2ccccc2)N(c2ccc(-c3c4ccccc4c(-c4ccc5ccccc5c4)c4ccccc34)cc2)C=C1]

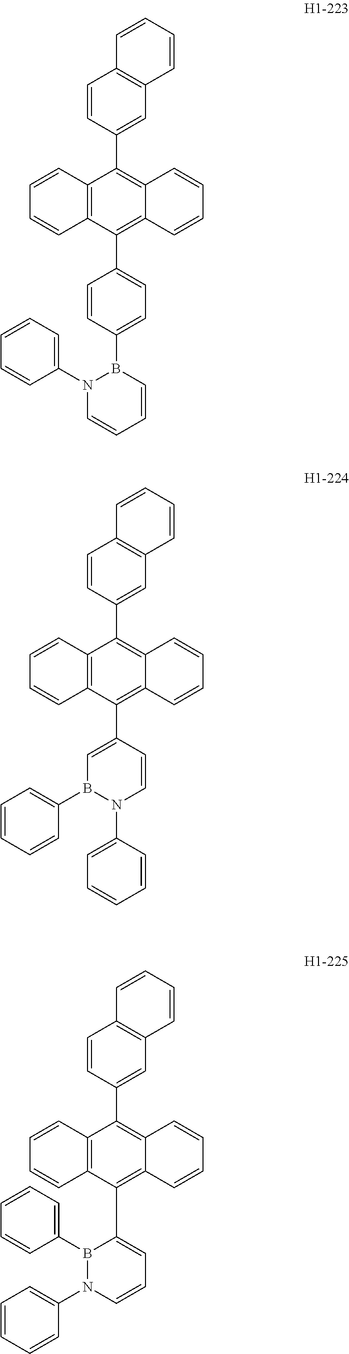 [SMILES: C1=CB(c2ccc(-c3c4ccccc4c(-c4ccc5ccccc5c4)c4ccccc34)cc2)N(c2ccccc2)C=C1 ; C1=CN(c2ccccc2)B(c2ccccc2)C=C1c1c2ccccc2c(-c2ccc3ccccc3c2)c2ccccc12 ; C1=CN(c2ccccc2)B(c2ccccc2)C(c2c3ccccc3c(-c3ccc4ccccc4c3)c3ccccc23)=C1]

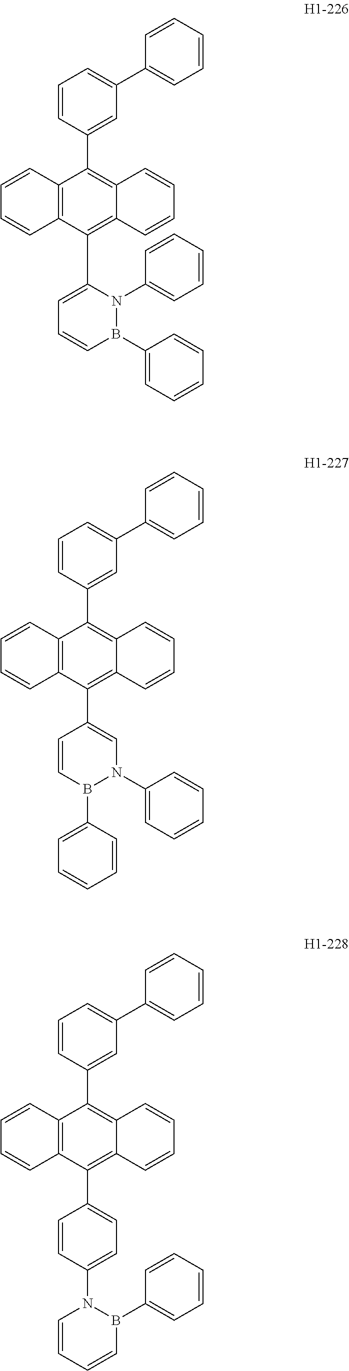 [SMILES: C1=CB(c2ccccc2)N(c2ccccc2)C(c2c3ccccc3c(-c3cccc(-c4ccccc4)c3)c3ccccc23)=C1 ; C1=CC(c2c3ccccc3c(-c3cccc(-c4ccccc4)c3)c3ccccc23)=CN(c2ccccc2)B1c1ccccc1 ; C1=CB(c2ccccc2)N(c2ccc(-c3c4ccccc4c(-c4cccc(-c5ccccc5)c4)c4ccccc34)cc2)C=C1]

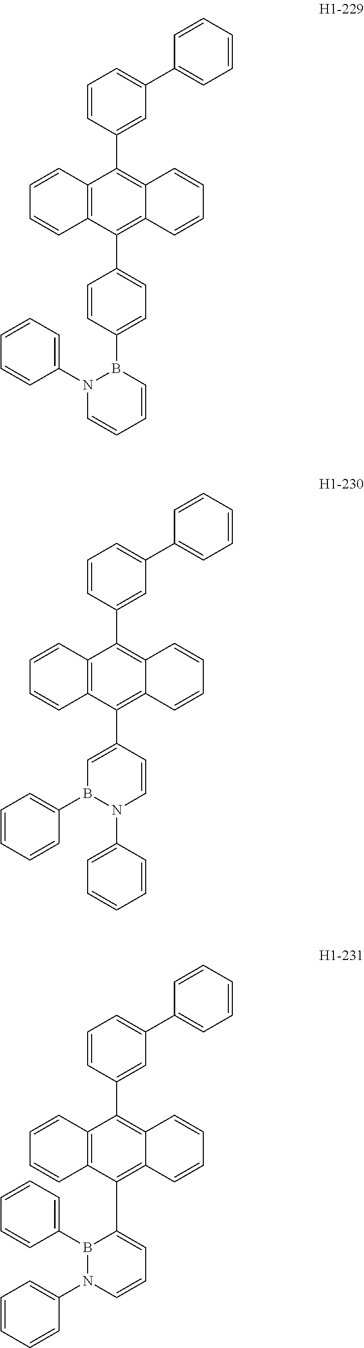 [SMILES: C1=CB(c2ccc(-c3c4ccccc4c(-c4cccc(-c5ccccc5)c4)c4ccccc34)cc2)N(c2ccccc2)C=C1 ; C1=CN(c2ccccc2)B(c2ccccc2)C=C1c1c2ccccc2c(-c2cccc(-c3ccccc3)c2)c2ccccc12 ; C1=CN(c2ccccc2)B(c2ccccc2)C(c2c3ccccc3c(-c3cccc(-c4ccccc4)c3)c3ccccc23)=C1]

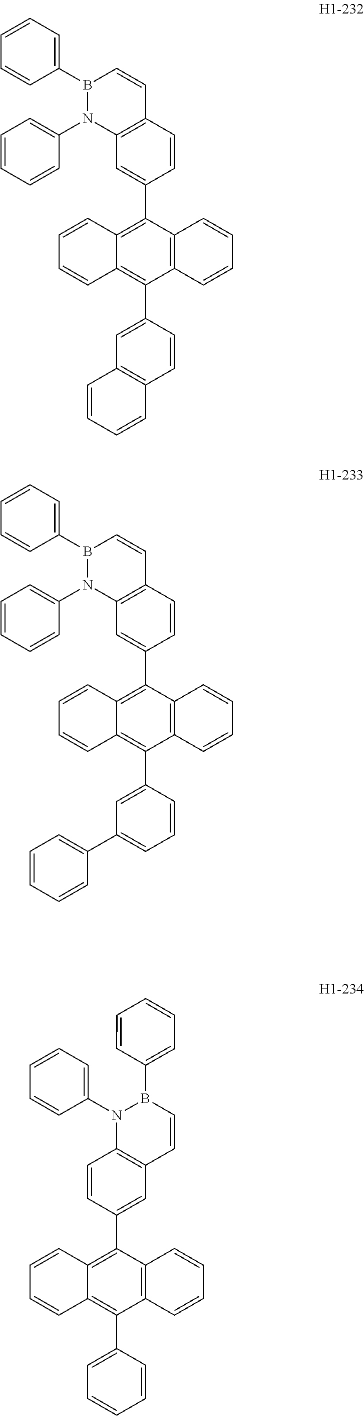 [SMILES: C1=Cc2ccc(-c3c4ccccc4c(-c4ccc5ccccc5c4)c4ccccc34)cc2N(c2ccccc2)B1c1ccccc1 ; C1=Cc2ccc(-c3c4ccccc4c(-c4cccc(-c5ccccc5)c4)c4ccccc34)cc2N(c2ccccc2)B1c1ccccc1 ; C1=Cc2cc(-c3c4ccccc4c(-c4ccccc4)c4ccccc34)ccc2N(c2ccccc2)B1c1ccccc1]

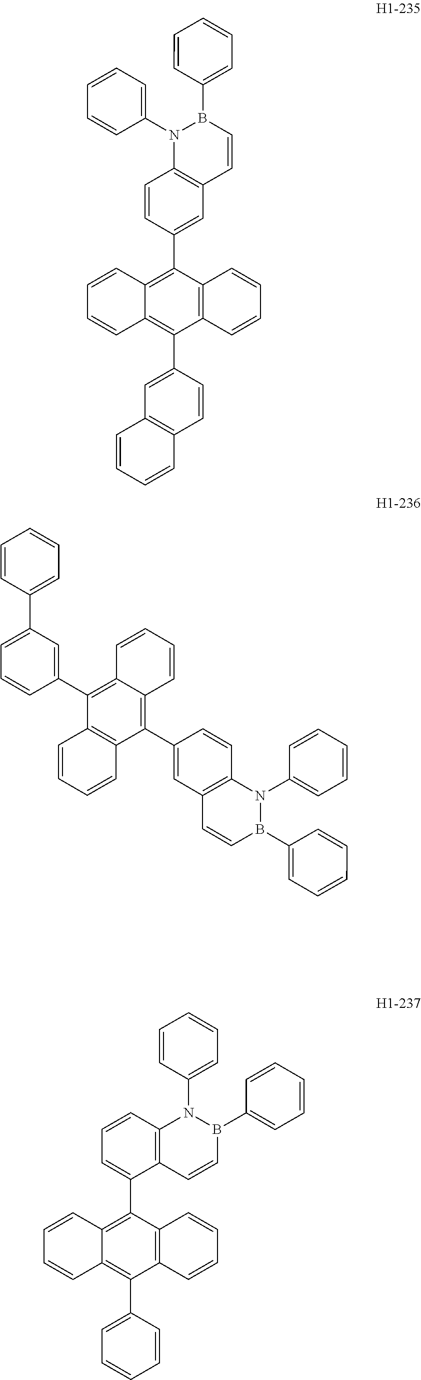 [SMILES: C1=Cc2cc(-c3c4ccccc4c(-c4ccc5ccccc5c4)c4ccccc34)ccc2N(c2ccccc2)B1c1ccccc1 ; C1=Cc2cc(-c3c4ccccc4c(-c4cccc(-c5ccccc5)c4)c4ccccc34)ccc2N(c2ccccc2)B1c1ccccc1 ; C1=Cc2c(-c3c4ccccc4c(-c4ccccc4)c4ccccc34)cccc2N(c2ccccc2)B1c1ccccc1]

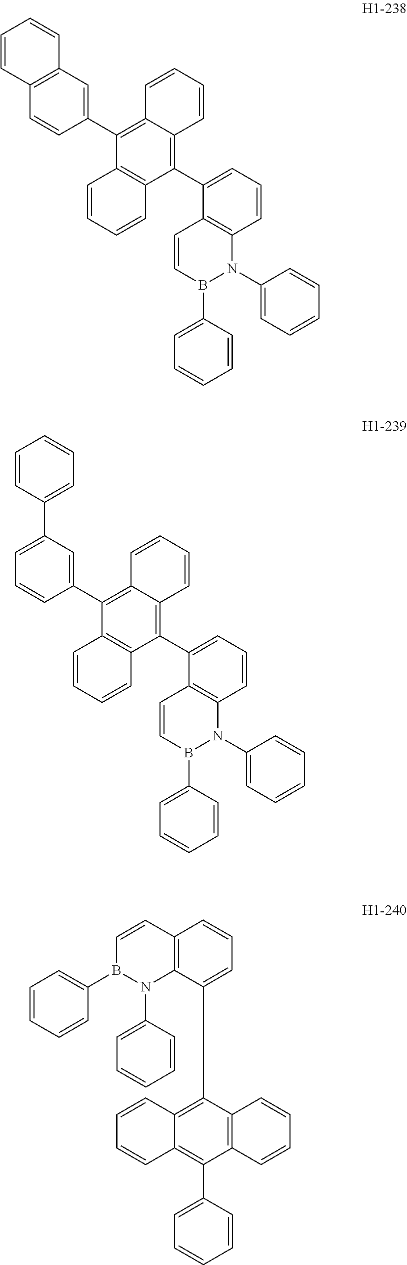 [SMILES: C1=Cc2c(-c3c4ccccc4c(-c4ccc5ccccc5c4)c4ccccc34)cccc2N(c2ccccc2)B1c1ccccc1 ; C1=Cc2c(-c3c4ccccc4c(-c4cccc(-c5ccccc5)c4)c4ccccc34)cccc2N(c2ccccc2)B1c1ccccc1 ; C1=Cc2cccc(-c3c4ccccc4c(-c4ccccc4)c4ccccc34)c2N(c2ccccc2)B1c1ccccc1]

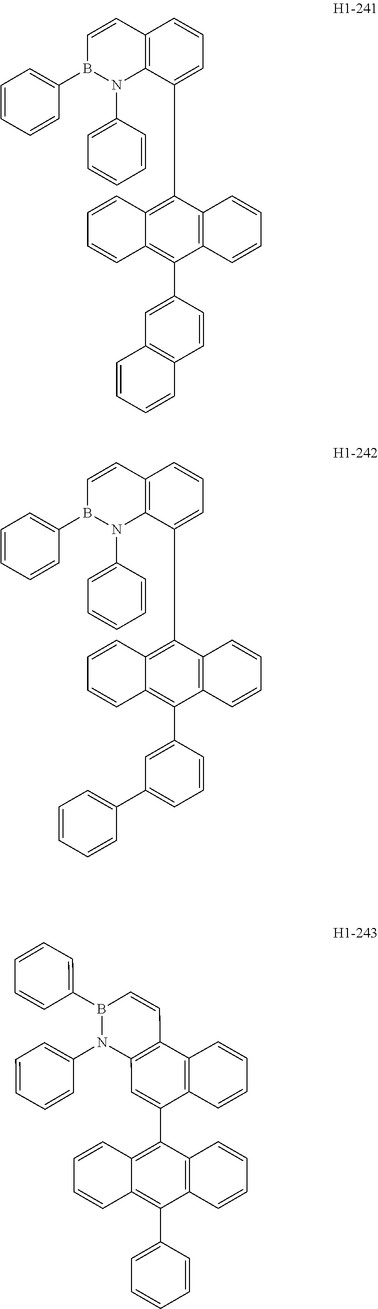 [SMILES: C1=Cc2cccc(-c3c4ccccc4c(-c4ccc5ccccc5c4)c4ccccc34)c2N(c2ccccc2)B1c1ccccc1 ; C1=Cc2cccc(-c3c4ccccc4c(-c4cccc(-c5ccccc5)c4)c4ccccc34)c2N(c2ccccc2)B1c1ccccc1 ; C1=Cc2c(cc(-c3c4ccccc4c(-c4ccccc4)c4ccccc34)c3ccccc23)N(c2ccccc2)B1c1ccccc1]

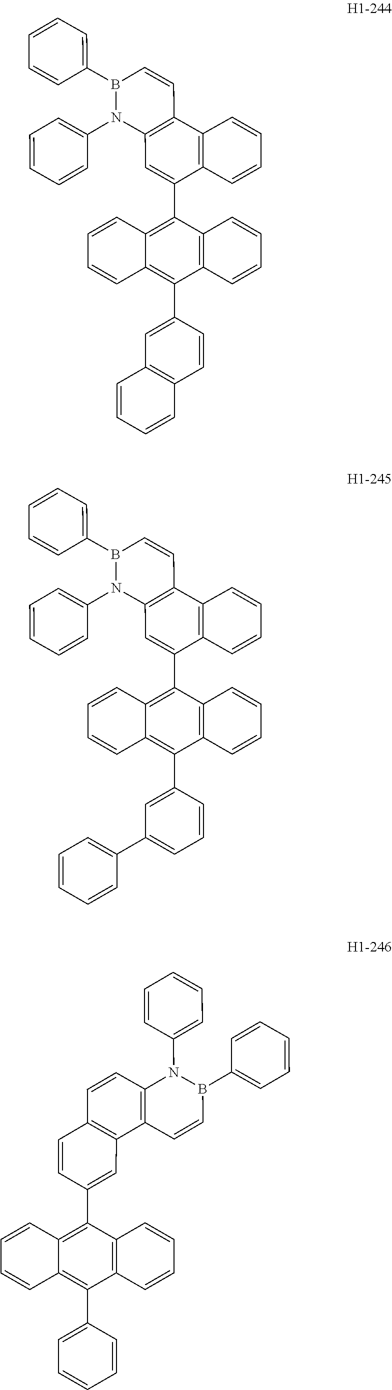 [SMILES: C1=Cc2c(cc(-c3c4ccccc4c(-c4ccc5ccccc5c4)c4ccccc34)c3ccccc23)N(c2ccccc2)B1c1ccccc1 ; C1=Cc2c(cc(-c3c4ccccc4c(-c4cccc(-c5ccccc5)c4)c4ccccc34)c3ccccc23)N(c2ccccc2)B1c1ccccc1 ; C1=Cc2c(ccc3ccc(-c4c5ccccc5c(-c5ccccc5)c5ccccc45)cc23)N(c2ccccc2)B1c1ccccc1]

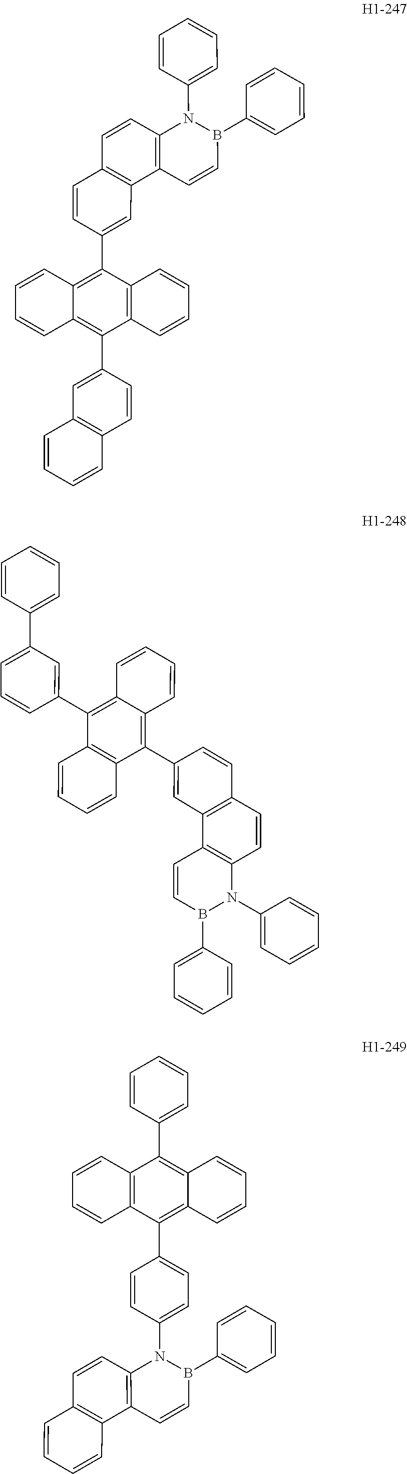 [SMILES: C1=Cc2c(ccc3ccc(-c4c5ccccc5c(-c5ccc6ccccc6c5)c5ccccc45)cc23)N(c2ccccc2)B1c1ccccc1 ; C1=Cc2c(ccc3ccc(-c4c5ccccc5c(-c5cccc(-c6ccccc6)c5)c5ccccc45)cc23)N(c2ccccc2)B1c1ccccc1 ; C1=Cc2c(ccc3ccccc23)N(c2ccc(-c3c4ccccc4c(-c4ccccc4)c4ccccc34)cc2)B1c1ccccc1]

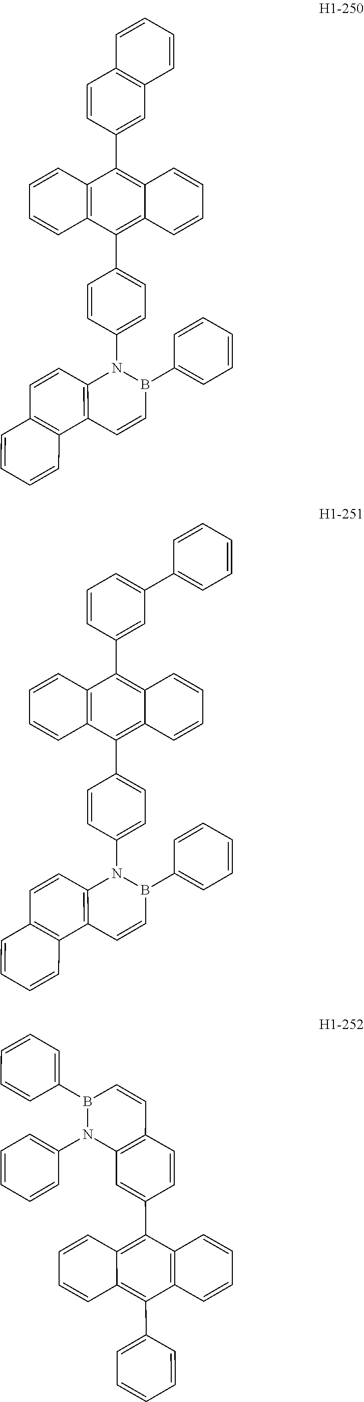

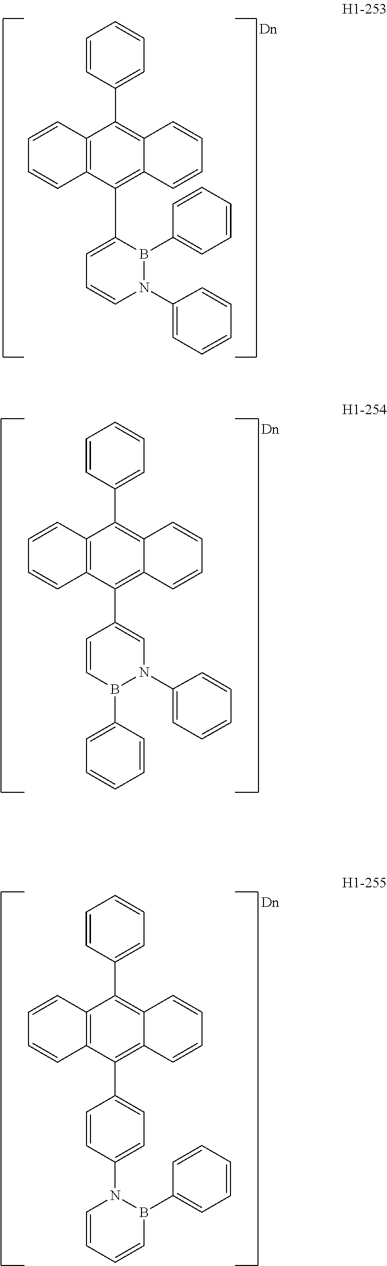

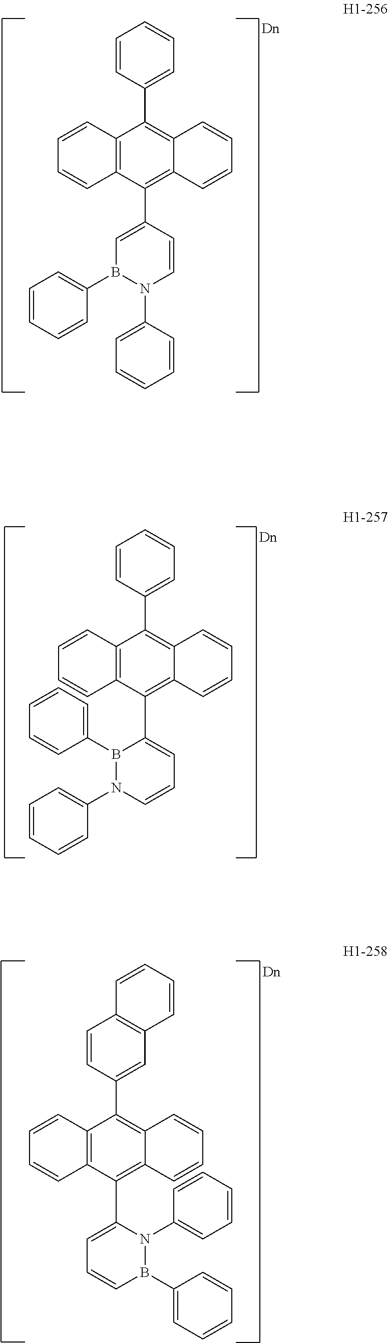

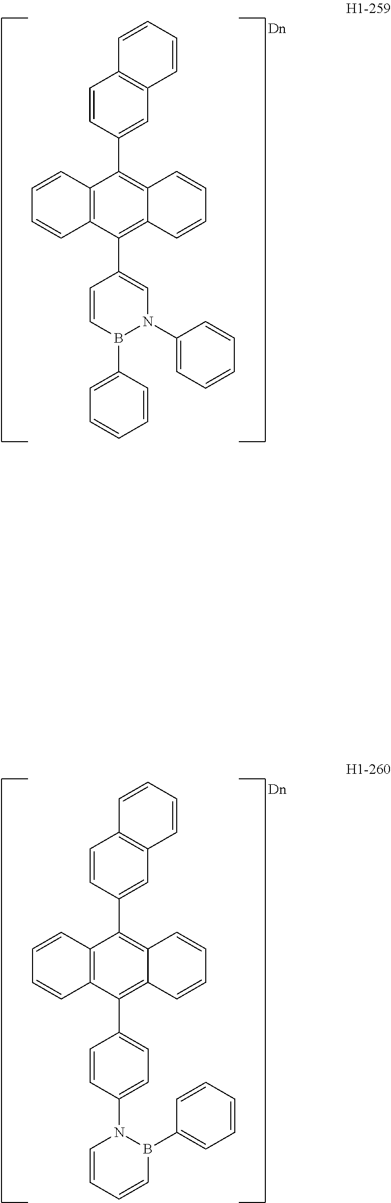

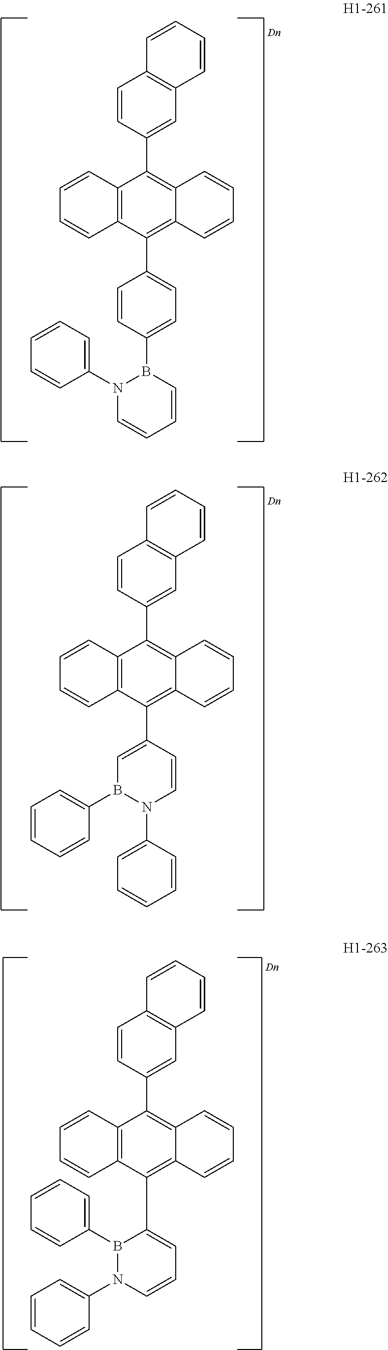

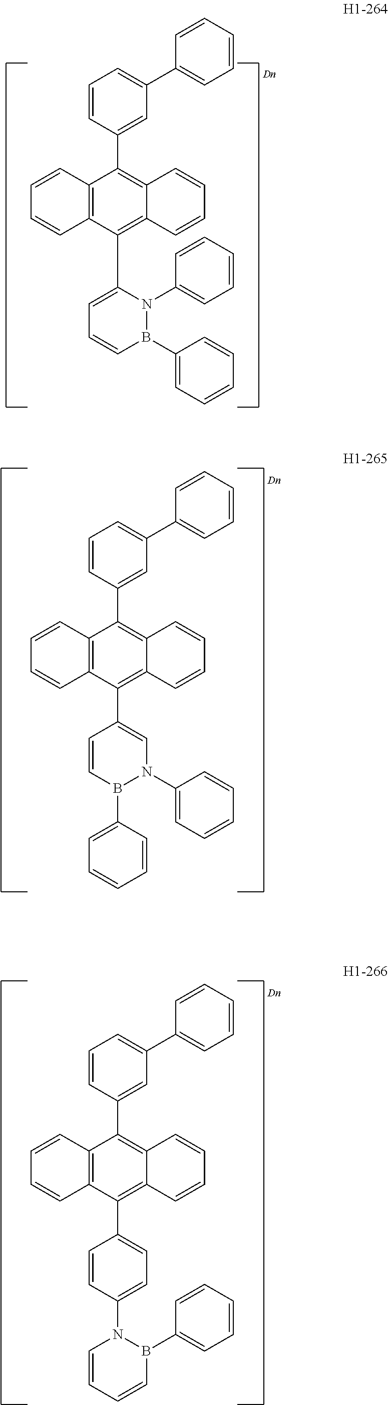

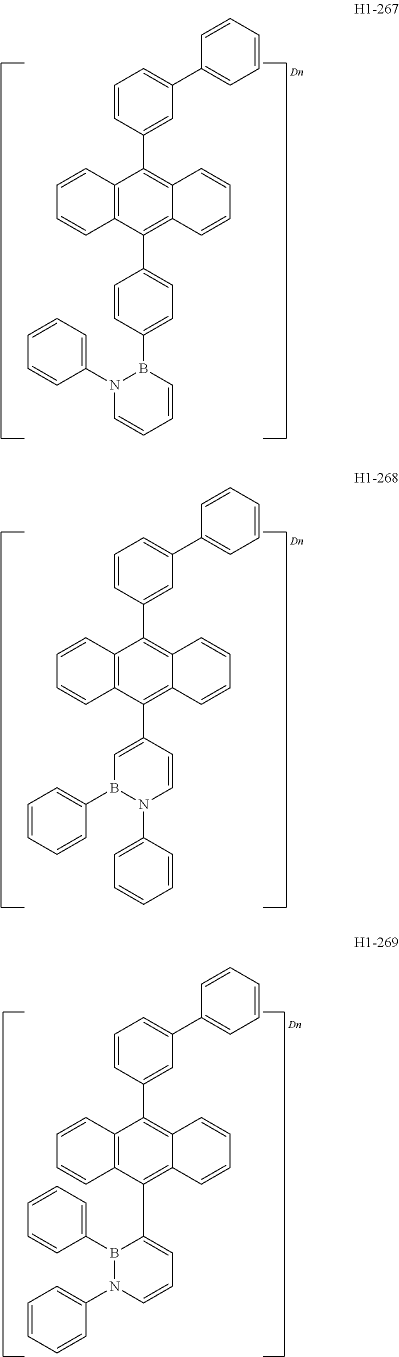

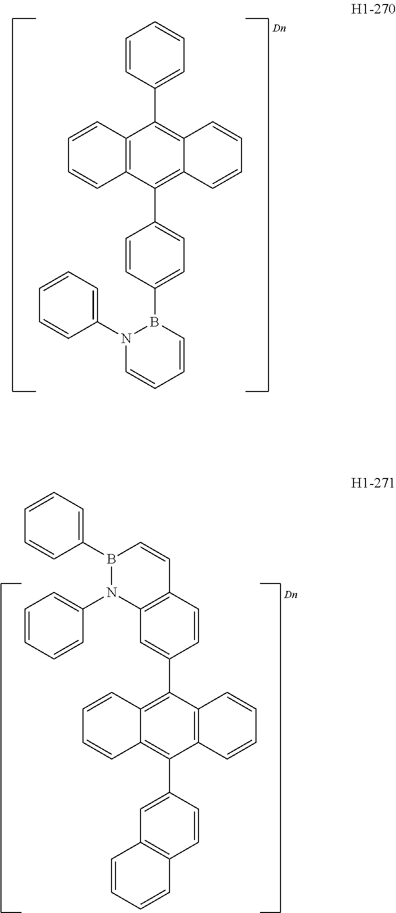

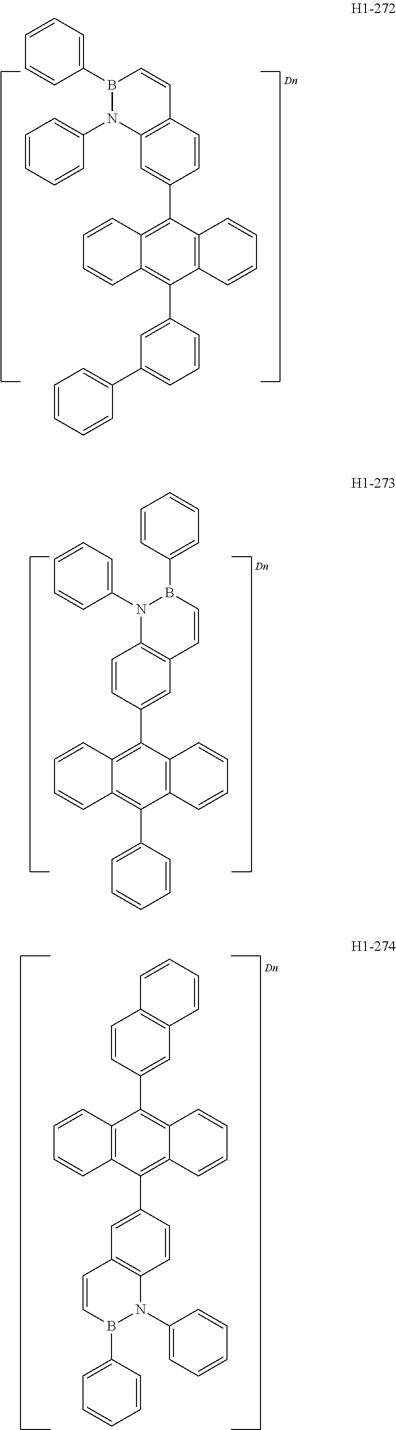

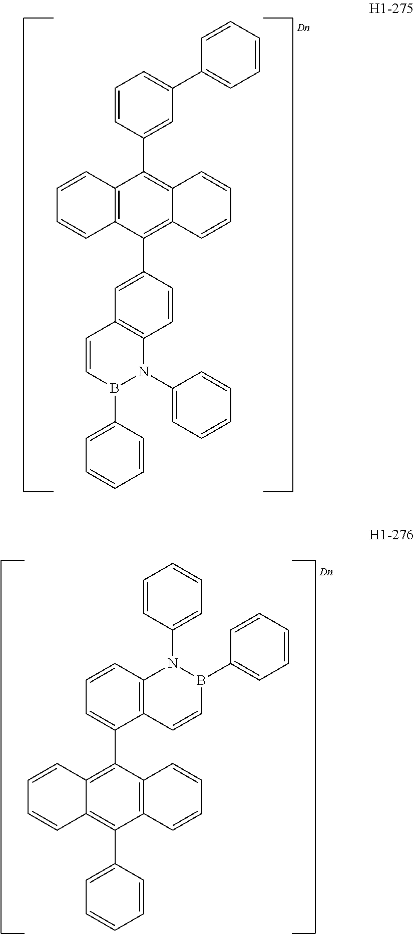

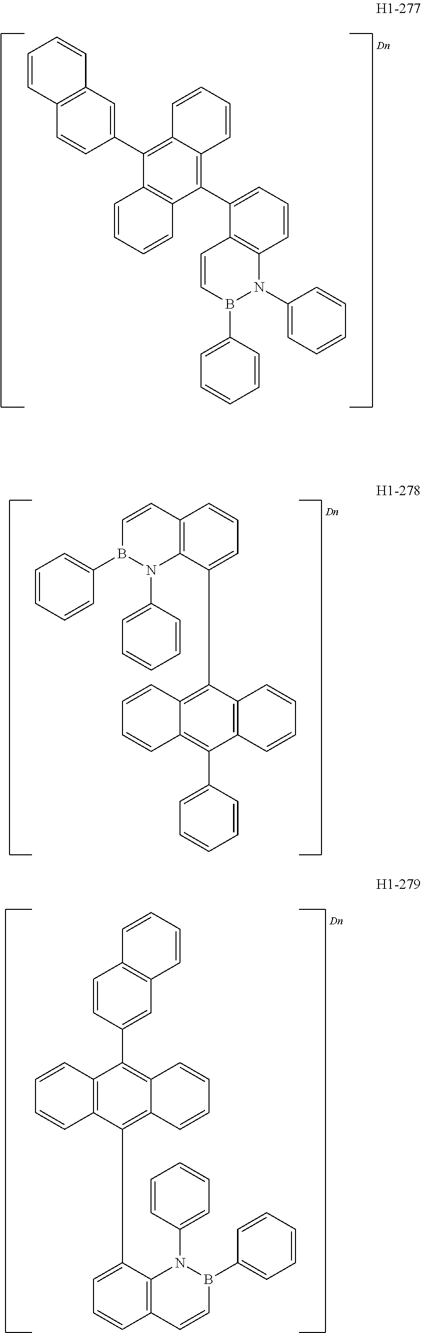

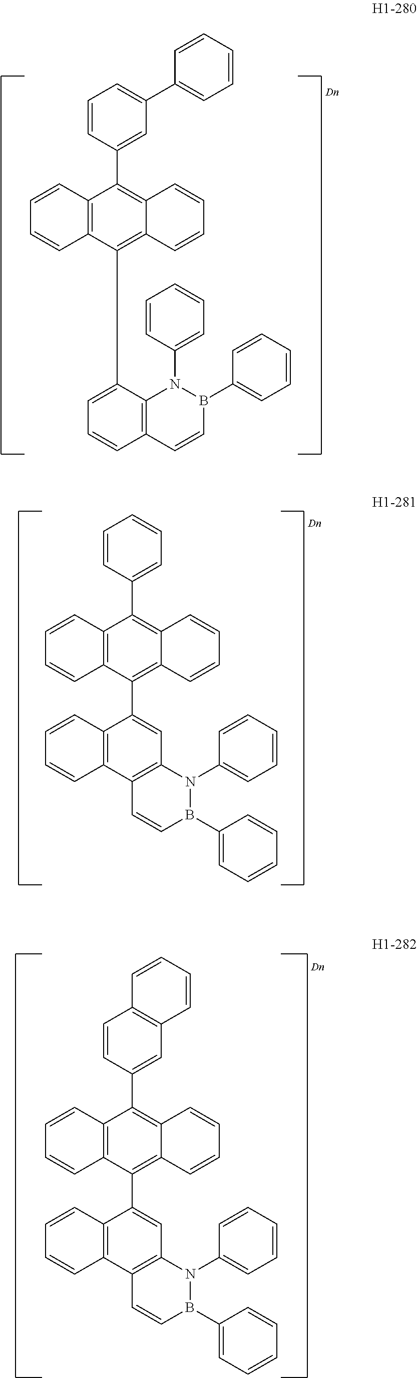

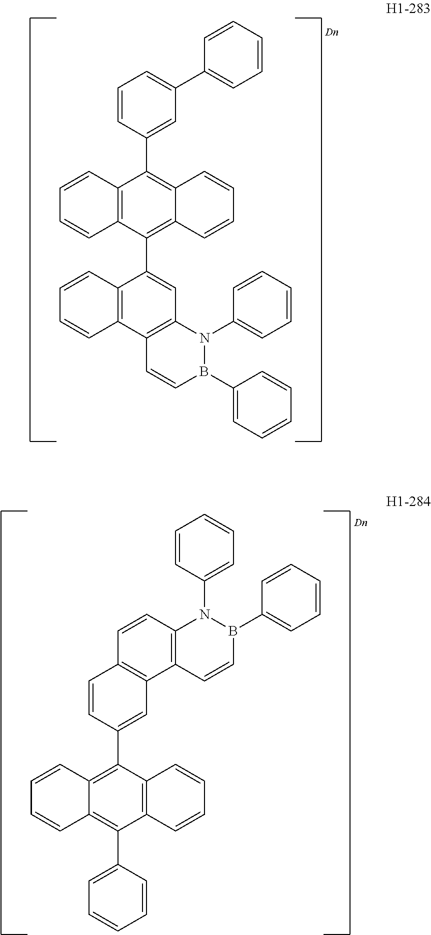

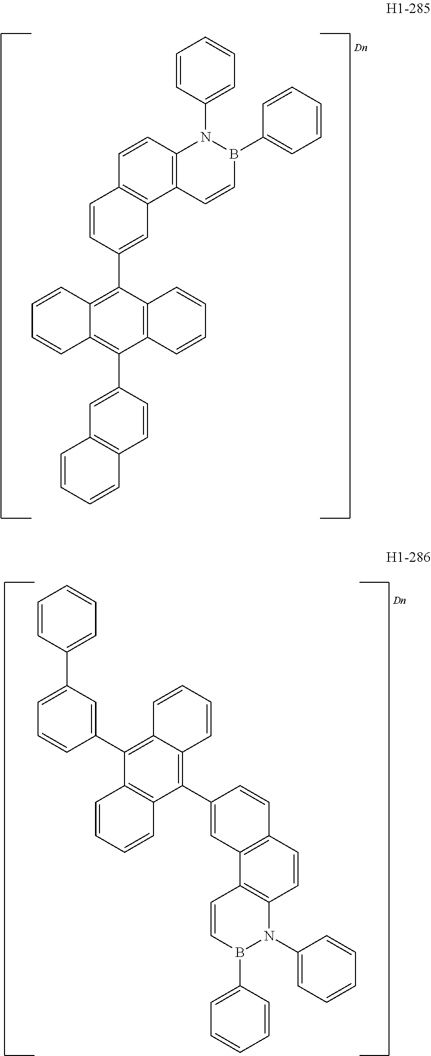

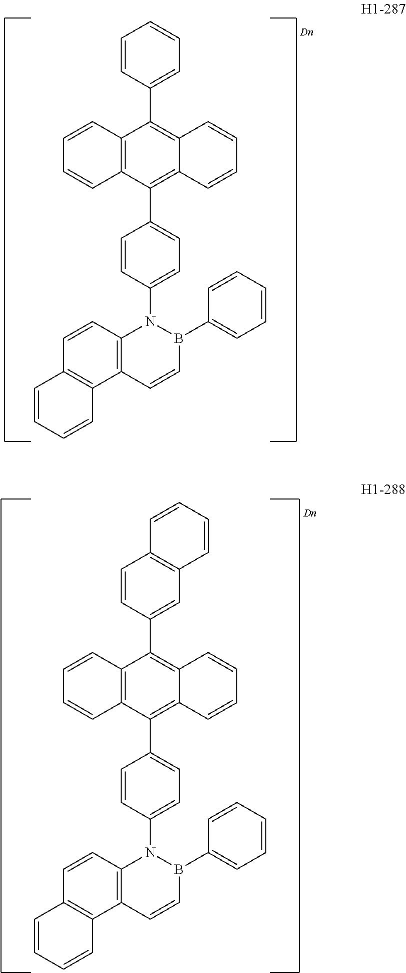

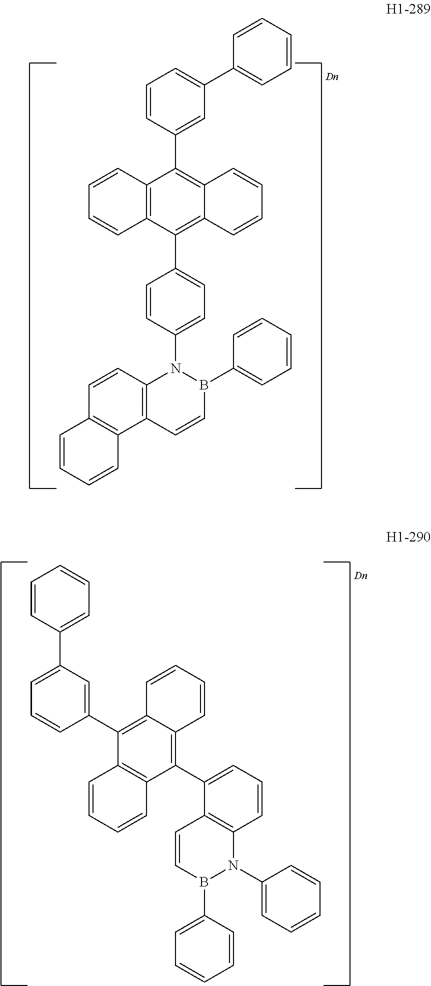

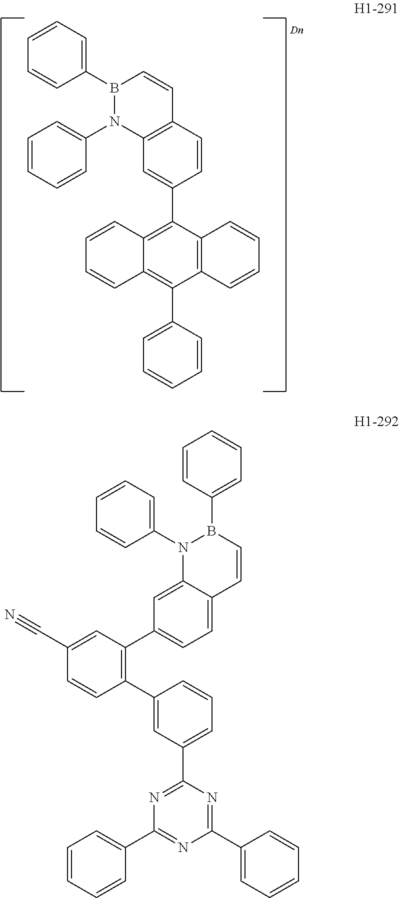

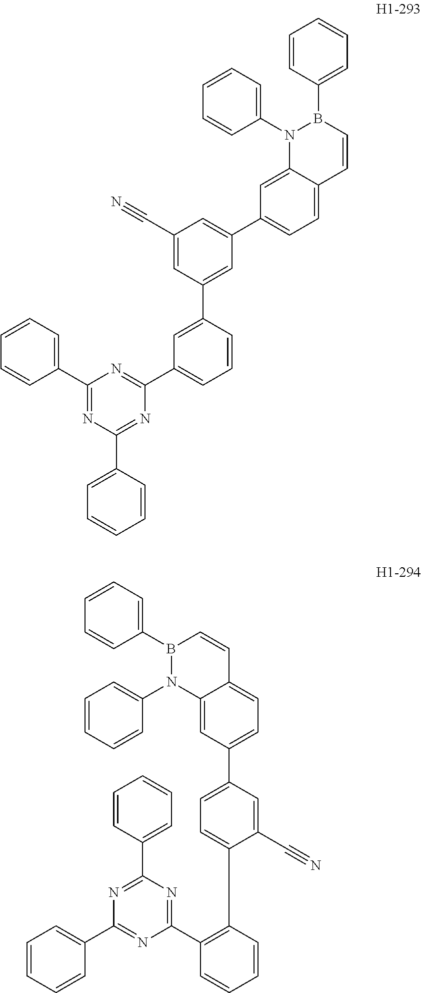 [SMILES: N#Cc1cc(-c2cccc(-c3nc(-c4ccccc4)nc(-c4ccccc4)n3)c2)cc(-c2ccc3c(c2)N(c2ccccc2)B(c2ccccc2)C=C3)c1 ; N#Cc1cc(-c2ccc3c(c2)N(c2ccccc2)B(c2ccccc2)C=C3)ccc1-c1ccccc1-c1nc(-c2ccccc2)nc(-c2ccccc2)n1]

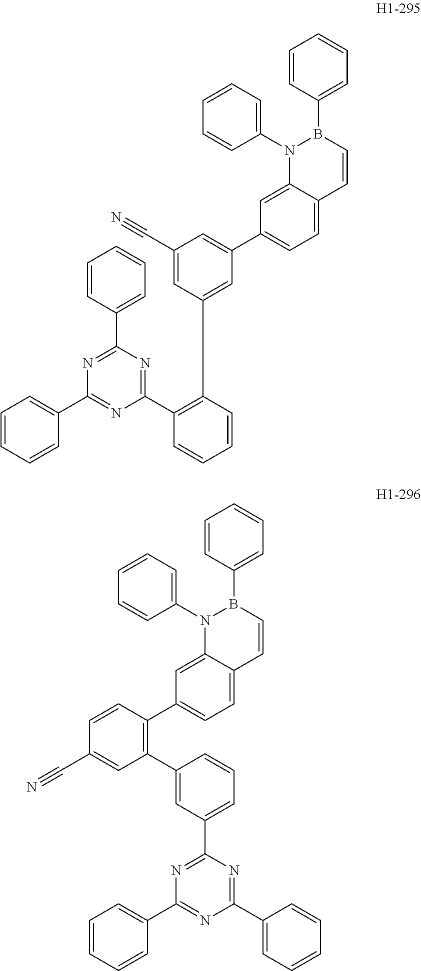 [SMILES: N#Cc1cc(-c2ccc3c(c2)N(c2ccccc2)B(c2ccccc2)C=C3)cc(-c2ccccc2-c2nc(-c3ccccc3)nc(-c3ccccc3)n2)c1 ; N#Cc1ccc(-c2ccc3c(c2)N(c2ccccc2)B(c2ccccc2)C=C3)c(-c2cccc(-c3nc(-c4ccccc4)nc(-c4ccccc4)n3)c2)c1]

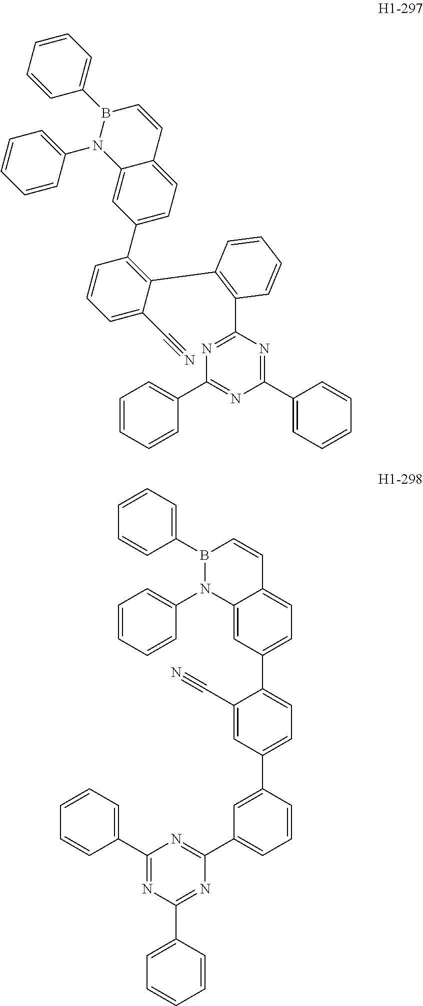

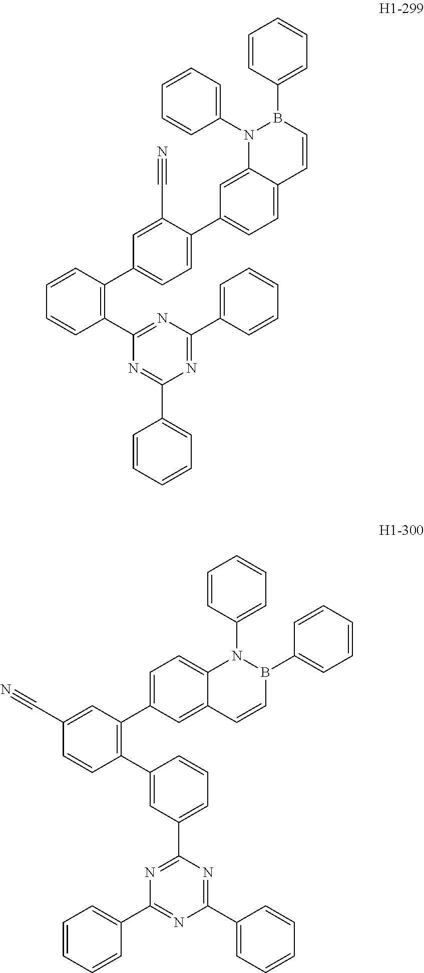 [SMILES: N#Cc1cc(-c2ccccc2-c2nc(-c3ccccc3)nc(-c3ccccc3)n2)ccc1-c1ccc2c(c1)N(c1ccccc1)B(c1ccccc1)C=C2 ; N#Cc1ccc(-c2cccc(-c3nc(-c4ccccc4)nc(-c4ccccc4)n3)c2)c(-c2ccc3c(c2)C=CB(c2ccccc2)N3c2ccccc2)c1]

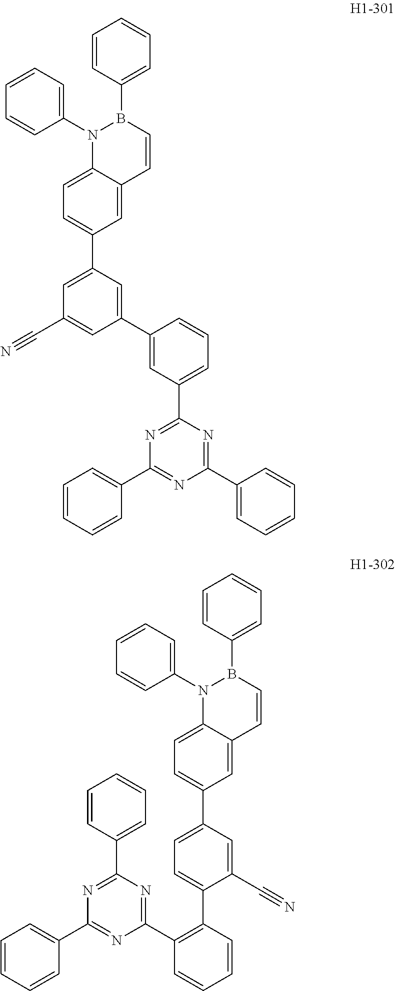 [SMILES: N#Cc1cc(-c2cccc(-c3nc(-c4ccccc4)nc(-c4ccccc4)n3)c2)cc(-c2ccc3c(c2)C=CB(c2ccccc2)N3c2ccccc2)c1 ; N#Cc1cc(-c2ccc3c(c2)C=CB(c2ccccc2)N3c2ccccc2)ccc1-c1ccccc1-c1nc(-c2ccccc2)nc(-c2ccccc2)n1]

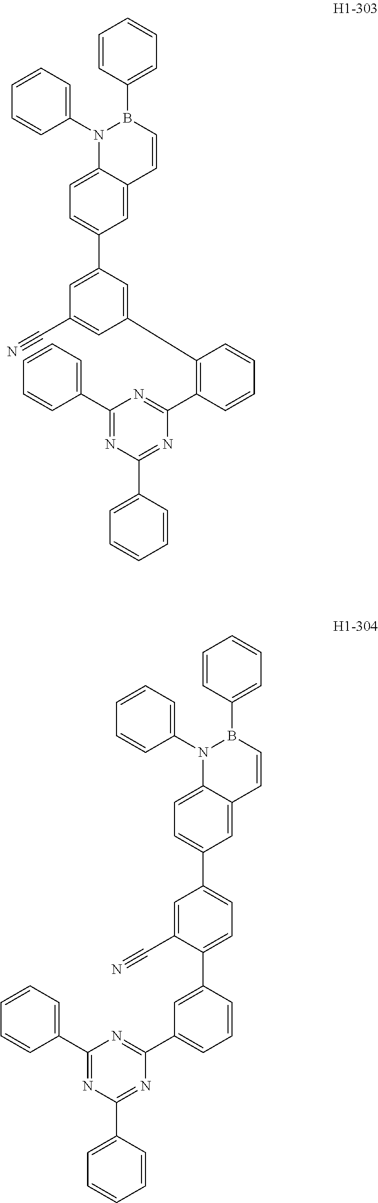 [SMILES: N#Cc1cc(-c2ccc3c(c2)C=CB(c2ccccc2)N3c2ccccc2)cc(-c2ccccc2-c2nc(-c3ccccc3)nc(-c3ccccc3)n2)c1 ; N#Cc1cc(-c2ccc3c(c2)C=CB(c2ccccc2)N3c2ccccc2)ccc1-c1cccc(-c2nc(-c3ccccc3)nc(-c3ccccc3)n2)c1]

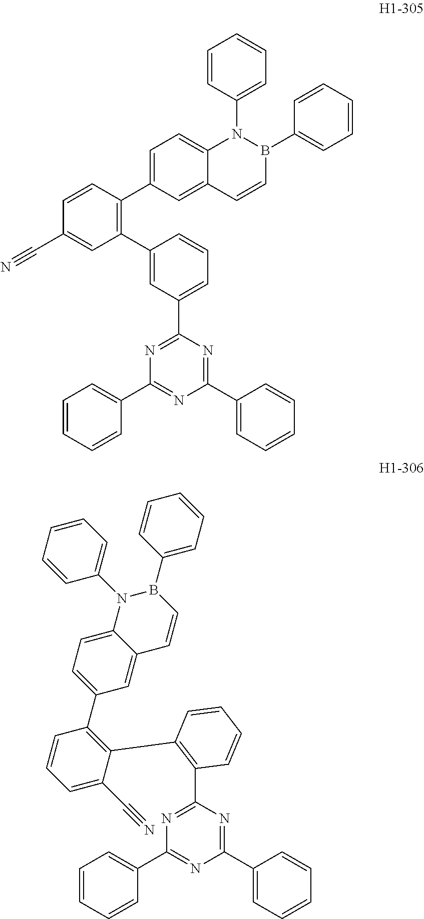 [SMILES: N#Cc1ccc(-c2ccc3c(c2)C=CB(c2ccccc2)N3c2ccccc2)c(-c2cccc(-c3nc(-c4ccccc4)nc(-c4ccccc4)n3)c2)c1 ; N#Cc1cccc(-c2ccc3c(c2)C=CB(c2ccccc2)N3c2ccccc2)c1-c1ccccc1-c1nc(-c2ccccc2)nc(-c2ccccc2)n1]

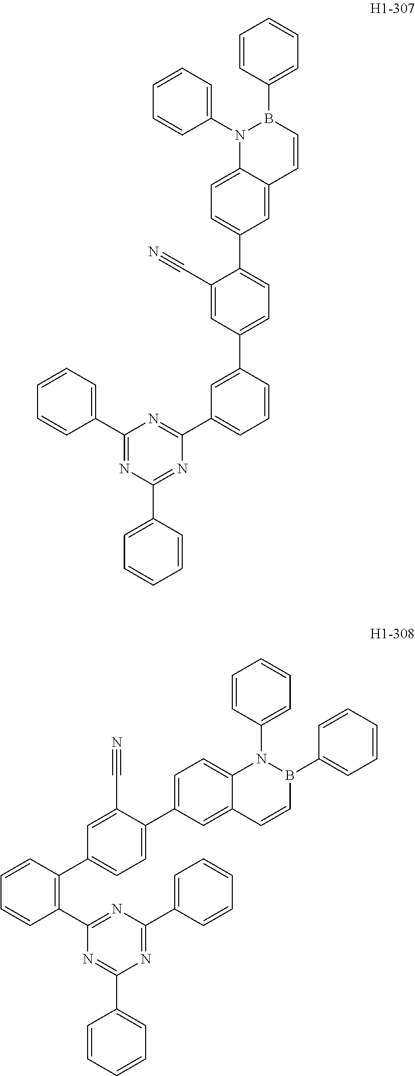 [SMILES: N#Cc1cc(-c2cccc(-c3nc(-c4ccccc4)nc(-c4ccccc4)n3)c2)ccc1-c1ccc2c(c1)C=CB(c1ccccc1)N2c1ccccc1 ; N#Cc1cc(-c2ccccc2-c2nc(-c3ccccc3)nc(-c3ccccc3)n2)ccc1-c1ccc2c(c1)C=CB(c1ccccc1)N2c1ccccc1]

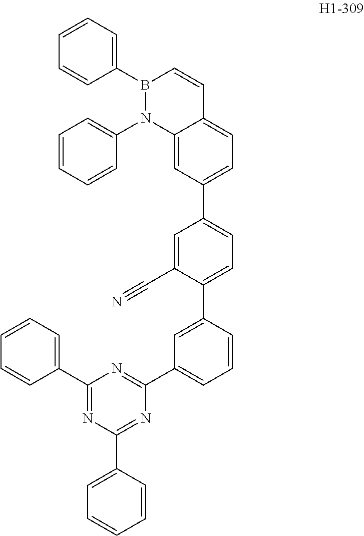 [SMILES: N#Cc1cc(-c2ccc3c(c2)N(c2ccccc2)B(c2ccccc2)C=C3)ccc1-c1cccc(-c2nc(-c3ccccc3)nc(-c3ccccc3)n2)c1]

In the compounds above, Dₙ means that n number of hydrogens are replaced with deuterium, and n represents an integer from 1 to the maximum number of hydrogens in the compound.

According to one embodiment of the present disclosure, the present disclosure provides an organic electroluminescent material comprising the organic electroluminescent compound represented by Formula 1′.

According to one embodiment of the present disclosure, the present disclosure provides an organic electroluminescent device comprising the organic electroluminescent compound represented by Formula 1′.

According to one embodiment of the present disclosure, the present disclosure provides an organic electroluminescent device comprising the organic electroluminescent compound represented by Formula 1′ in a light-emitting layer as a phosphorescent host material.

According to one embodiment of the present disclosure, the present disclosure provides an organic electroluminescent device comprising the organic electroluminescent compound represented by Formula 1′ in a light-emitting layer as a phosphorescent host material.

According to another embodiment of the present disclosure, the present disclosure provides an organic electroluminescent device wherein the light-emitting layer emits red light.

According to one embodiment of the present disclosure, the present disclosure provides an organic electroluminescent device comprising the organic electroluminescent compound represented by Formula 1′ in at least one layer of a hole transport layer, a light-emitting layer, a hole auxiliary layer, an electron blocking layer, and a light-emitting auxiliary layer.

The compounds represented by Formulas 1 and 1′ according to the present disclosure may be synthesized by referring to the following Reaction Scheme 1, but is not limited thereto.

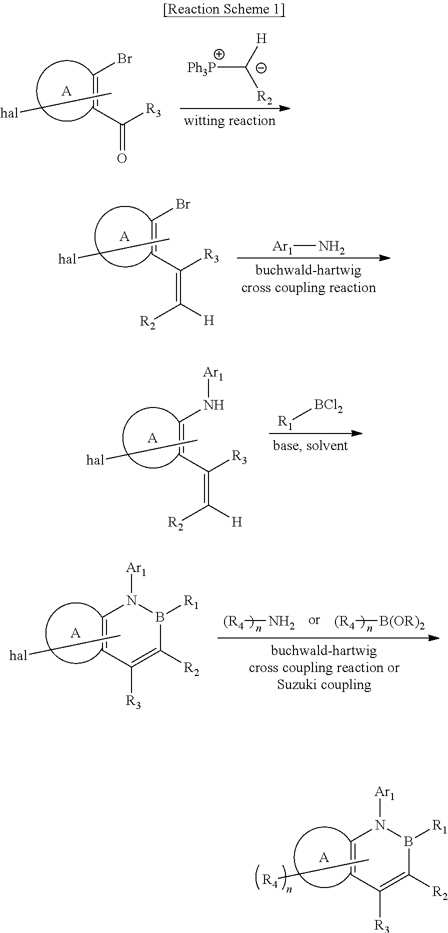

The compound represented by Formula 2-1 according to the present disclosure may be synthesized by referring to synthetic methods known to one skilled in the art, in particular, by using synthetic methods disclosed in many patent literatures. For example, it may be produced by referring to the synthetic methods disclosed in Korean Patent Application Laid-Open Nos. 2017-0022865, 2018-0099487, etc., but are not limited thereto.

The compound represented by Formula 2-2 according to the present disclosure may be synthesized by referring to synthetic methods known to one skilled in the art, in particular, by using synthetic methods disclosed in many patent literatures. For example, it may be produced by referring to the synthetic methods disclosed in Korean Patent Application Laid-Open Nos. 2023-0174704, 2023-0157860, etc., but are not limited thereto.

Although illustrative synthesis examples of the compounds represented by Formulas 1, 2-1, 2-2, and 1′ are described above, one skilled in the art will be able to readily understand that all of them are based on a Buchwald-Hartwig cross coupling reaction, an N-arylation reaction, a H-mont-mediated etherification reaction, a Miyaura borylation reaction, a Suzuki cross-coupling reaction, an Intramolecular acid-induced cyclization reaction, a Pd(II)-catalyzed oxidative cyclization reaction, a Grignard reaction, a Heck reaction, a Cyclic Dehydration reaction, an SN₁ substitution reaction, an SN₂ substitution reaction, and a Phosphine-mediated reductive cyclization reaction, etc., and the above reactions proceed even when substituents defined in Formulas 1, 2-1, 2-2, and 1′ other than the substituents specified in the specific synthesis examples, are bonded.

The organic electroluminescent device according to the present disclosure comprises an anode, a cathode, and at least one light-emitting layer between the anode and the cathode, wherein the at least one light-emitting layer comprises the plurality of host materials comprising at least one first host compound represented by Formula 1 and a second host compound which is different from the first host compound. Herein, the weight ratio of the first host compound to the second host compound may be in the range of about 1:99 to about 99:1, preferably about 10:90 to about 90:10, more preferably about 30:70 to about 70:30, more preferably about 40:60 to about 60:40, even more preferably about 50:50 in the light-emitting layer. For example, the plurality of host materials of the present disclosure may comprise at least one compound of the first host compounds H1-1 to H1-212, and H1-292 to H1-309 and at least one compound of the second host compounds H2-1 to H2-391 and H3-1 to H3-455, and the plurality of host materials may be included in the same organic layer, for example, the same light-emitting layer, or each may be included in different light-emitting layers.

The organic electroluminescent compound represented by Formula 1′ may comprised in at least one layer of a light-emitting layer, a hole injection layer, a hole transport layer, a hole auxiliary layer, a light-emitting auxiliary layer, an electron transport layer, an electron buffer layer, an electron injection layer, an interlayer, a hole blocking layer, and an electron blocking layer, and preferably in at least one layer of a hole transport layer, a light-emitting layer, a hole auxiliary layer, an electron blocking layer, and a light-emitting auxiliary layer. When used in a light emitting layer, the organic electroluminescent compound of Formula 1′ may be included as a host material. The organic electroluminescent compound of the present disclosure may be used as co-host materials.

The organic layer may further include one or more layers selected from a hole injection layer, a hole auxiliary layer, a light-emitting auxiliary layer, an electron transport layer, an electron injection layer, an interlayer, a hole blocking layer, an electron blocking layer, and an electron buffer layer in addition to a hole transport layer and a light-emitting layer. The organic layer may further include an amine-based compound and/or an azine-based compound in addition to the light-emitting material of the present disclosure. Specifically, the hole injection layer, the hole transport layer, the hole auxiliary layer, the light-emitting layer, the light-emitting auxiliary layer, or the electron blocking layer may include an amine-based compound, for example, an arylamine-based compound, a styrylarylamine-based compound, or the like, as a hole injection material, a hole transport material, a hole auxiliary material, a light-emitting material, a light-emitting auxiliary material, and an electron blocking material. In addition, the electron transport layer, the electron injection layer, the electron buffer layer and the hole blocking layer may include an azine-based compound as an electron transport material, an electron injection material, an electron buffer material and a hole blocking material. Also, the organic layer may further comprise at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound comprising such a metal.

The anode and the cathode may each be formed as a transmissive conductive material, a transflective conductive material, or a reflective conductive material. The organic electroluminescent device may be a top emission type, a bottom emission type, or a both-sides emission type depending on the kinds of the material forming the first electrode and the second electrode.

A hole injection layer, a hole transport layer, an electron blocking layer, or a combination thereof can be used between the anode and the light-emitting layer. The hole injection layer may be multi-layers in order to lower the hole injection barrier (or hole injection voltage) from the anode to the hole transport layer or the electron blocking layer, wherein each of the multi-layers may use two compounds simultaneously. Also, the hole injection layer may be doped as a p-dopant. The electron blocking layer may be placed between the hole transport layer (or hole injection layer) and the light-emitting layer, and can confine the excitons within the light-emitting layer by blocking the overflow of electrons from the light-emitting layer to prevent a light-emitting leakage. A plurality of layers may be used in the hole transport layer or electron blocking layer, and a plurality of compounds may be used in each layer.

An electron buffer layer, a hole-blocking layer, an electron transport layer, an electron injection layer, or a combination thereof can be used between the light-emitting layer and the cathode. The electron buffer layer may be multi-layers in order to control the injection of the electron and improve the interfacial properties between the light-emitting layer and the electron injection layer, wherein each of the multi-layers may use two compounds simultaneously. The hole blocking layer may be placed between the electron transport layer (or electron injection layer) and the light-emitting layer, and blocks the arrival of holes to the cathode, thereby improving the probability of recombination of electrons and holes in the light-emitting layer. The hole blocking layer or the electron transport layer may also be multi-layers, wherein each layer may use a plurality of compounds. Also, the electron injection layer may be doped as an n-dopant.

The light-emitting auxiliary layer, the hole auxiliary layer, or the electron blocking layer may have an effect of improving the efficiency and/or the lifetime of the organic electroluminescent device.

The light-emitting auxiliary layer may be a layer placed between the anode and the light-emitting layer or between the cathode and the light-emitting layer, when the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes.

In addition, the hole auxiliary layer is located between the hole transport layer (or hole injection layer) and the light-emitting layer, and can exhibit the effect of facilitating or blocking the hole transport speed (or injection speed), thereby controlling the charge balance. When the organic electroluminescent device includes two or more hole transport layers, the additionally included hole transport layer can also be used as the hole auxiliary layer or the electron blocking layer.

In the organic electroluminescent device of the present disclosure, preferably at least one layer (hereinafter, “a surface layer”) selected from a chalcogenide layer, a halogenated metal layer, and a metal oxide layer may be placed on an inner surface(s) of one or both of a pair of electrodes. Specifically, a chalcogenide (including oxides) layer of silicon and aluminum is preferably placed on an anode surface of an electroluminescent medium layer, and a halogenated metal layer or a metal oxide layer is preferably placed on a cathode surface of an electroluminescent medium layer. The operation stability for the organic electroluminescent device may be obtained by the surface layer. Preferably, the chalcogenide includes SiO_{X} (1≤X≤2), AlO_{X} (1≤X≤1.5), SiON, SiAlON, etc.; the halogenated metal includes LiF, MgF₂, CaF₂, a rare earth metal fluoride, etc.; and the metal oxide includes Cs₂O, Li₂O, MgO, SrO, BaO, CaO, etc.

In addition, in the organic electroluminescent device of the present disclosure, a mixed region of an electron transport compound and a reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Furthermore, the hole transport compound is oxidized to a cation; thus, it becomes easier to inject and transport holes from the mixed region to the electroluminescent medium. Preferably, the oxidative dopant includes various Lewis acids and acceptor compounds, and the reductive dopant includes alkali metals, alkali metal compounds, alkaline earth metals, rare earth metals, and mixtures thereof. Also, a reductive dopant layer may be employed as a charge generating layer to prepare an organic electroluminescent device having two or more light-emitting layers and emitting white light.

The organic electroluminescent device according to one embodiment of the present disclosure may be an organic electroluminescent device having a tandem structure. In the case of a tandem organic electroluminescent device according to one embodiment, a single light-emitting unit (light-emitting unit) may be formed in a structure in which two or more units are connected by a charge generation layer. The organic electroluminescent device may include a plurality of two or more light-emitting units, for example, a plurality of three or more light-emitting units, having first and second electrodes opposed to each other on a substrate and a light-emitting layer that is stacked between the first and second electrodes and emits light in a specific wavelength range. According to one embodiment, the organic electroluminescent device may include a plurality of light-emitting units, and each of the light-emitting units may include a hole transport zone, a light-emitting layer, and an electron transport zone, and the hole transport zone may include a hole injection layer and a hole transport layer, and the electron transport zone may include an electron transport layer and an electron injection layer. According to one embodiment, three or more light-emitting layers may be included in the light-emitting unit. A plurality of light-emitting units may emit the same color or different colors. Additionally, one light-emitting unit may include one or more light-emitting layers, and the plurality of light-emitting layers may be light-emitting layers of the same or different colors. This may include one or more charge generation layers located between each light-emitting unit. The charge generation layer refers to the layer in which holes and electrons are generated when voltage is applied. When there are three or more light-emitting units, a charge generation layer may be located between each light-emitting unit. Here, the plurality of charge generation layers may be the same as or different from each other. By disposing the charge generation layer between light-emitting units, current efficiency is increased in each light-emitting unit, and charges can be smoothly distributed. Specifically, the charge generation layer is provided between two adjacent stacks and can serve to drive a tandem organic electroluminescent device using only a pair of anode and cathode without a separate internal electrode located between the stacks.

The charge generation layer may be composed of an n-type charge generation layer and a p-type charge generation layer, and the n-type charge generation layer may be doped with an alkali metal, an alkaline earth metal, or a compound of an alkali metal and an alkaline earth metal. The alkali metal may include one selected from the group consisting of Li, Na, K, Rb, Cs, Fr, Yb, and combinations thereof, and the alkaline earth metal may include one selected from the group consisting of Be, Mg, Ca, Sr, Ba, Ra, and combinations thereof. The p-type charge generation layer may be made of a metal or an organic material doped with a p-type dopant. For example, the metal may be made of one or two or more alloys selected from the group consisting of Al, Cu, Fe, Pb, Zn, Au, Pt, W, In, Mo, Ni, and Ti. Additionally, commonly used materials may be used as the p-type dopant and host materials used in the p-type doped organic material.

An organic electroluminescent device according to one embodiment may further comprise at least one dopant in the light-emitting layer.

The dopant comprised in the organic electroluminescent device of the present disclosure may be at least one phosphorescent or fluorescent dopant, preferably a phosphorescent dopant. The phosphorescent dopant material applied to the organic electroluminescent device of the present disclosure is not particularly limited, but may preferably be a metallated complex compound(s) of a metal atom(s) selected from iridium (Ir), osmium (Os), copper (Cu), and platinum (Pt), more preferably an ortho-metallated complex compound(s) of a metal atom(s) selected from iridium (Ir), osmium (Os), copper (Cu), and platinum (Pt), and even more preferably ortho-metallated iridium complex compound(s).

The dopant comprised in the organic electroluminescent device of the present disclosure may use the compound represented by the following Formula 101, but is not limited thereto.

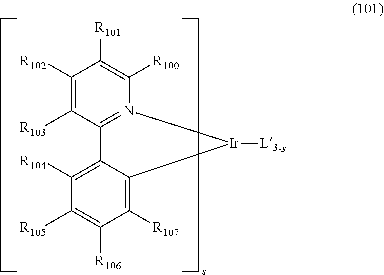

In Formula 101,
L′ is selected from the following structures 1 to 3:

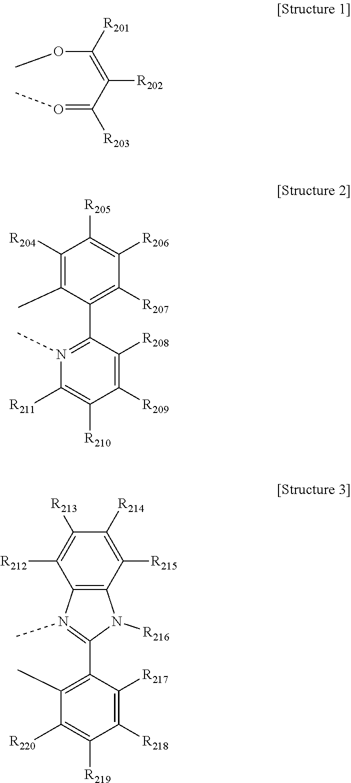

R₁₀₀ to R₁₀₃ each independently represent hydrogen, deuterium, a halogen, a (C₁-C₃₀)alkyl unsubstituted or substituted with deuterium and/or halogen, a substituted or unsubstituted (C₃-C₃₀)cycloalkyl, a substituted or unsubstituted (C₆-C₃₀)aryl, a cyano, a substituted or unsubstituted (3- to 30-membered)heteroaryl, or a substituted or unsubstituted (C₁-C₃₀)alkoxy; or may be linked to the adjacent substituents to form a ring(s), for example, to form a ring(s) with a pyridine, e.g., a substituted or unsubstituted quinoline, a substituted or unsubstituted isoquinoline, a substituted or unsubstituted benzofuropyridine, a substituted or unsubstituted benzothienopyridine, a substituted or unsubstituted indenopyridine, a substituted or unsubstituted benzofuroquinoline, a substituted or unsubstituted benzothienoquinoline, or a substituted or unsubstituted indenoquinoline;
R₁₀₄ to R₁₀₇ each independently represent hydrogen, deuterium, a halogen, a (C₁-C₃₀)alkyl unsubstituted or substituted with deuterium and/or halogen, a substituted or unsubstituted (C₃-C₃₀)cycloalkyl, a substituted or unsubstituted (C₆-C₃₀)aryl, a substituted or unsubstituted (3- to 30-membered)heteroaryl, a cyano, or a substituted or unsubstituted (C₁-C₃₀)alkoxy; or may be linked to an adjacent substituent(s) to form a ring(s), for example, to form a ring(s) with a benzene, e.g., a substituted or unsubstituted naphthalene, a substituted or unsubstituted fluorene, a substituted or unsubstituted dibenzothiophene, a substituted or unsubstituted dibenzofuran, a substituted or unsubstituted indenopyridine, a substituted or unsubstituted benzofuropyridine, or a substituted or unsubstituted benzothienopyridine;
R₂₀₁ to R₂₂₀ each independently represent hydrogen, deuterium, a halogen, a (C₁-C₃₀)alkyl unsubstituted or substituted with deuterium and/or halogen, a substituted or unsubstituted (C₃-C₃₀)cycloalkyl, or a substituted or unsubstituted (C₆-C₃₀)aryl; or may be linked to an adjacent substituent(s) to form a ring(s); and
s represents an integer of 1 to 3.

Specifically, the specific examples of the dopant compound include the following, but are not limited thereto.

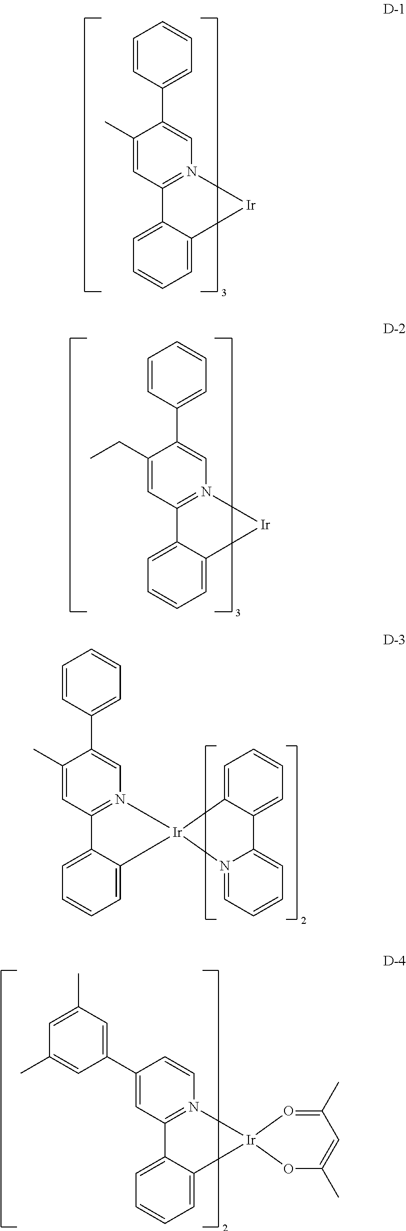

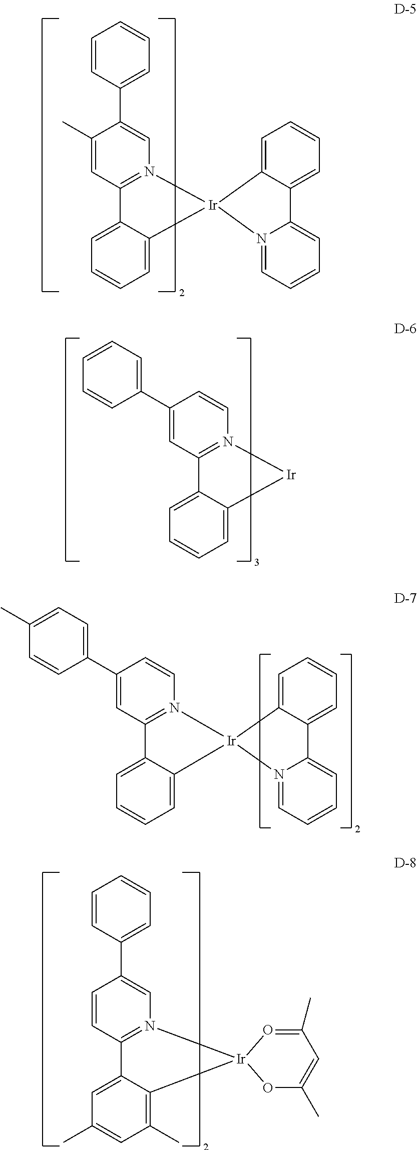

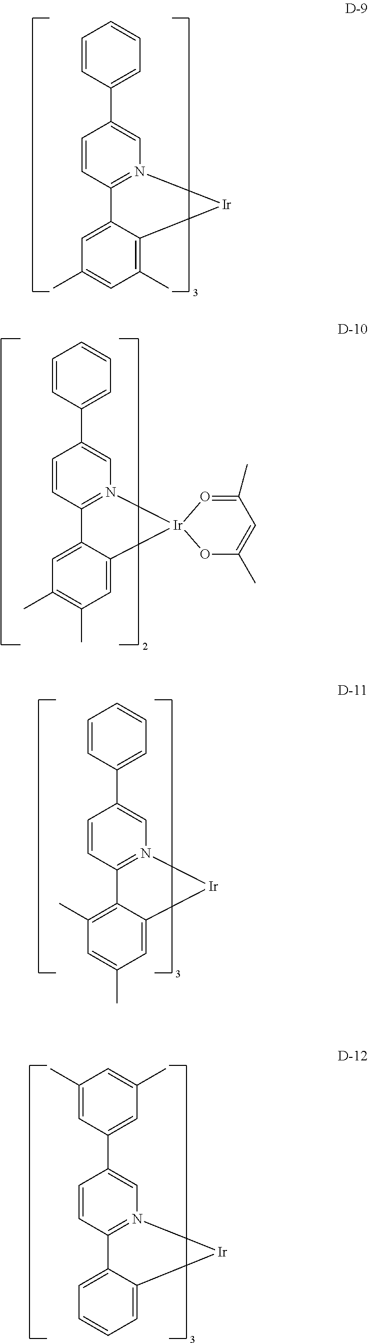

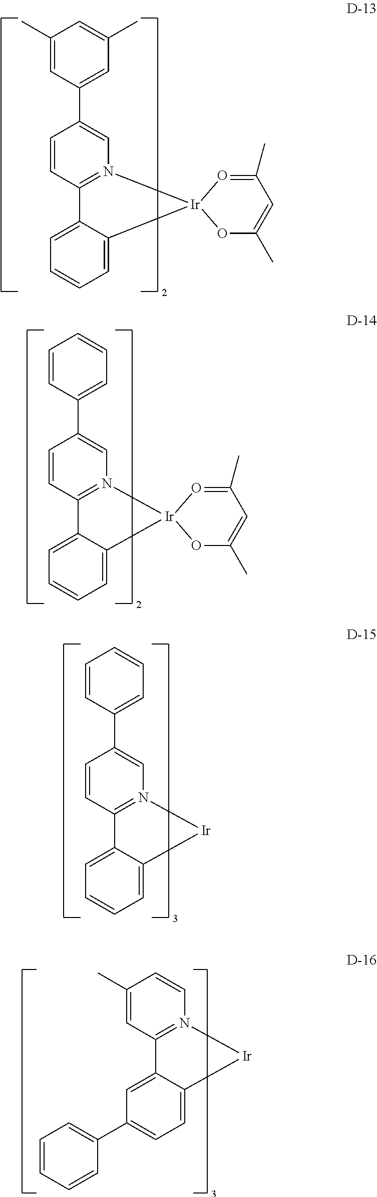

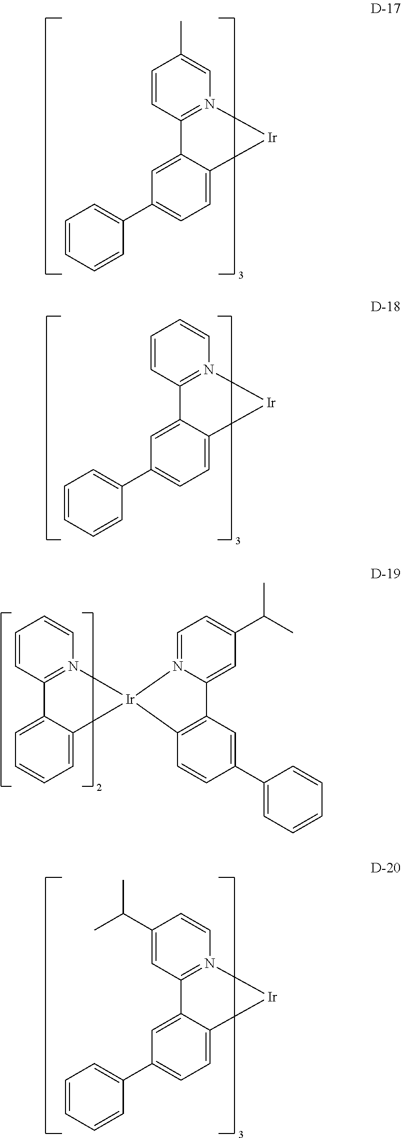

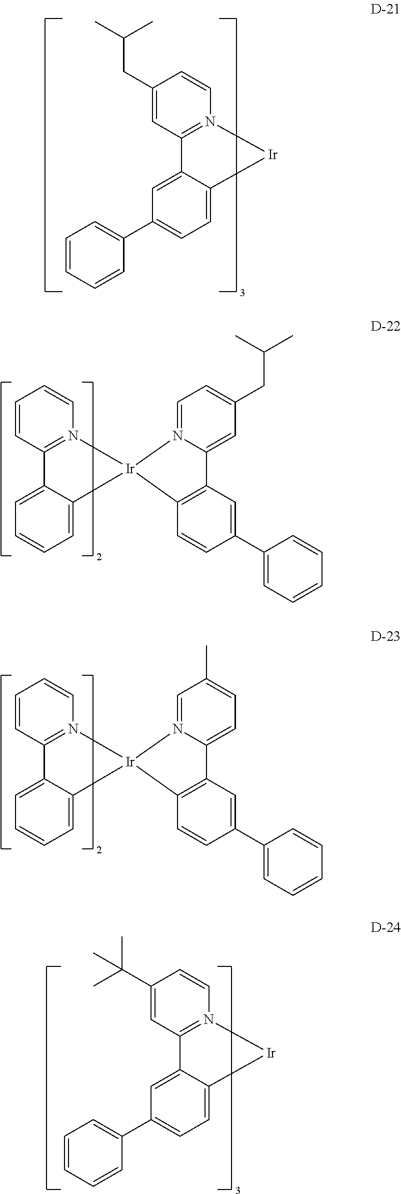

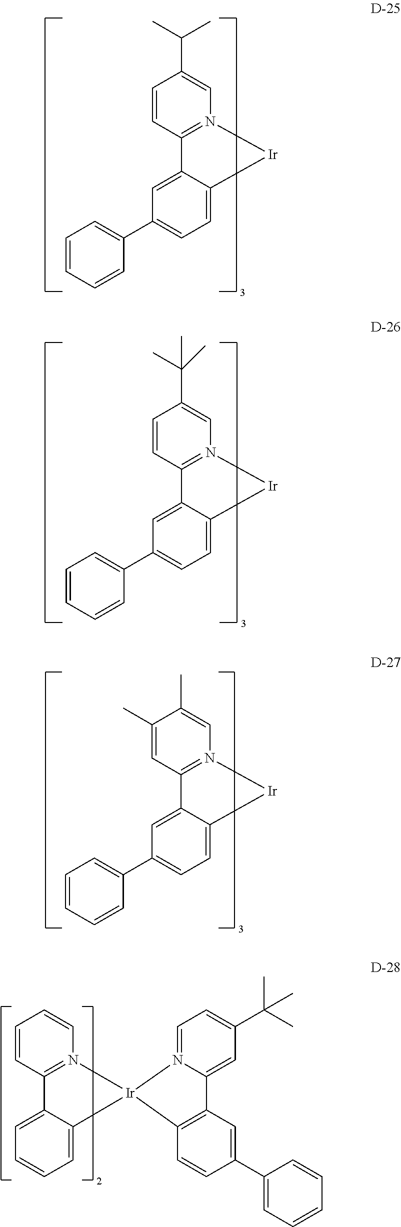

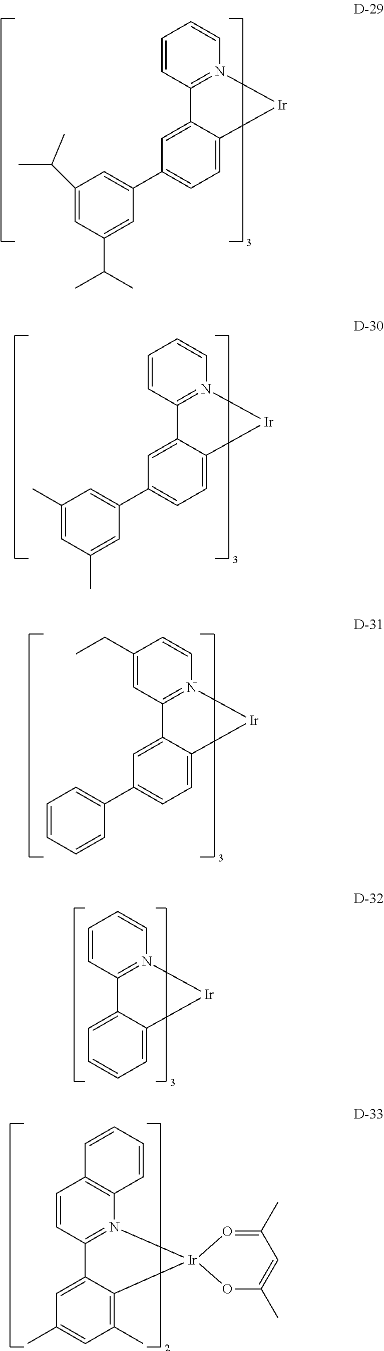

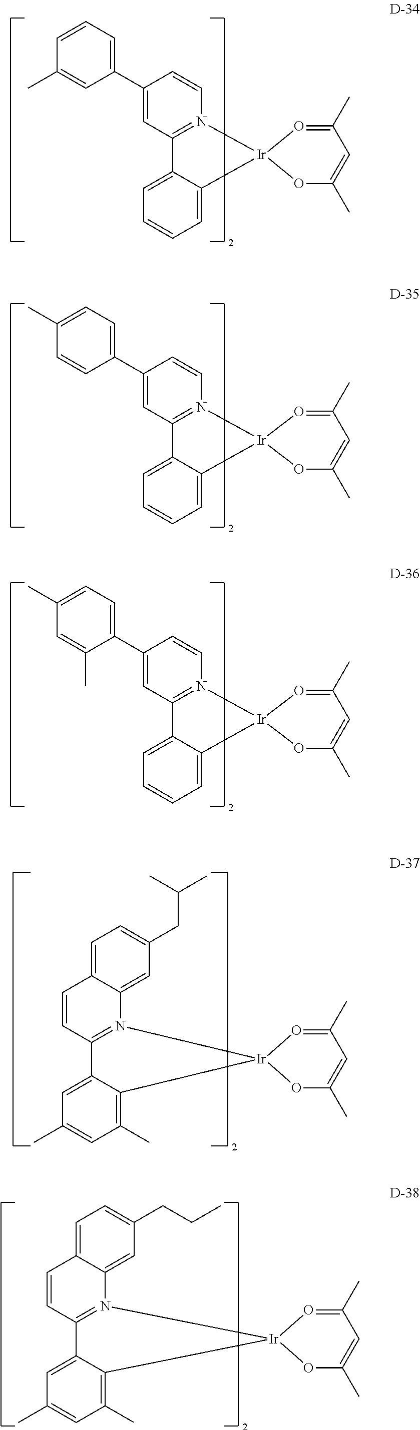

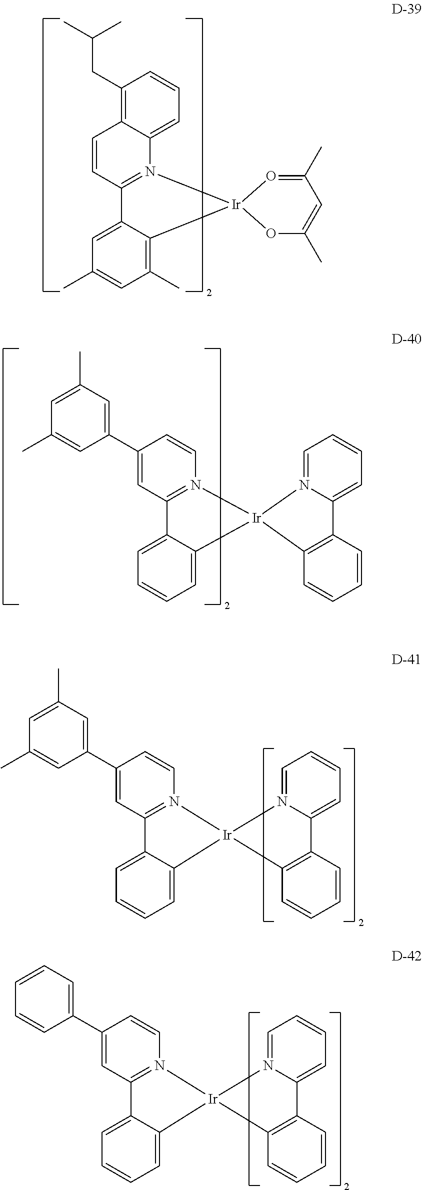

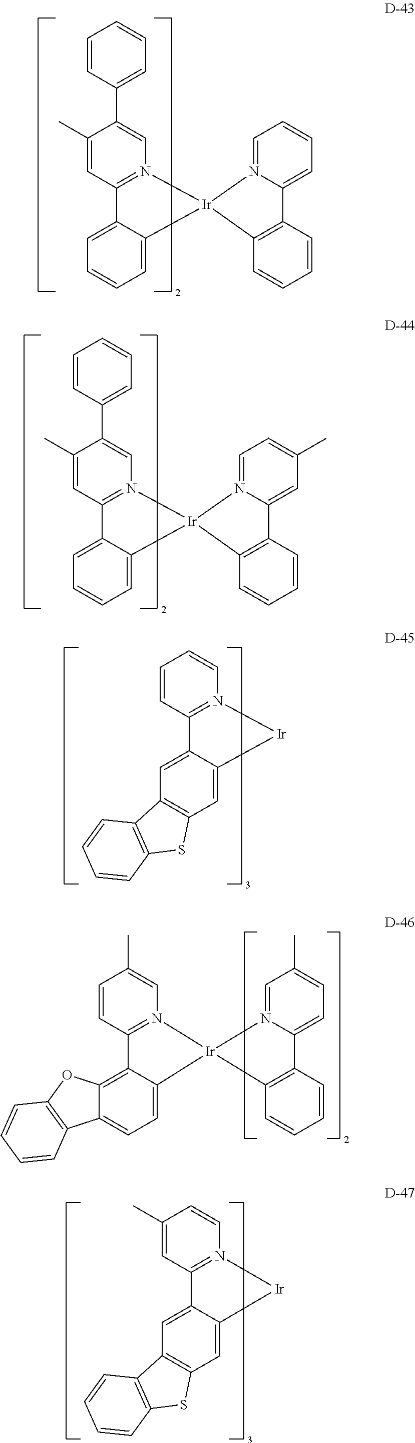

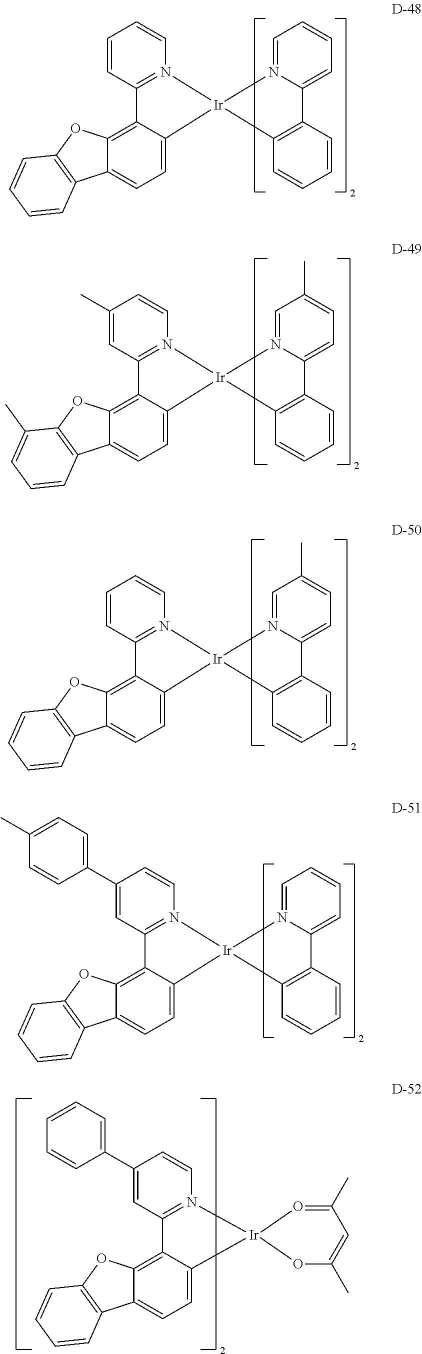

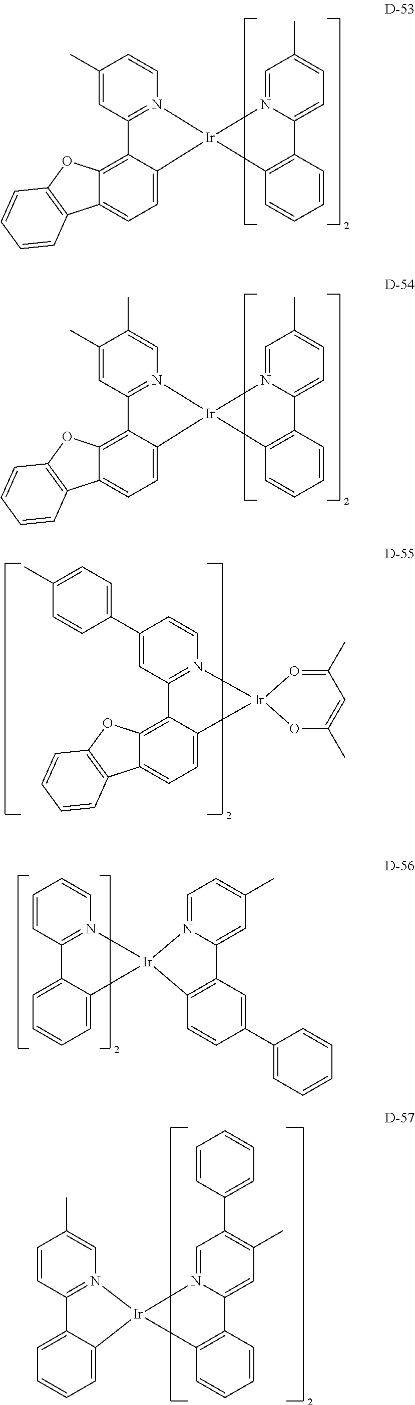

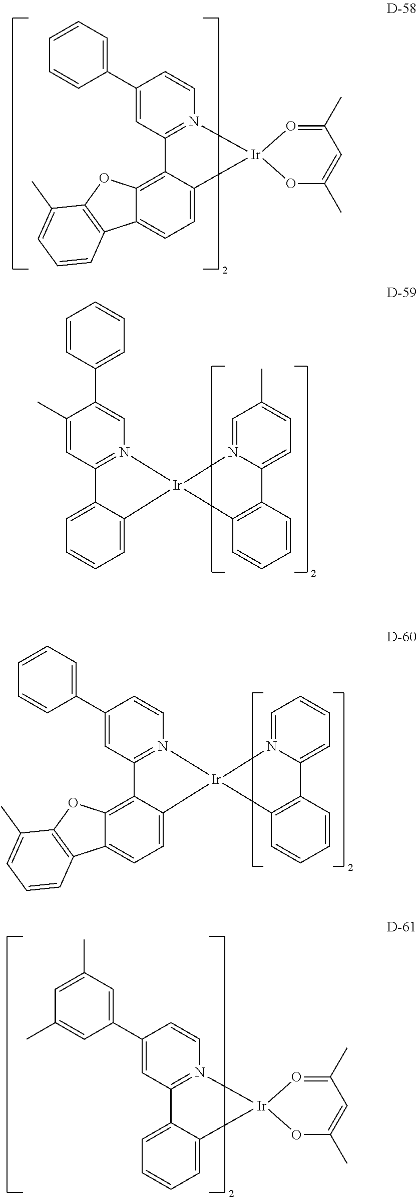

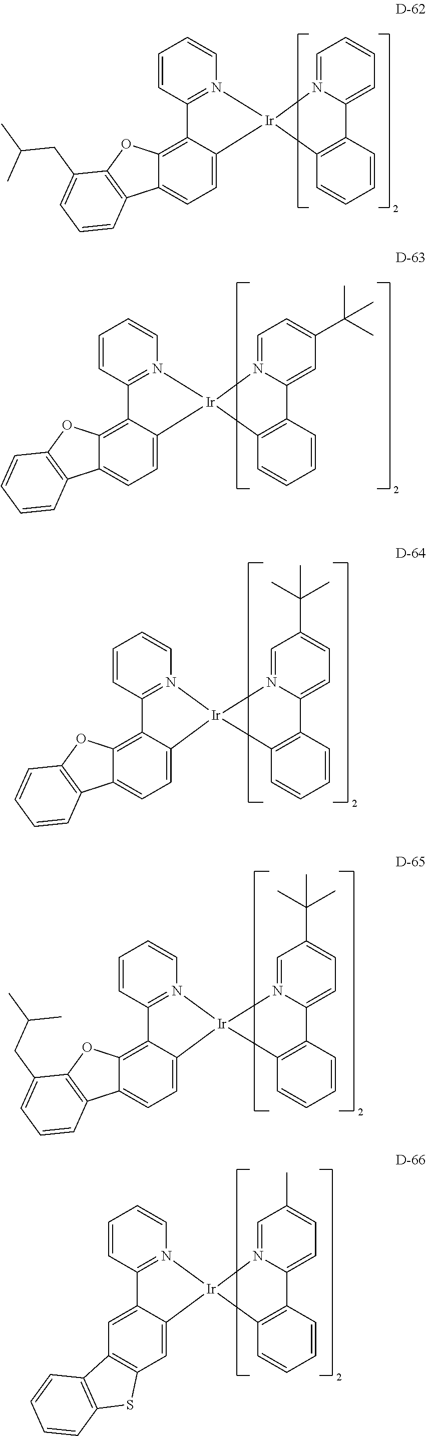

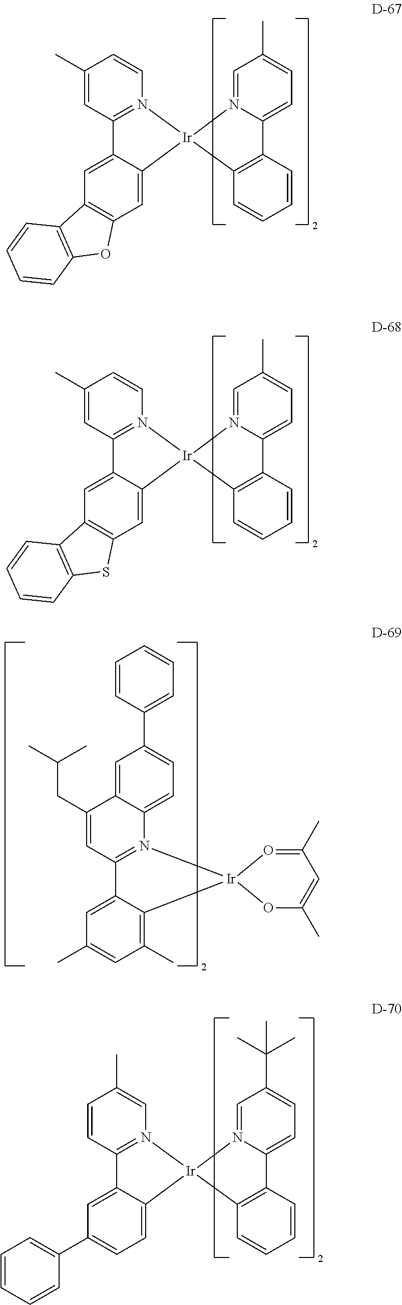

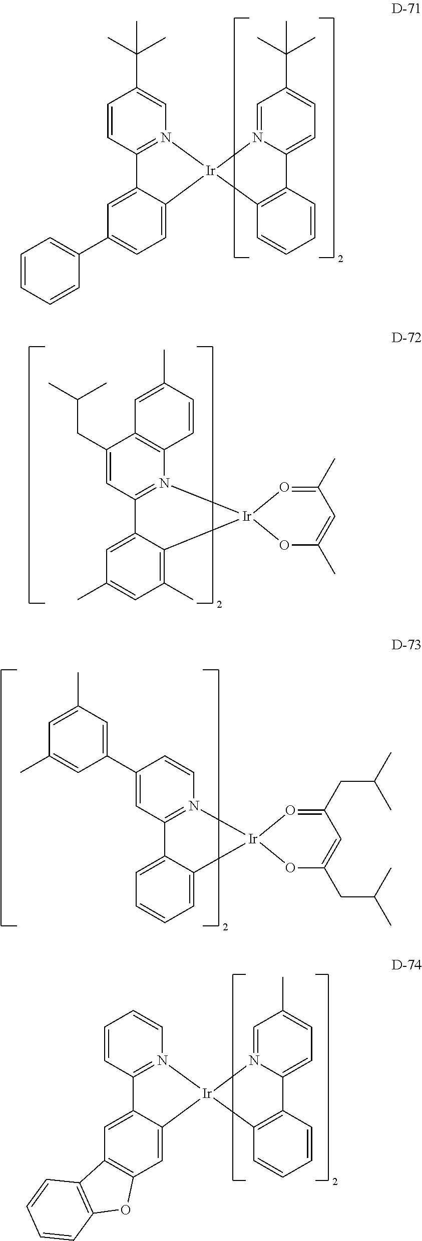

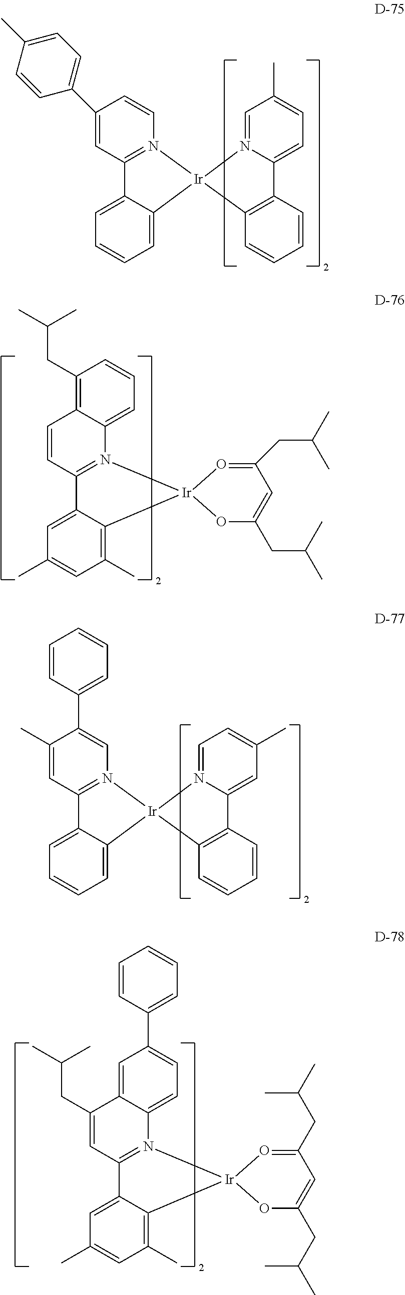

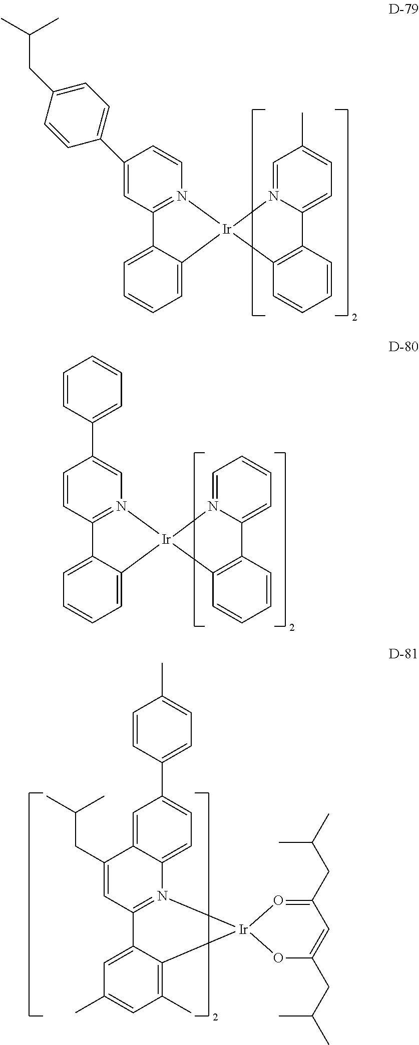

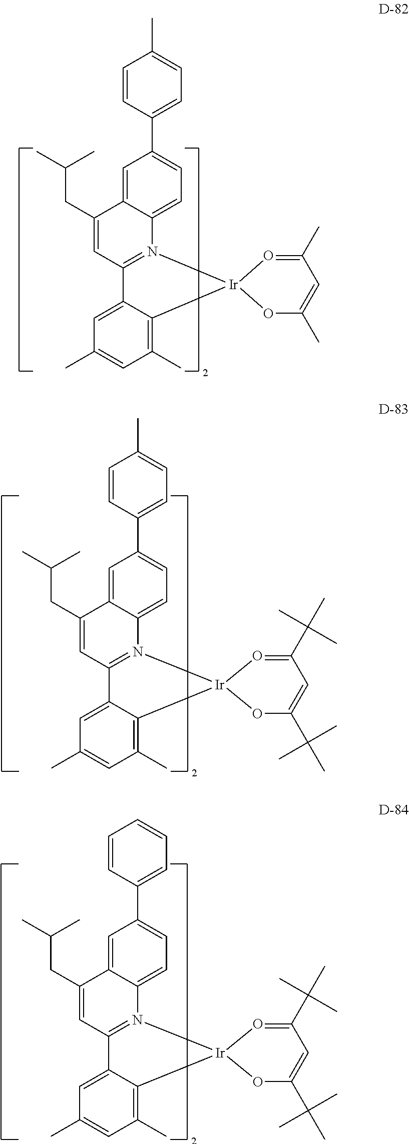

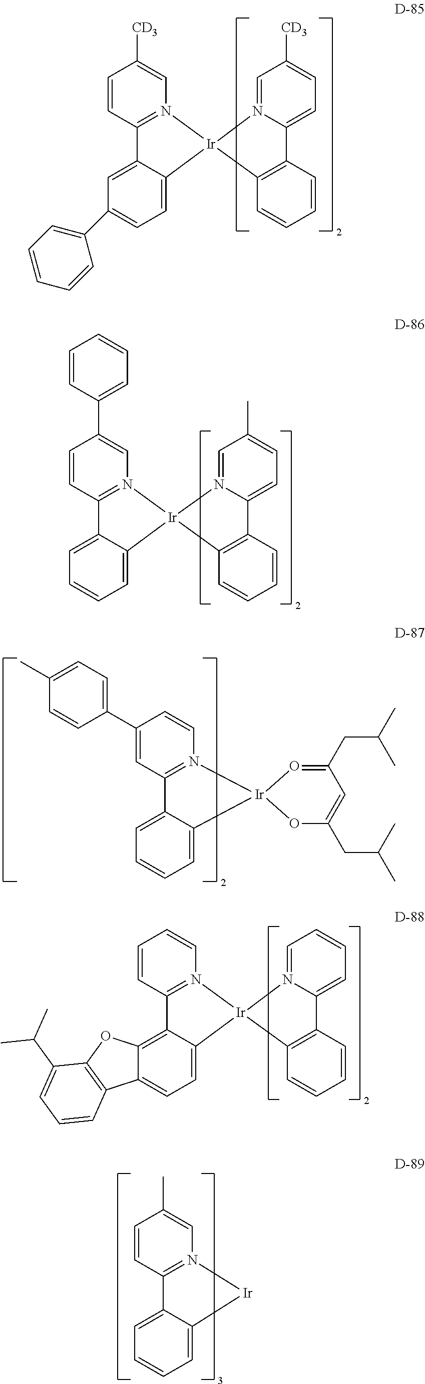

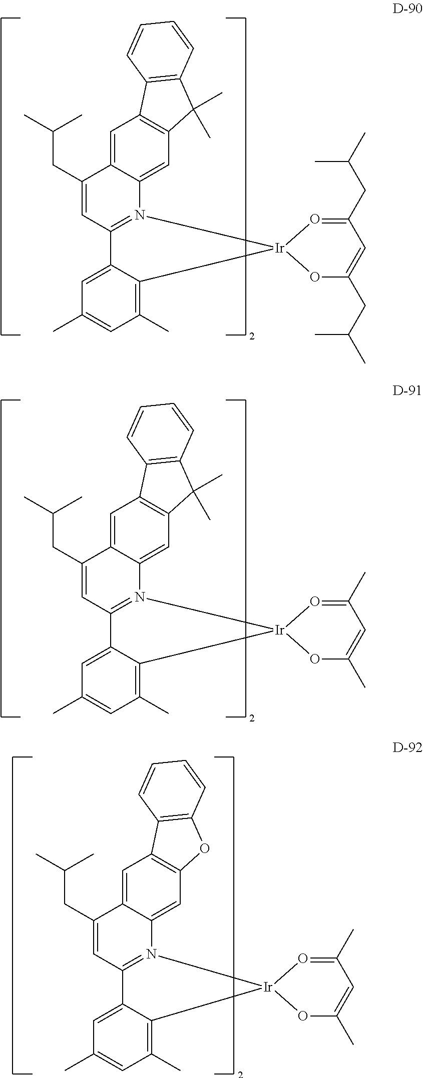

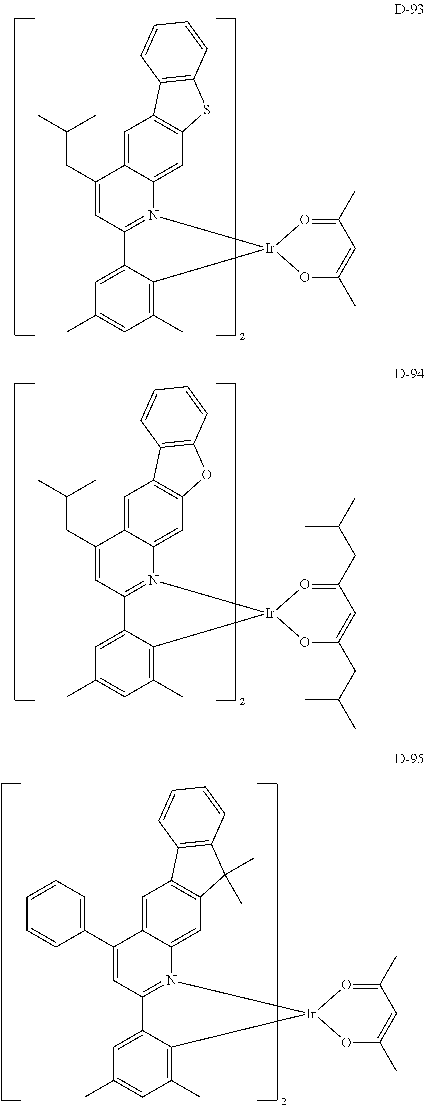

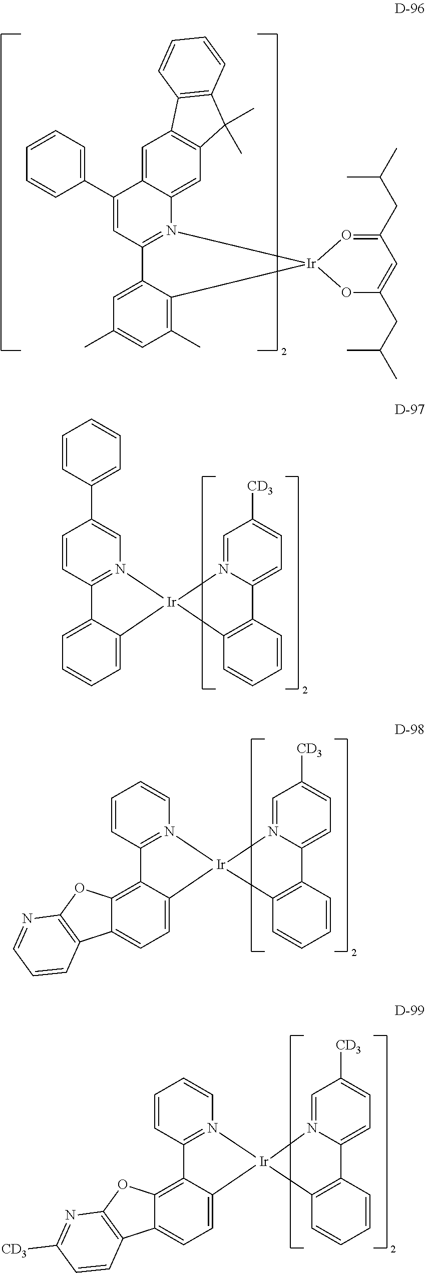

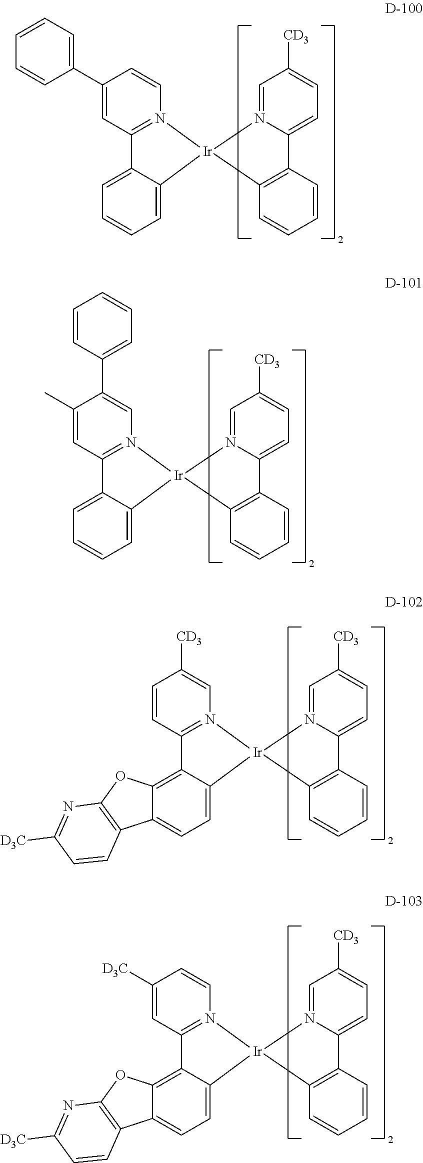

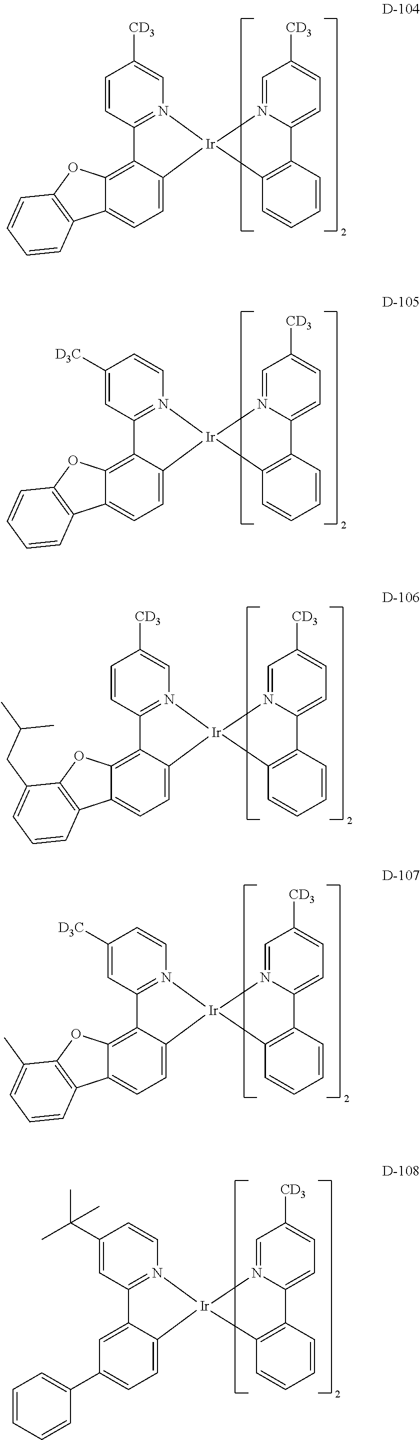

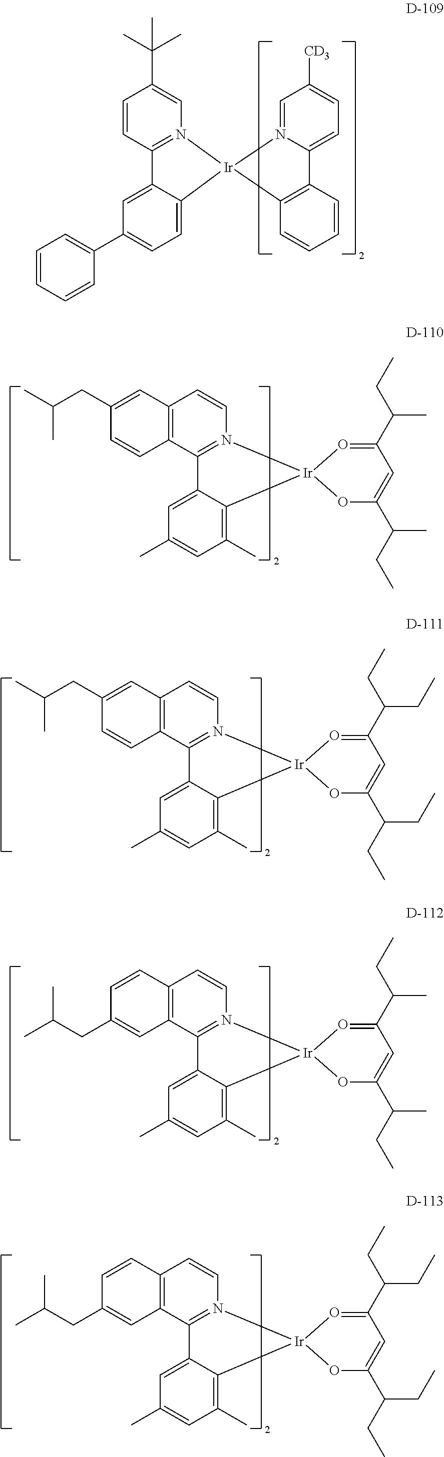

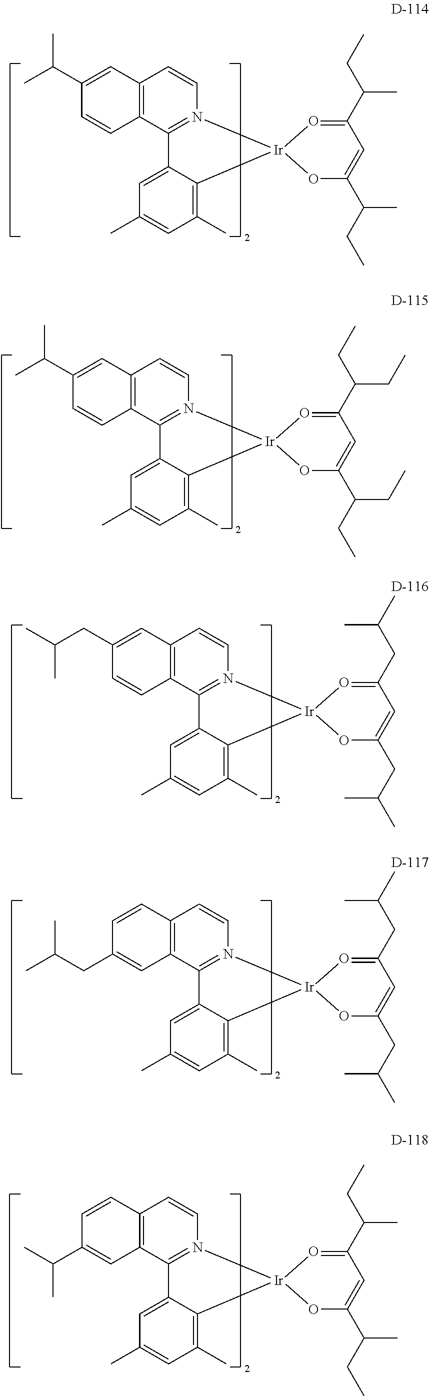

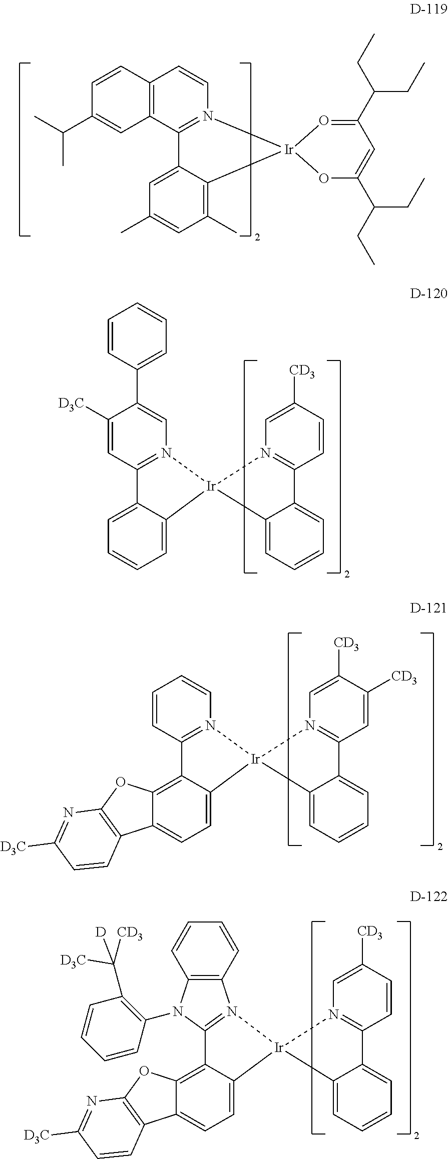

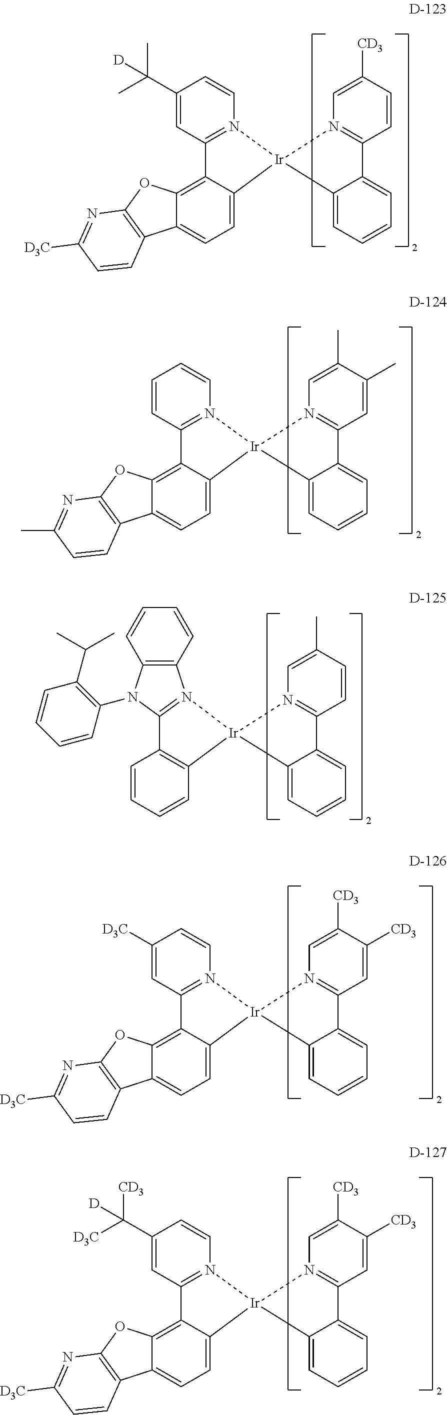

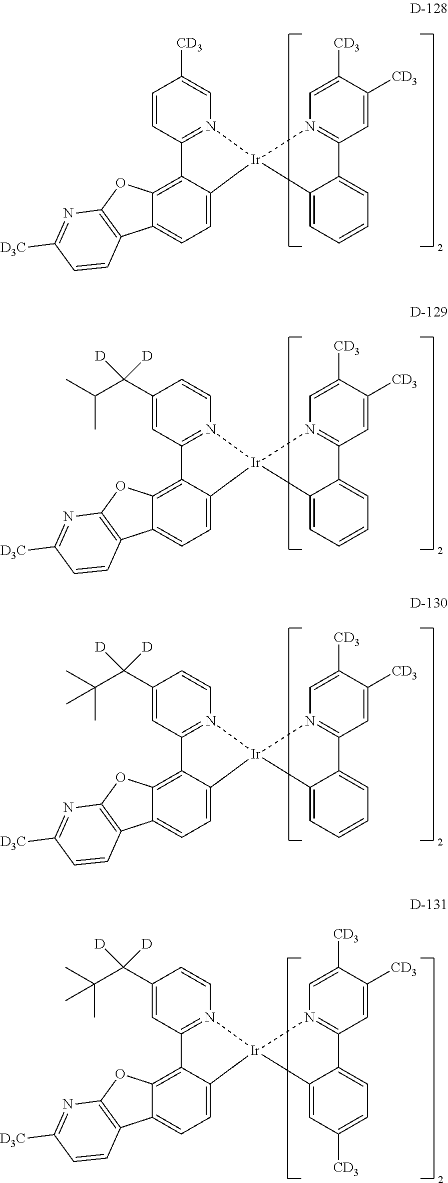

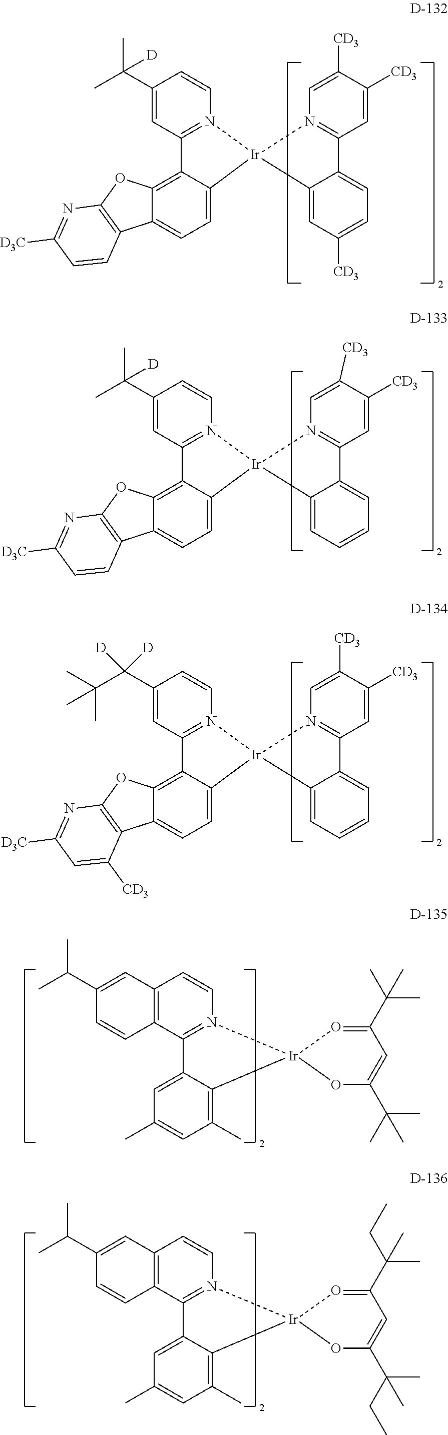

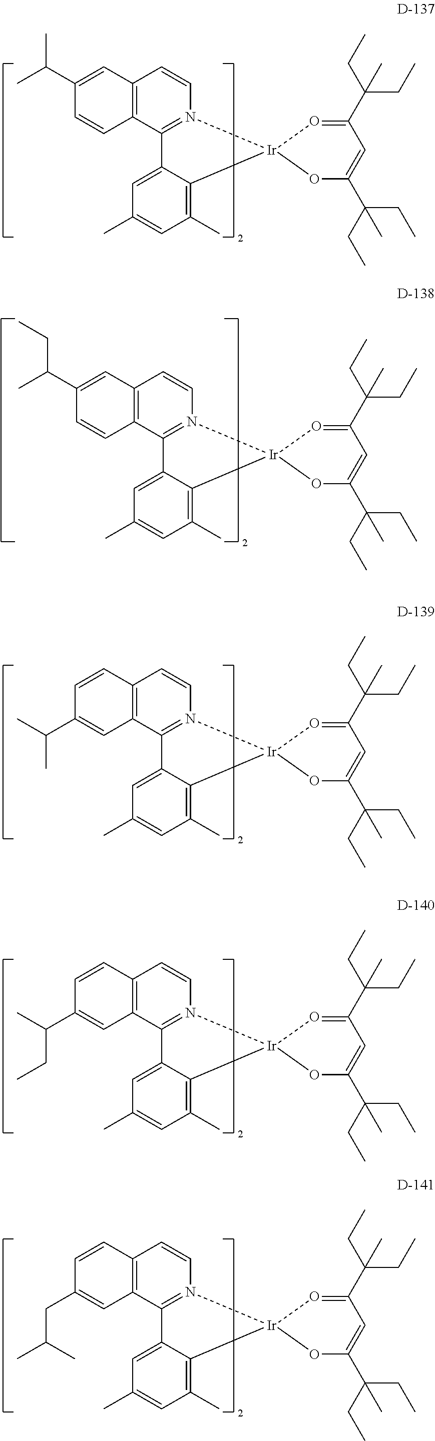

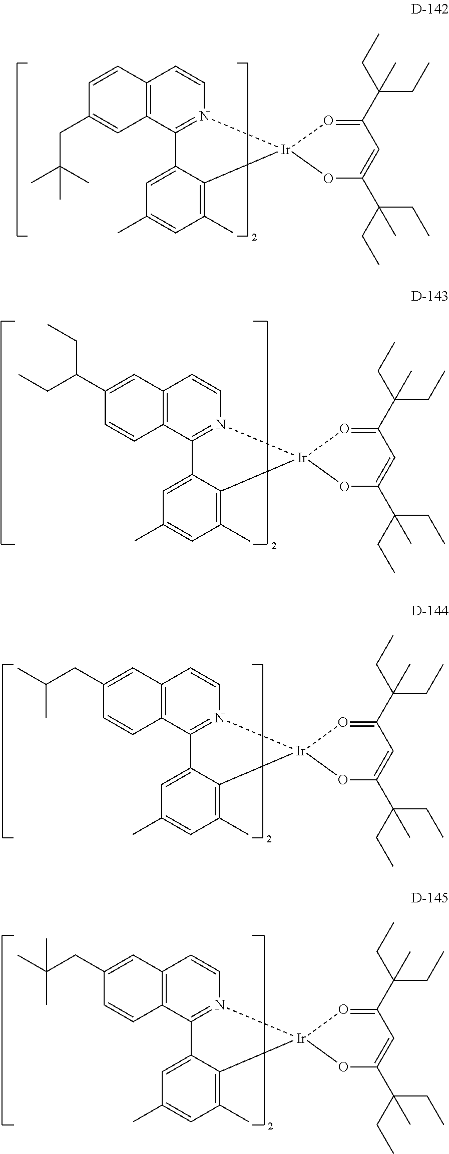

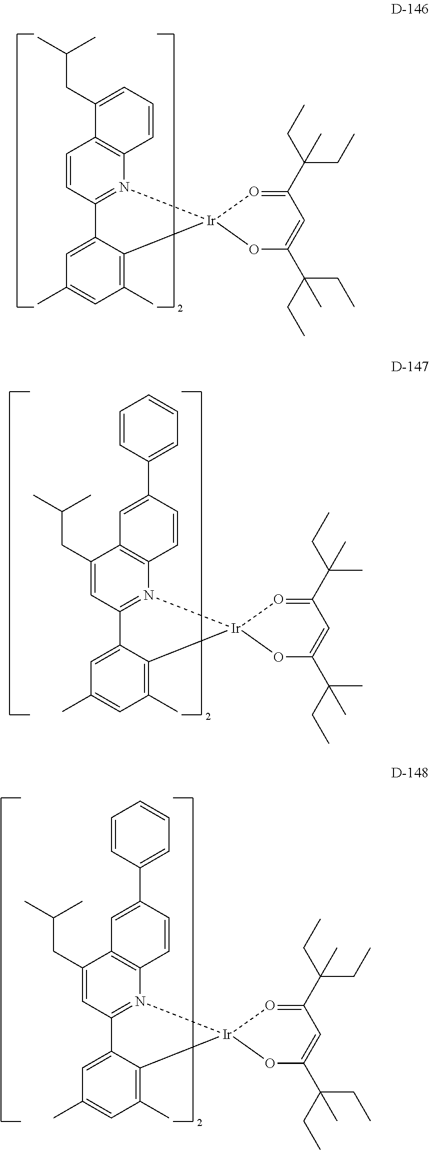

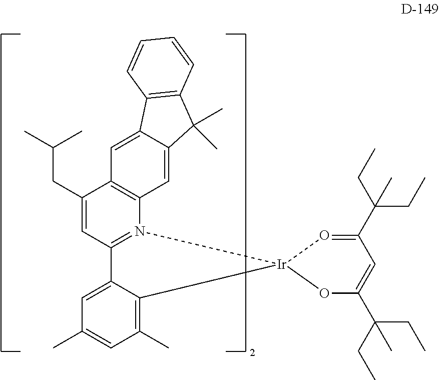

The dopant comprised in the organic electroluminescent device of the present disclosure may use the compound represented by the following Formula D, but is not limited thereto.

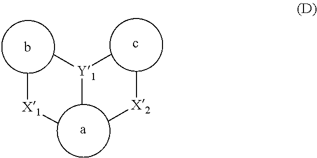

In Formula D,
Y′₁ represents B or N;
X′₁ and X′₂ each independently represent O, S, NR′, or BR′;
ring a, ring b, and ring c each independently represent a substituted or unsubstituted aromatic hydrocarbon ring having 5 to 50 carbon atoms, a substituted or unsubstituted aromatic hetero ring having 2 to 50 carbon atoms, or a mixed ring of a substituted or unsubstituted aliphatic ring(s) having 3 to 30 carbon atoms and a substituted or unsubstituted aromatic ring(s) having 3 to 30 carbon atoms;
R′ each independently represents hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L′₄—N—(Ar′₄)(Ar′₅); or may be linked to an adjacent substituent(s) to form a ring(s);
L′₄ represents a single bond, a substituted or unsubstituted (C₆-C₃₀)arylene, or a substituted or unsubstituted (3- to 30-membered)heteroarylene; and
Ar′₄ and Ar′₅ each independently represent hydrogen, a substituted or unsubstituted (C₁-C₃₀)alkyl, a substituted or unsubstituted (C₂-C₃₀)alkenyl, a substituted or unsubstituted fused ring group of a (C₃-C₃₀) aliphatic ring(s) and a (C₆-C₃₀) aromatic ring(s), a substituted or unsubstituted (C₆-C₃₀)aryl, or a substituted or unsubstituted (3- to 30-membered)heteroaryl.

According to one embodiment of the present disclosure, Formula D may be represented by the following Formula D-1.

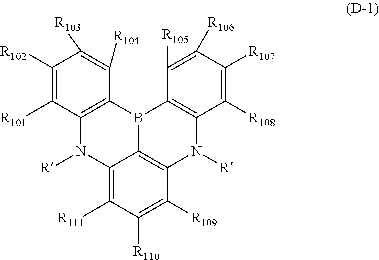

In Formula D-1,
R₁₀₁ to R₁₁₁ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L′₄—N—(Ar′₄)(Ar′₅); or may be linked to an adjacent substituent(s) to form a ring(s);
R′ each independently represents hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L′₄—N—(Ar′₄)(Ar′₅); or may be linked to at least one of R₁₀₁, R₁₀₈, R₁₀₉, R₁₁₁ to form a ring(s);
L′₄ each independently represents a single bond, a substituted or unsubstituted (C₆-C₃₀)arylene, or a substituted or unsubstituted (3- to 30-membered)heteroarylene; and
Ar′₄ and Ar′₅ each independently represent hydrogen, a substituted or unsubstituted (C₁-C₃₀)alkyl, a substituted or unsubstituted (C₂-C₃₀)alkenyl, a substituted or unsubstituted fused ring group of a (C₃-C₃₀) aliphatic ring(s) and a (C₆-C₃₀) aromatic ring(s), a substituted or unsubstituted (C₆-C₃₀)aryl, or a substituted or unsubstituted (3- to 30-membered)heteroaryl.

Preferably, R₁₀₁ to R₁₁₁ each independently represent hydrogen, deuterium, a substituted or unsubstituted (C₁-C₂₀)alkyl, a substituted or unsubstituted (C₆-C₂₅)aryl, a substituted or unsubstituted (5- to 20-membered)heteroaryl, or -L′₄—N—(Ar′₄)(Ar′₅); or may be linked to an adjacent substituent(s) to form a ring(s).

More preferably, R₁₀₁ to R₁₁₁ each independently represent hydrogen, deuterium, an unsubstituted (C₁-C₁₀)alkyl; a (C₆-C₁₈)aryl unsubstituted or substituted with at least one of a (C₁-C₁₀)alkyl, a (13- to 18-membered)heteroaryl, and di(C₆-C₁₈)arylamino; a (5- to 18-membered)heteroaryl unsubstituted or substituted with at least one (C₁-C₁₀)alkyl; or -L′₄—N—(Ar′₄)(Ar′₅); or may be linked to an adjacent substituent(s) to form a ring(s). For example, R₁₀₁ to R₁₁₁ each independently may be hydrogen, a methyl, a tert-butyl, a substituted or unsubstituted phenyl, a biphenyl, a terphenyl, a triphenylenyl, a carbazolyl, a phenoxazinyl, a phenothiazinyl, a dimethylacridinyl, a dimethylxanthenyl, a diphenylamino unsubstituted or substituted with at least one of a methyl and a diphenylamino, a phenylnaphthylamino, a divinylphenylamino, a phenylamino substituted with a phenylcarbazolyl or a dibenzofuranyl, a (17- to 21-membered)heteroaryl substituted with at least one of a methyl and a phenyl; or may be linked to an adjacent substituent(s) to form a benzene ring, an indole ring substituted with at least one of a phenyl and a diphenylamino, a benzofuran ring, a benzothiophene ring, or a 19-membered hetero ring substituted with at least one methyl. The substituted phenyl may be substituted with at least one of a methyl, a carbazolyl, a dibenzofuranyl, a diphenylamino, a phenoxazinyl, a phenothiazinyl, and a dimethylacridinyl.

According to another embodiment of the present disclosure, Formula D may be represented by the following Formula D-2 or D-3.

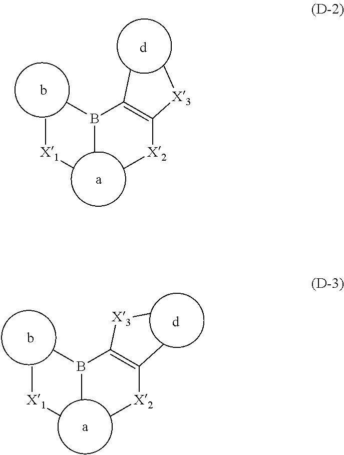

In Formulas D-2 and D-3,
X₁ and X′₂ each independently represent O, S, NR′, or BR′;
X′₃ represents O or S;
ring a, ring b, and ring d each independently represent a substituted or unsubstituted aromatic hydrocarbon ring having 5 to 50 carbon atoms, a substituted or unsubstituted aromatic hetero ring having 2 to 50 carbon atoms, or a mixed ring of a substituted or unsubstituted aliphatic ring(s) having 3 to 30 carbon atoms and a substituted or unsubstituted aromatic ring(s) having 3 to 30 carbon atoms; and
R′, L′₄, Ar′₄, and Ar′₅ are as defined in Formula D above.

According to one embodiment, the specific examples of the compound represented by Formula D include the following compounds, but are not limited thereto.

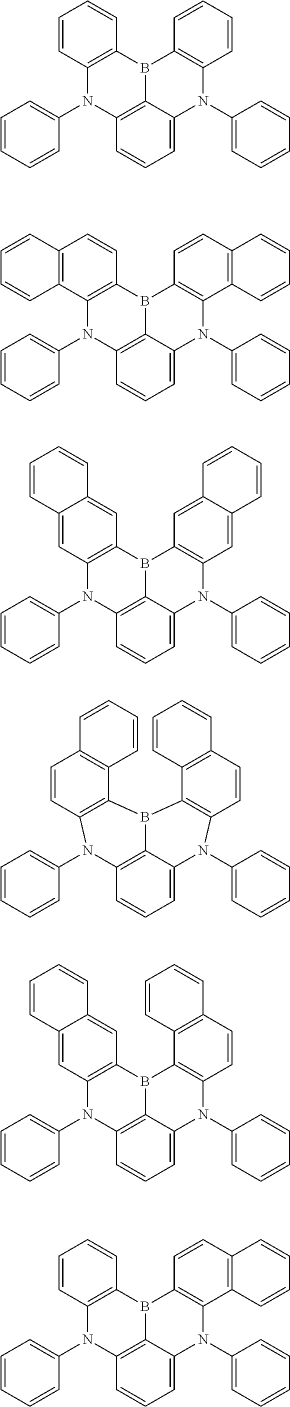 [SMILES: c1ccc(N2c3ccccc3B3c4ccccc4N(c4ccccc4)c4cccc2c43)cc1 ; c1ccc(N2c3cccc4c3B(c3ccc5ccccc5c32)c2ccc3ccccc3c2N4c2ccccc2)cc1 ; c1ccc(N2c3cc4ccccc4cc3B3c4cc5ccccc5cc4N(c4ccccc4)c4cccc2c43)cc1 ; c1ccc(N2c3cccc4c3B(c3c2ccc2ccccc32)c2c(ccc3ccccc23)N4c2ccccc2)cc1 ; c1ccc(N2c3cc4ccccc4cc3B3c4c2cccc4N(c2ccccc2)c2ccc4ccccc4c23)cc1 ; c1ccc(N2c3ccccc3B3c4ccc5ccccc5c4N(c4ccccc4)c4cccc2c43)cc1]

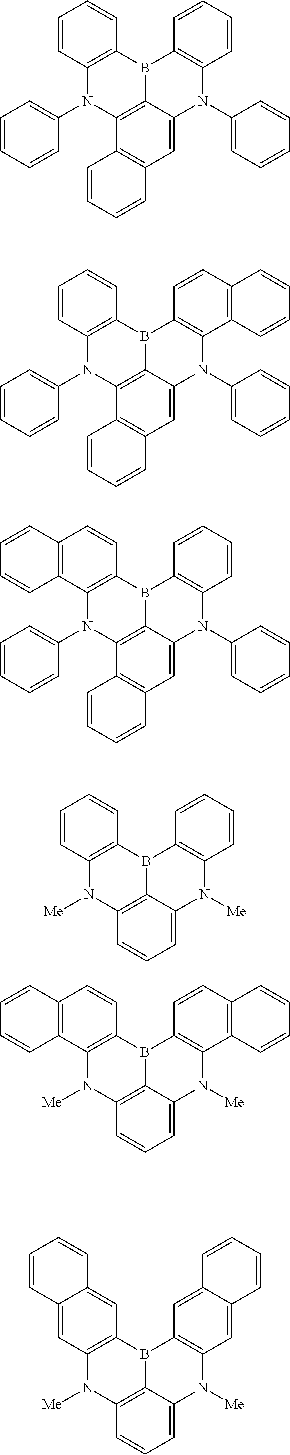 [SMILES: c1ccc(N2c3ccccc3B3c4ccccc4N(c4ccccc4)c4c3c2cc2ccccc42)cc1 ; c1ccc(N2c3cc4ccccc4c4c3B(c3ccccc3N4c3ccccc3)c3ccc4ccccc4c32)cc1 ; c1ccc(N2c3ccccc3B3c4ccc5ccccc5c4N(c4ccccc4)c4c3c2cc2ccccc42)cc1 ; CN1c2ccccc2B2c3ccccc3N(C)c3cccc1c32 ; CN1c2cccc3c2B(c2ccc4ccccc4c21)c1ccc2ccccc2c1N3C ; CN1c2cc3ccccc3cc2B2c3cc4ccccc4cc3N(C)c3cccc1c32]

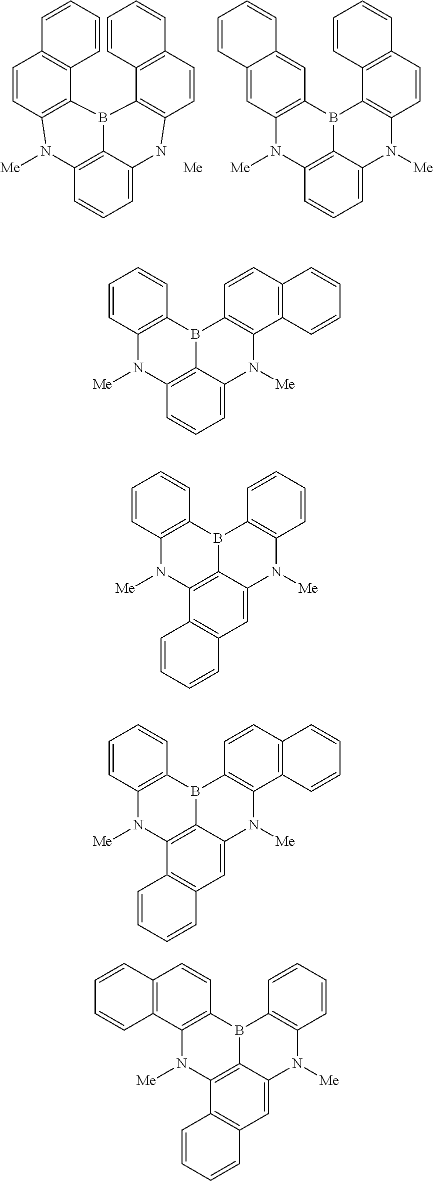

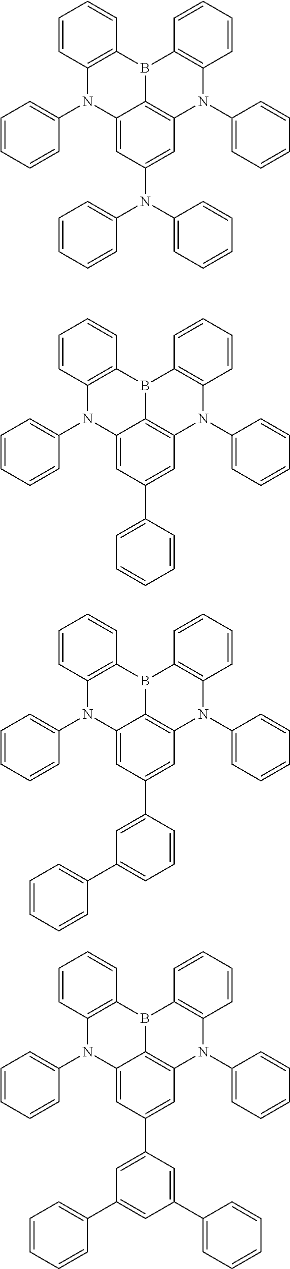

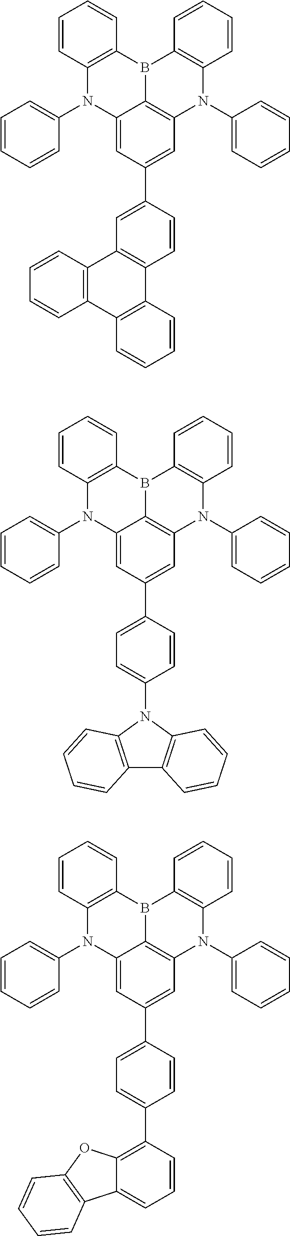 [SMILES: c1ccc(N2c3ccccc3B3c4ccccc4N(c4ccccc4)c4cc(-c5ccc6c7ccccc7c7ccccc7c6c5)cc2c43)cc1 ; c1ccc(N2c3ccccc3B3c4ccccc4N(c4ccccc4)c4cc(-c5ccc(-n6c7ccccc7c7ccccc76)cc5)cc2c43)cc1 ; c1ccc(N2c3ccccc3B3c4ccccc4N(c4ccccc4)c4cc(-c5ccc(-c6cccc7c6oc6ccccc67)cc5)cc2c43)cc1]

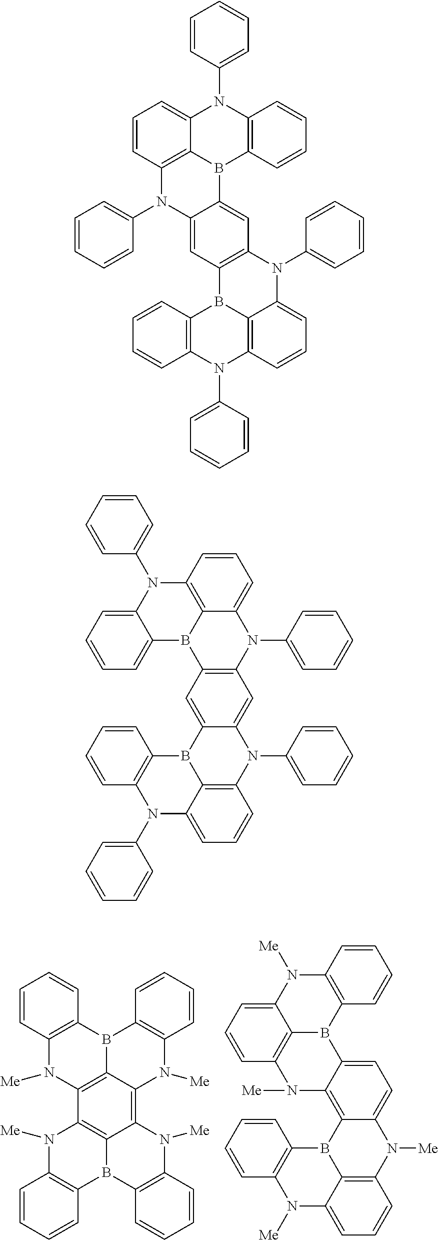

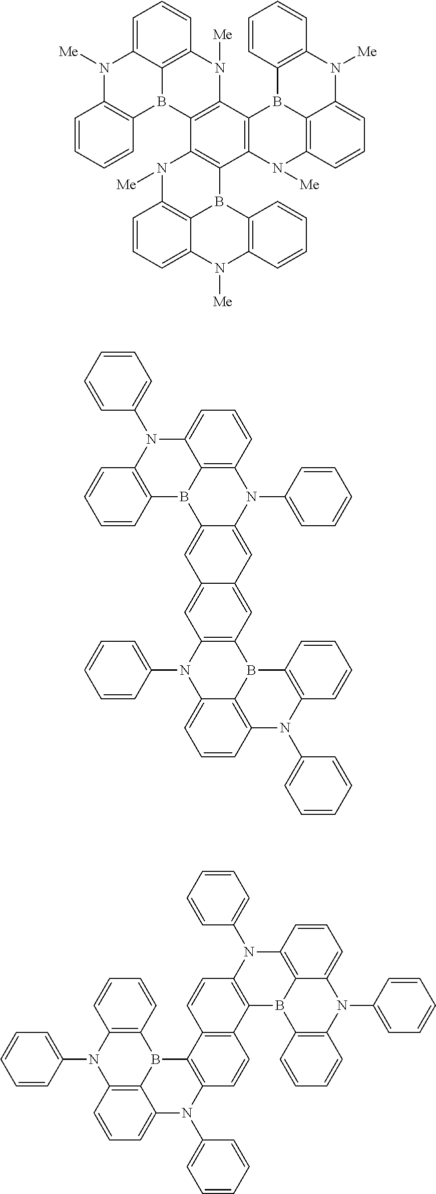 [SMILES: CN1c2ccccc2B2c3c1cccc3N(C)c1c3c(c4c(c12)N(C)c1cccc2c1B4c1ccccc1N2C)N(C)c1cccc2c1B3c1ccccc1N2C ; c1ccc(N2c3ccccc3B3c4cc5cc6c(cc5cc4N(c4ccccc4)c4cccc2c43)B2c3ccccc3N(c3ccccc3)c3cccc(c32)N6c2ccccc2)cc1 ; c1ccc(N2c3ccccc3B3c4c2cccc4N(c2ccccc2)c2ccc4c5c(ccc4c23)N(c2ccccc2)c2cccc3c2B5c2ccccc2N3c2ccccc2)cc1]

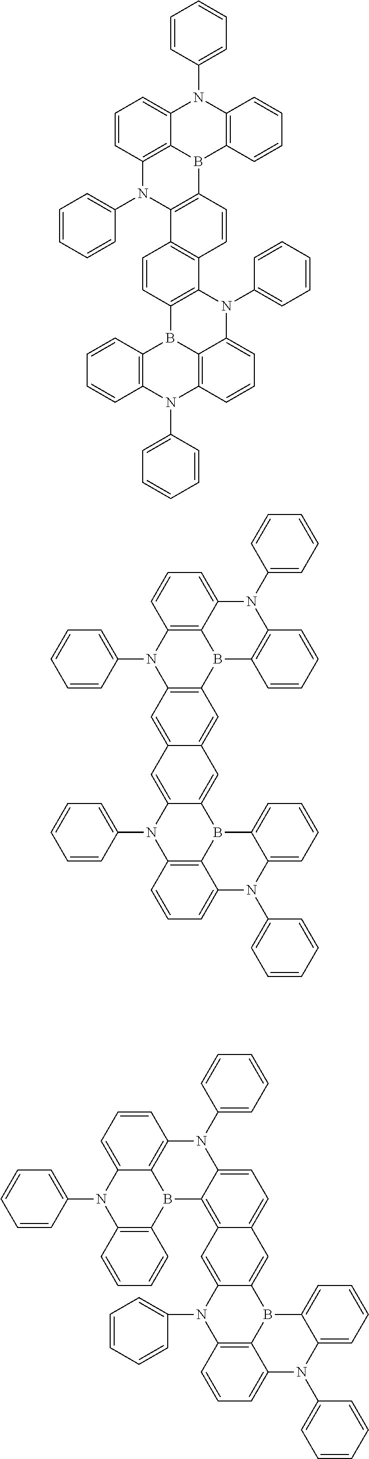 [SMILES: c1ccc(N2c3ccccc3B3c4ccc5c6c(ccc5c4N(c4ccccc4)c4cccc2c43)B2c3ccccc3N(c3ccccc3)c3cccc(c32)N6c2ccccc2)cc1 ; c1ccc(N2c3ccccc3B3c4cc5cc6c(cc5cc4N(c4ccccc4)c4cccc2c43)N(c2ccccc2)c2cccc3c2B6c2ccccc2N3c2ccccc2)cc1 ; c1ccc(N2c3ccccc3B3c4cc5ccc6c(c5cc4N(c4ccccc4)c4cccc2c43)B2c3ccccc3N(c3ccccc3)c3cccc(c32)N6c2ccccc2)cc1]

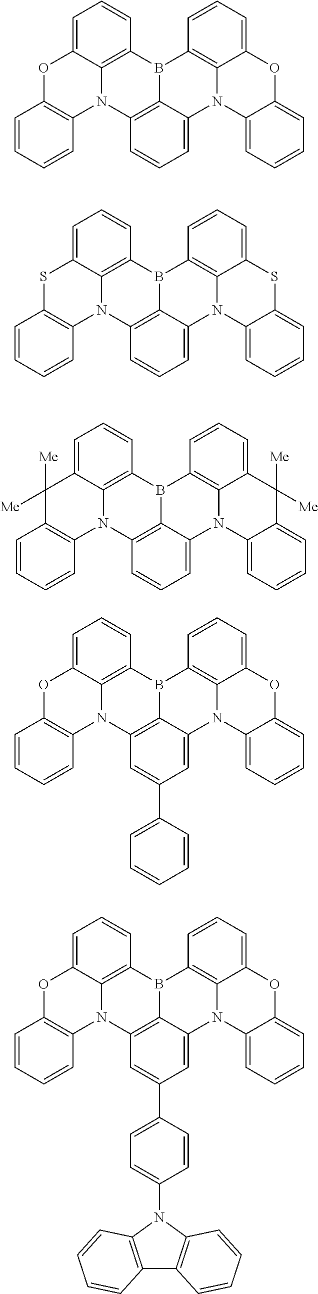 [SMILES: c1ccc2c(c1)Oc1cccc3c1N2c1cccc2c1B3c1cccc3c1N2c1ccccc1O3 ; c1ccc2c(c1)Sc1cccc3c1N2c1cccc2c1B3c1cccc3c1N2c1ccccc1S3 ; CC1(C)c2ccccc2N2c3cccc4c3B(c3cccc1c32)c1cccc2c1N4c1ccccc1C2(C)C ; c1ccc(-c2cc3c4c(c2)N2c5ccccc5Oc5cccc(c52)B4c2cccc4c2N3c2ccccc2O4)cc1 ; c1ccc2c(c1)Oc1cccc3c1N2c1cc(-c2ccc(-n4c5ccccc5c5ccccc54)cc2)cc2c1B3c1cccc3c1N2c1ccccc1O3]

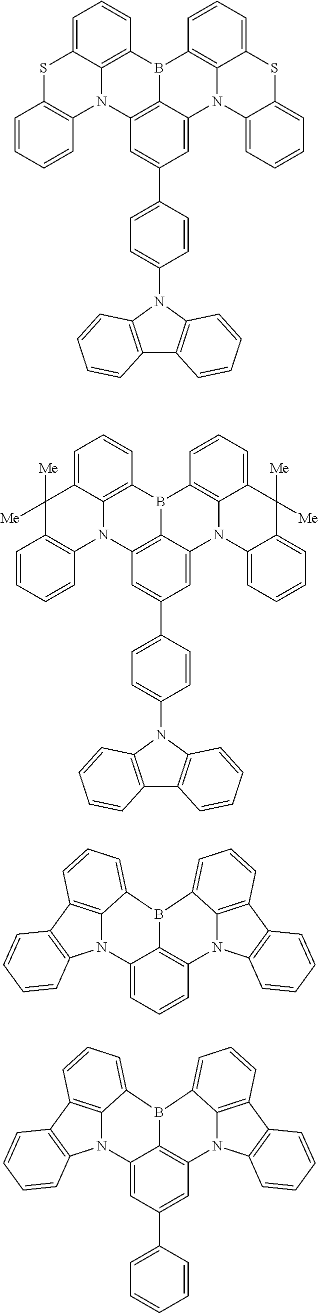

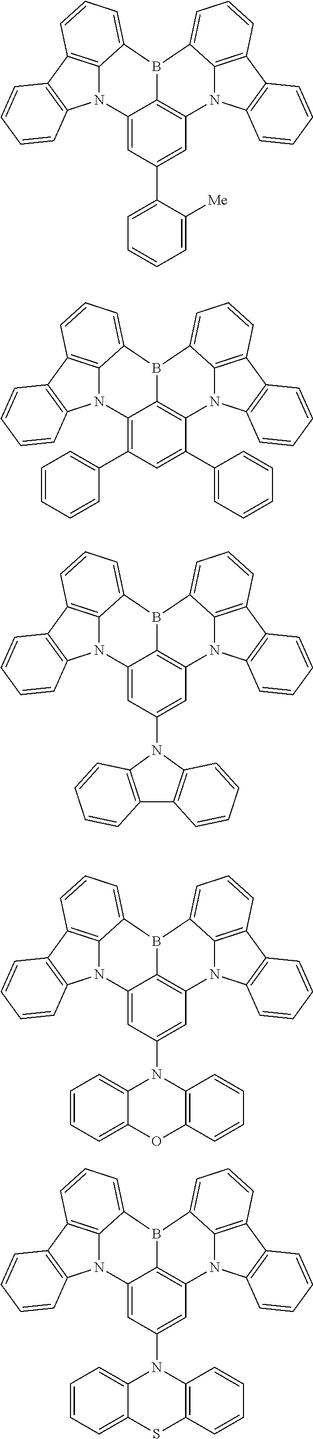

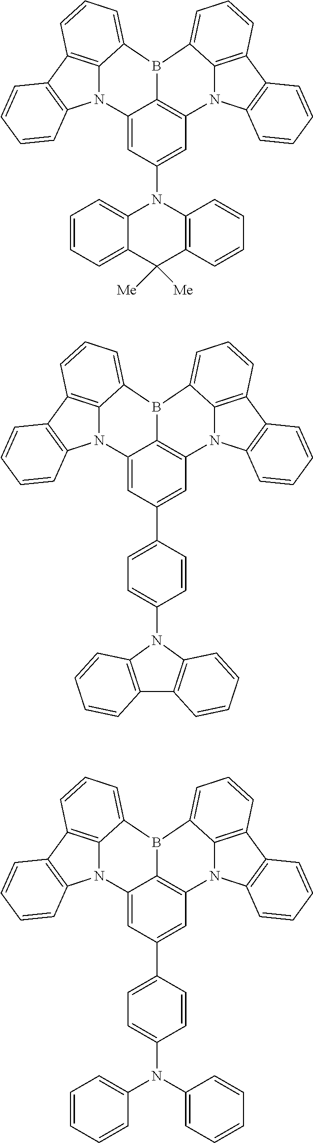 [SMILES: CC1(C)c2ccccc2N(c2cc3c4c(c2)-n2c5ccccc5c5cccc(c52)B4c2cccc4c5ccccc5n-3c24)c2ccccc21 ; c1ccc2c(c1)c1ccccc1n2-c1ccc(-c2cc3c4c(c2)-n2c5ccccc5c5cccc(c52)B4c2cccc4c5ccccc5n-3c24)cc1 ; c1ccc(N(c2ccccc2)c2ccc(-c3cc4c5c(c3)-n3c6ccccc6c6cccc(c63)B5c3cccc5c6ccccc6n-4c35)cc2)cc1]

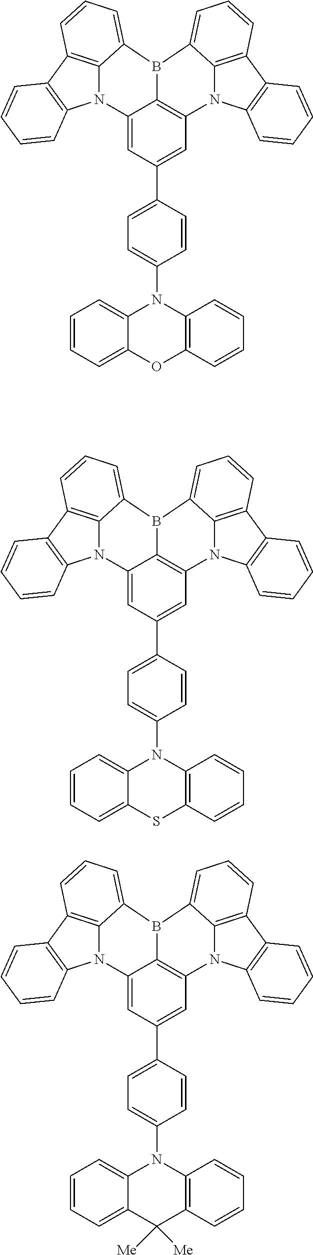

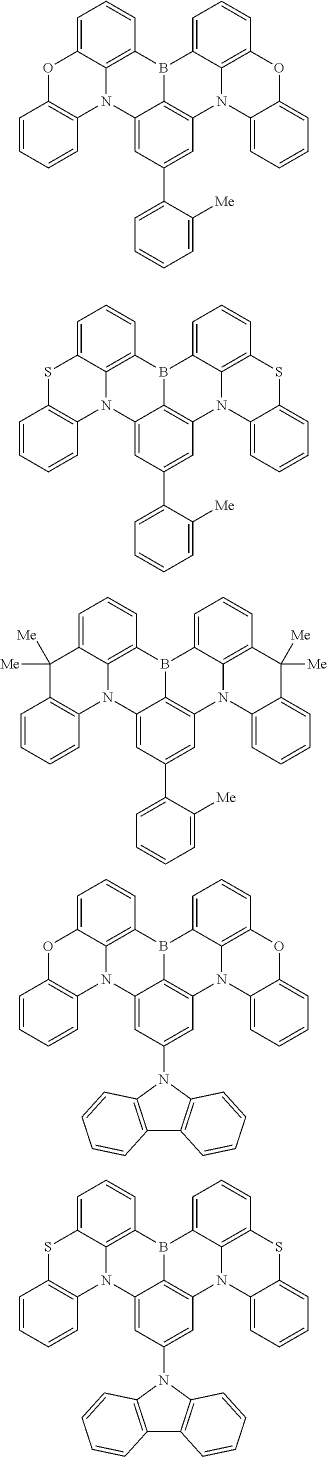

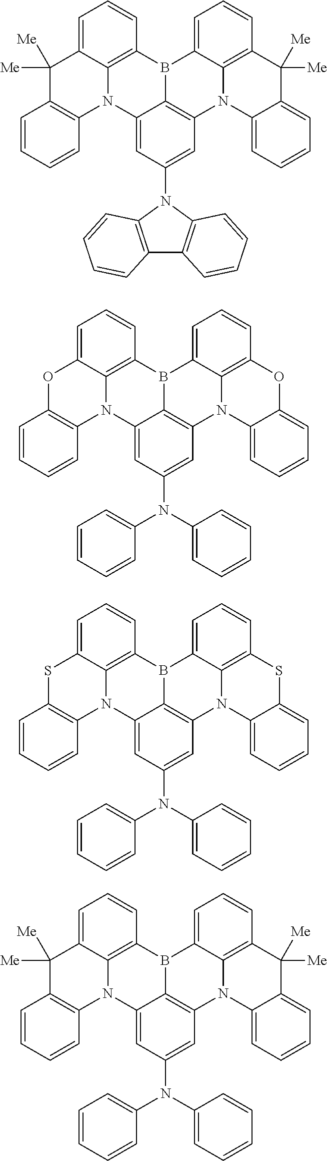

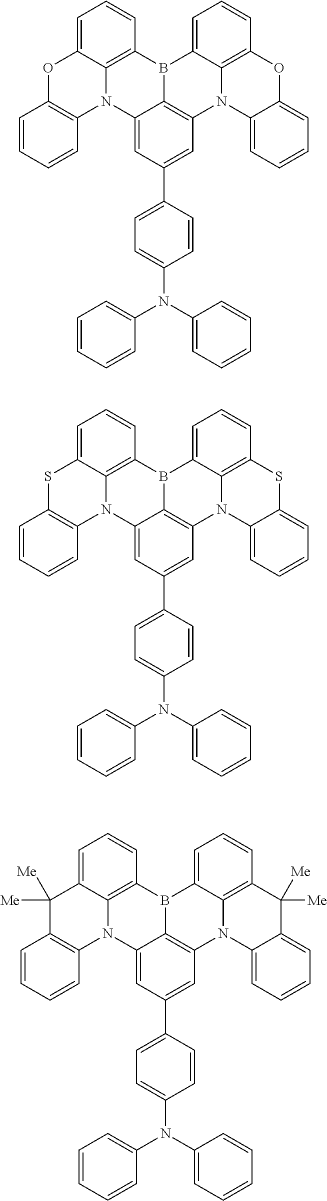

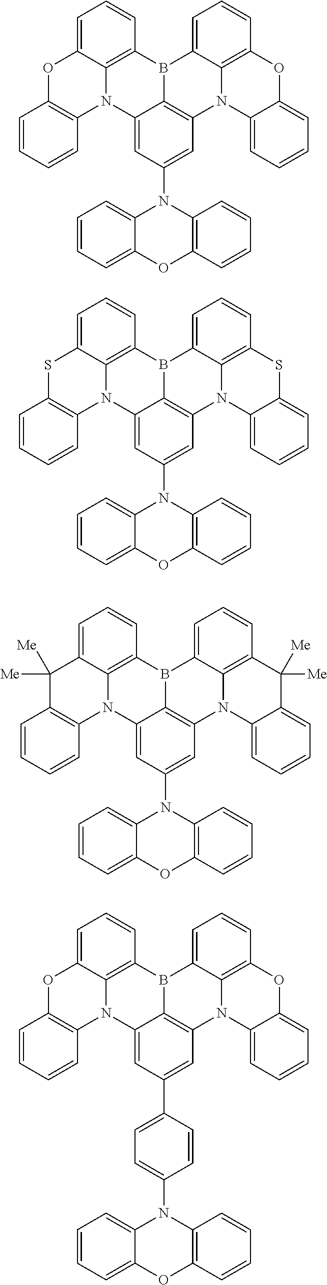

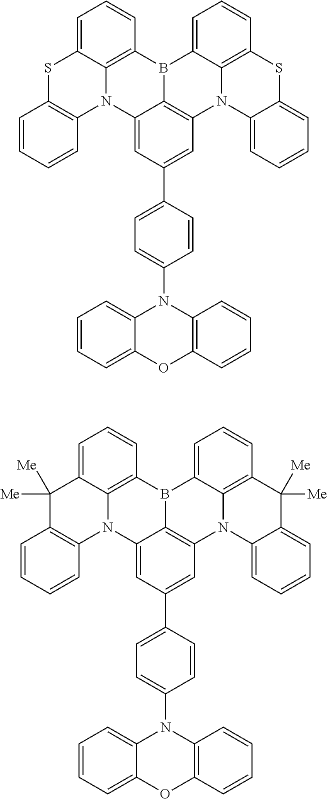 [SMILES: c1ccc2c(c1)Oc1ccccc1N2c1ccc(-c2cc3c4c(c2)N2c5ccccc5Sc5cccc(c52)B4c2cccc4c2N3c2ccccc2S4)cc1 ; CC1(C)c2ccccc2N2c3cc(-c4ccc(N5c6ccccc6Oc6ccccc65)cc4)cc4c3B(c3cccc1c32)c1cccc2c1N4c1ccccc1C2(C)C]

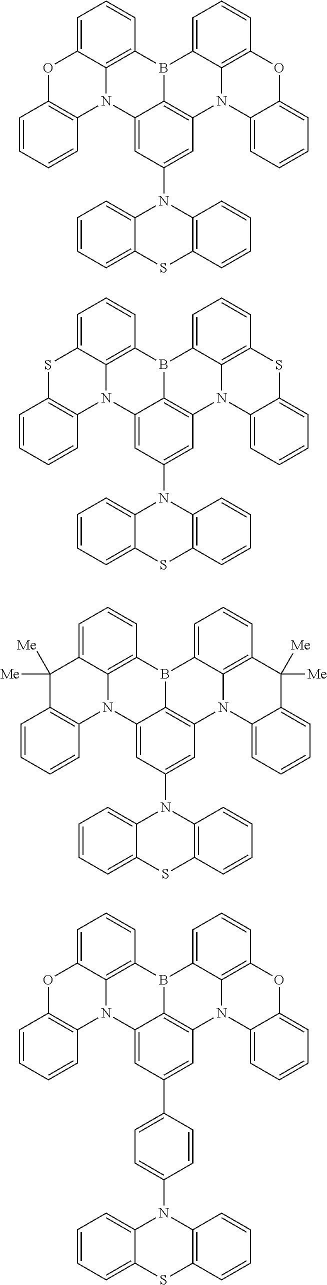

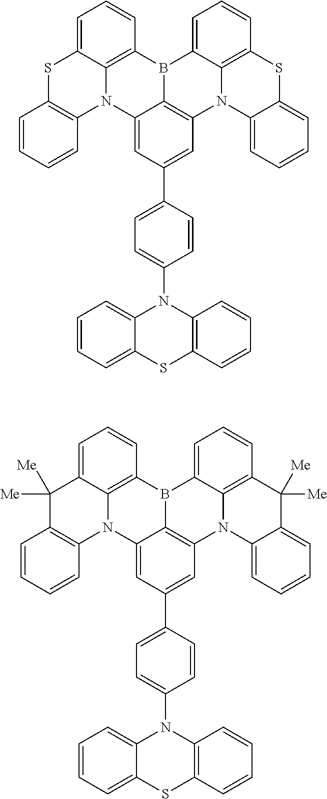 [SMILES: c1ccc2c(c1)Sc1ccccc1N2c1ccc(-c2cc3c4c(c2)N2c5ccccc5Sc5cccc(c52)B4c2cccc4c2N3c2ccccc2S4)cc1 ; CC1(C)c2ccccc2N2c3cc(-c4ccc(N5c6ccccc6Sc6ccccc65)cc4)cc4c3B(c3cccc1c32)c1cccc2c1N4c1ccccc1C2(C)C]

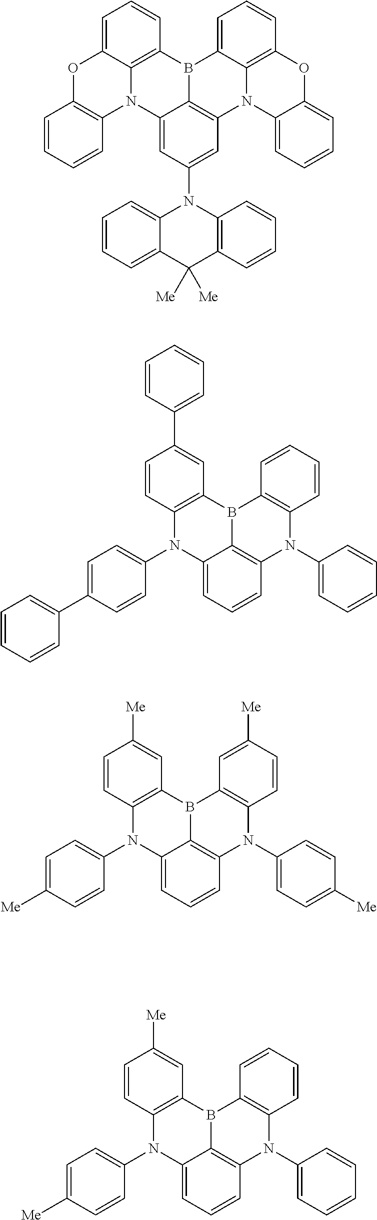 [SMILES: CC1(C)c2ccccc2N(c2cc3c4c(c2)N2c5ccccc5Oc5cccc(c52)B4c2cccc4c2N3c2ccccc2O4)c2ccccc21 ; c1ccc(-c2ccc(N3c4ccc(-c5ccccc5)cc4B4c5ccccc5N(c5ccccc5)c5cccc3c54)cc2)cc1 ; Cc1ccc(N2c3ccc(C)cc3B3c4cc(C)ccc4N(c4ccc(C)cc4)c4cccc2c43)cc1 ; Cc1ccc(N2c3ccc(C)cc3B3c4ccccc4N(c4ccccc4)c4cccc2c43)cc1]

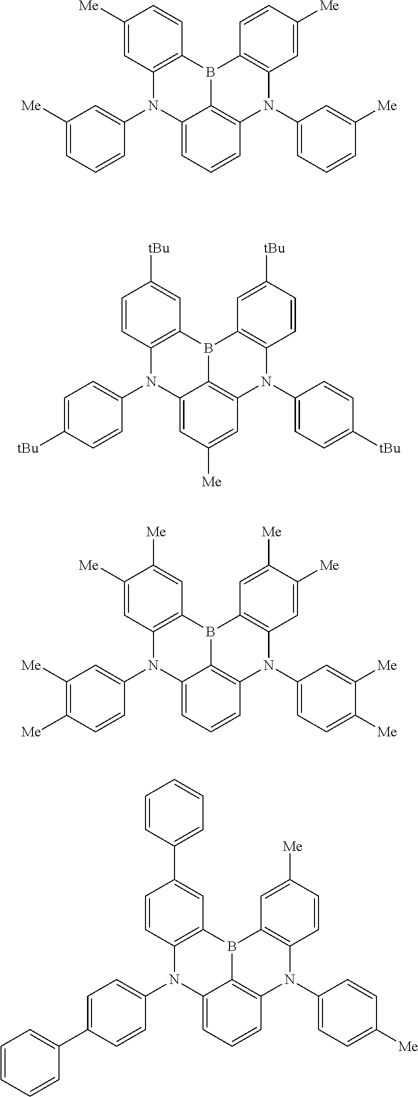 [SMILES: Cc1cccc(N2c3cc(C)ccc3B3c4ccc(C)cc4N(c4cccc(C)c4)c4cccc2c43)c1 ; Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; Cc1ccc(N2c3cc(C)c(C)cc3B3c4cc(C)c(C)cc4N(c4ccc(C)c(C)c4)c4cccc2c43)cc1C ; Cc1ccc(N2c3ccc(C)cc3B3c4cc(-c5ccccc5)ccc4N(c4ccc(-c5ccccc5)cc4)c4cccc2c43)cc1]

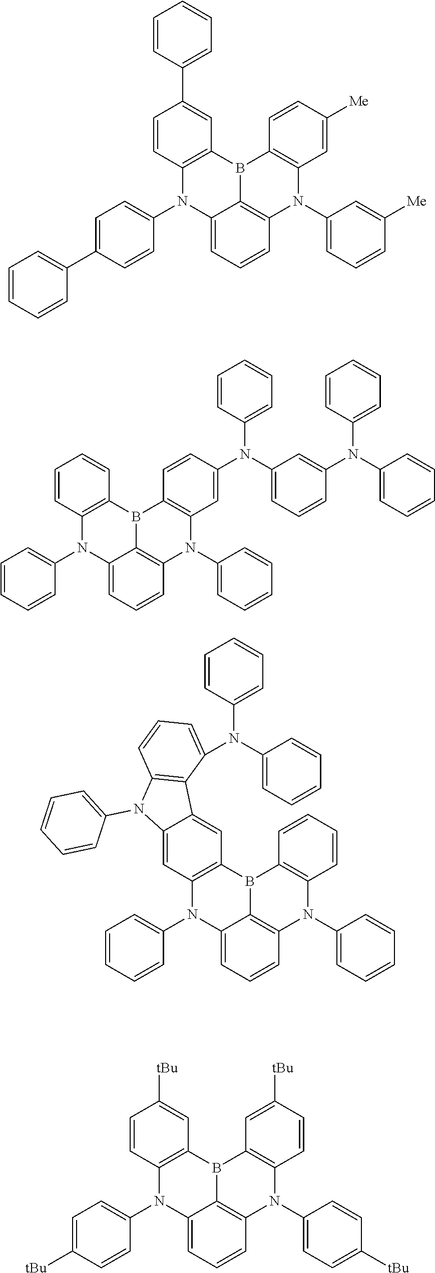

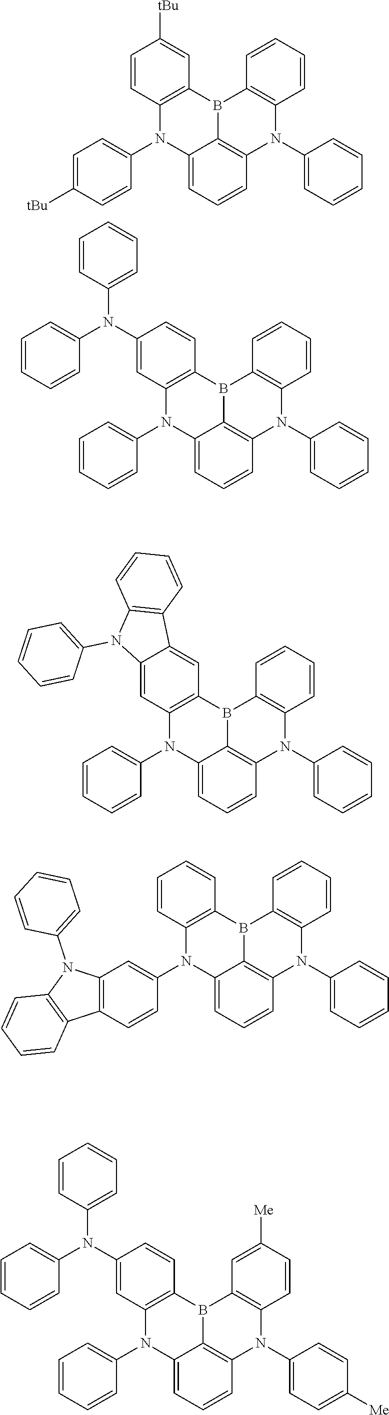

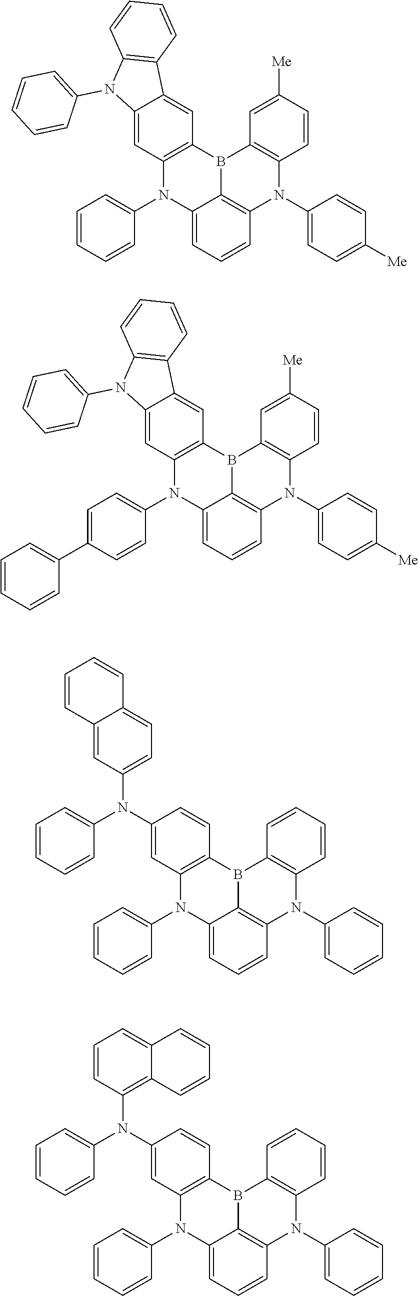 [SMILES: Cc1ccc(N2c3ccc(C)cc3B3c4cc5c6ccccc6n(-c6ccccc6)c5cc4N(c4ccccc4)c4cccc2c43)cc1 ; Cc1ccc(N2c3ccc(C)cc3B3c4cc5c6ccccc6n(-c6ccccc6)c5cc4N(c4ccc(-c5ccccc5)cc4)c4cccc2c43)cc1 ; c1ccc(N(c2ccc3c(c2)N(c2ccccc2)c2cccc4c2B3c2ccccc2N4c2ccccc2)c2ccc3ccccc3c2)cc1 ; c1ccc(N2c3ccccc3B3c4ccc(N(c5ccccc5)c5cccc6ccccc56)cc4N(c4ccccc4)c4cccc2c43)cc1]

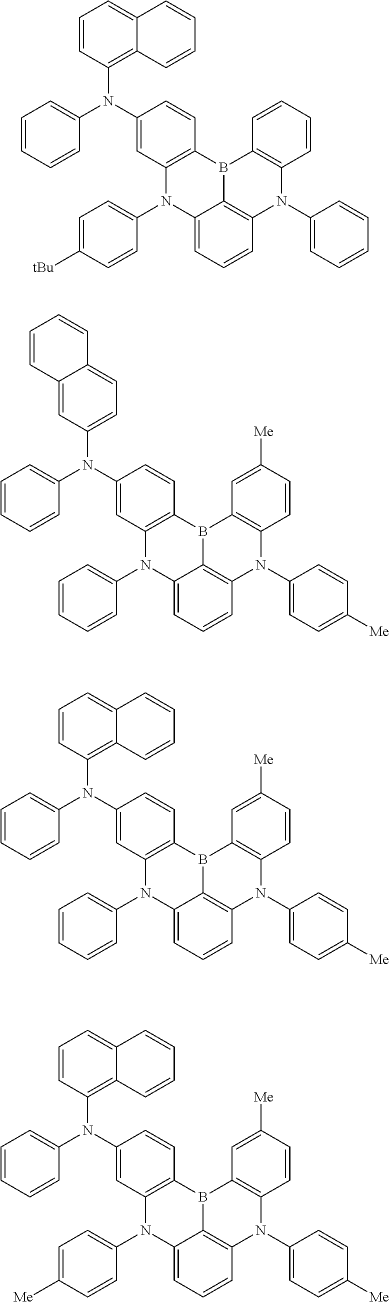 [SMILES: CC(C)(C)c1ccc(N2c3cc(N(c4ccccc4)c4cccc5ccccc45)ccc3B3c4ccccc4N(c4ccccc4)c4cccc2c43)cc1 ; Cc1ccc(N2c3ccc(C)cc3B3c4ccc(N(c5ccccc5)c5ccc6ccccc6c5)cc4N(c4ccccc4)c4cccc2c43)cc1 ; Cc1ccc(N2c3ccc(C)cc3B3c4ccc(N(c5ccccc5)c5cccc6ccccc56)cc4N(c4ccccc4)c4cccc2c43)cc1 ; Cc1ccc(N2c3ccc(C)cc3B3c4ccc(N(c5ccccc5)c5cccc6ccccc56)cc4N(c4ccc(C)cc4)c4cccc2c43)cc1]

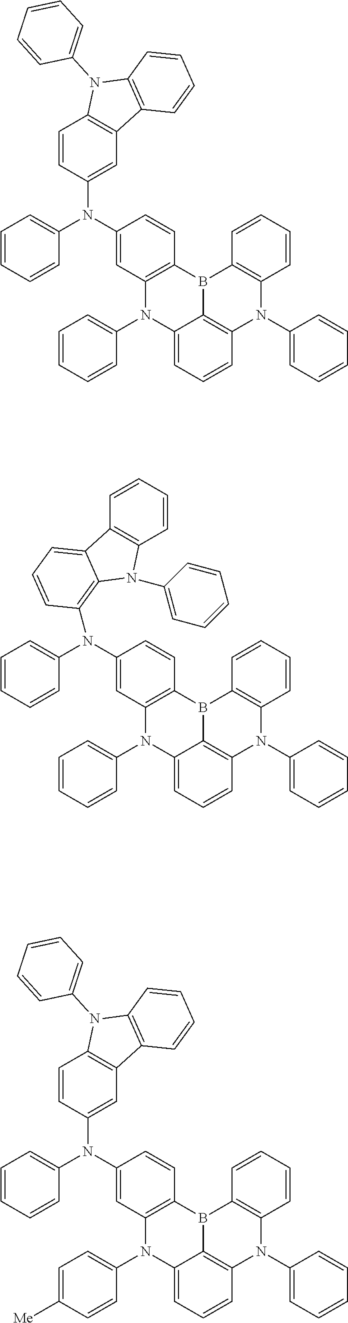 [SMILES: c1ccc(N(c2ccc3c(c2)N(c2ccccc2)c2cccc4c2B3c2ccccc2N4c2ccccc2)c2ccc3c(c2)c2ccccc2n3-c2ccccc2)cc1 ; c1ccc(N2c3ccccc3B3c4ccc(N(c5ccccc5)c5cccc6c7ccccc7n(-c7ccccc7)c56)cc4N(c4ccccc4)c4cccc2c43)cc1 ; Cc1ccc(N2c3cc(N(c4ccccc4)c4ccc5c(c4)c4ccccc4n5-c4ccccc4)ccc3B3c4ccccc4N(c4ccccc4)c4cccc2c43)cc1]

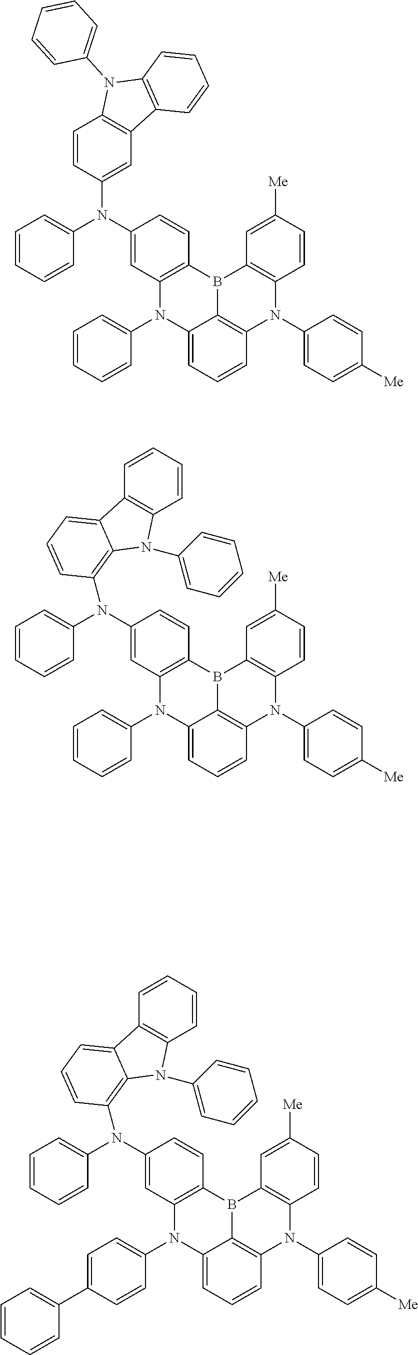 [SMILES: Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1]

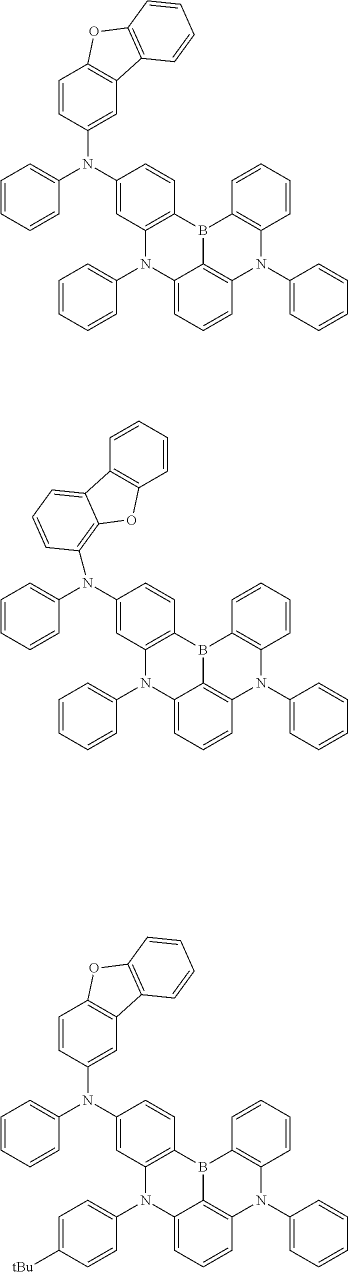 [SMILES: c1ccc(N(c2ccc3c(c2)N(c2ccccc2)c2cccc4c2B3c2ccccc2N4c2ccccc2)c2ccc3oc4ccccc4c3c2)cc1 ; c1ccc(N2c3ccccc3B3c4ccc(N(c5ccccc5)c5cccc6c5oc5ccccc56)cc4N(c4ccccc4)c4cccc2c43)cc1 ; CC(C)(C)c1ccc(N2c3cc(N(c4ccccc4)c4ccc5oc6ccccc6c5c4)ccc3B3c4ccccc4N(c4ccccc4)c4cccc2c43)cc1]

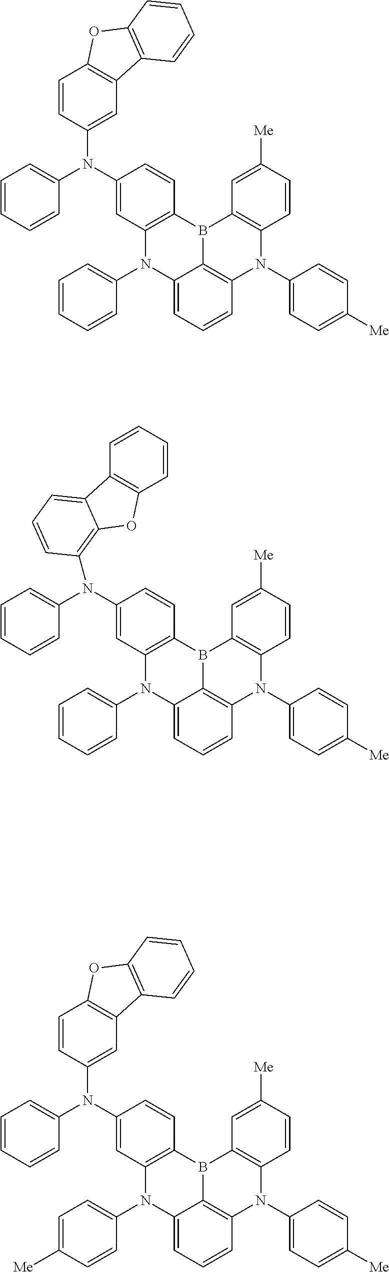 [SMILES: Cc1ccc(N2c3ccc(C)cc3B3c4ccc(N(c5ccccc5)c5ccc6oc7ccccc7c6c5)cc4N(c4ccccc4)c4cccc2c43)cc1 ; Cc1ccc(N2c3ccc(C)cc3B3c4ccc(N(c5ccccc5)c5cccc6c5oc5ccccc56)cc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccc(C)cc4)c4cccc2c43)cc1]

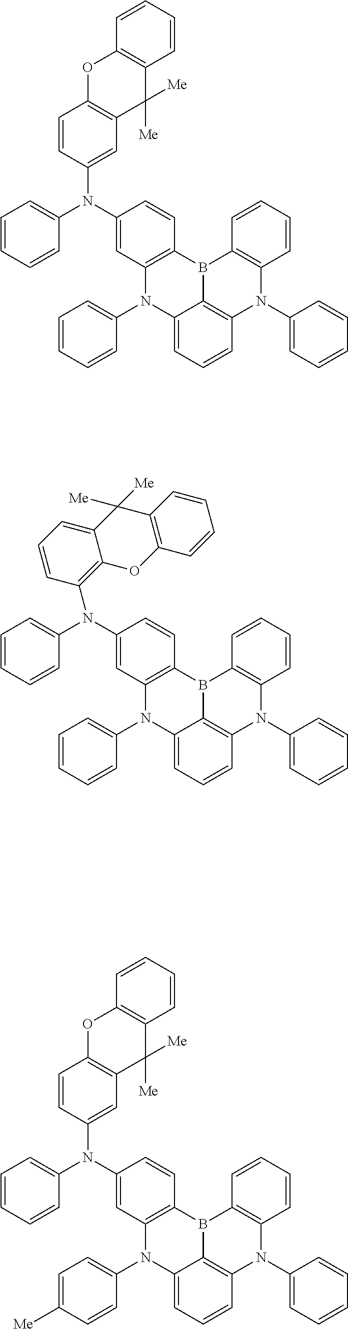 [SMILES: CC1(C)c2ccccc2Oc2ccc(N(c3ccccc3)c3ccc4c(c3)N(c3ccccc3)c3cccc5c3B4c3ccccc3N5c3ccccc3)cc21 ; CC1(C)c2ccccc2Oc2c(N(c3ccccc3)c3ccc4c(c3)N(c3ccccc3)c3cccc5c3B4c3ccccc3N5c3ccccc3)cccc21 ; Cc1ccc(N2c3cc(N(c4ccccc4)c4ccc5c(c4)C(C)(C)c4ccccc4O5)ccc3B3c4ccccc4N(c4ccccc4)c4cccc2c43)cc1]

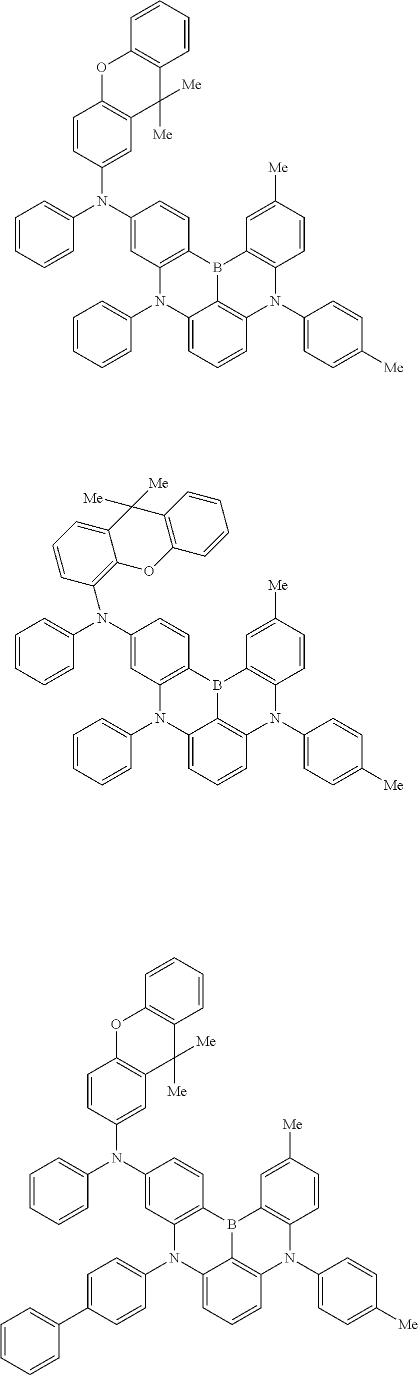 [SMILES: Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1 ; Cc1ccc(N2c3ccc(C)cc3B3c4ccc(N(c5ccccc5)c5cccc6c5Oc5ccccc5C6(C)C)cc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1]

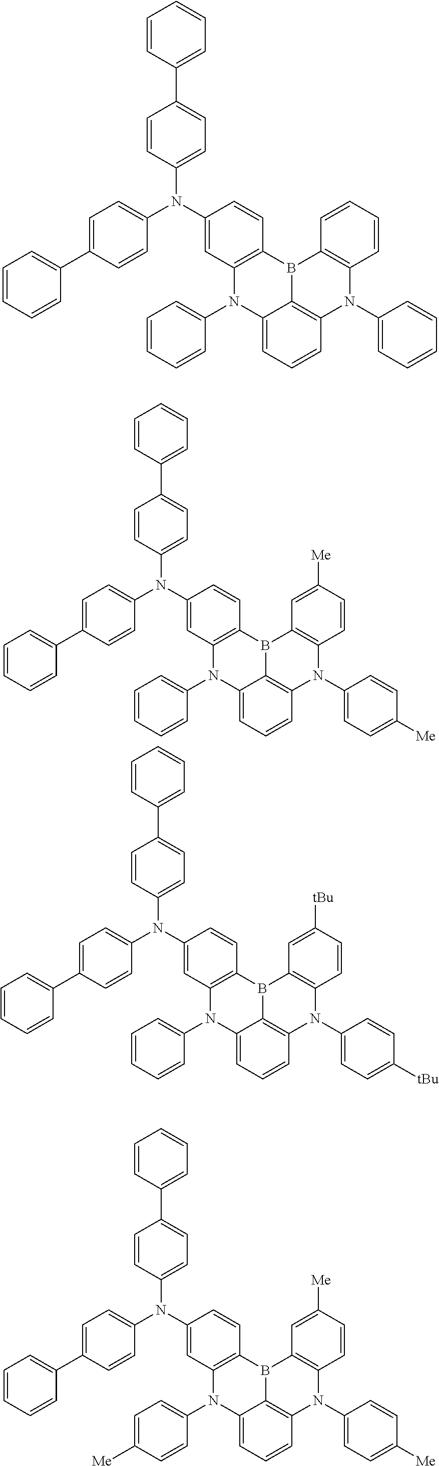

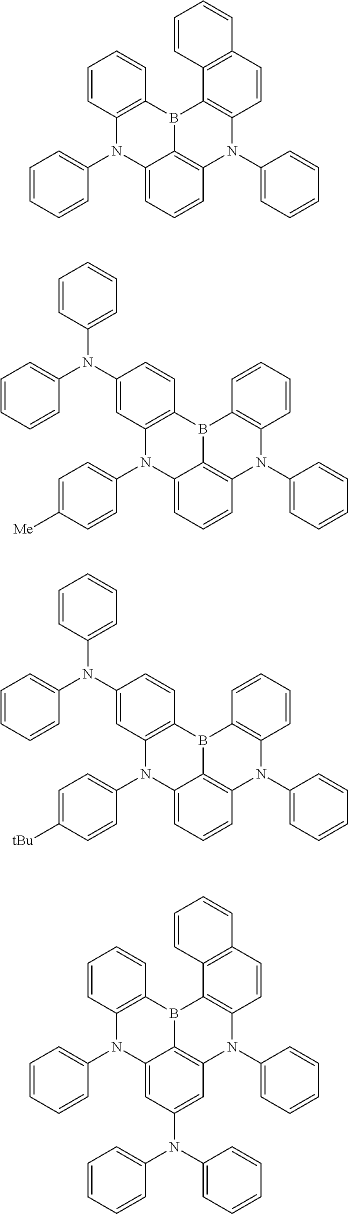

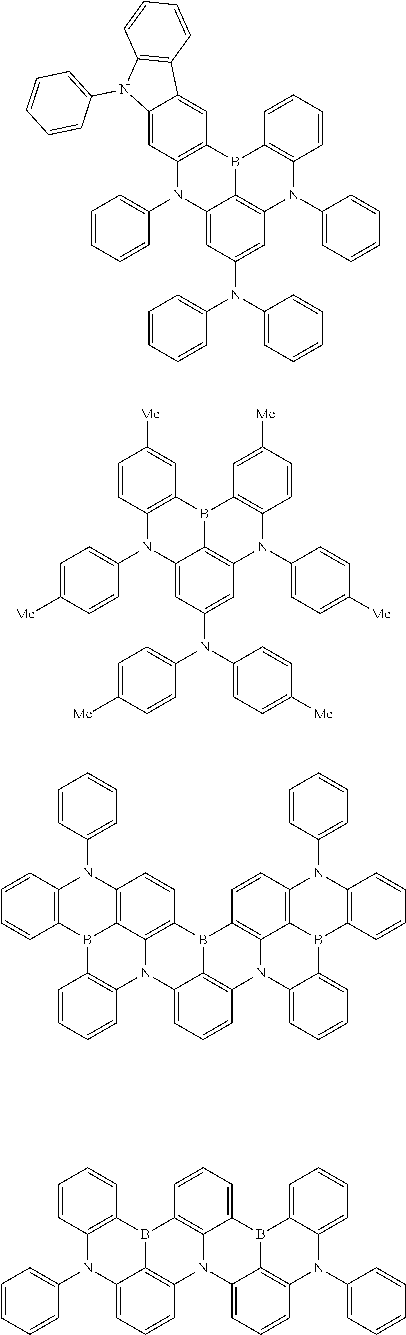 [SMILES: c1ccc(N(c2ccccc2)c2cc3c4c(c2)N(c2ccccc2)c2cc5c(cc2B4c2ccccc2N3c2ccccc2)c2ccccc2n5-c2ccccc2)cc1 ; Cc1ccc(N(c2ccc(C)cc2)c2cc3c4c(c2)N(c2ccc(C)cc2)c2ccc(C)cc2B4c2cc(C)ccc2N3c2ccc(C)cc2)cc1 ; c1ccc(N2c3ccccc3B3c4ccccc4N4c5cccc6c5B(c5ccc2c3c54)c2ccc3c4c2N6c2ccccc2B4c2ccccc2N3c2ccccc2)cc1 ; c1ccc(N2c3ccccc3B3c4cccc5c4N(c4cccc2c43)c2cccc3c2B5c2ccccc2N3c2ccccc2)cc1]

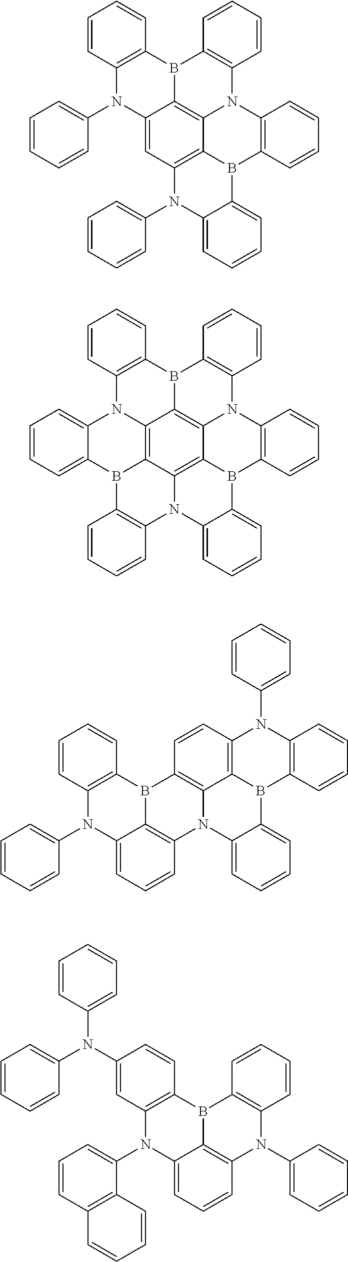

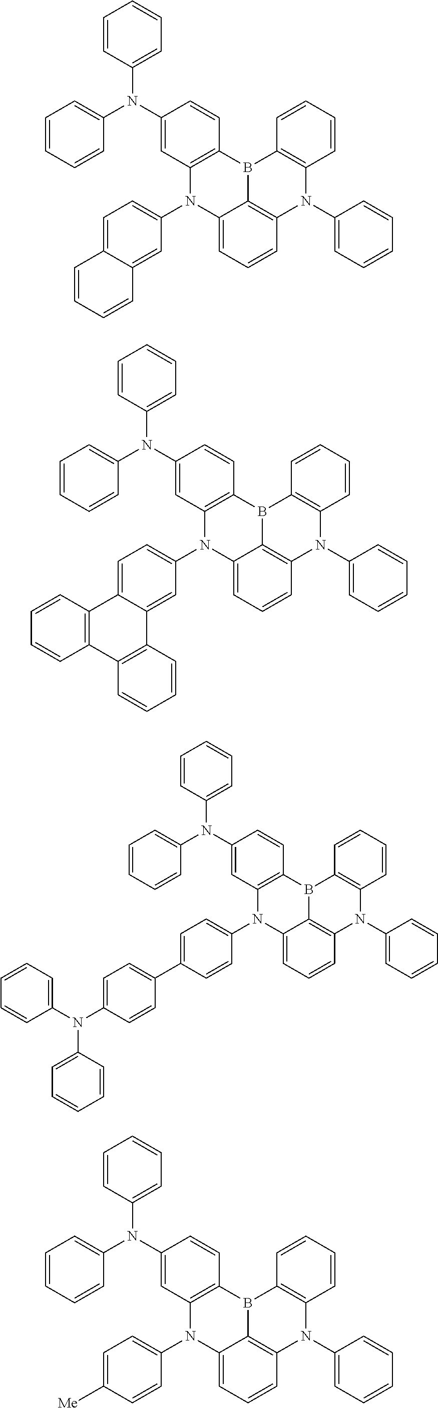

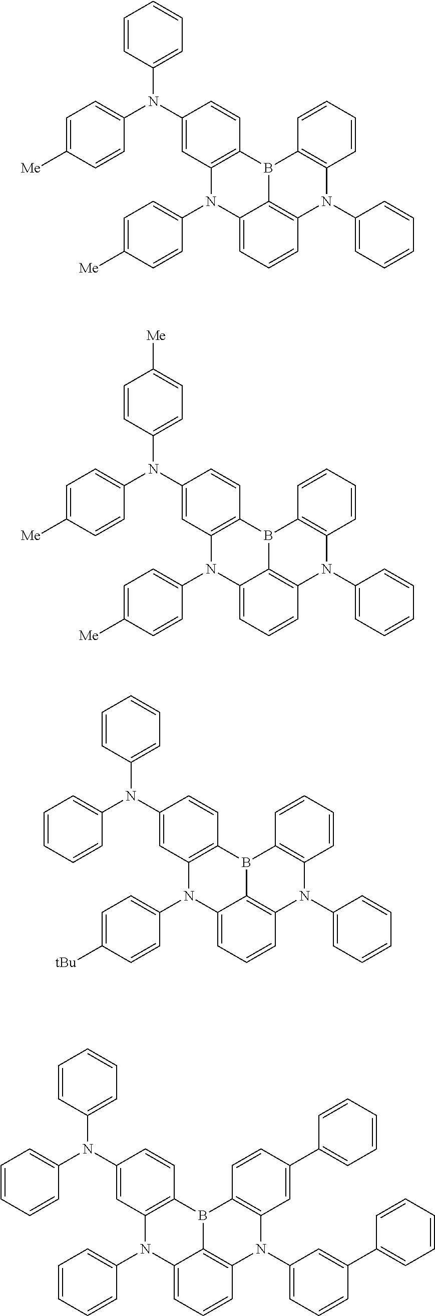 [SMILES: Cc1ccc(N(c2ccccc2)c2ccc3c(c2)N(c2ccc(C)cc2)c2cccc4c2B3c2ccccc2N4c2ccccc2)cc1 ; Cc1ccc(N(c2ccc(C)cc2)c2ccc3c(c2)N(c2ccc(C)cc2)c2cccc4c2B3c2ccccc2N4c2ccccc2)cc1 ; CC(C)(C)c1ccc(N2c3cc(N(c4ccccc4)c4ccccc4)ccc3B3c4ccccc4N(c4ccccc4)c4cccc2c43)cc1 ; c1ccc(-c2cccc(N3c4cc(-c5ccccc5)ccc4B4c5ccc(N(c6ccccc6)c6ccccc6)cc5N(c5ccccc5)c5cccc3c54)c2)cc1]

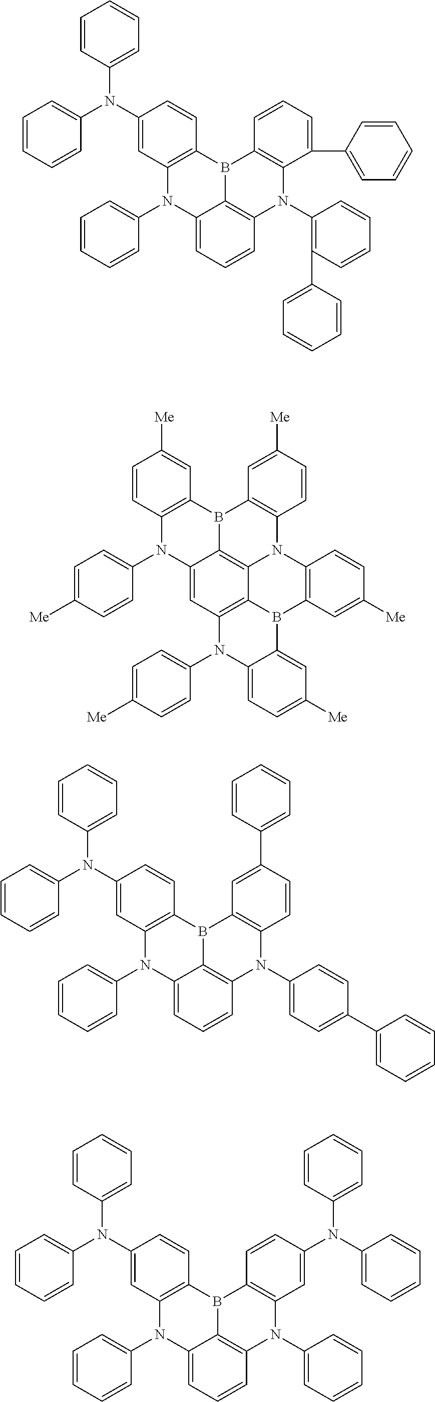 [SMILES: c1ccc(-c2ccccc2N2c3cccc4c3B(c3ccc(N(c5ccccc5)c5ccccc5)cc3N4c3ccccc3)c3cccc(-c4ccccc4)c32)cc1 ; Cc1ccc(N2c3ccc(C)cc3B3c4cc(C)ccc4N4c5ccc(C)cc5B5c6cc(C)ccc6N(c6ccc(C)cc6)c6cc2c3c4c65)cc1 ; c1ccc(-c2ccc(N3c4ccc(-c5ccccc5)cc4B4c5ccc(N(c6ccccc6)c6ccccc6)cc5N(c5ccccc5)c5cccc3c54)cc2)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1]

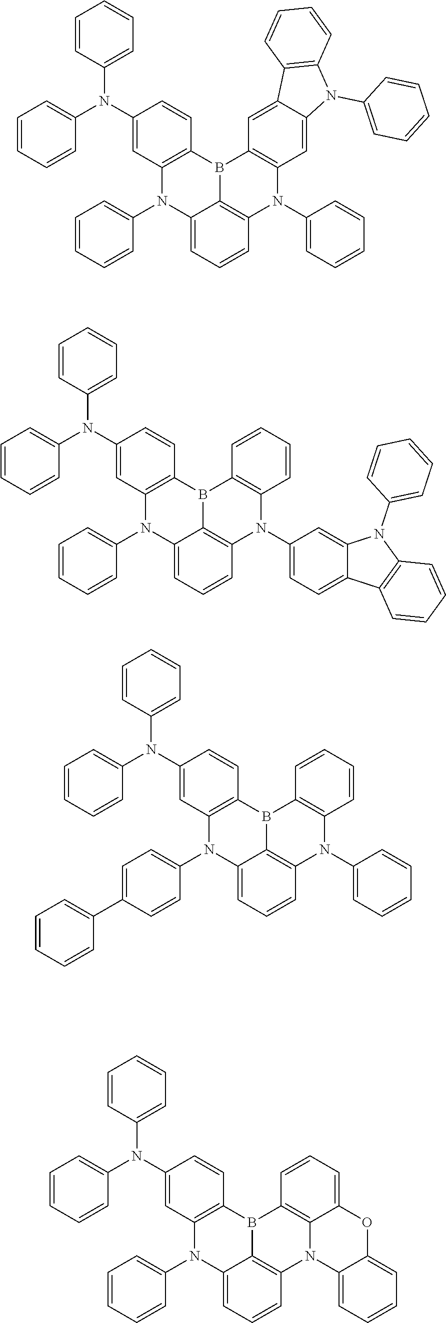 [SMILES: c1ccc(N(c2ccccc2)c2ccc3c(c2)N(c2ccccc2)c2cccc4c2B3c2cc3c5ccccc5n(-c5ccccc5)c3cc2N4c2ccccc2)cc1 ; c1ccc(N(c2ccccc2)c2ccc3c(c2)N(c2ccccc2)c2cccc4c2B3c2ccccc2N4c2ccc3c4ccccc4n(-c4ccccc4)c3c2)cc1 ; c1ccc(-c2ccc(N3c4cc(N(c5ccccc5)c5ccccc5)ccc4B4c5ccccc5N(c5ccccc5)c5cccc3c54)cc2)cc1 ; c1ccc(N(c2ccccc2)c2ccc3c(c2)N(c2ccccc2)c2cccc4c2B3c2cccc3c2N4c2ccccc2O3)cc1]

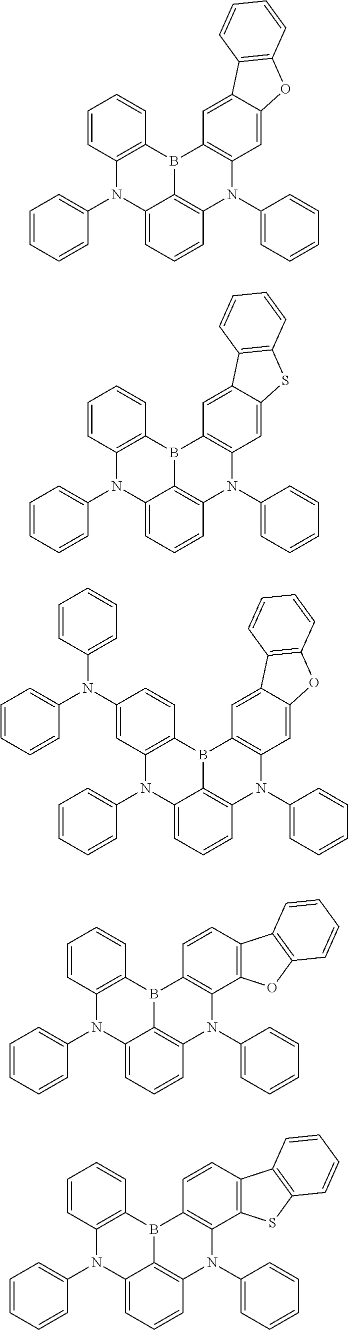

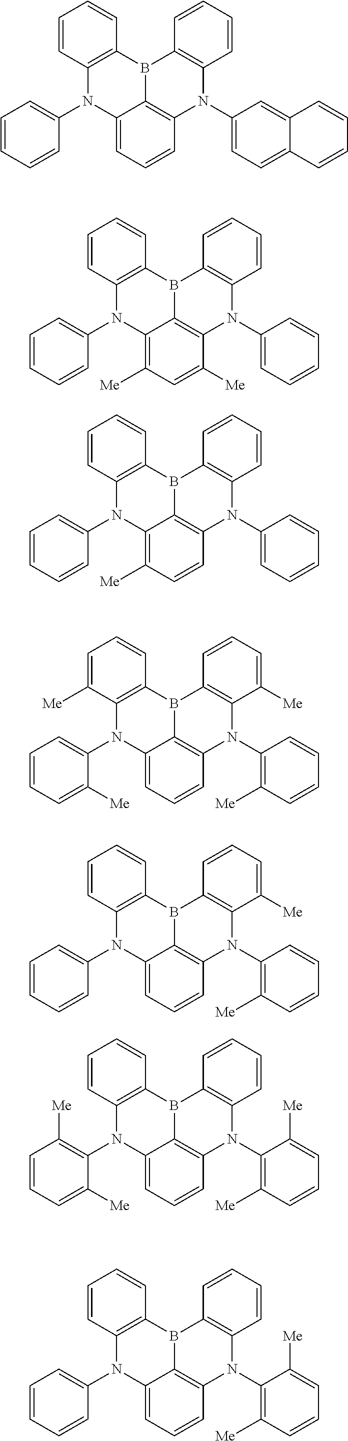

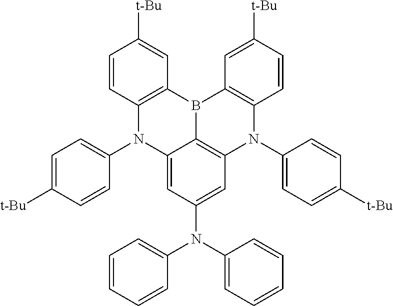 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

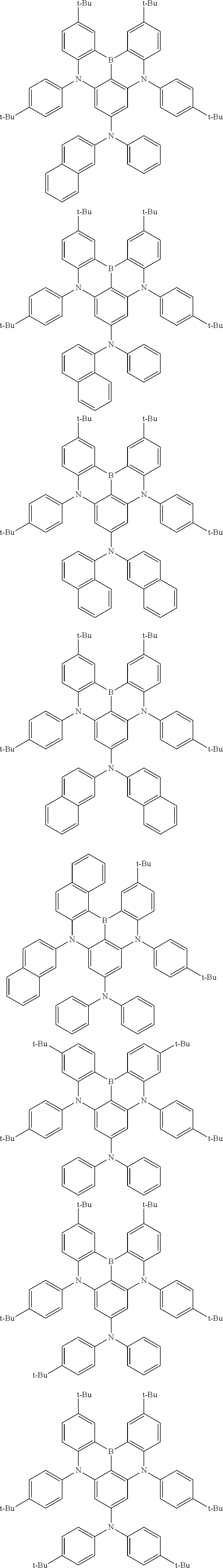

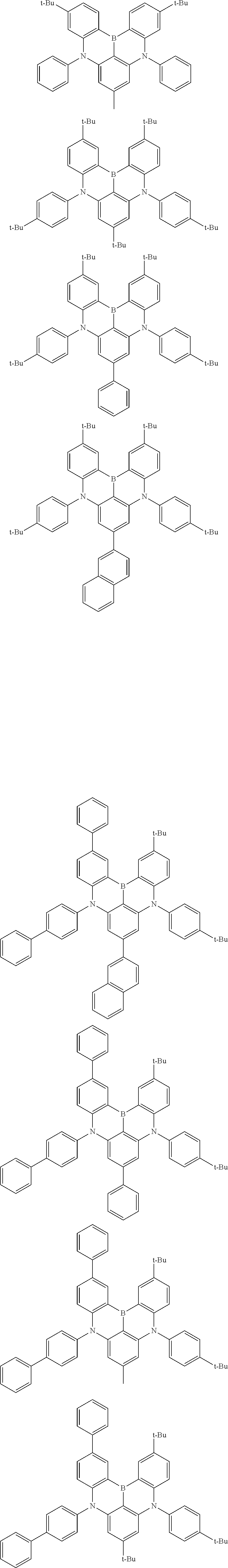

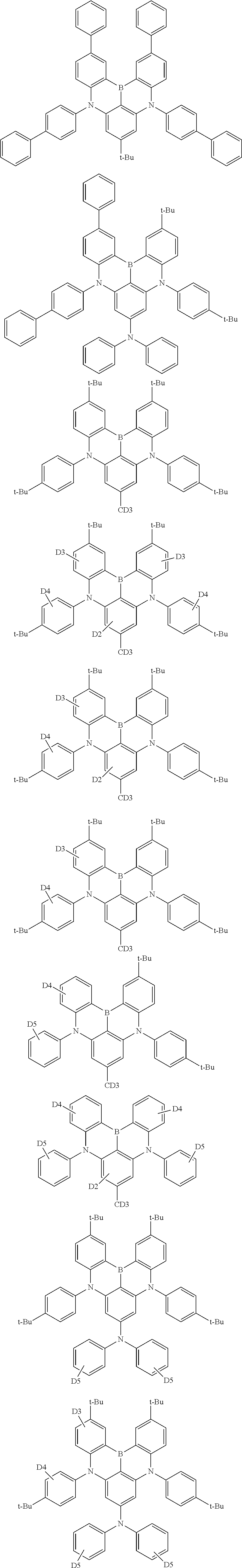

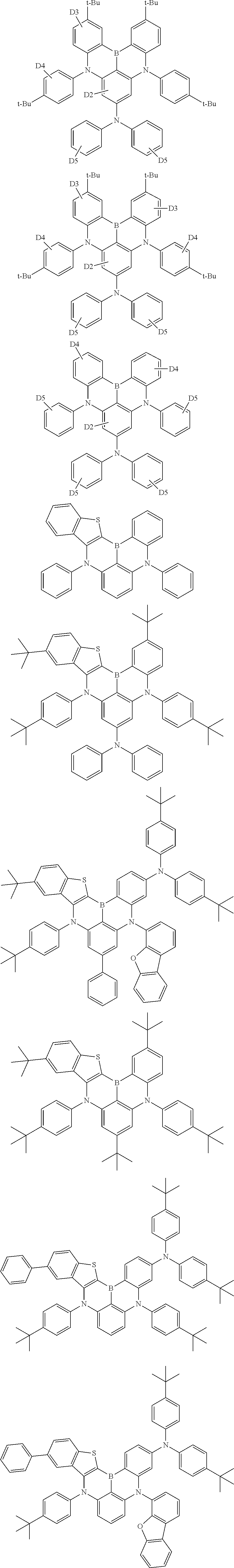

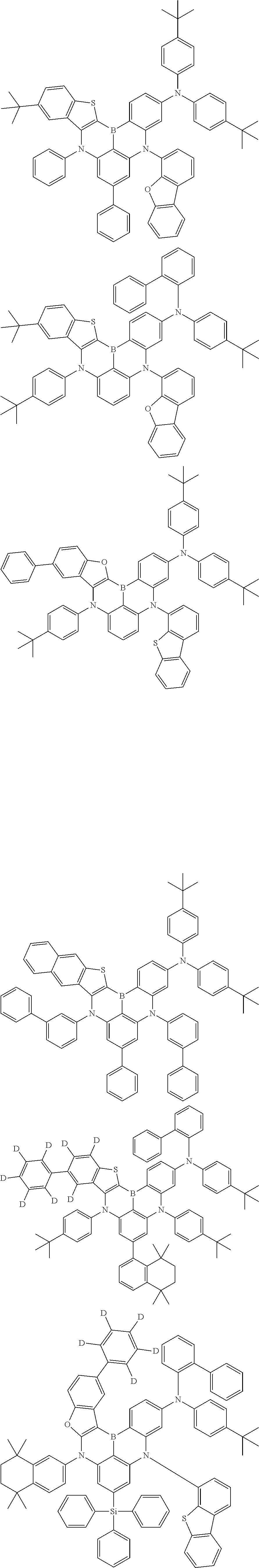

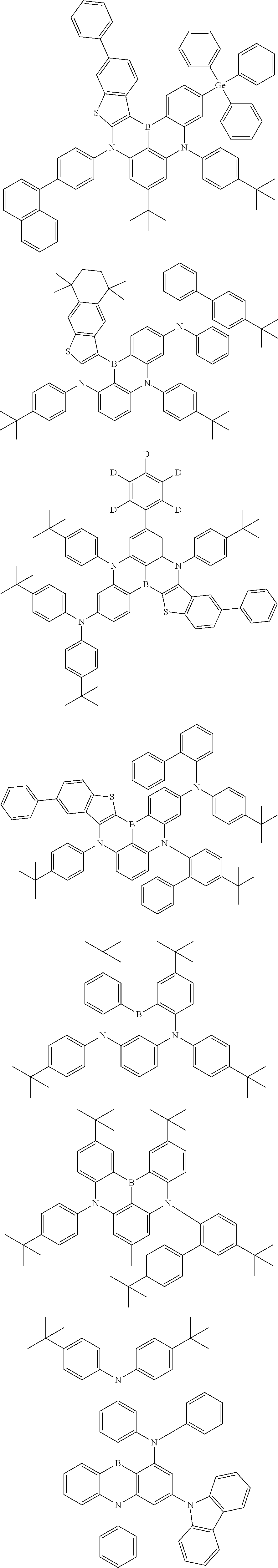

In the compounds above, D2 to D5 mean that 2 to 5 hydrogens are replaced with deuterium, respectively.

The formation of each layer of the organic electroluminescent devices of the present disclosure can be achieved by any one of a dry deposition method such as vacuum deposition, sputtering, plasma, or ion plating, or a wet deposition method such as spin coating, dip coating, or flow coating.

When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

According to one embodiment of the present disclosure, when forming a layer by the first host compound and the second host compound of the present disclosure, the layer can be formed by the above-listed methods, and can often be formed by co-deposition or mixture-deposition. The co-deposition is a mixed deposition method in which two or more materials are put into respective individual crucible sources, and a current is applied to both cells simultaneously to evaporate the materials; and the mixture-deposition is a mixed deposition method in which two or more materials are mixed in one crucible source before deposition, and then a current is applied to one cell to evaporate the materials.

According to one embodiment of the present disclosure, when the first host compound and the second host compound are present in the same layer or different layers within the organic electroluminescent device, the two host compounds can be deposited separately. For example, the first host compound may be deposited and then the second host compound may be deposited.

The plurality of host materials according to one embodiment of the present disclosure may be used as light-emitting materials for a white organic light-emitting device. The white organic light-emitting device has various suggested structures such as a side-by-side arrangement method, a stacking arrangement method, or a CCM (color conversion material) method, etc., depending on the arrangement of R (red), G (green), YG (yellowish green), or B (blue) light-emitting units. In addition, the plurality of host materials according to another embodiment of the present disclosure may also be applied to the organic electroluminescent device comprising a QD (quantum dot). In addition, the plurality of host materials according to the present disclosure can be used for the manufacture of display devices such as smartphones, tablets, notebooks, PCs, TVs, or display devices for vehicles, or lighting devices such as outdoor or indoor lighting.

Hereinafter, the preparation method of the compounds according to the present disclosure and the properties thereof, and the light-emitting characteristics of an organic electroluminescent device (OLED) comprising an organic electroluminescent compound or a plurality of host materials according to the present disclosure will be explained in detail with reference to the representative compounds of the present disclosure. However, the following examples only describe the properties of the organic electroluminescent compound or the plurality of host materials according to the present disclosure and the OLED comprising the same, and the present disclosure is not limited to the following examples.

### Example 1: Preparation of Compound H1-105

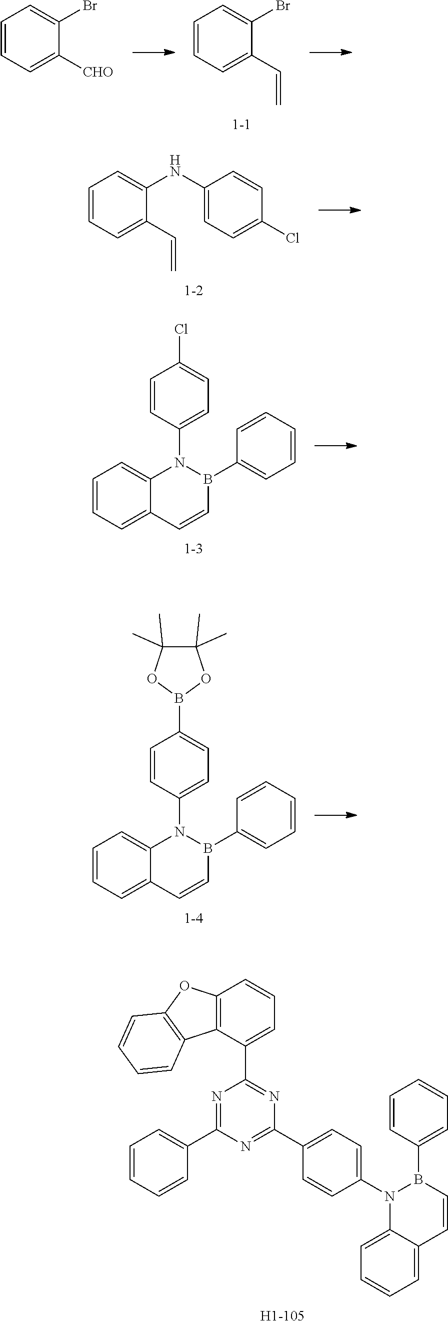

### 1) Synthesis of Compound 1-1

In a flask, methyltriphosphonium bromide (69.5 g, 194 mmol) was dissolved in 1.5 L of THF, and then potassium tert-butoxide (27 g, 243 mmol) and 2-bromobenzaldehyde (30 g, 162 mmol) were slowly added dropwise at 0° C. After the mixture was stirred at room temperature for 1 hour, and the reaction was completed, the organic layer was extracted with ethyl acetate, and the remaining moisture was removed using magnesium sulfate. The residue was dried and separated using column chromatography to obtain compound 1-1 (27.2 g, yield: 92%).

### 2) Synthesis of Compound 1-2

Compound 1-1 (28.8 g, 157 mmol), 4-chloroanilin (22 g, 173 mmol), Pd₂dba₃ (7.2 g, 7.8 mmol), dppf (8.7 g, 15.7 mmol), and sodium tert-butoxide (30.2 g, 314 mmol) were dissolved in 785 mL of toluene, and heated under reflux at 120° C. for 1 hour. After the reaction was completed, the organic layer was extracted with ethyl acetate, and the remaining moisture was removed using magnesium sulfate. The residue was dried and separated using column chromatography to obtain compound 1-2 (33 g, yield: 83%).

### 3) Synthesis of Compound 1-3

Compound 1-2 (30 g, 130 mmol) was dissolved in 860 mL of toluene, and then dichlorophenylborane (21.2 mL, 163 mmol) and TEA (27.3 ml, 196 mmol) were slowly added dropwise at 0° C. and refluxed at 130° C. for 1 hour. After the reaction was completed, the organic layer was extracted with ethyl acetate, and the remaining moisture was removed using magnesium sulfate. The residue was dried and separated using column chromatography to obtain compound 1-3 (35 g, yield: 85%).

### 4) Synthesis of Compound 1-4

Compound 1-3 (30.6 g, 97 mmol), 4,4,4′,4′,5,5,5′,5′-octamethyl-2,2′-bi(1,3,2-dioxaborolane) (98.5 g, 388 mmol), Pd₂dba₃ (4.5 g, 4.9 mmol), s-phos (4 g, 9.7 mmol), and KOAc (23.8 g, 242 mmol) were dissolved in 650 mL of 1,4-dioxane, and then refluxed at 100° C. for 3 hours. After the reaction was completed, the organic layer was extracted with ethyl acetate, and the remaining moisture was removed using magnesium sulfate. The residue was dried and separated using column chromatography to obtain compound 1-4 (54 g, yield: 137%).

### 5) Synthesis of Compound H1-105

Compound 1-4 (17 g, 41.8 mmol), 2-chloro-4-(dibenzo[b,d]furan-1-yl)-6-phenyl-1,3,5-triazine (16.4 g, 46 mmol), Pd(PPh₃)₄ (2.4 g, 21 mmol), K₂CO₃ (14.4 g, 104 mmol), 200 mL of toluene, 50 mL of ethanol, and 50 mL of water were stirred under reflux for 24 hours. After the reaction was completed, the organic layer was extracted with ethyl acetate, and the remaining moisture was removed using magnesium sulfate. The residue was dried and separated using column chromatography to obtain compound H1-105 (7 g, yield: 28%).

| | MW | M.P. | Tg |
|---|---|---|---|
| H1-105 | 602 | 203° C. | 113.8° C. |

### Example 2: Preparation of Compound H1-106

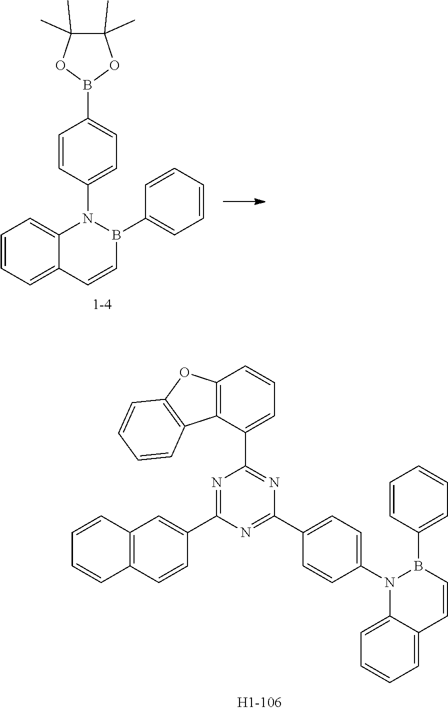 [SMILES: CC1(C)OB(c2ccc(N3B(c4ccccc4)C=Cc4ccccc43)cc2)OC1(C)C ; C1=Cc2ccccc2N(c2ccc(-c3nc(-c4ccc5ccccc5c4)nc(-c4cccc5oc6ccccc6c45)n3)cc2)B1c1ccccc1]

Compound 1-4 (10 g, 25 mmol), 2-chloro-4-(dibenzo[b,d]furan-1-yl)-6-(naphthalene-2-yl)-1,3,5-triazine (15 g, 37.5 mmol), Pd(PPh₃)₄ (1.5 g, 1.25 mmol), K₂CO₃ (7 g, 50 mmol), 90 mL of toluene, 20 mL of ethanol, and 20 mL of water were stirred under reflux for 24 hours. After the reaction was completed, the organic layer was extracted with ethyl acetate, and the remaining moisture was removed using magnesium sulfate. The residue was dried and separated using column chromatography to obtain compound H1-106 (1.2 g, yield: 7.5%).

| | MW | M.P. | Tg |
|---|---|---|---|
| H1-106 | 652 | 194° C. | 126.4° C. |

### Example 3: Preparation of Compound H1-118

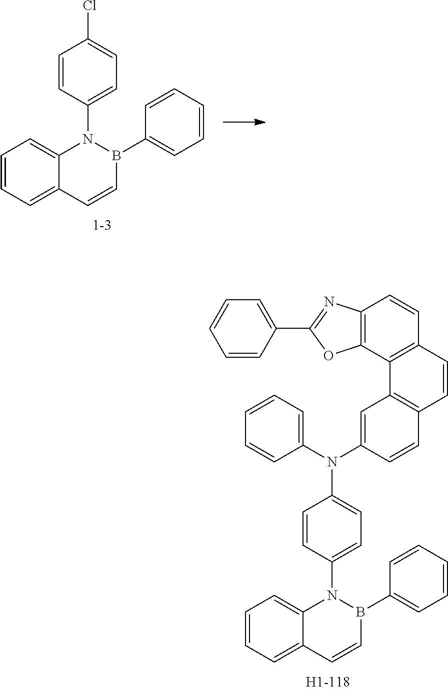 [SMILES: Clc1ccc(N2B(c3ccccc3)C=Cc3ccccc32)cc1 ; C1=Cc2ccccc2N(c2ccc(N(c3ccccc3)c3ccc4ccc5ccc6nc(-c7ccccc7)oc6c5c4c3)cc2)B1c1ccccc1]

Compound 1-3 (7 g, 22.2 mmol), N,2-diphenylphenanthro[3,4-d]oxazole-10-amine (8.5 g, 22.2 mmol), Pd₂(dba)₃ (1 g, 1.1 mmol), s-phos (903 mg, 2.2 mmol), NaOtBu (4.2 g, 44.4 mmol) and 150 mL of xylene were stirred under reflux for 1 hour. After the reaction was completed, the organic layer was extracted with ethyl acetate, and the remaining moisture was removed using magnesium sulfate. The residue was dried and separated using column chromatography to obtain compound H1-118 (3.5 g, yield: 24%).

| | MW | M.P. | Tg |
|---|---|---|---|
| H1-118 | 665.6 | 271° C. | 118.8° C. |

### Example 4: Preparation of Compound H1-119

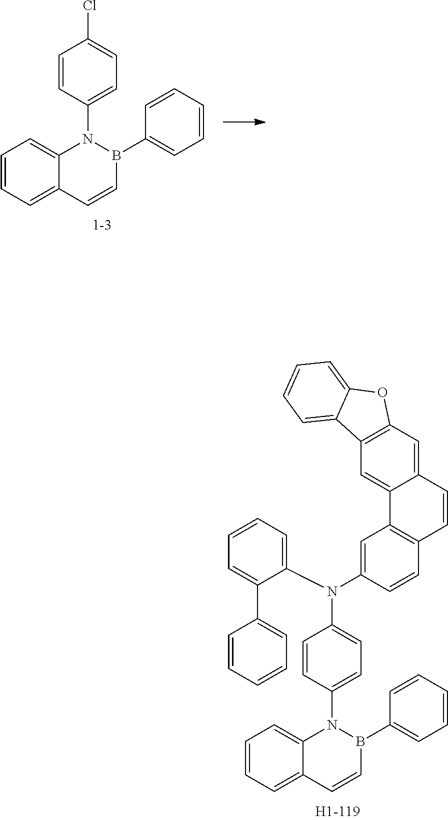 [SMILES: Clc1ccc(N2B(c3ccccc3)C=Cc3ccccc32)cc1 ; C1=Cc2ccccc2N(c2ccc(N(c3ccc4ccc5cc6oc7ccccc7c6cc5c4c3)c3ccccc3-c3ccccc3)cc2)B1c1ccccc1]

Compound 1-3 (3.2 g, 10.1 mmol), N-([1,1′-biphenyl]-2-yl)phenanthro[2,3-b]benzofuran-2-amine (3 g, 6.88 mmol), Pd₂(dba)₃ (470 mg, 0.5 mmol), s-phos (415 mg, 1.01 mmol), NaOtBu (2 g, 20.2 mmol) and 66 mL of xylene were stirred under reflux for 2 hours. After the reaction was completed, the organic layer was extracted with ethyl acetate, and the remaining moisture was removed using magnesium sulfate. The residue was dried and separated using column chromatography to obtain compound H1-119 (2.9 g, yield: 40%).

| | MW | M.P. | Tg |
|---|---|---|---|
| H1-119 | 714 | 278.5° C. | 132.1° C. |

### Example 5: Preparation of Compound H1-115

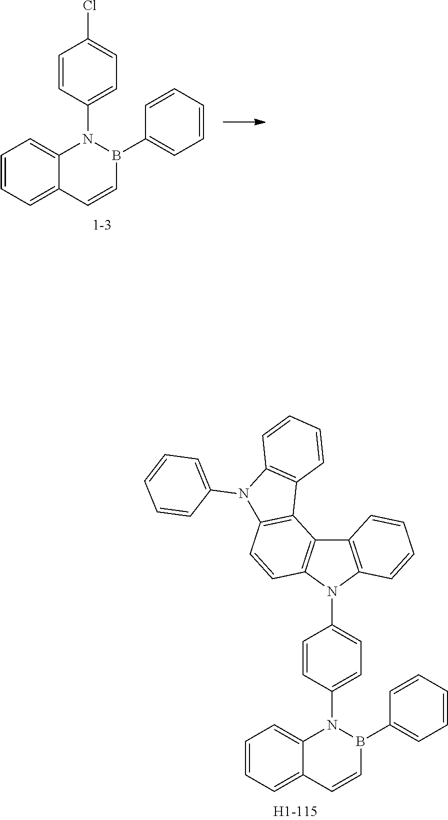 [SMILES: Clc1ccc(N2B(c3ccccc3)C=Cc3ccccc32)cc1 ; C1=Cc2ccccc2N(c2ccc(-n3c4ccccc4c4c5c6ccccc6n(-c6ccccc6)c5ccc43)cc2)B1c1ccccc1]

Compound 1-3 (5.7 g, 18 mmol), 5-phenyl-5,8-dihydroindolo[2,3-c]carbazole (6 g, 18 mmol), Pd₂(dba)₃ (828 mg, 0.9 mmol), s-phos (738 mg, 1.8 mmol), NaOtBu (3.4 g, 36 mmol) and 120 mL of xylene were stirred under reflux for 4 hours. After the reaction was completed, the organic layer was extracted with ethyl acetate, and the remaining moisture was removed using magnesium sulfate. The residue was dried and separated using column chromatography to obtain compound H1-115 (5.6 g, yield: 51%).

| | MW | M.P. | Tg |
|---|---|---|---|
| H1-115 | 611.5 | 255.4° C. | 123.59° C. |

### Example 6: Preparation of Compound H1-193

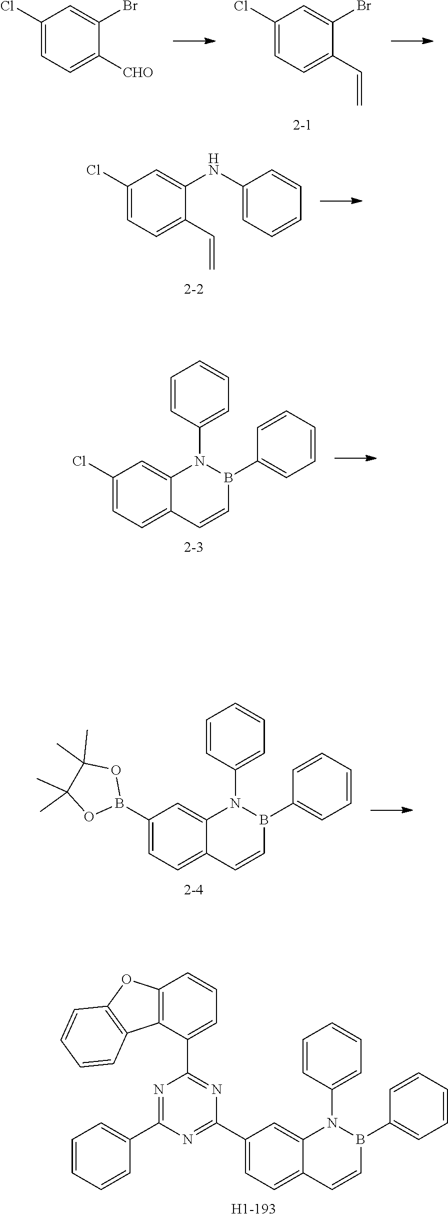

### 1) Synthesis of Compound 2-1

In a flask, methyltriphenylphosphonium bromide (58.5 g, 164 mmol) was dissolved in 1.3 of THF, and then potassium tert-butoxide (23 g, 205 mmol) and 2-bromo-4-chlofobenzaldehyde (30 g, 136 mmol) were slowly added dropwise at 0° C. After the mixture was stirred at room temperature for 1 hour, and the reaction was completed, the organic layer was extracted with ethyl acetate, and the remaining moisture was removed using magnesium sulfate. The residue was dried and separated using column chromatography to obtain compound 2-1 (30 g, yield: 101%).

### 2) Synthesis of Compound 2-2

Compound 2-1 (25 g, 115 mmol), aniline (11.4 mL, 126 mmol), Pd₂dba₃ (5.2 g, 5.7 mmol), xantphos (6.6 g, 11.5 mmol), and sodium tert-butoxide (22 g, 230 mmol) were dissolved in 575 mL of toluene, and then and heated under reflux at 120° C. for 2 hours. After the reaction was completed, the organic layer was extracted with ethyl acetate, and the remaining moisture was removed using magnesium sulfate. The residue was dried and separated using column chromatography to obtain compound 2-2 (20.6 g, yield: 78%).

### 3) Synthesis of Compound 2-3

Compound 2-2 (20 g, 87 mmol) was dissolved in 580 mL of toluene, and then dichlorophenylborane (14.1 mL, 109 mmol) and TEA (18.2 mL, 130 mmol) were slowly added dropwise at 0° C. and refluxed at 130° C. for 1 hour. After the reaction was completed, the organic layer was extracted with ethyl acetate, and the remaining moisture was removed using magnesium sulfate. The residue was dried and separated using column chromatography to obtain compound 2-3 (22 g, yield: 80%).

### 4) Synthesis of Compound 2-4

Compound 2-3 (14 g, 44 mmol), 4,4,4′,4′,5,5,5′,5′-octamethyl-2,2′-bi(1,3,2-dioxaborolane) (45 g, 177 mmol), Pd₂dba₃ (2 g, 2.2 mmol), s-phos (1.8 g, 4.4 mmol), and KOAc (10.9 g, 111 mmol) were dissolved in 290 mL of 1,4-dioxane, and then refluxed at 100° C. for 5 hours. After the reaction was completed, the organic layer was extracted with ethyl acetate, and the remaining moisture was removed using magnesium sulfate. The residue was dried and separated using column chromatography to obtain compound 2-4 (15.5 g, yield: 86%).

### 5) Synthesis of Compound H1-193

Compound 2-4 (7 g, 17.2 mmol), 2-chloro-4-(dibenzo[b,d]furane-1-yl)-6-phenyl-1,3,5-triazine (6.1 g, 17.2 mmol), Pd(PPh₃)₄ (1 g, 0.9 mmol), K₂CO₃ (6 g, 43 mmol), 80 mL of toluene, 20 mL of ethanol, and 20 mL of water were stirred under reflux for 3.5 hours. After the reaction was completed, the organic layer was extracted with ethyl acetate, and the remaining moisture was removed using magnesium sulfate. The residue was dried and separated using column chromatography to obtain compound H1-193 (2.2 g, yield: 21%).

| | MW | M.P. | Tg |
|---|---|---|---|
| H1-193 | 602 | 207.5° C. | 102.43° C. |

### Example 7: Preparation of Compound H1-208

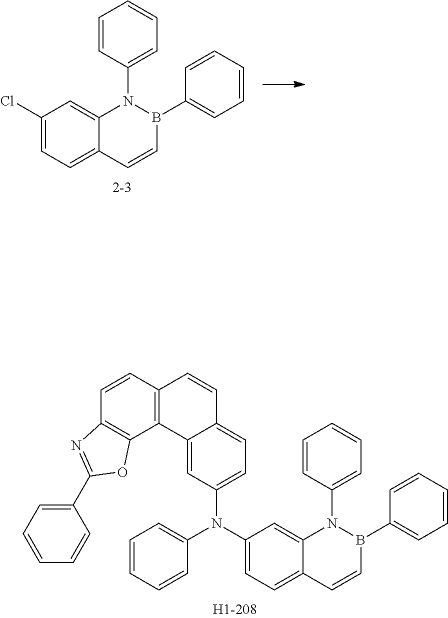 [SMILES: Clc1ccc2c(c1)N(c1ccccc1)B(c1ccccc1)C=C2 ; C1=Cc2ccc(N(c3ccccc3)c3ccc4ccc5ccc6nc(-c7ccccc7)oc6c5c4c3)cc2N(c2ccccc2)B1c1ccccc1]

Compound 2-3 (6.7 g, 21 mmol), N,2-diphenylphenanthro[3,4-d]oxazole-10-amine (8.2 g, 21 mmol), Pd₂(dba)₃ (1 g, 1.1 mmol), s-phos (862 mg, 2.1 mmol), sodium tert-butoxide (4 g, 42 mmol), and 140 mL of xylene were stirred under reflux for 2 hours. After the reaction was completed, the organic layer was extracted with ethyl acetate, and the remaining moisture was removed using magnesium sulfate. The residue was dried and separated using column chromatography to obtain compound H1-208 (5.5 g, yield: 39%).

| | MW | M.P. | Tg |
|---|---|---|---|
| H1-208 | 665.6 | 248.9° C. | 117.58° C. |

### Example 8: Preparation of Compound H1-205

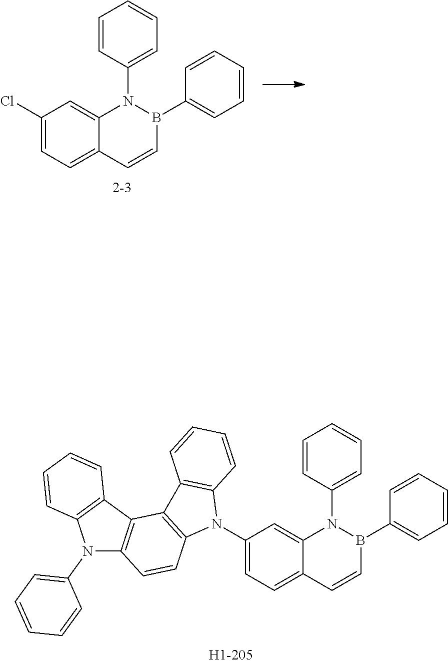 [SMILES: Clc1ccc2c(c1)N(c1ccccc1)B(c1ccccc1)C=C2 ; C1=Cc2ccc(-n3c4ccccc4c4c5c6ccccc6n(-c6ccccc6)c5ccc43)cc2N(c2ccccc2)B1c1ccccc1]

In a flask, compound 2-3 (4.7 g, 15 mmol), 5-phenyl-5,8-dihydroindolo[2,3-c]carbazole (5 g, 15 mmol), Pd₂(dba)₃ (688 mg, 0.7 mmol), s-phos (617 mg, 1.5 mmol), sodium tert-butoxide (2.9 g, 30 mmol), and 100 mL of xylene were stirred under reflux for 4 hours. After the reaction was completed, the organic layer was extracted with ethyl acetate, and the remaining moisture was removed using magnesium sulfate. The residue was dried and separated using column chromatography to obtain compound H1-205 (1.6 g, yield: 17%).

| | MW | M.P. | Tg |
|---|---|---|---|
| H1-205 | 611.5 | 209° C. | 132.4° C. |

### Example 9: Preparation of Compound H1-209

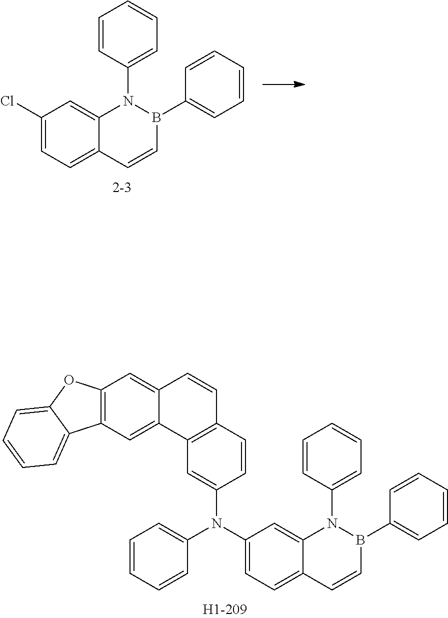 [SMILES: Clc1ccc2c(c1)N(c1ccccc1)B(c1ccccc1)C=C2 ; C1=Cc2ccc(N(c3ccccc3)c3ccc4ccc5cc6oc7ccccc7c6cc5c4c3)cc2N(c2ccccc2)B1c1ccccc1]

In a flask, compound 2-3 (5.0 g, 15.8 mmol), N-phenylphenanthro[2,3-b]benzofuran-2-amine (5.7 g, 15.8 mmol), Pd₂(dba)₃ (725 mg, 0.8 mmol), s-phos (650 mg, 1.5 mmol), sodium tert-butoxide (3 g, 31 mmol), and 105 mL of xylene were stirred under reflux for 1.5 hours. After the reaction was completed, the organic layer was extracted with ethyl acetate, and the remaining moisture was removed using magnesium sulfate. The residue was dried and separated using column chromatography to obtain compound H1-209 (1.9 g, yield: 19%).

| | MW | M.P. | Tg |
|---|---|---|---|
| H1-209 | 638.58 | 228° C. | 122.4° C. |

### Example 10: Preparation of Compound H1-252

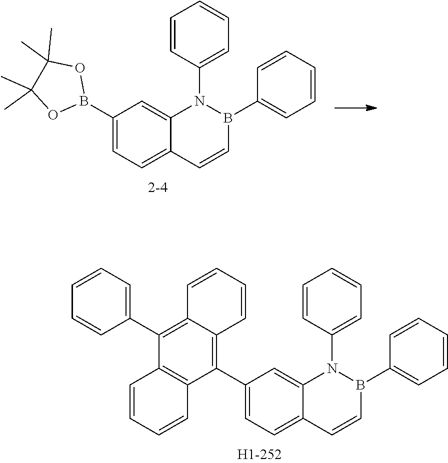 [SMILES: CC1(C)OB(c2ccc3c(c2)N(c2ccccc2)B(c2ccccc2)C=C3)OC1(C)C ; C1=Cc2ccc(-c3c4ccccc4c(-c4ccccc4)c4ccccc34)cc2N(c2ccccc2)B1c1ccccc1]

In a flask, compound 2-4 (5.2 g, 12.7 mmol), 9-bromo-10-phenylanthracene (3.8 g, 11.6 mmol), Pd(OAc)₂ (128 mg, 0.5 mmol), s-phos (468 mg, 1 mmol), K₃PO₄ (6 g, 28.5 mmol), 60 mL of toluene, 15 mL of ethanol, and 15 mL of water were stirred under reflux for 4 hours. After the reaction was completed, the organic layer was extracted with ethyl acetate, and the remaining moisture was removed using magnesium sulfate. The residue was dried and separated using column chromatography to obtain compound H1-252 (3.8 g, yield: 63%).

| | MW | M.P. | Tg |
|---|---|---|---|
| H1-252 | 533.48 | 317.5° C. | 124° C. |

### Example 11: Preparation of Compound H1-234

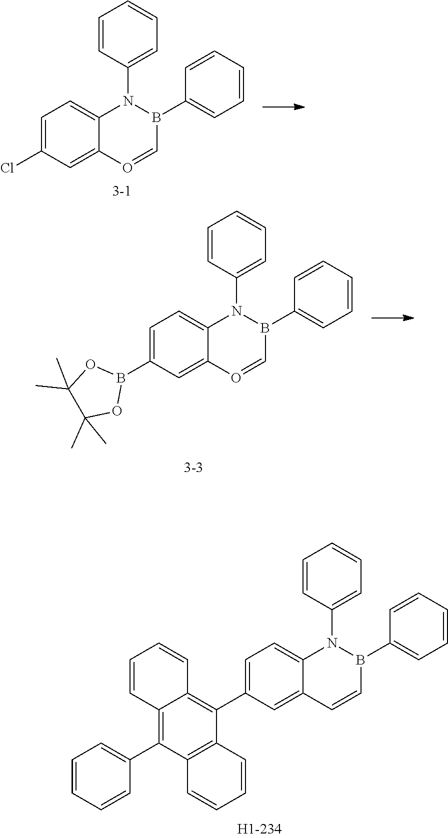

### 1) Synthesis of Compound 3-2

In a flask, compound 3-1 (20 g, 63 mmol), 4,4,4′,4′,5,5,5′,5′-octamethyl-2,2′-bi(1,3,2-dioxaborolane) (21 g, 82 mmol), Pd₂dba₃ (2.9 g, 3 mmol), s-phos (2.6 g, 6.3 mmol), KOAc (15.5 g, 158 mmol), and 420 mL of 1,4-dioxane were stirred under reflux for 12 hours. After the reaction was completed, the organic layer was extracted with ethyl acetate, and the remaining moisture was removed using magnesium sulfate. The residue was dried and separated using column chromatography to obtain compound 3-2 (16 g, yield: 62%).

### 2) Synthesis of Compound H1-234

Compound 3-2 (6 g, 14.7 mmol), 9-bromo-10-phenylanthracene (4.5 g, 13.4 mmol), Pd(OAc)₂ (151 mg, 0.6 mmol), s-phos (554 mg, 1.3 mmol), K₃PO₄ (7.1 g, 33 mmol), 68 mL of toluene, 17 mL of ethanol, and 17 mL of water were stirred under reflux for 4 hours. After the reaction was completed, the organic layer was extracted with ethyl acetate, and the remaining moisture was removed using magnesium sulfate. The residue was dried and separated using column chromatography to obtain compound H1-234 (2.7 g, yield: 35%).

| | MW | M.P. | Tg |
|---|---|---|---|
| H1-234 | 533.48 | 313.7° C. | 137° C. |

### Example 12: Preparation of Compound H1-292

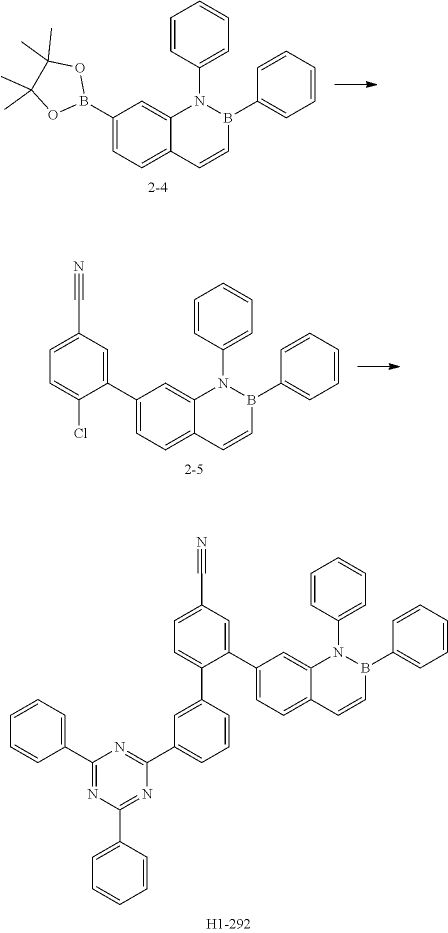 [SMILES: CC1(C)OB(c2ccc3c(c2)N(c2ccccc2)B(c2ccccc2)C=C3)OC1(C)C ; N#Cc1ccc(Cl)c(-c2ccc3c(c2)N(c2ccccc2)B(c2ccccc2)C=C3)c1 ; N#Cc1ccc(-c2cccc(-c3nc(-c4ccccc4)nc(-c4ccccc4)n3)c2)c(-c2ccc3c(c2)N(c2ccccc2)B(c2ccccc2)C=C3)c1]

### 1) Synthesis of Compound 2-5

In a flask, compound 2-4 (9 g, 22.1 mmol), 3-bromo-4-chlorobenzonitrile (7.1 g, 33.1 mmol), Pd(PPh₃)₄ (1.28 g, 1.11 mmol), K₂CO₃ (7.64 g, 55.26 mmol), 110 mL of toluene, 27 mL of ethanol, and 27 mL of water were stirred under reflux for 5 hours. After the reaction was completed, the organic layer was extracted with ethyl acetate, and the remaining moisture was removed using magnesium sulfate. The residue was dried and separated using column chromatography to obtain compound 2-5 (6.1 g, yield: 66.2%).

### 2) Synthesis of Compound H1-292

Compound 2-5 (5.0 g, 12.0 mmol), 2,4-diphenyl-6-(3-(4,4,5,5-tetramethyl-1,3,2-dioxaborolane-2-yl)phenyl)-1,3,5-triazine (5.2 g, 12.0 mmol), Pd(OAc)₂ (270 mg, 1.2 mmol), s-phos (999 mg, 2.4 mmol), K₃PO₄ (7.64 g, 59.9 mmol), 60 mL of xylene, 15 mL of 1,4-dioxane, and 15 mL of water were stirred under reflux for 1.5 hours. After the reaction was completed, the organic layer was extracted with ethyl acetate, and the remaining moisture was removed using magnesium sulfate. The residue was dried and separated using column chromatography to obtain compound H1-292 (5.0 g, yield: 60.4%).

| | MW | M.P. | Tg |
|---|---|---|---|
| H1-292 | 689.63 | 210° C. | 129° C. |

### Device Examples 1 and 2: Preparation of Red Light-Emitting OLEDs According to the Present Disclosure

An OLED according to the present disclosure was prepared. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and thereafter was stored in isopropanol and then used. Thereafter, the ITO substrate was mounted on a substrate holder of a vacuum vapor deposition apparatus. Compound HI-1 of Table 5 was then introduced into a cell of the vacuum vapor deposition apparatus, and Compound HT-1 was introduced into another cell. The two materials were evaporated at different rates, and Compound HI-1 was deposited in a doping amount of 3 wt % based on the total amount of Compounds HI-1 and HT-1 to form a hole injection layer having a thickness of 10 nm. Compound HT-1 was then deposited on the hole injection layer to form a first hole transport layer with a thickness of 80 nm. Thereafter, Compound HT-2 was introduced into another cell of the vacuum vapor deposition apparatus and was evaporated by applying an electric current to the cell, thereby forming a second hole transport layer with a thickness of 60 nm on the first hole transport layer. After formation of the hole injection layer and the hole transport layers, a light-emitting layer was deposited thereon as follows: the compound shown in Table 1 was introduced into cells of the vacuum vapor deposition apparatus as a host, and Compound D-39 was introduced into the other cell as a dopant. The two materials were evaporated at different rates to deposit in a doping amount of 3 wt % based on the total amount of the host and dopant to form a light-emitting layer with a thickness of 40 nm on the second hole transport layer. Next, Compound ET-1 and Compound EI-1 as electron transport layer materials were introduced into another cells of the vacuum vapor deposition apparatus and evaporated at a rate of 1:1 to form an electron transport layer having a thickness of 35 nm on the light-emitting layer. Compound EI-1 was evaporated to deposit an electron injection layer with a thickness of 2 nm on the electron transport layer. An Al cathode was deposited with a thickness of 80 nm on the electron injection layer by using another vacuum vapor deposition apparatus, thereby producing an OLED. All of the materials used for producing the OLED were purified by vacuum sublimation at 10⁻⁶ Torr.

### Comparative Example 1: Preparation of an OLED Comprising a Host not According to the Present Disclosure

An OLED was produced in the same manner as in Device Example 1, except that host compound CBP shown in Table 1 below was used as the host of the light-emitting layer.

The driving voltage, luminous efficiency, and light-emitting color at a luminance of 1,000 nit for the OLEDs of Device Examples 1 and 2, and Comparative Example 1 produced as described above are shown in Table 1 below.

TABLE 1

| | | Driving | Luminous | Light- |
|---|---|---|---|---|
| | | Voltage | Efficiency | Emitting |
| | Host | (V) | (cd/A) | Color |
| Comparative | CBP | 9.0 | 14.3 | Red |
| Example 1 | | | | |
| Device | H1-105 | 4.2 | 24.8 | Red |
| Example 1 | | | | |
| Device | H1-106 | 4.6 | 22.6 | Red |
| Example 2 | | | | |

From Table 1 above, it can be confirmed that the organic electroluminescent device including the host according to the present invention has a lower driving voltage and higher luminous efficiency compared to the organic electroluminescent device including the host not according to the present invention.

### Device Examples 3 to 6: Preparation of OLEDs Co-Deposited with a First Host Compound and a Second Host Compound According to the Present Disclosure

OLEDs were produced in the same manner as in Device Example 1, except that the first and second host compounds shown in Table 2 below were introduced into two cells of the vacuum vapor deposition apparatus as a host, and Compound D-39 was introduced into the other cell as a dopant; the two host materials were evaporated at a rate of 1:1 and the dopant material was evaporated simultaneously at a different rate to deposit in a doping amount of 3 wt % based on the total amount of the hosts and dopant to form a light-emitting layer with a thickness of 40 nm on the second hole transport layer.

The driving voltage, luminous efficiency, and light-emitting color at a luminance of 1,000 nit, and time taken for luminance to reduce from 100% to 95% at a luminance of 5,000 nit (lifetime: T95) for the OLEDs of Comparative Example 1 and Device Examples 3 to 6 produced as described above are shown in Table 2 below.

TABLE 2

| | | | Driving | Luminous | Light- | |
|---|---|---|---|---|---|---|
| | First | Second | Voltage | Efficiency | Emitting | Lifetime |
| | Host | Host | (V) | (cd/A) | Color | T95(hr) |
| Comparative Example 1 | CBP | — | 9.0 | 14.3 | Red | 0.3 |
| Device Example 3 | H1-118 | H3-26 | 3.1 | 31.6 | Red | 51.9 |
| Device Example 4 | H1-119 | H3-26 | 3.2 | 31.3 | Red | 10.0 |
| Device Example 5 | H2-144 | H1-105 | 3.1 | 32.2 | Red | 42.4 |
| Device Example 6 | H2-144 | H1-106 | 3.2 | 31.1 | Red | 23.3 |

From Table 2 above, it can be confirmed that the organic electroluminescent device including the plurality of host materials according to the present invention has very low driving voltage, very high luminous efficiency, and significantly improved lifetime property compared to the organic electroluminescent device including the host material not according to the present invention.

### Device Examples 7 and 8: Preparation of OLEDs Co-Deposited with a First Host Compound and a Second Host Compound According to the Present Disclosure

OLEDs were produced in the same manner as in Device Example 3, except that compounds shown in Table 3 below were used as the host of the light-emitting layer.

The driving voltage, luminous efficiency, and light-emitting color at a luminance of 1,000 nit, and time taken for luminance to reduce from 100% to 95% at a luminance of 10,000 nit (lifetime: T95) for the OLEDs of Device Examples 7 and 8 produced as described above are shown in Table 3 below.

TABLE 3

| | | | Driving | Luminous | Light- | |
|---|---|---|---|---|---|---|
| | First | Second | Voltage | Efficiency | Emitting | Lifetime |
| | Host | Host | (V) | (cd/A) | Color | T95(hr) |
| Device Example 7 | H1-115 | H3-26 | 3.5 | 35.4 | Red | 52.2 |
| Device Example 8 | H1-208 | H3-26 | 2.8 | 34.8 | Red | 118.5 |

From Table 3 above, it can be confirmed that the driving voltage, luminous efficiency, and lifetime of the organic electroluminescent device including the compound according to the present disclosure as a host material are excellent.

### Device Examples 9 and 10: Preparation of OLEDs Co-Deposited with a First Host Compound and a Second Host Compound According to the Present Disclosure

An OLED according to the present disclosure was prepared. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and thereafter was stored in isopropyl alcohol and then used. Thereafter, the ITO substrate was mounted on a substrate holder of a vacuum vapor deposition apparatus. Compound HI-1 of Table 5 was then introduced into a cell of the vacuum vapor deposition apparatus, and Compound HT-3 was introduced into another cell. The two materials were evaporated at different rates, and Compound HI-1 was deposited in a doping amount of 3 wt % based on the total amount of Compounds HI-1 and HT-3 to form a hole injection layer having a thickness of 10 nm. Compound HT-3 was then deposited on the hole injection layer to form a first hole transport layer with a thickness of 80 nm. Thereafter, Compound HT-4 was introduced into another cell of the vacuum vapor deposition apparatus and was evaporated by applying an electric current to the cell, thereby forming a second hole transport layer with a thickness of 55 nm on the first hole transport layer. After formation of the hole injection layer and the hole transport layers, Compound HT-5 was introduced into another cell of the vacuum vapor deposition apparatus and was evaporated by applying an electric current to the cell, thereby forming a third hole transport layer with a thickness of 5 nm on the second hole transport layer. A light-emitting layer was deposited thereon as follows: the host compounds shown in Table 4 were introduced into two cells of the vacuum vapor deposition apparatus as hosts, and Compound D-39 was introduced into the other cell as a dopant. The two host materials were evaporated at a rate of 1:1, and the dopant material was evaporated simulataneously at a different rate to deposit in a doping amount of 3 wt % based on the total amount of the hosts and dopant to form a light-emitting layer with a thickness of 40 nm on the third hole transport layer. Compound BF-1 was deposited thereon to form a buffer layer with a thickness of 5 nm. Next, Compound ET-2 and Compound EI-1 were evaporated in a weight ratio of 50:50 to form an electron transport layer having a thickness of 30 nm on the buffer layer. Compounds EI-1 was evaporated to deposit an electron injection layer with a thickness of 2 nm on the electron transport layer. An Al cathode was deposited with a thickness of 80 nm on the electron injection layer by using another vacuum vapor deposition apparatus, thereby producing an OLED. All of the materials used for producing the OLED were purified by vacuum sublimation at 10⁻⁶ Torr.

The driving voltage, luminous efficiency, and light-emitting color at a luminance of 1,000 nit, and time taken for luminance to reduce from 100% to 95% at a luminance of 10,000 nit (lifetime: T95) for the OLEDs of Device Examples 9 and 10 produced as described above are shown in Table 4 below.

TABLE 4

| | | | Driving | Luminous | Light- | |
|---|---|---|---|---|---|---|
| | First | Second | Voltage | Efficiency | Emitting | Lifetime |
| | Host | Host | (V) | (cd/A) | Color | T95(hr) |
| Device Example 9 | H2-144 | H1-193 | 2.9 | 32.7 | Red | 43.4 |
| Device Example 10 | H1-209 | H3-26 | 2.9 | 34.1 | Red | 117.5 |

From Table 4 above, it can be confirmed that the driving voltage, luminous efficiency, and lifetime of the organic electroluminescent device including the compound according to the present invention as a host material are excellent.

The compounds used in the Device Examples and the Comparative Example are shown in Table 5 below.

TABLE 5

| | |
|---|---|
| Hole Injection Layer/Hole Transport Layer | 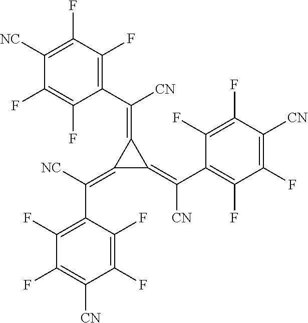 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] |
| | HI-1 |
| | 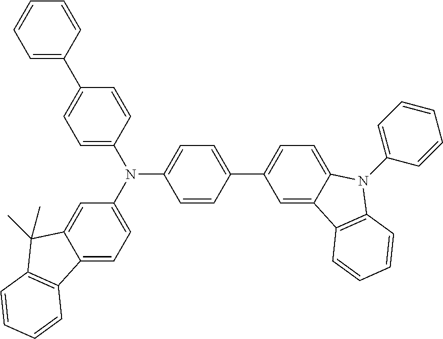 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| | HT-1 |
| | 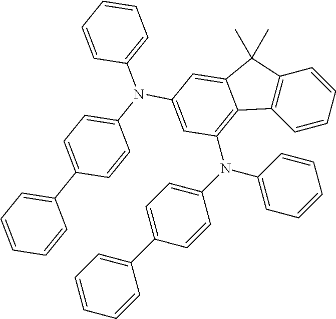 [SMILES: CC1(C)c2ccccc2-c2c(N(c3ccccc3)c3ccc(-c4ccccc4)cc3)cc(N(c3ccccc3)c3ccc(-c4ccccc4)cc3)cc21] |
| | HT-2 |
| | 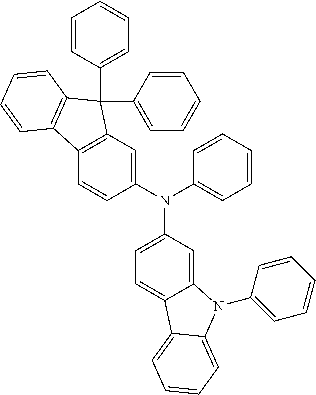 [SMILES: c1ccc(N(c2ccc3c(c2)C(c2ccccc2)(c2ccccc2)c2ccccc2-3)c2ccc3c4ccccc4n(-c4ccccc4)c3c2)cc1] |
| | HT-3 |
| | 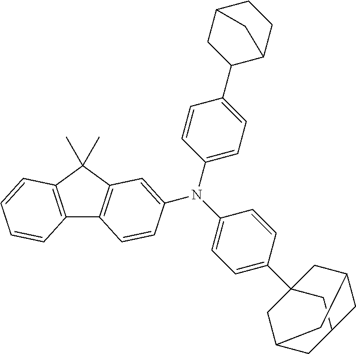 [SMILES: CC1(C)c2ccccc2-c2ccc(N(c3ccc(C4CC5CCC4C5)cc3)c3ccc(C45CC6CC(CC(C6)C4)C5)cc3)cc21] |
| | HT-4 |
| | 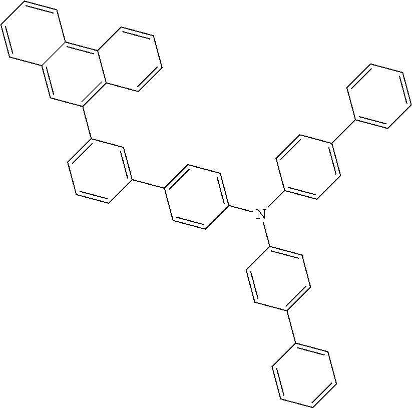 [SMILES: c1ccc(-c2ccc(N(c3ccc(-c4ccccc4)cc3)c3ccc(-c4cccc(-c5cc6ccccc6c6ccccc56)c4)cc3)cc2)cc1] |
| | HT-5 |
| | 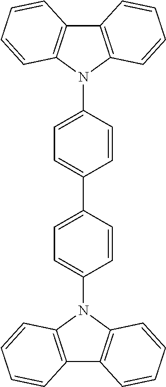 [SMILES: c1ccc2c(c1)c1ccccc1n2-c1ccc(-c2ccc(-n3c4ccccc4c4ccccc43)cc2)cc1] |
| | CBP |
| | 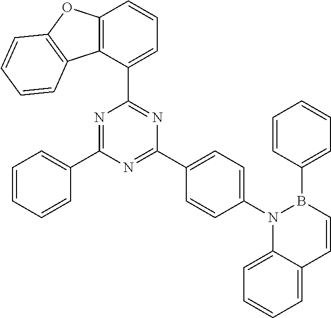 [SMILES: C1=Cc2ccccc2N(c2ccc(-c3nc(-c4ccccc4)nc(-c4cccc5oc6ccccc6c45)n3)cc2)B1c1ccccc1] |
| | H1-105 |
| | 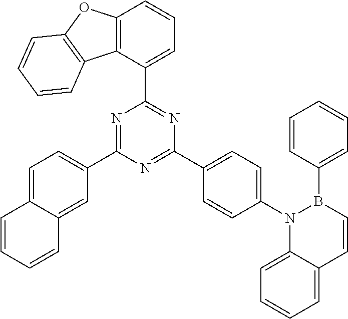 [SMILES: C1=Cc2ccccc2N(c2ccc(-c3nc(-c4ccc5ccccc5c4)nc(-c4cccc5oc6ccccc6c45)n3)cc2)B1c1ccccc1] |
| | H1-106 |
| | 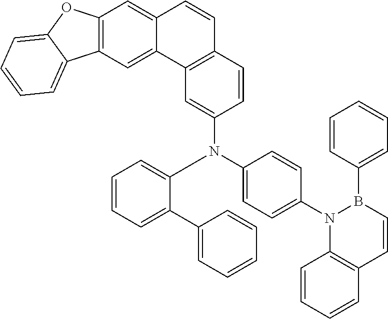 [SMILES: C1=Cc2ccccc2N(c2ccc(N(c3ccc4ccc5cc6oc7ccccc7c6cc5c4c3)c3ccccc3-c3ccccc3)cc2)B1c1ccccc1] |
| | H1-119 |
| | 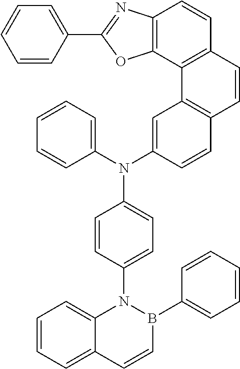 [SMILES: C1=Cc2ccccc2N(c2ccc(N(c3ccccc3)c3ccc4ccc5ccc6nc(-c7ccccc7)oc6c5c4c3)cc2)B1c1ccccc1] |
| | H1-118 |
| Light-Emitting Layer | 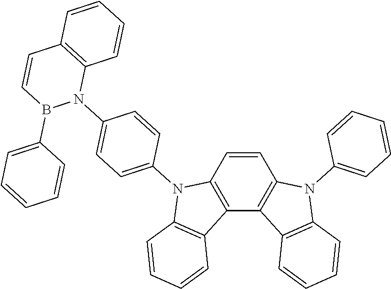 [SMILES: C1=Cc2ccccc2N(c2ccc(-n3c4ccccc4c4c5c6ccccc6n(-c6ccccc6)c5ccc43)cc2)B1c1ccccc1] |
| | H1-115 |
| | 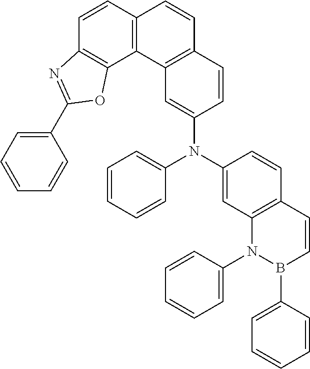 [SMILES: C1=Cc2ccc(N(c3ccccc3)c3ccc4ccc5ccc6nc(-c7ccccc7)oc6c5c4c3)cc2N(c2ccccc2)B1c1ccccc1] |
| | H1-208 |
| | 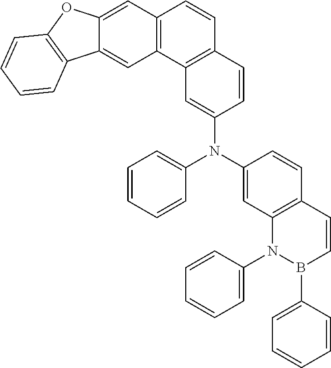 [SMILES: C1=Cc2ccc(N(c3ccccc3)c3ccc4ccc5cc6oc7ccccc7c6cc5c4c3)cc2N(c2ccccc2)B1c1ccccc1] |
| | H1-209 |
| | 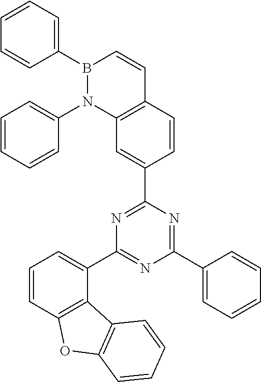 [SMILES: C1=Cc2ccc(-c3nc(-c4ccccc4)nc(-c4cccc5oc6ccccc6c45)n3)cc2N(c2ccccc2)B1c1ccccc1] |
| | H1-193 |
| | 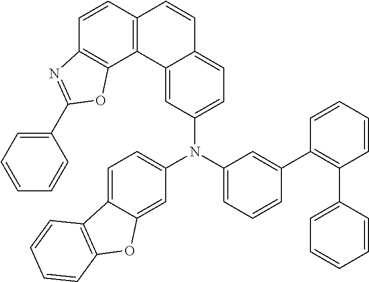 [SMILES: c1ccc(-c2nc3ccc4ccc5ccc(N(c6cccc(-c7ccccc7-c7ccccc7)c6)c6ccc7c(c6)oc6ccccc67)cc5c4c3o2)cc1] |
| | H2-144 |
| | 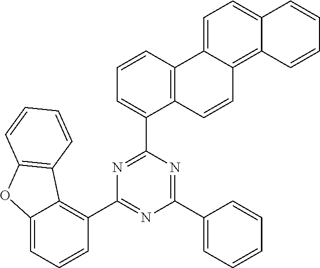 [SMILES: c1ccc(-c2nc(-c3cccc4c3ccc3c5ccccc5ccc43)nc(-c3cccc4oc5ccccc5c34)n2)cc1] |
| | H3-26 |
| | 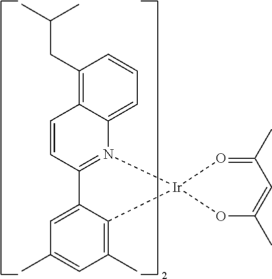 |
| | D-39 |
| Buffer Layer/ Electron Transport Layer/ Electron Injection Layer | 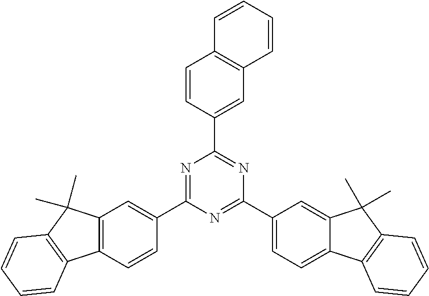 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | ET-1 |
| | 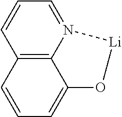 |
| | EI-1 |
| | 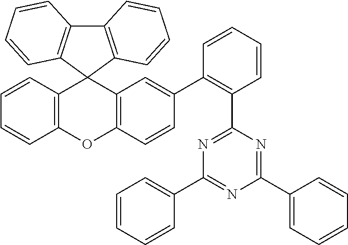 [SMILES: c1ccc(-c2nc(-c3ccccc3)nc(-c3ccccc3-c3ccc4c(c3)C3(c5ccccc5O4)c4ccccc4-c4ccccc43)n2)cc1] |
| | BF-1 |
| | 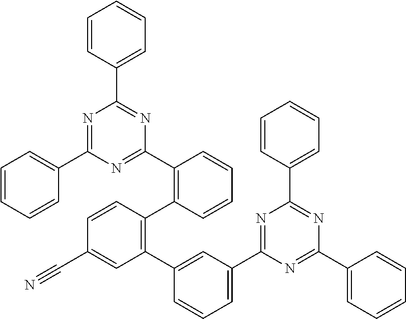 [SMILES: N#Cc1ccc(-c2ccccc2-c2nc(-c3ccccc3)nc(-c3ccccc3)n2)c(-c2cccc(-c3nc(-c4ccccc4)nc(-c4ccccc4)n3)c2)c1] |
| | ET-2 |

### Device Example 11: Preparation of an OLED Comprising an Electron Transport Layer Compound According to the Present Disclosure in an Electron Transport Layer

An OLED according to the present disclosure was prepared. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and thereafter was stored in isopropyl alcohol and then used. Thereafter, the ITO substrate was mounted on a substrate holder of a vacuum vapor deposition apparatus. Compound HI-1 was then introduced into a cell of the vacuum vapor deposition apparatus, and Compound HT-3 was introduced into another cell. The two materials were evaporated at different rates, and Compound HI-1 was deposited in a doping amount of 3 wt % based on the total amount of Compounds HI-1 and HT-3 to form a hole injection layer having a thickness of 10 nm. Compound HT-3 was then deposited on the hole injection layer to form a first hole transport layer with a thickness of 80 nm. Thereafter, Compound HT-6 was introduced into another cell of the vacuum vapor deposition apparatus and was evaporated by applying an electric current to the cell, thereby forming a second hole transport layer with a thickness of 5 nm on the first hole transport layer. After formation of the hole injection layer and the hole transport layers, a light-emitting layer was deposited thereon as follows: Compound BH-1 was introduced into a cell of the vacuum vapor deposition apparatus as a host, and Compound BD-1 was introduced into the other cell as a dopant. The two materials were evaporated at different rates to deposit in a doping amount of 3 wt % based on the total amount of the host and dopant to form a light-emitting layer with a thickness of 20 nm on the second hole transport layer. Thereafter, Compound BF-1 was deposited on the light-emitting layer to form a hole blocking layer with a thickness of 5 nm. Next, the compound shown in Table 6 was introduced into a cell of the vacuum vapor deposition apparatus and Compound EI-1 was introduced into another cell, and the two materials were evaporated in a weight ratio of 1:1 to form an electron transport layer with a thickness of 30 nm. Yb was evaporated to deposit an electron injection layer with a thickness of 2 nm on the electron transport layer. An Al cathode was deposited with a thickness of 80 nm on the electron injection layer by using another vacuum vapor deposition apparatus, thereby producing an OLED. All of the materials used for producing the OLED were purified by vacuum sublimation at 10⁻⁶ Torr.

### Comparative Example 2: Preparation of an OLED Comprising a Electron Transport Layer Compound not According to the Present Disclosure in an Electron Transport Layer

An OLED was produced in the same manner as in Device Example 11, except that the compound of Table 6 below was used as the electron transport layer compound.

The luminous efficiency and time taken for luminance to reduce from 100% to 95% at a luminance of 1,000 nit (lifetime: T95) for the OLEDs of Device Example 11 and Comparative Example 2 produced as described above are shown in Table 6 below.

TABLE 6

| | Electron | Luminous | Lifetime |
|---|---|---|---|
| | Transport | Efficiency | T95 |
| | Layer | [cd/A] | [hr] |
| Device | H1-292 | 6.9 | 90 |
| Example 11 | | | |
| Comparative | ET-2 | 6.7 | 60 |
| Example 2 | | | |

From Table 6 above, it can be confirmed that the organic electroluminescent device including the compound according to the present disclosure in the electron transport layer has superior luminous efficiency and lifetime compared to the organic electroluminescent device including the compound not according to the present disclosure in the electron transport layer.

The compounds used in the Device Example and the Comparative Example are shown in Table 7 below.

TABLE 7

| | |
|---|---|
| Hole Injection Layer/Hole Transport Layer | 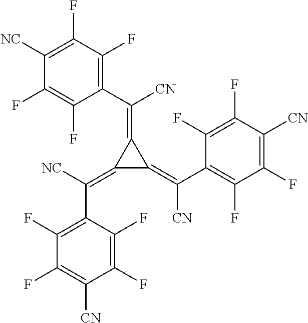 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] |
| | HI-1 |
| | 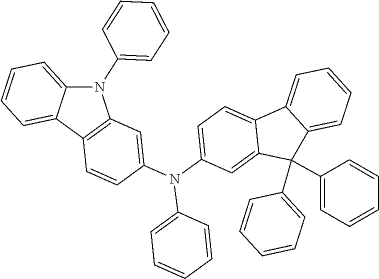 [SMILES: c1ccc(N(c2ccc3c(c2)C(c2ccccc2)(c2ccccc2)c2ccccc2-3)c2ccc3c4ccccc4n(-c4ccccc4)c3c2)cc1] |
| | HT-3 |
| | 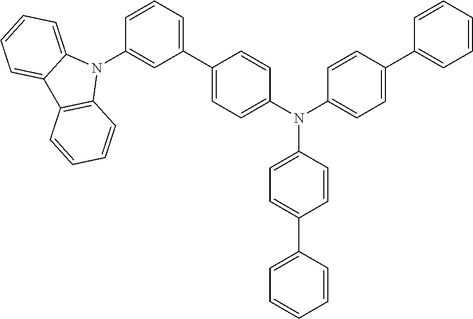 [SMILES: c1ccc(-c2ccc(N(c3ccc(-c4ccccc4)cc3)c3ccc(-c4cccc(-n5c6ccccc6c6ccccc65)c4)cc3)cc2)cc1] |
| | HT-6 |
| Light-Emitting Layer | 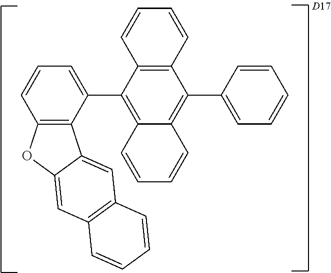 |
| | BH-1 |
| | 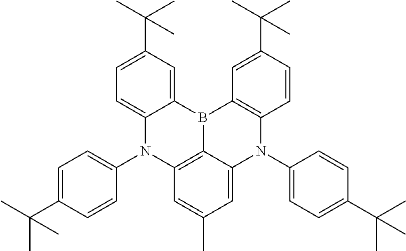 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1] |
| | BD-1 |
| Electron Blocking Layer/ Electron Transport Layer/ Electron Injection Layer | 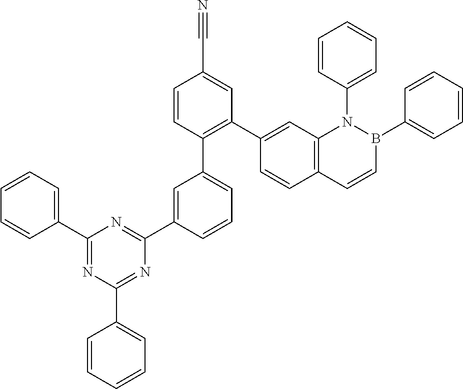 [SMILES: N#Cc1ccc(-c2cccc(-c3nc(-c4ccccc4)nc(-c4ccccc4)n3)c2)c(-c2ccc3c(c2)N(c2ccccc2)B(c2ccccc2)C=C3)c1] |
| | H1-292 |
| | 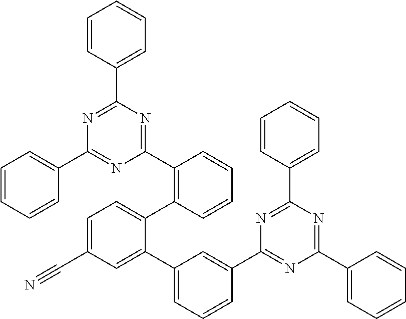 [SMILES: N#Cc1ccc(-c2ccccc2-c2nc(-c3ccccc3)nc(-c3ccccc3)n2)c(-c2cccc(-c3nc(-c4ccccc4)nc(-c4ccccc4)n3)c2)c1] |
| | ET-2 |
| | 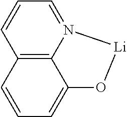 |
| | EI-1 |
| | 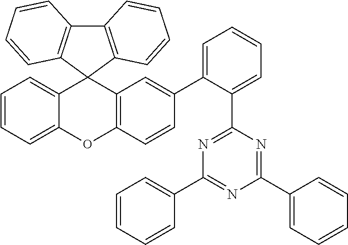 [SMILES: c1ccc(-c2nc(-c3ccccc3)nc(-c3ccccc3-c3ccc4c(c3)C3(c5ccccc5O4)c4ccccc4-c4ccccc43)n2)cc1] |
| | BF-1 |

### Device Examples 12 and 13: Preparation of OLEDs Deposited with a Host Compound According to the Present Disclosure as a Host

An OLED according to the present disclosure was prepared. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and thereafter was stored in isopropyl alcohol and then used.

Thereafter, the ITO substrate was mounted on a substrate holder of a vacuum vapor deposition apparatus. Compound HI-1 was then introduced into a cell of the vacuum vapor deposition apparatus, and Compound HT-7 was introduced into another cell. The two materials were evaporated at different rates, and Compound HI-1 was deposited in a doping amount of 5 wt % based on the total amount of Compounds HI-1 and HT-7 to form a hole injection layer having a thickness of 10 nm. Compound HT-7 was then deposited on the hole injection layer to form a first hole transport layer with a thickness of 80 nm. Thereafter, Compound HT-8 was introduced into another cell of the vacuum vapor deposition apparatus and was evaporated by applying an electric current to the cell, thereby forming a second hole transport layer with a thickness of 15 nm on the first hole transport layer. After formation of the hole injection layer and the hole transport layers, a light-emitting layer was deposited thereon as follows: The compound as shown in Table 8 was introduced into a cell of the vacuum vapor deposition apparatus as a host, and Compound BD-2 was introduced into the other cell as a dopant. The two materials were evaporated at different rates to deposit in a doping amount of 2 wt % based on the total amount of the host and dopant to form a light-emitting layer with a thickness of 18 nm on the second hole transport layer. Compound ET-3 was deposited thereon to form a buffer layer with a thickness of 5 nm. Next, Compound EI-1 and Compound EI-2 were introduced into another two cells and evaporated at a rate of 1:2 to form an electron transport layer having a thickness of 25 nm on the light-emitting layer. Yb was introduced into another two cells and evaporated to deposit an electron injection layer with a thickness of 1 nm on the electron transport layer. An Al cathode was deposited with a thickness of 80 nm on the electron injection layer by using another vacuum vapor deposition apparatus, thereby producing an OLED. All of the materials used for producing the OLED were purified by vacuum sublimation at 10⁻⁶ Torr.

### Comparative Example 3: Preparation of an OLED Comprising a Host Compound not According to the Present Disclosure

An OLED was produced in the same manner as in Device Example 12, except that the compound of Table 8 below was used as the host material of the electron transport layer.

The driving voltage at a luminance of 500 nit, and the minimum time taken for luminance to reduce from 100% to 97% at a luminance according to CIE color coordinate system (lifetime: T97) converted to a percentage, for the OLEDs of Device Examples 12 and 13 and Comparative Example 3 produced as described above are shown in Table 8 below.

TABLE 8

| | | Driving | Lifetime |
|---|---|---|---|
| | | Voltage | T97 |
| | Host | [V] | [%] |
| Device | H1-252 | 3.48 | 158 |
| Example 12 | | | |
| Device | H1-234 | 3.59 | 143 |
| Example 13 | | | |
| Comparative | BH-2 | 3.64 | 100 |
| Example 3 | | | |

From Table 8 above, it can be confirmed that the organic electroluminescent device including the host compound according to the present invention has superior driving voltage and lifetime compared to the organic electroluminescent device including the host compound not according to the present invention.

The compounds used in Device Examples 12 and 13 and Comparative Example 3 are shown in Table 9 below.

TABLE 9

| | |
|---|---|
| Hole Injection Layer/Hole Transport Layer | 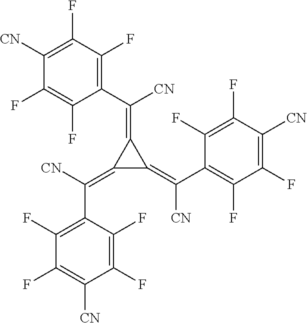 |
| | HI-1 |
| | 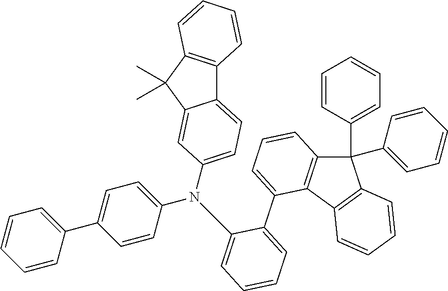 [SMILES: CC1(C)c2ccccc2-c2ccc(N(c3ccc(-c4ccccc4)cc3)c3ccccc3-c3cccc4c3-c3ccccc3C4(c3ccccc3)c3ccccc3)cc21] |
| | HT-7 |
| | 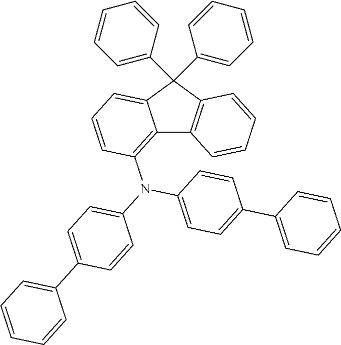 [SMILES: c1ccc(-c2ccc(N(c3ccc(-c4ccccc4)cc3)c3cccc4c3-c3ccccc3C4(c3ccccc3)c3ccccc3)cc2)cc1] |
| | HT-8 |
| Light-Emitting Layer | 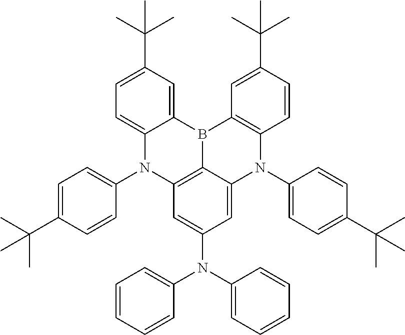 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1] |
| | BD-2 |
| | 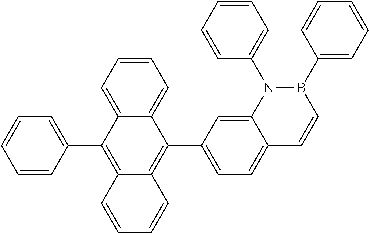 [SMILES: C1=Cc2ccc(-c3c4ccccc4c(-c4ccccc4)c4ccccc34)cc2N(c2ccccc2)B1c1ccccc1] |
| | H1-252 |
| | 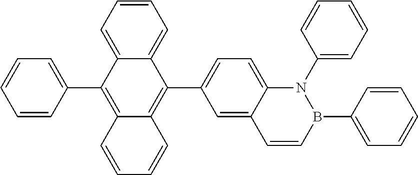 [SMILES: C1=Cc2cc(-c3c4ccccc4c(-c4ccccc4)c4ccccc34)ccc2N(c2ccccc2)B1c1ccccc1] |
| | H1-234 |
| | 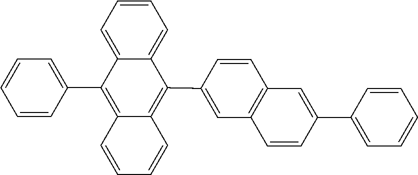 [SMILES: c1ccc(-c2ccc3cc(-c4c5ccccc5c(-c5ccccc5)c5ccccc45)ccc3c2)cc1] |
| | BH-2 |
| Electron Buffer Layer | 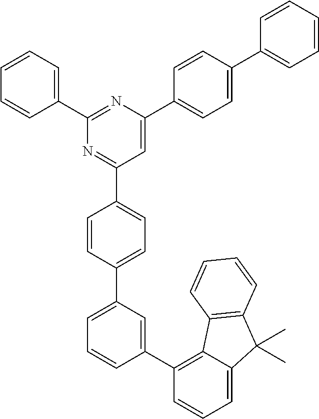 [SMILES: CC1(C)c2ccccc2-c2c(-c3cccc(-c4ccc(-c5cc(-c6ccc(-c7ccccc7)cc6)nc(-c6ccccc6)n5)cc4)c3)cccc21] |
| | ET-3 |
| Electron Transport Layer/ Electron Injection Layer | 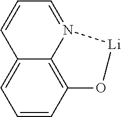 |
| | EI-1 |
| | 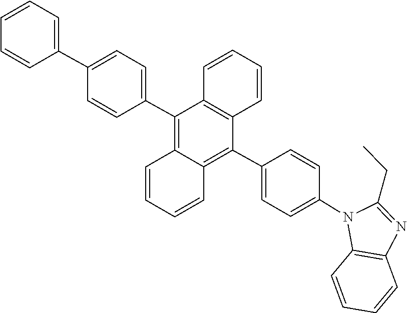 [SMILES: CCc1nc2ccccc2n1-c1ccc(-c2c3ccccc3c(-c3ccc(-c4ccccc4)cc3)c3ccccc23)cc1] |
| | EI-2 |

1. A plurality of host materials comprising at least one first host compound and at least one second host compound, wherein the first host compound is represented by the following Formula 1 and the second host compound is different from the first host compound: 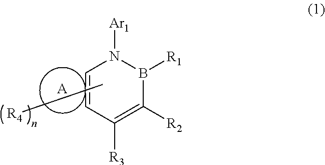
in Formula 1,
ring A is not present, or represents a substituted or unsubstituted benzene, or a substituted or unsubstituted naphthalene;
Ar₁ and R₁ to R₄ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s); and
n represents an integer of 1 to 6; and if n is an integer of 2 or more, each of R₄ may be the same as or different from each other.

2. The plurality of host materials according to claim 1, wherein Formula 1 is represented by any one of the following Formulas 1-1 to 1-3: 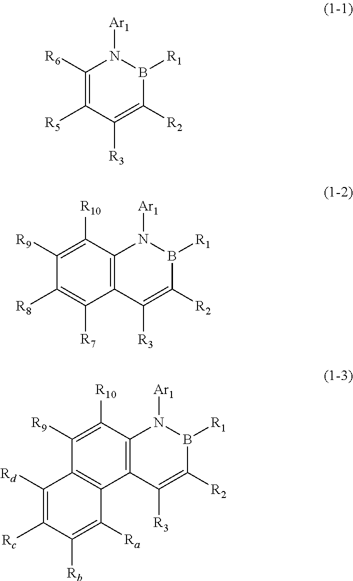
in Formulas 1-1 to 1-3,
R₅ to R₁₀ and Rₐ to R_{d} are as defined for R₄ in claim 1; and
R₁ to R₃, and Ar₁ are as defined in claim 1.

3. The plurality of host materials according to claim 1, wherein at least one of Ar₁ and R₁ to R₄ in Formula 1 represent a substituted or unsubstituted (C₆-C₃₀)aryl, a substituted or unsubstituted (3- to 30-membered)heteroaryl, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino.

4. The plurality of host materials according to claim 1, wherein at least one of Ar₁ and R₁ to R₄ in Formula 1 is represented by any one of the following Formulas 1-a to 1-c: 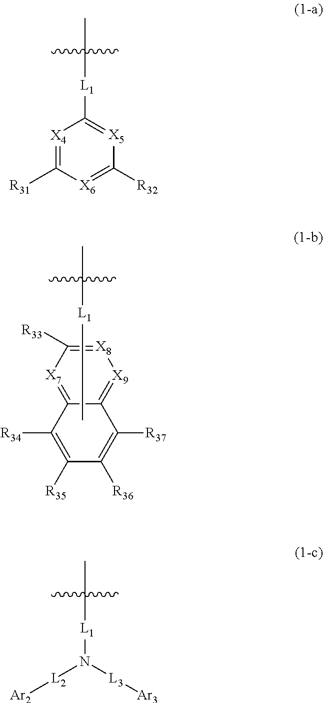
in Formulas 1-a to 1-c, 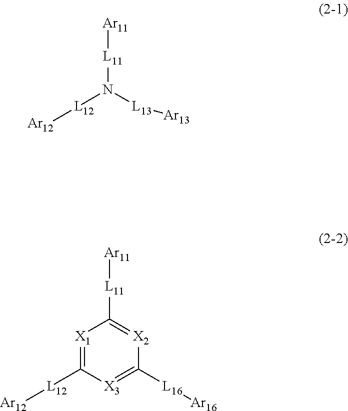
represents a site linked to Formula 1;
L₁ to L₃ each independently represent a single bond, a substituted or unsubstituted (C₆-C₃₀)arylene, or a substituted or unsubstituted (3- to 30-membered)heteroarylene;
X₄ to X₅ each independently represent N or CR₃₈, with a proviso that at least one of X₄ to X₆ and at least one of X₇ to X₉ represent N;
R₃₁ to R₃₈ each independently represent hydrogen, deuterium, a halogen, a cyano, a substituted or unsubstituted (C₁-C₃₀)alkyl, a substituted or unsubstituted (C₆-C₃₀)aryl, or a substituted or unsubstituted (3- to 30-membered)heteroaryl;
with a proviso that in Formula 1-b, any one of X₇ to X₉, and R₃₃ to R₃₈ is linked to L₁; and
Ar₂ and Ar₃ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino.

5. The plurality of host materials according to claim 1, wherein the second host compound is represented by any one of the following Formulas 2-1 and 2-2: 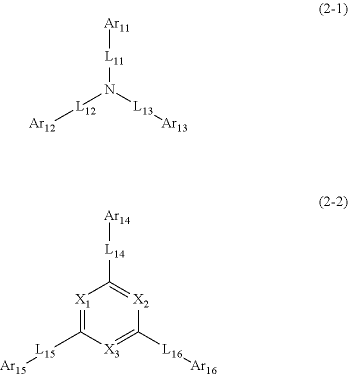
in Formulas 2-1 and 2-2,
X₁ to X₃ each independently represent N or CR₁₁, with a proviso that at least one of X₁ to X₃ represents N;
L₁ to L₁₆ each independently represent a single bond, a substituted or unsubstituted (C₆-C₃₀)arylene, or a substituted or unsubstituted (3- to 30-membered)heteroarylene; and
Ar₁₁ to Ar₁₆ and R₁₁ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s).

6. The plurality of host materials according to claim 1, wherein the substituted alkyl, the substituted aryl(ene), the substituted heteroaryl(ene), the substituted cycloalkyl, the substituted alkoxy, the substituted trialkylsilyl, the substituted dialkylarylsilyl, the substituted alkyldiarylsilyl, the substituted triarylsilyl, the substituted fused ring group of an aliphatic ring(s) and an aromatic ring(s), the substituted mono- or dialkylamino, the substituted mono- or dialkenylamino, the substituted alkylalkenylamino, the substituted mono- or diarylamino, the substituted alkylarylamino, the substituted mono- or diheteroarylamino, the substituted alkylheteroarylamino, the substituted alkenylarylamino, the substituted alkenylheteroarylamino, and the substituted arylheteroarylamino each independently are substituted with at least one selected from the group consisting of deuterium, a halogen, a cyano, a carboxyl, a nitro, a hydroxyl, a (C₁-C₃₀)alkyl, a halo(C₁-C₃₀)alkyl, a (C₂-C₃₀)alkenyl, a (C₂-C₃₀)alkynyl, a (C₁-C₃₀)alkoxy, a (C₁-C₃₀)alkylthio, a (C₃-C₃₀)cycloalkyl, a (C₃-C₃₀)cycloalkenyl, a (3- to 7-membered)heterocycloalkyl, a (C₆-C₃₀)aryloxy, a (C₆-C₃₀)arylthio, a (3- to 30-membered)heteroaryl, a (C₆-C₃₀)aryl, a tri(C₁-C₃₀)alkylsilyl, a tri(C₆-C₃₀)arylsilyl, a di(C₁-C₃₀)alkyl(C₆-C₃₀)arylsilyl, a (C₁-C₃₀)alkyldi(C₆-C₃₀)arylsilyl, a fused ring group of a (C₃-C₃₀) aliphatic ring(s) and a (C₆-C₃₀) aromatic ring(s), an amino, a mono- or di(C₁-C₃₀)alkylamino, a substituted or unsubstituted mono- or di(C₆-C₃₀)arylamino, a (C₁-C₃₀)alkyl(C₆-C₃₀)arylamino, a mono- or di(3- to 30-membered)heteroarylamino, a (C₁-C₃₀)alkyl(3- to 30-membered)heteroarylamino, a (C₆-C₃₀)aryl(3- to 30-membered)heteroarylamino, a (C₁-C₃₀)alkylcarbonyl, a (C₁-C₃₀)alkoxycarbonyl, a (C₆-C₃₀)arylcarbonyl, a (C₆-C₃₀)arylphosphinyl, a di(C₆-C₃₀)arylboronyl, a di(C₁-C₃₀)alkylboronyl, a (C₁-C₃₀)alkyl(C₆-C₃₀)arylboronyl, a (C₆-C₃₀)aryl(C₁-C₃₀)alkyl, a (C₁-C₃₀)alkyl(C₆-C₃₀)aryl, and a combination thereof.

7. The plurality of host materials according to claim 5, wherein Ar₁₁ in Formula 2-1 is represented by the following Formula 2-1a: 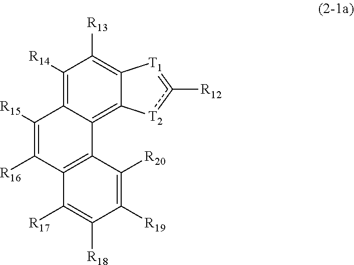
in Formula 2-1a,
T₁ and T₂ each independently represent —N═, —NR₂₁—, —O—, or —S—, with a proviso that one of T₁ and T₂ represents —N═, and the other of T₁ and T₂ represents —NR₂₁—, —O—, or —S—; and
R₁₂ to R₂₁ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring group of a (C₃-C₃₀) aliphatic ring(s) and a (C₆-C₃₀) aromatic ring(s), a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3-to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino; or may be linked to an adjacent substituent(s) to form a ring(s); with a proviso that any one of R₁₂ to R₂₁ is linked to L₁₁.

8. The plurality of host materials according to claim 5, wherein Ar₁₄ in Formula 2-2 is represented by the following Formula 2-2a: 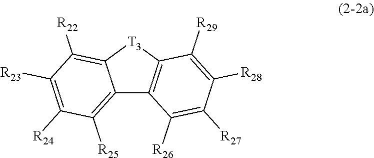
in Formula 2-2a,
T₃ represents O or S; and
R₂₂ to R₂₉ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, or a substituted or unsubstituted tri(C₆-C₃₀)arylsilyl; or may be linked to an adjacent substituent(s) to form a ring(s); with a proviso that any one of R₂₂ to R₂₉ is linked to L₁₄.

9. The plurality of host materials according to claim 1, wherein the compound represented by Formula 1 is selected from the following compounds: 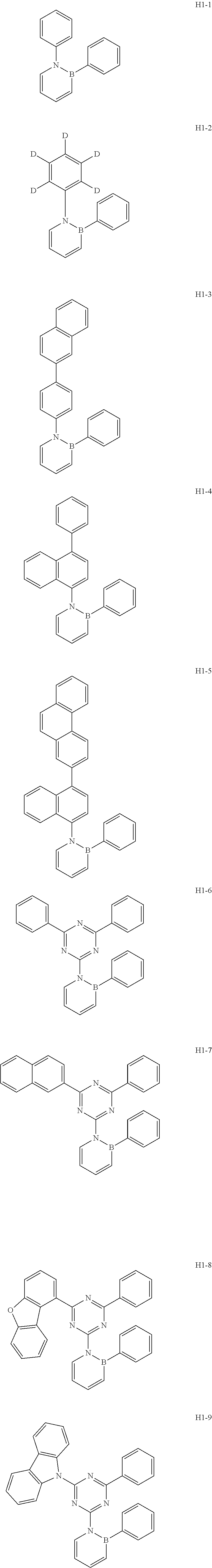 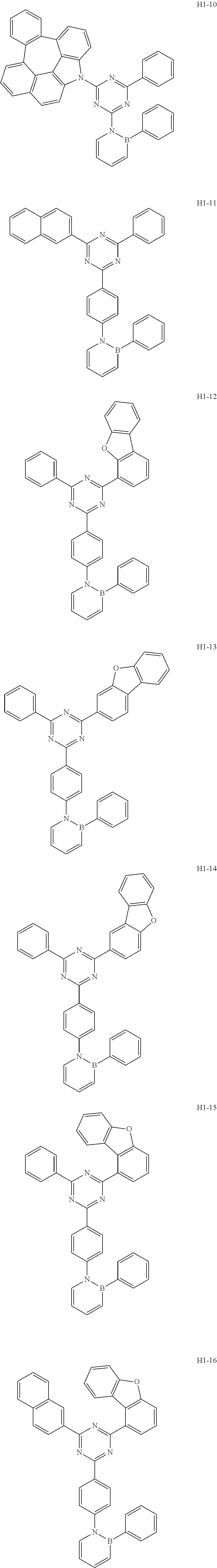 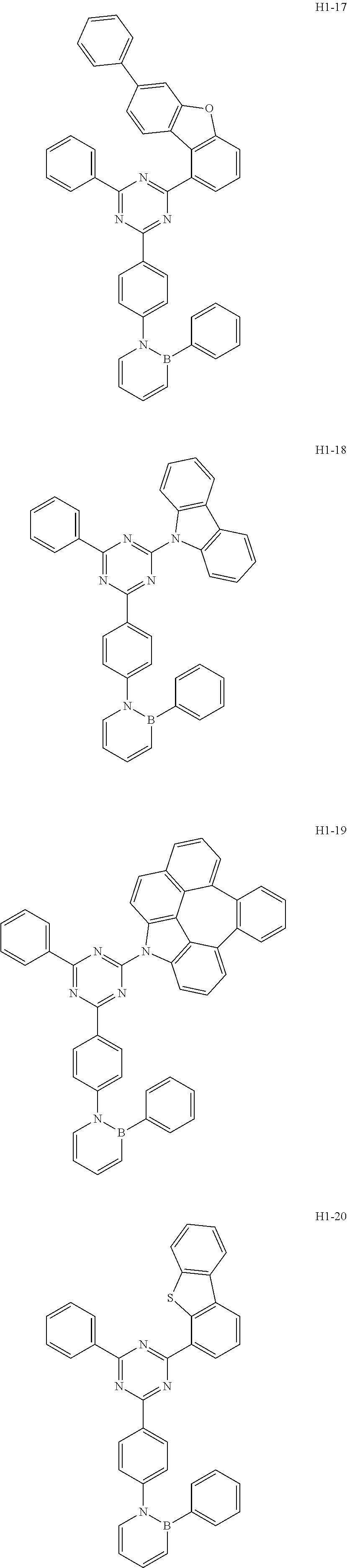 [SMILES: C1=CB(c2ccccc2)N(c2ccc(-c3nc(-c4ccccc4)nc(-c4cccc5oc6cc(-c7ccccc7)ccc6c45)n3)cc2)C=C1 ; C1=CB(c2ccccc2)N(c2ccc(-c3nc(-c4ccccc4)nc(-n4c5ccccc5c5ccccc54)n3)cc2)C=C1 ; C1=CB(c2ccccc2)N(c2ccc(-c3nc(-c4ccccc4)nc(-n4c5cccc6c5c5c7c(cccc7ccc54)-c4ccccc4-6)n3)cc2)C=C1 ; C1=CB(c2ccccc2)N(c2ccc(-c3nc(-c4ccccc4)nc(-c4cccc5c4sc4ccccc45)n3)cc2)C=C1] 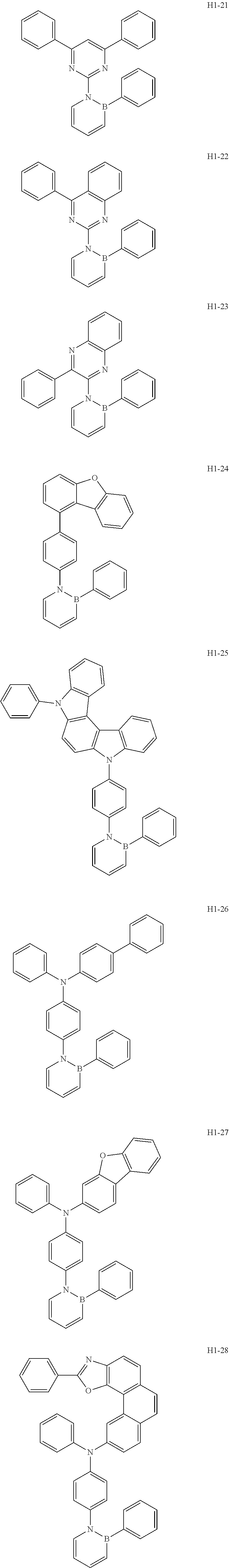 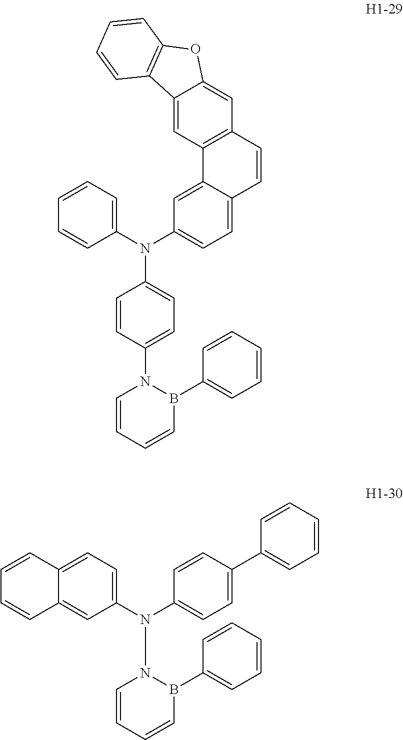 [SMILES: C1=CB(c2ccccc2)N(c2ccc(N(c3ccccc3)c3ccc4ccc5cc6oc7ccccc7c6cc5c4c3)cc2)C=C1 ; C1=CB(c2ccccc2)N(N(c2ccc(-c3ccccc3)cc2)c2ccc3ccccc3c2)C=C1] 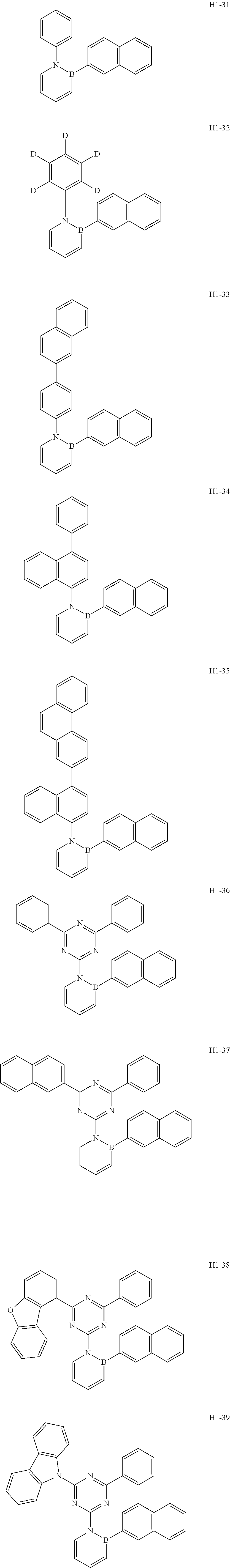 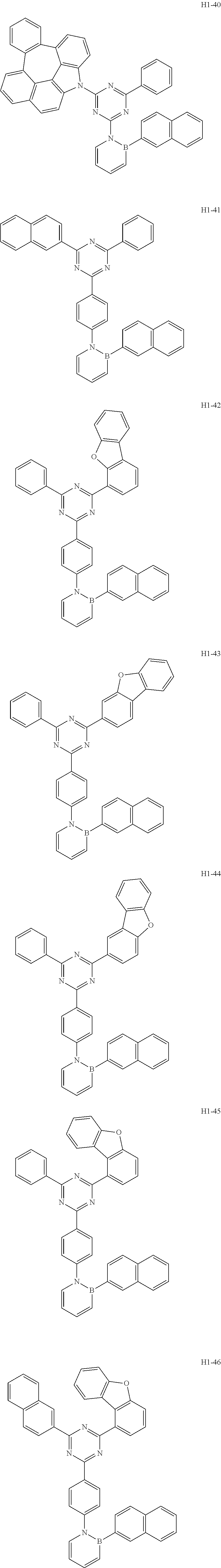 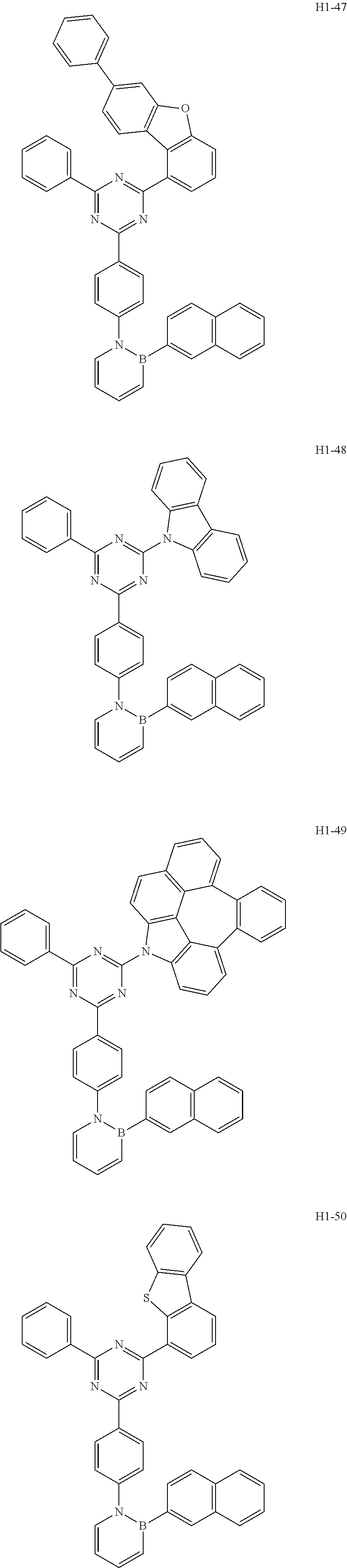 [SMILES: C1=CB(c2ccc3ccccc3c2)N(c2ccc(-c3nc(-c4ccccc4)nc(-c4cccc5oc6cc(-c7ccccc7)ccc6c45)n3)cc2)C=C1 ; C1=CB(c2ccc3ccccc3c2)N(c2ccc(-c3nc(-c4ccccc4)nc(-n4c5ccccc5c5ccccc54)n3)cc2)C=C1 ; C1=CB(c2ccc3ccccc3c2)N(c2ccc(-c3nc(-c4ccccc4)nc(-n4c5cccc6c5c5c7c(cccc7ccc54)-c4ccccc4-6)n3)cc2)C=C1 ; C1=CB(c2ccc3ccccc3c2)N(c2ccc(-c3nc(-c4ccccc4)nc(-c4cccc5c4sc4ccccc45)n3)cc2)C=C1] 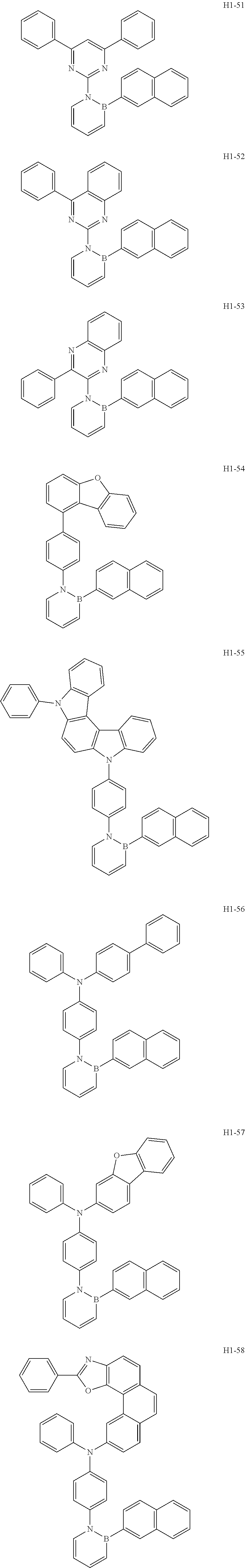 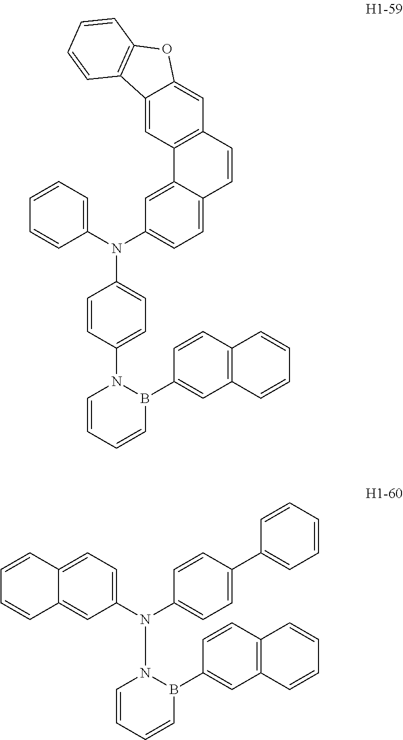 [SMILES: C1=CB(c2ccc3ccccc3c2)N(c2ccc(N(c3ccccc3)c3ccc4ccc5cc6oc7ccccc7c6cc5c4c3)cc2)C=C1 ; C1=CB(c2ccc3ccccc3c2)N(N(c2ccc(-c3ccccc3)cc2)c2ccc3ccccc3c2)C=C1] 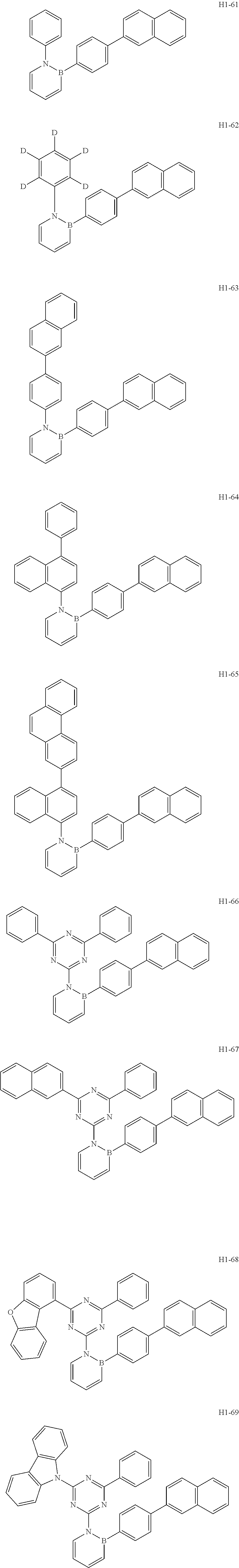 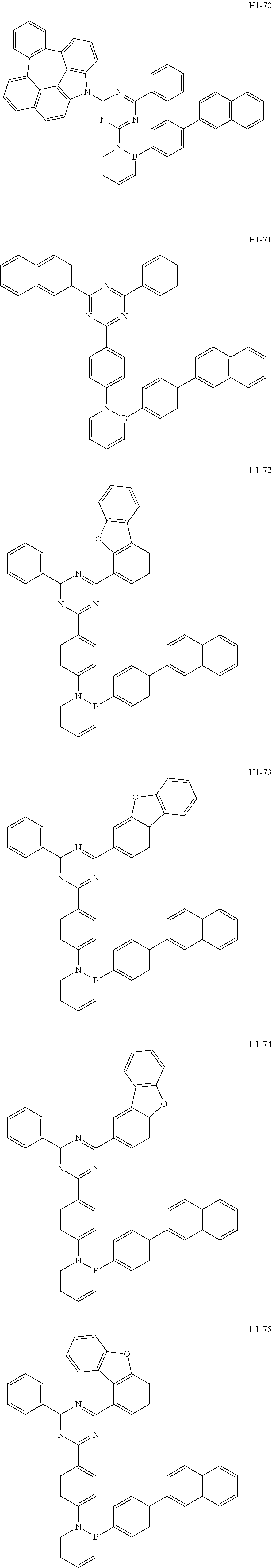 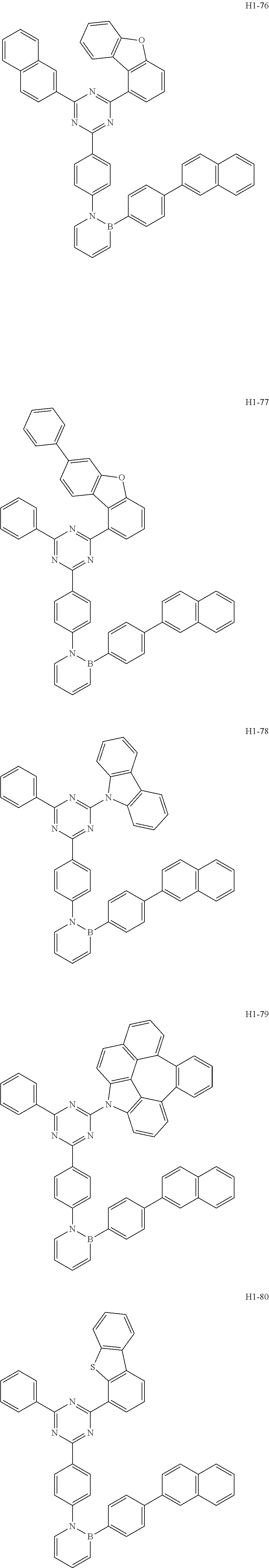 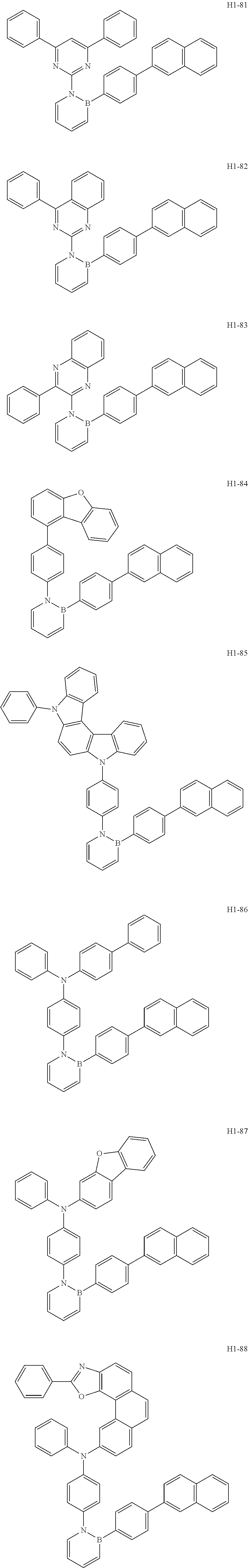 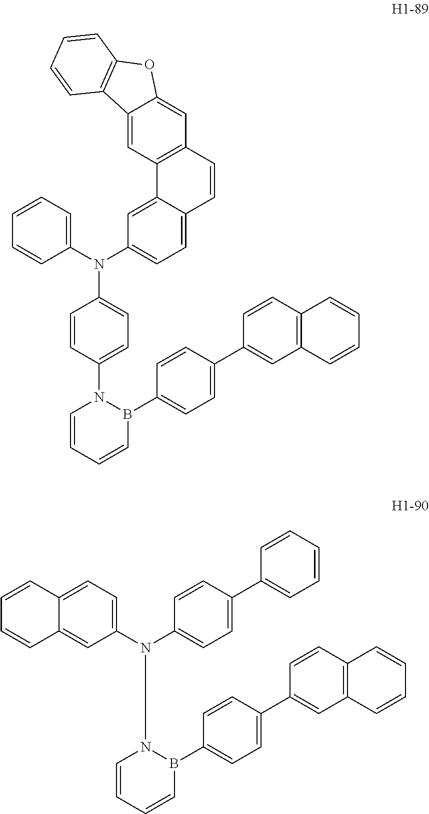 [SMILES: C1=CB(c2ccc(-c3ccc4ccccc4c3)cc2)N(c2ccc(N(c3ccccc3)c3ccc4ccc5cc6oc7ccccc7c6cc5c4c3)cc2)C=C1 ; C1=CB(c2ccc(-c3ccc4ccccc4c3)cc2)N(N(c2ccc(-c3ccccc3)cc2)c2ccc3ccccc3c2)C=C1] 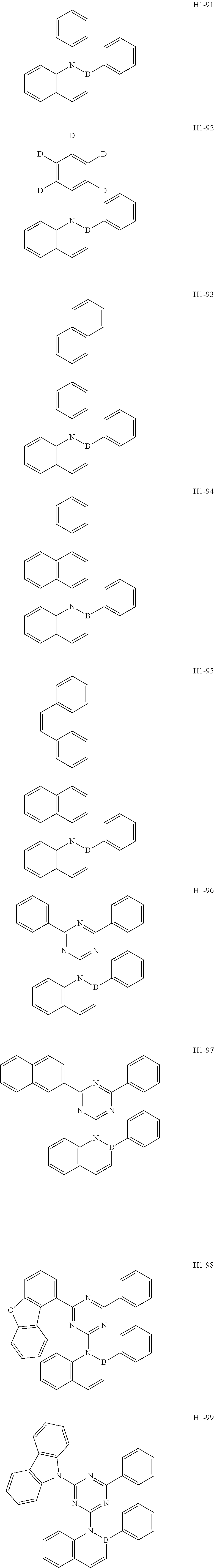 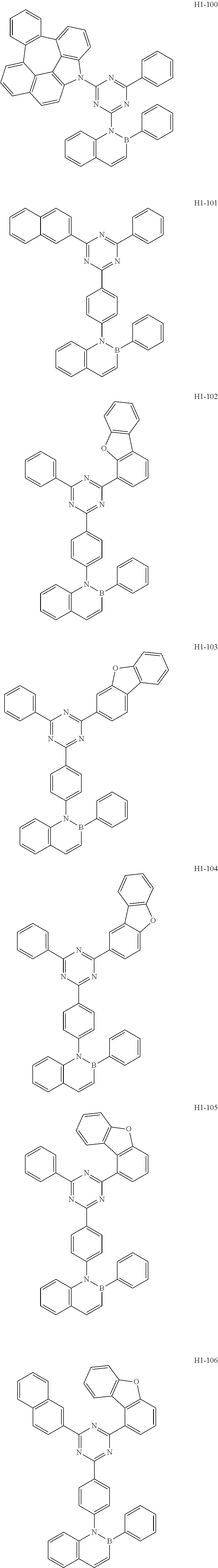 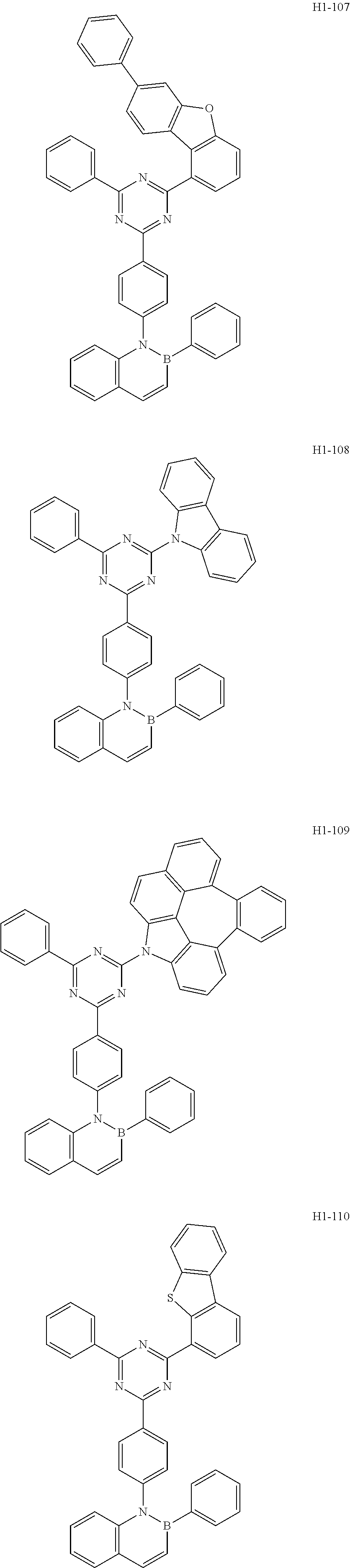 [SMILES: C1=Cc2ccccc2N(c2ccc(-c3nc(-c4ccccc4)nc(-c4cccc5oc6cc(-c7ccccc7)ccc6c45)n3)cc2)B1c1ccccc1 ; C1=Cc2ccccc2N(c2ccc(-c3nc(-c4ccccc4)nc(-n4c5ccccc5c5ccccc54)n3)cc2)B1c1ccccc1 ; C1=Cc2ccccc2N(c2ccc(-c3nc(-c4ccccc4)nc(-n4c5cccc6c5c5c7c(cccc7ccc54)-c4ccccc4-6)n3)cc2)B1c1ccccc1 ; C1=Cc2ccccc2N(c2ccc(-c3nc(-c4ccccc4)nc(-c4cccc5c4sc4ccccc45)n3)cc2)B1c1ccccc1] 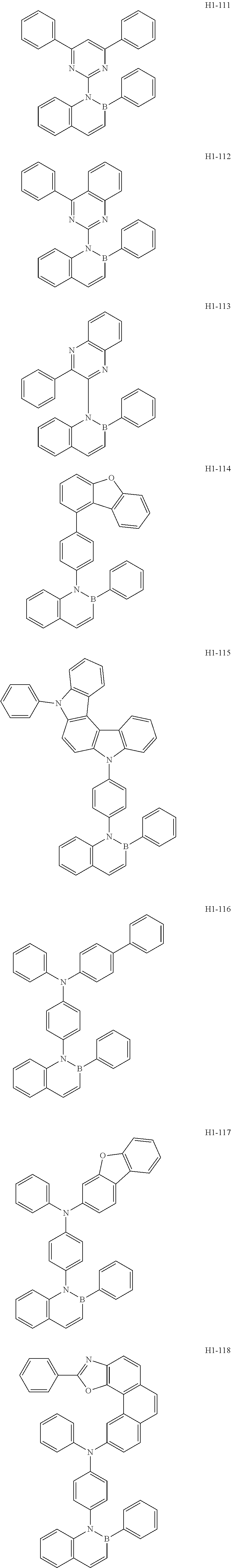 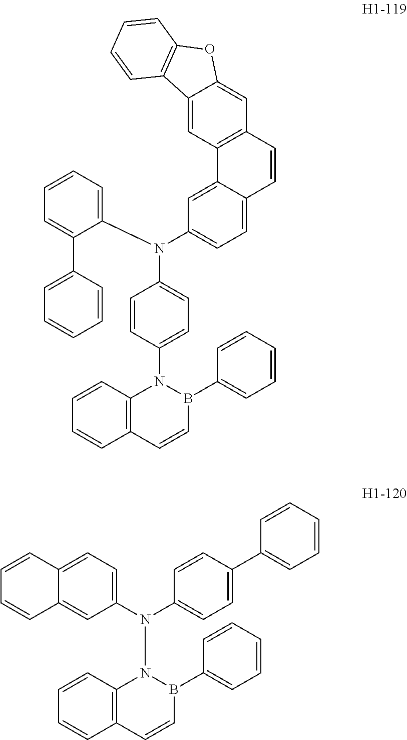 [SMILES: C1=Cc2ccccc2N(c2ccc(N(c3ccc4ccc5cc6oc7ccccc7c6cc5c4c3)c3ccccc3-c3ccccc3)cc2)B1c1ccccc1 ; C1=Cc2ccccc2N(N(c2ccc(-c3ccccc3)cc2)c2ccc3ccccc3c2)B1c1ccccc1] 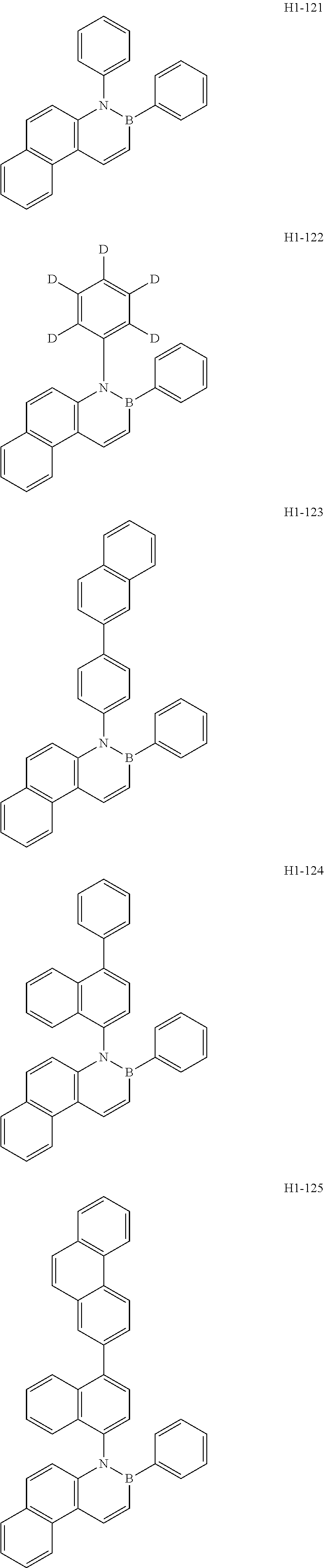 [SMILES: C1=Cc2c(ccc3ccccc23)N(c2ccccc2)B1c1ccccc1 ; [2H]c1c([2H])c([2H])c(N2B(c3ccccc3)C=Cc3c2ccc2ccccc32)c([2H])c1[2H] ; C1=Cc2c(ccc3ccccc23)N(c2ccc(-c3ccc4ccccc4c3)cc2)B1c1ccccc1 ; C1=Cc2c(ccc3ccccc23)N(c2ccc(-c3ccccc3)c3ccccc23)B1c1ccccc1 ; C1=Cc2c(ccc3ccccc23)N(c2ccc(-c3ccc4c(ccc5ccccc54)c3)c3ccccc23)B1c1ccccc1] 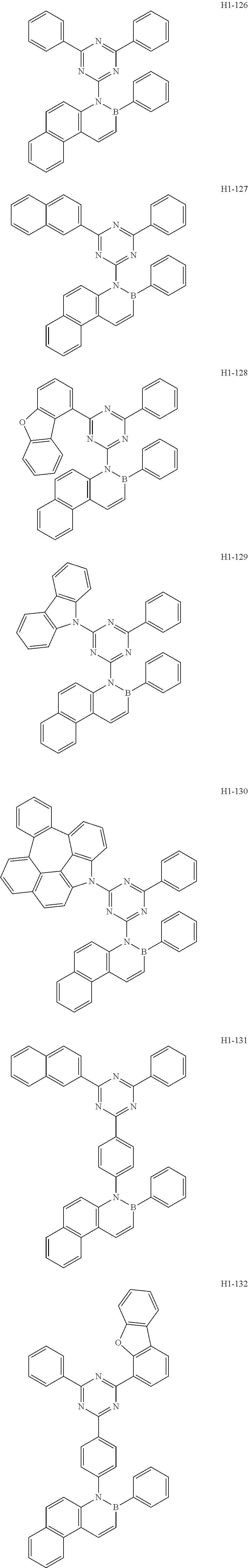 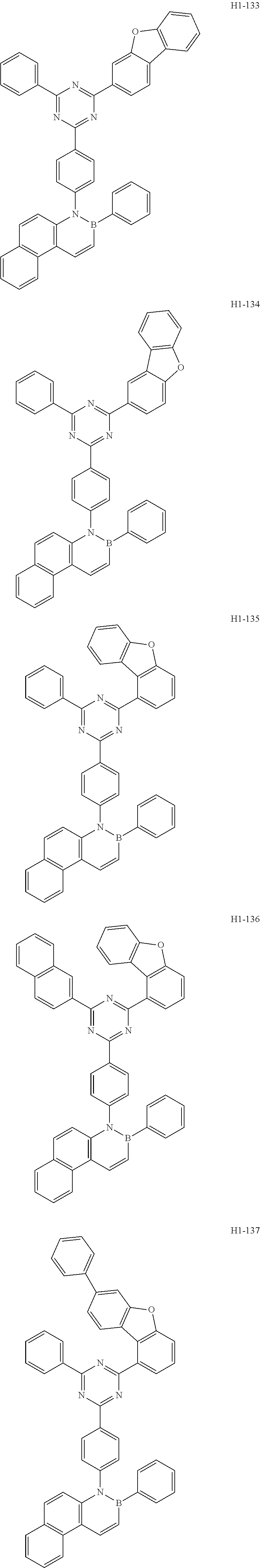 [SMILES: C1=Cc2c(ccc3ccccc23)N(c2ccc(-c3nc(-c4ccccc4)nc(-c4ccc5c(c4)oc4ccccc45)n3)cc2)B1c1ccccc1 ; C1=Cc2c(ccc3ccccc23)N(c2ccc(-c3nc(-c4ccccc4)nc(-c4ccc5oc6ccccc6c5c4)n3)cc2)B1c1ccccc1 ; C1=Cc2c(ccc3ccccc23)N(c2ccc(-c3nc(-c4ccccc4)nc(-c4cccc5oc6ccccc6c45)n3)cc2)B1c1ccccc1 ; C1=Cc2c(ccc3ccccc23)N(c2ccc(-c3nc(-c4ccc5ccccc5c4)nc(-c4cccc5oc6ccccc6c45)n3)cc2)B1c1ccccc1 ; C1=Cc2c(ccc3ccccc23)N(c2ccc(-c3nc(-c4ccccc4)nc(-c4cccc5oc6cc(-c7ccccc7)ccc6c45)n3)cc2)B1c1ccccc1] 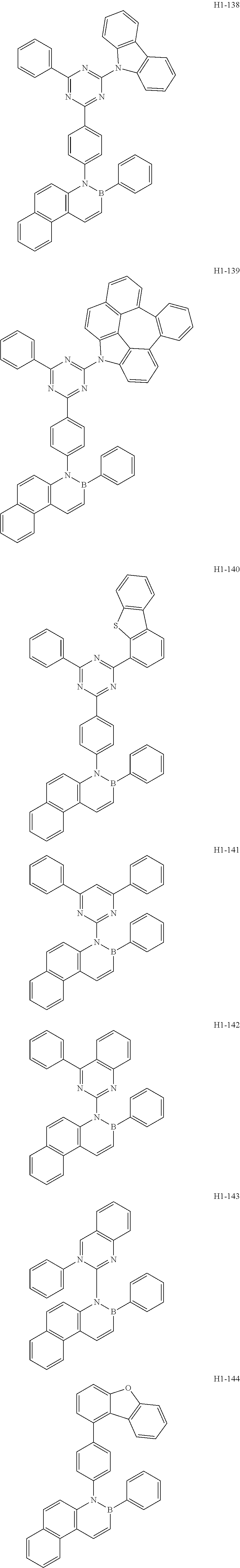 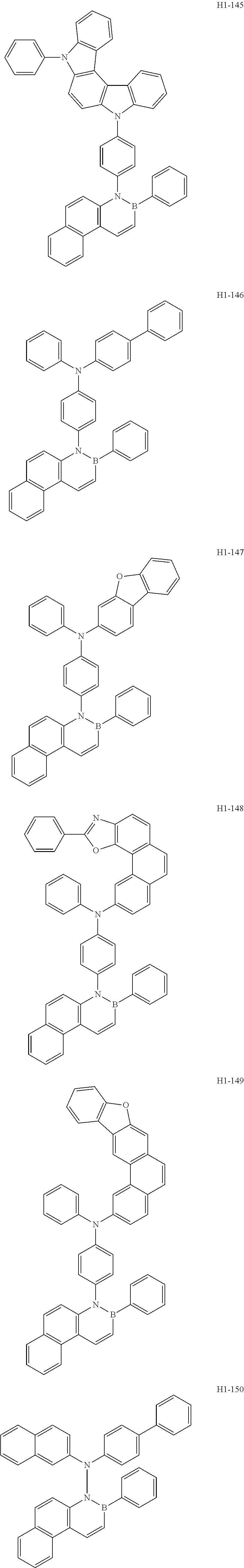 [SMILES: C1=Cc2c(ccc3ccccc23)N(c2ccc(-n3c4ccccc4c4c5c6ccccc6n(-c6ccccc6)c5ccc43)cc2)B1c1ccccc1 ; C1=Cc2c(ccc3ccccc23)N(c2ccc(N(c3ccccc3)c3ccc(-c4ccccc4)cc3)cc2)B1c1ccccc1 ; C1=Cc2c(ccc3ccccc23)N(c2ccc(N(c3ccccc3)c3ccc4c(c3)oc3ccccc34)cc2)B1c1ccccc1 ; C1=Cc2c(ccc3ccccc23)N(c2ccc(N(c3ccccc3)c3ccc4ccc5ccc6nc(-c7ccccc7)oc6c5c4c3)cc2)B1c1ccccc1 ; C1=Cc2c(ccc3ccccc23)N(c2ccc(N(c3ccccc3)c3ccc4ccc5cc6oc7ccccc7c6cc5c4c3)cc2)B1c1ccccc1 ; C1=Cc2c(ccc3ccccc23)N(N(c2ccc(-c3ccccc3)cc2)c2ccc3ccccc3c2)B1c1ccccc1] 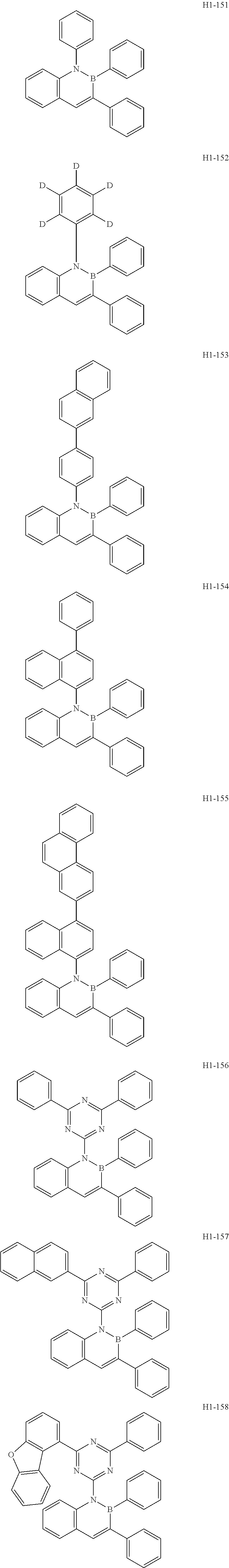 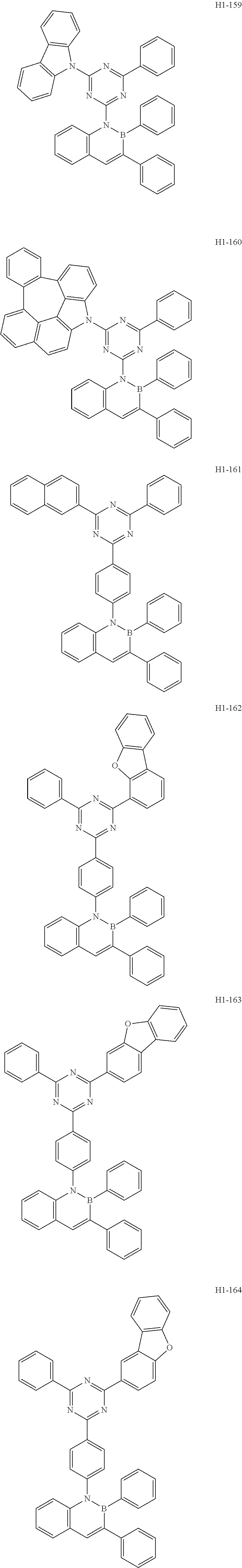 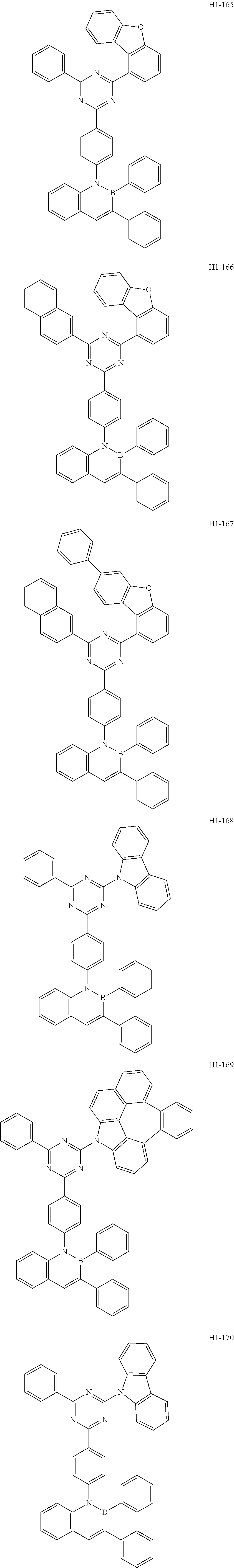 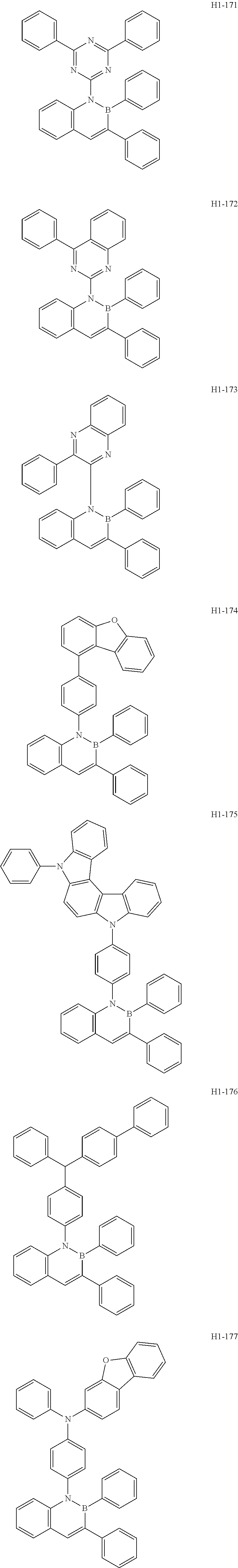 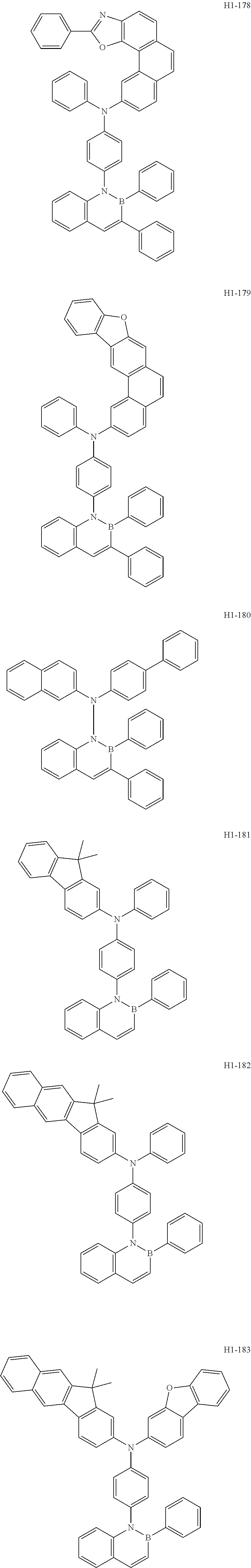 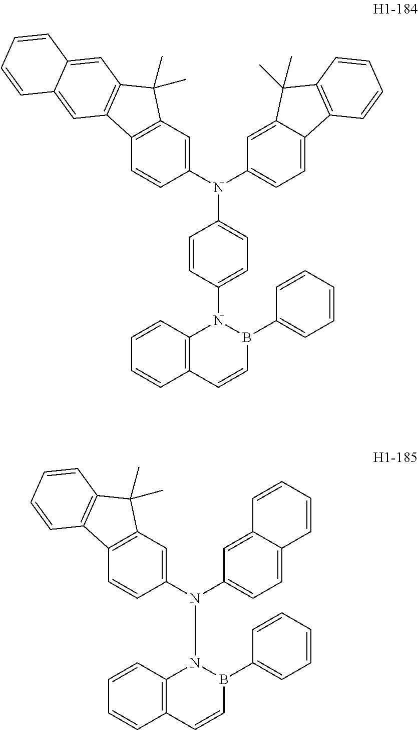 [SMILES: CC1(C)c2ccccc2-c2ccc(N(c3ccc(N4B(c5ccccc5)C=Cc5ccccc54)cc3)c3ccc4c(c3)C(C)(C)c3cc5ccccc5cc3-4)cc21 ; CC1(C)c2ccccc2-c2ccc(N(c3ccc4ccccc4c3)N3B(c4ccccc4)C=Cc4ccccc43)cc21] 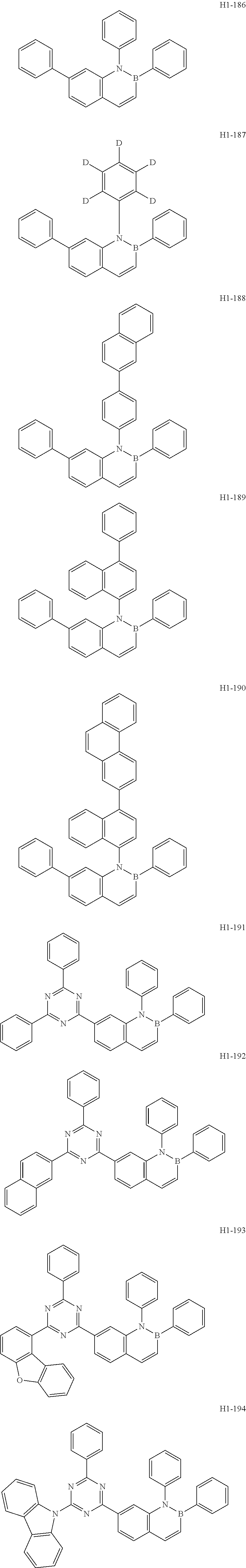 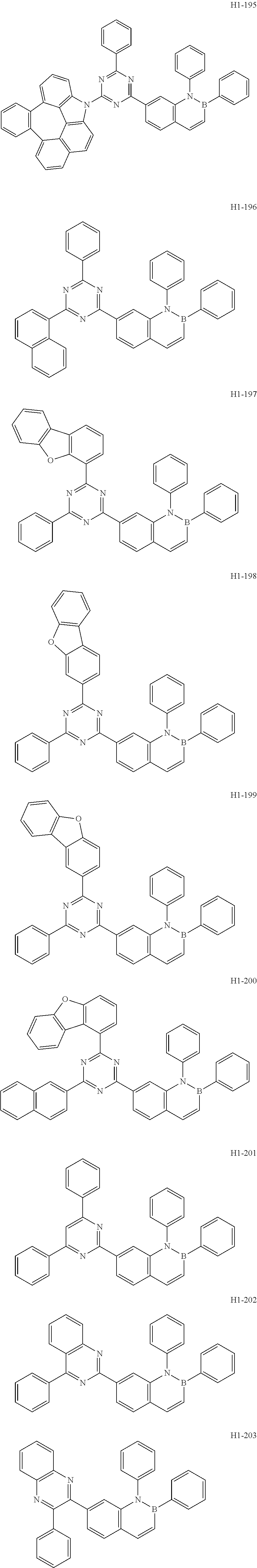 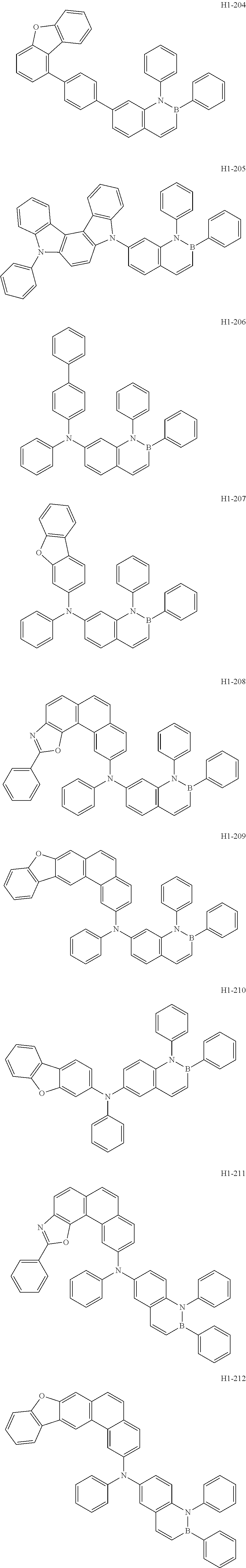 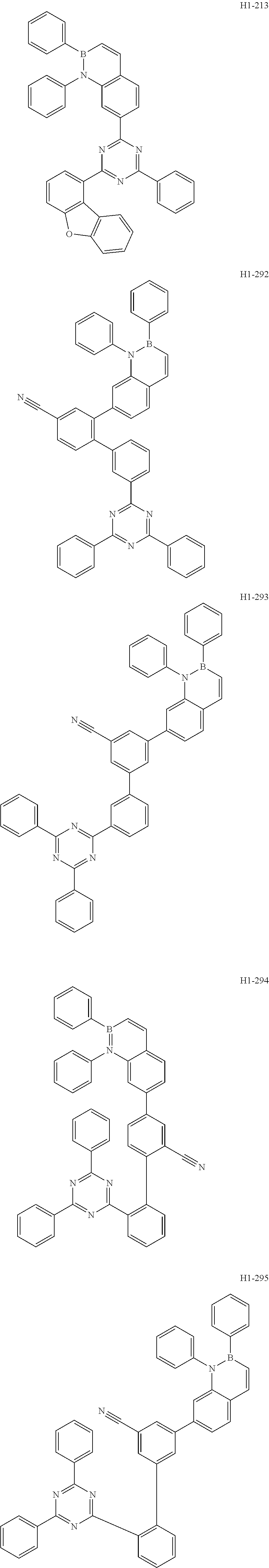 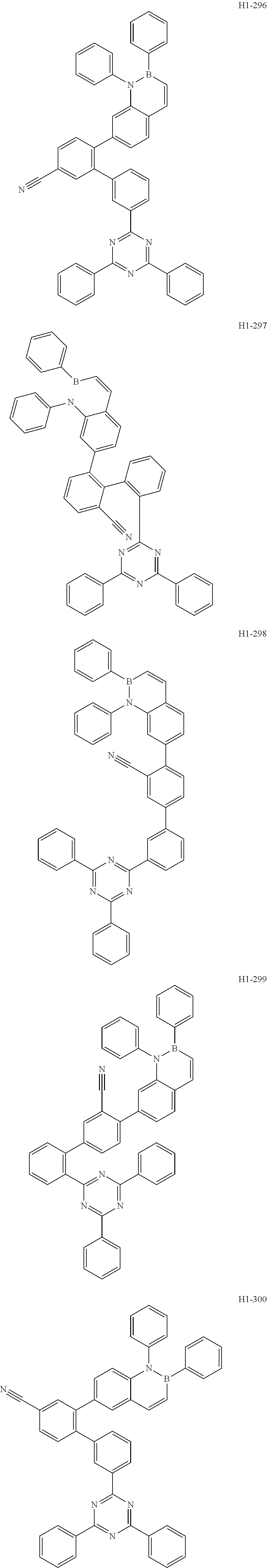 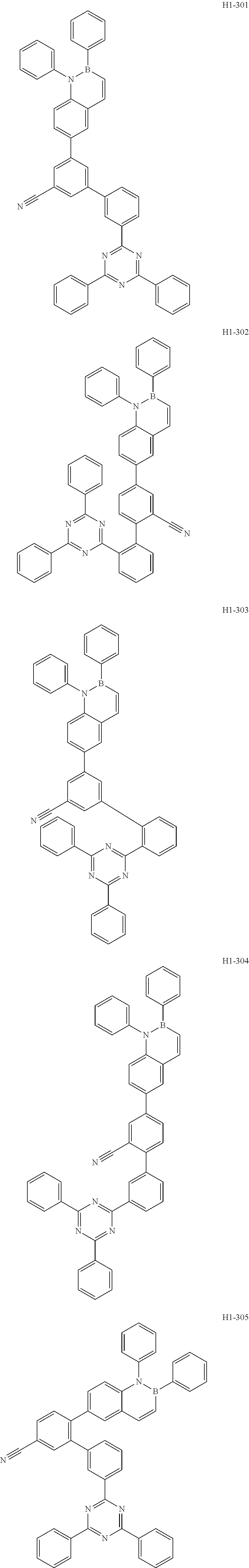 [SMILES: N#Cc1cc(-c2cccc(-c3nc(-c4ccccc4)nc(-c4ccccc4)n3)c2)cc(-c2ccc3c(c2)C=CB(c2ccccc2)N3c2ccccc2)c1 ; N#Cc1cc(-c2ccc3c(c2)C=CB(c2ccccc2)N3c2ccccc2)ccc1-c1ccccc1-c1nc(-c2ccccc2)nc(-c2ccccc2)n1 ; N#Cc1cc(-c2ccc3c(c2)C=CB(c2ccccc2)N3c2ccccc2)cc(-c2ccccc2-c2nc(-c3ccccc3)nc(-c3ccccc3)n2)c1 ; N#Cc1cc(-c2ccc3c(c2)C=CB(c2ccccc2)N3c2ccccc2)ccc1-c1cccc(-c2nc(-c3ccccc3)nc(-c3ccccc3)n2)c1 ; N#Cc1ccc(-c2ccc3c(c2)C=CB(c2ccccc2)N3c2ccccc2)c(-c2cccc(-c3nc(-c4ccccc4)nc(-c4ccccc4)n3)c2)c1] 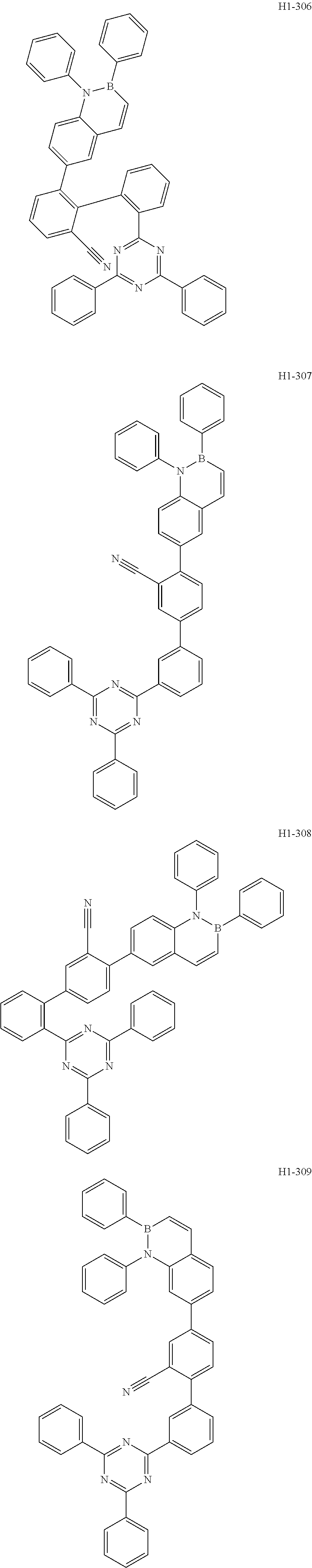
in the compounds above, Dₙ means that n number of hydrogens are replaced with deuterium, and n represents an integer from 1 to the maximum number of hydrogens in the compound.

10. The plurality of host materials according to claim 5, wherein the compound represented by Formula 2-1 is selected from the following compounds: 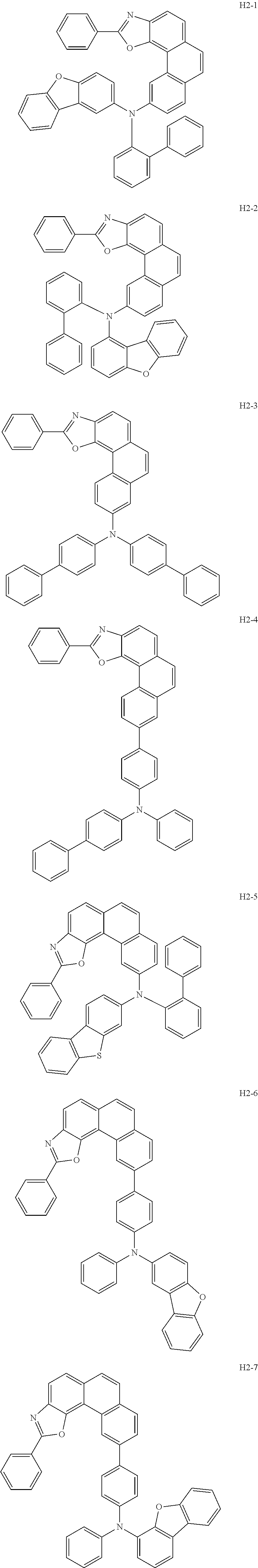 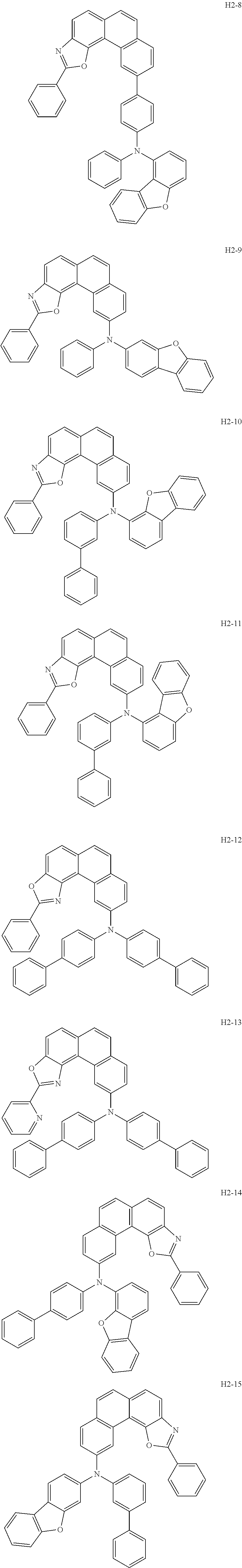 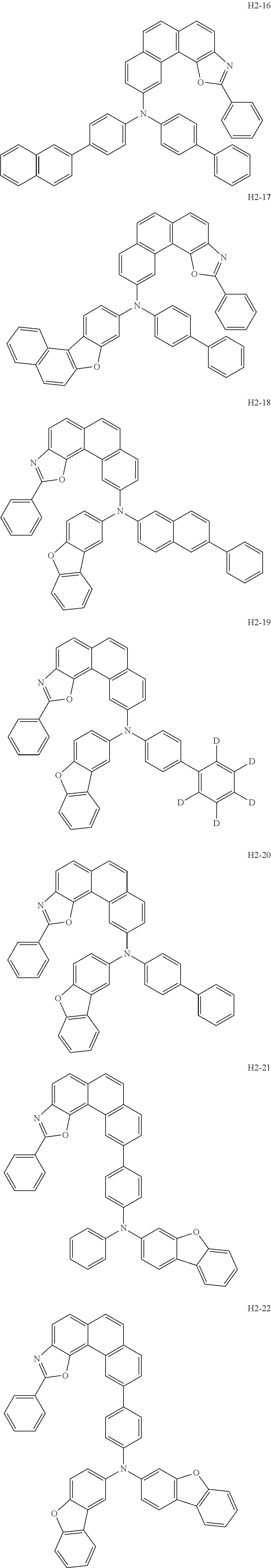 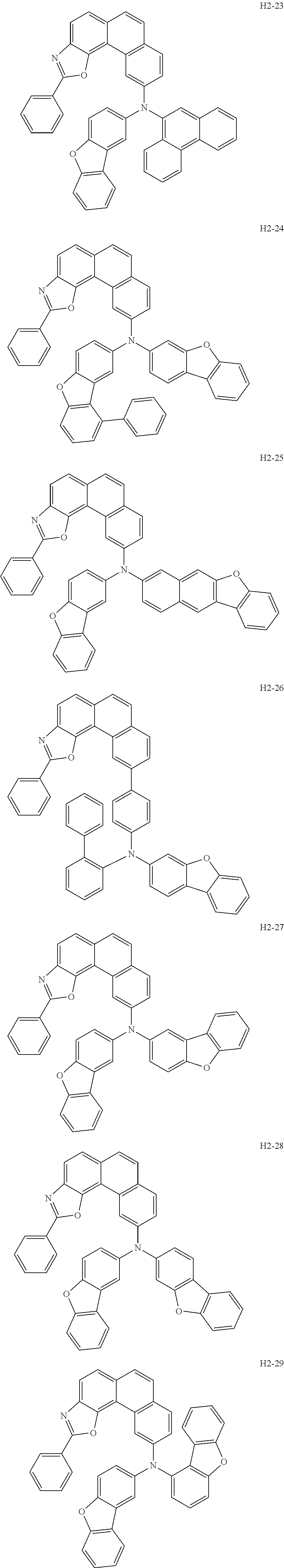 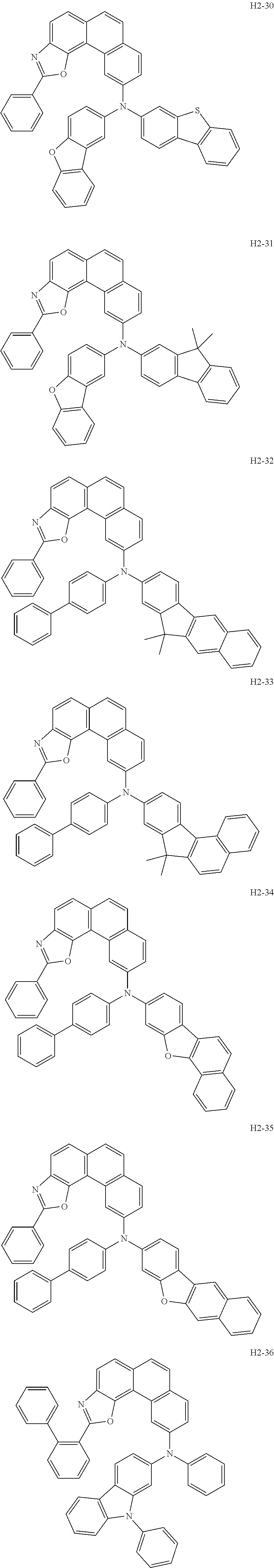 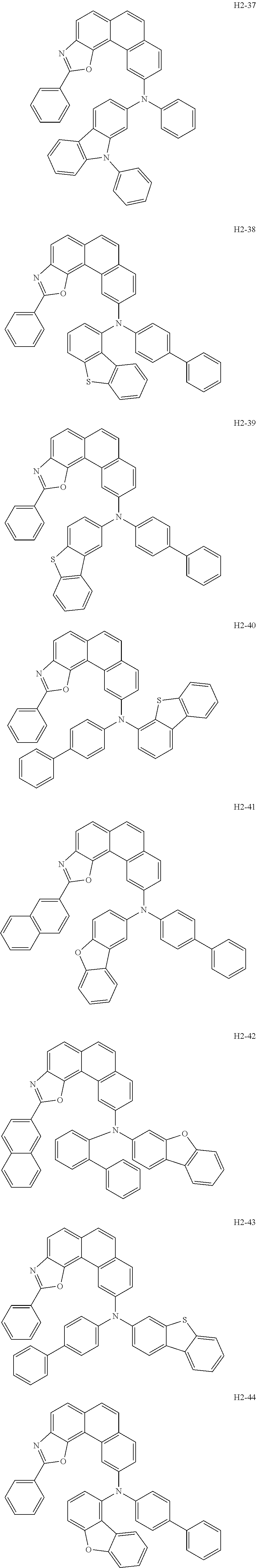 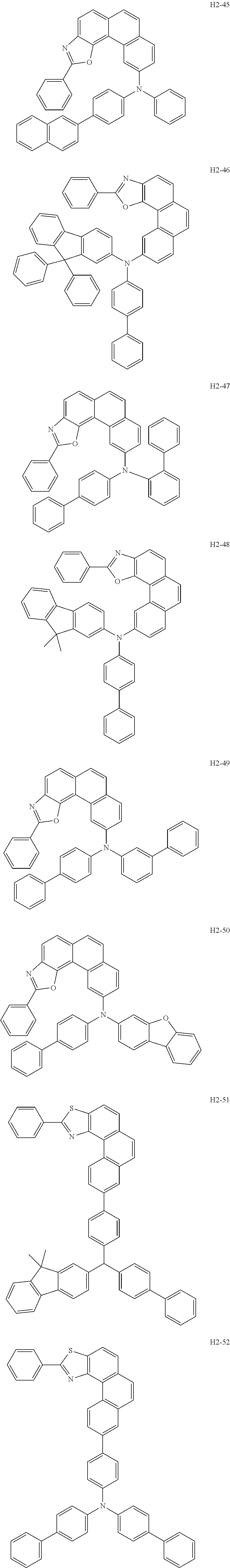 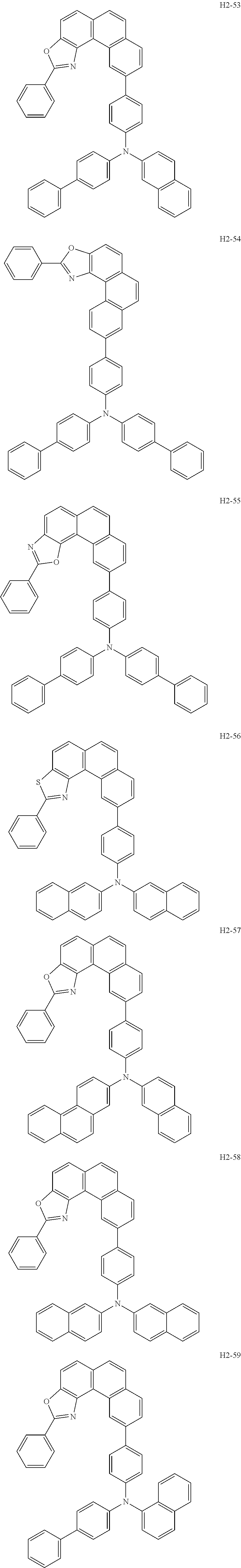 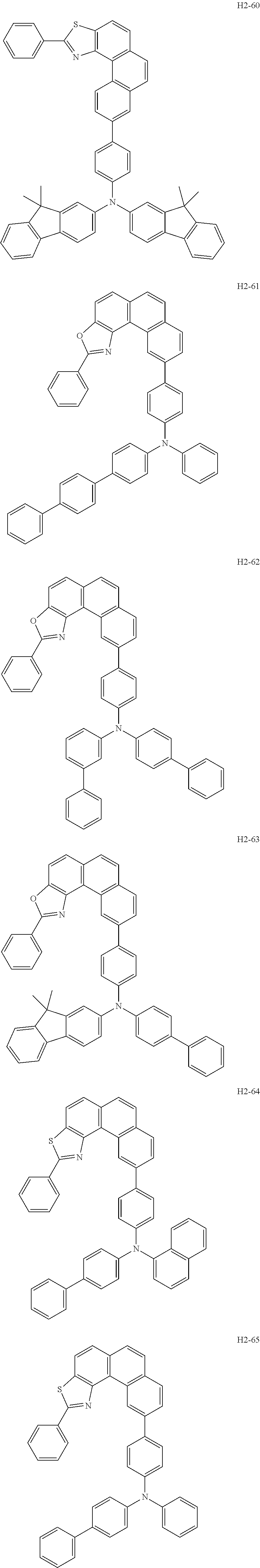 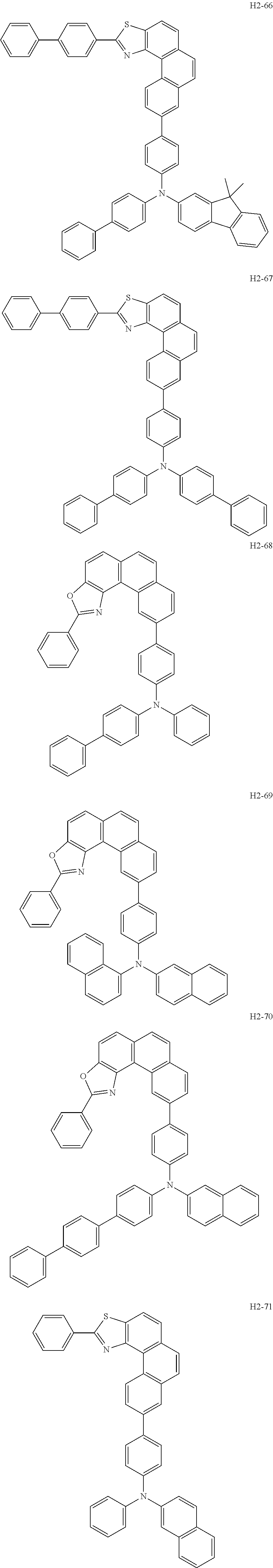 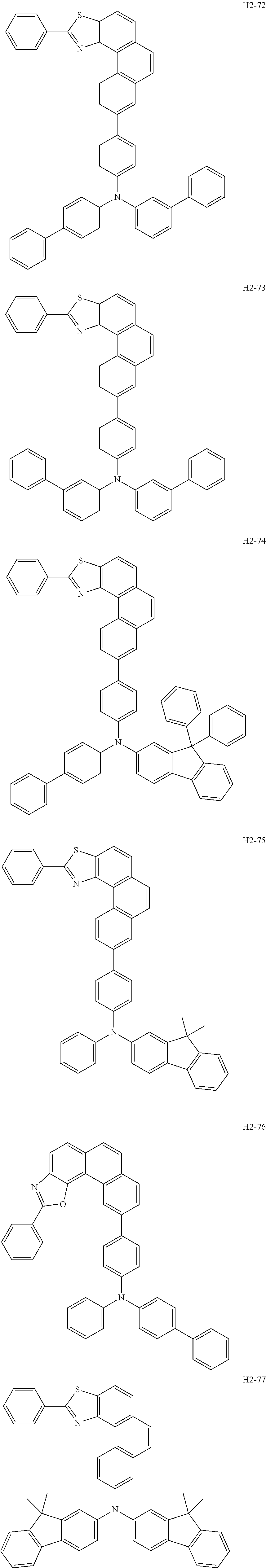 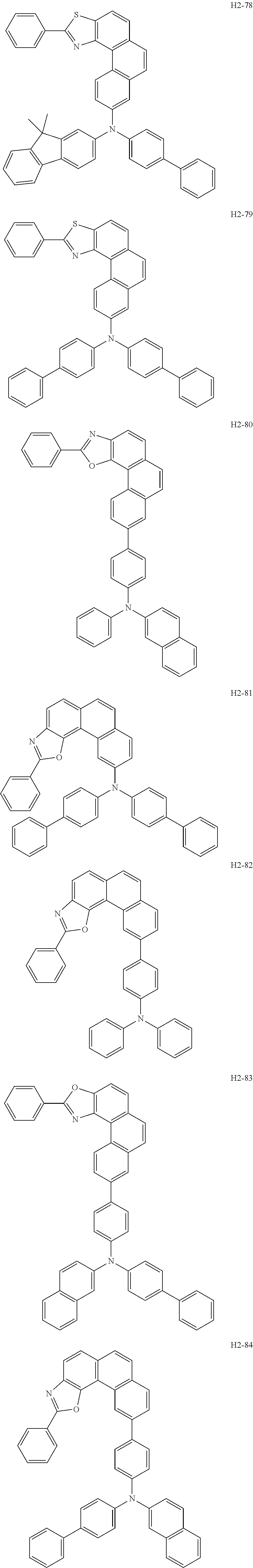 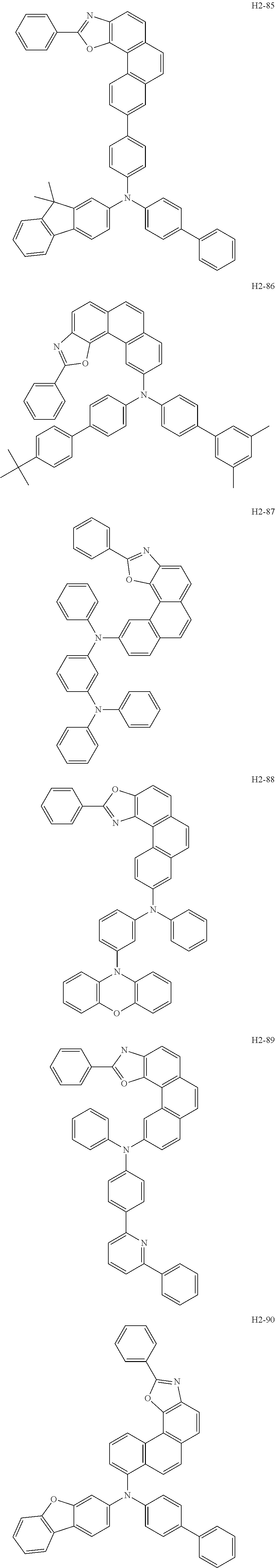 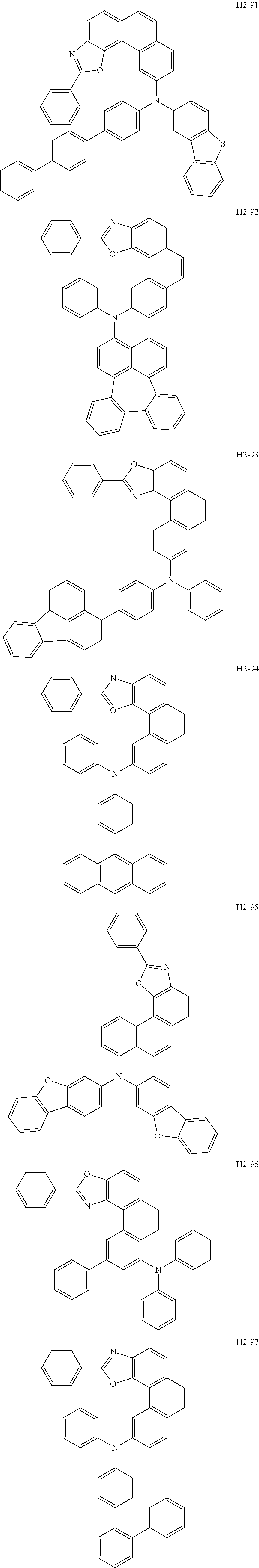 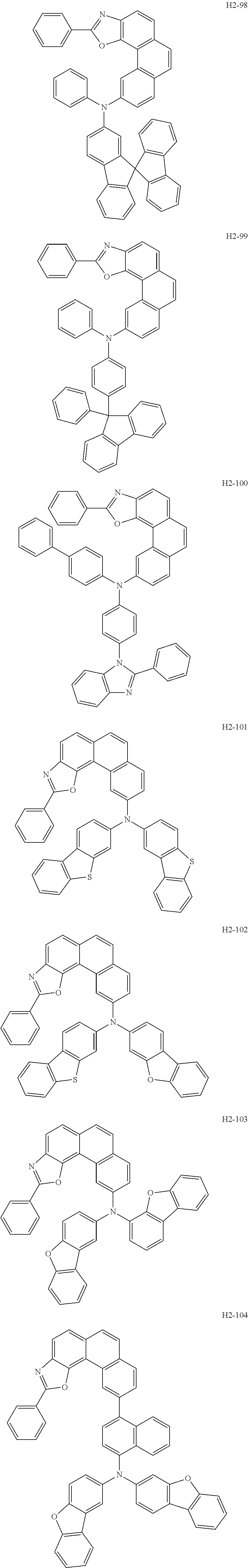 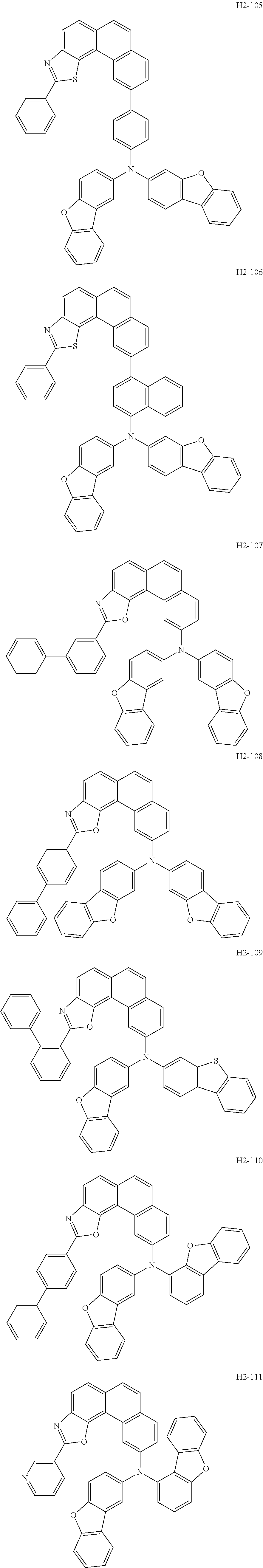 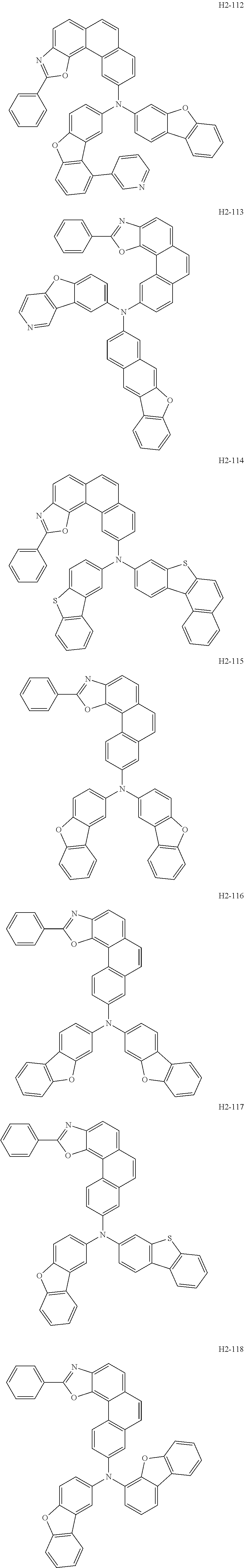 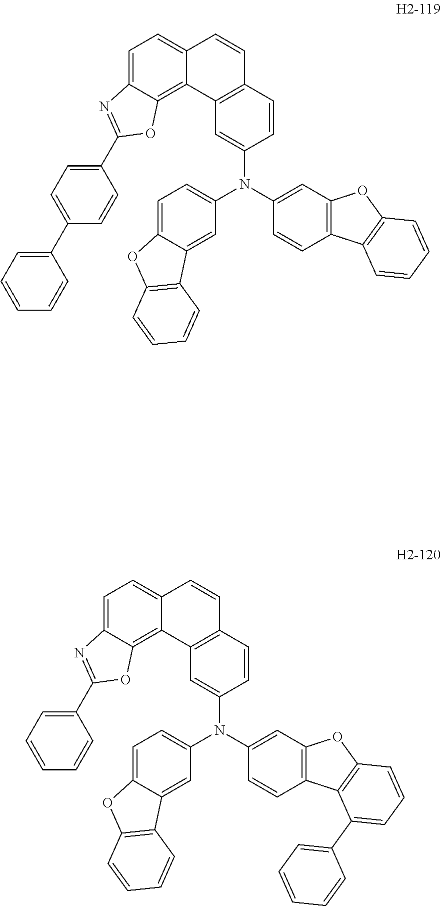 [SMILES: c1ccc(-c2ccc(-c3nc4ccc5ccc6ccc(N(c7ccc8c(c7)oc7ccccc78)c7ccc8oc9ccccc9c8c7)cc6c5c4o3)cc2)cc1 ; c1ccc(-c2nc3ccc4ccc5ccc(N(c6ccc7c(c6)oc6cccc(-c8ccccc8)c67)c6ccc7oc8ccccc8c7c6)cc5c4c3o2)cc1] 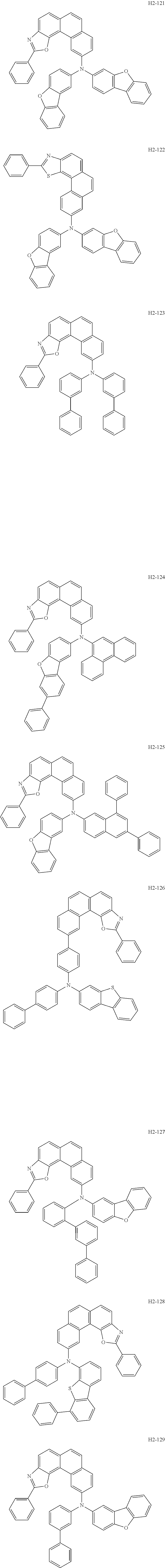 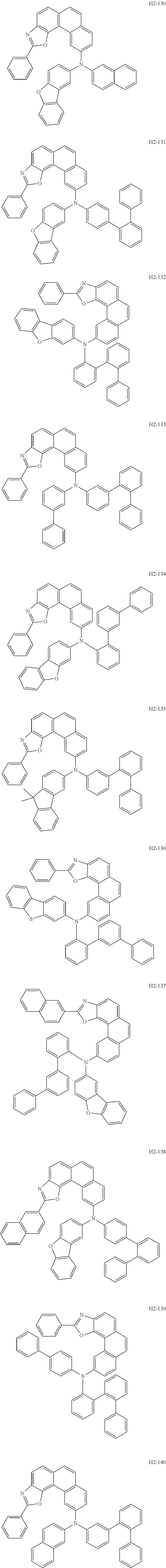 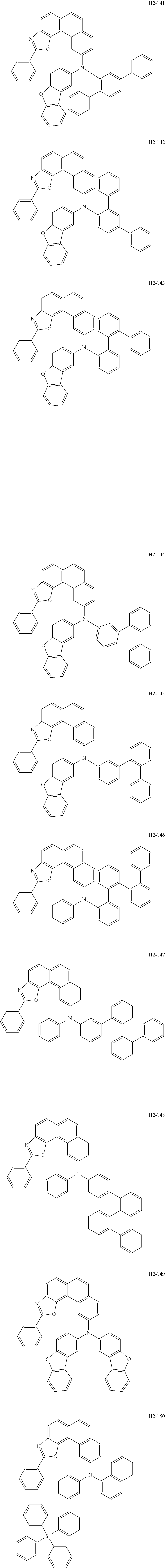 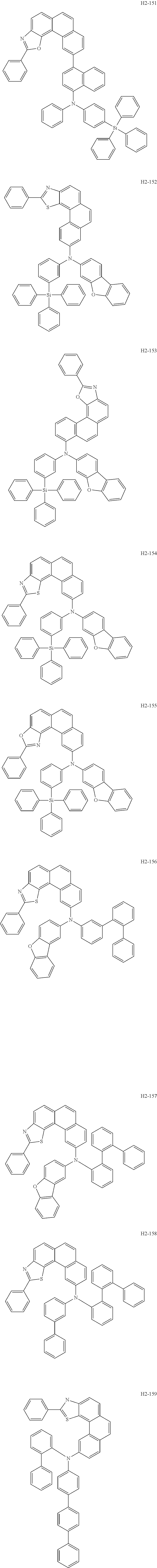 [chemical structure] 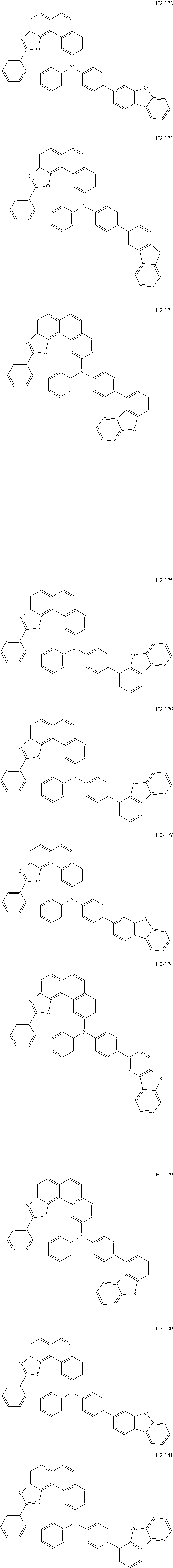 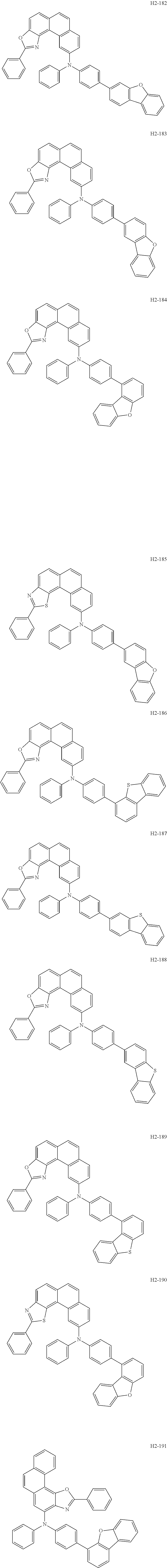 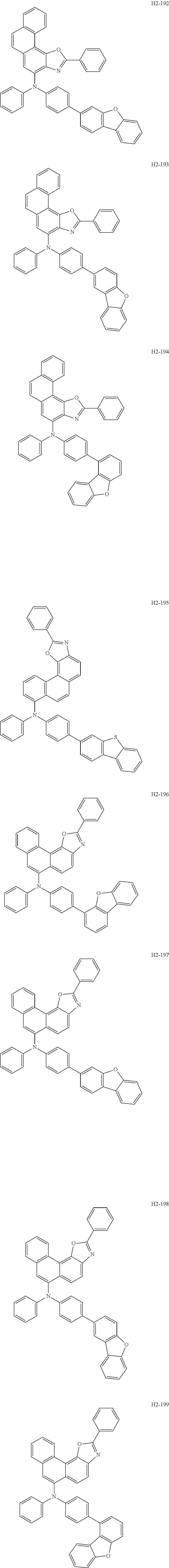 [chemical structure] [chemical structure] [chemical structure] 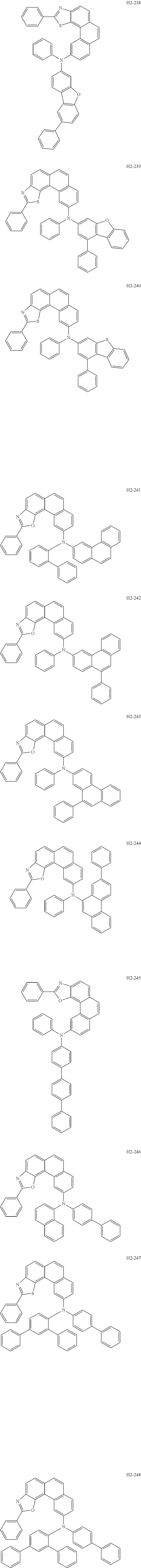 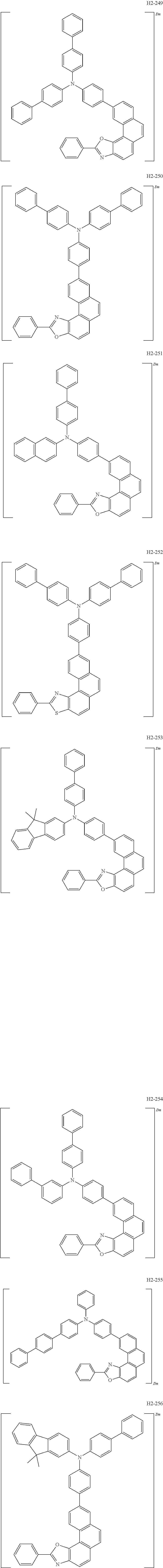 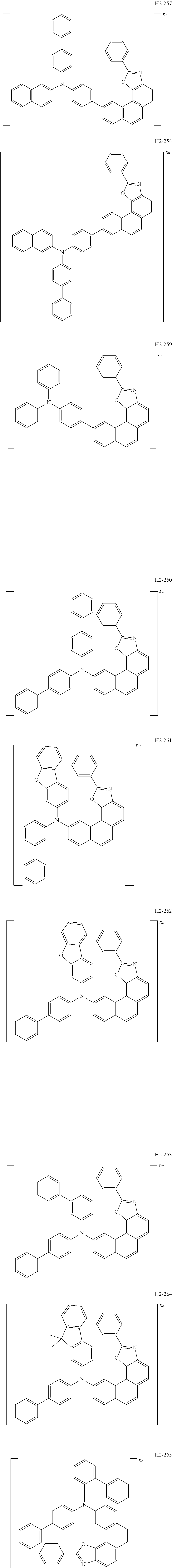 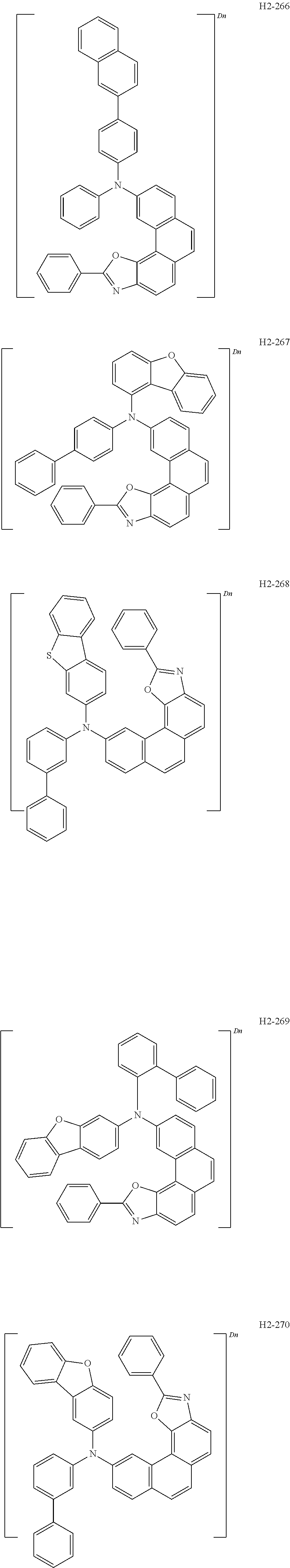 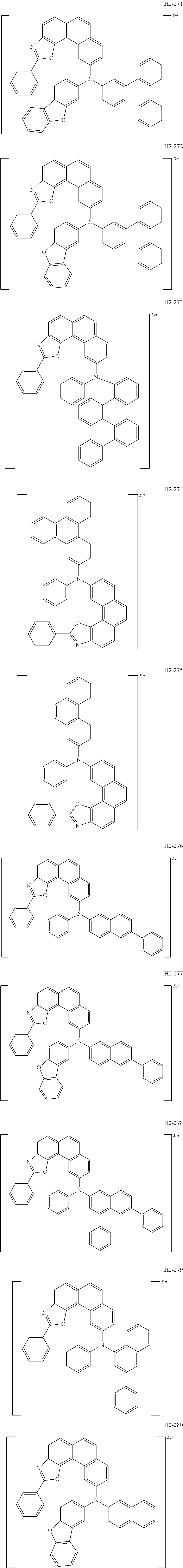 [chemical structure] 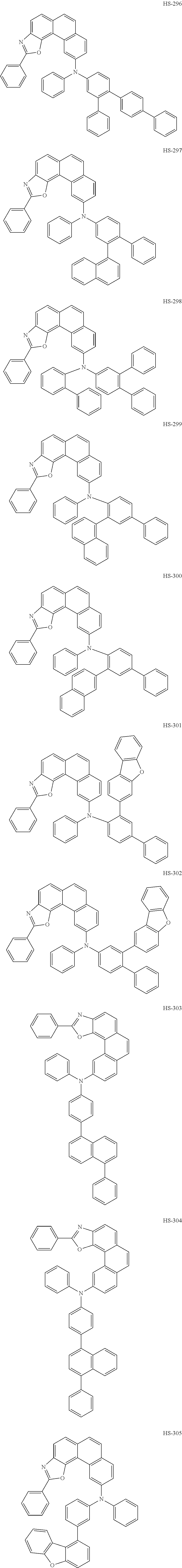 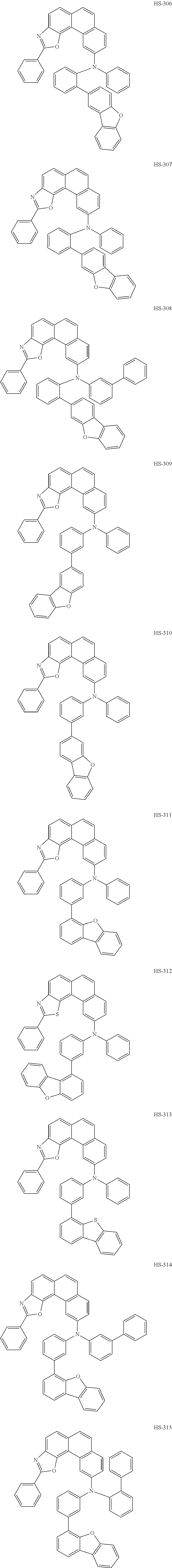 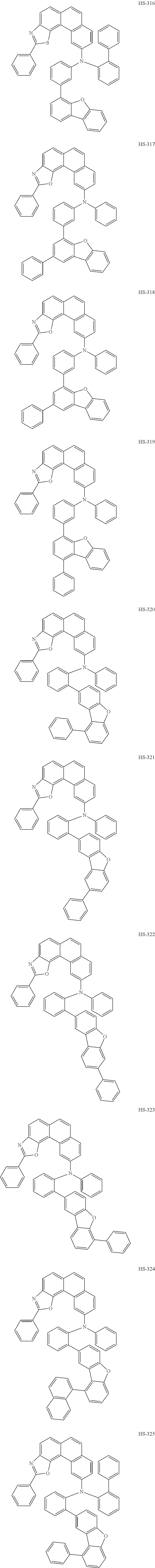 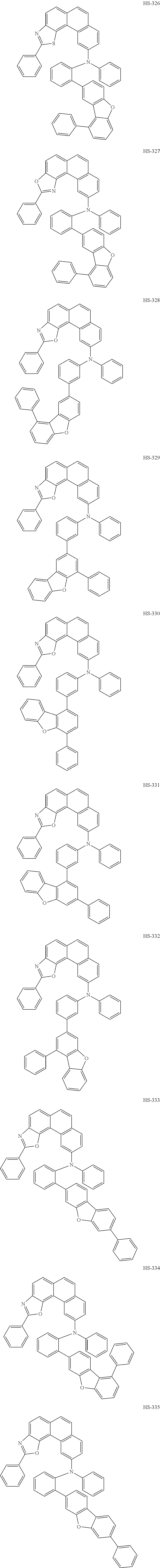 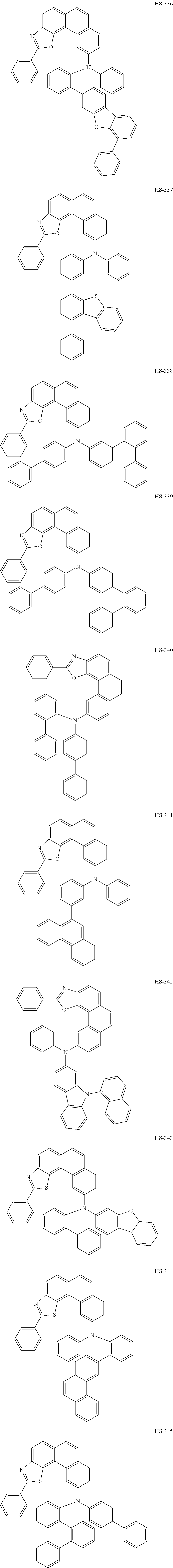 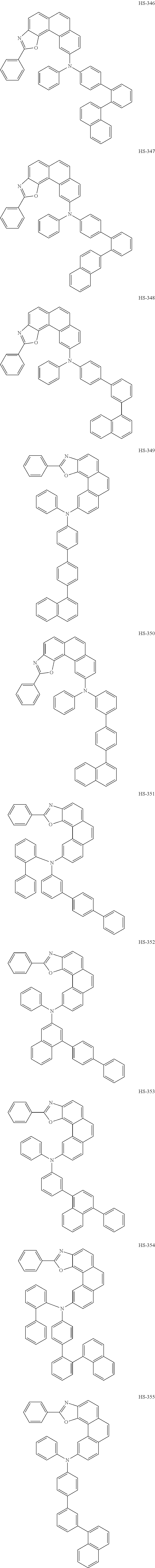 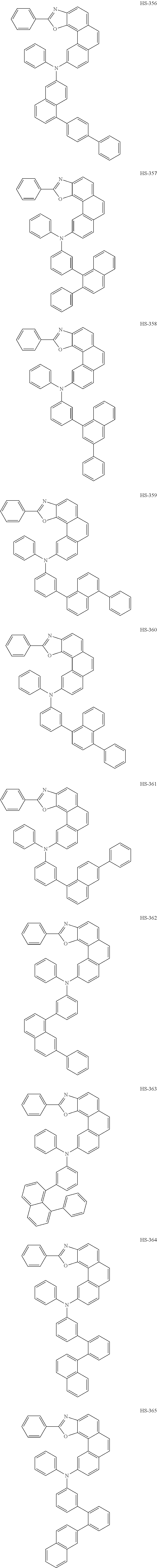 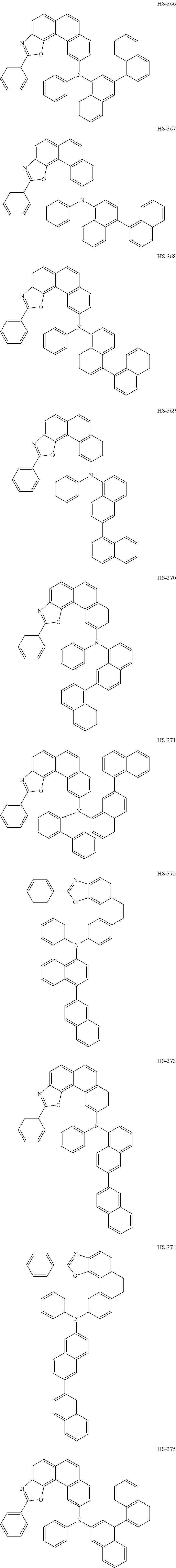 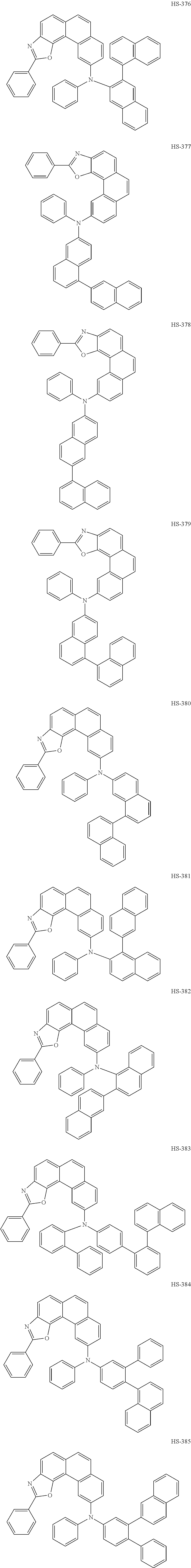 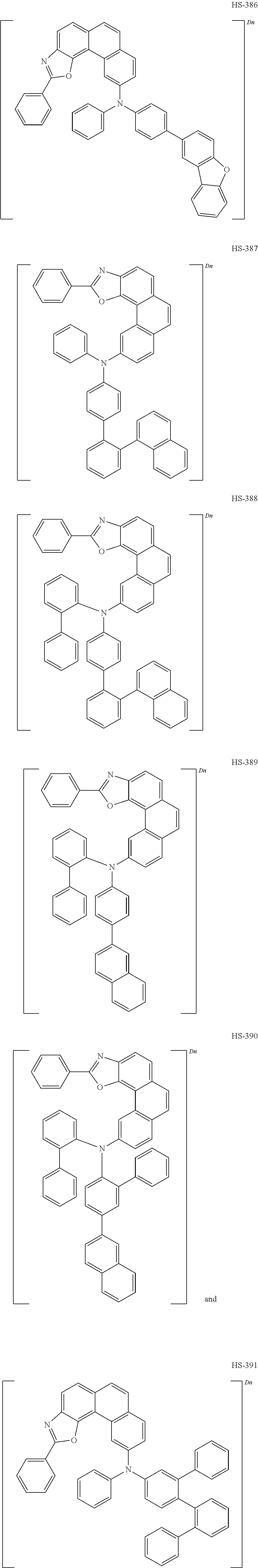
in the compounds above, Dₙ means that n number of hydrogens are replaced with deuterium, and n represents an integer from 1 to the maximum number of hydrogens in the compound.

11. The plurality of host materials according to claim 5, wherein the compound represented by Formula 2-2 is selected from the following compounds: 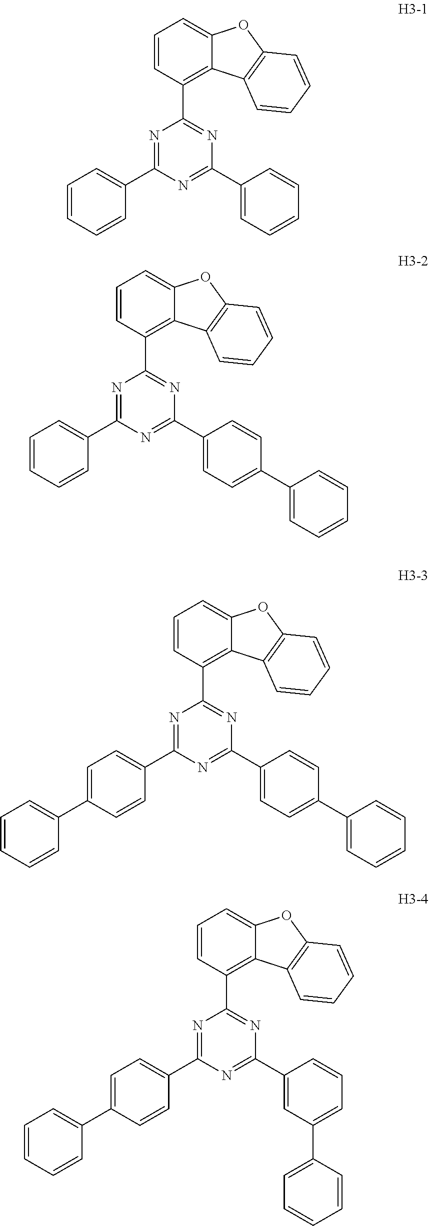 [SMILES: c1ccc(-c2nc(-c3ccccc3)nc(-c3cccc4oc5ccccc5c34)n2)cc1 ; c1ccc(-c2ccc(-c3nc(-c4ccccc4)nc(-c4cccc5oc6ccccc6c45)n3)cc2)cc1 ; c1ccc(-c2ccc(-c3nc(-c4ccc(-c5ccccc5)cc4)nc(-c4cccc5oc6ccccc6c45)n3)cc2)cc1 ; c1ccc(-c2ccc(-c3nc(-c4cccc(-c5ccccc5)c4)nc(-c4cccc5oc6ccccc6c45)n3)cc2)cc1] 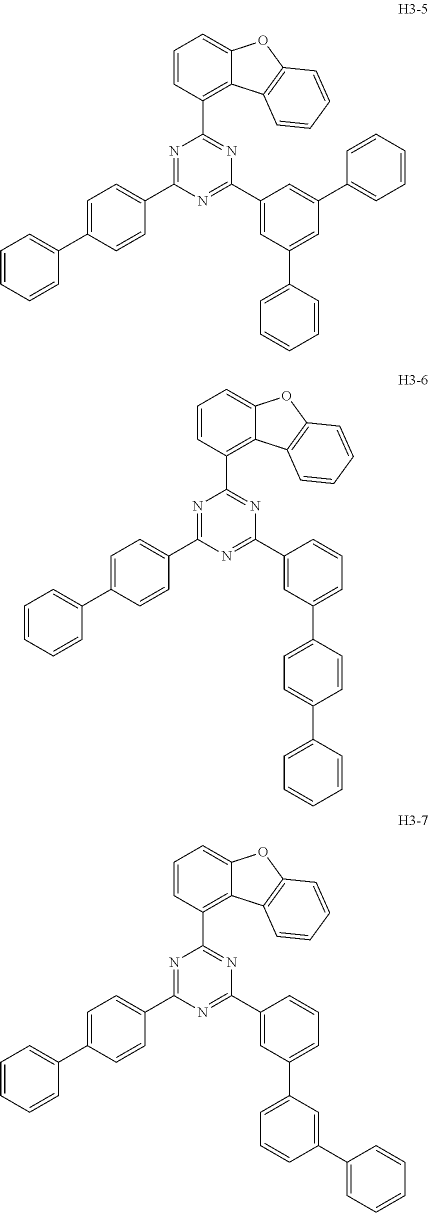 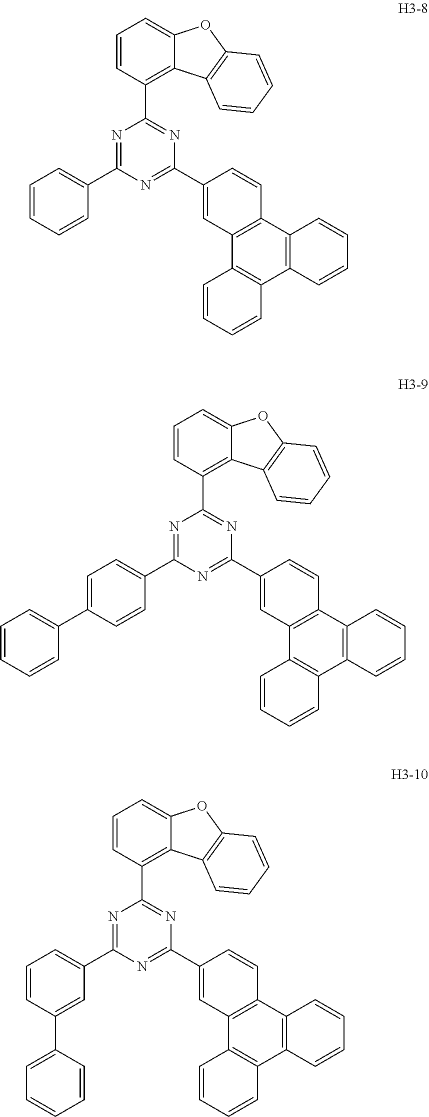 [SMILES: c1ccc(-c2nc(-c3ccc4c5ccccc5c5ccccc5c4c3)nc(-c3cccc4oc5ccccc5c34)n2)cc1 ; c1ccc(-c2ccc(-c3nc(-c4ccc5c6ccccc6c6ccccc6c5c4)nc(-c4cccc5oc6ccccc6c45)n3)cc2)cc1 ; c1ccc(-c2cccc(-c3nc(-c4ccc5c6ccccc6c6ccccc6c5c4)nc(-c4cccc5oc6ccccc6c45)n3)c2)cc1] 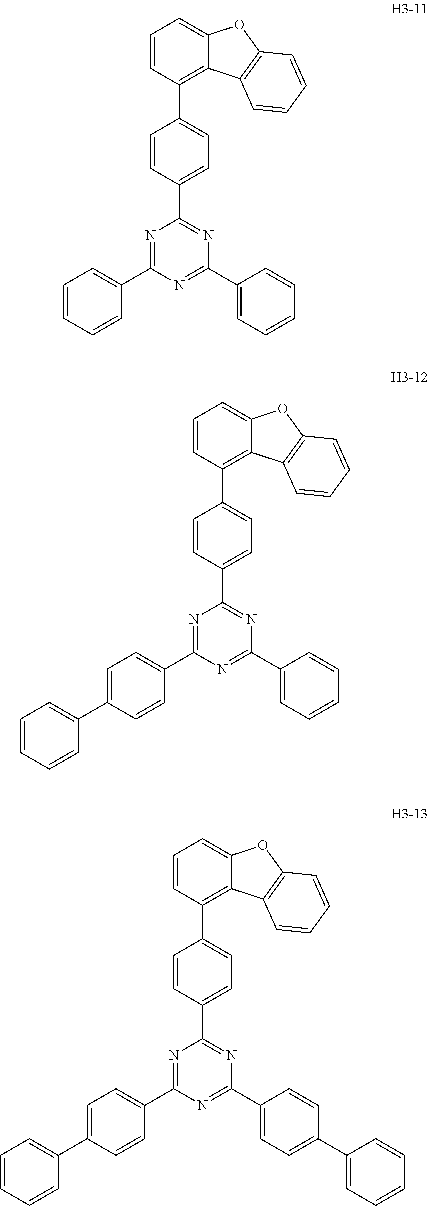 [SMILES: c1ccc(-c2nc(-c3ccccc3)nc(-c3ccc(-c4cccc5oc6ccccc6c45)cc3)n2)cc1 ; c1ccc(-c2ccc(-c3nc(-c4ccccc4)nc(-c4ccc(-c5cccc6oc7ccccc7c56)cc4)n3)cc2)cc1 ; c1ccc(-c2ccc(-c3nc(-c4ccc(-c5ccccc5)cc4)nc(-c4ccc(-c5cccc6oc7ccccc7c56)cc4)n3)cc2)cc1] 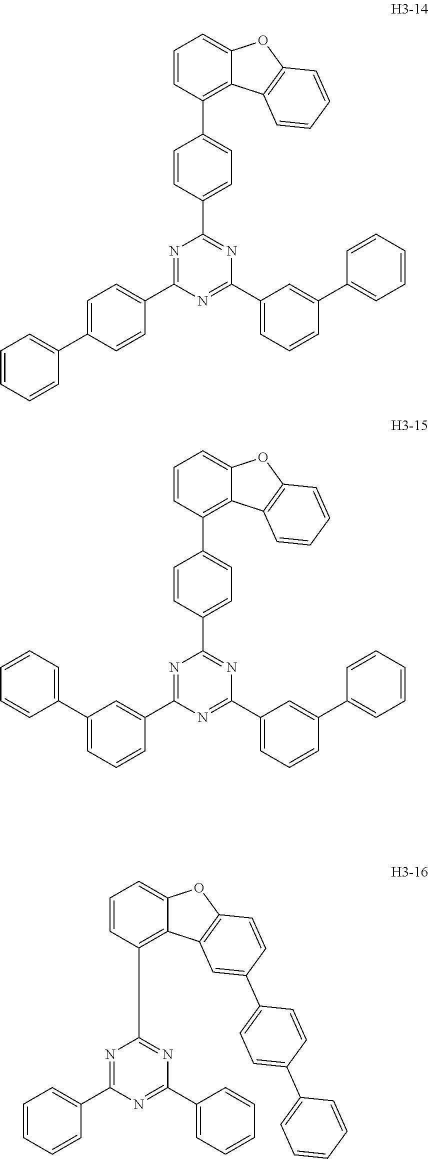 [SMILES: c1ccc(-c2ccc(-c3nc(-c4ccc(-c5cccc6oc7ccccc7c56)cc4)nc(-c4cccc(-c5ccccc5)c4)n3)cc2)cc1 ; c1ccc(-c2cccc(-c3nc(-c4ccc(-c5cccc6oc7ccccc7c56)cc4)nc(-c4cccc(-c5ccccc5)c4)n3)c2)cc1 ; c1ccc(-c2ccc(-c3ccc4oc5cccc(-c6nc(-c7ccccc7)nc(-c7ccccc7)n6)c5c4c3)cc2)cc1] 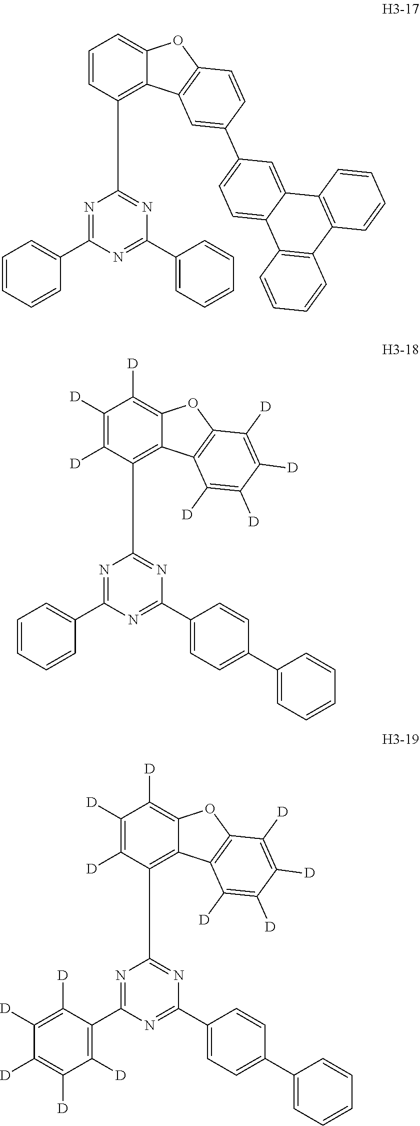 [SMILES: c1ccc(-c2nc(-c3ccccc3)nc(-c3cccc4oc5ccc(-c6ccc7c8ccccc8c8ccccc8c7c6)cc5c34)n2)cc1 ; [2H]c1c([2H])c([2H])c2c(oc3c([2H])c([2H])c([2H])c(-c4nc(-c5ccccc5)nc(-c5ccc(-c6ccccc6)cc5)n4)c32)c1[2H] ; [2H]c1c([2H])c([2H])c(-c2nc(-c3ccc(-c4ccccc4)cc3)nc(-c3c([2H])c([2H])c([2H])c4oc5c([2H])c([2H])c([2H])c([2H])c5c34)n2)c([2H])c1[2H]] 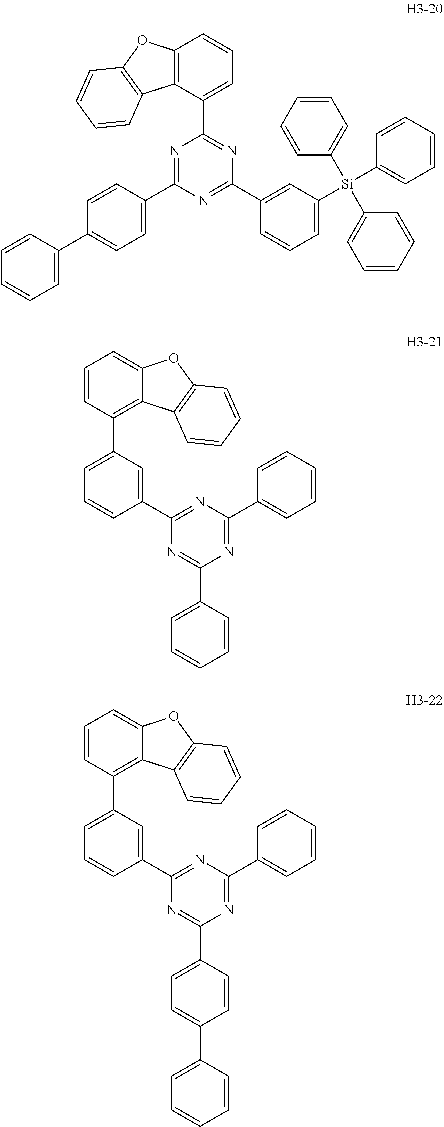 [SMILES: c1ccc(-c2ccc(-c3nc(-c4cccc([Si](c5ccccc5)(c5ccccc5)c5ccccc5)c4)nc(-c4cccc5oc6ccccc6c45)n3)cc2)cc1 ; c1ccc(-c2nc(-c3ccccc3)nc(-c3cccc(-c4cccc5oc6ccccc6c45)c3)n2)cc1 ; c1ccc(-c2ccc(-c3nc(-c4ccccc4)nc(-c4cccc(-c5cccc6oc7ccccc7c56)c4)n3)cc2)cc1] 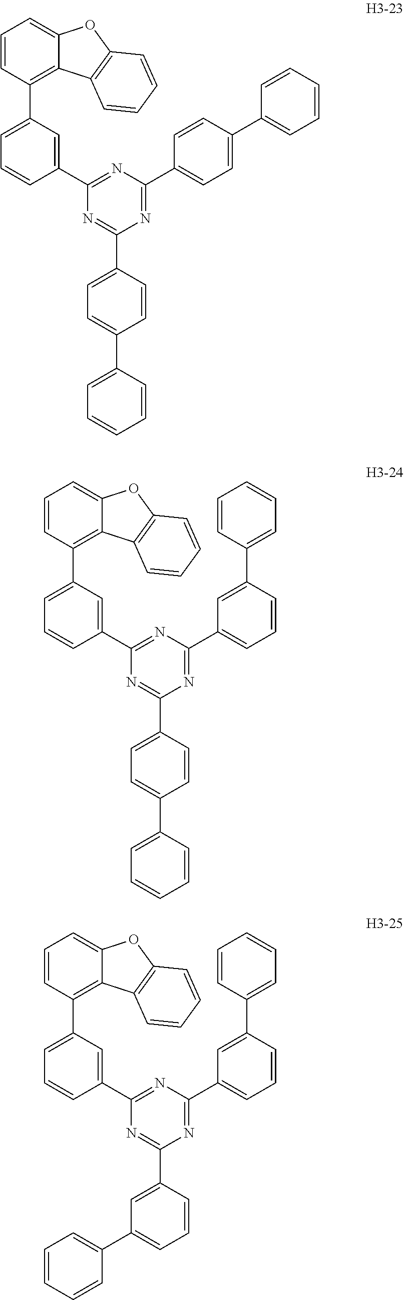 [SMILES: c1ccc(-c2ccc(-c3nc(-c4ccc(-c5ccccc5)cc4)nc(-c4cccc(-c5cccc6oc7ccccc7c56)c4)n3)cc2)cc1 ; c1ccc(-c2ccc(-c3nc(-c4cccc(-c5ccccc5)c4)nc(-c4cccc(-c5cccc6oc7ccccc7c56)c4)n3)cc2)cc1 ; c1ccc(-c2cccc(-c3nc(-c4cccc(-c5ccccc5)c4)nc(-c4cccc(-c5cccc6oc7ccccc7c56)c4)n3)c2)cc1] 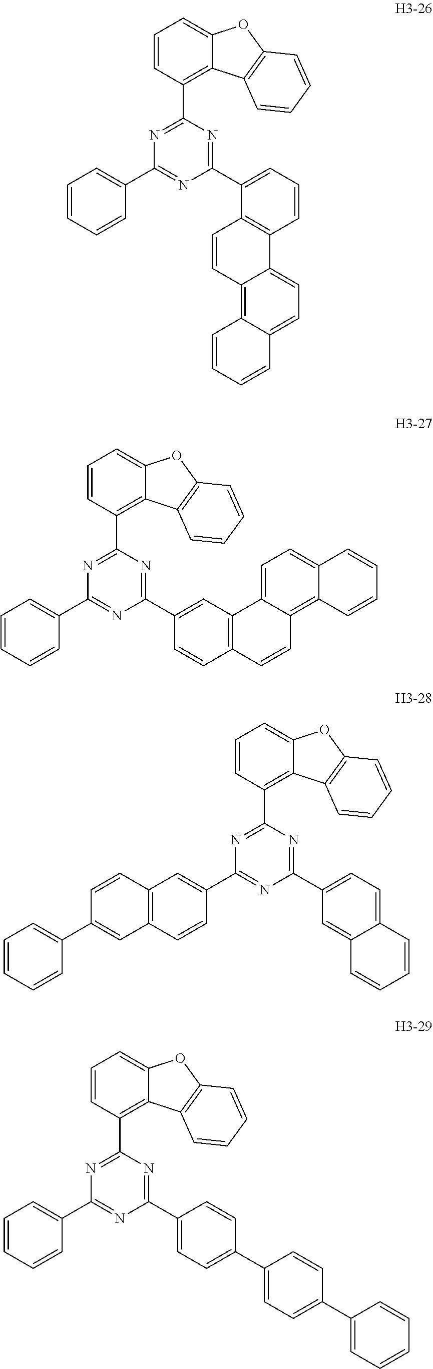 [SMILES: c1ccc(-c2nc(-c3cccc4c3ccc3c5ccccc5ccc43)nc(-c3cccc4oc5ccccc5c34)n2)cc1 ; c1ccc(-c2nc(-c3ccc4ccc5c6ccccc6ccc5c4c3)nc(-c3cccc4oc5ccccc5c34)n2)cc1 ; c1ccc(-c2ccc3cc(-c4nc(-c5ccc6ccccc6c5)nc(-c5cccc6oc7ccccc7c56)n4)ccc3c2)cc1 ; c1ccc(-c2ccc(-c3ccc(-c4nc(-c5ccccc5)nc(-c5cccc6oc7ccccc7c56)n4)cc3)cc2)cc1] 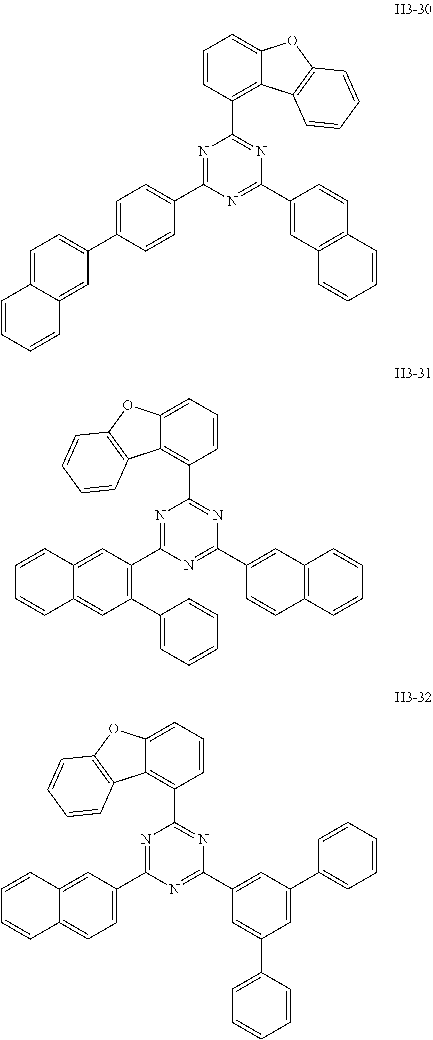 [SMILES: c1ccc2cc(-c3ccc(-c4nc(-c5ccc6ccccc6c5)nc(-c5cccc6oc7ccccc7c56)n4)cc3)ccc2c1 ; c1ccc(-c2cc3ccccc3cc2-c2nc(-c3ccc4ccccc4c3)nc(-c3cccc4oc5ccccc5c34)n2)cc1 ; c1ccc(-c2cc(-c3ccccc3)cc(-c3nc(-c4ccc5ccccc5c4)nc(-c4cccc5oc6ccccc6c45)n3)c2)cc1] 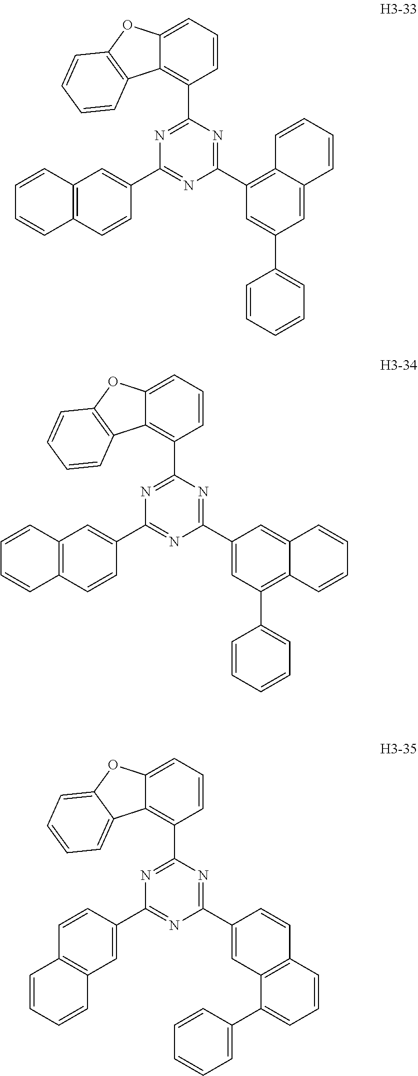 [SMILES: c1ccc(-c2cc(-c3nc(-c4ccc5ccccc5c4)nc(-c4cccc5oc6ccccc6c45)n3)c3ccccc3c2)cc1 ; c1ccc(-c2cc(-c3nc(-c4ccc5ccccc5c4)nc(-c4cccc5oc6ccccc6c45)n3)cc3ccccc23)cc1 ; c1ccc(-c2cccc3ccc(-c4nc(-c5ccc6ccccc6c5)nc(-c5cccc6oc7ccccc7c56)n4)cc23)cc1] 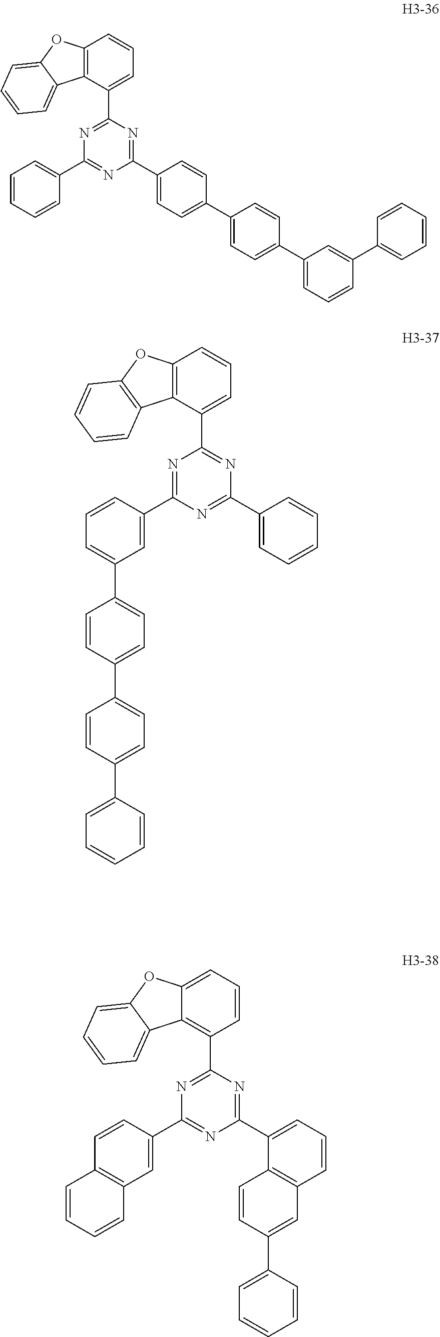 [SMILES: c1ccc(-c2cccc(-c3ccc(-c4ccc(-c5nc(-c6ccccc6)nc(-c6cccc7oc8ccccc8c67)n5)cc4)cc3)c2)cc1 ; c1ccc(-c2ccc(-c3ccc(-c4cccc(-c5nc(-c6ccccc6)nc(-c6cccc7oc8ccccc8c67)n5)c4)cc3)cc2)cc1 ; c1ccc(-c2ccc3c(-c4nc(-c5ccc6ccccc6c5)nc(-c5cccc6oc7ccccc7c56)n4)cccc3c2)cc1] 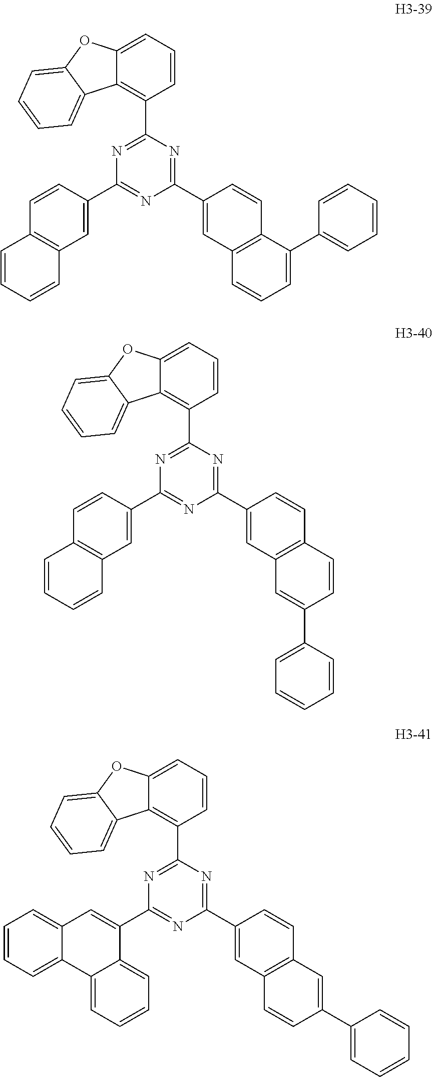 [SMILES: c1ccc(-c2cccc3cc(-c4nc(-c5ccc6ccccc6c5)nc(-c5cccc6oc7ccccc7c56)n4)ccc23)cc1 ; c1ccc(-c2ccc3ccc(-c4nc(-c5ccc6ccccc6c5)nc(-c5cccc6oc7ccccc7c56)n4)cc3c2)cc1 ; c1ccc(-c2ccc3cc(-c4nc(-c5cc6ccccc6c6ccccc56)nc(-c5cccc6oc7ccccc7c56)n4)ccc3c2)cc1] 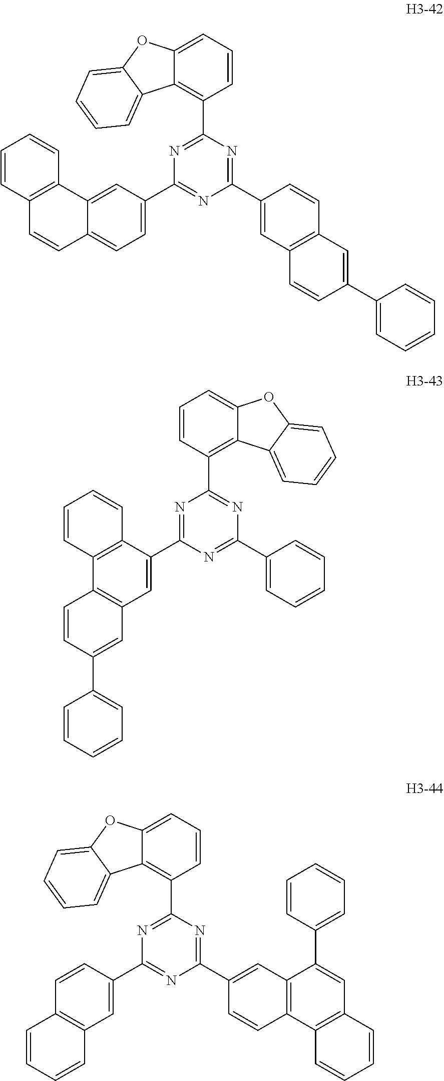 [SMILES: c1ccc(-c2ccc3cc(-c4nc(-c5ccc6ccc7ccccc7c6c5)nc(-c5cccc6oc7ccccc7c56)n4)ccc3c2)cc1 ; c1ccc(-c2ccc3c(c2)cc(-c2nc(-c4ccccc4)nc(-c4cccc5oc6ccccc6c45)n2)c2ccccc23)cc1 ; c1ccc(-c2cc3ccccc3c3ccc(-c4nc(-c5ccc6ccccc6c5)nc(-c5cccc6oc7ccccc7c56)n4)cc23)cc1] 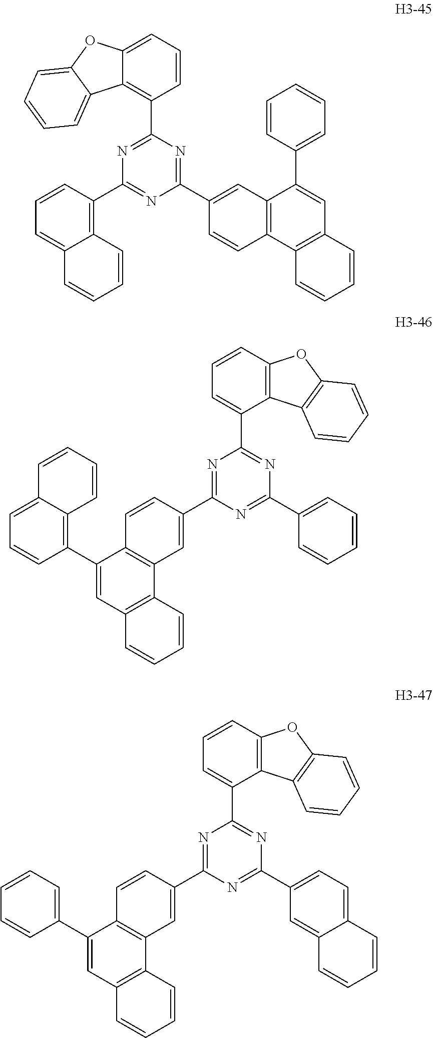 [SMILES: c1ccc(-c2cc3ccccc3c3ccc(-c4nc(-c5cccc6ccccc56)nc(-c5cccc6oc7ccccc7c56)n4)cc23)cc1 ; c1ccc(-c2nc(-c3ccc4c(-c5cccc6ccccc56)cc5ccccc5c4c3)nc(-c3cccc4oc5ccccc5c34)n2)cc1 ; c1ccc(-c2cc3ccccc3c3cc(-c4nc(-c5ccc6ccccc6c5)nc(-c5cccc6oc7ccccc7c56)n4)ccc23)cc1] 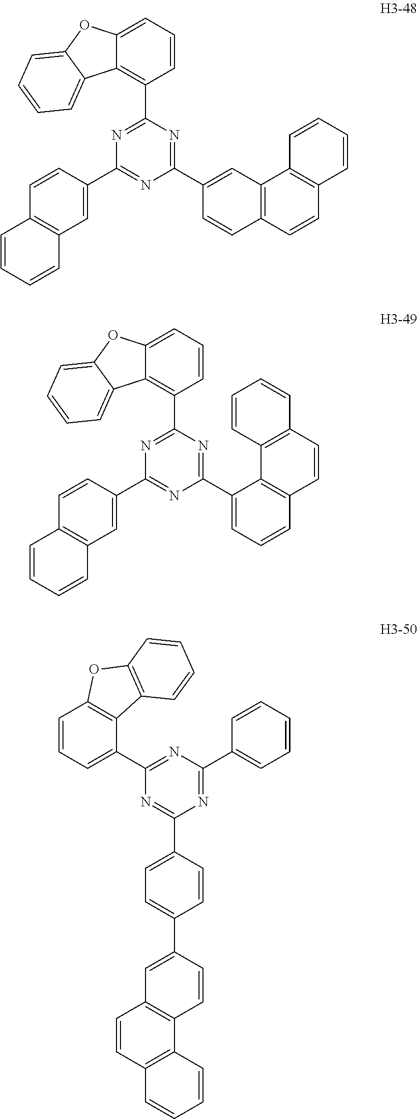 [SMILES: c1ccc2cc(-c3nc(-c4ccc5ccc6ccccc6c5c4)nc(-c4cccc5oc6ccccc6c45)n3)ccc2c1 ; c1ccc2cc(-c3nc(-c4cccc5ccc6ccccc6c45)nc(-c4cccc5oc6ccccc6c45)n3)ccc2c1 ; c1ccc(-c2nc(-c3ccc(-c4ccc5c(ccc6ccccc65)c4)cc3)nc(-c3cccc4oc5ccccc5c34)n2)cc1] 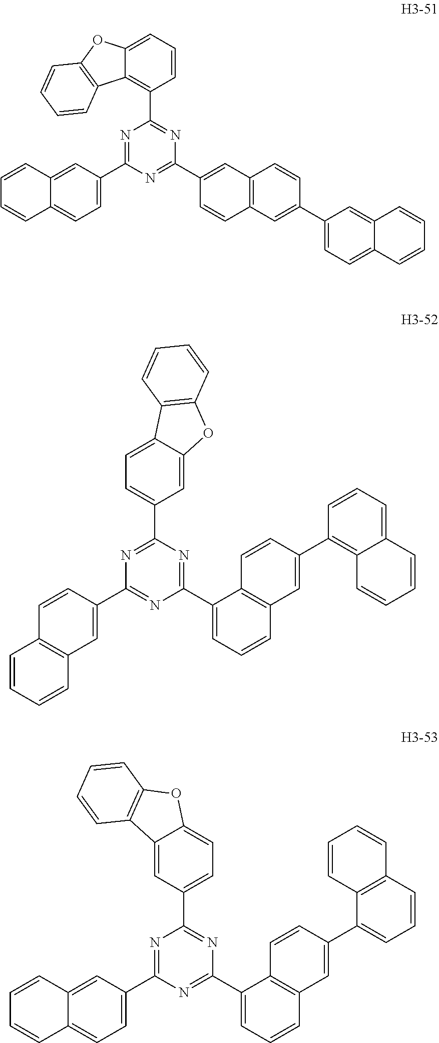 [SMILES: c1ccc2cc(-c3ccc4cc(-c5nc(-c6ccc7ccccc7c6)nc(-c6cccc7oc8ccccc8c67)n5)ccc4c3)ccc2c1 ; c1ccc2cc(-c3nc(-c4ccc5c(c4)oc4ccccc45)nc(-c4cccc5cc(-c6cccc7ccccc67)ccc45)n3)ccc2c1 ; c1ccc2cc(-c3nc(-c4ccc5oc6ccccc6c5c4)nc(-c4cccc5cc(-c6cccc7ccccc67)ccc45)n3)ccc2c1] 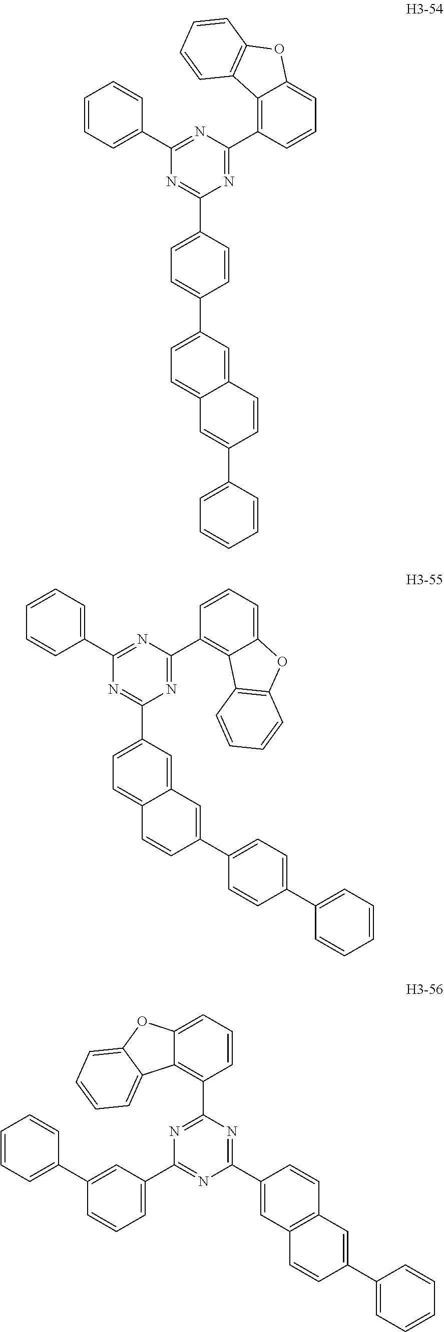 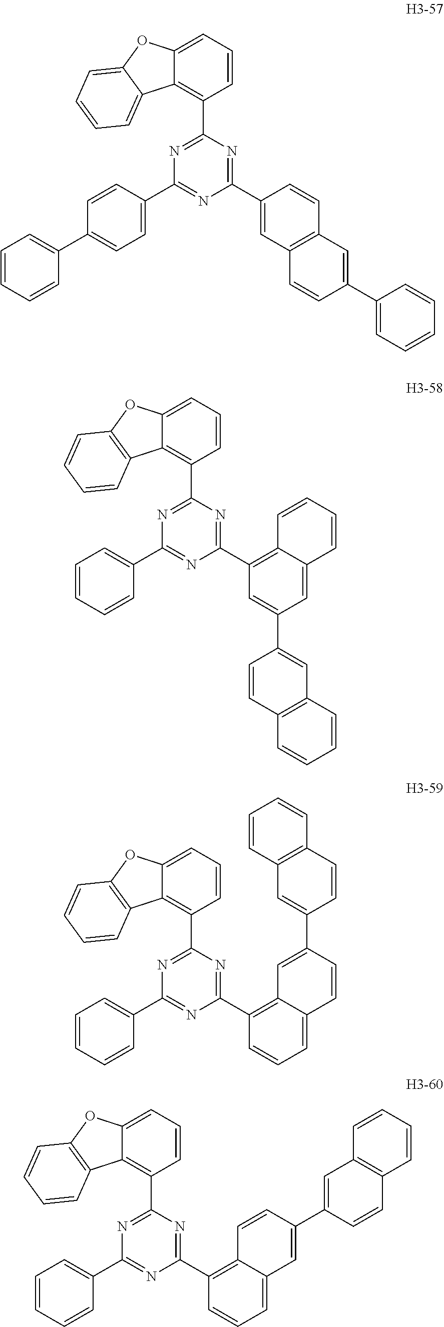 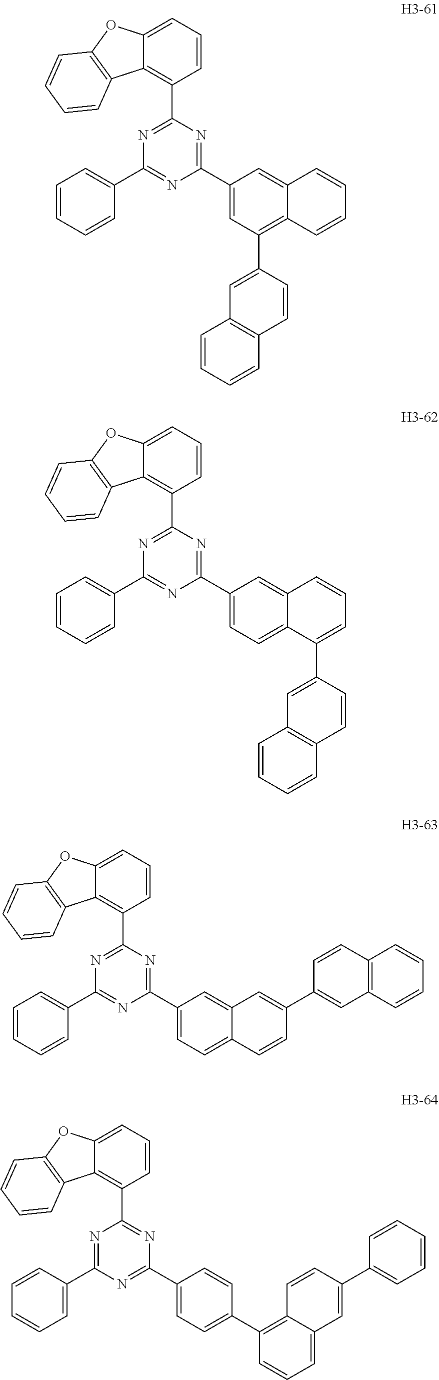 [SMILES: c1ccc(-c2nc(-c3cc(-c4ccc5ccccc5c4)c4ccccc4c3)nc(-c3cccc4oc5ccccc5c34)n2)cc1 ; c1ccc(-c2nc(-c3ccc4c(-c5ccc6ccccc6c5)cccc4c3)nc(-c3cccc4oc5ccccc5c34)n2)cc1 ; c1ccc(-c2nc(-c3ccc4ccc(-c5ccc6ccccc6c5)cc4c3)nc(-c3cccc4oc5ccccc5c34)n2)cc1 ; c1ccc(-c2ccc3c(-c4ccc(-c5nc(-c6ccccc6)nc(-c6cccc7oc8ccccc8c67)n5)cc4)cccc3c2)cc1] 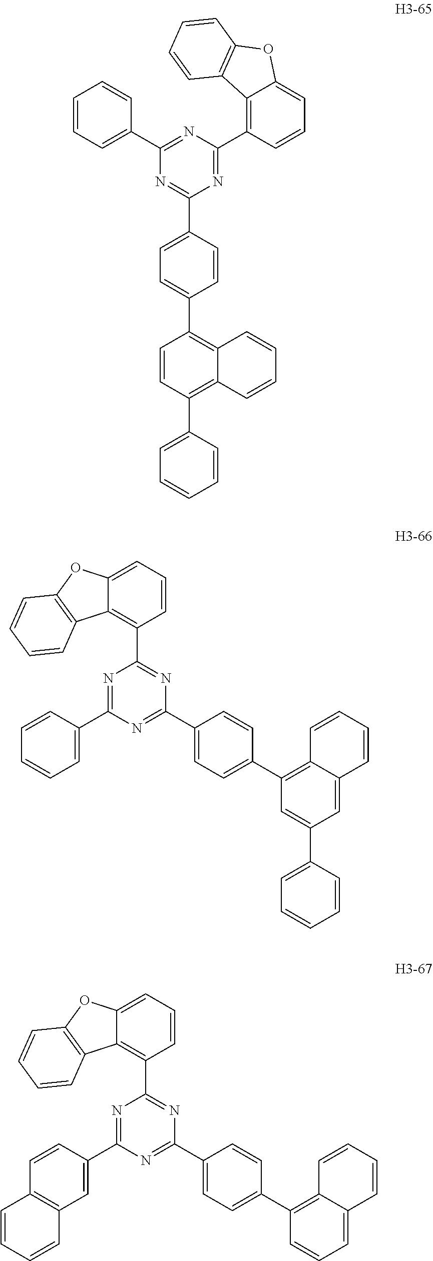 [SMILES: c1ccc(-c2nc(-c3ccc(-c4ccc(-c5ccccc5)c5ccccc45)cc3)nc(-c3cccc4oc5ccccc5c34)n2)cc1 ; c1ccc(-c2cc(-c3ccc(-c4nc(-c5ccccc5)nc(-c5cccc6oc7ccccc7c56)n4)cc3)c3ccccc3c2)cc1 ; c1ccc2cc(-c3nc(-c4ccc(-c5cccc6ccccc56)cc4)nc(-c4cccc5oc6ccccc6c45)n3)ccc2c1] 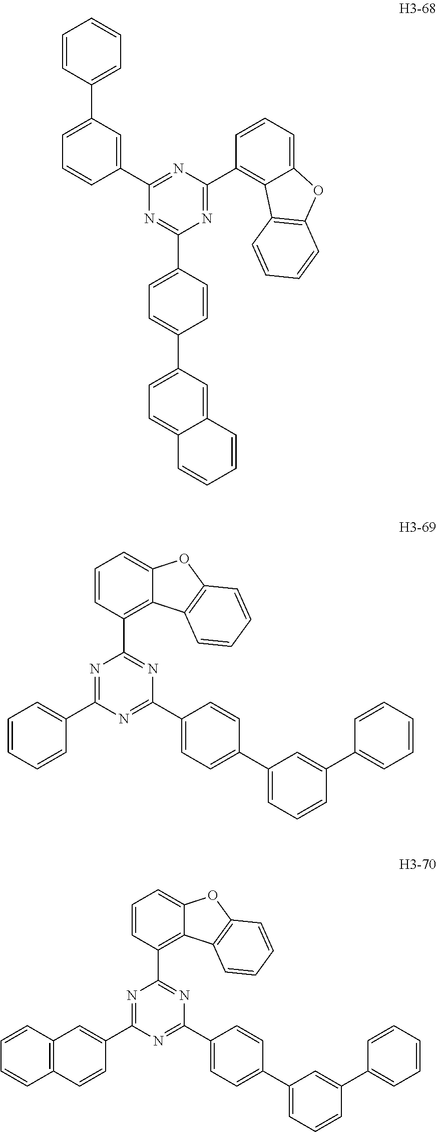 [SMILES: c1ccc(-c2cccc(-c3nc(-c4ccc(-c5ccc6ccccc6c5)cc4)nc(-c4cccc5oc6ccccc6c45)n3)c2)cc1 ; c1ccc(-c2cccc(-c3ccc(-c4nc(-c5ccccc5)nc(-c5cccc6oc7ccccc7c56)n4)cc3)c2)cc1 ; c1ccc(-c2cccc(-c3ccc(-c4nc(-c5ccc6ccccc6c5)nc(-c5cccc6oc7ccccc7c56)n4)cc3)c2)cc1] 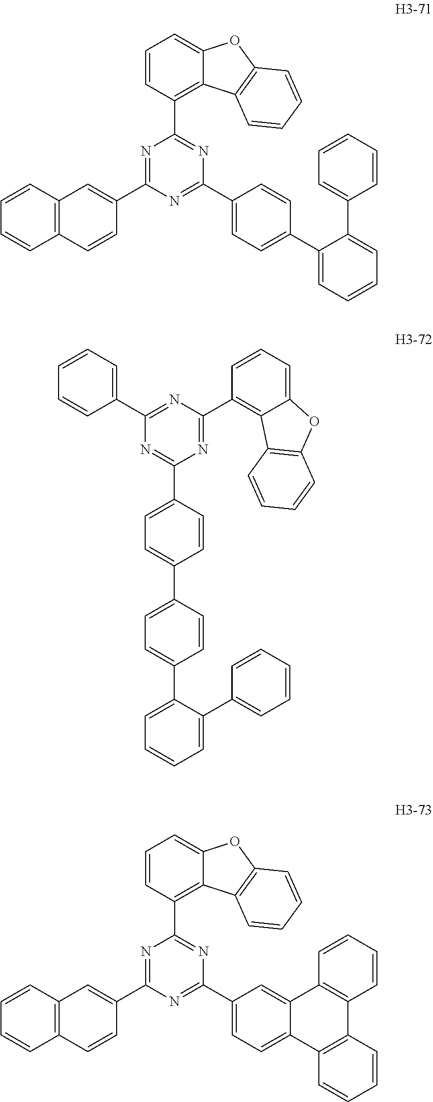 [SMILES: c1ccc(-c2ccccc2-c2ccc(-c3nc(-c4ccc5ccccc5c4)nc(-c4cccc5oc6ccccc6c45)n3)cc2)cc1 ; c1ccc(-c2nc(-c3ccc(-c4ccc(-c5ccccc5-c5ccccc5)cc4)cc3)nc(-c3cccc4oc5ccccc5c34)n2)cc1 ; c1ccc2cc(-c3nc(-c4ccc5c6ccccc6c6ccccc6c5c4)nc(-c4cccc5oc6ccccc6c45)n3)ccc2c1] 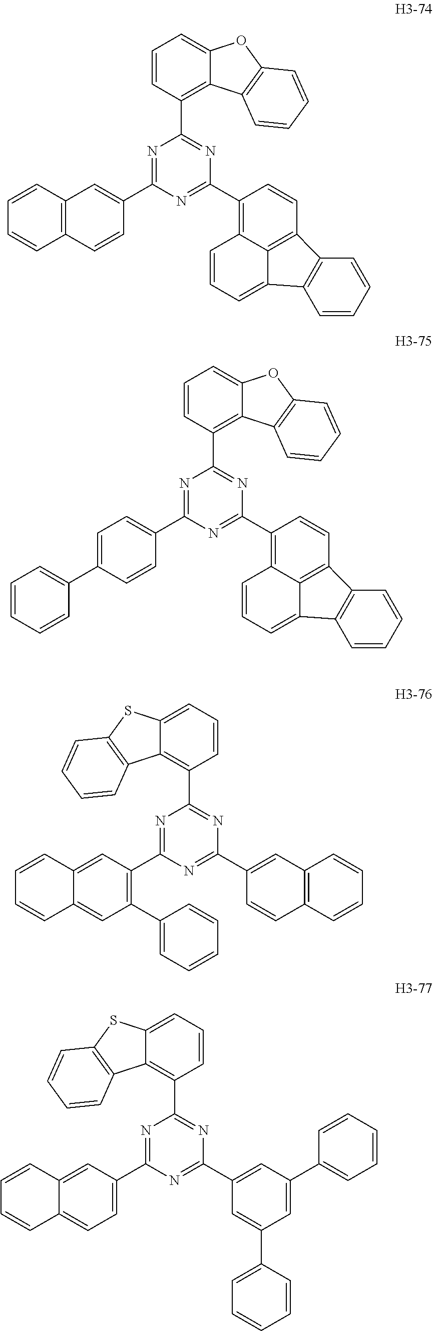 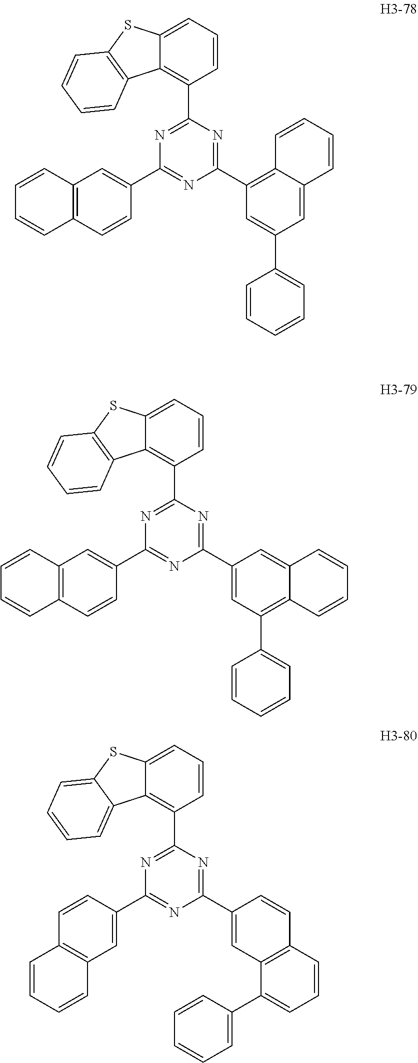 [SMILES: c1ccc(-c2cc(-c3nc(-c4ccc5ccccc5c4)nc(-c4cccc5sc6ccccc6c45)n3)c3ccccc3c2)cc1 ; c1ccc(-c2cc(-c3nc(-c4ccc5ccccc5c4)nc(-c4cccc5sc6ccccc6c45)n3)cc3ccccc23)cc1 ; c1ccc(-c2cccc3ccc(-c4nc(-c5ccc6ccccc6c5)nc(-c5cccc6sc7ccccc7c56)n4)cc23)cc1] 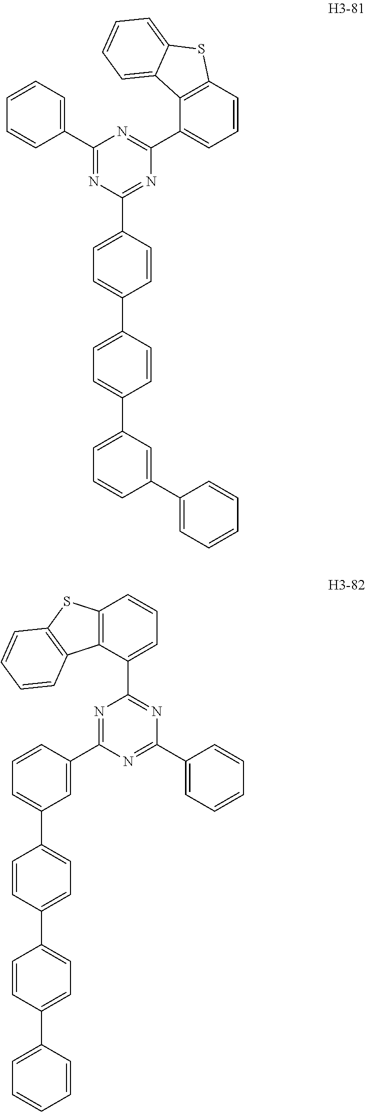 [SMILES: c1ccc(-c2cccc(-c3ccc(-c4ccc(-c5nc(-c6ccccc6)nc(-c6cccc7sc8ccccc8c67)n5)cc4)cc3)c2)cc1 ; c1ccc(-c2ccc(-c3ccc(-c4cccc(-c5nc(-c6ccccc6)nc(-c6cccc7sc8ccccc8c67)n5)c4)cc3)cc2)cc1] 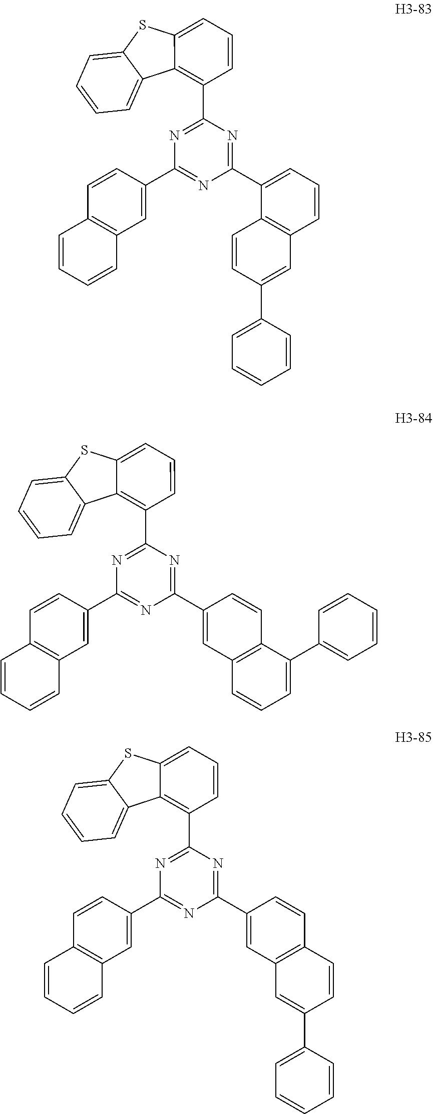 [SMILES: c1ccc(-c2ccc3c(-c4nc(-c5ccc6ccccc6c5)nc(-c5cccc6sc7ccccc7c56)n4)cccc3c2)cc1 ; c1ccc(-c2cccc3cc(-c4nc(-c5ccc6ccccc6c5)nc(-c5cccc6sc7ccccc7c56)n4)ccc23)cc1 ; c1ccc(-c2ccc3ccc(-c4nc(-c5ccc6ccccc6c5)nc(-c5cccc6sc7ccccc7c56)n4)cc3c2)cc1] 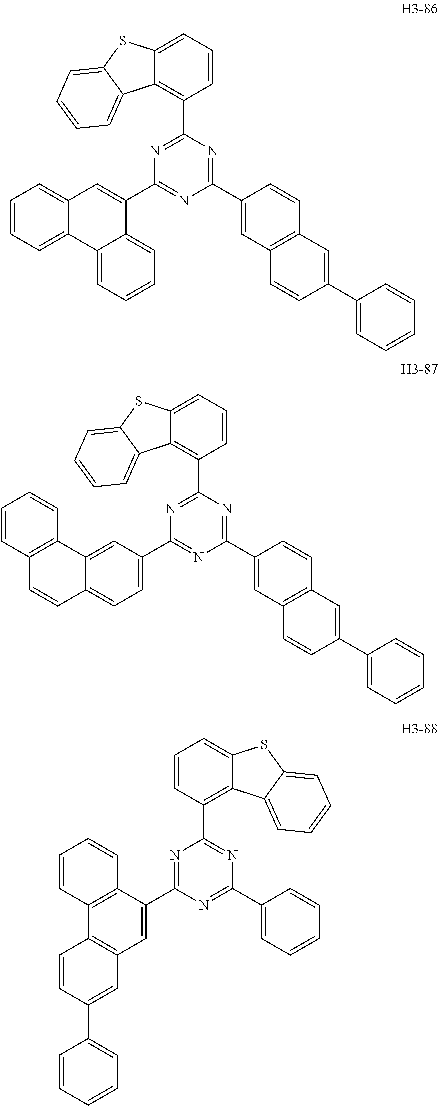 [SMILES: c1ccc(-c2ccc3cc(-c4nc(-c5cc6ccccc6c6ccccc56)nc(-c5cccc6sc7ccccc7c56)n4)ccc3c2)cc1 ; c1ccc(-c2ccc3cc(-c4nc(-c5ccc6ccc7ccccc7c6c5)nc(-c5cccc6sc7ccccc7c56)n4)ccc3c2)cc1 ; c1ccc(-c2ccc3c(c2)cc(-c2nc(-c4ccccc4)nc(-c4cccc5sc6ccccc6c45)n2)c2ccccc23)cc1] 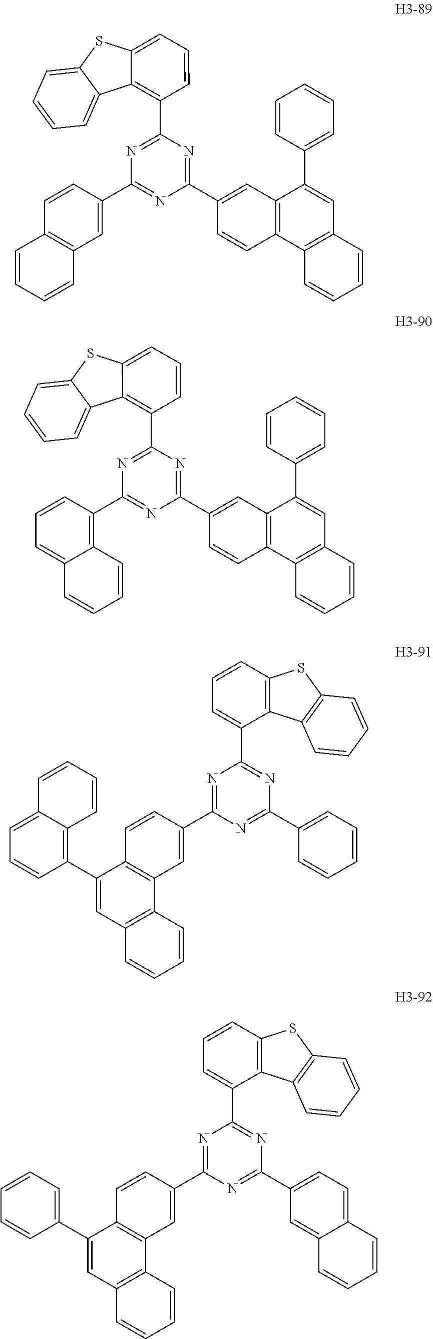 [SMILES: c1ccc(-c2cc3ccccc3c3ccc(-c4nc(-c5ccc6ccccc6c5)nc(-c5cccc6sc7ccccc7c56)n4)cc23)cc1 ; c1ccc(-c2cc3ccccc3c3ccc(-c4nc(-c5cccc6ccccc56)nc(-c5cccc6sc7ccccc7c56)n4)cc23)cc1 ; c1ccc(-c2nc(-c3ccc4c(-c5cccc6ccccc56)cc5ccccc5c4c3)nc(-c3cccc4sc5ccccc5c34)n2)cc1 ; c1ccc(-c2cc3ccccc3c3cc(-c4nc(-c5ccc6ccccc6c5)nc(-c5cccc6sc7ccccc7c56)n4)ccc23)cc1] 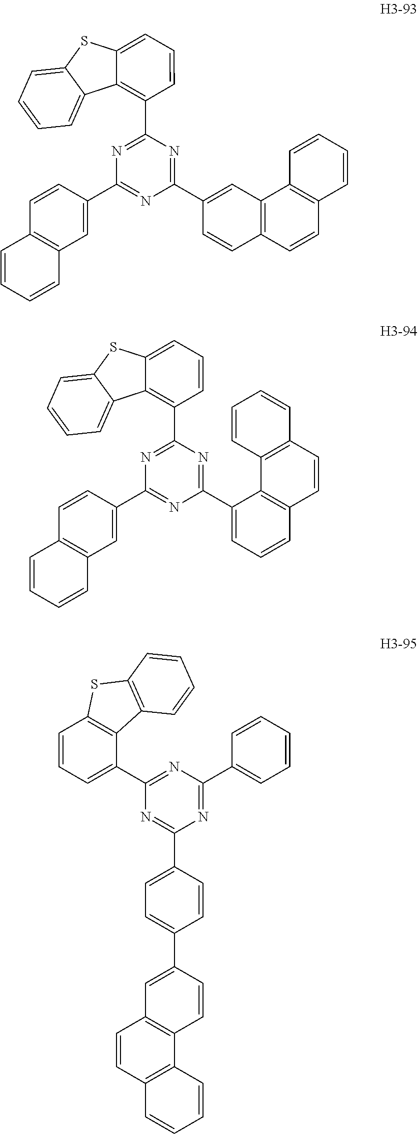 [SMILES: c1ccc2cc(-c3nc(-c4ccc5ccc6ccccc6c5c4)nc(-c4cccc5sc6ccccc6c45)n3)ccc2c1 ; c1ccc2cc(-c3nc(-c4cccc5ccc6ccccc6c45)nc(-c4cccc5sc6ccccc6c45)n3)ccc2c1 ; c1ccc(-c2nc(-c3ccc(-c4ccc5c(ccc6ccccc65)c4)cc3)nc(-c3cccc4sc5ccccc5c34)n2)cc1] 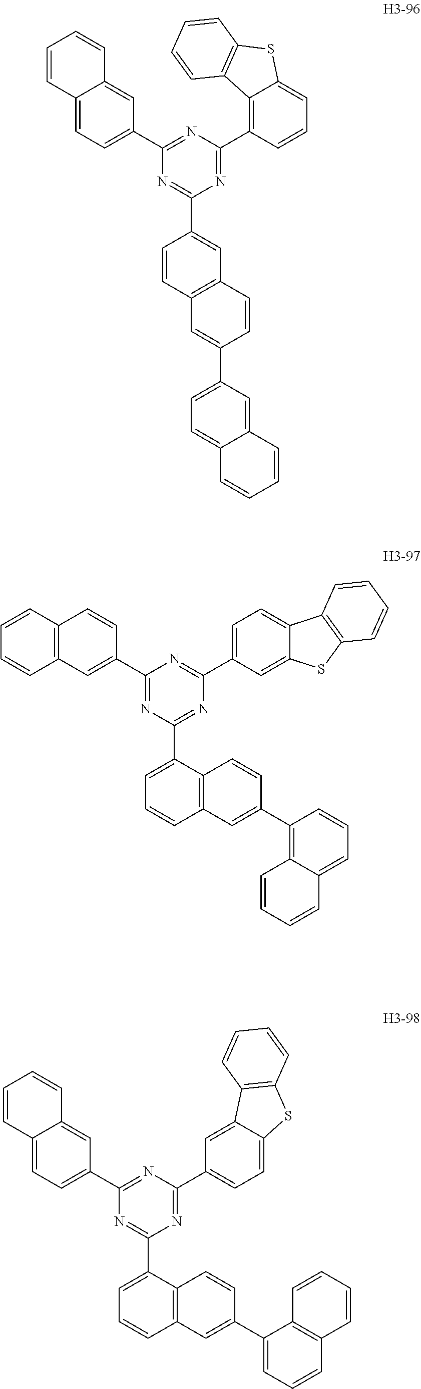 [SMILES: c1ccc2cc(-c3ccc4cc(-c5nc(-c6ccc7ccccc7c6)nc(-c6cccc7sc8ccccc8c67)n5)ccc4c3)ccc2c1 ; c1ccc2cc(-c3nc(-c4ccc5c(c4)sc4ccccc45)nc(-c4cccc5cc(-c6cccc7ccccc67)ccc45)n3)ccc2c1 ; c1ccc2cc(-c3nc(-c4ccc5sc6ccccc6c5c4)nc(-c4cccc5cc(-c6cccc7ccccc67)ccc45)n3)ccc2c1] 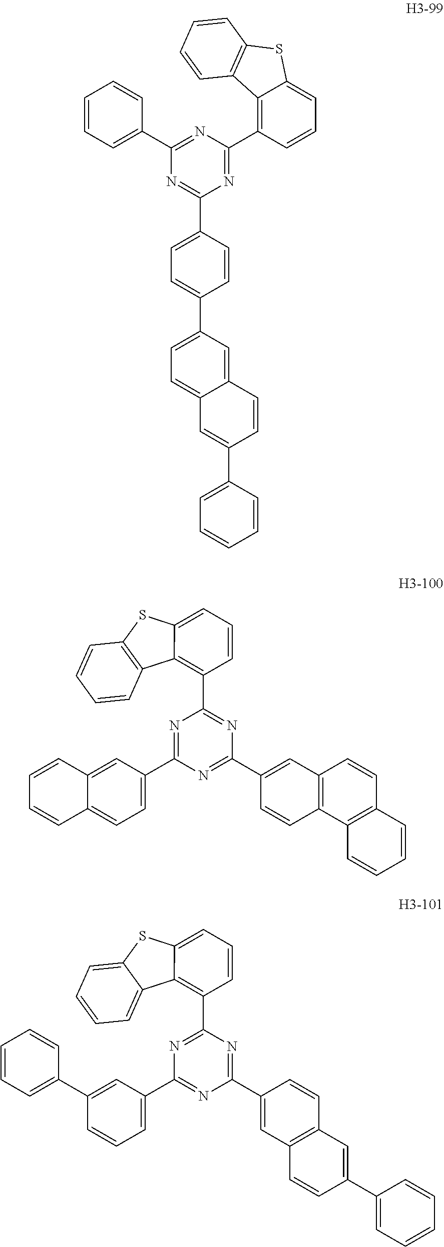 [SMILES: c1ccc(-c2ccc3cc(-c4ccc(-c5nc(-c6ccccc6)nc(-c6cccc7sc8ccccc8c67)n5)cc4)ccc3c2)cc1 ; c1ccc2cc(-c3nc(-c4ccc5c(ccc6ccccc65)c4)nc(-c4cccc5sc6ccccc6c45)n3)ccc2c1 ; c1ccc(-c2cccc(-c3nc(-c4ccc5cc(-c6ccccc6)ccc5c4)nc(-c4cccc5sc6ccccc6c45)n3)c2)cc1] 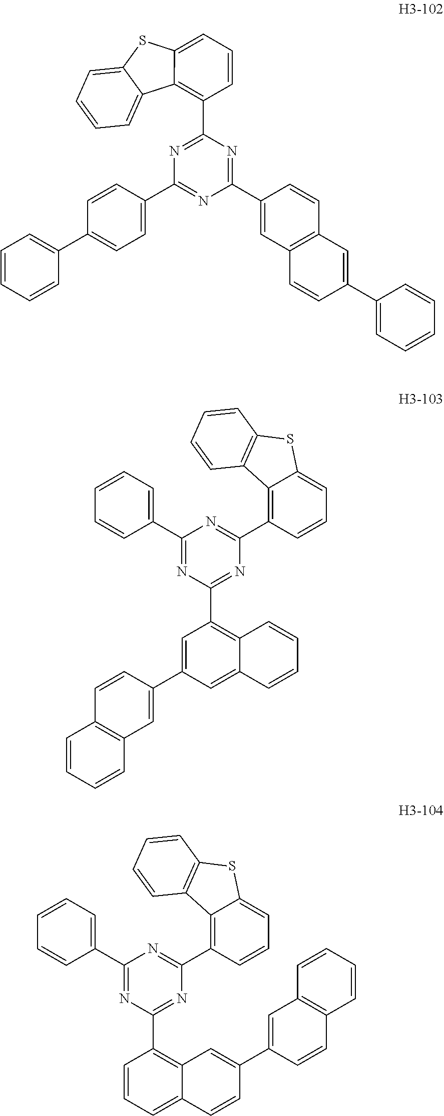 [SMILES: c1ccc(-c2ccc(-c3nc(-c4ccc5cc(-c6ccccc6)ccc5c4)nc(-c4cccc5sc6ccccc6c45)n3)cc2)cc1 ; c1ccc(-c2nc(-c3cc(-c4ccc5ccccc5c4)cc4ccccc34)nc(-c3cccc4sc5ccccc5c34)n2)cc1 ; c1ccc(-c2nc(-c3cccc4ccc(-c5ccc6ccccc6c5)cc34)nc(-c3cccc4sc5ccccc5c34)n2)cc1] 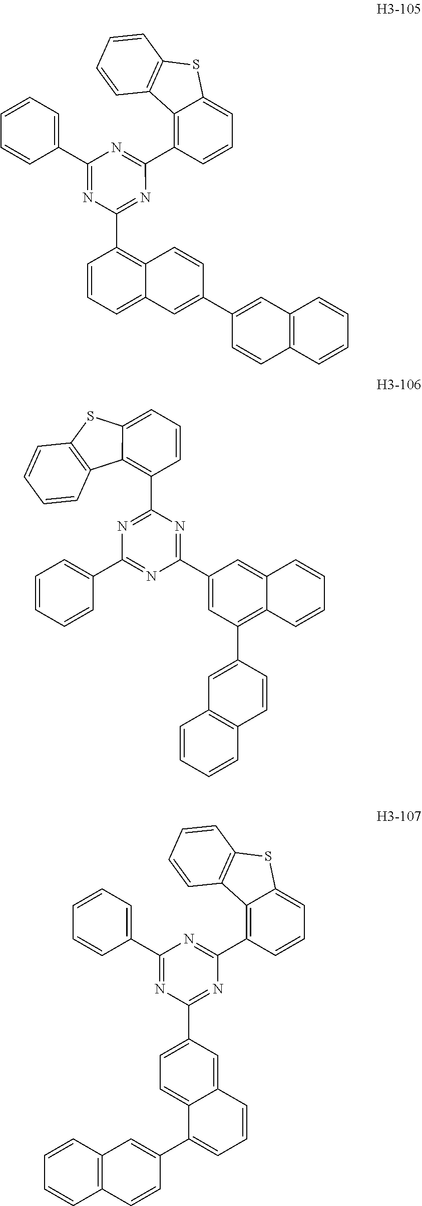 [SMILES: c1ccc(-c2nc(-c3cccc4cc(-c5ccc6ccccc6c5)ccc34)nc(-c3cccc4sc5ccccc5c34)n2)cc1 ; c1ccc(-c2nc(-c3cc(-c4ccc5ccccc5c4)c4ccccc4c3)nc(-c3cccc4sc5ccccc5c34)n2)cc1 ; c1ccc(-c2nc(-c3ccc4c(-c5ccc6ccccc6c5)cccc4c3)nc(-c3cccc4sc5ccccc5c34)n2)cc1] 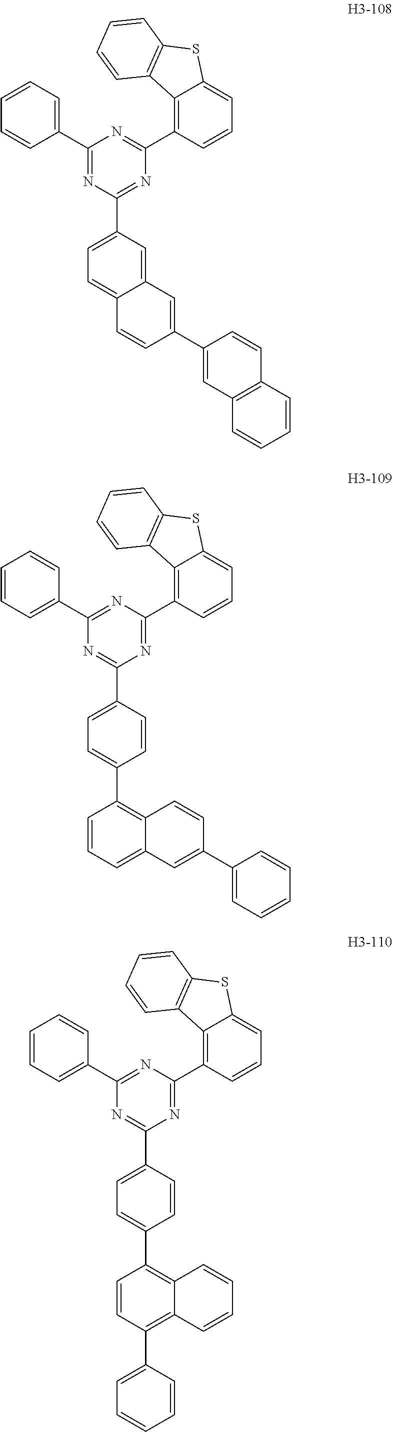 [SMILES: c1ccc(-c2nc(-c3ccc4ccc(-c5ccc6ccccc6c5)cc4c3)nc(-c3cccc4sc5ccccc5c34)n2)cc1 ; c1ccc(-c2ccc3c(-c4ccc(-c5nc(-c6ccccc6)nc(-c6cccc7sc8ccccc8c67)n5)cc4)cccc3c2)cc1 ; c1ccc(-c2nc(-c3ccc(-c4ccc(-c5ccccc5)c5ccccc45)cc3)nc(-c3cccc4sc5ccccc5c34)n2)cc1] 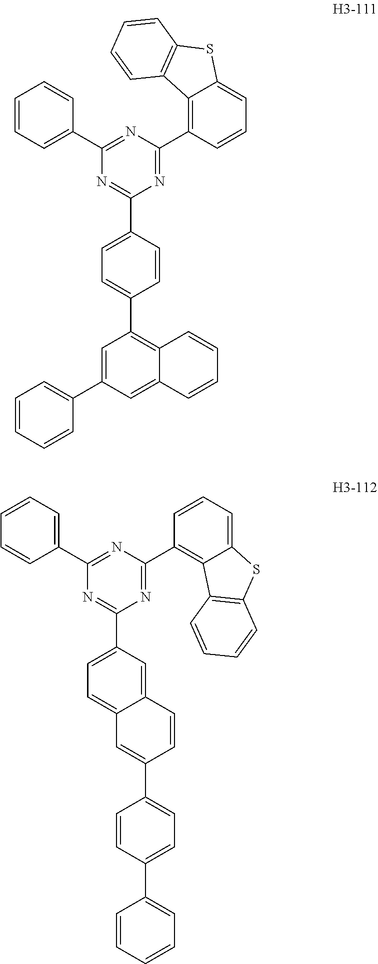 [SMILES: c1ccc(-c2cc(-c3ccc(-c4nc(-c5ccccc5)nc(-c5cccc6sc7ccccc7c56)n4)cc3)c3ccccc3c2)cc1 ; c1ccc(-c2ccc(-c3ccc4cc(-c5nc(-c6ccccc6)nc(-c6cccc7sc8ccccc8c67)n5)ccc4c3)cc2)cc1] 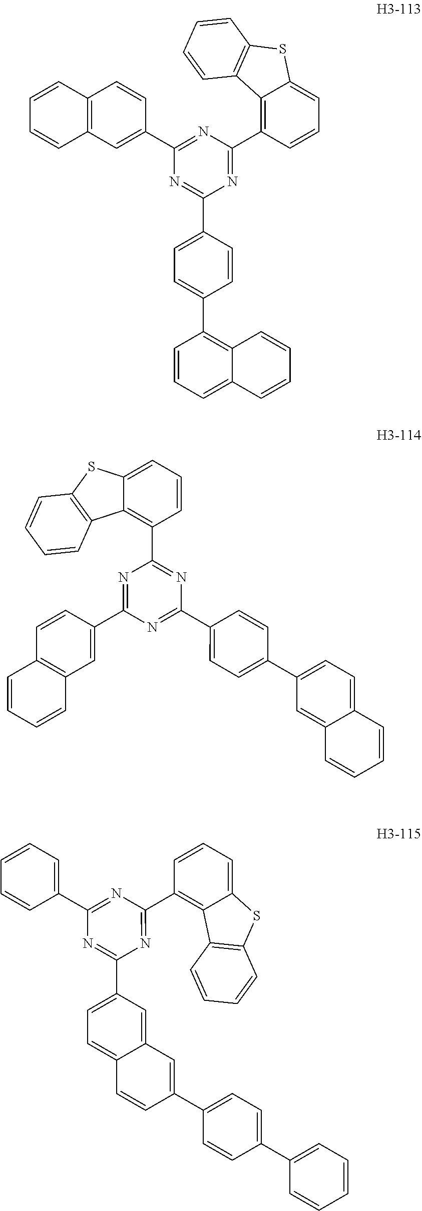 [SMILES: c1ccc2cc(-c3nc(-c4ccc(-c5cccc6ccccc56)cc4)nc(-c4cccc5sc6ccccc6c45)n3)ccc2c1 ; c1ccc2cc(-c3ccc(-c4nc(-c5ccc6ccccc6c5)nc(-c5cccc6sc7ccccc7c56)n4)cc3)ccc2c1 ; c1ccc(-c2ccc(-c3ccc4ccc(-c5nc(-c6ccccc6)nc(-c6cccc7sc8ccccc8c67)n5)cc4c3)cc2)cc1] 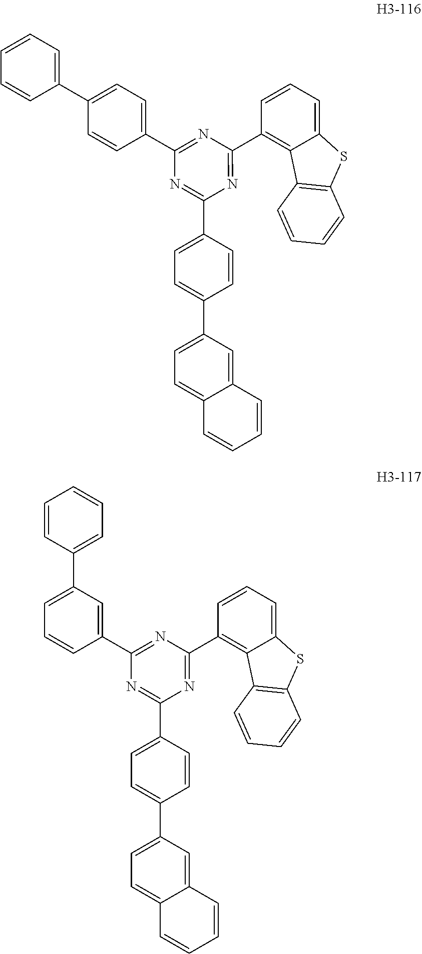 [SMILES: c1ccc(-c2ccc(-c3nc(-c4ccc(-c5ccc6ccccc6c5)cc4)nc(-c4cccc5sc6ccccc6c45)n3)cc2)cc1 ; c1ccc(-c2cccc(-c3nc(-c4ccc(-c5ccc6ccccc6c5)cc4)nc(-c4cccc5sc6ccccc6c45)n3)c2)cc1] 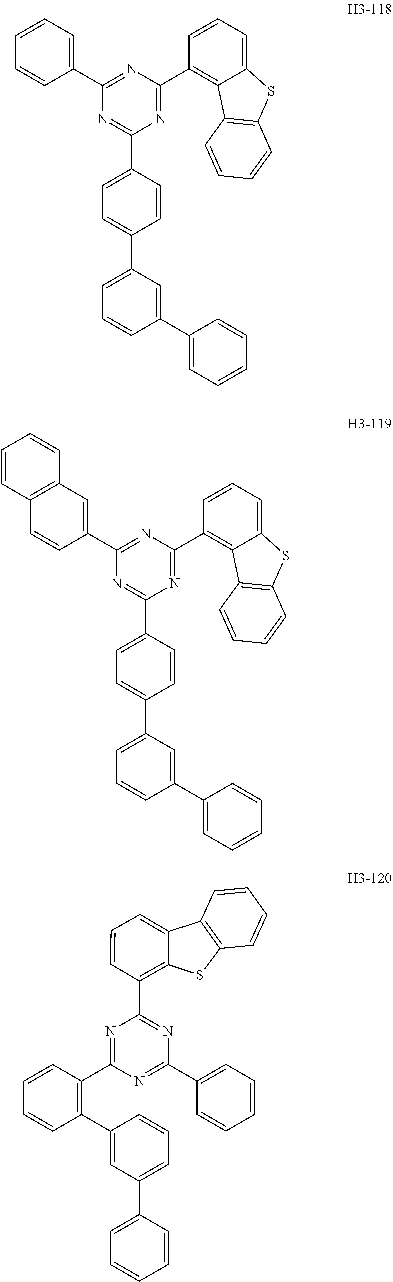 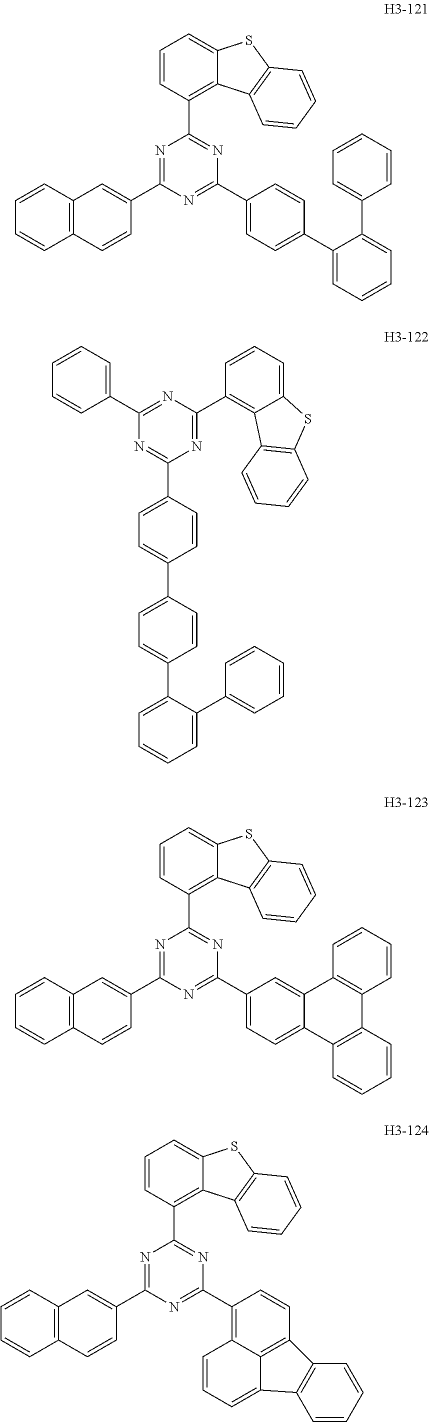 [SMILES: c1ccc(-c2ccccc2-c2ccc(-c3nc(-c4ccc5ccccc5c4)nc(-c4cccc5sc6ccccc6c45)n3)cc2)cc1 ; c1ccc(-c2nc(-c3ccc(-c4ccc(-c5ccccc5-c5ccccc5)cc4)cc3)nc(-c3cccc4sc5ccccc5c34)n2)cc1 ; c1ccc2cc(-c3nc(-c4ccc5c6ccccc6c6ccccc6c5c4)nc(-c4cccc5sc6ccccc6c45)n3)ccc2c1 ; c1ccc2c(c1)-c1cccc3c(-c4nc(-c5ccc6ccccc6c5)nc(-c5cccc6sc7ccccc7c56)n4)ccc-2c13] 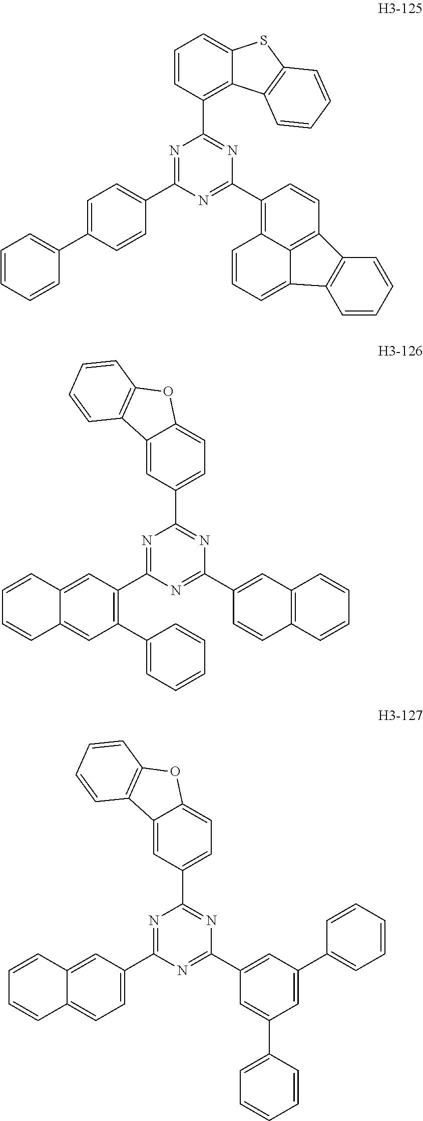 [SMILES: c1ccc(-c2ccc(-c3nc(-c4ccc5c6c(cccc46)-c4ccccc4-5)nc(-c4cccc5sc6ccccc6c45)n3)cc2)cc1 ; c1ccc(-c2cc3ccccc3cc2-c2nc(-c3ccc4ccccc4c3)nc(-c3ccc4oc5ccccc5c4c3)n2)cc1 ; c1ccc(-c2cc(-c3ccccc3)cc(-c3nc(-c4ccc5ccccc5c4)nc(-c4ccc5oc6ccccc6c5c4)n3)c2)cc1] 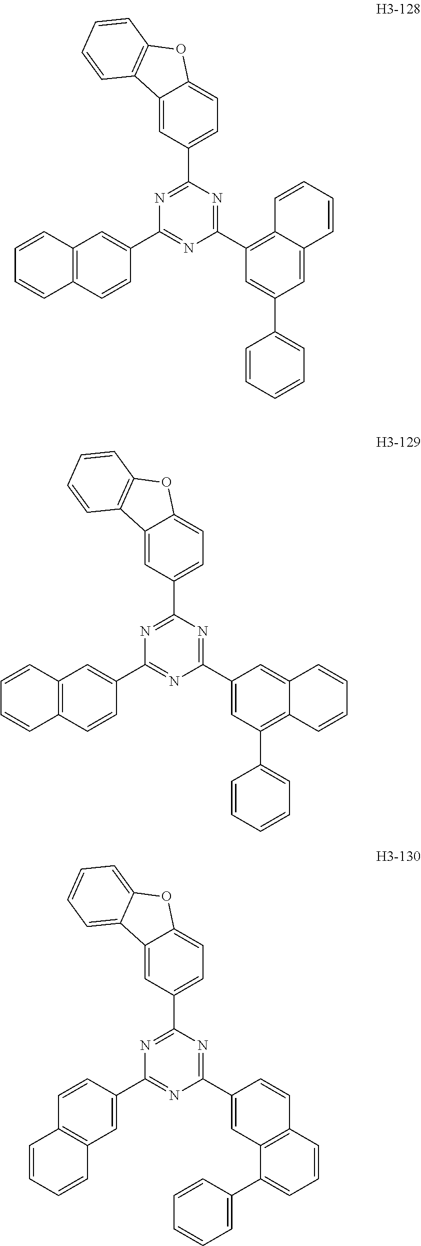 [SMILES: c1ccc(-c2cc(-c3nc(-c4ccc5ccccc5c4)nc(-c4ccc5oc6ccccc6c5c4)n3)c3ccccc3c2)cc1 ; c1ccc(-c2cc(-c3nc(-c4ccc5ccccc5c4)nc(-c4ccc5oc6ccccc6c5c4)n3)cc3ccccc23)cc1 ; c1ccc(-c2cccc3ccc(-c4nc(-c5ccc6ccccc6c5)nc(-c5ccc6oc7ccccc7c6c5)n4)cc23)cc1] 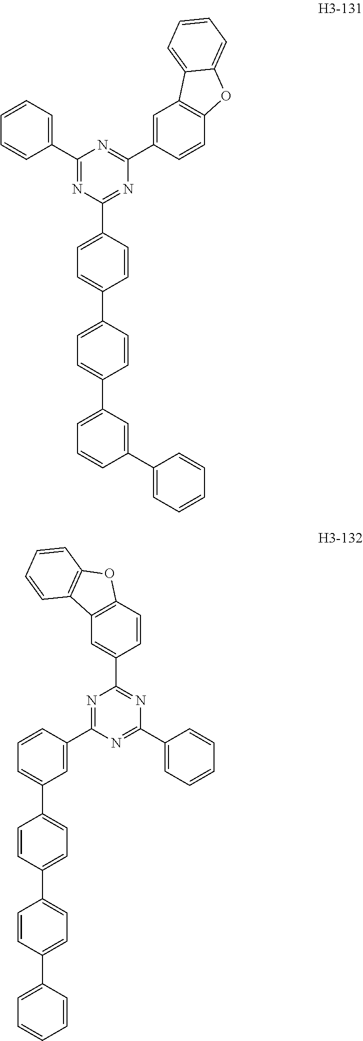 [SMILES: c1ccc(-c2cccc(-c3ccc(-c4ccc(-c5nc(-c6ccccc6)nc(-c6ccc7oc8ccccc8c7c6)n5)cc4)cc3)c2)cc1 ; c1ccc(-c2ccc(-c3ccc(-c4cccc(-c5nc(-c6ccccc6)nc(-c6ccc7oc8ccccc8c7c6)n5)c4)cc3)cc2)cc1] 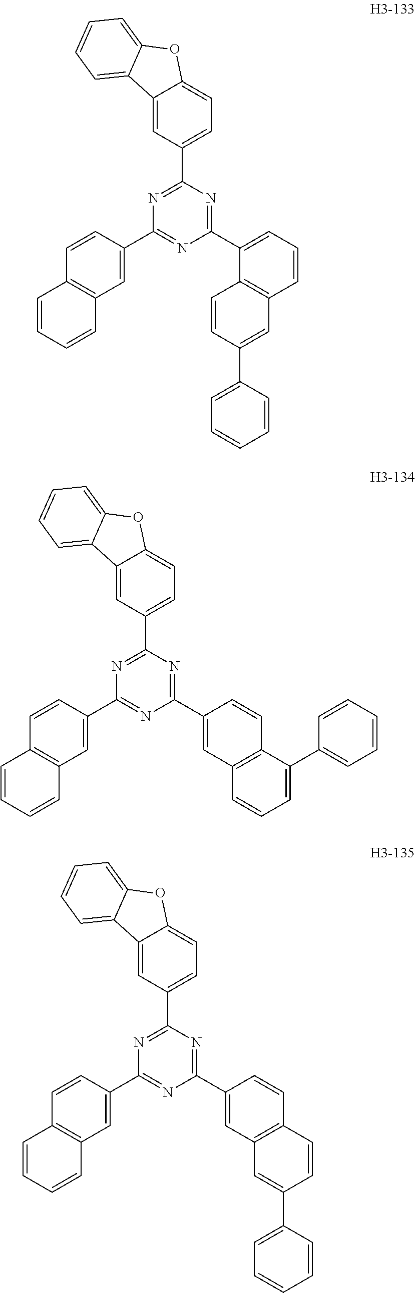 [SMILES: c1ccc(-c2ccc3c(-c4nc(-c5ccc6ccccc6c5)nc(-c5ccc6oc7ccccc7c6c5)n4)cccc3c2)cc1 ; c1ccc(-c2cccc3cc(-c4nc(-c5ccc6ccccc6c5)nc(-c5ccc6oc7ccccc7c6c5)n4)ccc23)cc1 ; c1ccc(-c2ccc3ccc(-c4nc(-c5ccc6ccccc6c5)nc(-c5ccc6oc7ccccc7c6c5)n4)cc3c2)cc1] 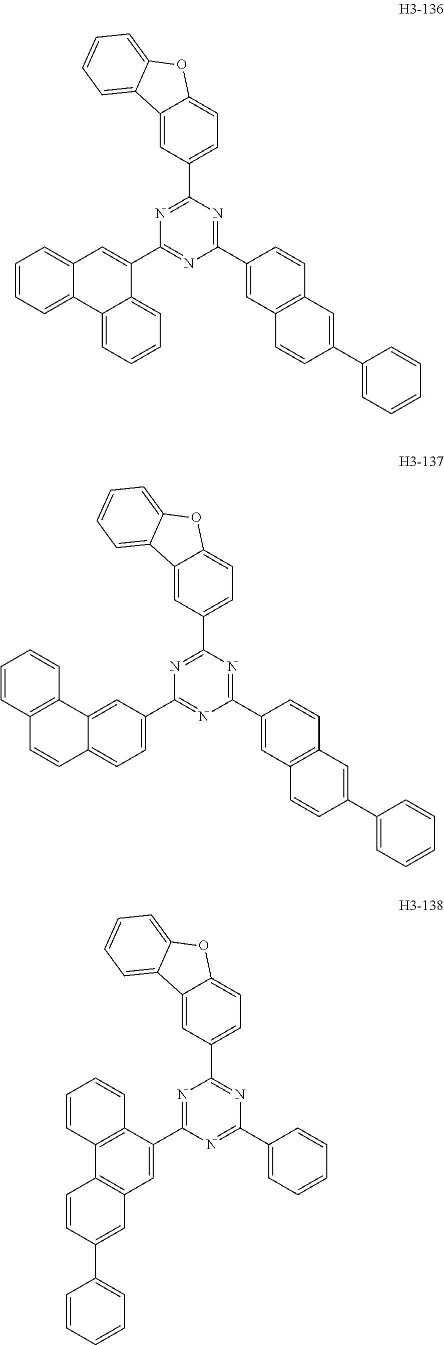 [SMILES: c1ccc(-c2ccc3cc(-c4nc(-c5ccc6oc7ccccc7c6c5)nc(-c5cc6ccccc6c6ccccc56)n4)ccc3c2)cc1 ; c1ccc(-c2ccc3cc(-c4nc(-c5ccc6ccc7ccccc7c6c5)nc(-c5ccc6oc7ccccc7c6c5)n4)ccc3c2)cc1 ; c1ccc(-c2ccc3c(c2)cc(-c2nc(-c4ccccc4)nc(-c4ccc5oc6ccccc6c5c4)n2)c2ccccc23)cc1] 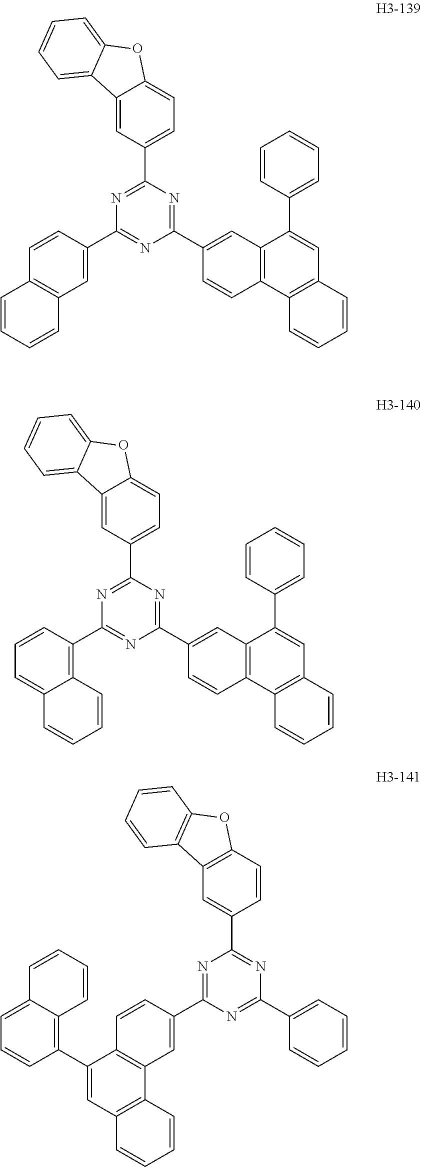 [SMILES: c1ccc(-c2cc3ccccc3c3ccc(-c4nc(-c5ccc6ccccc6c5)nc(-c5ccc6oc7ccccc7c6c5)n4)cc23)cc1 ; c1ccc(-c2cc3ccccc3c3ccc(-c4nc(-c5ccc6oc7ccccc7c6c5)nc(-c5cccc6ccccc56)n4)cc23)cc1 ; c1ccc(-c2nc(-c3ccc4oc5ccccc5c4c3)nc(-c3ccc4c(-c5cccc6ccccc56)cc5ccccc5c4c3)n2)cc1] 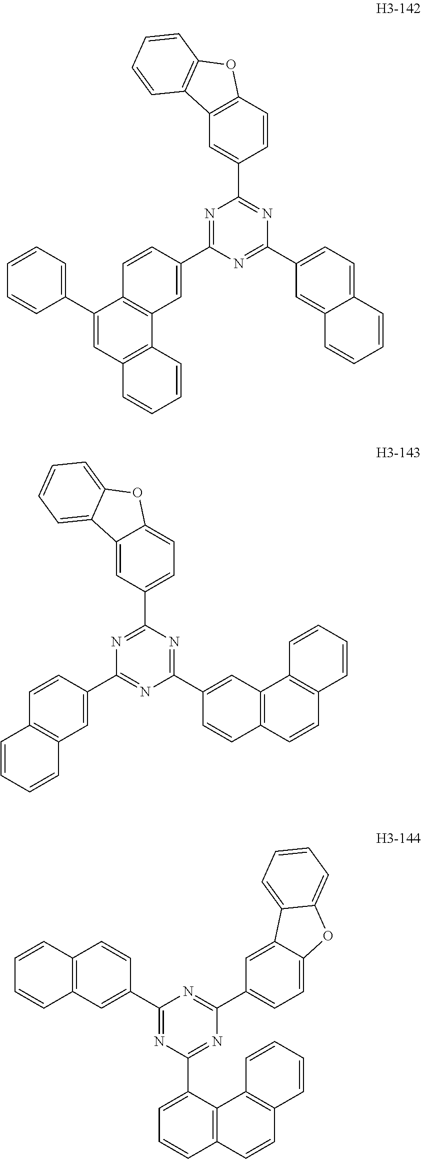 [SMILES: c1ccc(-c2cc3ccccc3c3cc(-c4nc(-c5ccc6ccccc6c5)nc(-c5ccc6oc7ccccc7c6c5)n4)ccc23)cc1 ; c1ccc2cc(-c3nc(-c4ccc5ccc6ccccc6c5c4)nc(-c4ccc5oc6ccccc6c5c4)n3)ccc2c1 ; c1ccc2cc(-c3nc(-c4ccc5oc6ccccc6c5c4)nc(-c4cccc5ccc6ccccc6c45)n3)ccc2c1] 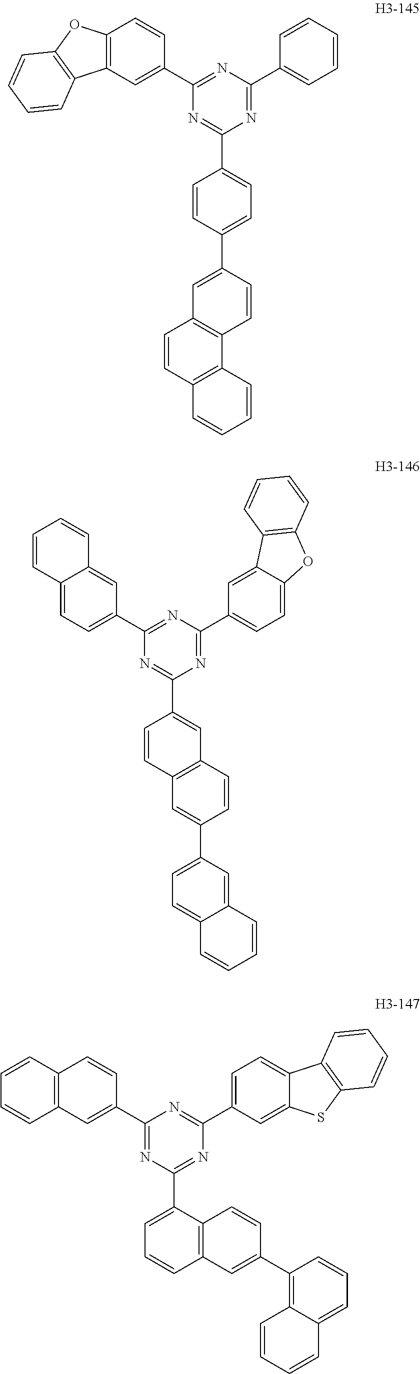 [SMILES: c1ccc(-c2nc(-c3ccc(-c4ccc5c(ccc6ccccc65)c4)cc3)nc(-c3ccc4oc5ccccc5c4c3)n2)cc1 ; c1ccc2cc(-c3ccc4cc(-c5nc(-c6ccc7ccccc7c6)nc(-c6ccc7oc8ccccc8c7c6)n5)ccc4c3)ccc2c1 ; c1ccc2cc(-c3nc(-c4ccc5c(c4)sc4ccccc45)nc(-c4cccc5cc(-c6cccc7ccccc67)ccc45)n3)ccc2c1] 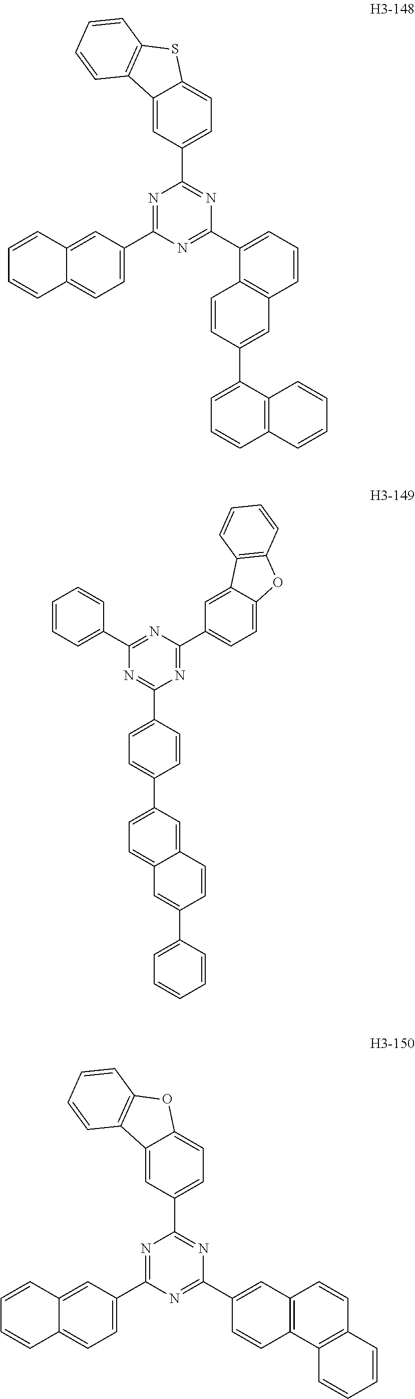 [SMILES: c1ccc2cc(-c3nc(-c4ccc5sc6ccccc6c5c4)nc(-c4cccc5cc(-c6cccc7ccccc67)ccc45)n3)ccc2c1 ; c1ccc(-c2ccc3cc(-c4ccc(-c5nc(-c6ccccc6)nc(-c6ccc7oc8ccccc8c7c6)n5)cc4)ccc3c2)cc1 ; c1ccc2cc(-c3nc(-c4ccc5c(ccc6ccccc65)c4)nc(-c4ccc5oc6ccccc6c5c4)n3)ccc2c1] 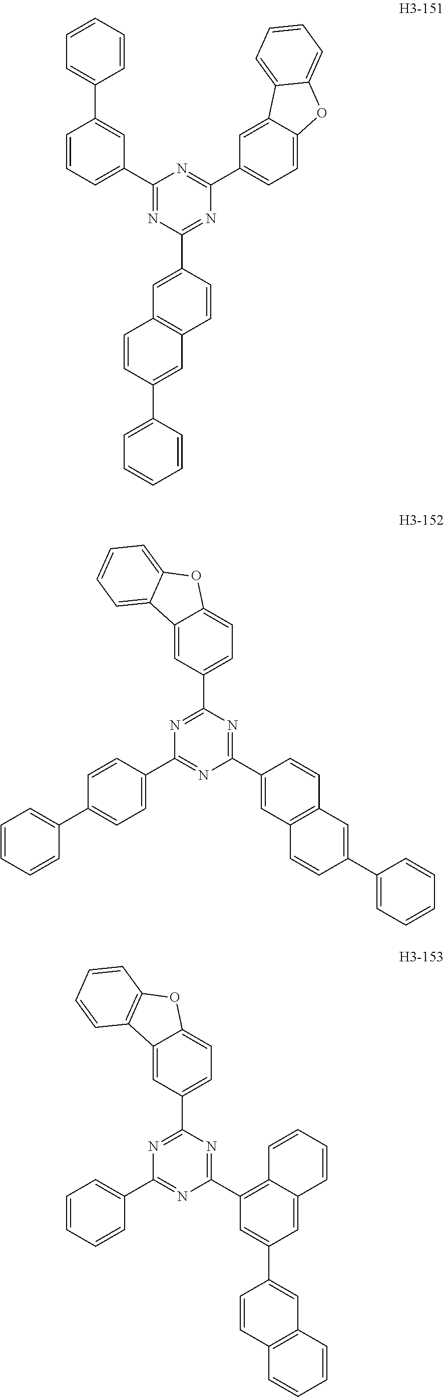 [SMILES: c1ccc(-c2cccc(-c3nc(-c4ccc5cc(-c6ccccc6)ccc5c4)nc(-c4ccc5oc6ccccc6c5c4)n3)c2)cc1 ; c1ccc(-c2ccc(-c3nc(-c4ccc5cc(-c6ccccc6)ccc5c4)nc(-c4ccc5oc6ccccc6c5c4)n3)cc2)cc1 ; c1ccc(-c2nc(-c3ccc4oc5ccccc5c4c3)nc(-c3cc(-c4ccc5ccccc5c4)cc4ccccc34)n2)cc1] 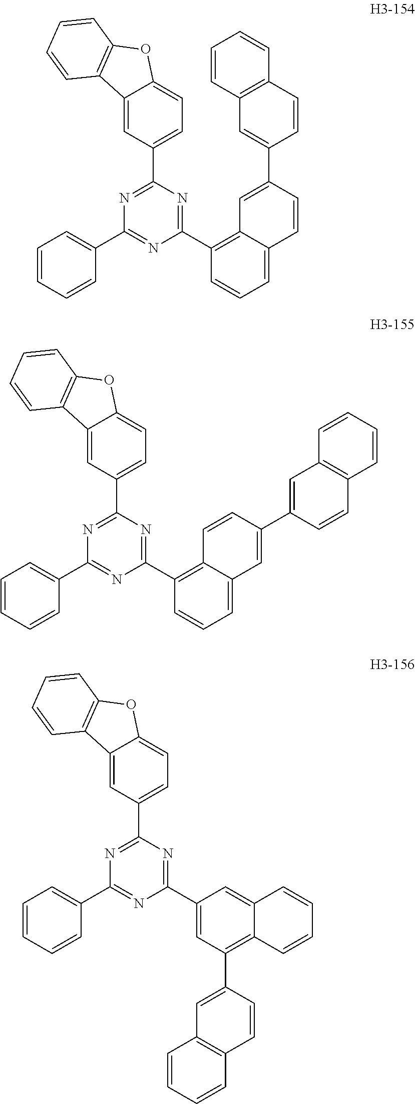 [SMILES: c1ccc(-c2nc(-c3ccc4oc5ccccc5c4c3)nc(-c3cccc4ccc(-c5ccc6ccccc6c5)cc34)n2)cc1 ; c1ccc(-c2nc(-c3ccc4oc5ccccc5c4c3)nc(-c3cccc4cc(-c5ccc6ccccc6c5)ccc34)n2)cc1 ; c1ccc(-c2nc(-c3cc(-c4ccc5ccccc5c4)c4ccccc4c3)nc(-c3ccc4oc5ccccc5c4c3)n2)cc1] 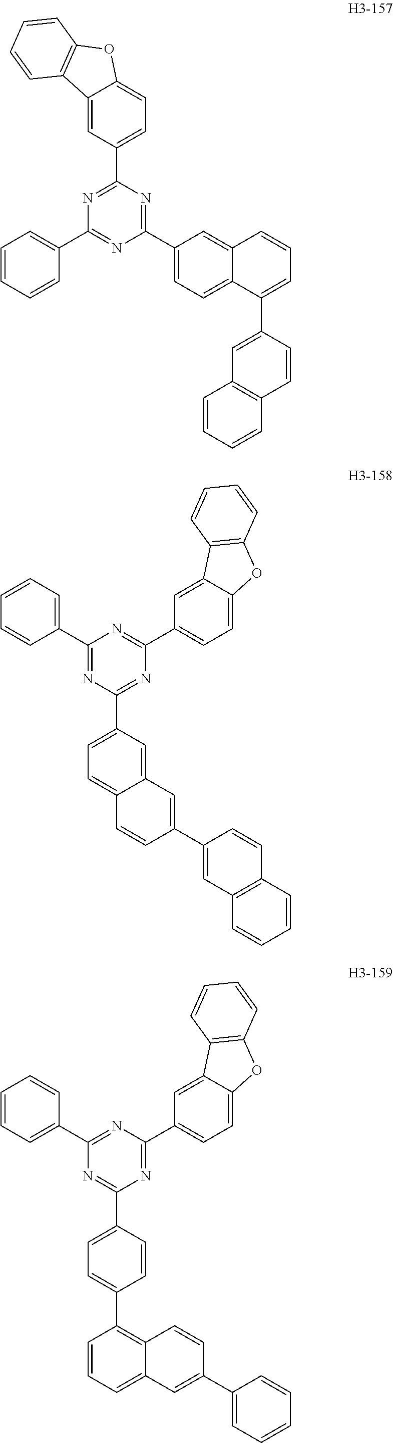 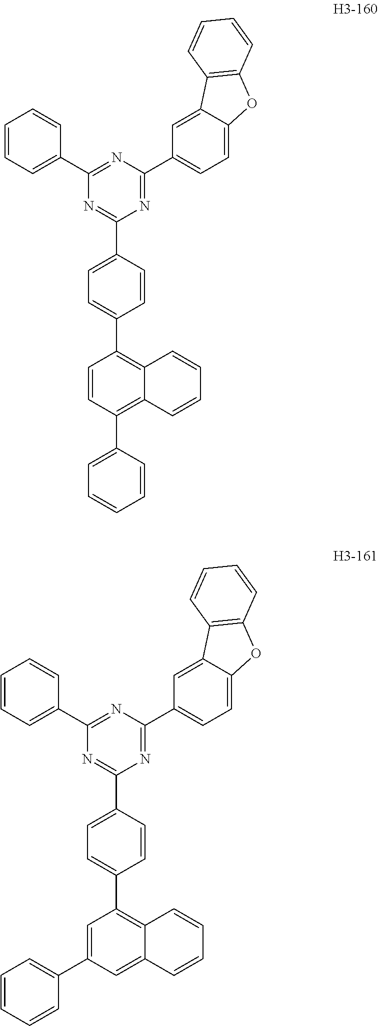 [SMILES: c1ccc(-c2nc(-c3ccc(-c4ccc(-c5ccccc5)c5ccccc45)cc3)nc(-c3ccc4oc5ccccc5c4c3)n2)cc1 ; c1ccc(-c2cc(-c3ccc(-c4nc(-c5ccccc5)nc(-c5ccc6oc7ccccc7c6c5)n4)cc3)c3ccccc3c2)cc1] 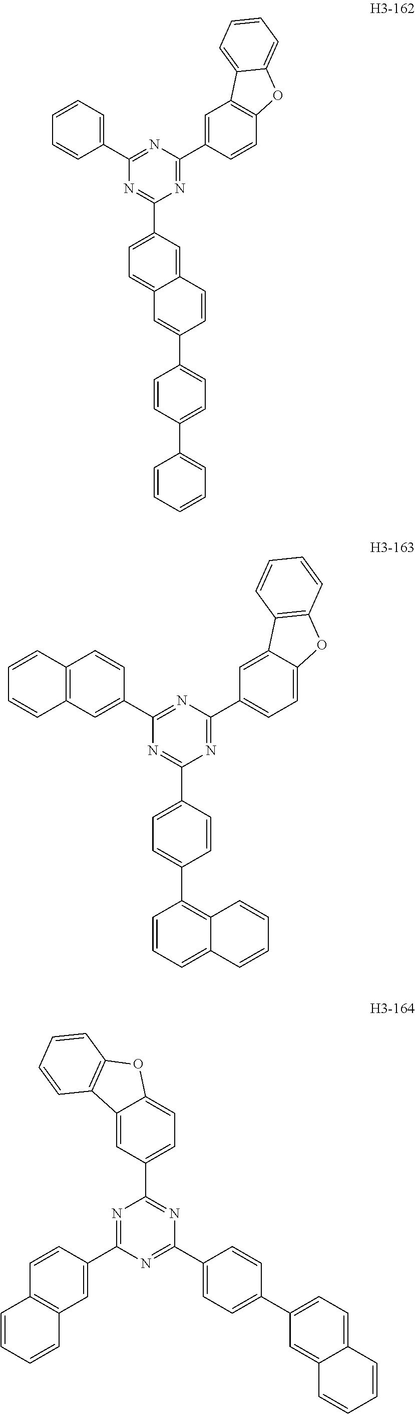 [SMILES: c1ccc(-c2ccc(-c3ccc4cc(-c5nc(-c6ccccc6)nc(-c6ccc7oc8ccccc8c7c6)n5)ccc4c3)cc2)cc1 ; c1ccc2cc(-c3nc(-c4ccc(-c5cccc6ccccc56)cc4)nc(-c4ccc5oc6ccccc6c5c4)n3)ccc2c1 ; c1ccc2cc(-c3ccc(-c4nc(-c5ccc6ccccc6c5)nc(-c5ccc6oc7ccccc7c6c5)n4)cc3)ccc2c1] 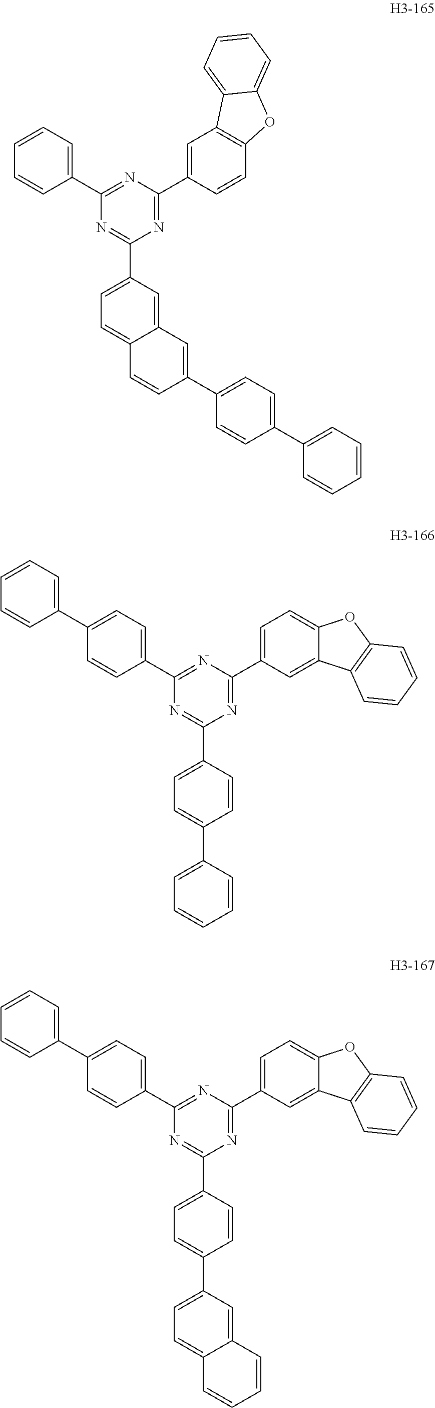 [SMILES: c1ccc(-c2ccc(-c3ccc4ccc(-c5nc(-c6ccccc6)nc(-c6ccc7oc8ccccc8c7c6)n5)cc4c3)cc2)cc1 ; c1ccc(-c2ccc(-c3nc(-c4ccc(-c5ccccc5)cc4)nc(-c4ccc5oc6ccccc6c5c4)n3)cc2)cc1 ; c1ccc(-c2ccc(-c3nc(-c4ccc(-c5ccc6ccccc6c5)cc4)nc(-c4ccc5oc6ccccc6c5c4)n3)cc2)cc1] 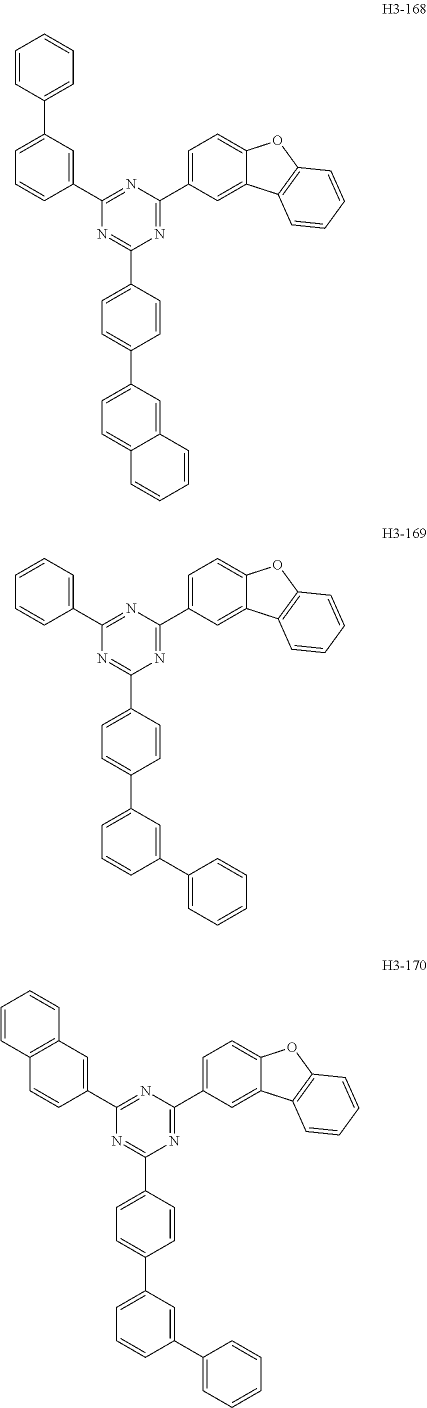 [SMILES: c1ccc(-c2cccc(-c3nc(-c4ccc(-c5ccc6ccccc6c5)cc4)nc(-c4ccc5oc6ccccc6c5c4)n3)c2)cc1 ; c1ccc(-c2cccc(-c3ccc(-c4nc(-c5ccccc5)nc(-c5ccc6oc7ccccc7c6c5)n4)cc3)c2)cc1 ; c1ccc(-c2cccc(-c3ccc(-c4nc(-c5ccc6ccccc6c5)nc(-c5ccc6oc7ccccc7c6c5)n4)cc3)c2)cc1] 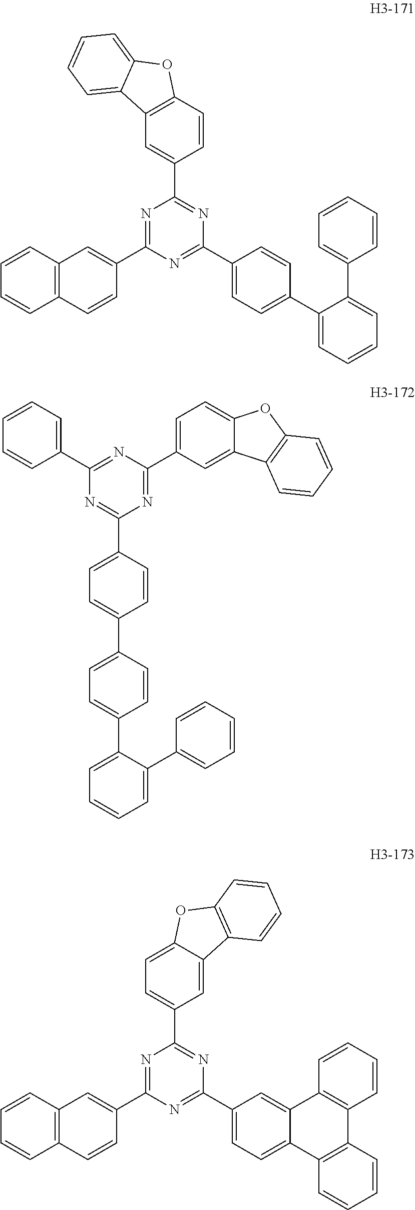 [SMILES: c1ccc(-c2ccccc2-c2ccc(-c3nc(-c4ccc5ccccc5c4)nc(-c4ccc5oc6ccccc6c5c4)n3)cc2)cc1 ; c1ccc(-c2nc(-c3ccc(-c4ccc(-c5ccccc5-c5ccccc5)cc4)cc3)nc(-c3ccc4oc5ccccc5c4c3)n2)cc1 ; c1ccc2cc(-c3nc(-c4ccc5oc6ccccc6c5c4)nc(-c4ccc5c6ccccc6c6ccccc6c5c4)n3)ccc2c1] 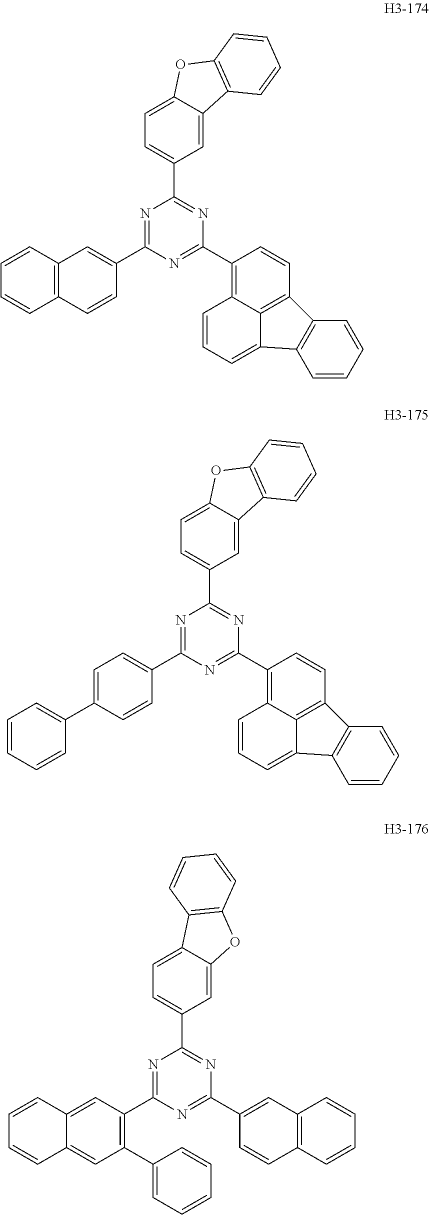 [SMILES: c1ccc2c(c1)-c1cccc3c(-c4nc(-c5ccc6ccccc6c5)nc(-c5ccc6oc7ccccc7c6c5)n4)ccc-2c13 ; c1ccc(-c2ccc(-c3nc(-c4ccc5oc6ccccc6c5c4)nc(-c4ccc5c6c(cccc46)-c4ccccc4-5)n3)cc2)cc1 ; c1ccc(-c2cc3ccccc3cc2-c2nc(-c3ccc4ccccc4c3)nc(-c3ccc4c(c3)oc3ccccc34)n2)cc1] 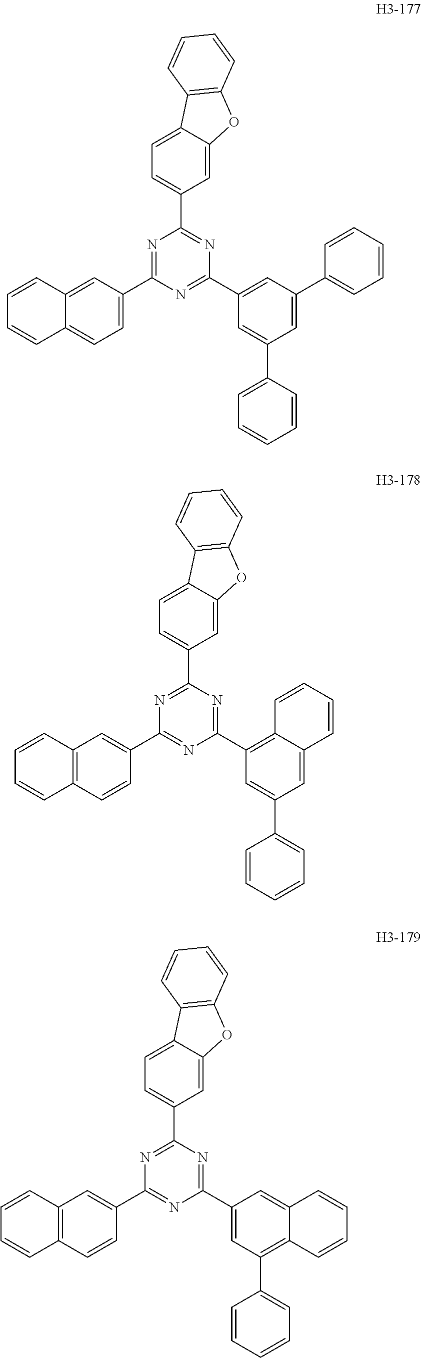 [SMILES: c1ccc(-c2cc(-c3ccccc3)cc(-c3nc(-c4ccc5ccccc5c4)nc(-c4ccc5c(c4)oc4ccccc45)n3)c2)cc1 ; c1ccc(-c2cc(-c3nc(-c4ccc5ccccc5c4)nc(-c4ccc5c(c4)oc4ccccc45)n3)c3ccccc3c2)cc1 ; c1ccc(-c2cc(-c3nc(-c4ccc5ccccc5c4)nc(-c4ccc5c(c4)oc4ccccc45)n3)cc3ccccc23)cc1] 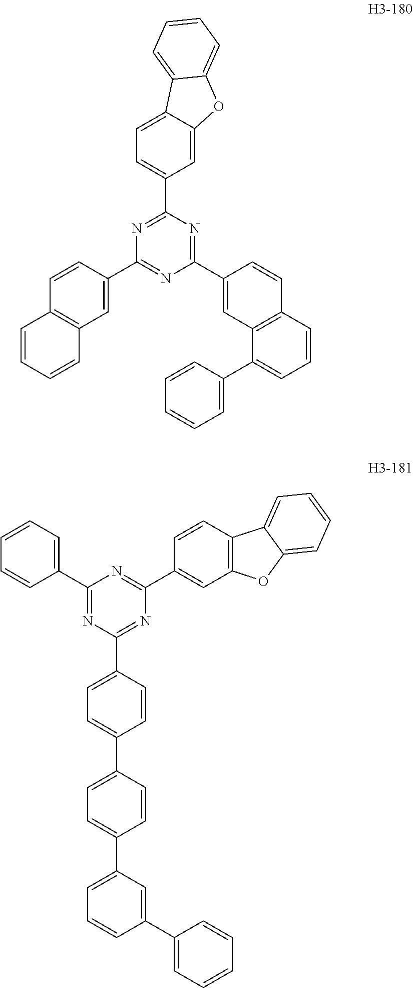 [SMILES: c1ccc(-c2cccc3ccc(-c4nc(-c5ccc6ccccc6c5)nc(-c5ccc6c(c5)oc5ccccc56)n4)cc23)cc1 ; c1ccc(-c2cccc(-c3ccc(-c4ccc(-c5nc(-c6ccccc6)nc(-c6ccc7c(c6)oc6ccccc67)n5)cc4)cc3)c2)cc1] 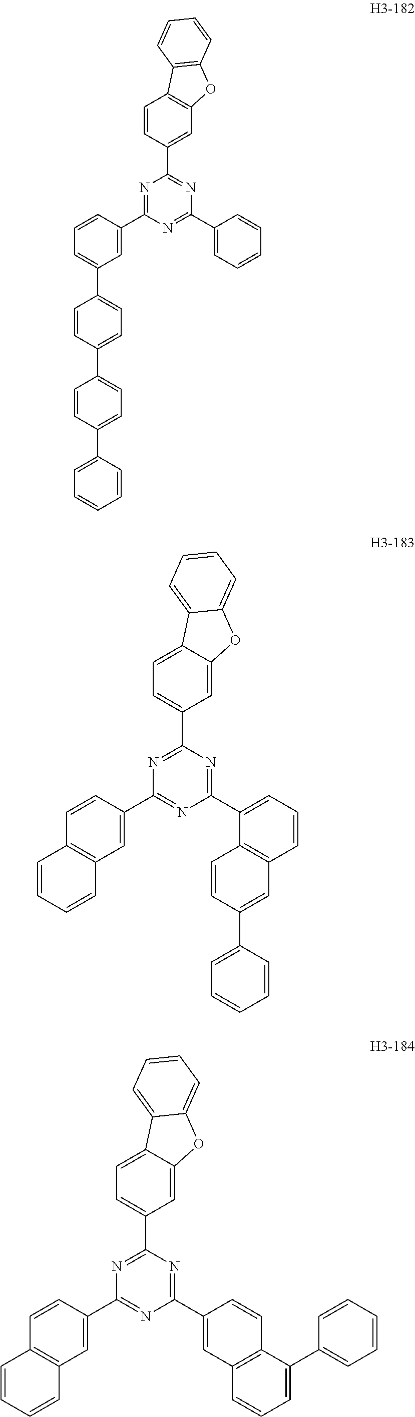 [SMILES: c1ccc(-c2ccc(-c3ccc(-c4cccc(-c5nc(-c6ccccc6)nc(-c6ccc7c(c6)oc6ccccc67)n5)c4)cc3)cc2)cc1 ; c1ccc(-c2ccc3c(-c4nc(-c5ccc6ccccc6c5)nc(-c5ccc6c(c5)oc5ccccc56)n4)cccc3c2)cc1 ; c1ccc(-c2cccc3cc(-c4nc(-c5ccc6ccccc6c5)nc(-c5ccc6c(c5)oc5ccccc56)n4)ccc23)cc1] 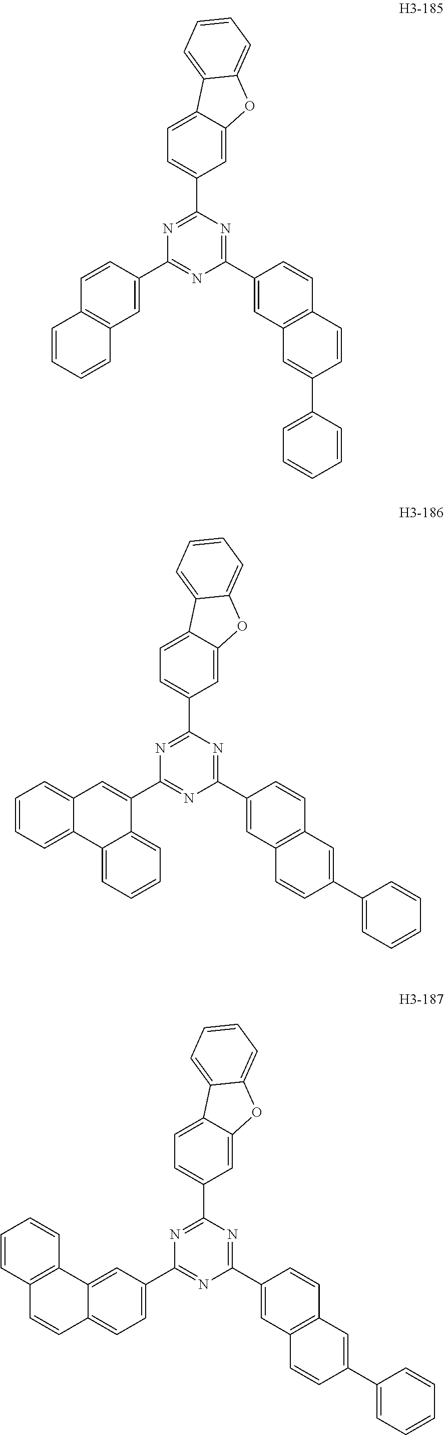 [SMILES: c1ccc(-c2ccc3ccc(-c4nc(-c5ccc6ccccc6c5)nc(-c5ccc6c(c5)oc5ccccc56)n4)cc3c2)cc1 ; c1ccc(-c2ccc3cc(-c4nc(-c5ccc6c(c5)oc5ccccc56)nc(-c5cc6ccccc6c6ccccc56)n4)ccc3c2)cc1 ; c1ccc(-c2ccc3cc(-c4nc(-c5ccc6c(c5)oc5ccccc56)nc(-c5ccc6ccc7ccccc7c6c5)n4)ccc3c2)cc1] 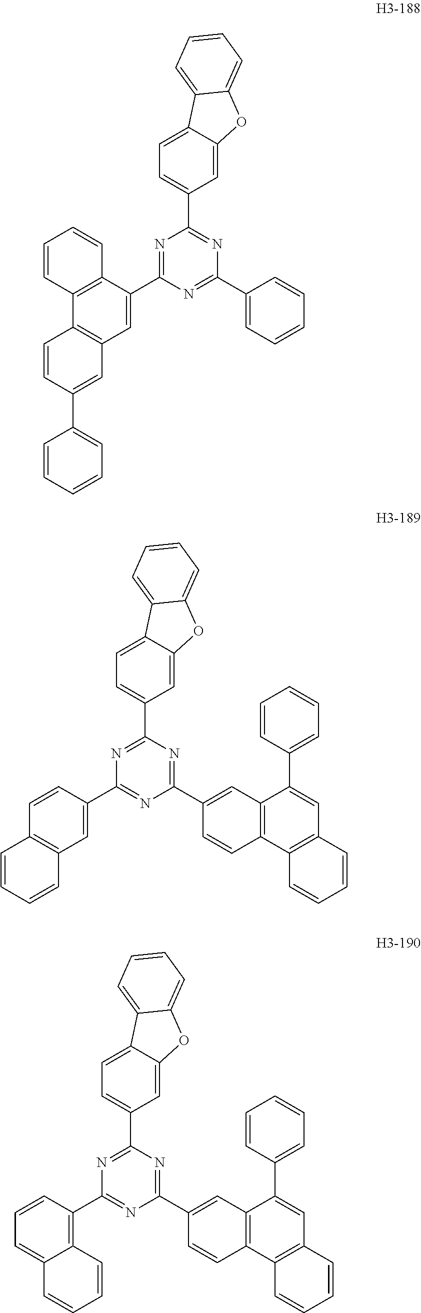 [SMILES: c1ccc(-c2ccc3c(c2)cc(-c2nc(-c4ccccc4)nc(-c4ccc5c(c4)oc4ccccc45)n2)c2ccccc23)cc1 ; c1ccc(-c2cc3ccccc3c3ccc(-c4nc(-c5ccc6ccccc6c5)nc(-c5ccc6c(c5)oc5ccccc56)n4)cc23)cc1 ; c1ccc(-c2cc3ccccc3c3ccc(-c4nc(-c5ccc6c(c5)oc5ccccc56)nc(-c5cccc6ccccc56)n4)cc23)cc1] 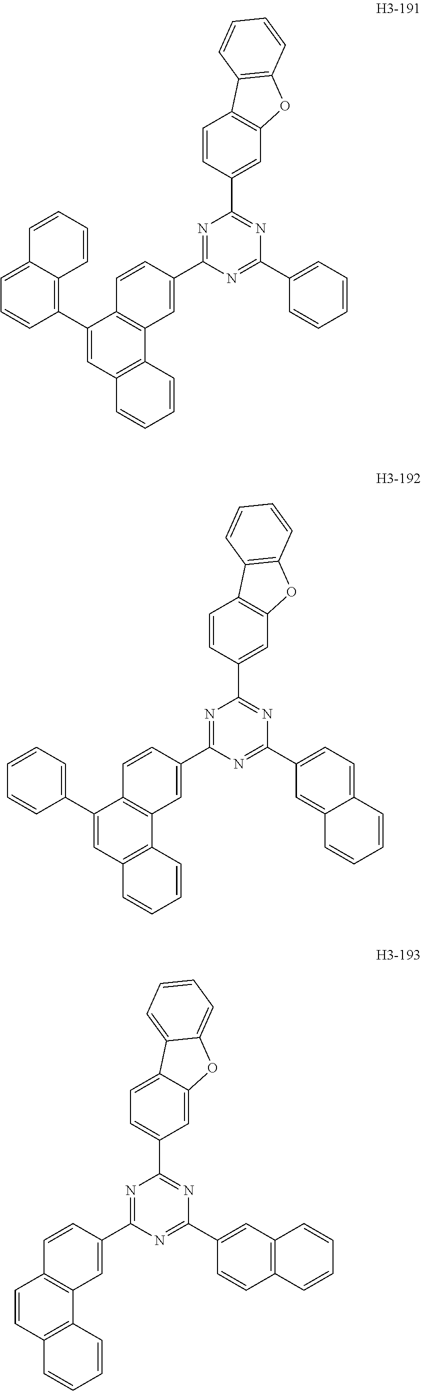 [SMILES: c1ccc(-c2nc(-c3ccc4c(c3)oc3ccccc34)nc(-c3ccc4c(-c5cccc6ccccc56)cc5ccccc5c4c3)n2)cc1 ; c1ccc(-c2cc3ccccc3c3cc(-c4nc(-c5ccc6ccccc6c5)nc(-c5ccc6c(c5)oc5ccccc56)n4)ccc23)cc1 ; c1ccc2cc(-c3nc(-c4ccc5c(c4)oc4ccccc45)nc(-c4ccc5ccc6ccccc6c5c4)n3)ccc2c1] 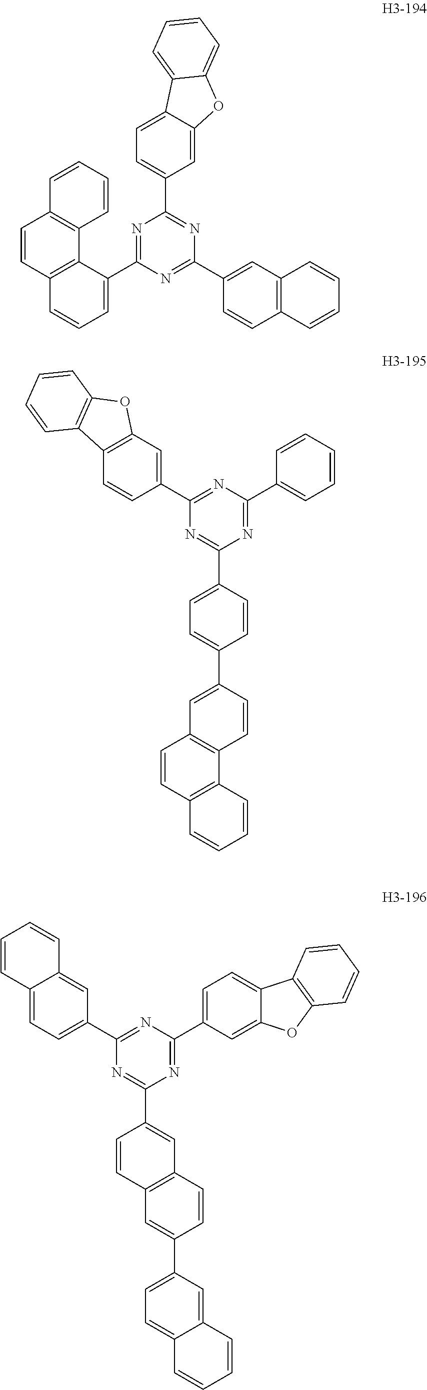 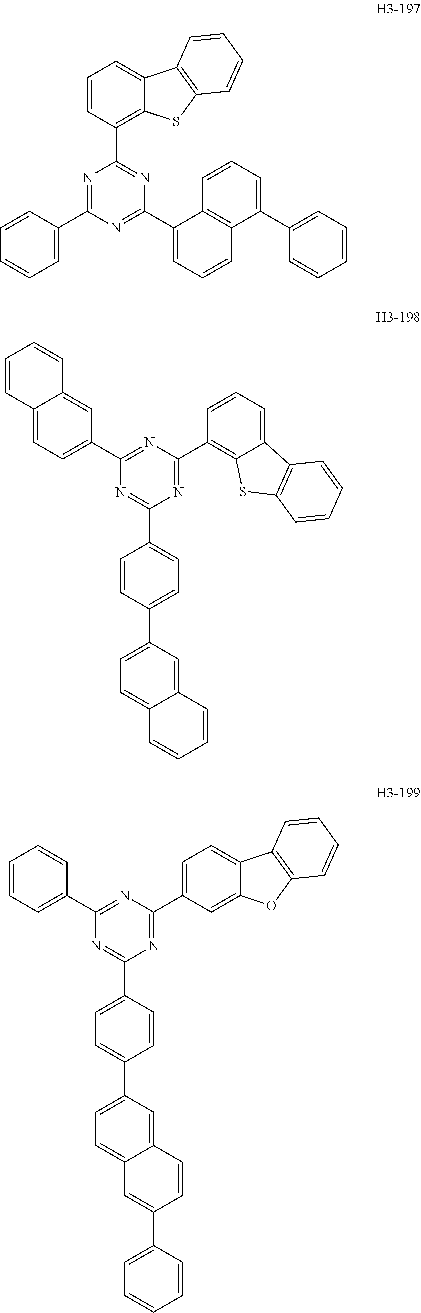 [SMILES: c1ccc(-c2nc(-c3cccc4c(-c5ccccc5)cccc34)nc(-c3cccc4c3sc3ccccc34)n2)cc1 ; c1ccc2cc(-c3ccc(-c4nc(-c5ccc6ccccc6c5)nc(-c5cccc6c5sc5ccccc56)n4)cc3)ccc2c1 ; c1ccc(-c2ccc3cc(-c4ccc(-c5nc(-c6ccccc6)nc(-c6ccc7c(c6)oc6ccccc67)n5)cc4)ccc3c2)cc1] 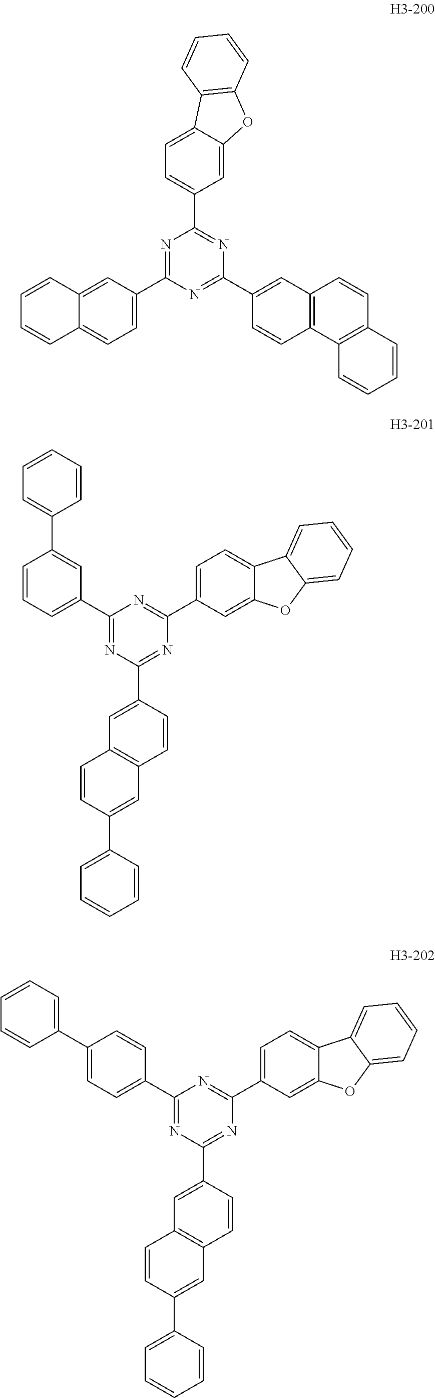 [SMILES: c1ccc2cc(-c3nc(-c4ccc5c(ccc6ccccc65)c4)nc(-c4ccc5c(c4)oc4ccccc45)n3)ccc2c1 ; c1ccc(-c2cccc(-c3nc(-c4ccc5cc(-c6ccccc6)ccc5c4)nc(-c4ccc5c(c4)oc4ccccc45)n3)c2)cc1 ; c1ccc(-c2ccc(-c3nc(-c4ccc5cc(-c6ccccc6)ccc5c4)nc(-c4ccc5c(c4)oc4ccccc45)n3)cc2)cc1] 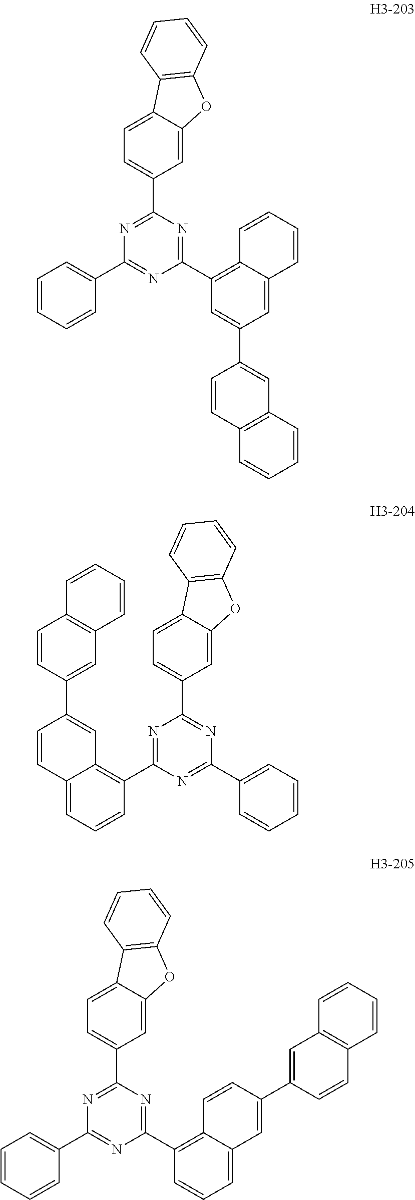 [SMILES: c1ccc(-c2nc(-c3ccc4c(c3)oc3ccccc34)nc(-c3cc(-c4ccc5ccccc5c4)cc4ccccc34)n2)cc1 ; c1ccc(-c2nc(-c3ccc4c(c3)oc3ccccc34)nc(-c3cccc4ccc(-c5ccc6ccccc6c5)cc34)n2)cc1 ; c1ccc(-c2nc(-c3ccc4c(c3)oc3ccccc34)nc(-c3cccc4cc(-c5ccc6ccccc6c5)ccc34)n2)cc1] 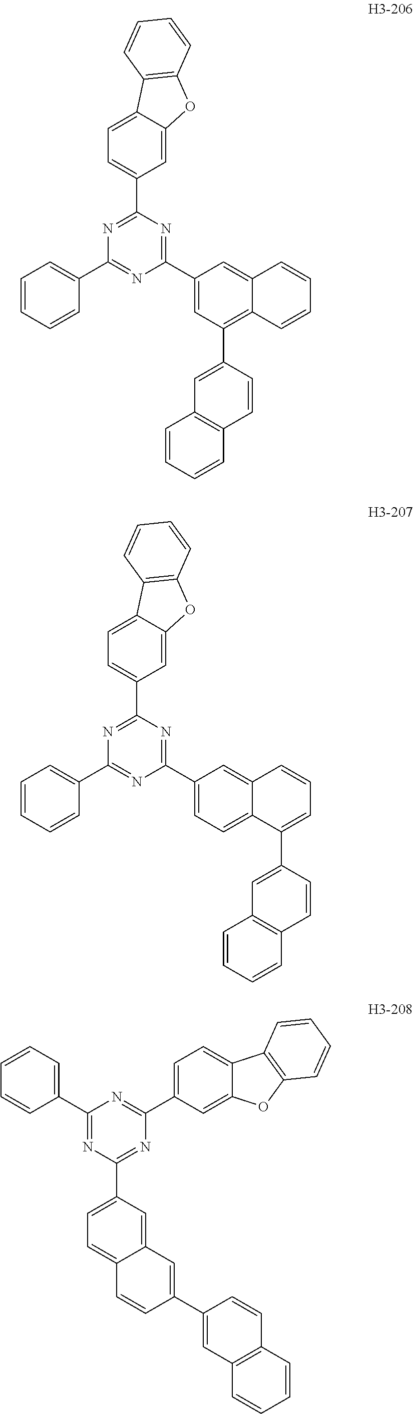 [SMILES: c1ccc(-c2nc(-c3cc(-c4ccc5ccccc5c4)c4ccccc4c3)nc(-c3ccc4c(c3)oc3ccccc34)n2)cc1 ; c1ccc(-c2nc(-c3ccc4c(-c5ccc6ccccc6c5)cccc4c3)nc(-c3ccc4c(c3)oc3ccccc34)n2)cc1 ; c1ccc(-c2nc(-c3ccc4ccc(-c5ccc6ccccc6c5)cc4c3)nc(-c3ccc4c(c3)oc3ccccc34)n2)cc1] 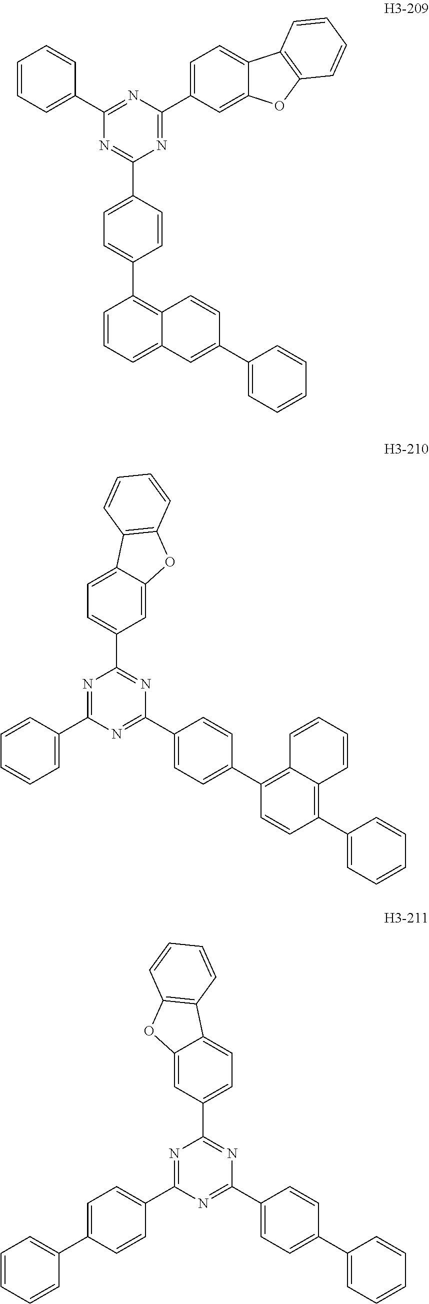 [SMILES: c1ccc(-c2ccc3c(-c4ccc(-c5nc(-c6ccccc6)nc(-c6ccc7c(c6)oc6ccccc67)n5)cc4)cccc3c2)cc1 ; c1ccc(-c2nc(-c3ccc(-c4ccc(-c5ccccc5)c5ccccc45)cc3)nc(-c3ccc4c(c3)oc3ccccc34)n2)cc1 ; c1ccc(-c2ccc(-c3nc(-c4ccc(-c5ccccc5)cc4)nc(-c4ccc5c(c4)oc4ccccc45)n3)cc2)cc1] 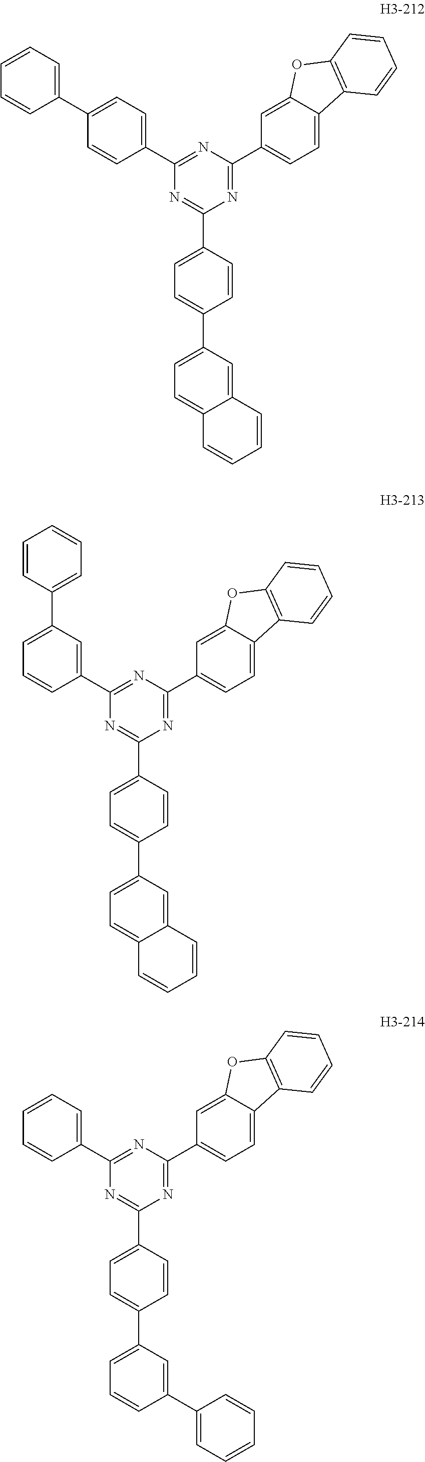 [SMILES: c1ccc(-c2ccc(-c3nc(-c4ccc(-c5ccc6ccccc6c5)cc4)nc(-c4ccc5c(c4)oc4ccccc45)n3)cc2)cc1 ; c1ccc(-c2cccc(-c3nc(-c4ccc(-c5ccc6ccccc6c5)cc4)nc(-c4ccc5c(c4)oc4ccccc45)n3)c2)cc1 ; c1ccc(-c2cccc(-c3ccc(-c4nc(-c5ccccc5)nc(-c5ccc6c(c5)oc5ccccc56)n4)cc3)c2)cc1] 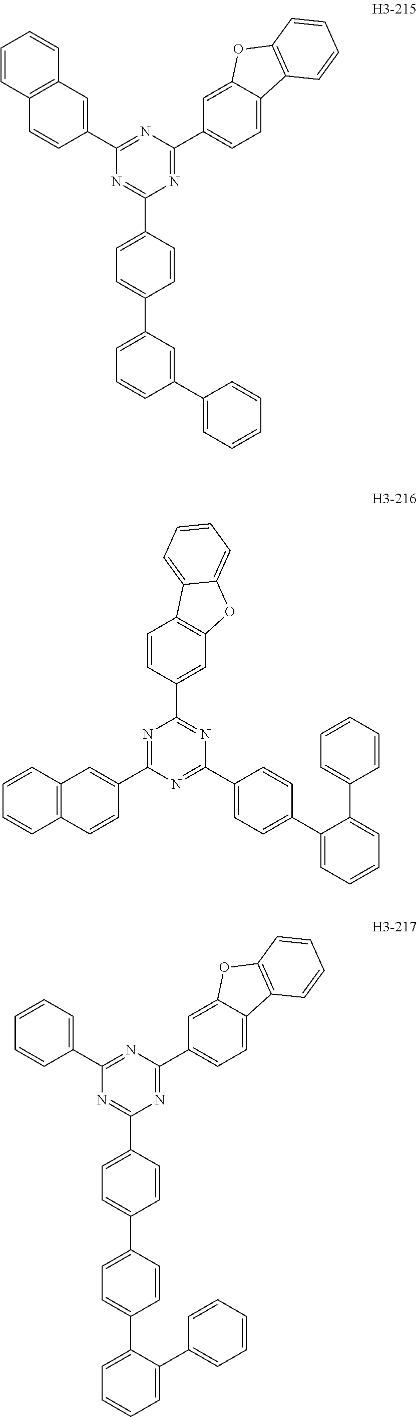 [SMILES: c1ccc(-c2cccc(-c3ccc(-c4nc(-c5ccc6ccccc6c5)nc(-c5ccc6c(c5)oc5ccccc56)n4)cc3)c2)cc1 ; c1ccc(-c2ccccc2-c2ccc(-c3nc(-c4ccc5ccccc5c4)nc(-c4ccc5c(c4)oc4ccccc45)n3)cc2)cc1 ; c1ccc(-c2nc(-c3ccc(-c4ccc(-c5ccccc5-c5ccccc5)cc4)cc3)nc(-c3ccc4c(c3)oc3ccccc34)n2)cc1] 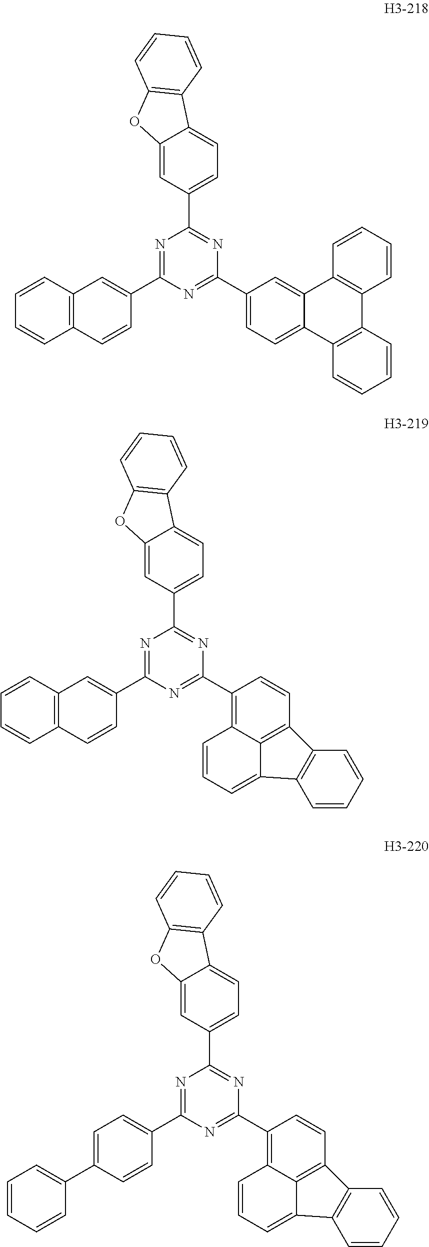 [SMILES: c1ccc2cc(-c3nc(-c4ccc5c(c4)oc4ccccc45)nc(-c4ccc5c6ccccc6c6ccccc6c5c4)n3)ccc2c1 ; c1ccc2c(c1)-c1cccc3c(-c4nc(-c5ccc6ccccc6c5)nc(-c5ccc6c(c5)oc5ccccc56)n4)ccc-2c13 ; c1ccc(-c2ccc(-c3nc(-c4ccc5c(c4)oc4ccccc45)nc(-c4ccc5c6c(cccc46)-c4ccccc4-5)n3)cc2)cc1] 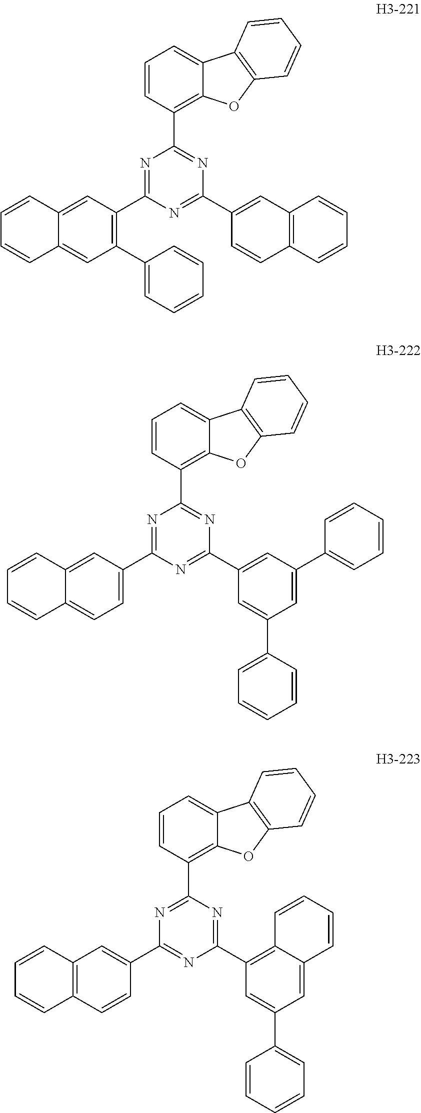 [SMILES: c1ccc(-c2cc3ccccc3cc2-c2nc(-c3ccc4ccccc4c3)nc(-c3cccc4c3oc3ccccc34)n2)cc1 ; c1ccc(-c2cc(-c3ccccc3)cc(-c3nc(-c4ccc5ccccc5c4)nc(-c4cccc5c4oc4ccccc45)n3)c2)cc1 ; c1ccc(-c2cc(-c3nc(-c4ccc5ccccc5c4)nc(-c4cccc5c4oc4ccccc45)n3)c3ccccc3c2)cc1] 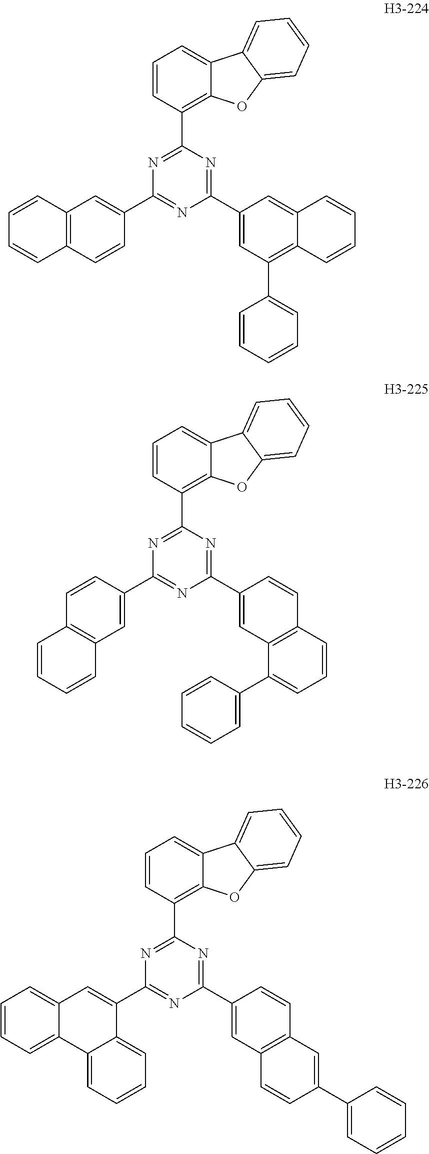 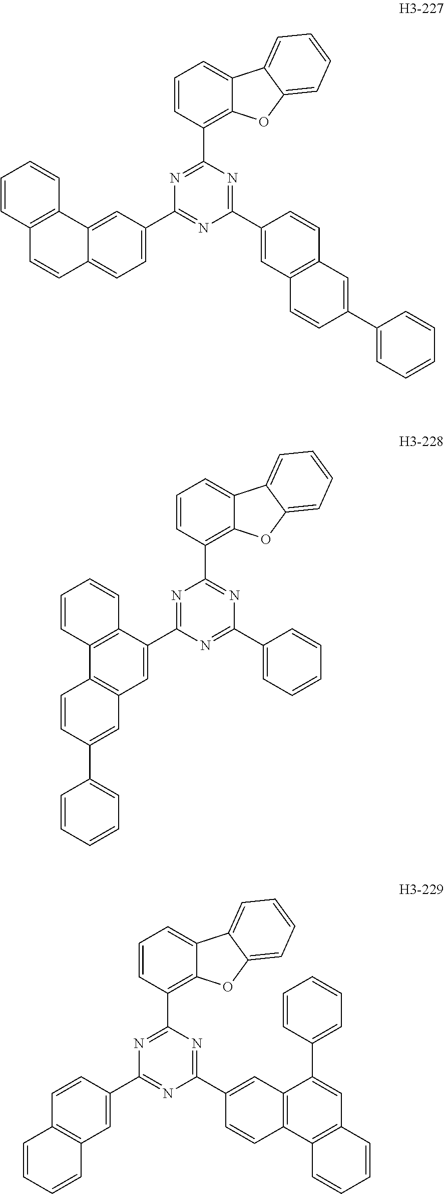 [SMILES: c1ccc(-c2ccc3cc(-c4nc(-c5ccc6ccc7ccccc7c6c5)nc(-c5cccc6c5oc5ccccc56)n4)ccc3c2)cc1 ; c1ccc(-c2ccc3c(c2)cc(-c2nc(-c4ccccc4)nc(-c4cccc5c4oc4ccccc45)n2)c2ccccc23)cc1 ; c1ccc(-c2cc3ccccc3c3ccc(-c4nc(-c5ccc6ccccc6c5)nc(-c5cccc6c5oc5ccccc56)n4)cc23)cc1] 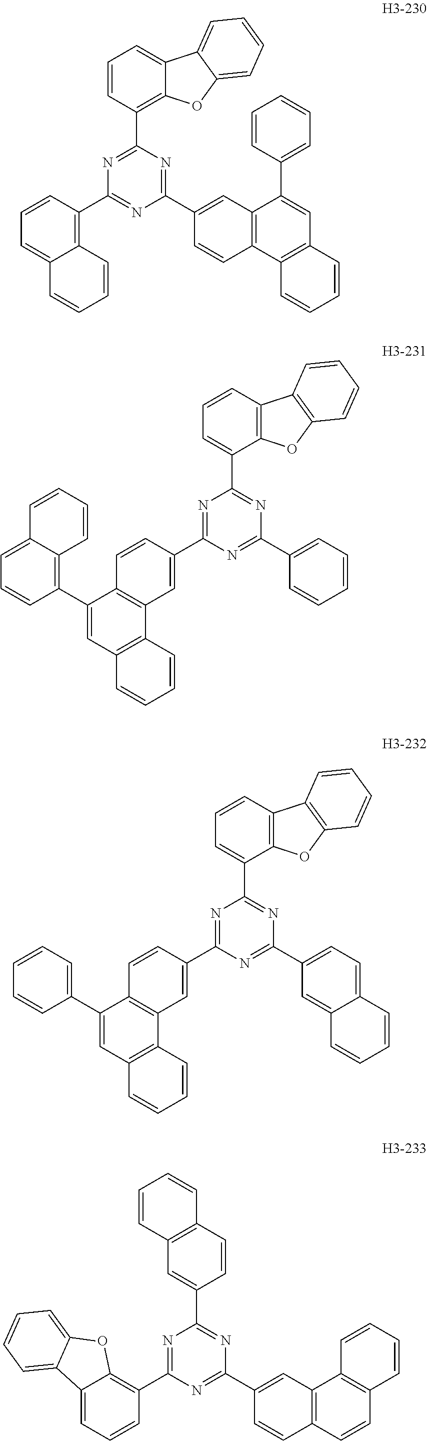 [SMILES: c1ccc(-c2cc3ccccc3c3ccc(-c4nc(-c5cccc6ccccc56)nc(-c5cccc6c5oc5ccccc56)n4)cc23)cc1 ; c1ccc(-c2nc(-c3ccc4c(-c5cccc6ccccc56)cc5ccccc5c4c3)nc(-c3cccc4c3oc3ccccc34)n2)cc1 ; c1ccc(-c2cc3ccccc3c3cc(-c4nc(-c5ccc6ccccc6c5)nc(-c5cccc6c5oc5ccccc56)n4)ccc23)cc1 ; c1ccc2cc(-c3nc(-c4ccc5ccc6ccccc6c5c4)nc(-c4cccc5c4oc4ccccc45)n3)ccc2c1] 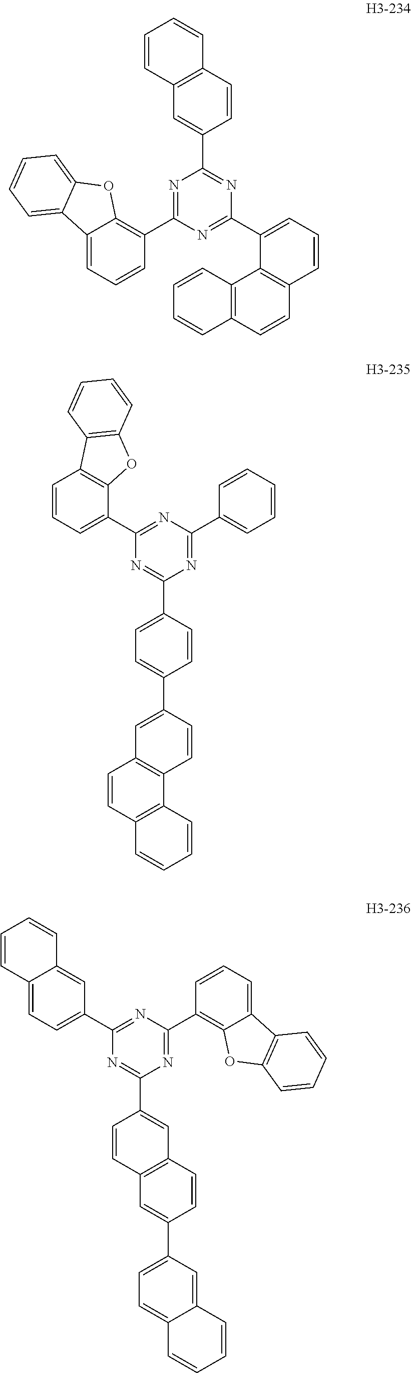 [SMILES: c1ccc2cc(-c3nc(-c4cccc5c4oc4ccccc45)nc(-c4cccc5ccc6ccccc6c45)n3)ccc2c1 ; c1ccc(-c2nc(-c3ccc(-c4ccc5c(ccc6ccccc65)c4)cc3)nc(-c3cccc4c3oc3ccccc34)n2)cc1 ; c1ccc2cc(-c3ccc4cc(-c5nc(-c6ccc7ccccc7c6)nc(-c6cccc7c6oc6ccccc67)n5)ccc4c3)ccc2c1] 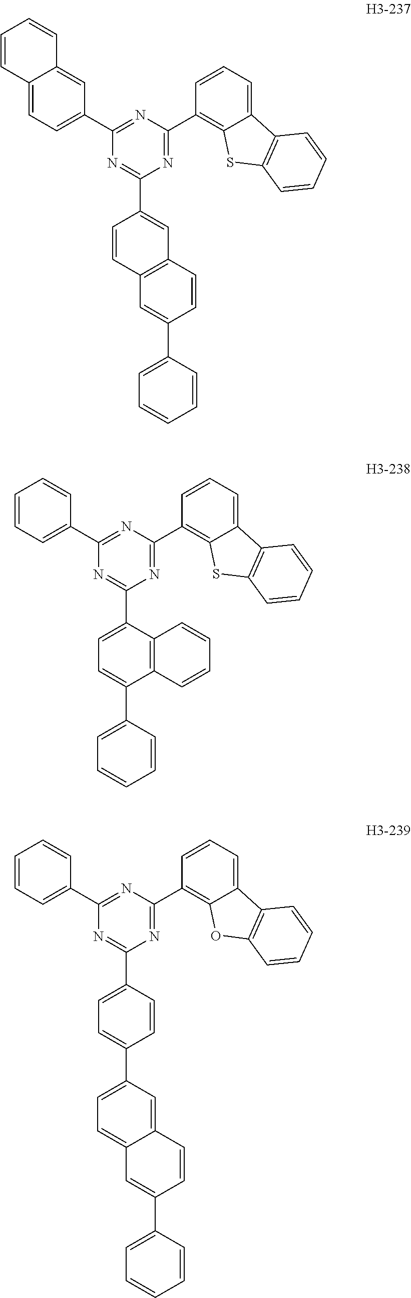 [SMILES: c1ccc(-c2ccc3cc(-c4nc(-c5ccc6ccccc6c5)nc(-c5cccc6c5sc5ccccc56)n4)ccc3c2)cc1 ; c1ccc(-c2nc(-c3ccc(-c4ccccc4)c4ccccc34)nc(-c3cccc4c3sc3ccccc34)n2)cc1 ; c1ccc(-c2ccc3cc(-c4ccc(-c5nc(-c6ccccc6)nc(-c6cccc7c6oc6ccccc67)n5)cc4)ccc3c2)cc1] 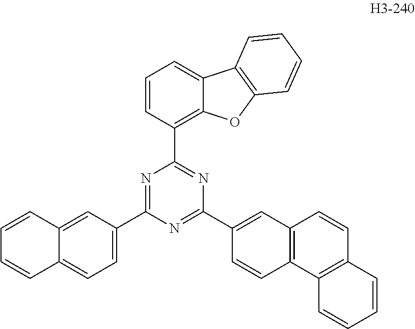 [SMILES: c1ccc2cc(-c3nc(-c4ccc5c(ccc6ccccc65)c4)nc(-c4cccc5c4oc4ccccc45)n3)ccc2c1] 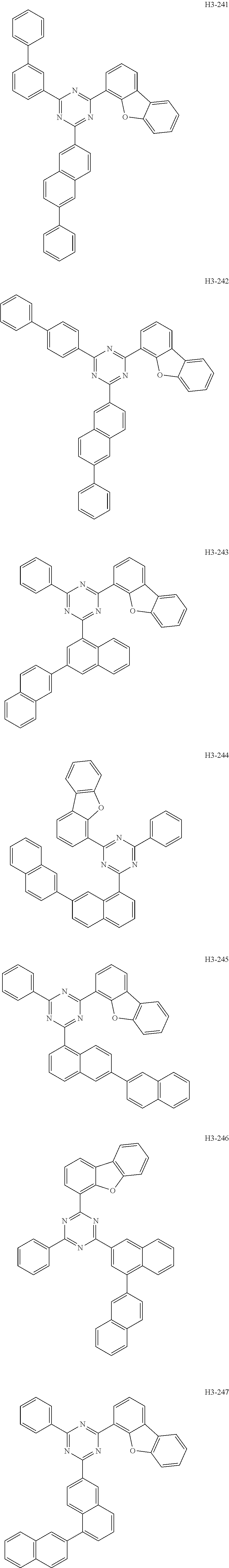 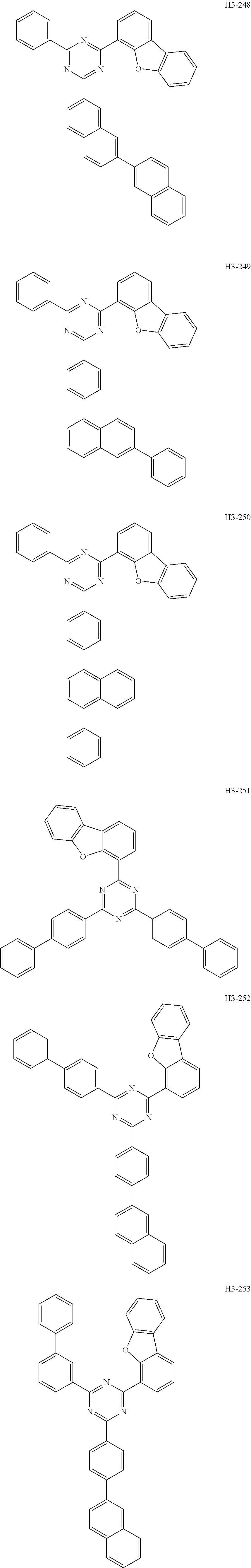 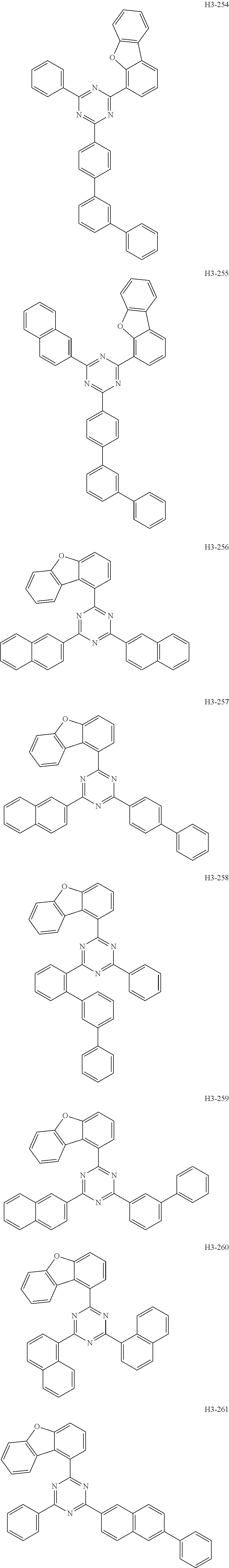 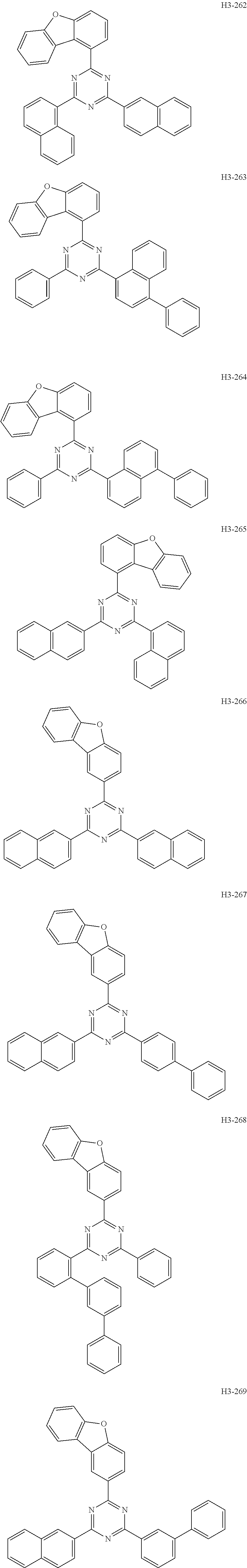 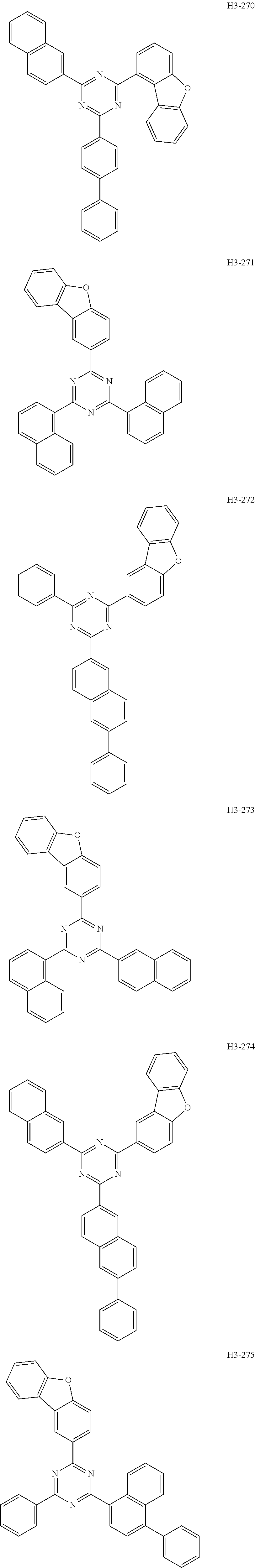 [SMILES: c1ccc(-c2ccc(-c3nc(-c4ccc5ccccc5c4)nc(-c4cccc5oc6ccccc6c45)n3)cc2)cc1 ; c1ccc2c(-c3nc(-c4ccc5oc6ccccc6c5c4)nc(-c4cccc5ccccc45)n3)cccc2c1 ; c1ccc(-c2ccc3cc(-c4nc(-c5ccccc5)nc(-c5ccc6oc7ccccc7c6c5)n4)ccc3c2)cc1 ; c1ccc2cc(-c3nc(-c4ccc5oc6ccccc6c5c4)nc(-c4cccc5ccccc45)n3)ccc2c1 ; c1ccc(-c2ccc3cc(-c4nc(-c5ccc6ccccc6c5)nc(-c5ccc6oc7ccccc7c6c5)n4)ccc3c2)cc1 ; c1ccc(-c2nc(-c3ccc4oc5ccccc5c4c3)nc(-c3ccc(-c4ccccc4)c4ccccc34)n2)cc1] 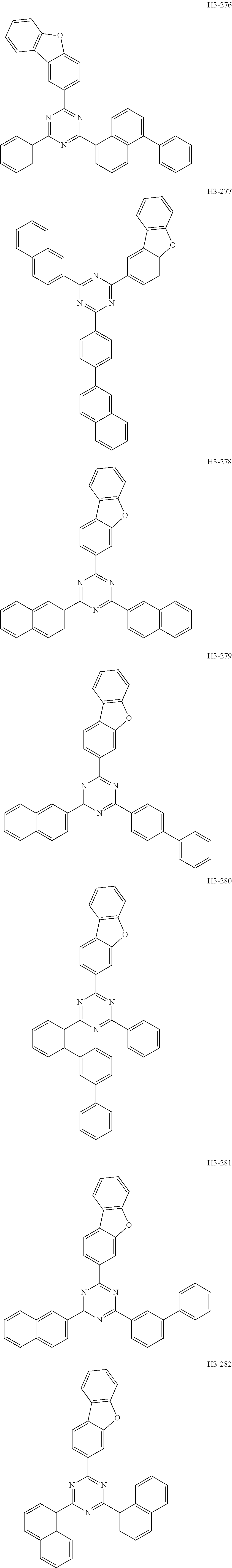 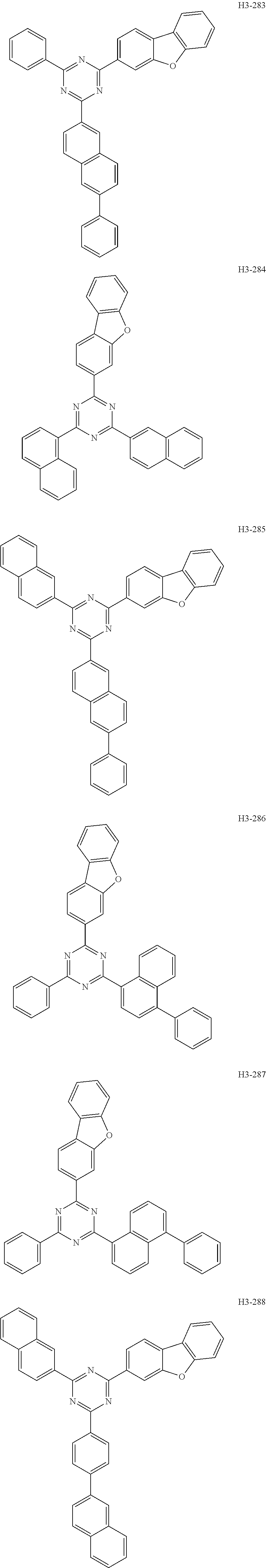 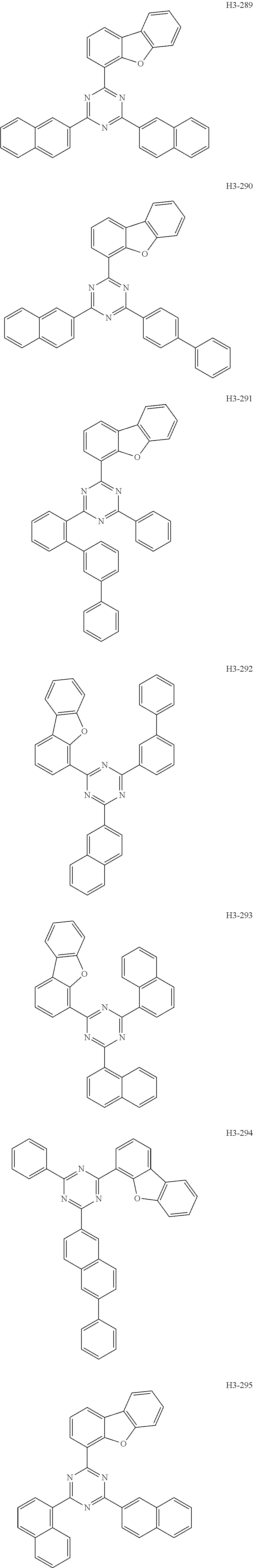 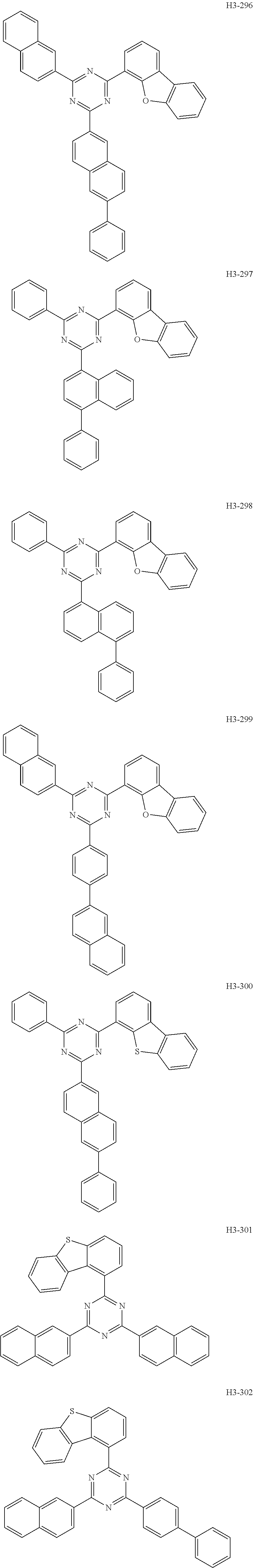 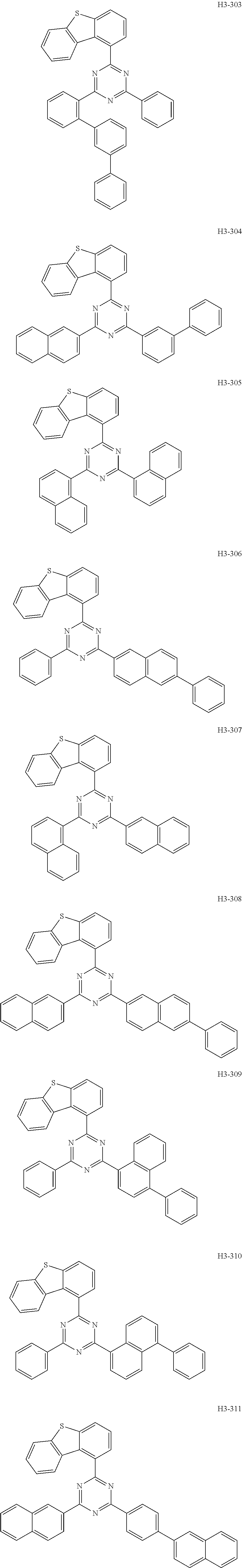 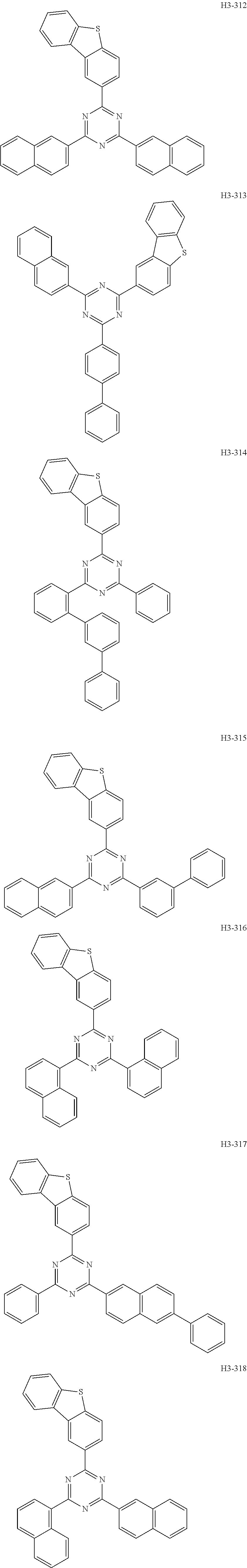 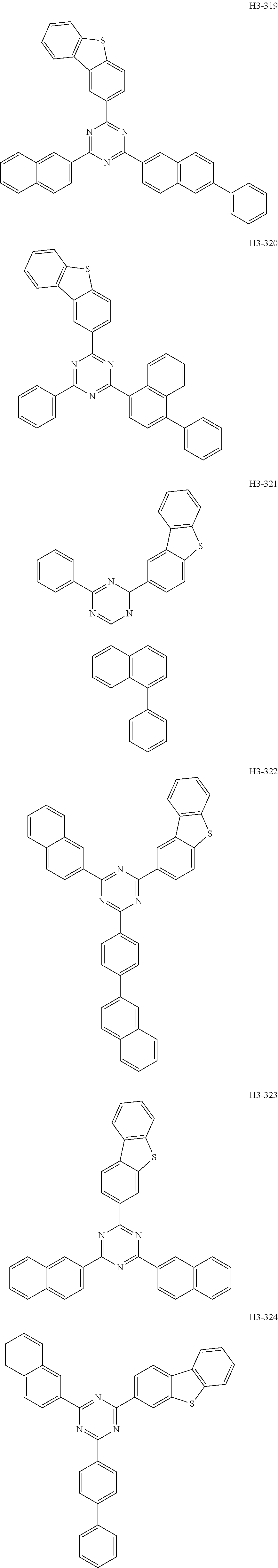 [SMILES: c1ccc(-c2ccc3cc(-c4nc(-c5ccc6ccccc6c5)nc(-c5ccc6sc7ccccc7c6c5)n4)ccc3c2)cc1 ; c1ccc(-c2nc(-c3ccc4sc5ccccc5c4c3)nc(-c3ccc(-c4ccccc4)c4ccccc34)n2)cc1 ; c1ccc(-c2nc(-c3ccc4sc5ccccc5c4c3)nc(-c3cccc4c(-c5ccccc5)cccc34)n2)cc1 ; c1ccc2cc(-c3ccc(-c4nc(-c5ccc6ccccc6c5)nc(-c5ccc6sc7ccccc7c6c5)n4)cc3)ccc2c1 ; c1ccc2cc(-c3nc(-c4ccc5ccccc5c4)nc(-c4ccc5c(c4)sc4ccccc45)n3)ccc2c1 ; c1ccc(-c2ccc(-c3nc(-c4ccc5ccccc5c4)nc(-c4ccc5c(c4)sc4ccccc45)n3)cc2)cc1] 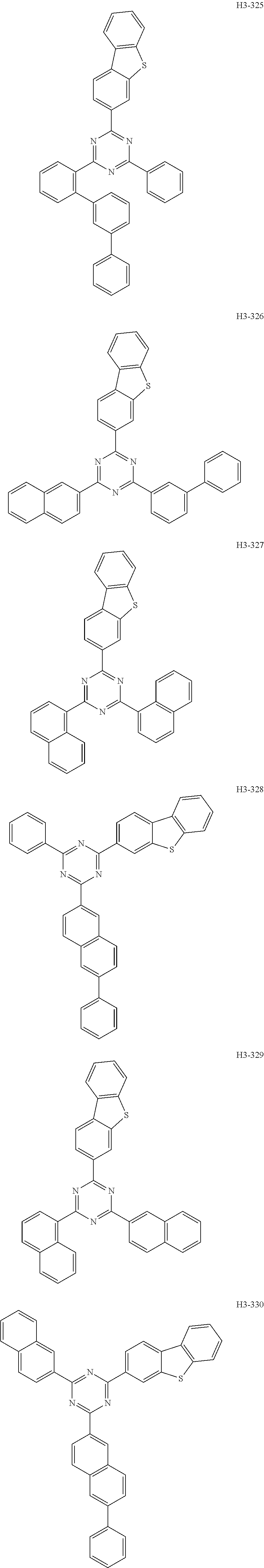 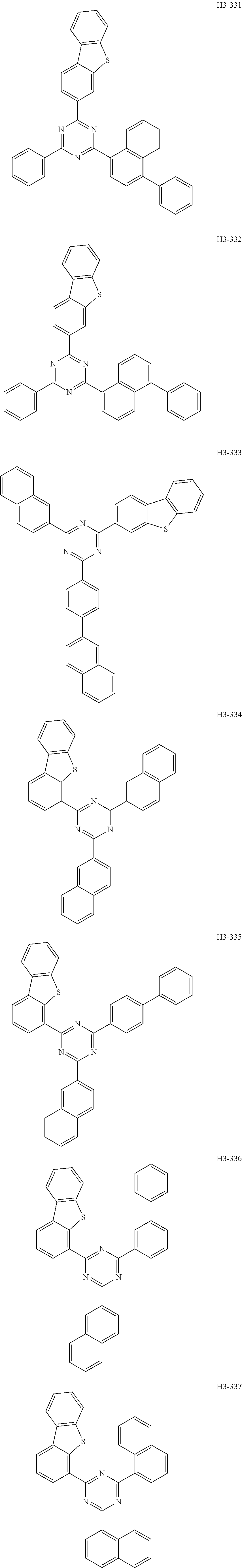 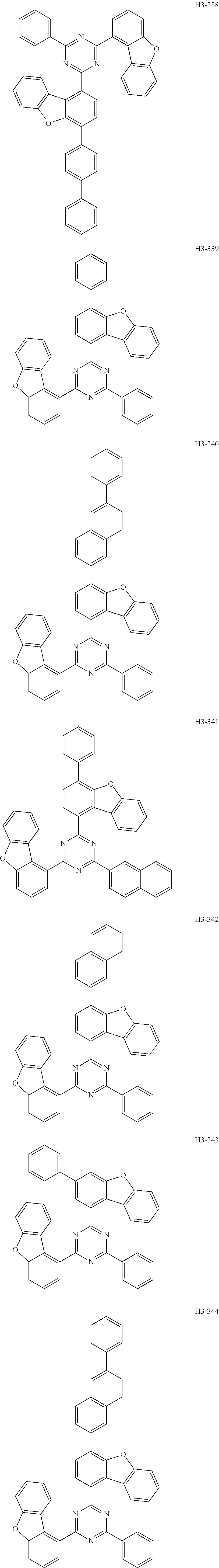 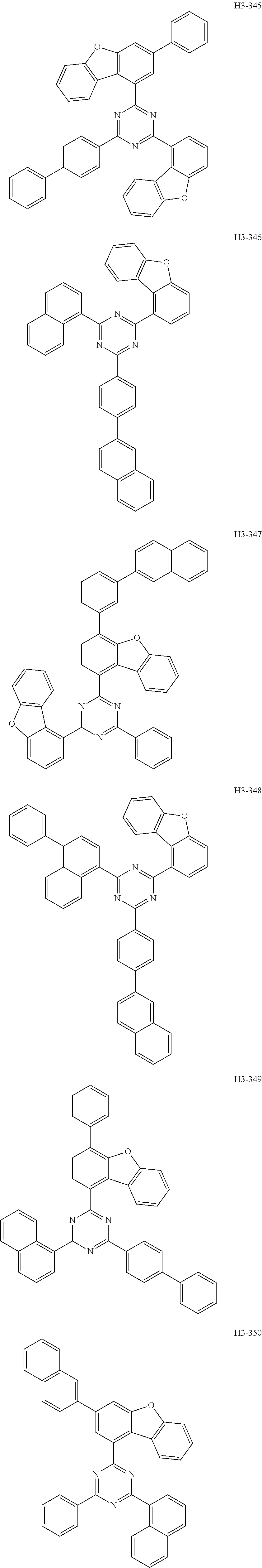 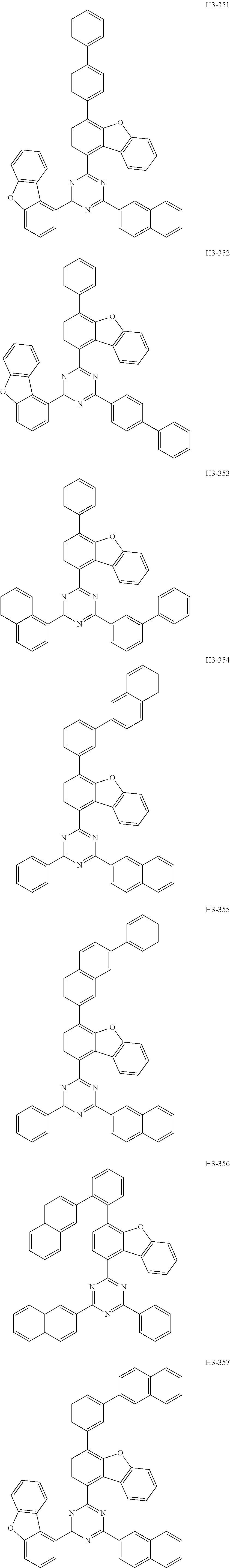 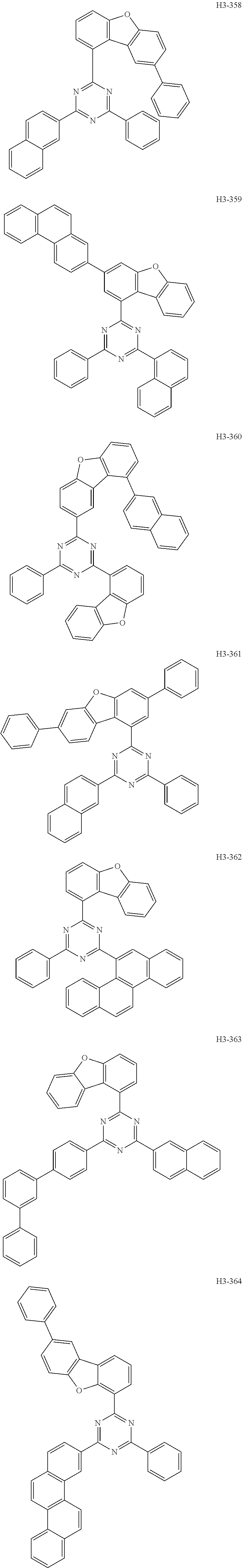 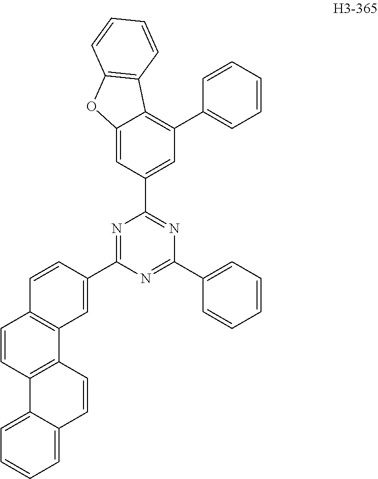 [SMILES: c1ccc(-c2nc(-c3cc(-c4ccccc4)c4c(c3)oc3ccccc34)nc(-c3ccc4ccc5c6ccccc6ccc5c4c3)n2)cc1] 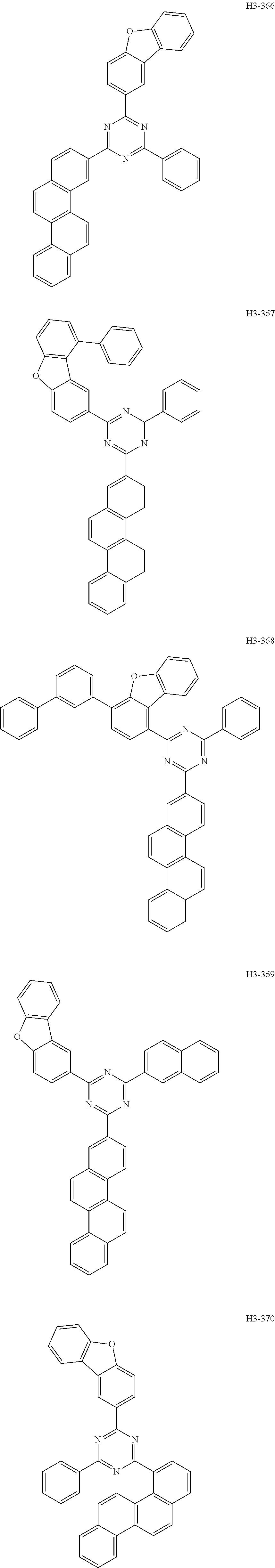 [SMILES: c1ccc(-c2nc(-c3ccc4ccc5c6ccccc6ccc5c4c3)nc(-c3ccc4oc5ccccc5c4c3)n2)cc1 ; c1ccc(-c2nc(-c3ccc4c(ccc5c6ccccc6ccc45)c3)nc(-c3ccc4oc5cccc(-c6ccccc6)c5c4c3)n2)cc1 ; c1ccc(-c2cccc(-c3ccc(-c4nc(-c5ccccc5)nc(-c5ccc6c(ccc7c8ccccc8ccc67)c5)n4)c4c3oc3ccccc34)c2)cc1 ; c1ccc2cc(-c3nc(-c4ccc5c(ccc6c7ccccc7ccc56)c4)nc(-c4ccc5oc6ccccc6c5c4)n3)ccc2c1 ; c1ccc(-c2nc(-c3ccc4oc5ccccc5c4c3)nc(-c3cccc4ccc5c6ccccc6ccc5c34)n2)cc1] 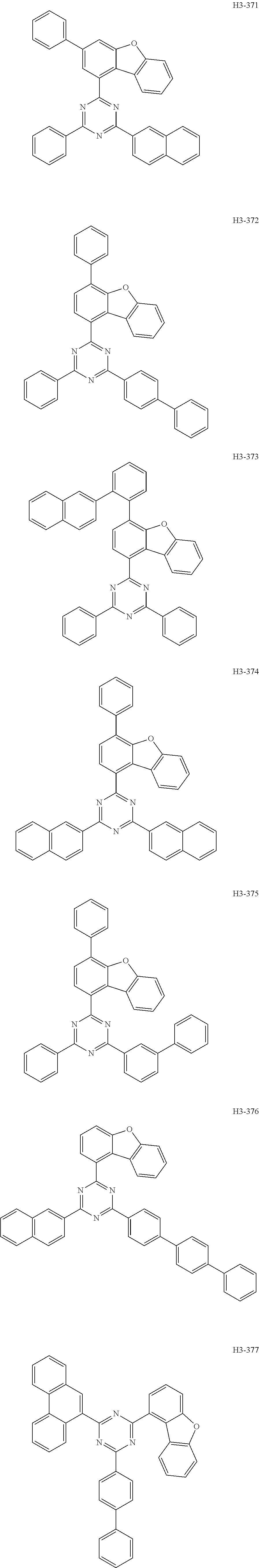 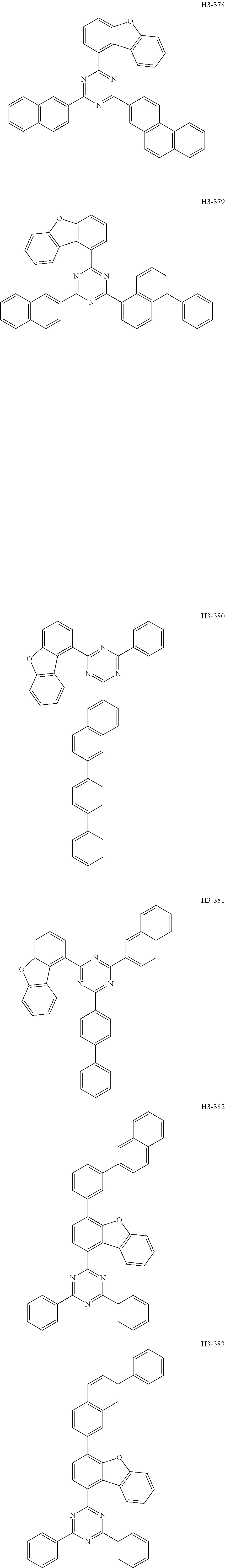 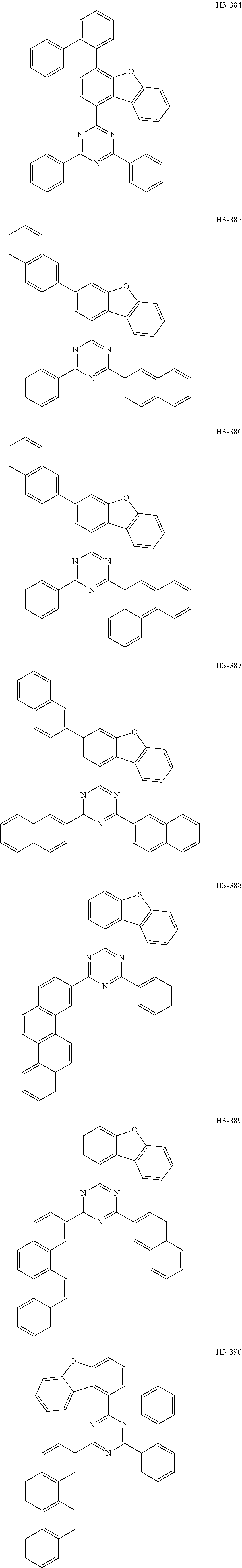 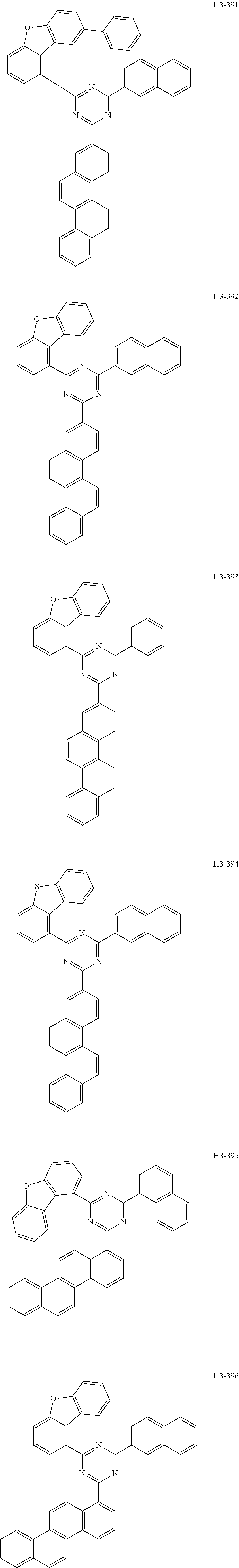 [SMILES: c1ccc(-c2ccc3oc4cccc(-c5nc(-c6ccc7ccccc7c6)nc(-c6ccc7c(ccc8c9ccccc9ccc78)c6)n5)c4c3c2)cc1 ; c1ccc2cc(-c3nc(-c4ccc5c(ccc6c7ccccc7ccc56)c4)nc(-c4cccc5oc6ccccc6c45)n3)ccc2c1 ; c1ccc(-c2nc(-c3ccc4c(ccc5c6ccccc6ccc45)c3)nc(-c3cccc4oc5ccccc5c34)n2)cc1 ; c1ccc2cc(-c3nc(-c4ccc5c(ccc6c7ccccc7ccc56)c4)nc(-c4cccc5sc6ccccc6c45)n3)ccc2c1 ; c1ccc2c(-c3nc(-c4cccc5c4ccc4c6ccccc6ccc54)nc(-c4cccc5oc6ccccc6c45)n3)cccc2c1 ; c1ccc2cc(-c3nc(-c4cccc5c4ccc4c6ccccc6ccc54)nc(-c4cccc5oc6ccccc6c45)n3)ccc2c1] 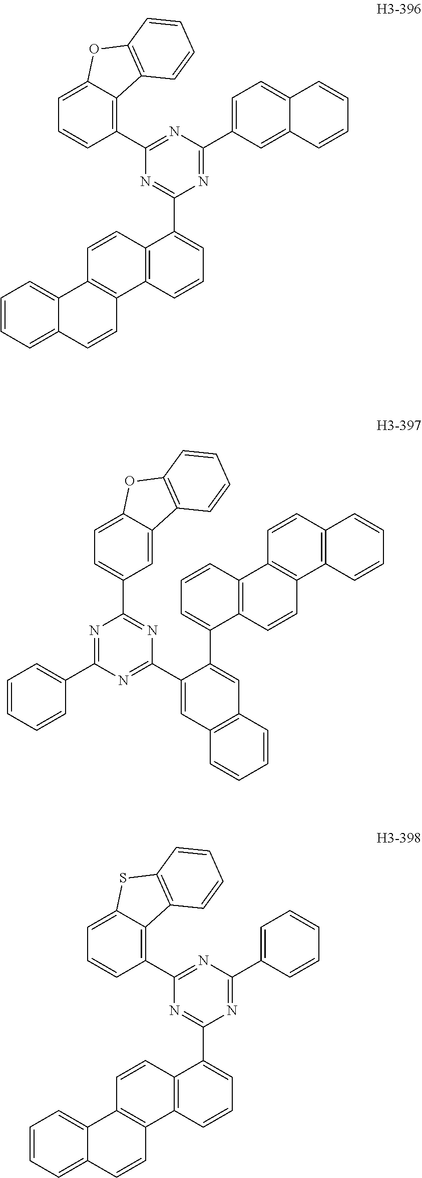 [SMILES: c1ccc2cc(-c3nc(-c4cccc5c4ccc4c6ccccc6ccc54)nc(-c4cccc5oc6ccccc6c45)n3)ccc2c1 ; c1ccc(-c2nc(-c3ccc4oc5ccccc5c4c3)nc(-c3cc4ccccc4cc3-c3cccc4c3ccc3c5ccccc5ccc43)n2)cc1 ; c1ccc(-c2nc(-c3cccc4c3ccc3c5ccccc5ccc43)nc(-c3cccc4sc5ccccc5c34)n2)cc1] 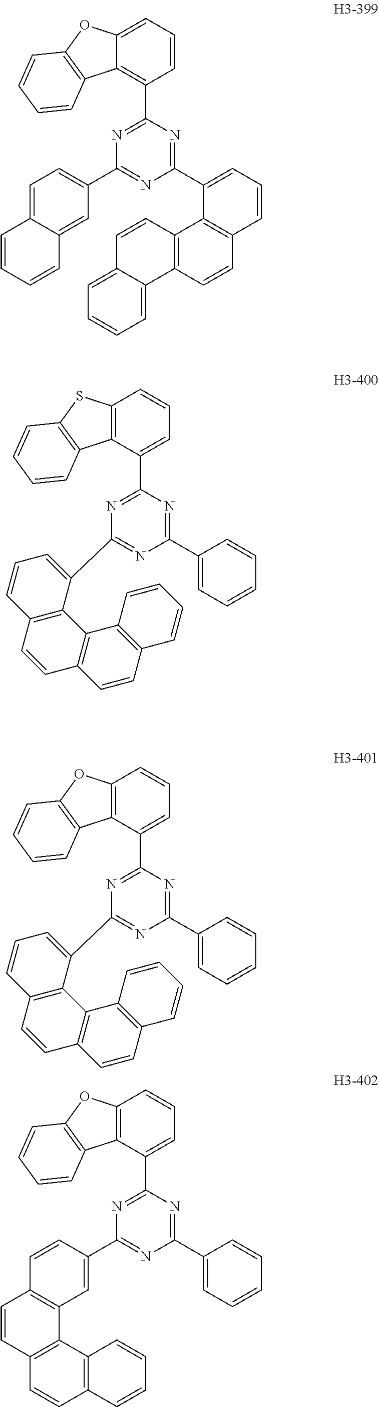 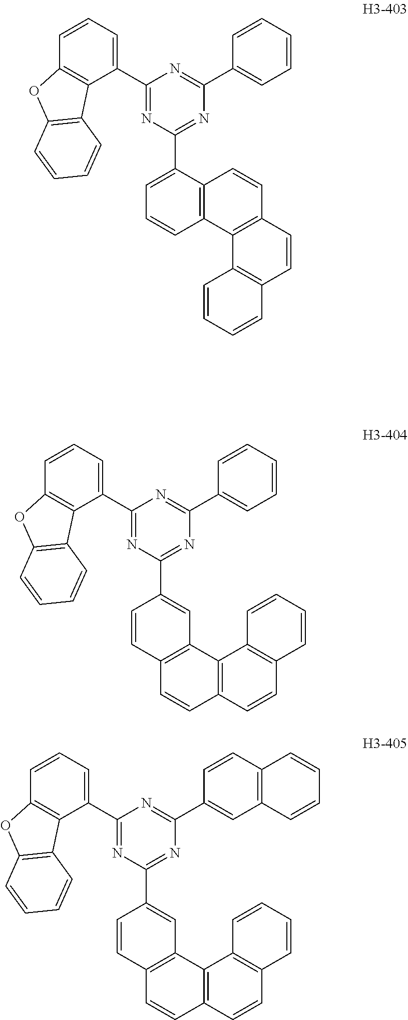 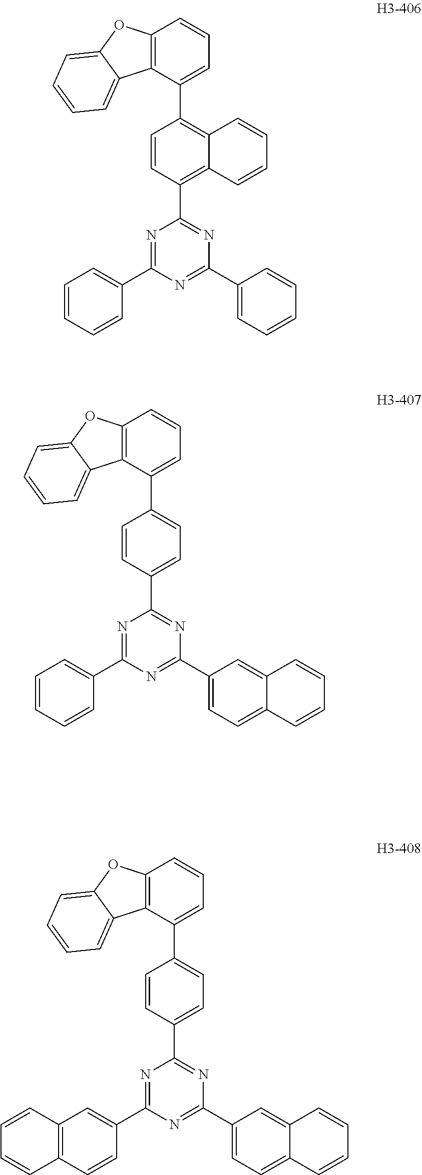 [SMILES: c1ccc(-c2nc(-c3ccccc3)nc(-c3ccc(-c4cccc5oc6ccccc6c45)c4ccccc34)n2)cc1 ; c1ccc(-c2nc(-c3ccc(-c4cccc5oc6ccccc6c45)cc3)nc(-c3ccc4ccccc4c3)n2)cc1 ; c1ccc2cc(-c3nc(-c4ccc(-c5cccc6oc7ccccc7c56)cc4)nc(-c4ccc5ccccc5c4)n3)ccc2c1] 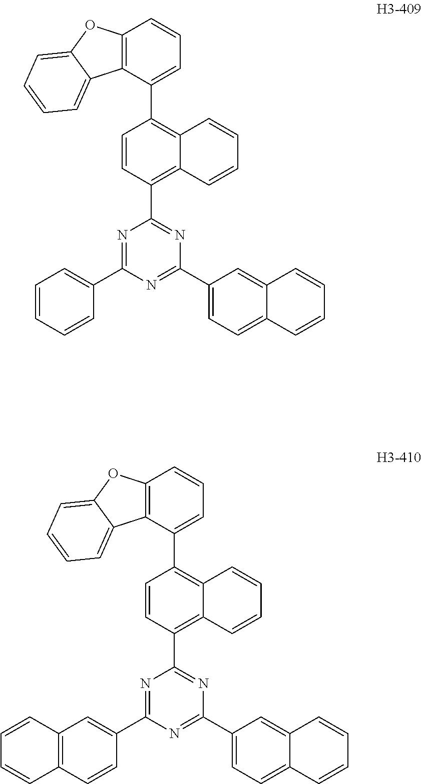 [SMILES: c1ccc(-c2nc(-c3ccc4ccccc4c3)nc(-c3ccc(-c4cccc5oc6ccccc6c45)c4ccccc34)n2)cc1 ; c1ccc2cc(-c3nc(-c4ccc5ccccc5c4)nc(-c4ccc(-c5cccc6oc7ccccc7c56)c5ccccc45)n3)ccc2c1] 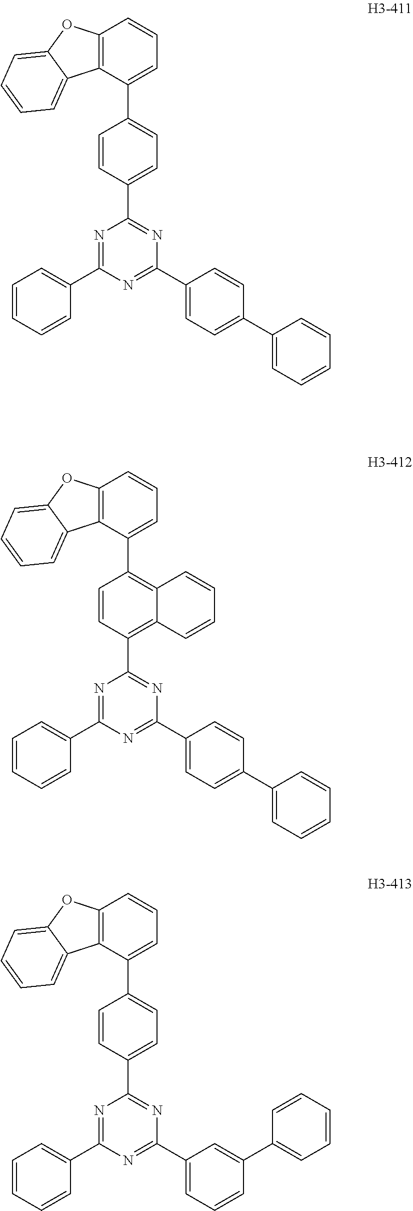 [SMILES: c1ccc(-c2ccc(-c3nc(-c4ccccc4)nc(-c4ccc(-c5cccc6oc7ccccc7c56)cc4)n3)cc2)cc1 ; c1ccc(-c2ccc(-c3nc(-c4ccccc4)nc(-c4ccc(-c5cccc6oc7ccccc7c56)c5ccccc45)n3)cc2)cc1 ; c1ccc(-c2cccc(-c3nc(-c4ccccc4)nc(-c4ccc(-c5cccc6oc7ccccc7c56)cc4)n3)c2)cc1] 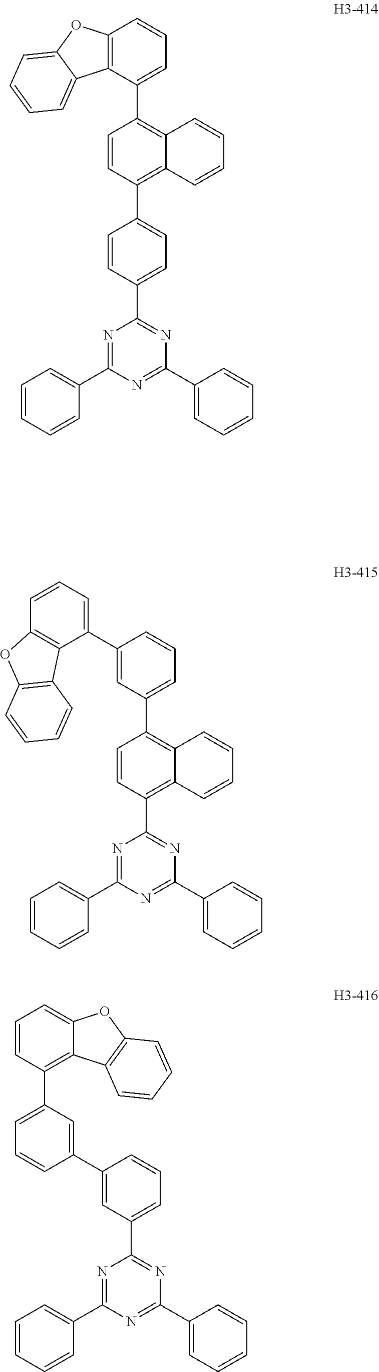 [SMILES: c1ccc(-c2nc(-c3ccccc3)nc(-c3ccc(-c4ccc(-c5cccc6oc7ccccc7c56)c5ccccc45)cc3)n2)cc1 ; c1ccc(-c2nc(-c3ccccc3)nc(-c3ccc(-c4cccc(-c5cccc6oc7ccccc7c56)c4)c4ccccc34)n2)cc1 ; c1ccc(-c2nc(-c3ccccc3)nc(-c3cccc(-c4cccc(-c5cccc6oc7ccccc7c56)c4)c3)n2)cc1] 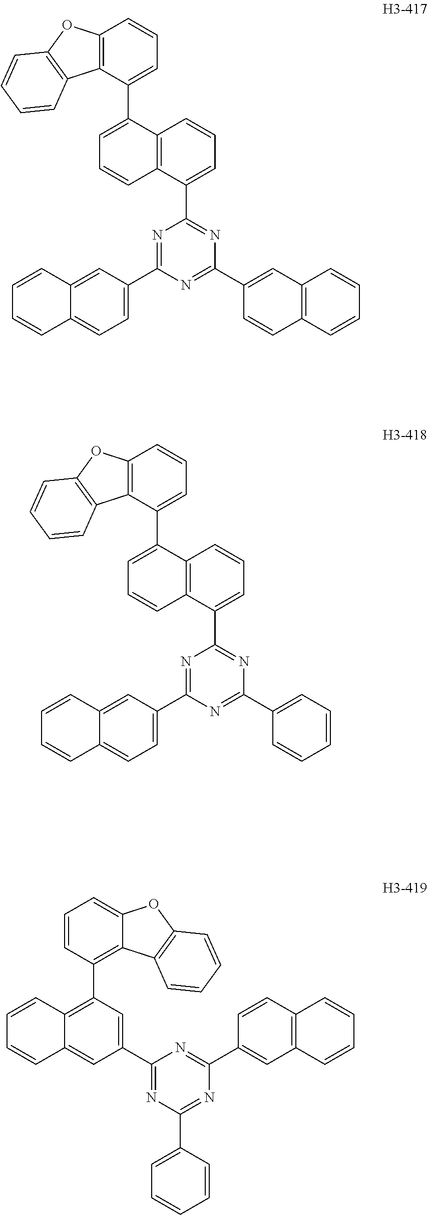 [SMILES: c1ccc2cc(-c3nc(-c4ccc5ccccc5c4)nc(-c4cccc5c(-c6cccc7oc8ccccc8c67)cccc45)n3)ccc2c1 ; c1ccc(-c2nc(-c3ccc4ccccc4c3)nc(-c3cccc4c(-c5cccc6oc7ccccc7c56)cccc34)n2)cc1 ; c1ccc(-c2nc(-c3ccc4ccccc4c3)nc(-c3cc(-c4cccc5oc6ccccc6c45)c4ccccc4c3)n2)cc1] 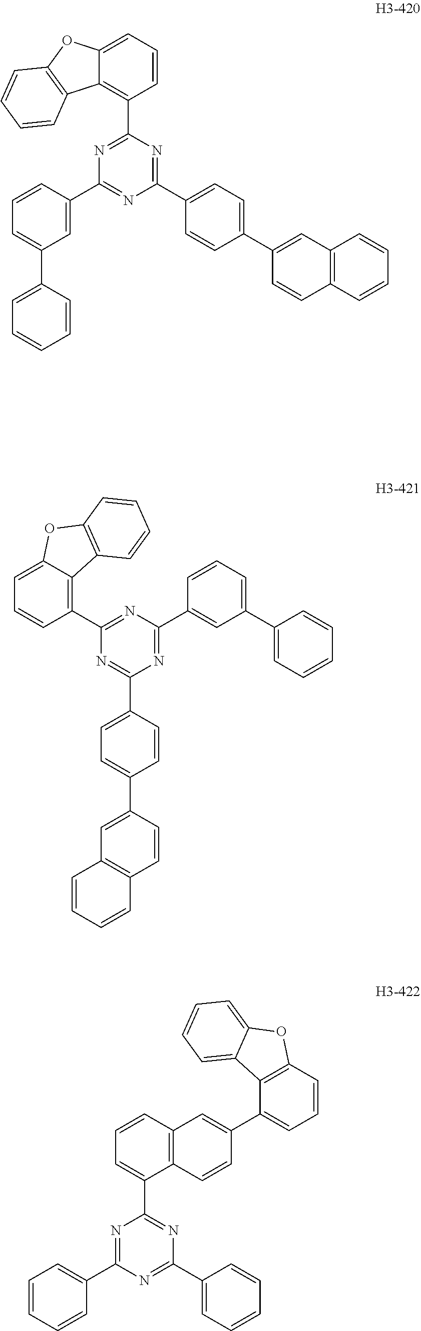 [SMILES: c1ccc(-c2cccc(-c3nc(-c4ccc(-c5ccc6ccccc6c5)cc4)nc(-c4cccc5oc6ccccc6c45)n3)c2)cc1 ; c1ccc(-c2cccc(-c3nc(-c4ccc(-c5ccc6ccccc6c5)cc4)nc(-c4cccc5oc6ccccc6c45)n3)c2)cc1 ; c1ccc(-c2nc(-c3ccccc3)nc(-c3cccc4cc(-c5cccc6oc7ccccc7c56)ccc34)n2)cc1] 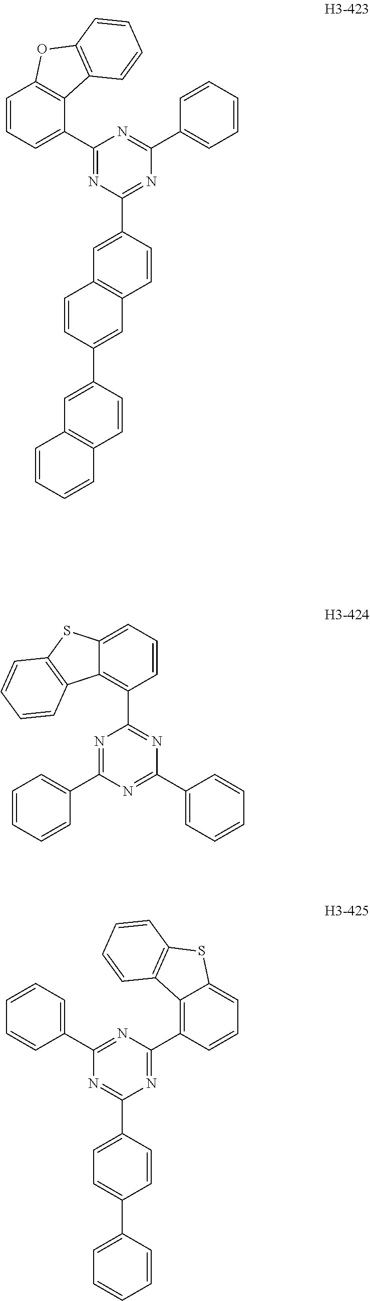 [SMILES: c1ccc(-c2nc(-c3ccc4cc(-c5ccc6ccccc6c5)ccc4c3)nc(-c3cccc4oc5ccccc5c34)n2)cc1 ; c1ccc(-c2nc(-c3ccccc3)nc(-c3cccc4sc5ccccc5c34)n2)cc1 ; c1ccc(-c2ccc(-c3nc(-c4ccccc4)nc(-c4cccc5sc6ccccc6c45)n3)cc2)cc1] 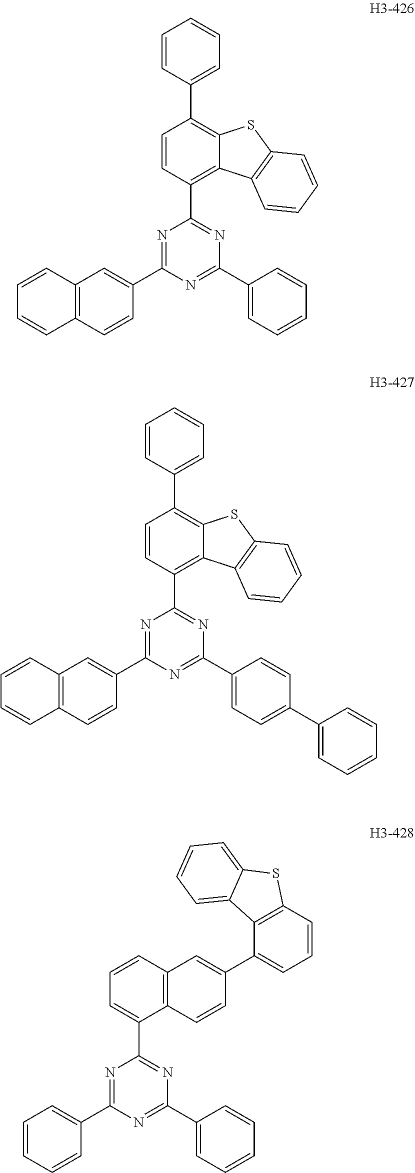 [SMILES: c1ccc(-c2nc(-c3ccc4ccccc4c3)nc(-c3ccc(-c4ccccc4)c4sc5ccccc5c34)n2)cc1 ; c1ccc(-c2ccc(-c3nc(-c4ccc5ccccc5c4)nc(-c4ccc(-c5ccccc5)c5sc6ccccc6c45)n3)cc2)cc1 ; c1ccc(-c2nc(-c3ccccc3)nc(-c3cccc4cc(-c5cccc6sc7ccccc7c56)ccc34)n2)cc1] 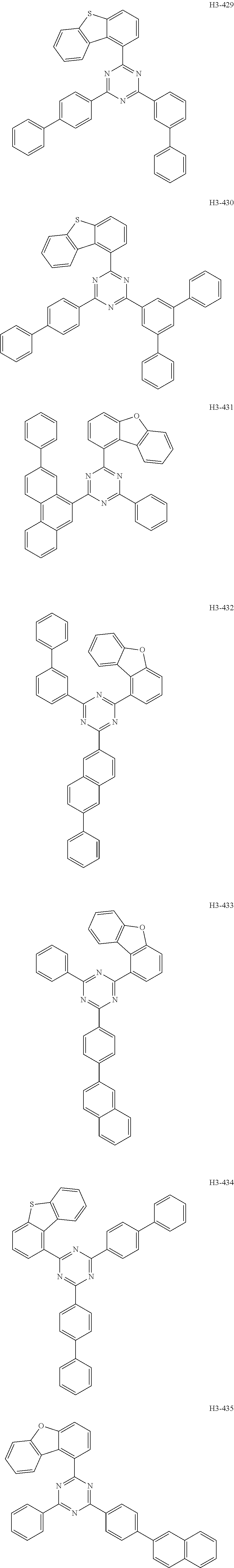 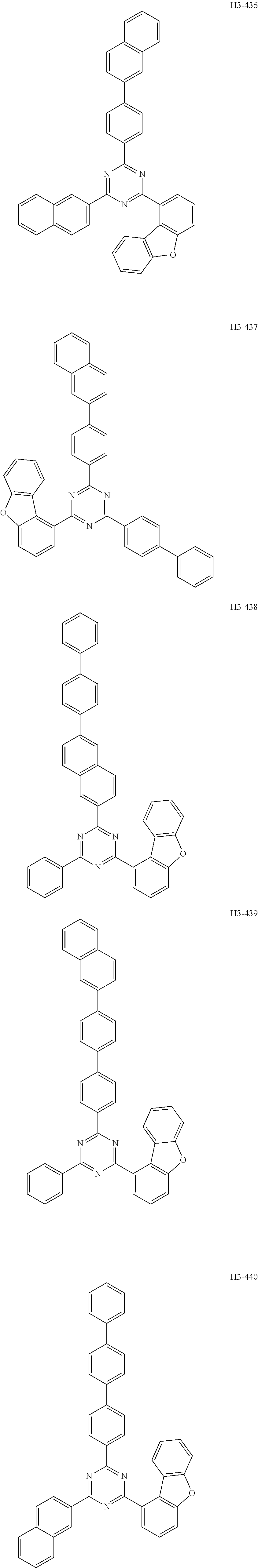 [SMILES: c1ccc2cc(-c3ccc(-c4nc(-c5ccc6ccccc6c5)nc(-c5cccc6oc7ccccc7c56)n4)cc3)ccc2c1 ; c1ccc(-c2ccc(-c3nc(-c4ccc(-c5ccc6ccccc6c5)cc4)nc(-c4cccc5oc6ccccc6c45)n3)cc2)cc1 ; c1ccc(-c2ccc(-c3ccc4cc(-c5nc(-c6ccccc6)nc(-c6cccc7oc8ccccc8c67)n5)ccc4c3)cc2)cc1 ; c1ccc(-c2nc(-c3ccc(-c4ccc(-c5ccc6ccccc6c5)cc4)cc3)nc(-c3cccc4oc5ccccc5c34)n2)cc1 ; c1ccc(-c2ccc(-c3ccc(-c4nc(-c5ccc6ccccc6c5)nc(-c5cccc6oc7ccccc7c56)n4)cc3)cc2)cc1] 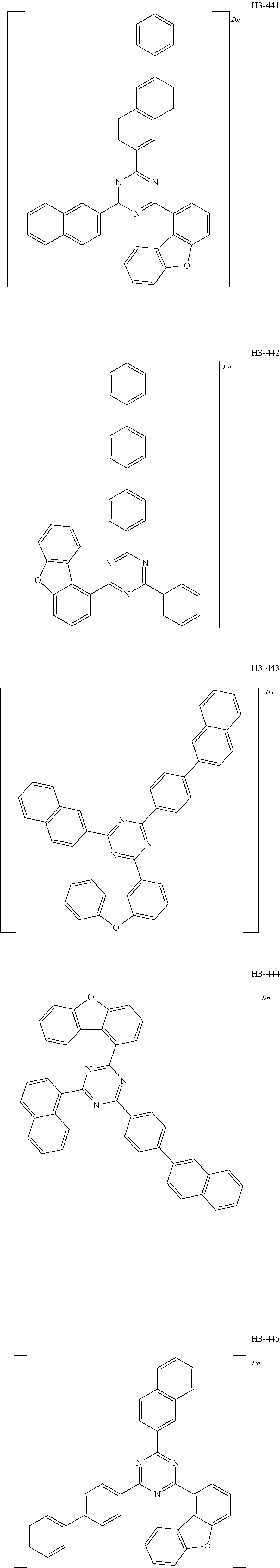 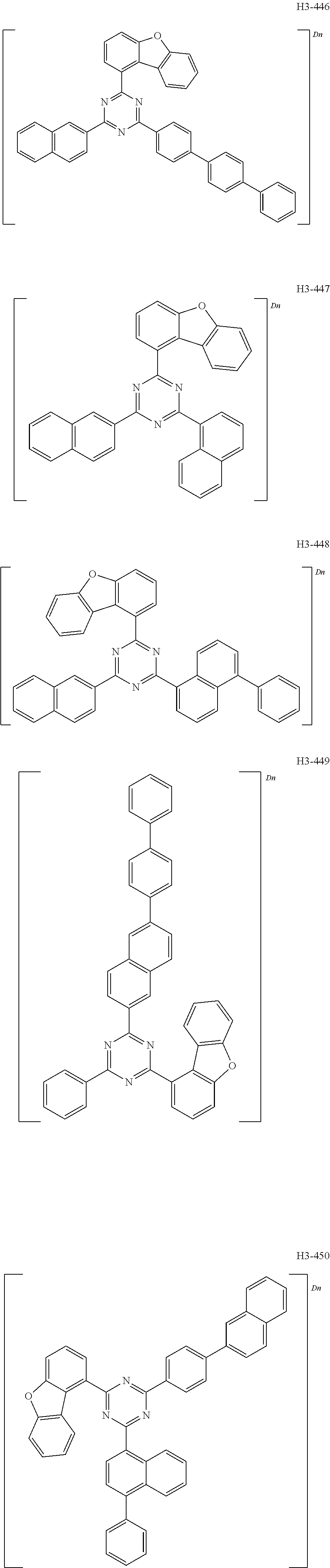 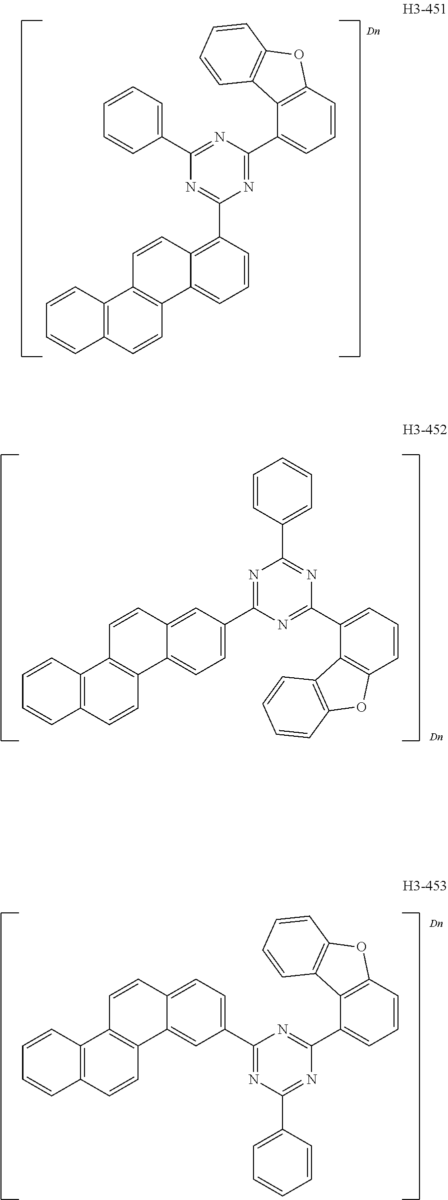 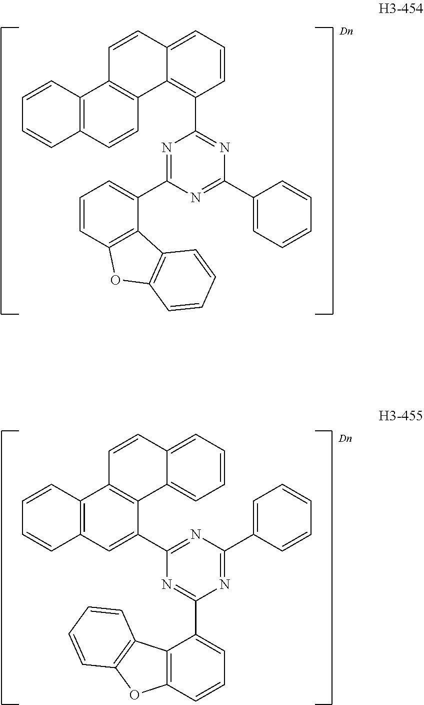
in the compounds above, Dₙ means that n number of hydrogens are replaced with deuterium, and n represents an integer from 1 to the maximum number of hydrogens in the compound.

12. The plurality of host materials according to claim 1, wherein the plurality of host materials are phosphorescent host materials.

13. An organic electroluminescent device comprising a first electrode; a second electrode; and at least one light-emitting layer between the first and second electrodes, wherein the at least one light-emitting layer comprises the plurality of host materials according to claim 1.

14. The organic electroluminescent device according to claim 13, wherein the light-emitting layer emits red light.

15. An organic electroluminescent compound represented by the following Formula 1′: 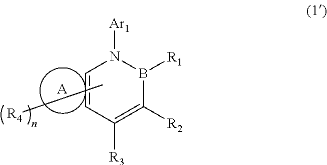
in Formula 1′,
ring A is not present, or represents a substituted or unsubstituted benzene, or a substituted or unsubstituted naphthalene;
Ar₁ and R₁ to R₄ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₂-C₃₀)alkenylamino, a substituted or unsubstituted (C₁-C₃₀)alkyl(C₂-C₃₀)alkenylamino, a substituted or unsubstituted mono- or di(C₆-C₃₀)arylamino, a substituted or unsubstituted (C₁-C₃₀)alkyl(C₆-C₃₀)arylamino, a substituted or unsubstituted mono- or di(3- to 30-membered)heteroarylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, a substituted or unsubstituted (C₆-C₃₀)aryl(3- to 30-membered)heteroarylamino, or a substituted or unsubstituted fused ring group of a (C₃-C₃₀) aliphatic ring(s) and a (C₆-C₃₀) aromatic ring(s); or may be linked to an adjacent substituent(s) to form a ring(s); with a proviso that it is excluded that Ar₁ and R₁, and R₂ and R₃ are linked to form a ring(s);
with a proviso that if ring A represents a substituted or unsubstituted benzene, R₂ represents a phenyl unsubstituted or substituted with deuterium, or Ar₁ represents a substituted or unsubstituted (C₆-C₃₀)aryl, a substituted or unsubstituted (3- to 30-membered)heteroaryl, a substituted or unsubstituted mono- or di(C₆-C₃₀)arylamino, or a substituted or unsubstituted (C₆-C₃₀)aryl(3- to 30-membered)heteroarylamino; and
n represents an integer of 1 to 6; and if n is an integer of 2 or more, each of R₄ may be the same as or different from each other.

16. The organic electroluminescent compound according to claim 15, wherein Formula 1′ is represented by any one of the following Formulas 1′-1 to 1′-3: 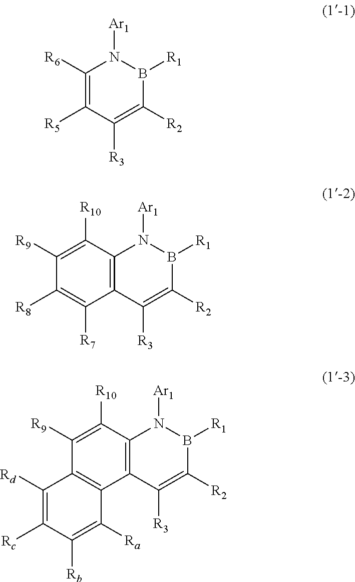
in Formulas 1′-1 to 1′-3,
Ar₁, R₁ to R₃, R₅ to R₁₀, and Rₐ to R_{d} each independently represent hydrogen, deuterium, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino, with a proviso that at least one of Ar₁, R₁, R₂, R₃, R₅, and R₆ in Formula 1′-1, at least one of Ar₁, R₁ to R₃, and R₇ to R₁₀ in Formula 1′-2, and at least one of Ar₁, R₁ to R₃, R₉, R₁₀, and Rₐ to R_{d} in Formula 1′-3 are each represented by one of Formulas 1′-a to 1′-d: 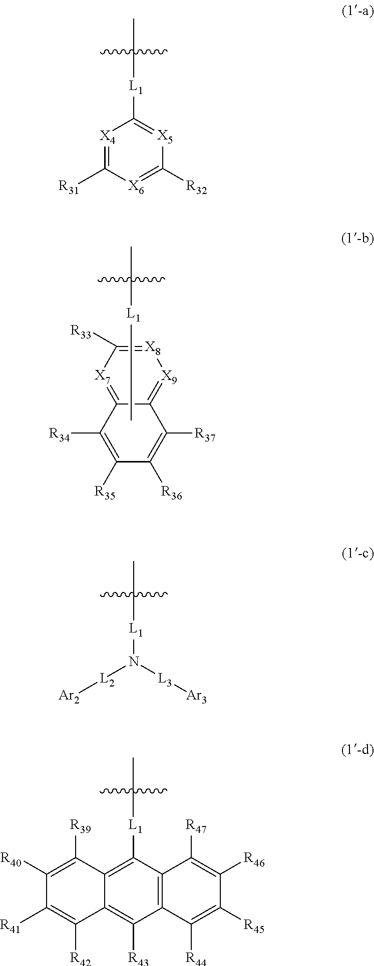
in Formulas 1′-a to 1′-d, 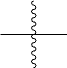
each independently represents a site linked to Formulas 1′-1 to 1′-3;
L₁ to L₃ each independently represent a single bond, a substituted or unsubstituted (C₆-C₃₀)arylene, or a substituted or unsubstituted (3- to 30-membered)heteroarylene;
X₄ to X₉ each independently represent N or CR₃₈, with a proviso that at least one of X₄ to X₆ and at least one of X₇ to X₉ represent N.
R₃₁ to R₄₇ each independently represent hydrogen, deuterium, a halogen, a cyano, a substituted or unsubstituted (C₁-C₃₀)alkyl, a substituted or unsubstituted (C₆-C₃₀)aryl, or a substituted or unsubstituted (3- to 30-membered)heteroaryl;
with a proviso that in Formula 1′-b, any one of X₇ to X₉, and R₃₃ to R₃₈ is linked to L₁; and
Ar₂ and Ar₃ each independently represent hydrogen, deuterium, a halogen, a cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted mono- or di(C₆-C₃₀)arylamino, a substituted or unsubstituted mono- or di(3- to 30-membered)heteroarylamino, or a substituted or unsubstituted (C₆-C₃₀)aryl(3- to 30-membered)heteroarylamino.

17. The organic electroluminescent compound according to claim 16, wherein Ar₁ in Formula 1-′2 is represented by any one of Formulas 1′-a to 1′-d.

18. The organic electroluminescent compound according to claim 16, wherein if any one of R₂, R₃, and R₇ to R₉ in Formula 1′-2 is represented by Formula 1′-a, at least one of R₃₁ and R₃₂ represents a substituted or unsubstituted (3- to 30-membered)heteroaryl.

19. The organic electroluminescent compound according to claim 16, wherein if any one of R₂, R₃, and R₇ to R₉ in Formula 1′-2 is represented by Formula 1′-c, at least one of Ar₂ and Ar₃ represents a substituted or unsubstituted (3- to 30-membered)heteroaryl containing O or S, or a substituted or unsubstituted (3- to 30-membered)heteroaryl containing N, O, or S and having four or more rings.

20. The organic electroluminescent compound according to claim 16, wherein any one of R₇ to R₁₀ in Formula 1′-2 is represented by Formula 1′-d.

21. The organic electroluminescent compound according to claim 16, wherein L₁ in Formulas 1′-a to 1′-d represents a (C₆-C₃₀)arylene substituted with at least one cyano, or a (3- to 30-membered)heteroarylene substituted with at least one cyano.

22. The organic electroluminescent compound according to claim 15, wherein the compound represented by Formula 1′ is selected from the following compounds: 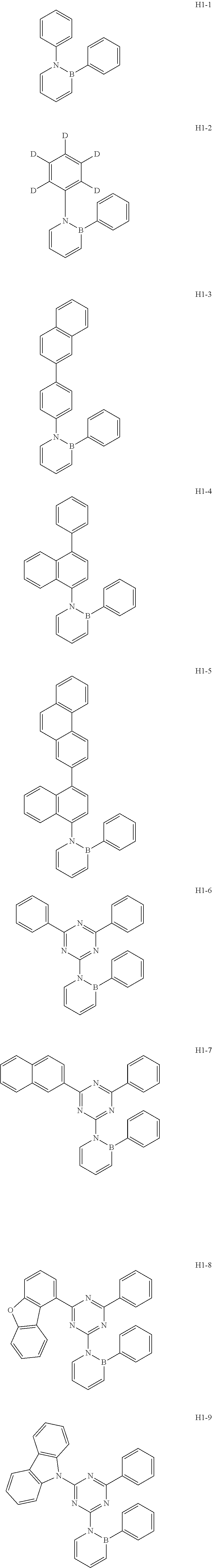 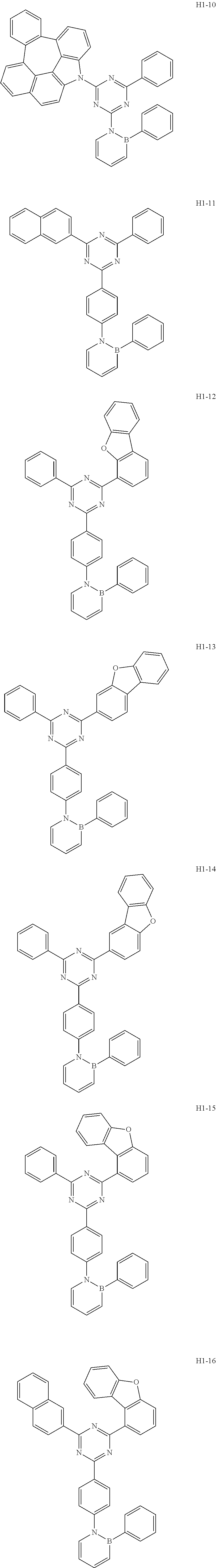 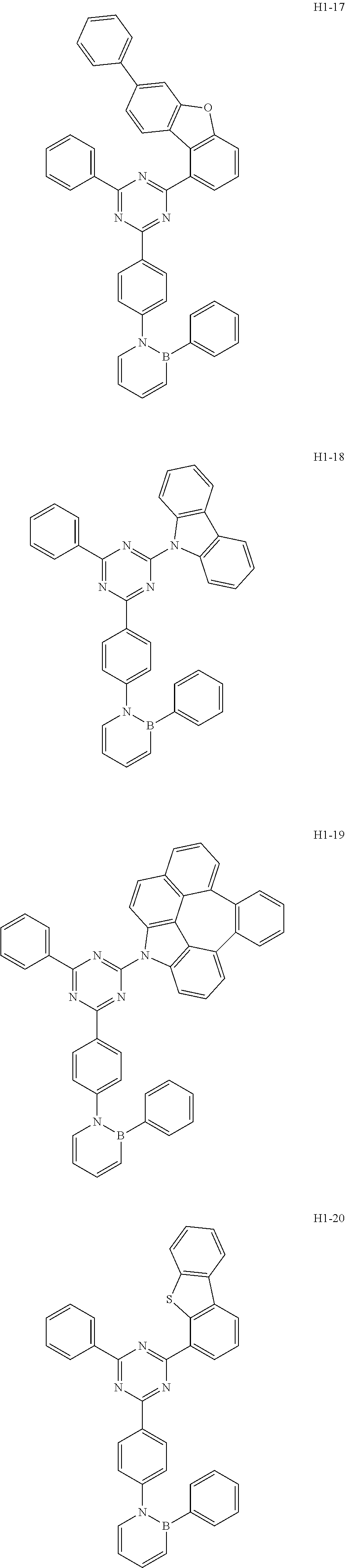 [SMILES: C1=CB(c2ccccc2)N(c2ccc(-c3nc(-c4ccccc4)nc(-c4cccc5oc6cc(-c7ccccc7)ccc6c45)n3)cc2)C=C1 ; C1=CB(c2ccccc2)N(c2ccc(-c3nc(-c4ccccc4)nc(-n4c5ccccc5c5ccccc54)n3)cc2)C=C1 ; C1=CB(c2ccccc2)N(c2ccc(-c3nc(-c4ccccc4)nc(-n4c5cccc6c5c5c7c(cccc7ccc54)-c4ccccc4-6)n3)cc2)C=C1 ; C1=CB(c2ccccc2)N(c2ccc(-c3nc(-c4ccccc4)nc(-c4cccc5c4sc4ccccc45)n3)cc2)C=C1] 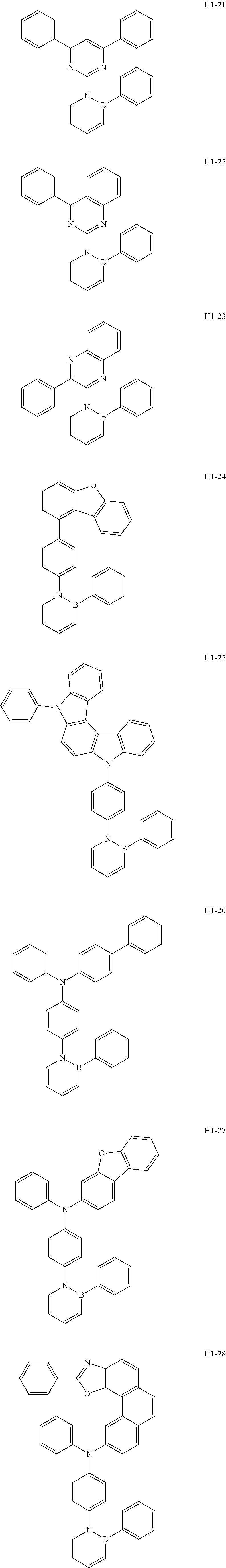 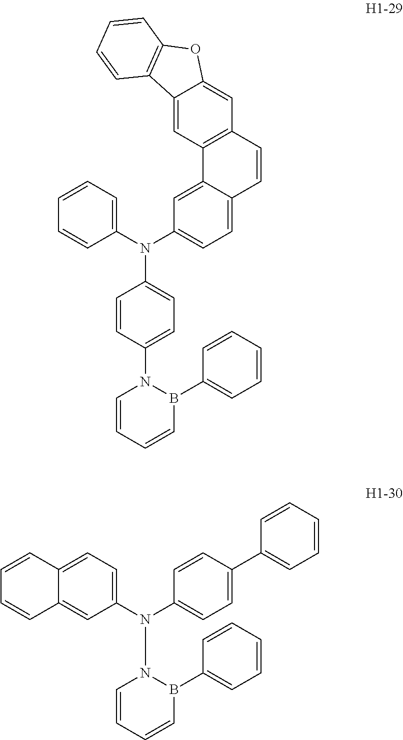 [SMILES: C1=CB(c2ccccc2)N(c2ccc(N(c3ccccc3)c3ccc4ccc5cc6oc7ccccc7c6cc5c4c3)cc2)C=C1 ; C1=CB(c2ccccc2)N(N(c2ccc(-c3ccccc3)cc2)c2ccc3ccccc3c2)C=C1] 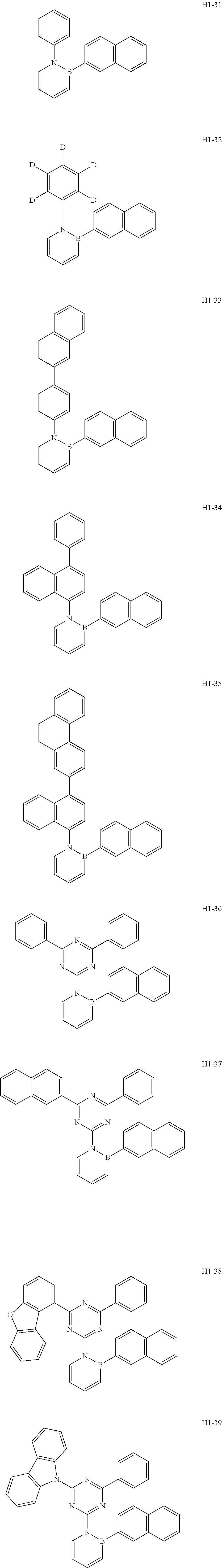 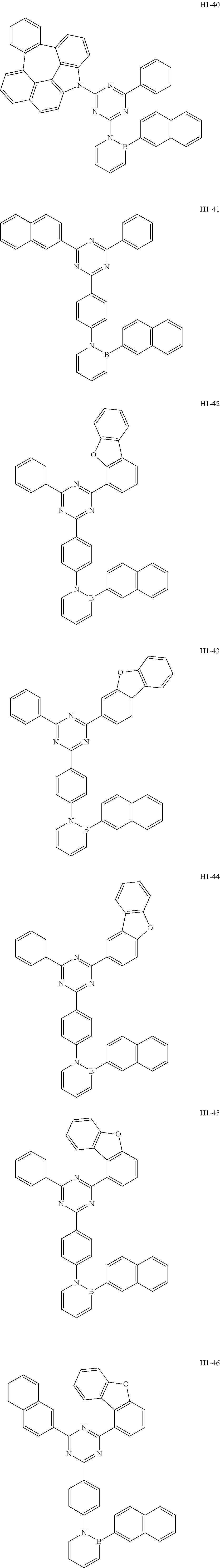 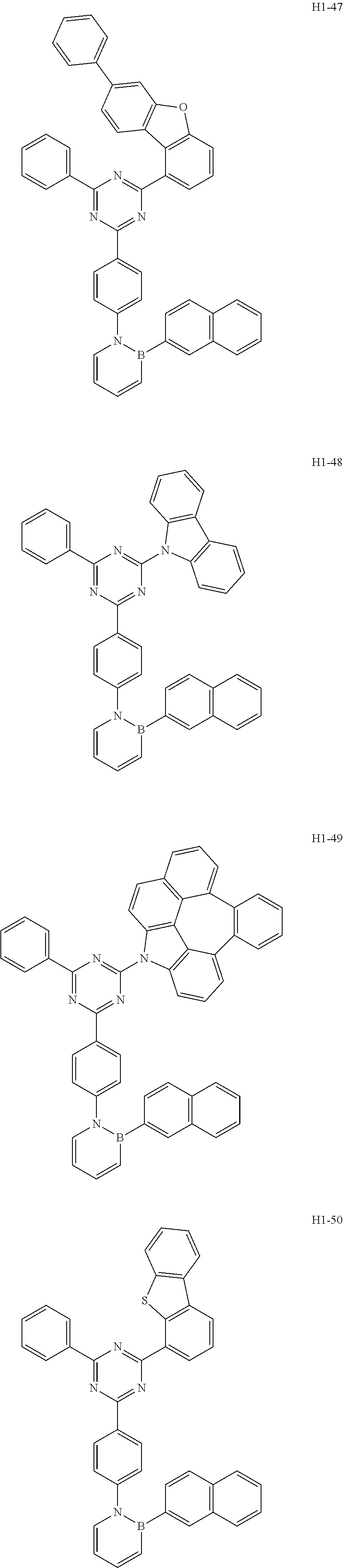 [SMILES: C1=CB(c2ccc3ccccc3c2)N(c2ccc(-c3nc(-c4ccccc4)nc(-c4cccc5oc6cc(-c7ccccc7)ccc6c45)n3)cc2)C=C1 ; C1=CB(c2ccc3ccccc3c2)N(c2ccc(-c3nc(-c4ccccc4)nc(-n4c5ccccc5c5ccccc54)n3)cc2)C=C1 ; C1=CB(c2ccc3ccccc3c2)N(c2ccc(-c3nc(-c4ccccc4)nc(-n4c5cccc6c5c5c7c(cccc7ccc54)-c4ccccc4-6)n3)cc2)C=C1 ; C1=CB(c2ccc3ccccc3c2)N(c2ccc(-c3nc(-c4ccccc4)nc(-c4cccc5c4sc4ccccc45)n3)cc2)C=C1] 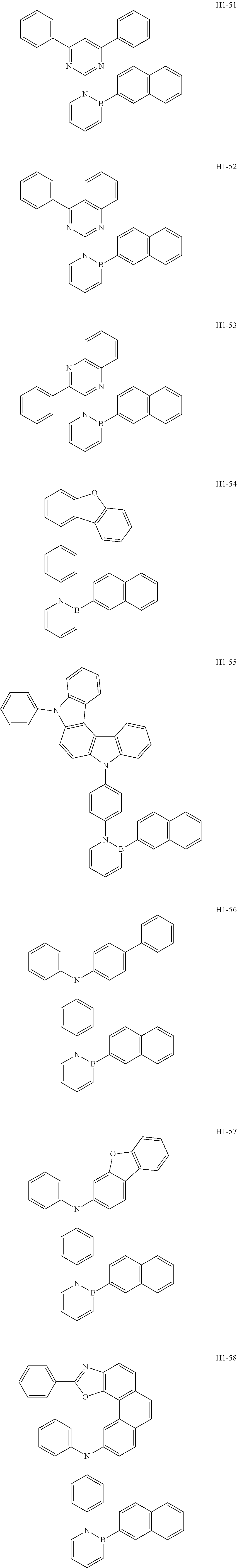 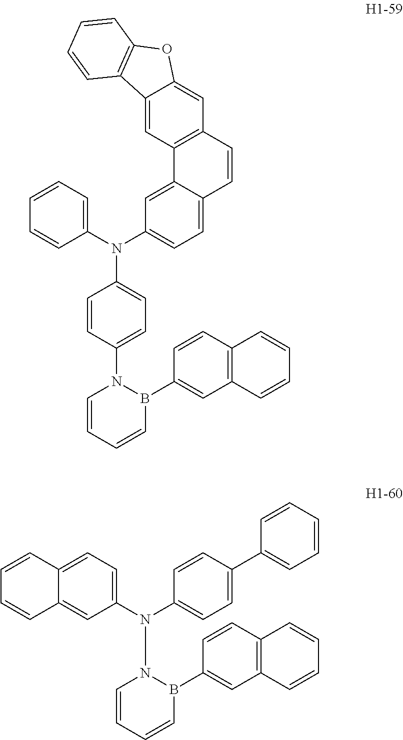 [SMILES: C1=CB(c2ccc3ccccc3c2)N(c2ccc(N(c3ccccc3)c3ccc4ccc5cc6oc7ccccc7c6cc5c4c3)cc2)C=C1 ; C1=CB(c2ccc3ccccc3c2)N(N(c2ccc(-c3ccccc3)cc2)c2ccc3ccccc3c2)C=C1] 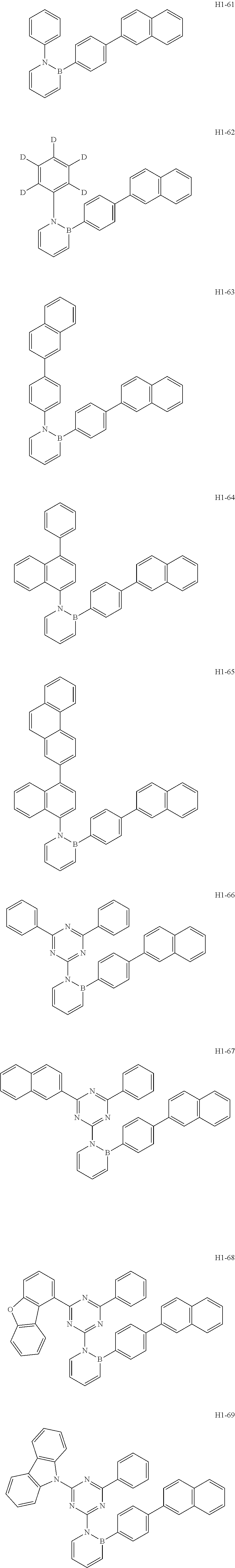 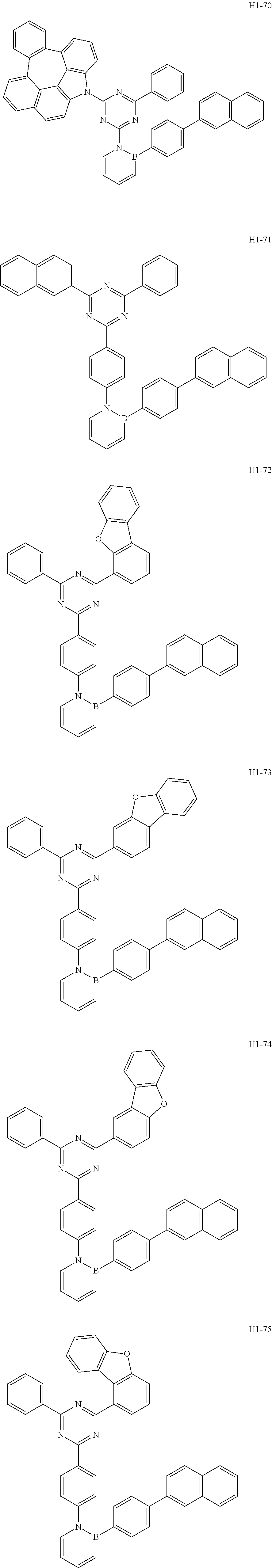 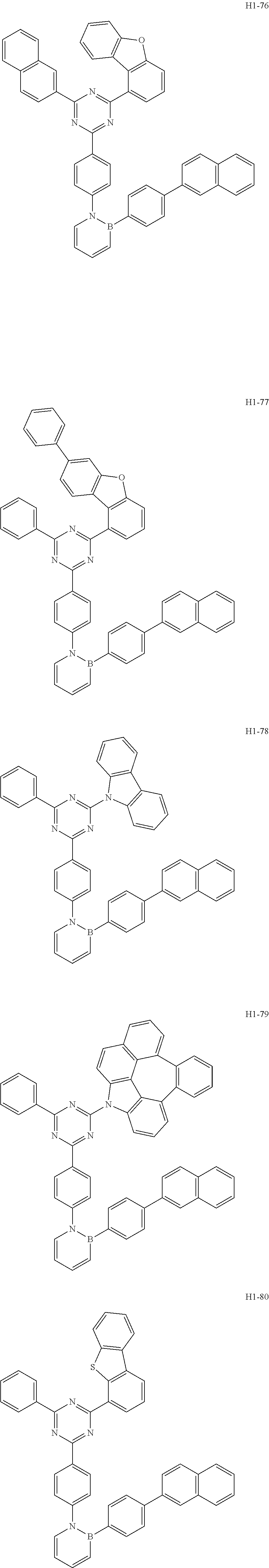 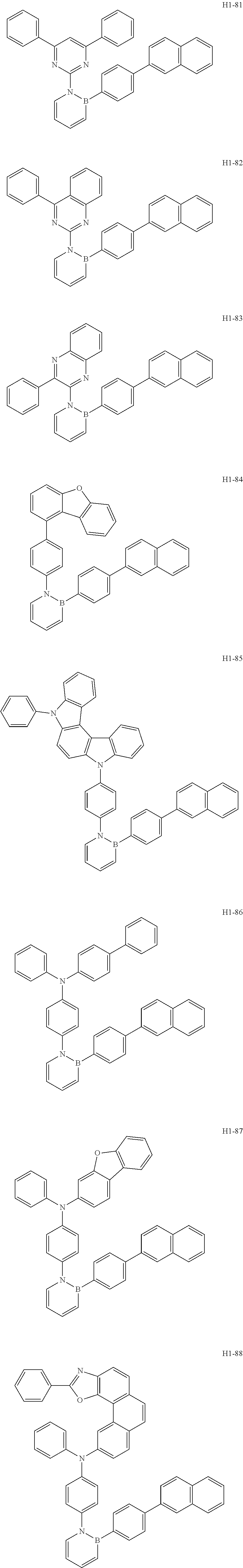 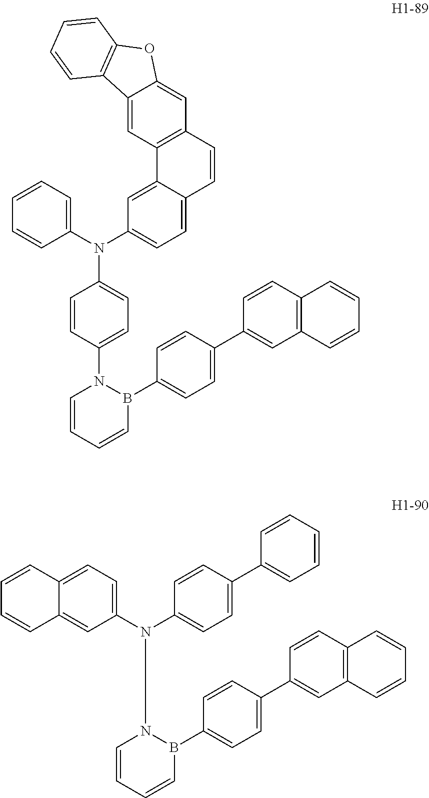 [SMILES: C1=CB(c2ccc(-c3ccc4ccccc4c3)cc2)N(c2ccc(N(c3ccccc3)c3ccc4ccc5cc6oc7ccccc7c6cc5c4c3)cc2)C=C1 ; C1=CB(c2ccc(-c3ccc4ccccc4c3)cc2)N(N(c2ccc(-c3ccccc3)cc2)c2ccc3ccccc3c2)C=C1] 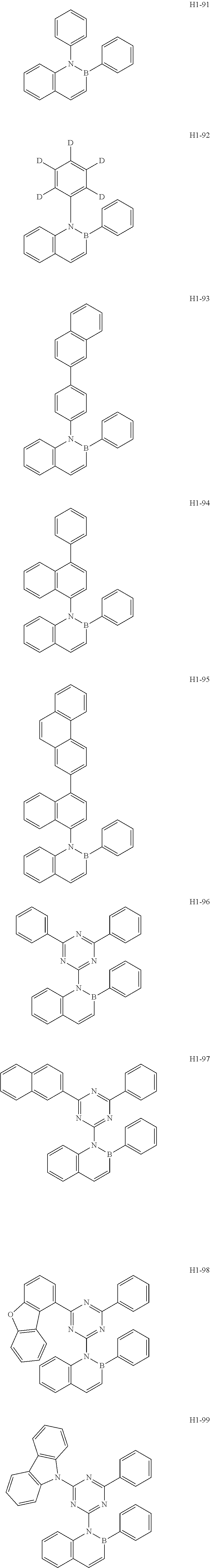 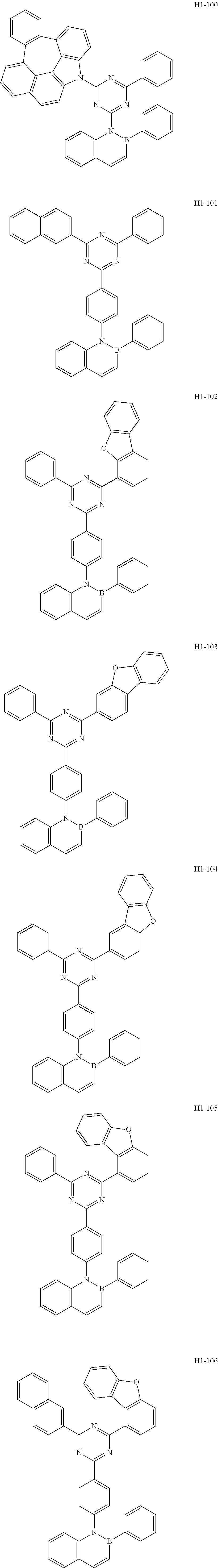 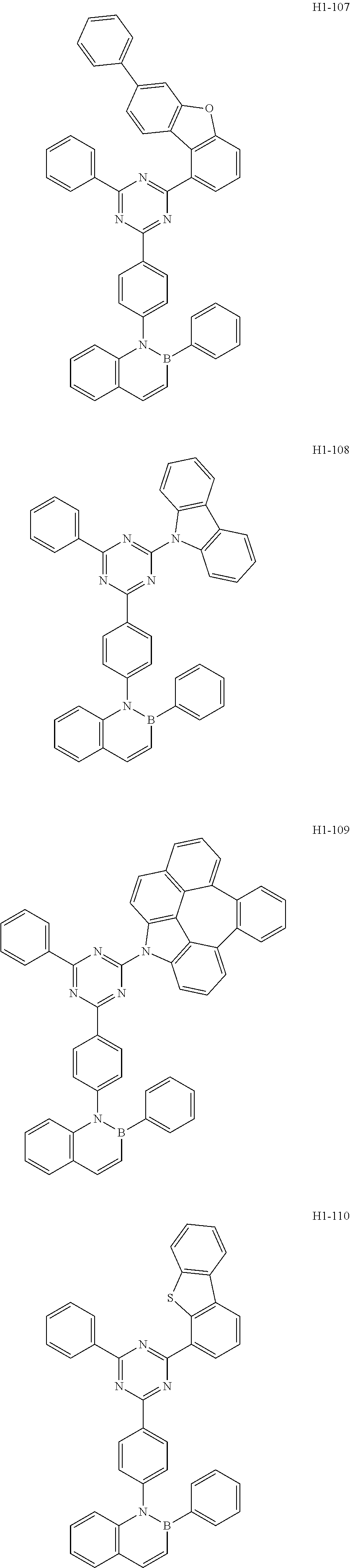 [SMILES: C1=Cc2ccccc2N(c2ccc(-c3nc(-c4ccccc4)nc(-c4cccc5oc6cc(-c7ccccc7)ccc6c45)n3)cc2)B1c1ccccc1 ; C1=Cc2ccccc2N(c2ccc(-c3nc(-c4ccccc4)nc(-n4c5ccccc5c5ccccc54)n3)cc2)B1c1ccccc1 ; C1=Cc2ccccc2N(c2ccc(-c3nc(-c4ccccc4)nc(-n4c5cccc6c5c5c7c(cccc7ccc54)-c4ccccc4-6)n3)cc2)B1c1ccccc1 ; C1=Cc2ccccc2N(c2ccc(-c3nc(-c4ccccc4)nc(-c4cccc5c4sc4ccccc45)n3)cc2)B1c1ccccc1] 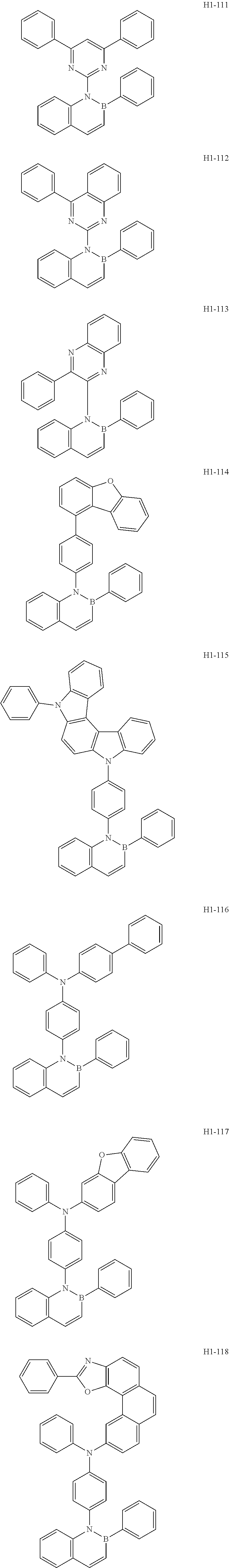 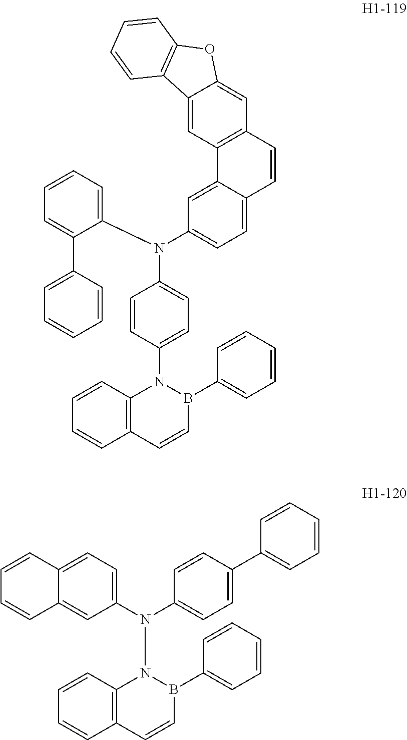 [SMILES: C1=Cc2ccccc2N(c2ccc(N(c3ccc4ccc5cc6oc7ccccc7c6cc5c4c3)c3ccccc3-c3ccccc3)cc2)B1c1ccccc1 ; C1=Cc2ccccc2N(N(c2ccc(-c3ccccc3)cc2)c2ccc3ccccc3c2)B1c1ccccc1] 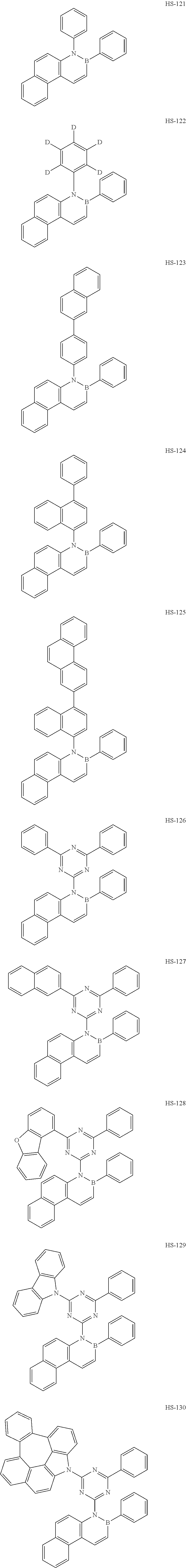 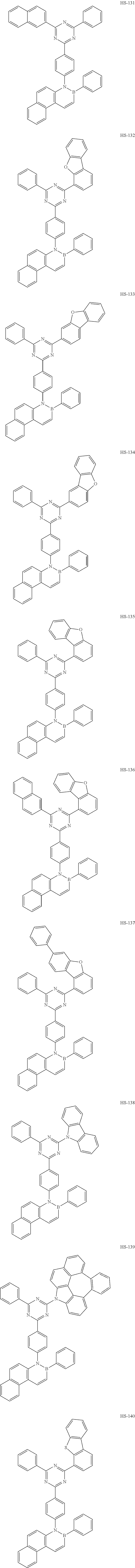 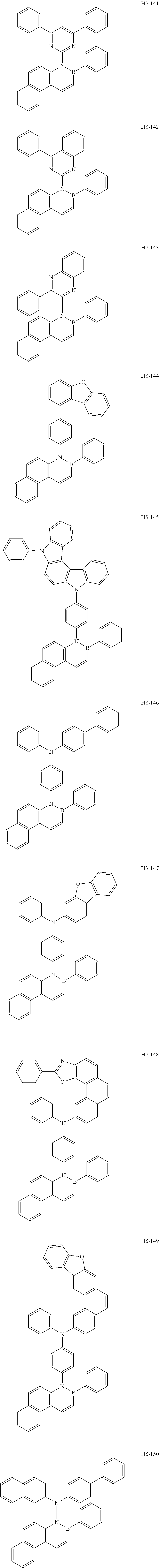 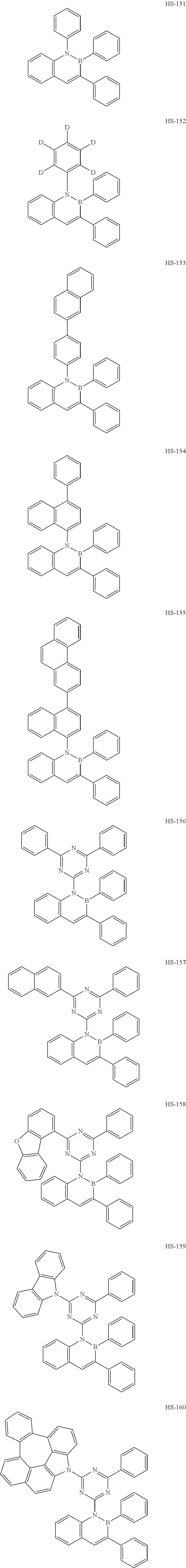 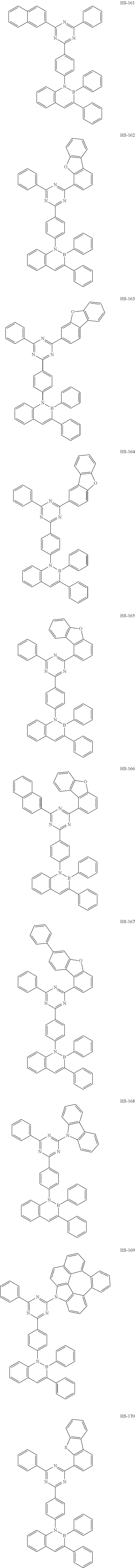 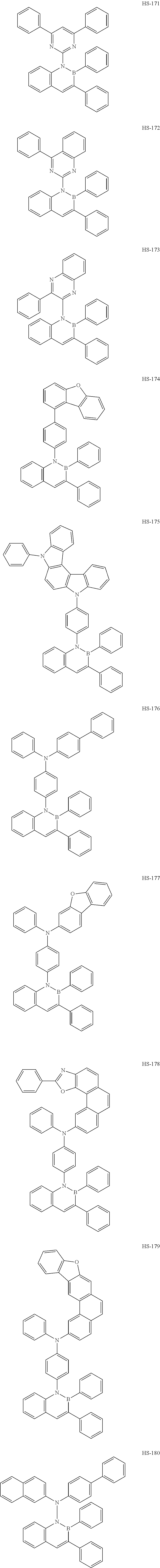 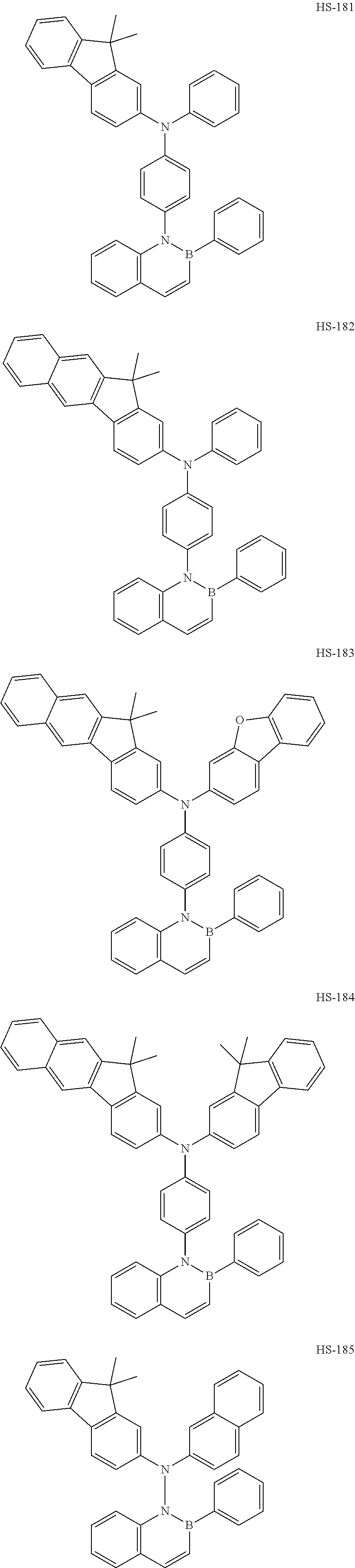 [SMILES: CC1(C)c2ccccc2-c2ccc(N(c3ccccc3)c3ccc(N4B(c5ccccc5)C=Cc5ccccc54)cc3)cc21 ; CC1(C)c2cc(N(c3ccccc3)c3ccc(N4B(c5ccccc5)C=Cc5ccccc54)cc3)ccc2-c2cc3ccccc3cc21 ; CC1(C)c2cc(N(c3ccc(N4B(c5ccccc5)C=Cc5ccccc54)cc3)c3ccc4c(c3)oc3ccccc34)ccc2-c2cc3ccccc3cc21 ; CC1(C)c2ccccc2-c2ccc(N(c3ccc(N4B(c5ccccc5)C=Cc5ccccc54)cc3)c3ccc4c(c3)C(C)(C)c3cc5ccccc5cc3-4)cc21 ; CC1(C)c2ccccc2-c2ccc(N(c3ccc4ccccc4c3)N3B(c4ccccc4)C=Cc4ccccc43)cc21] 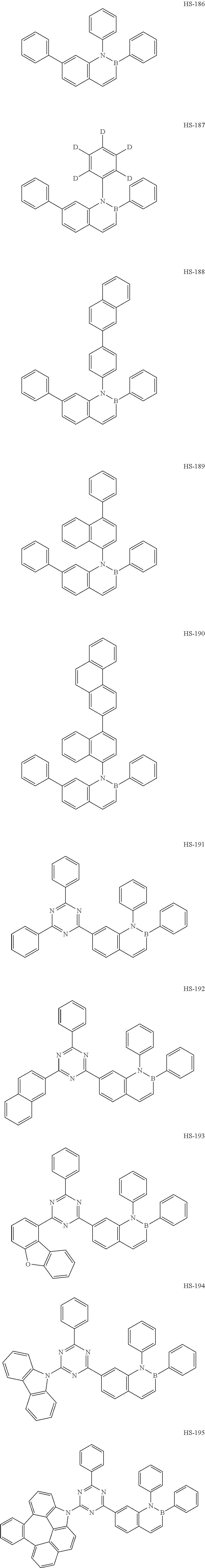 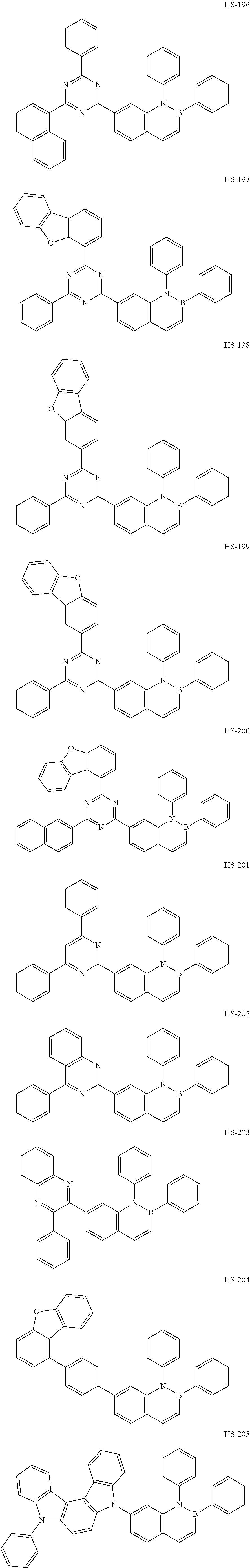 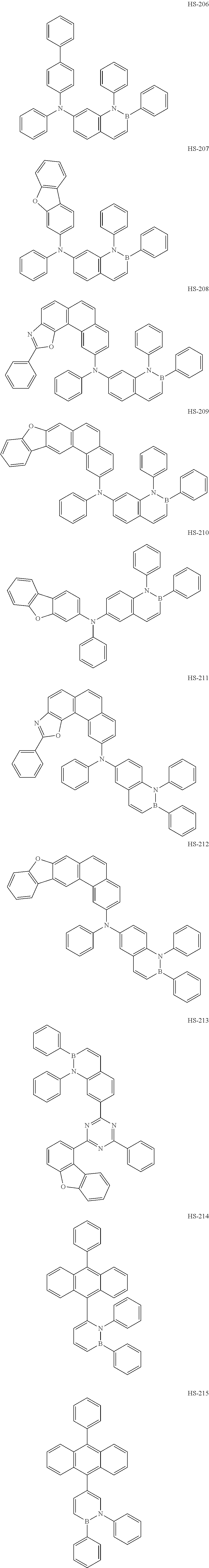 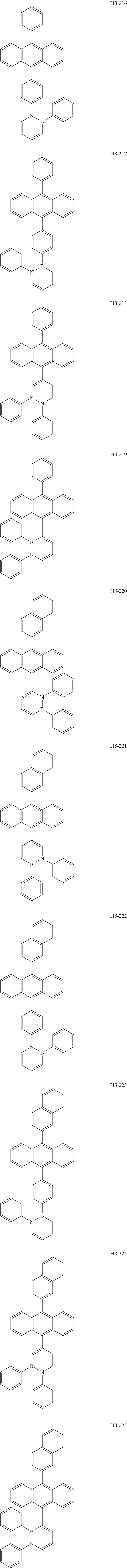 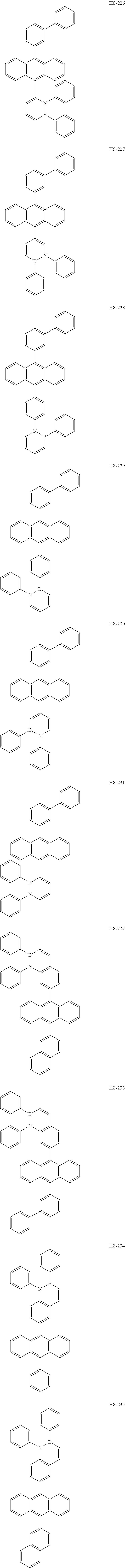 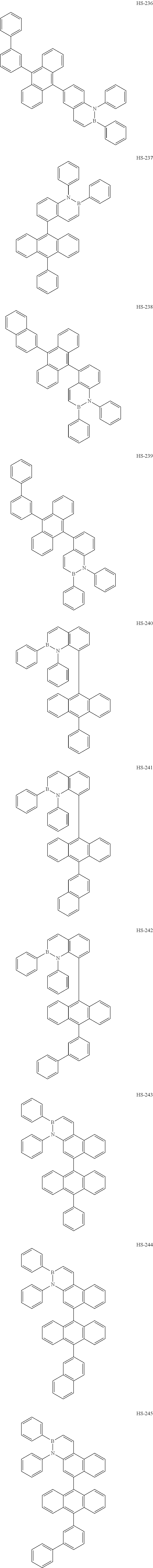 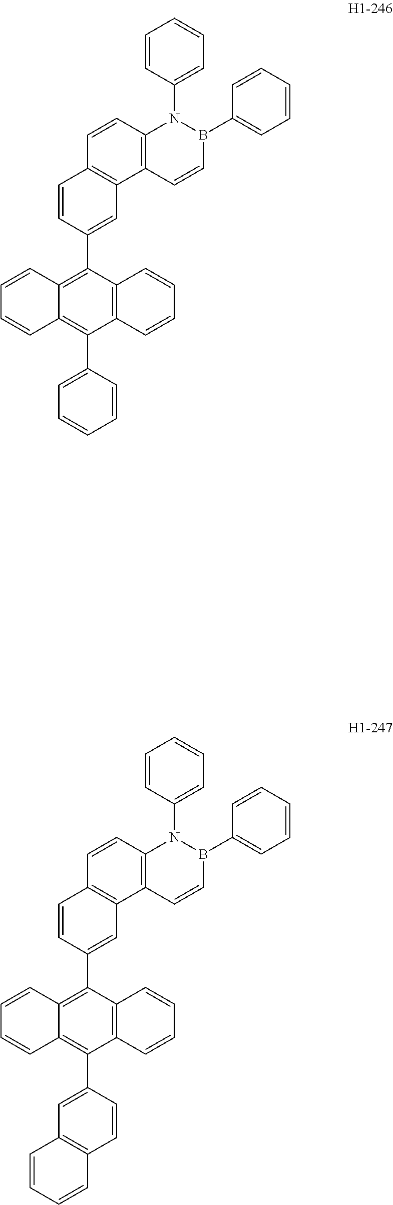 [SMILES: C1=Cc2c(ccc3ccc(-c4c5ccccc5c(-c5ccccc5)c5ccccc45)cc23)N(c2ccccc2)B1c1ccccc1 ; C1=Cc2c(ccc3ccc(-c4c5ccccc5c(-c5ccc6ccccc6c5)c5ccccc45)cc23)N(c2ccccc2)B1c1ccccc1] 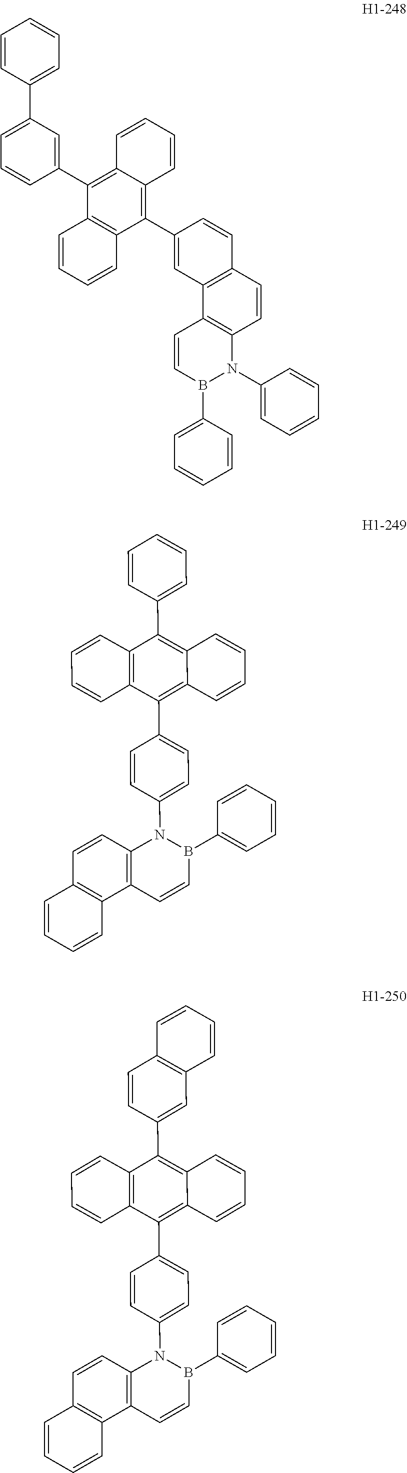 [SMILES: C1=Cc2c(ccc3ccc(-c4c5ccccc5c(-c5cccc(-c6ccccc6)c5)c5ccccc45)cc23)N(c2ccccc2)B1c1ccccc1 ; C1=Cc2c(ccc3ccccc23)N(c2ccc(-c3c4ccccc4c(-c4ccccc4)c4ccccc34)cc2)B1c1ccccc1 ; C1=Cc2c(ccc3ccccc23)N(c2ccc(-c3c4ccccc4c(-c4ccc5ccccc5c4)c4ccccc34)cc2)B1c1ccccc1] 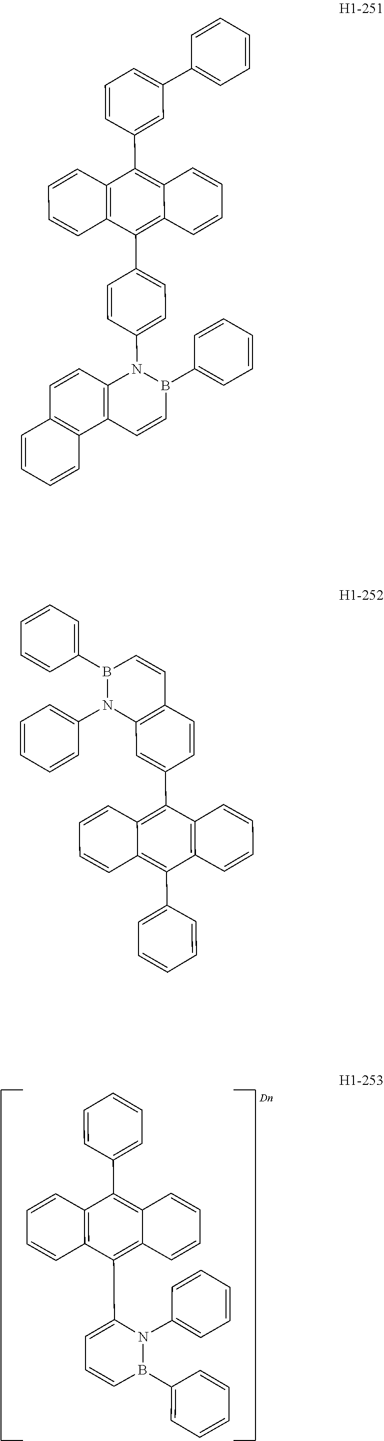 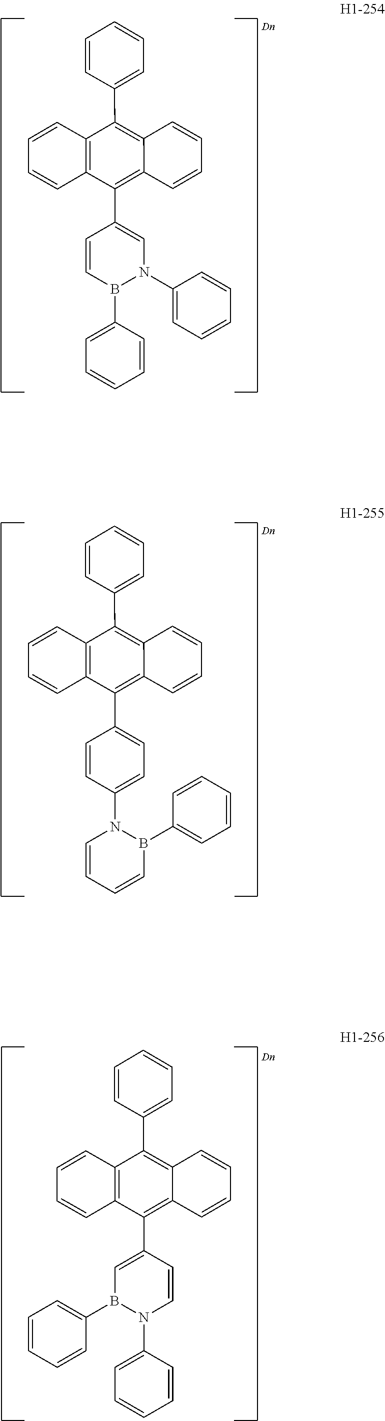 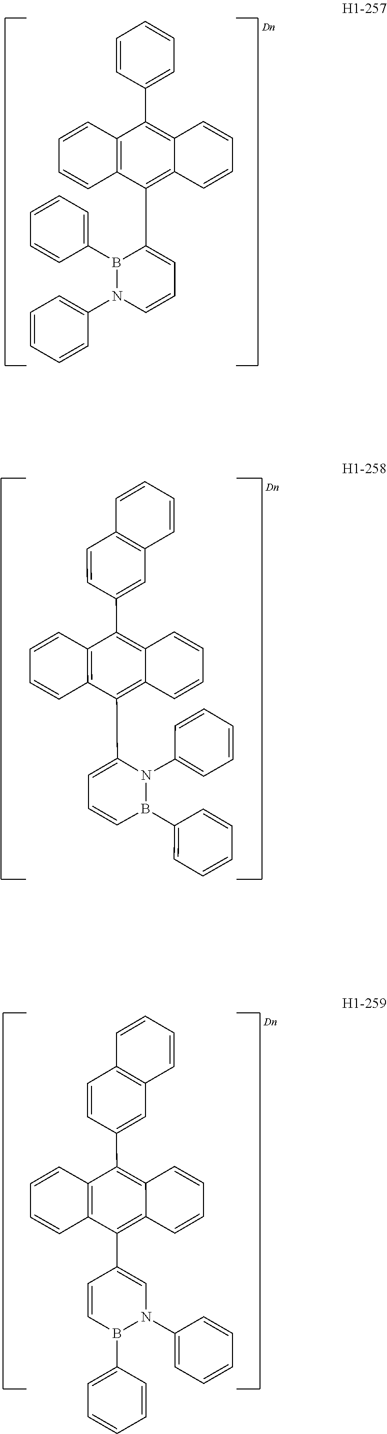 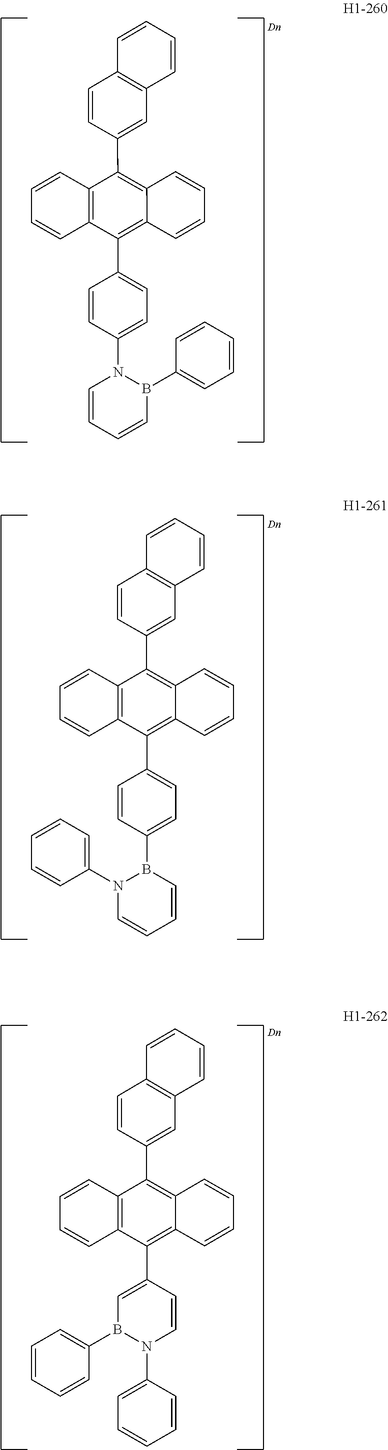 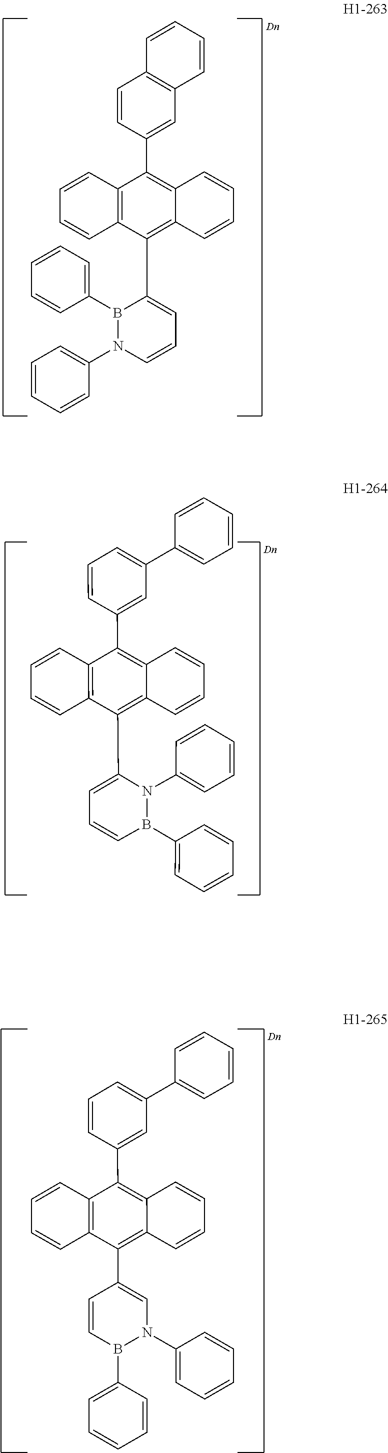 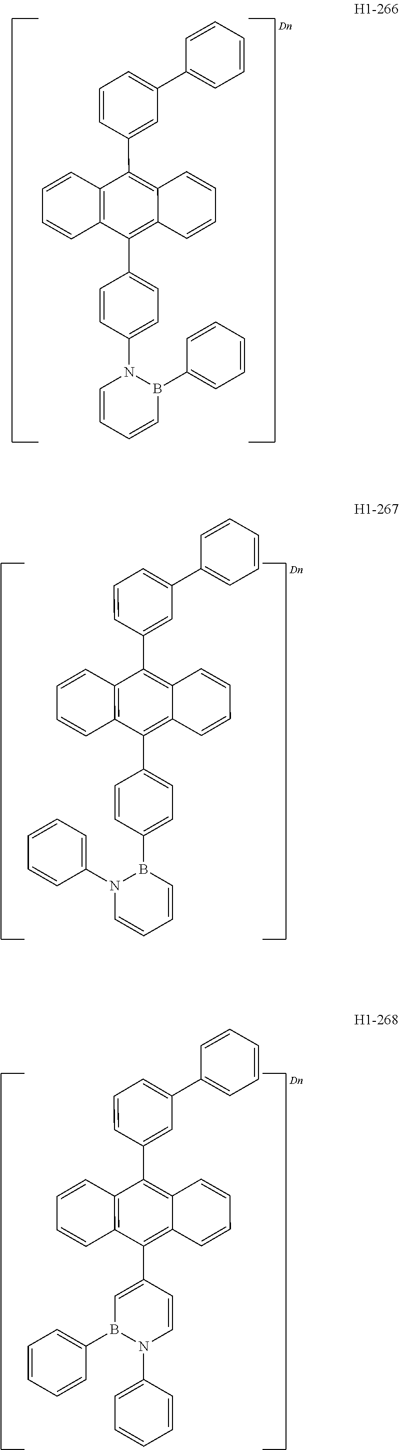 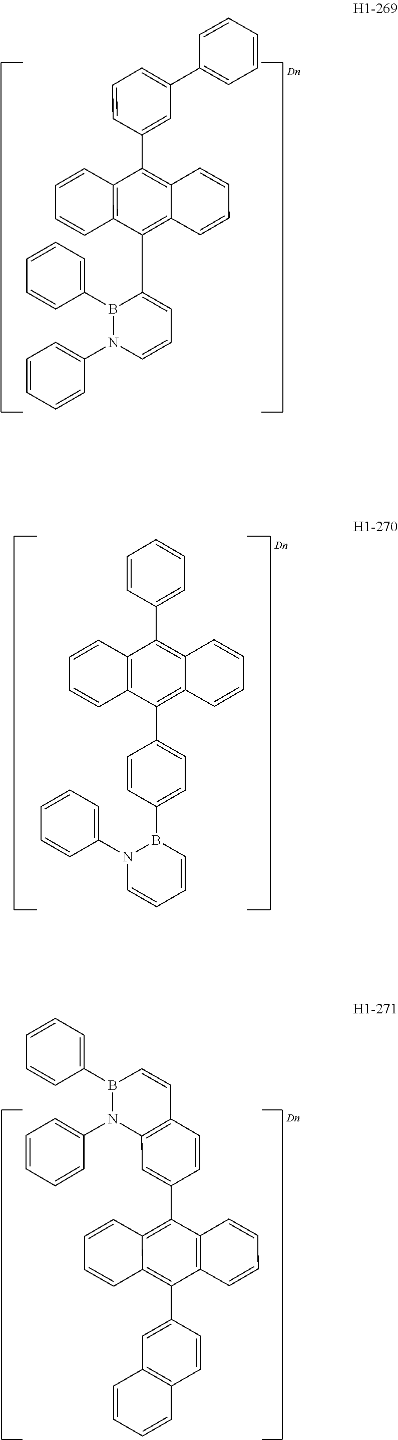 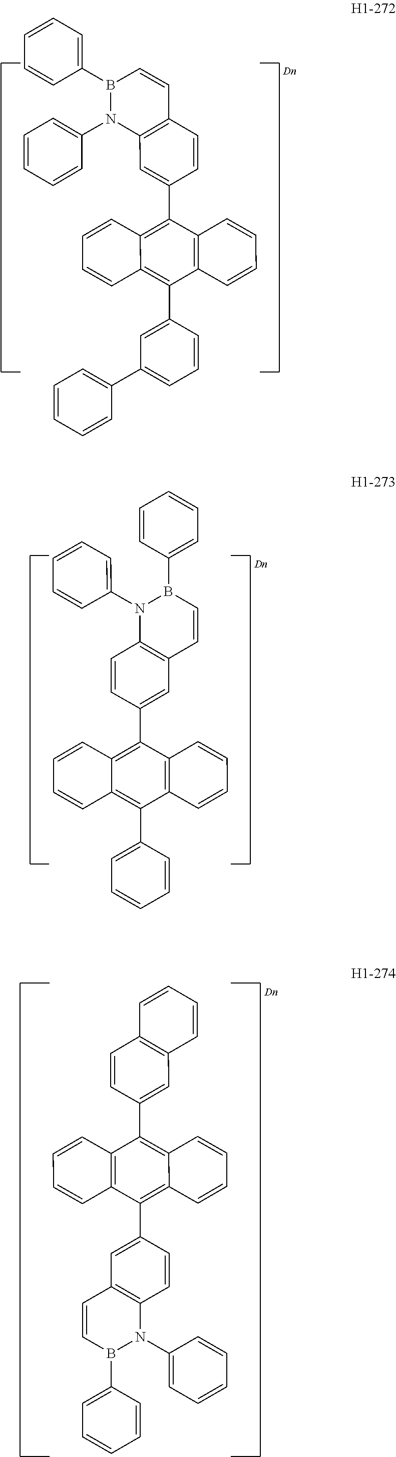 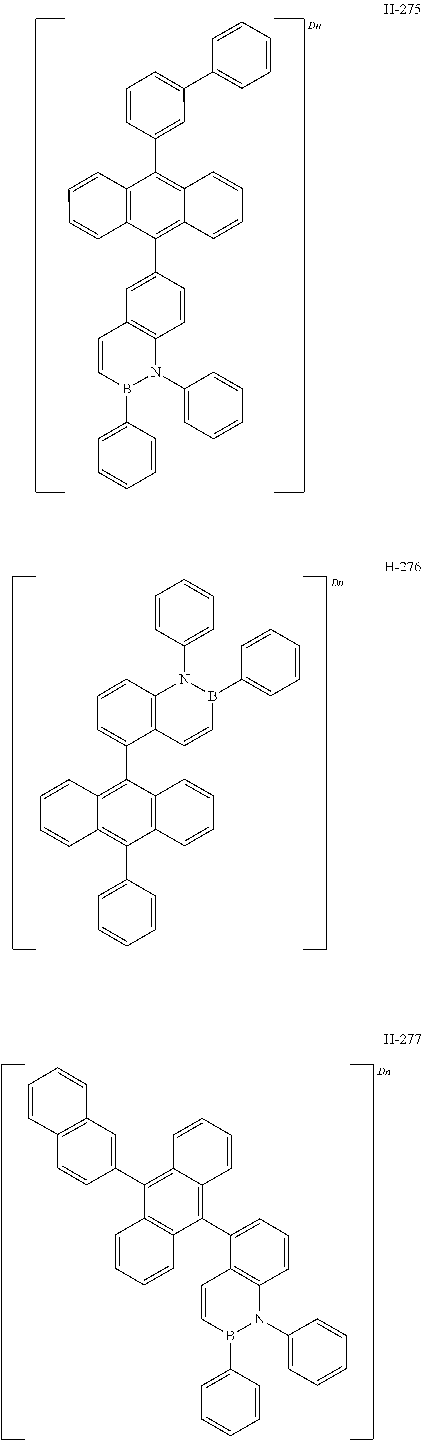 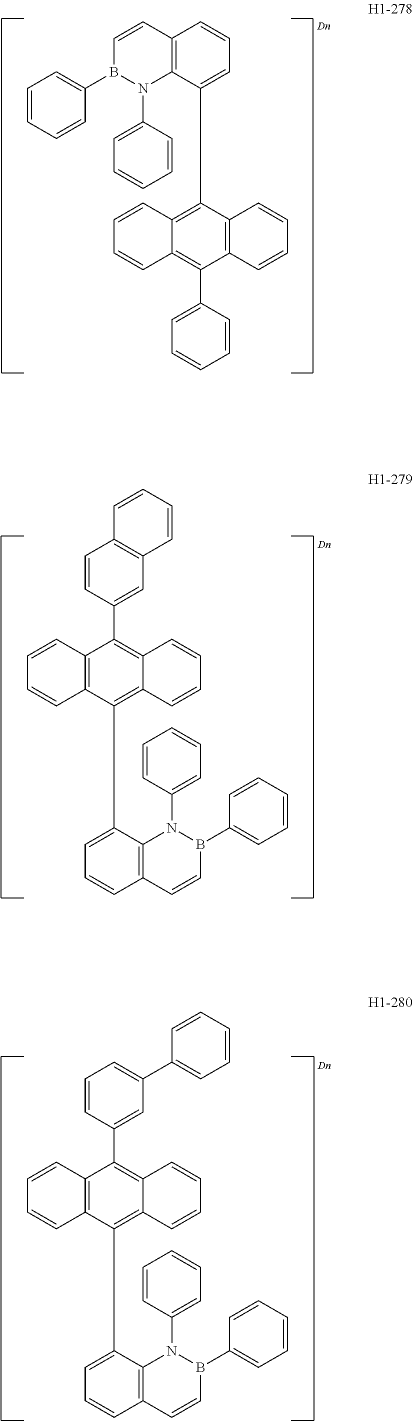 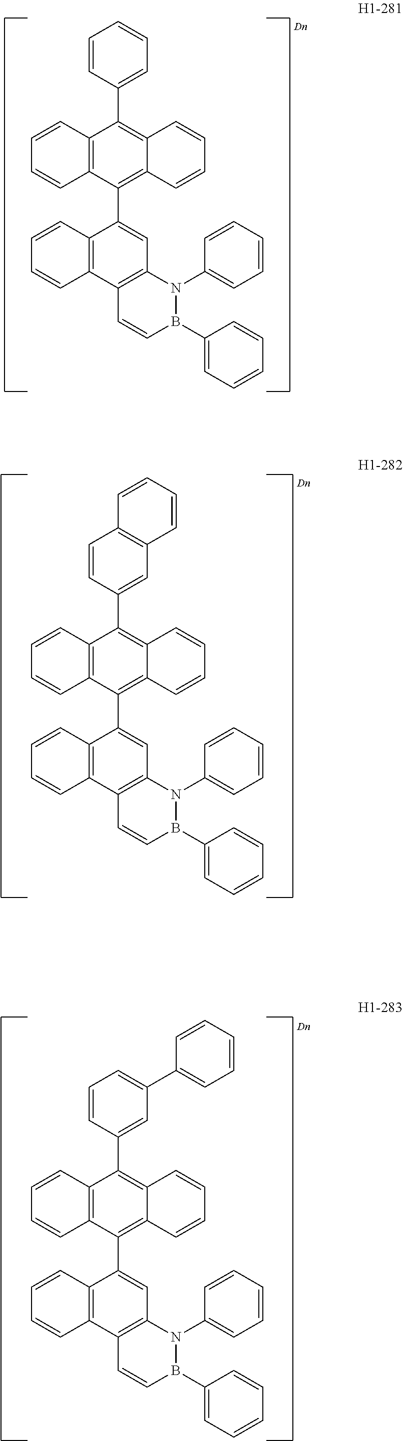 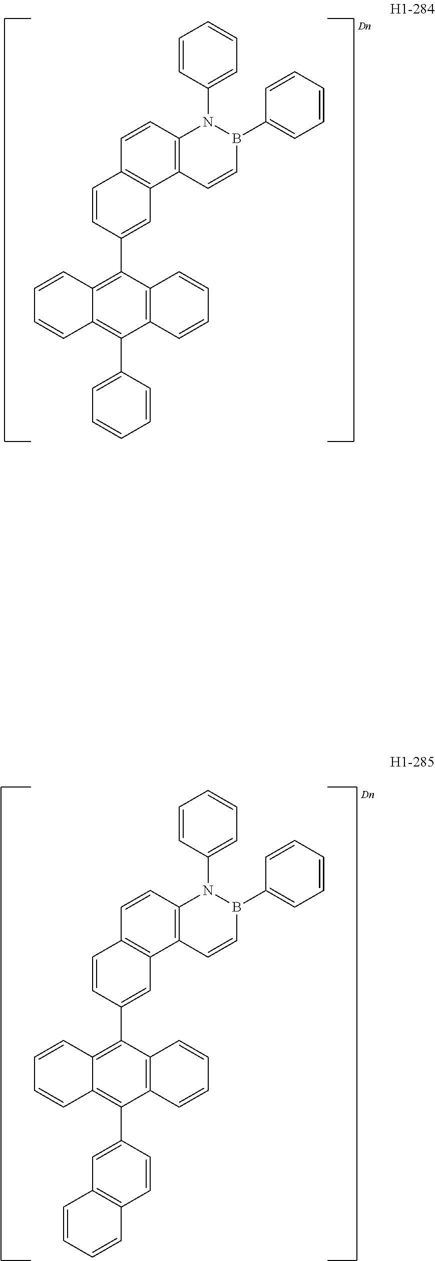 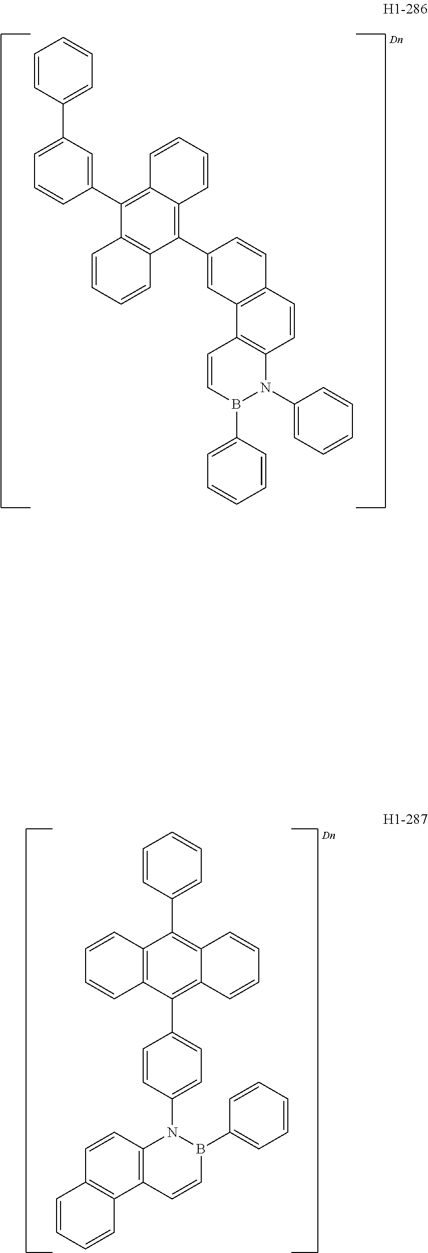 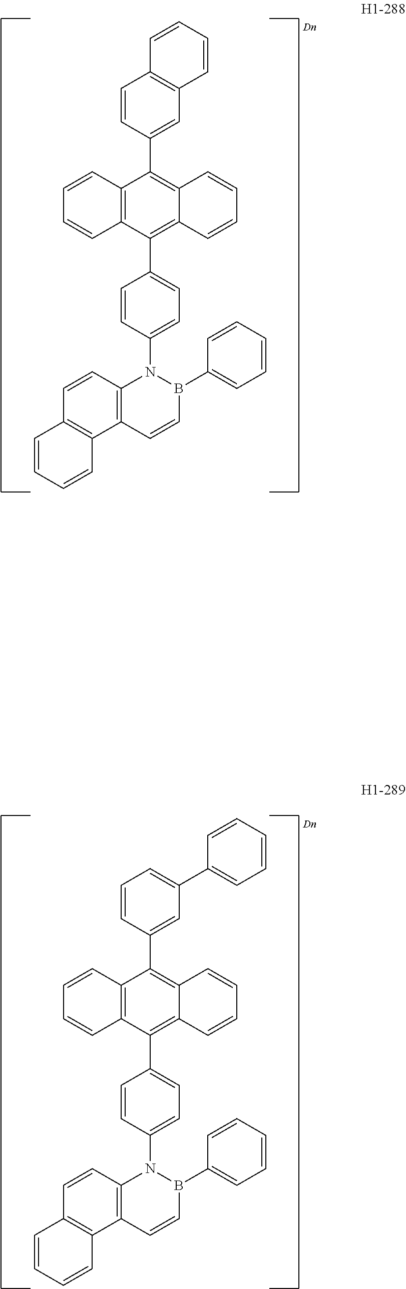 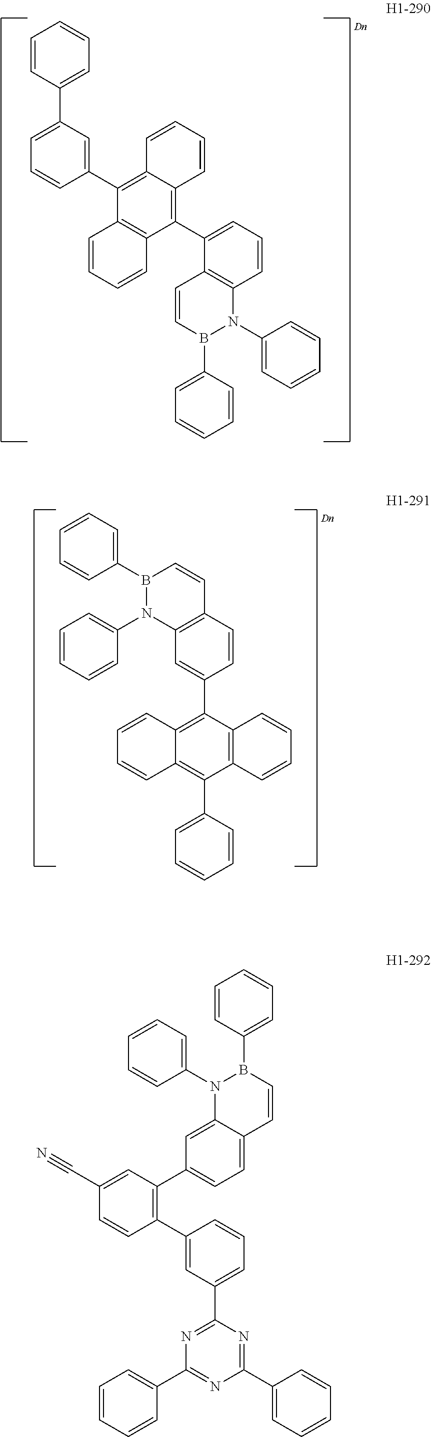 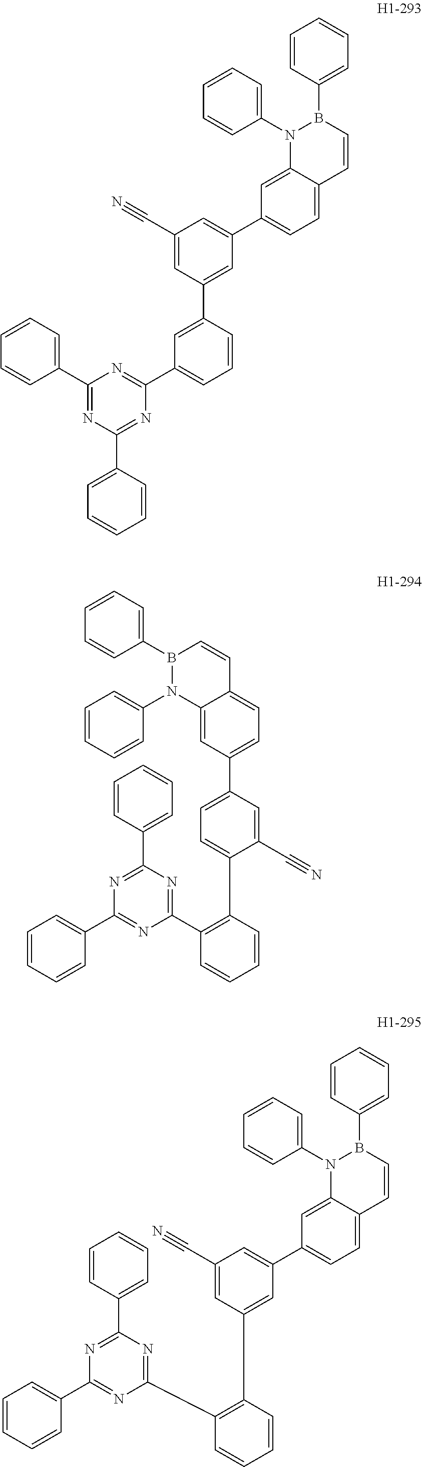 [SMILES: N#Cc1cc(-c2cccc(-c3nc(-c4ccccc4)nc(-c4ccccc4)n3)c2)cc(-c2ccc3c(c2)N(c2ccccc2)B(c2ccccc2)C=C3)c1 ; N#Cc1cc(-c2ccc3c(c2)N(c2ccccc2)B(c2ccccc2)C=C3)ccc1-c1ccccc1-c1nc(-c2ccccc2)nc(-c2ccccc2)n1 ; N#Cc1cc(-c2ccc3c(c2)N(c2ccccc2)B(c2ccccc2)C=C3)cc(-c2ccccc2-c2nc(-c3ccccc3)nc(-c3ccccc3)n2)c1] 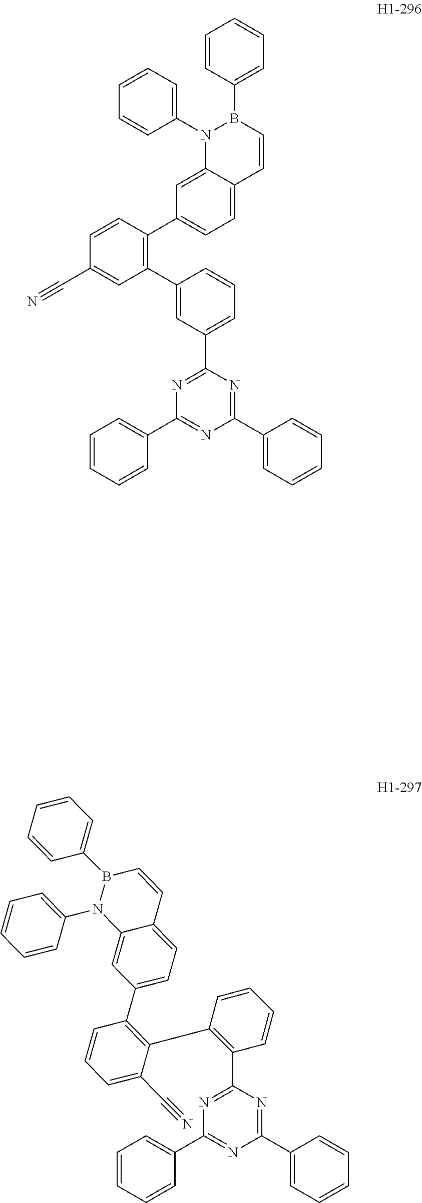 [SMILES: N#Cc1ccc(-c2ccc3c(c2)N(c2ccccc2)B(c2ccccc2)C=C3)c(-c2cccc(-c3nc(-c4ccccc4)nc(-c4ccccc4)n3)c2)c1 ; N#Cc1cccc(-c2ccc3c(c2)N(c2ccccc2)B(c2ccccc2)C=C3)c1-c1ccccc1-c1nc(-c2ccccc2)nc(-c2ccccc2)n1] 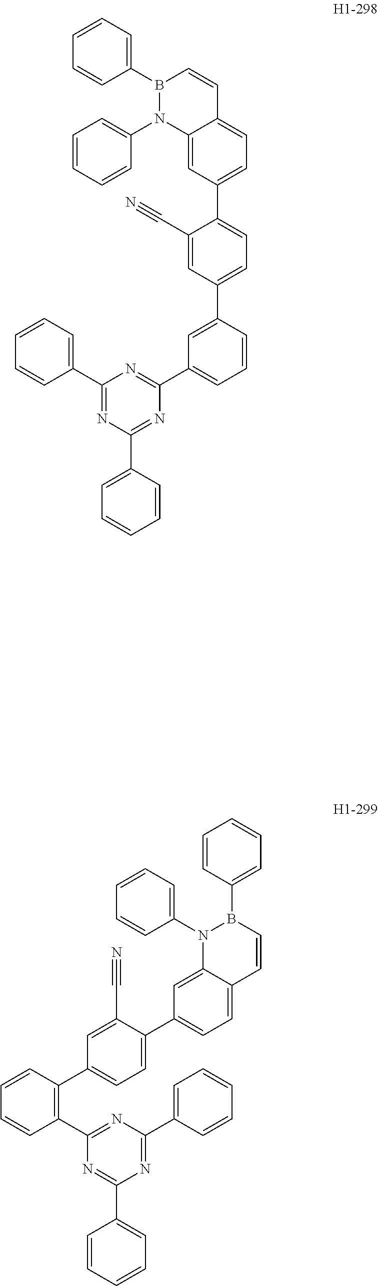 [SMILES: N#Cc1cc(-c2cccc(-c3nc(-c4ccccc4)nc(-c4ccccc4)n3)c2)ccc1-c1ccc2c(c1)N(c1ccccc1)B(c1ccccc1)C=C2 ; N#Cc1cc(-c2ccccc2-c2nc(-c3ccccc3)nc(-c3ccccc3)n2)ccc1-c1ccc2c(c1)N(c1ccccc1)B(c1ccccc1)C=C2] 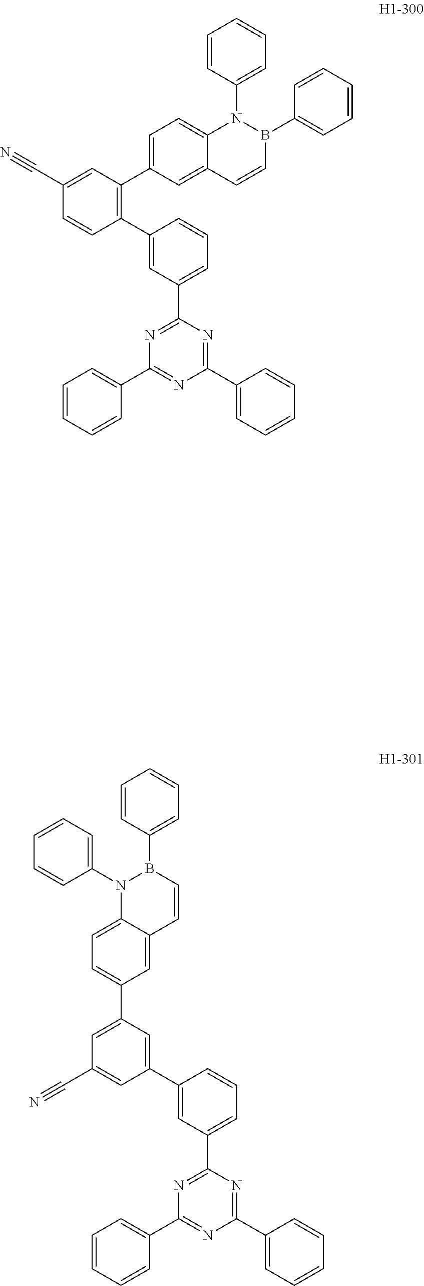 [SMILES: N#Cc1ccc(-c2cccc(-c3nc(-c4ccccc4)nc(-c4ccccc4)n3)c2)c(-c2ccc3c(c2)C=CB(c2ccccc2)N3c2ccccc2)c1 ; N#Cc1cc(-c2cccc(-c3nc(-c4ccccc4)nc(-c4ccccc4)n3)c2)cc(-c2ccc3c(c2)C=CB(c2ccccc2)N3c2ccccc2)c1] 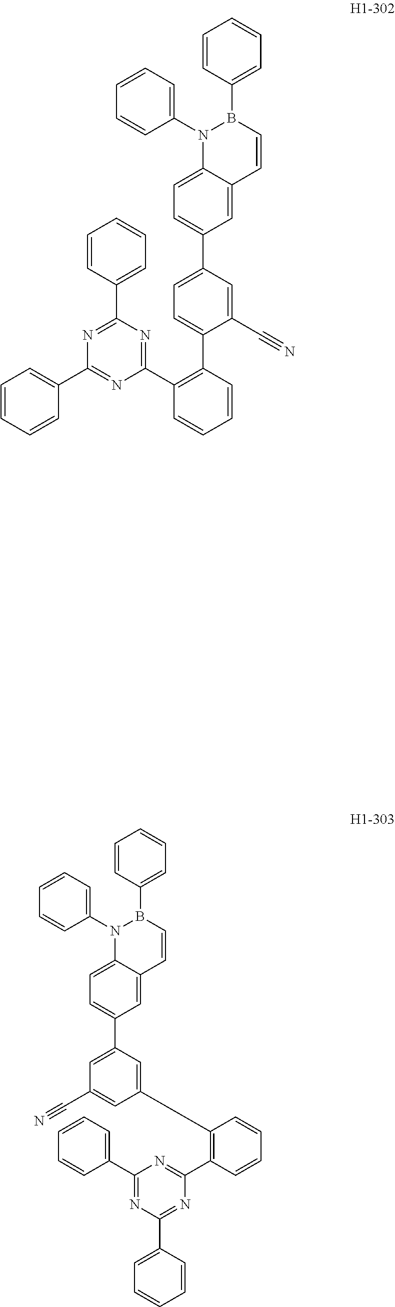 [SMILES: N#Cc1cc(-c2ccc3c(c2)C=CB(c2ccccc2)N3c2ccccc2)ccc1-c1ccccc1-c1nc(-c2ccccc2)nc(-c2ccccc2)n1 ; N#Cc1cc(-c2ccc3c(c2)C=CB(c2ccccc2)N3c2ccccc2)cc(-c2ccccc2-c2nc(-c3ccccc3)nc(-c3ccccc3)n2)c1] 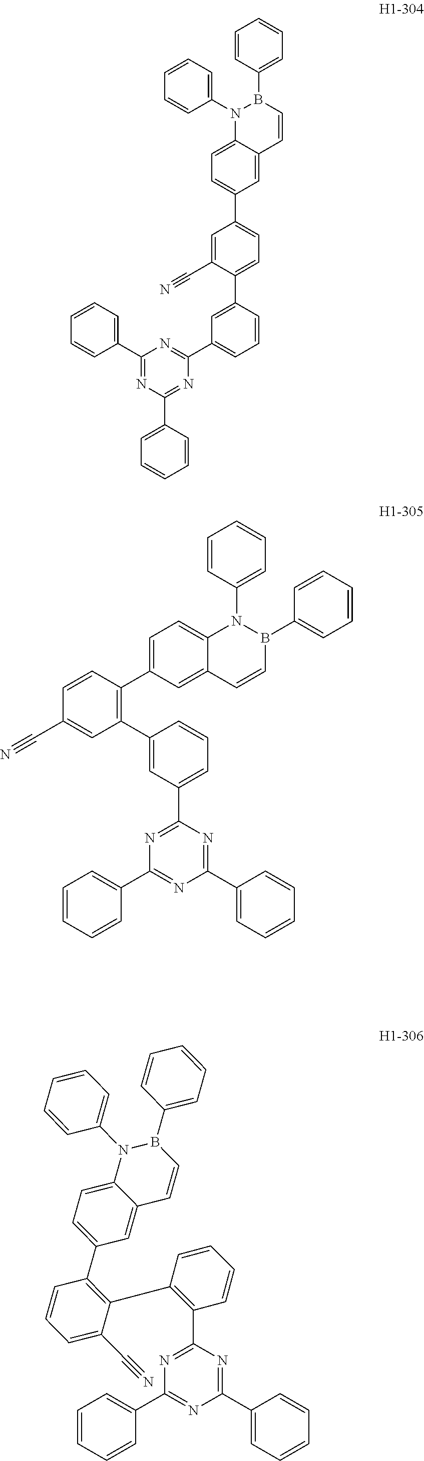 [SMILES: N#Cc1cc(-c2ccc3c(c2)C=CB(c2ccccc2)N3c2ccccc2)ccc1-c1cccc(-c2nc(-c3ccccc3)nc(-c3ccccc3)n2)c1 ; N#Cc1ccc(-c2ccc3c(c2)C=CB(c2ccccc2)N3c2ccccc2)c(-c2cccc(-c3nc(-c4ccccc4)nc(-c4ccccc4)n3)c2)c1 ; N#Cc1cccc(-c2ccc3c(c2)C=CB(c2ccccc2)N3c2ccccc2)c1-c1ccccc1-c1nc(-c2ccccc2)nc(-c2ccccc2)n1] 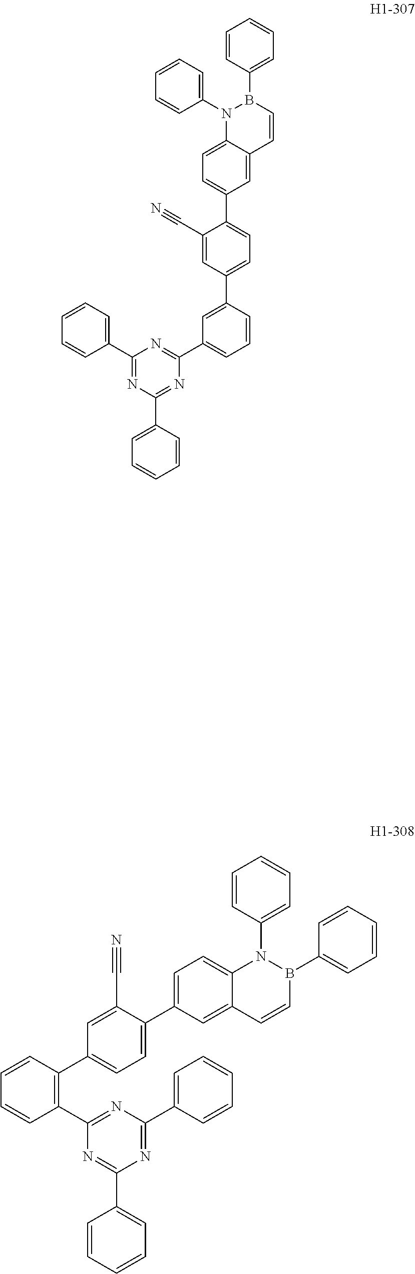 [SMILES: N#Cc1cc(-c2cccc(-c3nc(-c4ccccc4)nc(-c4ccccc4)n3)c2)ccc1-c1ccc2c(c1)C=CB(c1ccccc1)N2c1ccccc1 ; N#Cc1cc(-c2ccccc2-c2nc(-c3ccccc3)nc(-c3ccccc3)n2)ccc1-c1ccc2c(c1)C=CB(c1ccccc1)N2c1ccccc1] 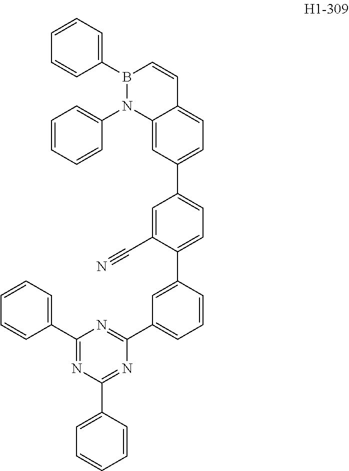 [SMILES: N#Cc1cc(-c2ccc3c(c2)N(c2ccccc2)B(c2ccccc2)C=C3)ccc1-c1cccc(-c2nc(-c3ccccc3)nc(-c3ccccc3)n2)c1]
in the compounds above, Dₙ means that n number of hydrogens are replaced with deuterium, and n represents an integer from 1 to the maximum number of hydrogens in the compound.

23. An organic electroluminescent material comprising the organic electroluminescent compound according to claim 15.

24. An organic electroluminescent device comprising the organic electroluminescent compound according to claim 15.

25. An organic electroluminescent device comprising the organic electroluminescent compound according to claim 15 in a light-emitting layer as a phosphorescent host material.

26. The organic electroluminescent device according to claim 25, wherein the light-emitting layer emits red light.

27. The organic electroluminescent device according to claim 24, wherein the organic electroluminescent compound is comprised in at least one layer of a hole transport layer, a light-emitting layer, a hole auxiliary layer, an electron blocking layer, and a light-emitting auxiliary layer.
